(19) United States
(12) Patent Application Publication
(10) Pub. No.: US 2024/0315135 A1
(43) Pub. Date: Sep. 19, 2024

(54) LIGHT EMITTING ELEMENT AND FUSED POLYCYCLIC COMPOUND FOR LIGHT EMITTING ELEMENT

(71) Applicant: Samsung Display Co., Ltd., Yongin-si (KR)

(72) Inventors: MinJae SUNG, Yongin-si (KR); TAEIL KIM, Yongin-si (KR); SUN YOUNG PAK, Yongin-si (KR); KYOUNG SUNWOO, Yongin-si (KR); MUN-KI SIM, Yongin-si (KR); CHANSEOK OH, Yongin-si (KR)

(73) Assignee: Samsung Display Co., Ltd., Yongin-si (KR)

(21) Appl. No.: 18/530,593

(22) Filed: Dec. 6, 2023

(30) Foreign Application Priority Data
Feb. 21, 2023 (KR) 10-2023-0023167

(51) Int. Cl. H10K 85/60; C07F 5/02; C09K 11/06

(52) U.S. Cl. CPC H10K 85/658; C07F 5/027; C09K 11/06; C07B 2200/05; C09K 2211/1018; H10K 50/11

(57) ABSTRACT

Embodiments provide fused polycyclic compound and a light emitting element that includes the fused polycyclic compound. The light emitting element include a first electrode, a second electrode facing the first electrode, and an emission layer disposed between the first electrode and the second electrode and including the fused polycyclic compound. The fused polycyclic compound is represented by Formula 1, which is explained in the specification:

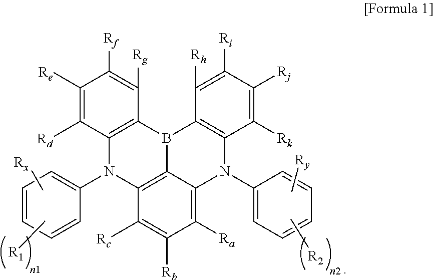

### CROSS-REFERENCE TO RELATED APPLICATION(S)

This application claims priority to and benefits of Korean Patent Application No. 10-2023-0023167 under 35 U.S.C. § 119, filed on Feb. 21, 2023, in the Korean Intellectual Property Office, the entire contents of which are incorporated herein by reference.

### BACKGROUND

### 1. Technical Field

The disclosure relates to a light emitting element and a fused polycyclic compound used therein.

### 2. Description of the Related Art

Active development continues for organic electroluminescence display devices and the like as image display devices. In contrast to liquid crystal display devices and the like, an organic electroluminescence display device is a so-called self-luminescent display device in which holes and electrons respectively injected from a first electrode and a second electrode recombine in an emission layer, so that a light emitting material including an organic compound in the emission layer emits light to achieve display.

In the application of an organic electroluminescence element to a display device, there is a demand for an organic electroluminescence element having low driving voltage, high emission efficiency, and a long life, and continuous development is required on materials for an organic electroluminescence element that is capable of stably achieving such characteristics.

In order to implement a highly efficient organic electroluminescence element, technologies pertaining to phosphorescence emission, which uses triplet state energy, or to fluorescence emission, which uses triplet-triplet annihilation (TTA) in which singlet excitons are generated through collision of triplet excitons, are being developed. Development is presently directed to thermally activated delayed fluorescence (TADF) materials which use delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a light emitting element having increased light emitting efficiency and longer element service life.

Embodiments also provide a fused polycyclic compound capable of improving light emitting efficiency and element service life.

An embodiment provides a light emitting element which may include a first electrode, a second electrode facing the first electrode, and an emission layer disposed between the first electrode and the second electrode, wherein the emission layer includes a first compound represented by Formula 1:

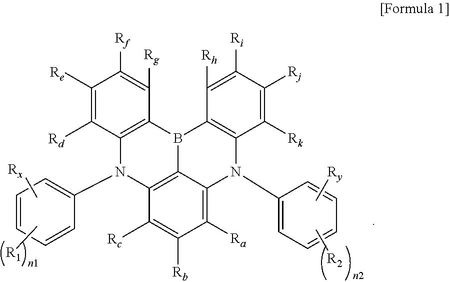

In Formula 1, R₁, R₂, and Rₐ to Rₖ may each independently be a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring; Rₓ and R_{y} may each independently be a substituted or unsubstituted aryl group having 6 to 30 ring-forming carbon atoms, a substituted or unsubstituted heteroaryl group having 2 to 30 ring-forming carbon atoms, or a group represented by Formula 2; n1 and n2 may each independently be an integer from 0 to 4; and at least one of Rₓ and R_{y} may each independently be a group represented by Formula 2.

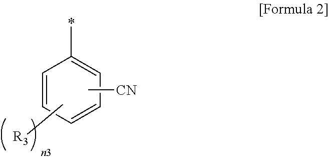

In Formula 2, R₃ may be a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; CN may be a cyano group; n3 may be an integer from 0 to 4; and [symbol] represents a bond to Formula 1.

In an embodiment, the light emitting element may further include a hole transport region disposed between the first electrode and the emission layer, and an electron transport region disposed between the emission layer and the second electrode.

In an embodiment, the emission layer may emit delayed fluorescence.

In an embodiment, the emission layer may emit light having a central wavelength in a range of about 430 nm to about 490 nm.

In an embodiment, a group represented by Formula 2 may be a group represented by any one of Formulas 2-1 to 2-3:

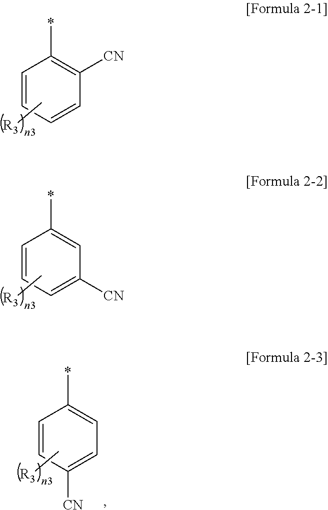

In Formulas 2-1 to 2-3, CN may be a cyano group.

In Formulas 2-1 to 2-3, R₃ and n3 are the same as defined in Formula 2.

In an embodiment, the first compound may be represented by Formula 1-1 or Formula 1-2:

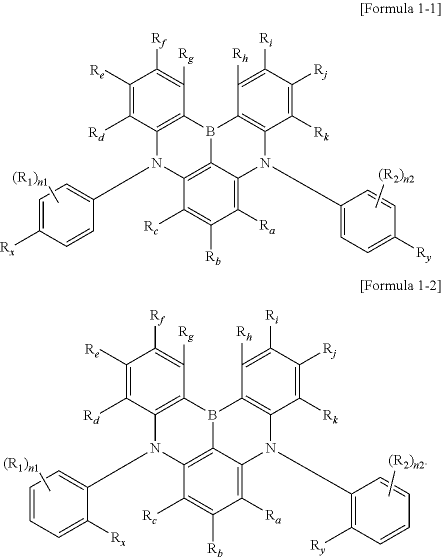

In Formulas 1-1 and 1-2, R₁, R₂, Rₐ to Rₖ, Rₓ, R_{y}, n1, and n2 are the same as defined in Formula 1.

In an embodiment, the first compound may be represented by Formula 3-1 or Formula 3-2:

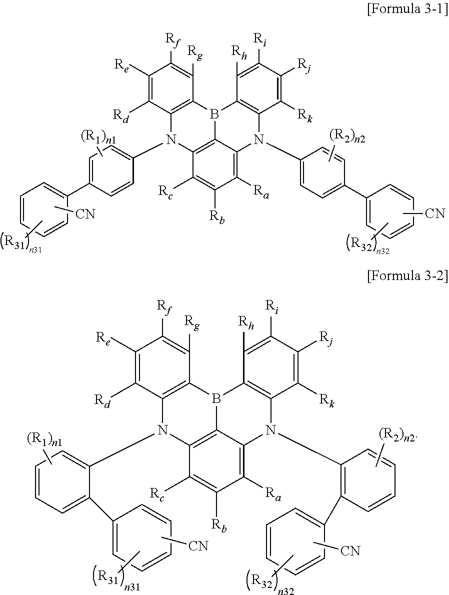

In Formulas 3-1 and 3-2, R₃₁ and R₃₂ may each independently be a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and n31 and n32 may each independently be an integer from 0 to 4.

In Formulas 3-1 and 3-2, R₁, R₂, Rₐ to Rₖ, n1, and n2 are the same as defined in Formula 1.

In an embodiment, the first compound may be represented by any one of Formulas 4-1 to 4-6:

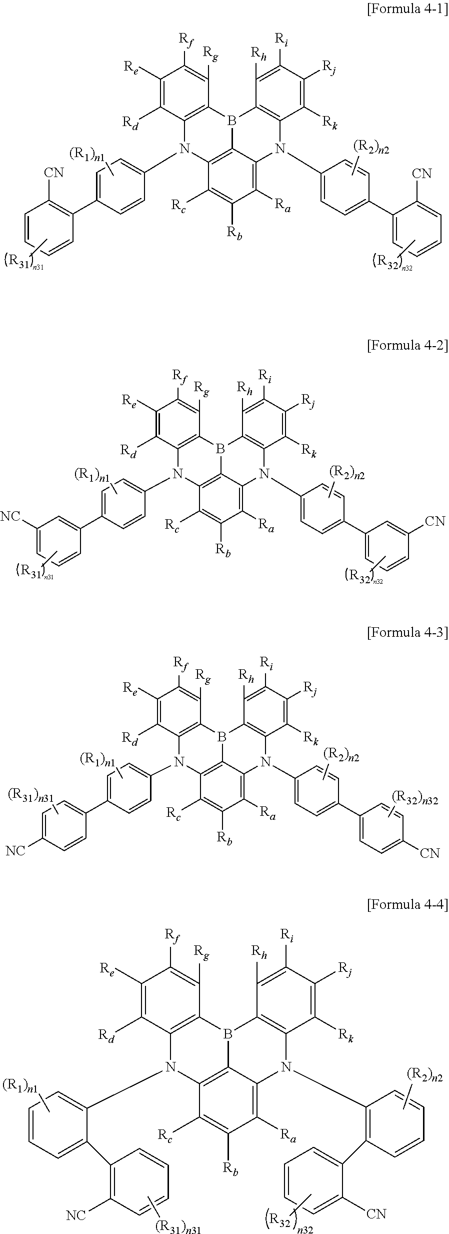

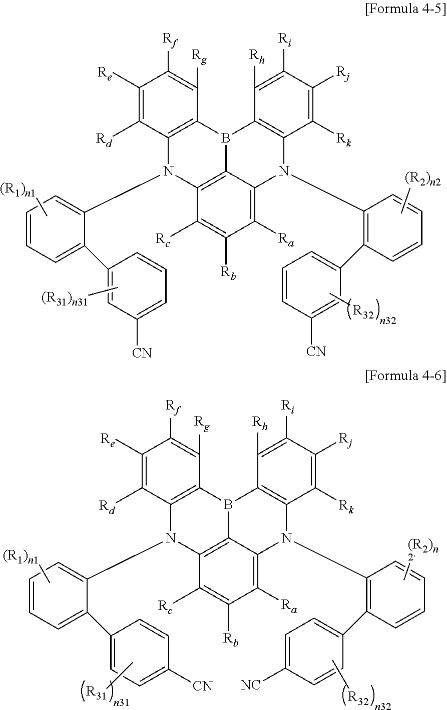

In Formulas 4-1 to 4-6, R₃₁ and R₃₂ may each independently be a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and n31 and n32 may each independently be an integer from 0 to 4.

In Formulas 4-1 to 4-6, R₁, R₂, Rₐ to Rₖ, n1, and n2 are the same as defined in Formula 1.

In an embodiment, the first compound may be represented by Formula 5:

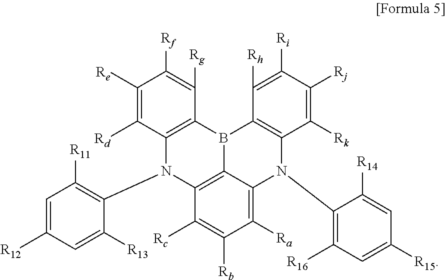

In Formula 5, R₁₁ to R₁₆ may each independently be a hydrogen atom, a deuterium atom, a substituted or unsubstituted aryl group having 6 to 30 ring-forming carbon atoms, a substituted or unsubstituted heteroaryl group having 2 to 30 ring-forming carbon atoms, or a group represented by Formula 2; and at least one of R₁₁ to R₁₆ may each independently be a group represented by Formula 2.

In Formula 5, Rₐ to Rₖ are the same as defined in Formula 1.

In an embodiment, R₁₁ to R₁₆ may each independently be a hydrogen atom, a deuterium atom, a group represented by Formula 2, or a group represented by any one of Formulas a-1 to a-7:

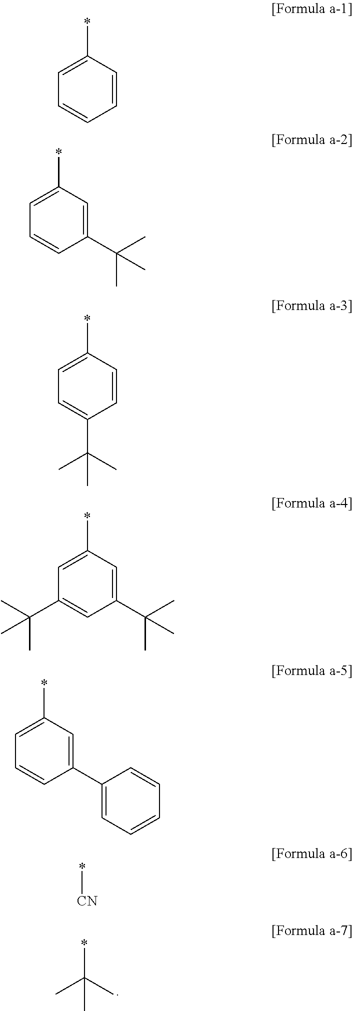

In Formulas a-1 to a-7, [symbol] represents a bond to Formula 5.

In an embodiment, the first compound may be represented by any one of Formulas 6-1 to 6-3:

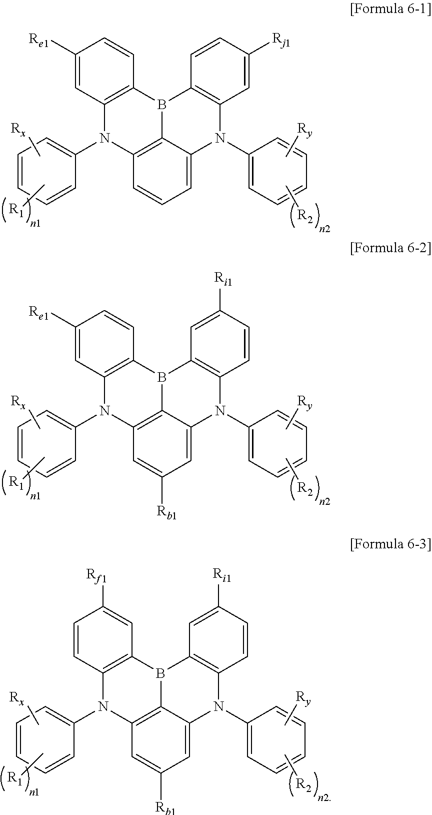

In Formulas 6-1 to 6-3, R_{b1}, Rₑ₁, R_{f1}, Rᵢ₁, and Rⱼ₁ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formulas 6-1 to 6-3, R₁, R₂, Rₓ, R_{y}, n1, and n2 are the same as defined in Formula 1.

In an embodiment, R_{b1}, Rₑ₁, R_{f1}, Rᵢ₁, and Rⱼ₁ may each independently be a group represented by any one of Formulas b-1 to b-5:

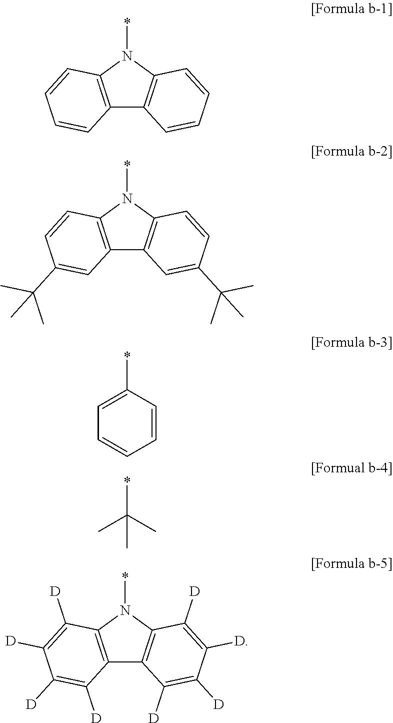

In Formulas b-1 to b-5, [symbol] represents a bond to one of Formulas 6-1 to 6-3.

In an embodiment, the first compound may include at least one compound selected from Compound Group 1, which is explained below.

In an embodiment, the emission layer may further include at least one of a second compound represented by Formula HT-1 and a third compound represented by Formula ET-1, which are each explained below.

In an embodiment, the emission layer may further include a fourth compound represented by Formula D-1, which is explained below.

Embodiments provide a fused polycyclic compound which may be represented by Formula 1, which is explained herein.

In an embodiment, the fused polycyclic compound represented by Formula 1 may be represented by Formula 3-1 or Formula 3-2, which are explained herein.

In an embodiment, the fused polycyclic compound represented by Formula 1 may be represented by any one of Formulas 4-1 to 4-6, which are explained herein.

In an embodiment, the fused polycyclic compound represented by Formula 1 may be represented by Formula 5, which is explained herein.

In an embodiment, the fused polycyclic compound may be selected from Compound Group 1, which is explained below.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display apparatus according to an embodiment;

FIG. 2 is a schematic cross-sectional view of a display apparatus according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display apparatus according to an embodiment;

FIG. 8 is a schematic cross-sectional view of a display apparatus according to an embodiment;

FIG. 9 is a schematic cross-sectional view of a display apparatus according to an embodiment;

FIG. 10 is a schematic cross-sectional view of a display apparatus according to an embodiment; and

FIG. 11 is a schematic perspective view of a vehicle in which a display apparatus is disposed, according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/of”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group including at least one carbon-carbon double bond in the middle or at a terminus of an alkyl group having 2 or more carbon atoms. An alkenyl group may be linear or branched. The number of carbon atoms in an alkenyl group is not particularly limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group including at least one carbon-carbon triple bond in the middle or at a terminus of an alkyl group having 2 or more carbon atoms. An alkynyl group may be linear or branched. The number of carbon atoms in an alkynyl group is not particularly limited, but may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

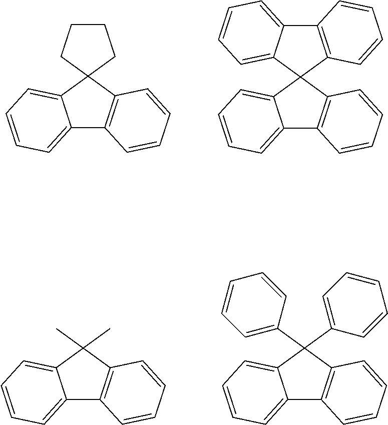

In the specification, a heterocyclic group may be any functional group or substituent derived from a ring including at least one of B, O, N, P, Si, S, and Se as a heteroatom. A heterocyclic group may be an aliphatic heterocyclic group or an aromatic heterocyclic group. An aromatic heterocyclic group may be a heteroaryl group. An aliphatic heterocycle and an aromatic heterocycle may each independently be monocyclic or polycyclic.

In the specification, a heterocyclic group may include at least one of B, O, N, P, Si, S, and Se as a heteroatom. If a heterocyclic group includes two or more heteroatoms, the two or more heteroatoms may be the same as or different from each other. A heterocyclic group may be monocyclic or polycyclic. A heterocyclic group may be a heteroaryl group. The number of ring-forming carbon atoms in a heterocyclic group may be 2 to 30, 2 to 20, or 2 to 10.

In the specification, an aliphatic heterocyclic group may include at least one of B, O, N, P, Si, S, and Se as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B, O, N, P, Si, S, and Se as a heteroatom. If a heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. The above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, but may be 1 to 40, 1 to 30, or 1 to 20. For example, a carbonyl group may have one of the following structures, but embodiments are not limited thereto.

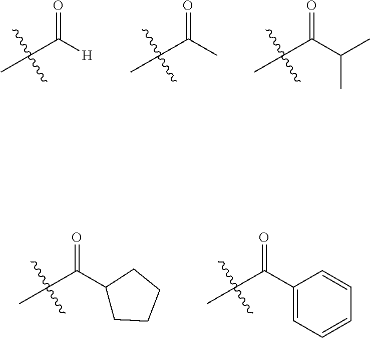

In the specification, the number of carbon atoms in a sulfinyl group or a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols [symbol] and [symbol] each represent a bond to a neighboring atom in a corresponding formula or moiety.

Hereinafter, embodiments will be described with reference to the accompanying drawings.

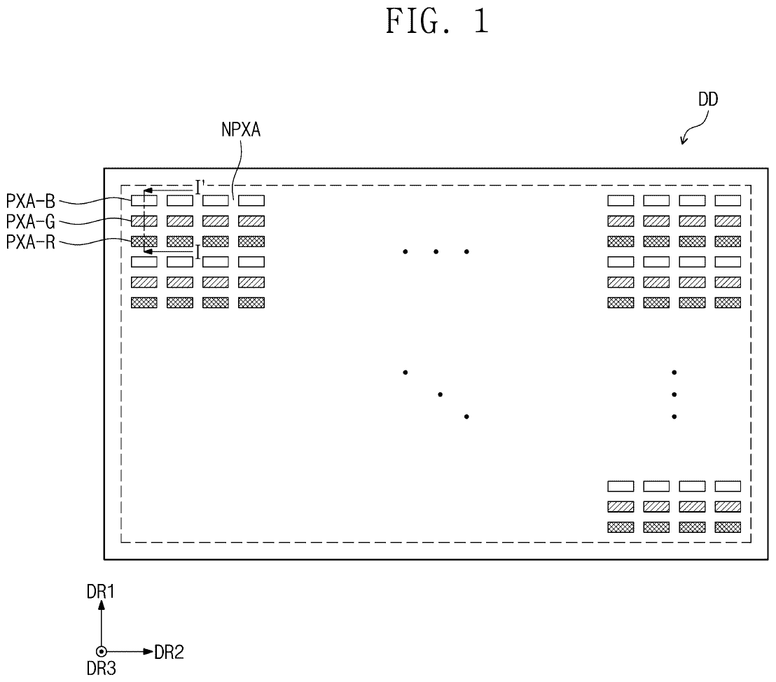

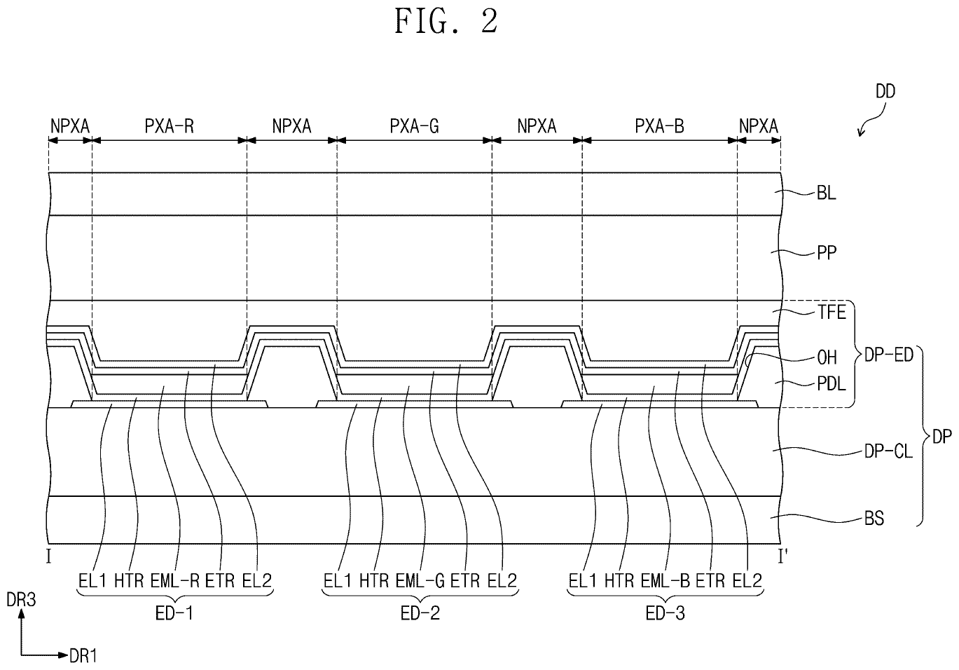

FIG. 1 is a schematic plan view of a display apparatus DD according to an embodiment. FIG. 2 is a schematic cross-sectional view of a display apparatus DD according to an embodiment. FIG. 2 is a schematic cross-sectional view illustrating a part taken along line I-I′ in FIG. 1.

The display apparatus DD may include a display panel DP and an optical layer PP disposed on the display panel DP. The display panel DP includes light emitting elements ED-1, ED-2, and ED-3. The display apparatus DD may include multiples of each of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display apparatus DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display apparatus DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display device layer DP-ED. The display device layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display device layer DP-ED.

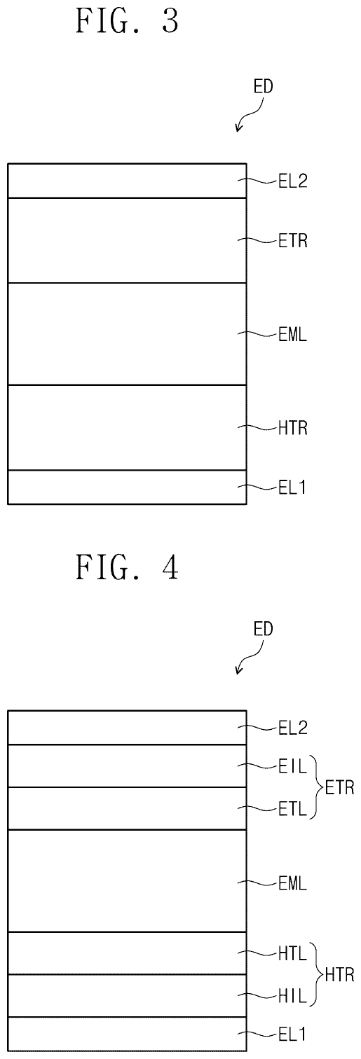

The light emitting elements ED-1, ED-2, and ED-3 may each have a structure of a light emitting element ED of an embodiment according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for the light emitting elements ED-1, ED-2, and ED-3. However, embodiments are not limited thereto. Although not illustrated in FIG. 2, in an embodiment, the hole transport region HTR and the electron transport region ETR may each be provided by being patterned in the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 may each be provided by being patterned through an inkjet printing method.

The encapsulation layer TFE may cover the light emitting elements ED-1, ED-2, and ED-3. The encapsulation layer TFE may seal the display device layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). In an embodiment, the encapsulation layer TFE may include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display apparatus DD may include non-light emitting regions NPXA and light emitting regions PXA-R, PXA-G, and PXA-B. The light emitting regions PXA-R, PXA-G, and PXA-B may each be a region that emits light generated from each of the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining film PDL. The non-light emitting regions NPXA may be areas between the adjacent light emitting areas PXA-R, PXA-G, and PXA-B, and which correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined by the pixel defining film PDL and separated from each other.

The light emitting regions PXA-R, PXA-G, and PXA-B may be arranged into groups according to the color of light generated from the light emitting elements ED-1, ED-2, and ED-3. In the display apparatus DD according to an embodiment illustrated in FIGS. 1 and 2, three light emitting regions PXA-R, PXA-G, and PXA-B, which respectively emit red light, green light, and blue light, are illustrated as an example. For example, the display apparatus DD may include a red light emitting region PXA-R, a green light emitting region PXA-G, and a blue light emitting region PXA-B, which are distinct from each other.

In the display apparatus DD according to an embodiment, the light emitting elements ED-1, ED-2, and ED-3 may emit light having wavelengths that are different from each other. For example, in an embodiment, the display apparatus DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display apparatus DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range or at least one light emitting element may emit light in a wavelength range that is different from the remainder. For example, the first to third light emitting elements ED-1, ED-2, and ED-3 may each emit blue light.

The light emitting regions PXA-R, PXA-G, and PXA-B in the display apparatus DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be alternately arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size or shape from each other, according to a wavelength range of emitted light. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics that are required for the display apparatus DD. For example, the light emitting regions PXA-R, PXA-G, and PXA-B may be arranged in a pentile configuration (such as PENTILE™) or in a diamond configuration (such as Diamond Pixel™).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIG. 3 to FIG. 6 are each a schematic cross-sectional view of a light emitting element according to an embodiment. The light emitting element ED according to an embodiment may include a first electrode EL1, a hole transport region HTR, an emission layer EML, an electron transport region ETR, and a second electrode EL2.

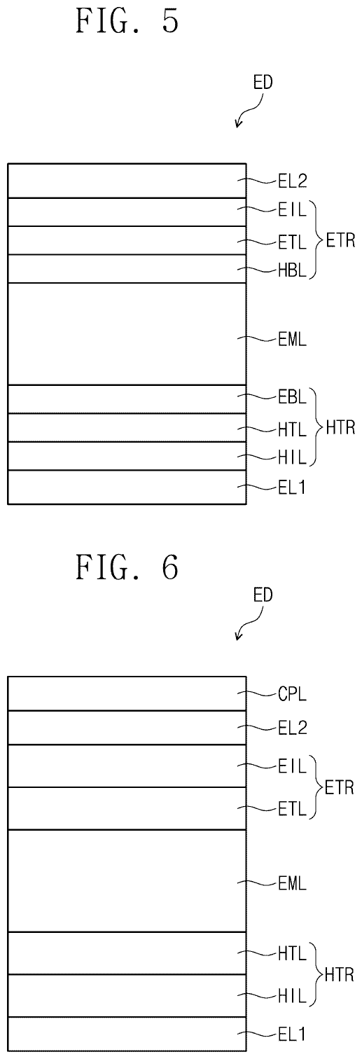

In comparison to FIG. 3, FIG. 4 is a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 is a schematic cross-sectional view of a light emitting element ED according to an embodiment that includes a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. In an embodiment, the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), and an electron blocking layer EBL. A thickness of the hole transport region HTR may be, for example, in a range of about 50 Å to about 15,000 Å.

The hole transport region HTR may be a layer consisting of a single material, a layer including different materials, or a structure including multiple layers including different materials.

In embodiments, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

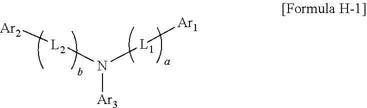

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, a compound represented by Formula H-1 may be a monoamine compound. In an embodiment, a compound represented by Formula H-1 may be a diamine compound in which at least one of Ar₁ to Ar₃ includes an amine group as a substituent. In another embodiment, a compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and the compound represented by Formula H-1 is not limited to Compound Group H:

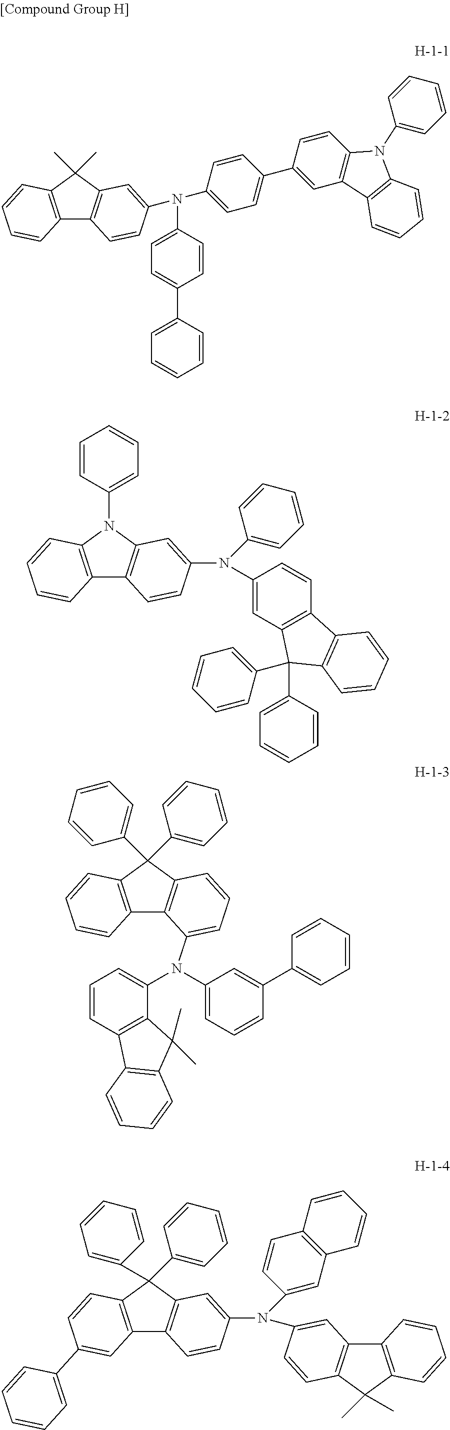 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

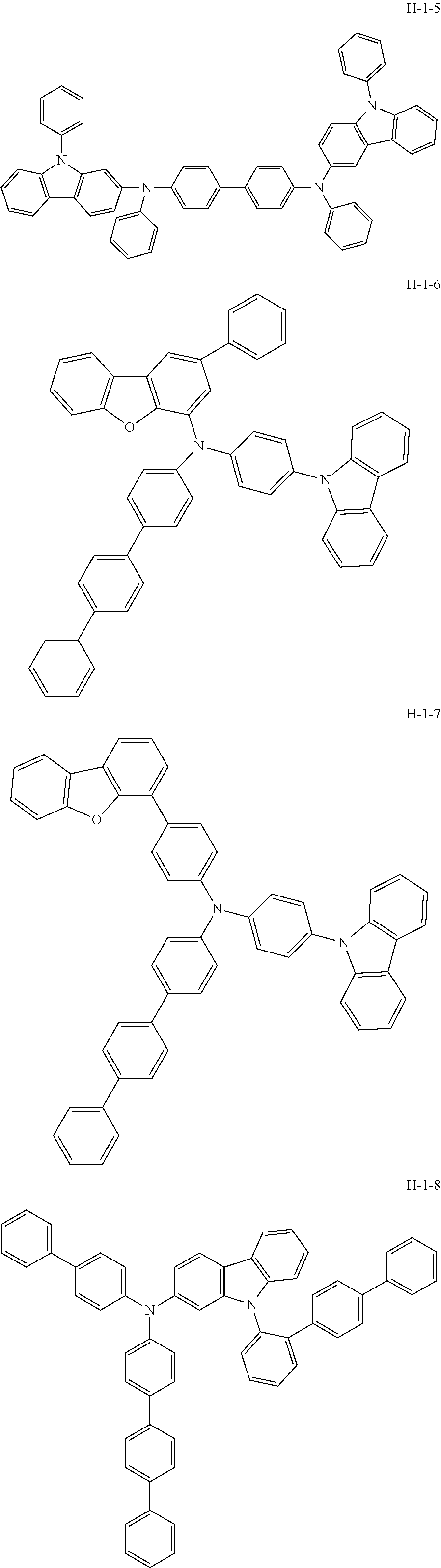 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1]

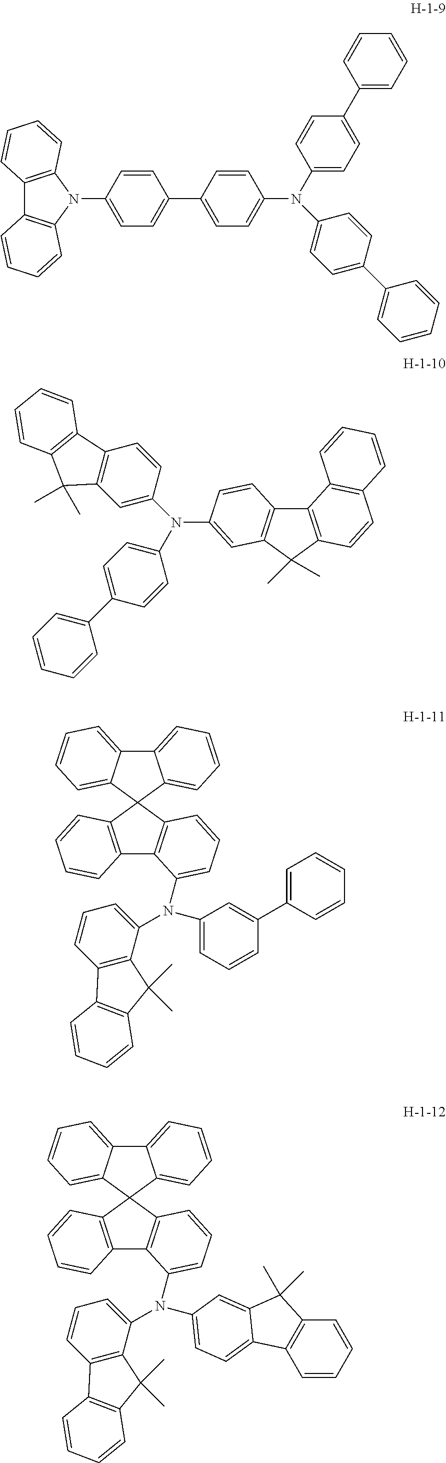 [SMILES: c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

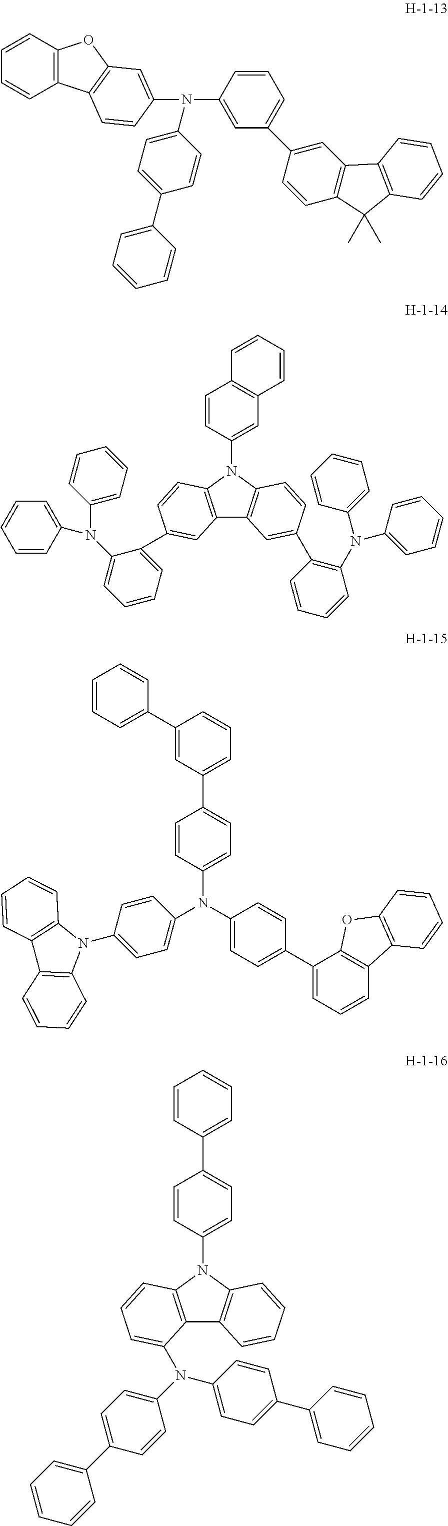 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

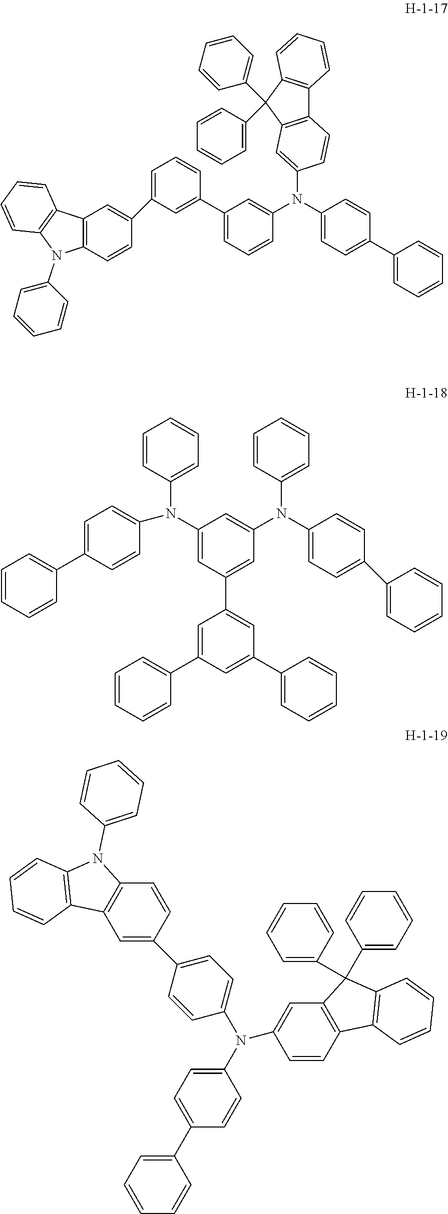 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto.

For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) and an electron blocking layer EBL, in addition to a hole injection layer HIL and a hole transport layer HTL. The buffer layer (not shown) may compensate for a resonance distance according to a wavelength of light emitted from the emission layer EML and may thus increase light emission efficiency. A material that may be included in the hole transport region HTR may be used as a material in the buffer layer (not shown). The electron blocking layer EBL may prevent injection of electrons from an electron transport region ETR to the hole transport region HTR.

The emission layer EML may be provided on the hole transport region HTR. The emission layer EML may have a thickness in a range of about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

The light emitting element ED according to an embodiment may include a fused polycyclic compound represented by Formula 1 in at least one functional layer disposed between the first electrode EL1 and the second electrode EL2. In the light emitting element ED, the emission layer EML may include the fused polycyclic compound according to an embodiment. In an embodiment, the emission layer EML may include the fused polycyclic compound as a dopant. The fused polycyclic compound may be a dopant material of the emission layer EML. In the specification, the fused polycyclic compound according to an embodiment, which will be described later, may be referred to as a first compound.

The fused polycyclic compound may have a structure in which multiple aromatic rings are fused together via at least one boron atom and at least two nitrogen atoms. For example, the fused polycyclic compound may include a fused ring core in which multiple aromatic rings are fused together via at least one boron atom and at least two nitrogen atoms.

The fused polycyclic compound may have a structure in which first to third aromatic rings are fused together via a first boron atom, a first nitrogen atom, and a second nitrogen atom. The first to third aromatic rings may each be linked to the first boron atom, the first aromatic ring and the second aromatic ring may be linked through the first nitrogen atom, and the first aromatic ring and the third aromatic ring may be linked through the second nitrogen atom. In the specification a structure in which the first to third aromatic rings are fused together via the boron atom, the first nitrogen atom, and the second nitrogen atom may be referred to as a “fused ring core”.

The fused polycyclic compound may include at least one first substituent. In the fused polycyclic compound, a first phenyl group may be linked to the first nitrogen atom, a second phenyl group may be linked to the second nitrogen atom, and at least one first substituent may be substituted on at least one of the first phenyl group and the second phenyl group. In the fused polycyclic compound, two or more first substituents may be provided, and the first substituents may be substituted on each of the first phenyl group and the second phenyl group.

The at least one first substituent includes a phenyl group and includes at least one cyano group substituted on the phenyl group. The fused polycyclic compound includes at least one first substituent including a cyano group, and accordingly, the fused polycyclic compound may include at least one cyano group.

The fused polycyclic compound according to an embodiment may be represented by Formula 1:

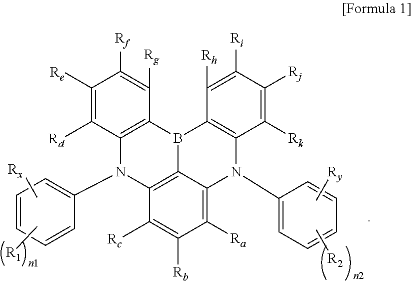

The fused polycyclic compound according to an embodiment, represented by Formula 1, has a structure in which three benzene rings are fused together through a boron atom and two nitrogen atoms. In the specification, the benzene ring which includes Rₐ to R_{c} in Formula 1 may correspond to the first aromatic ring described above, the benzene ring which includes R_{d} to R_{g} may correspond to the second aromatic ring described above, and the benzene ring which includes Rₕ to Rₖ may correspond to the third aromatic ring described above. The two nitrogen atoms in the fused ring core may correspond to the first nitrogen atom and the second nitrogen atom described above. The benzene ring that is linked to the first nitrogen atom and which includes Rₓ and R₁ may correspond to the first phenyl group described above, and the benzene ring that is linked to the second nitrogen atom and which includes R_{y} and R₂ may correspond to the second phenyl group described above. At least one of the substituents represented by Rₓ and R_{y} may correspond to the first substituent described above.

In Formula 1, R₁, R₂, and Rₐ to Rₖ may each independently be a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. In an embodiment, R₁ and R₂ may each independently be a hydrogen atom, a deuterium atom, or a substituted or unsubstituted aryl group having 6 to 30 ring-forming carbon atoms. For example, R₁ and R₂ may each independently be a hydrogen atom, a deuterium atom, a substituted or unsubstituted phenyl group, or a substituted or unsubstituted biphenyl group. In an embodiment, Rₐ to Rₖ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₐ to Rₖ may each independently be a hydrogen atom, a deuterium atom, a substituted or unsubstituted t-butyl group, a substituted or unsubstituted phenyl group, or a substituted or unsubstituted carbazole group.

In an embodiment, in Formula 1, R₁ and R₂ may each independently be a hydrogen atom, a deuterium atom, a group represented by one of Formulas a-1 to a-7, or a group represented by Formula 2, which will be described later.

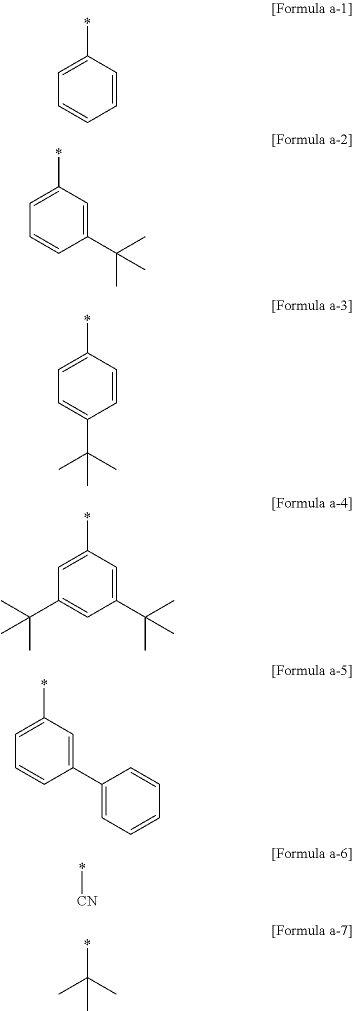

In Formulas a-1 to a-7, [symbol] represents a bond to Formula 1.

In an embodiment, in Formula 1, Rₐ to Rₖ may each independently be a hydrogen atom, a deuterium atom, or a group represented by one of Formulas b-1 to b-5. For example, Rₐ to Rₑ may each independently be a hydrogen atom, a deuterium atom, or a group represented by one Formula b-3 and Formula b-5. For example, R_{d} to Rₖ may each independently be a hydrogen atom, a deuterium atom, or a group represented by one of Formulas b-1 to b-5.

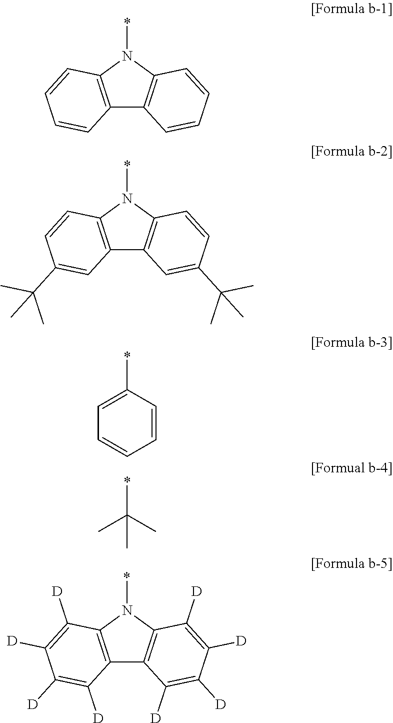

In Formulas b-1 to b-5, [symbol] represents a bond to Formula 1. In Formula 5, D represents a deuterium atom.

In Formula 1, n1 and n2 may each independently be an integer from 0 to 4. When n1 is 0, the fused polycyclic compound may not be substituted with R₁. A case where n1 is 4 and all R₁ groups are hydrogen atoms may be the same as a case where n1 is 0. When n1 is 2 or greater, multiple R₁ may be the same as each other, or at least one group thereof may be different from the remainder. When n2 is 0, the fused polycyclic compound may not be substituted with R₂. A case where n2 is 4 and all R₂ groups are hydrogen atoms may be the same as a case where n2 is 0. When n2 is 2 or greater, multiple R₂ groups may all be the same as each other, or at least one group thereof may be different from the remainder.

In Formula 1, Rₓ and R_{y} may each independently be a substituted or unsubstituted aryl group having 6 to 30 ring-forming carbon atoms, a substituted or unsubstituted heteroaryl group having 2 to 30 ring-forming carbon atoms, or a group represented by Formula 2. For example, Rₓ and R_{y} may each independently be a substituted or unsubstituted phenyl group, a substituted or unsubstituted biphenyl group, or a group represented by Formula 2. In Formula 1, at least one of Rₓ and R_{y} may each independently be a group represented by Formula 2. The group represented by Formula 2 may correspond to the “at least one first substituent” described above. The fused polycyclic compound represented by Formula 1 includes at least one group represented by Formula 2 in the molecular structure thereof.

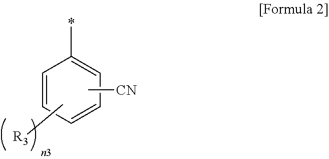

In Formula 2, R₃ may be a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₃ may be a hydrogen atom or a deuterium atom.

In Formula 2, n3 may be an integer from 0 to 4. When n3 is 0, the fused polycyclic compound may not be substituted with R₃. A case where n3 is 4 and all R₃ groups are hydrogen atoms may be the same as a case where n3 is 0. When n3 is 2 or greater, multiple R₃ groups may all be the same as each other, or at least one group thereof may be different from the remainder.

In Formula 2, CN is a cyano group. In the specification, a substituent represented by “—CN” or “NC—” is a cyano group.

In Formula 2, [symbol] represents a bond to Formula 1.

In an embodiment, a group represented by Formula 2 may be represented by any one of Formulas 2-1 to 2-3:

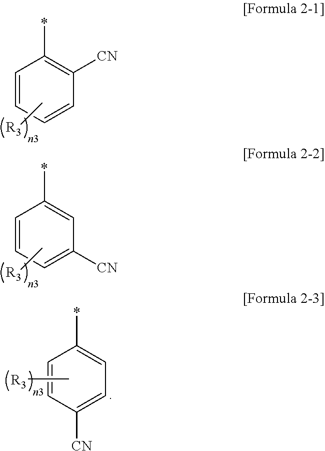

In Formulas 2-1 to 2-3, [symbol] represents a bond to Formula 1, and CN is a cyano group.

In Formulas 2-1 to 2-3, R₃ and n3 are the same as defined in Formula 2.

In an embodiment, the fused polycyclic compound represented by Formula 1 may be represented by Formula 1-1 or Formula 1-2:

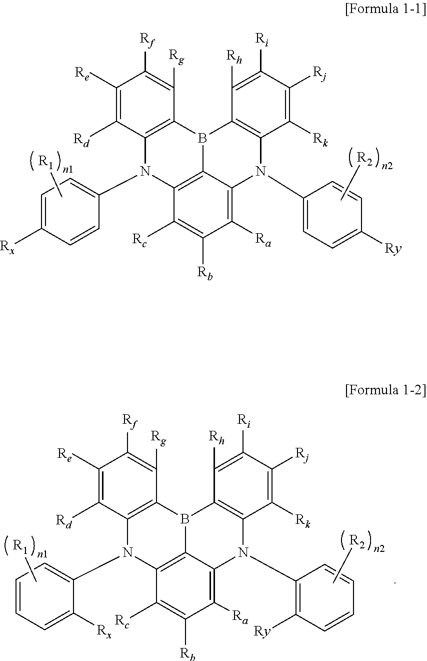

Formulas 1-1 and 1-2 each represent a case where the bonding positions of Rₓ and R_{y} in Formula 1 are further defined.

In Formulas 1-1 and 1-2, R₁, R₂, Rₐ to Rₖ, Rₓ, R_{y}, n1, and n2 are the same as defined in Formula 1.

In an embodiment, the fused polycyclic compound represented by Formula 1 may be represented by Formula 3-1 or Formula 3-2:

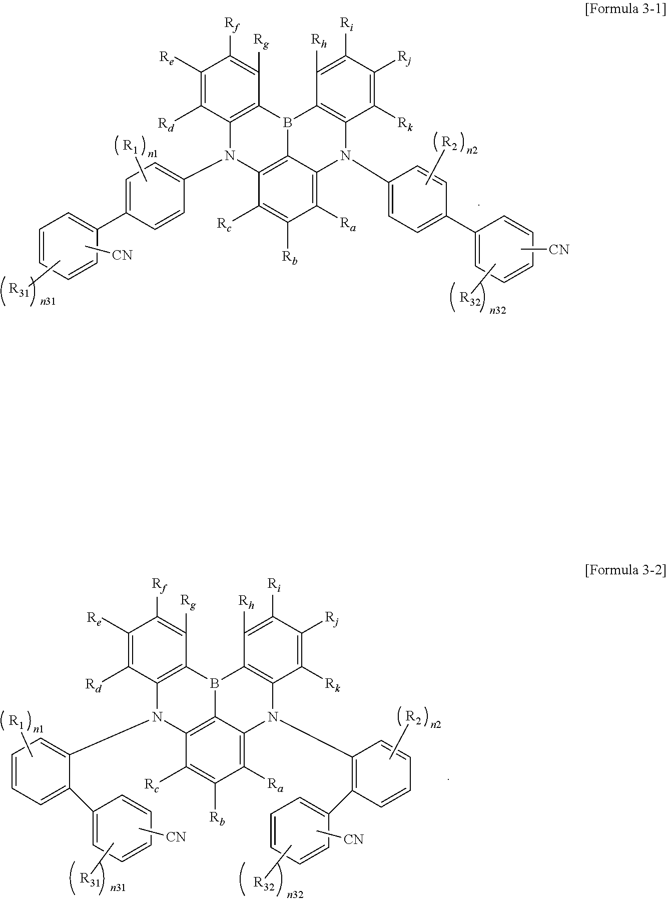

Formulas 3-1 and 3-2 each represent a case where Rₓ and R_{y} in Formula 1 are each a group represented by Formula 2 and the bonding position thereof is further defined.

In Formulas 3-1 and 3-2, R₃₁ and R₃₂ may each independently be a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₃₁ and R₃₂ may each independently be a hydrogen atom or a deuterium atom.

In Formulas 3-1 and 3-2, n31 and n32 may each independently be an integer from 0 to 4. When n31 is 0, the fused polycyclic compound may not be substituted with R₃₁. A case where n31 is 4 and all R₃₁ groups are hydrogen atoms may be the same as a case where n31 is 0. When n31 is 2 or greater, multiple R₃₁ groups may all be the same, or at least one group thereof may be different from the remainder. When n32 is 0, the fused polycyclic compound may not be substituted with R₃₂. A case where n32 is 4 and all R₃₂ groups hydrogen atoms may be the same as a case where n32 is 0. When n32 is 2 or greater, multiple R₃₂ groups may all be the same, or at least one group thereof may be different from the remainder.

In Formulas 3-1 to 3-2, R₁, R₂, Rₐ to Rₖ, n1, and n2 are the same as defined in Formula 1.

In an embodiment, the fused polycyclic compound represented by Formula 1 may be represented by any one of Formulas 4-1 to 4-6:

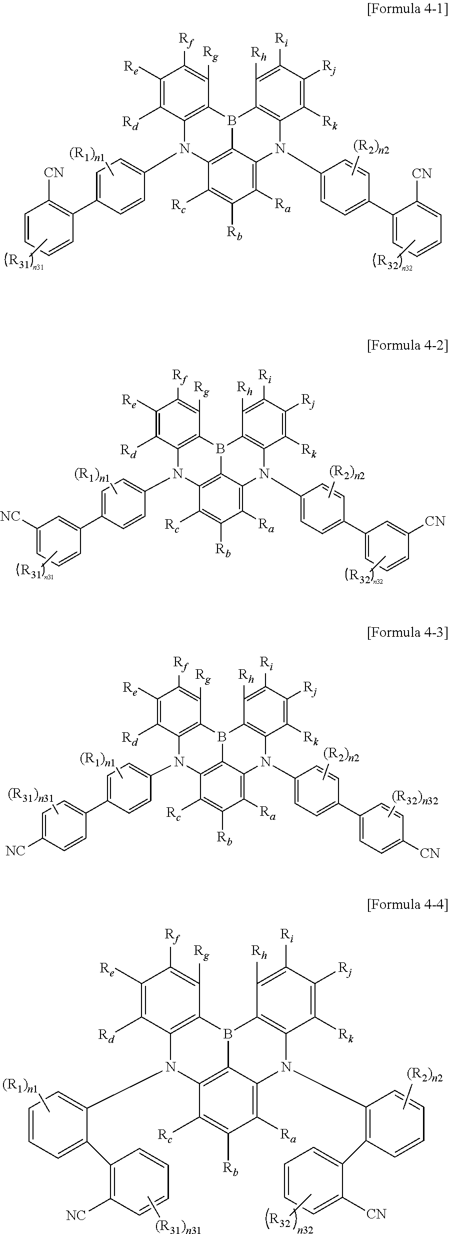

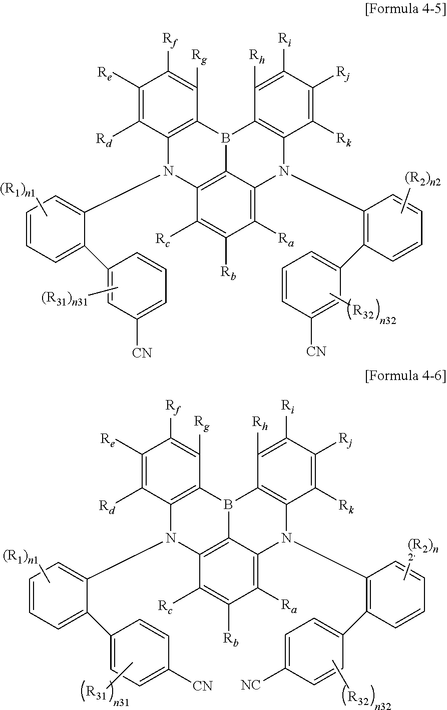

Formulas 4-1 to 4-6 each represent a case where Rₓ and R_{y} in Formula 1 are each a group represented by Formula 2, and a bonding position thereof is further defined, and a bonding position of a cyano group is also further defined.

In Formulas 4-1 to 4-6, R₁, R₂, Rₐ to Rₖ, n1, and n2 are the same as defined in Formula 1. In Formulas 4-1 to 4-6, R₃₁, R₃₂, n31, and n32 are the same as defined in Formulas 3-1 and 3-2.

In an embodiment, the fused polycyclic compound represented by Formula 1 may be represented by Formula 5:

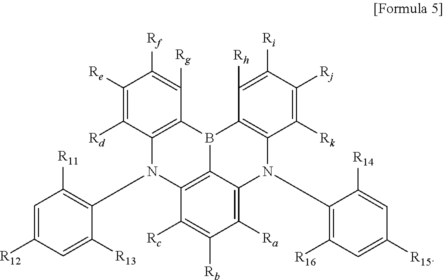

Formula 5 represents a case where a bonding position of a first substituent in each of the first phenyl group and the second phenyl group described above is further defined.

In Formula 5, R₁₁ to R₁₆ may each independently be a hydrogen atom, a deuterium atom, a substituted or unsubstituted aryl group having 6 to 30 ring-forming carbon atoms, a substituted or unsubstituted heteroaryl group having 2 to 30 ring-forming carbon atoms, or a group represented by Formula 2. In an embodiment, R₁₁ to R₁₆ may each independently be a hydrogen atom, a deuterium atom, a substituted or unsubstituted aryl group having 6 to 30 ring-forming carbon atoms, or a group represented by Formula 2. For example, R₁ to R₁₆ may each independently be a hydrogen atom, a deuterium atom, a substituted or unsubstituted phenyl group, a substituted or unsubstituted biphenyl group, or a group represented by Formula 2.

In an embodiment, in Formula 5, R₁₁ to R₁₆ may each independently be a hydrogen atom, a deuterium atom, a group represented by Formula 2, or a group represented by one of Formulas a-1 to a-7, wherein in Formulas a-1 to a-7, [symbol] represents a bond to Formula 5.

In Formula 5, at least one of R₁₁ to R₁₆ may each independently be a group represented by Formula 2. In an embodiment, in Formula 5, two or more of R₁₁ to R₁₆ may each independently be a group represented by Formula 2. For example, at least one of R₁₁ to R₁₃ may each independently be a group represented by Formula 2, and at least one of R₁₄ to R₁₆ may each independently be a group represented by Formula 2. In another embodiment, two or more of R₁₁ to R₁₃ may each independently be a group represented by Formula 2, and two or more of R₁₄ to R₁₆ may each independently be a group represented by Formula 2.

In Formula 5, Rₐ to Rₖ are the same as defined in Formula 1.

In an embodiment, the fused polycyclic compound represented by Formula 1 may be represented by any one of Formulas 6-1 to 6-3:

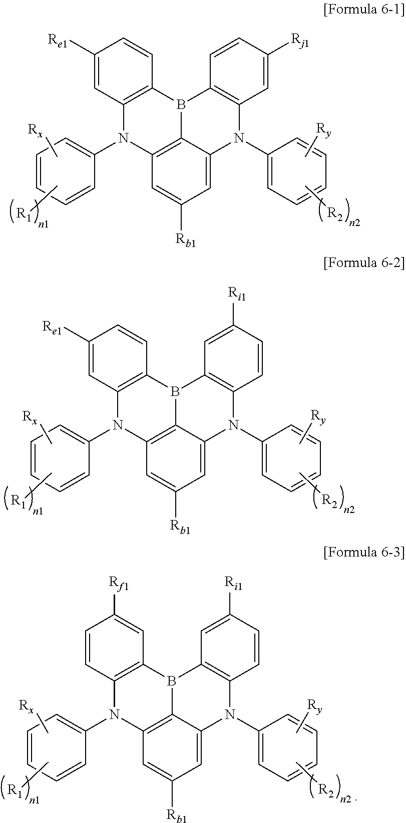

Formulas 6-1 to 6-3 each represent a case where Rₐ to Rₖ are further defined.

In Formulas 6-1 to 6-3, R_{b1}, Rₑ₁, R_{f1}, Rᵢ₁, and Rⱼ₁ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R_{b1}, Rₑ₁, R_{f1}, Rᵢ₁, and Rⱼ₁ may each independently be a substituted or unsubstituted t-butyl group, a substituted or unsubstituted phenyl group, or a substituted or unsubstituted carbazole group. For example, R_{b1} may be a substituted or unsubstituted t-butyl group or a substituted or unsubstituted phenyl group. For example, Rₑ₁, R_{f1}, Rᵢ₁, and Rⱼ₁ may each independently be a substituted or unsubstituted phenyl group, or a substituted or unsubstituted carbazole group.

In an embodiment, in Formulas 6-1 to 6-3, R_{b1}, Rₑ₁, R_{f1}, Rᵢ₁, and Rⱼ₁ may each independently be a group represented by any one of Formulas b-1 to b-5, as described above. For example, Rei may be represented by Formula b-3 or Formula b-4. For example, Rₑ₁, R_{f1}, Rᵢ₁, and Rⱼ₁ may each independently be represented by any one of Formulas b-1 to b-3, and b-5. In an embodiment, in Formulas b-1 to b-5, [symbol] represents a bond to one of Formulas 6-1 to 6-3.

In an embodiment, the fused polycyclic compound represented by Formula 1 may be represented by Formula 7:

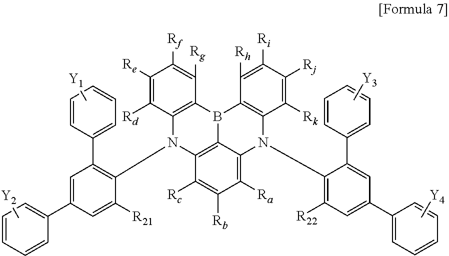

In Formula 7, R₂₁ and R₂₂ may each independently be a hydrogen atom, a deuterium atom, a substituted or unsubstituted aryl group having 6 to 30 ring-forming carbon atoms, a substituted or unsubstituted heteroaryl group having 2 to 30 ring-forming carbon atoms, or a group represented by Formula 2. In an embodiment, R₂₁ and R₂₂ may each independently be a hydrogen atom, a deuterium atom, or a substituted or unsubstituted aryl group having 6 to 30 ring-forming carbon atoms. For example, R₂₁ and R₂₂ may each independently be a hydrogen atom, a deuterium atom, a substituted or unsubstituted phenyl group, or a substituted or unsubstituted biphenyl group.

In an embodiment, in Formula 7, R₂₁ and R₂₂ may each independently be a hydrogen atom, a deuterium atom, a group represented by Formula 2, or a group represented by any one of Formulas a-1 to a-5. In an embodiment, in Formulas a-1 to a-5, [symbol] represents a bond to Formula 7.

In Formula 7, Y₁ to Y₄ may each independently be a hydrogen atom, a deuterium atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Y₁ to Y₄ may each independently be a hydrogen atom, a deuterium atom, a cyano group, a substituted or unsubstituted t-butyl group, or a substituted or unsubstituted phenyl group. In Formula 7, at least one of Y₁ to Y₄ may each be a cyano group. For example, at least one of Y₁ and Y₂ may each be a cyano group, and at least one of Y₃ and Y₄ may each be a cyano group.

In an embodiment, the fused polycyclic compound represented by Formula 1 may include at least one deuterium atom as a substituent. In an embodiment, the group represented by Formula 2 may include at least one deuterium atom as a substituent.

In an embodiment, the fused polycyclic compound may be any compound selected from Compound Group 1. In an embodiment, in the light emitting element ED, the at least one functional layer (for example, an emission layer EML) may include at least one fused polycyclic compound selected from Compound Group 1.

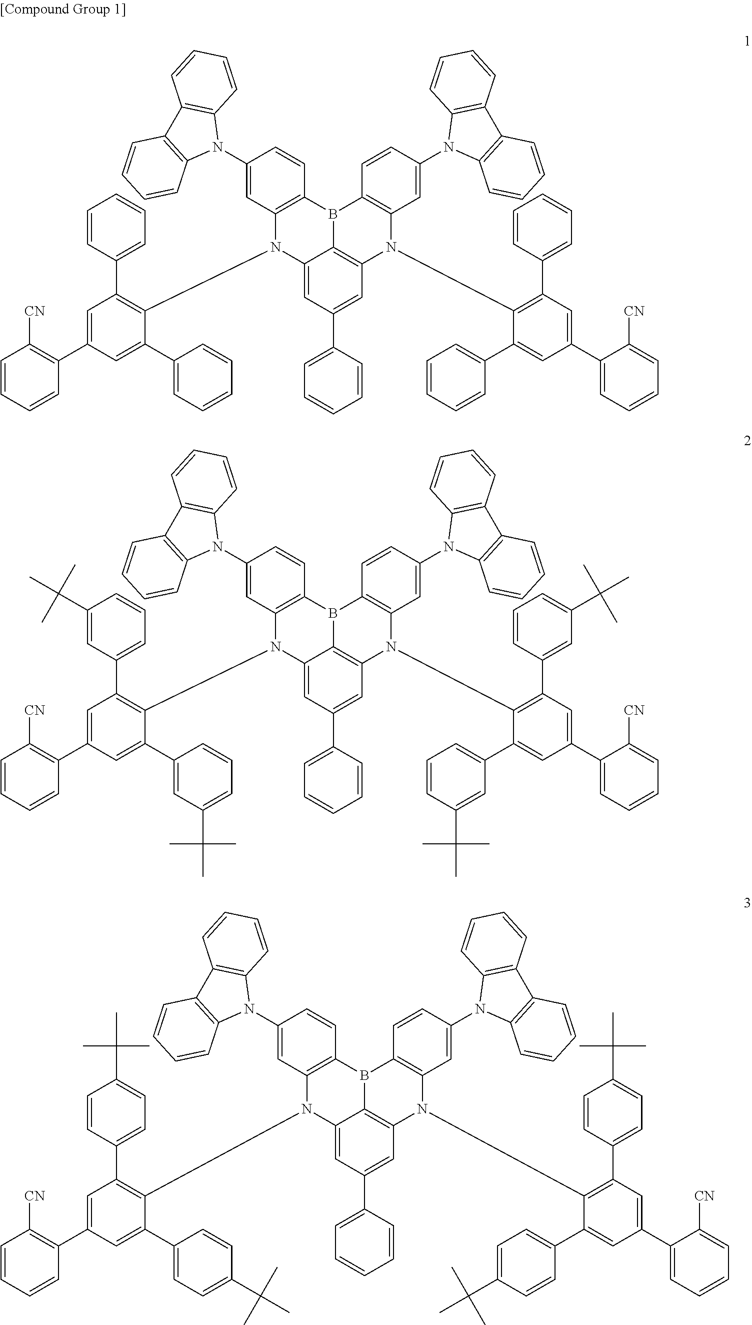

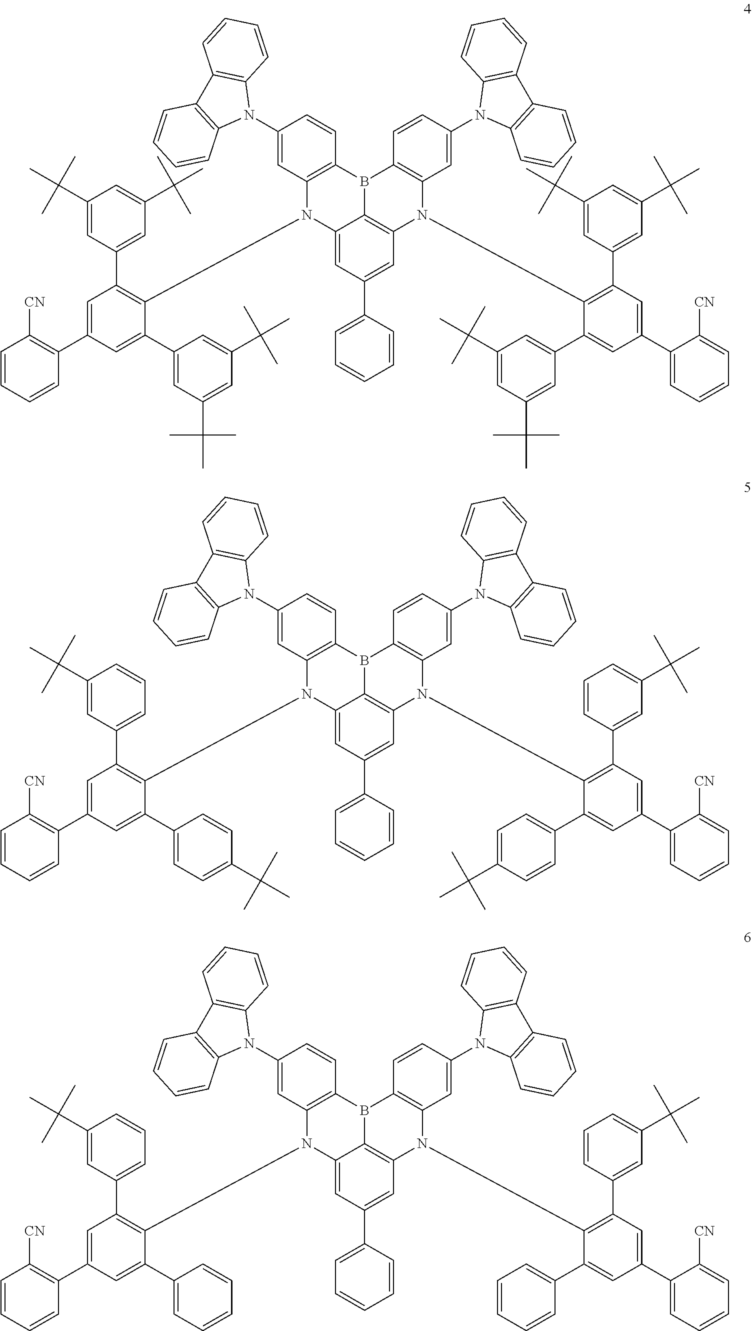

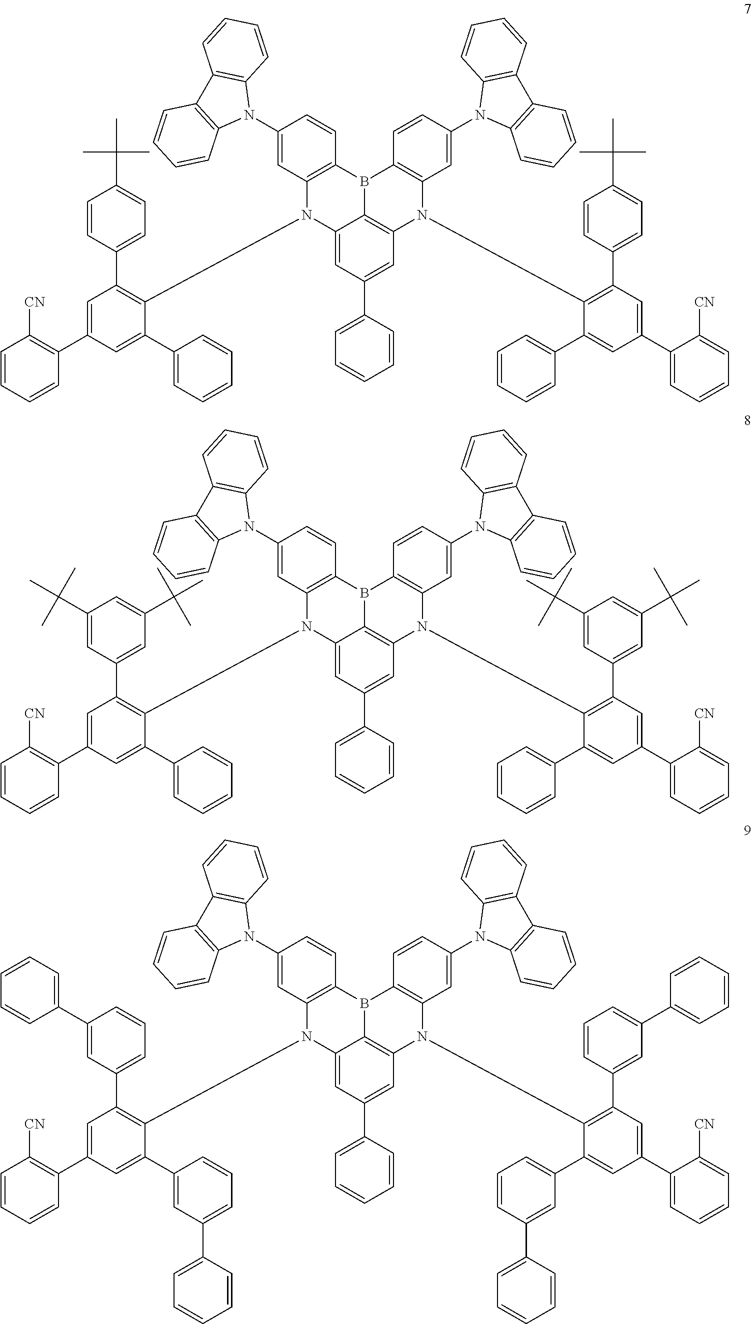

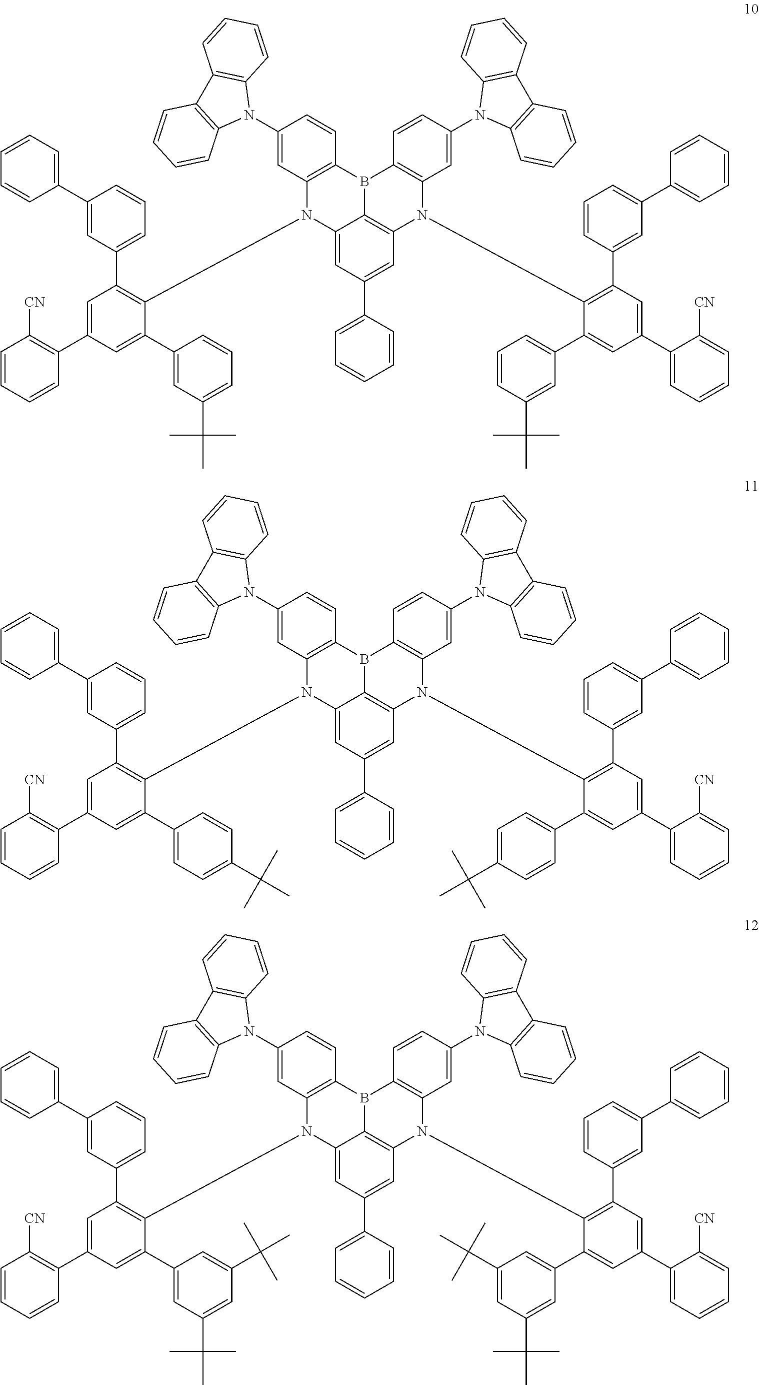

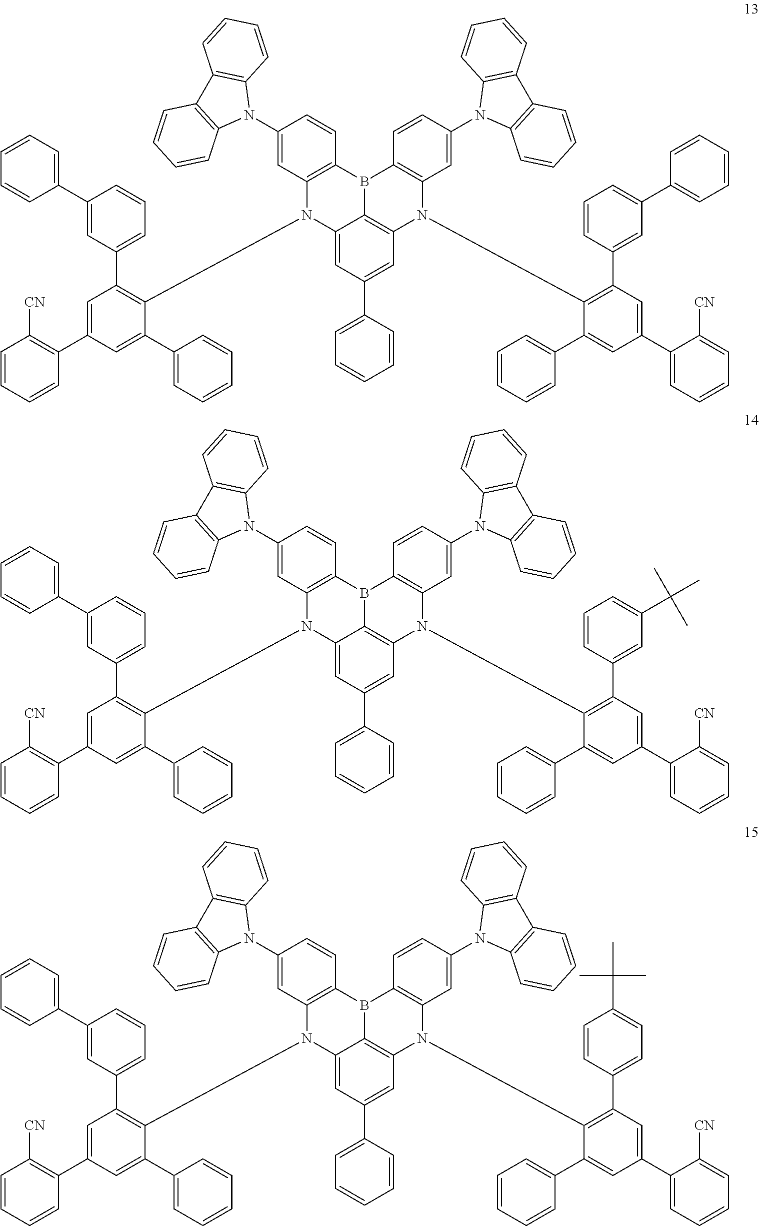

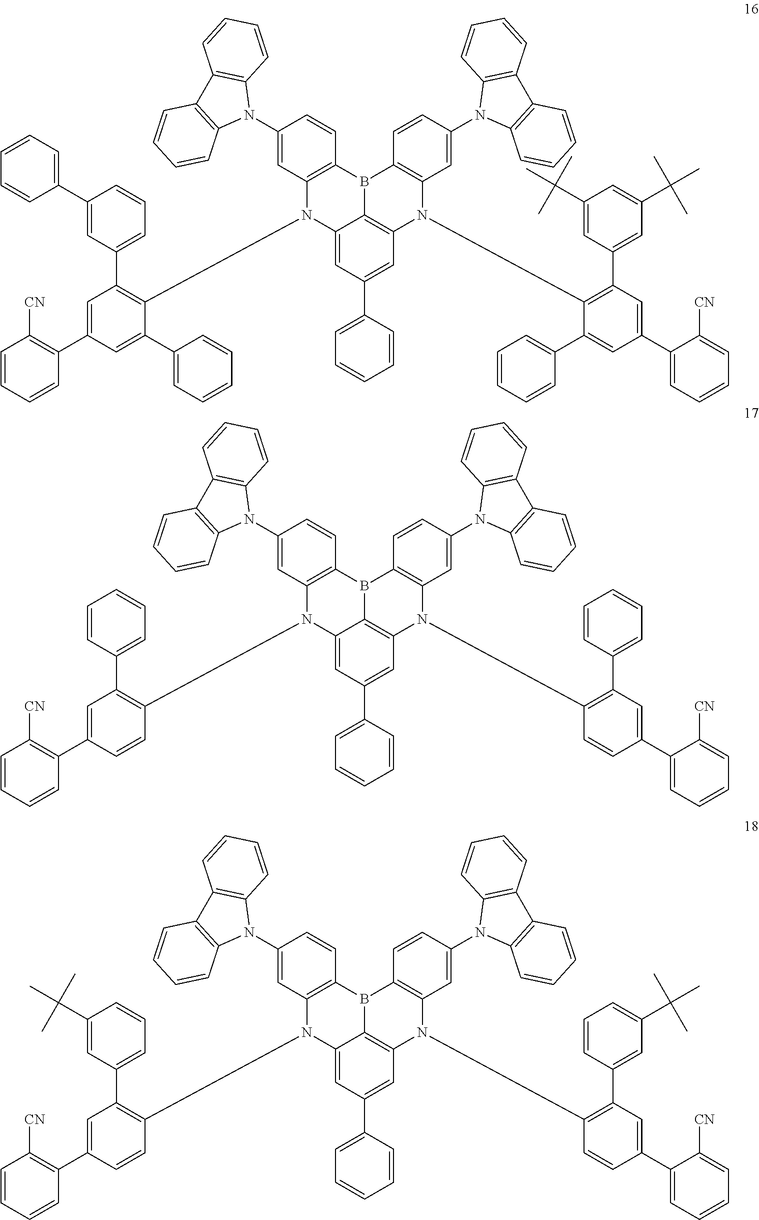

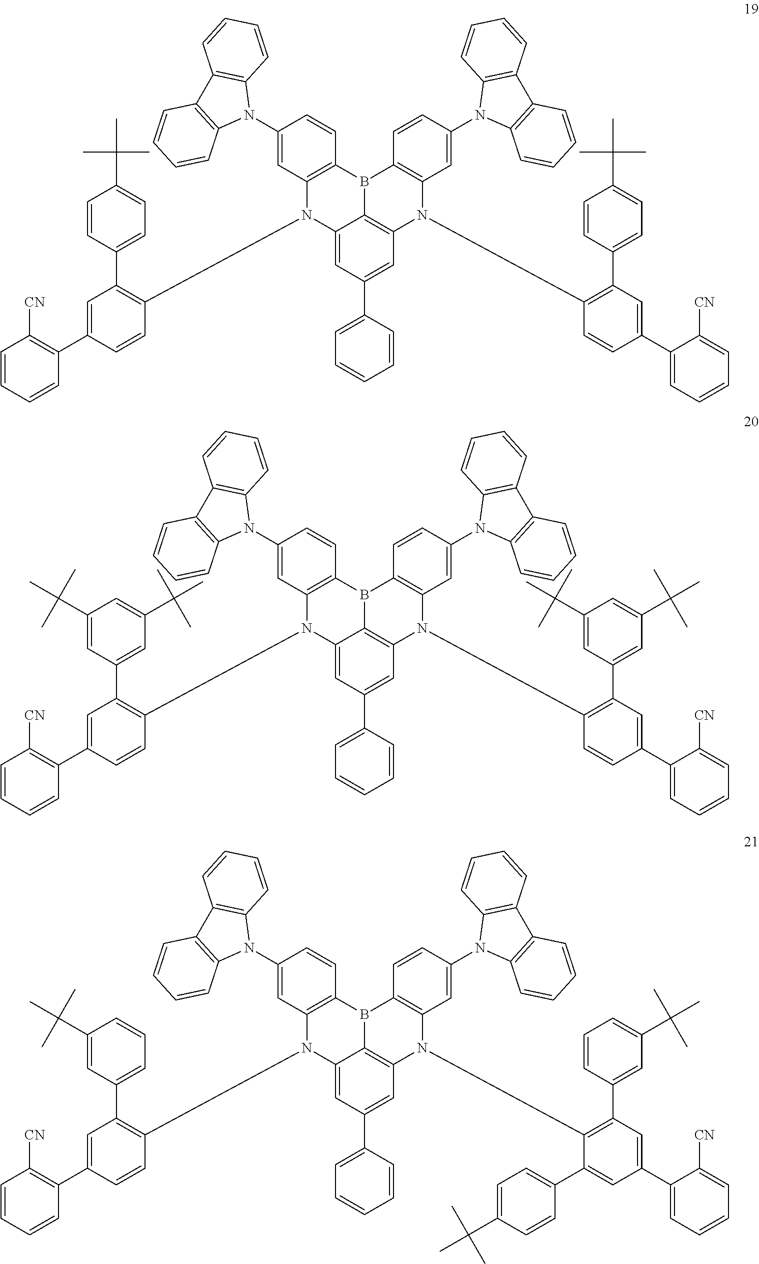

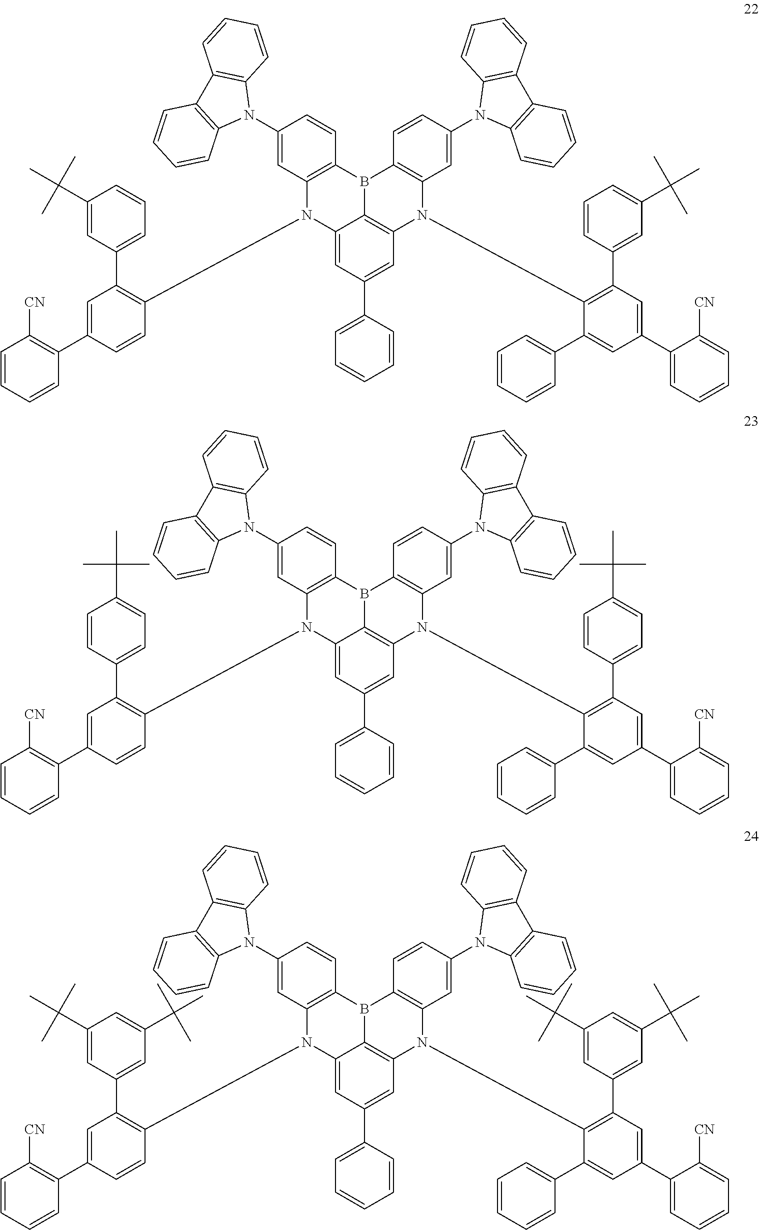

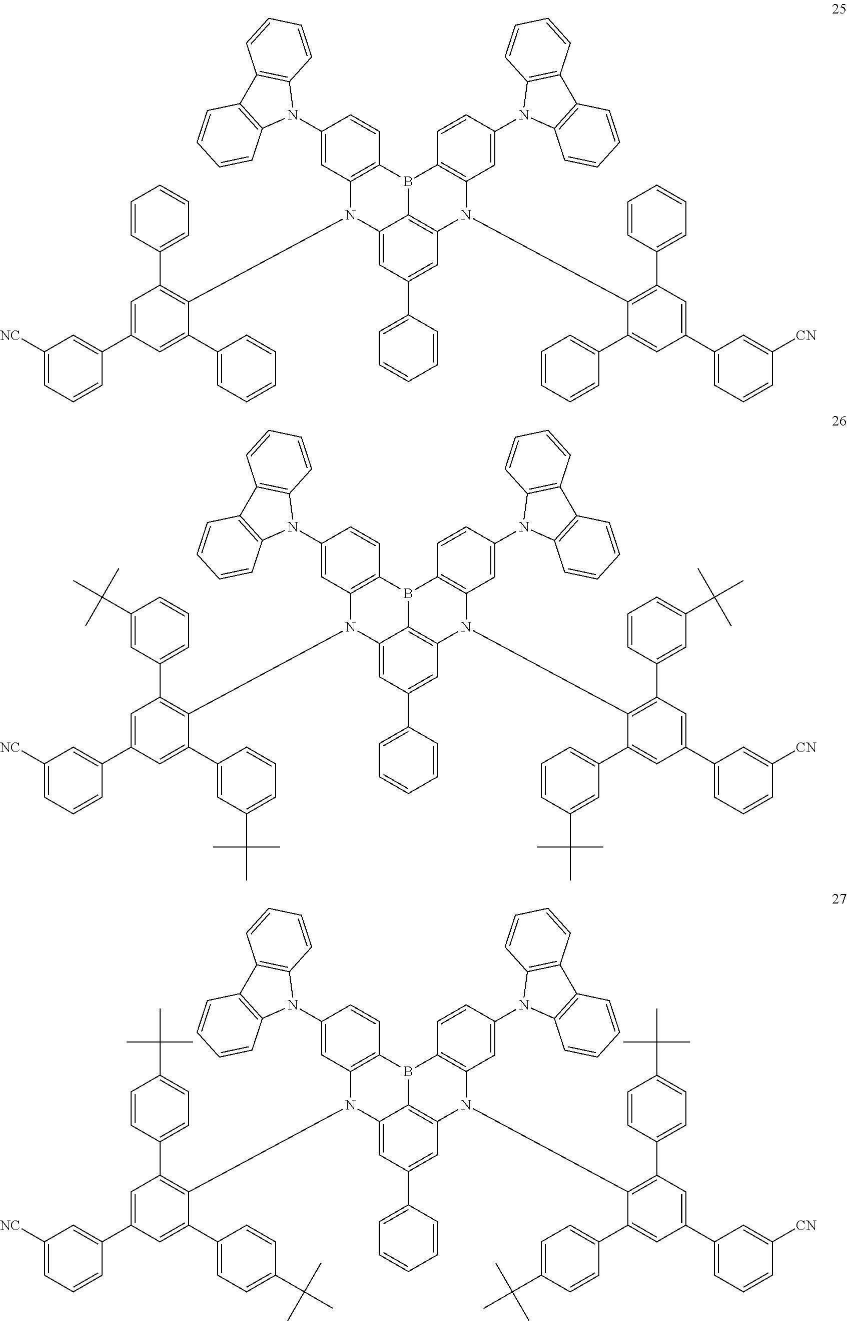

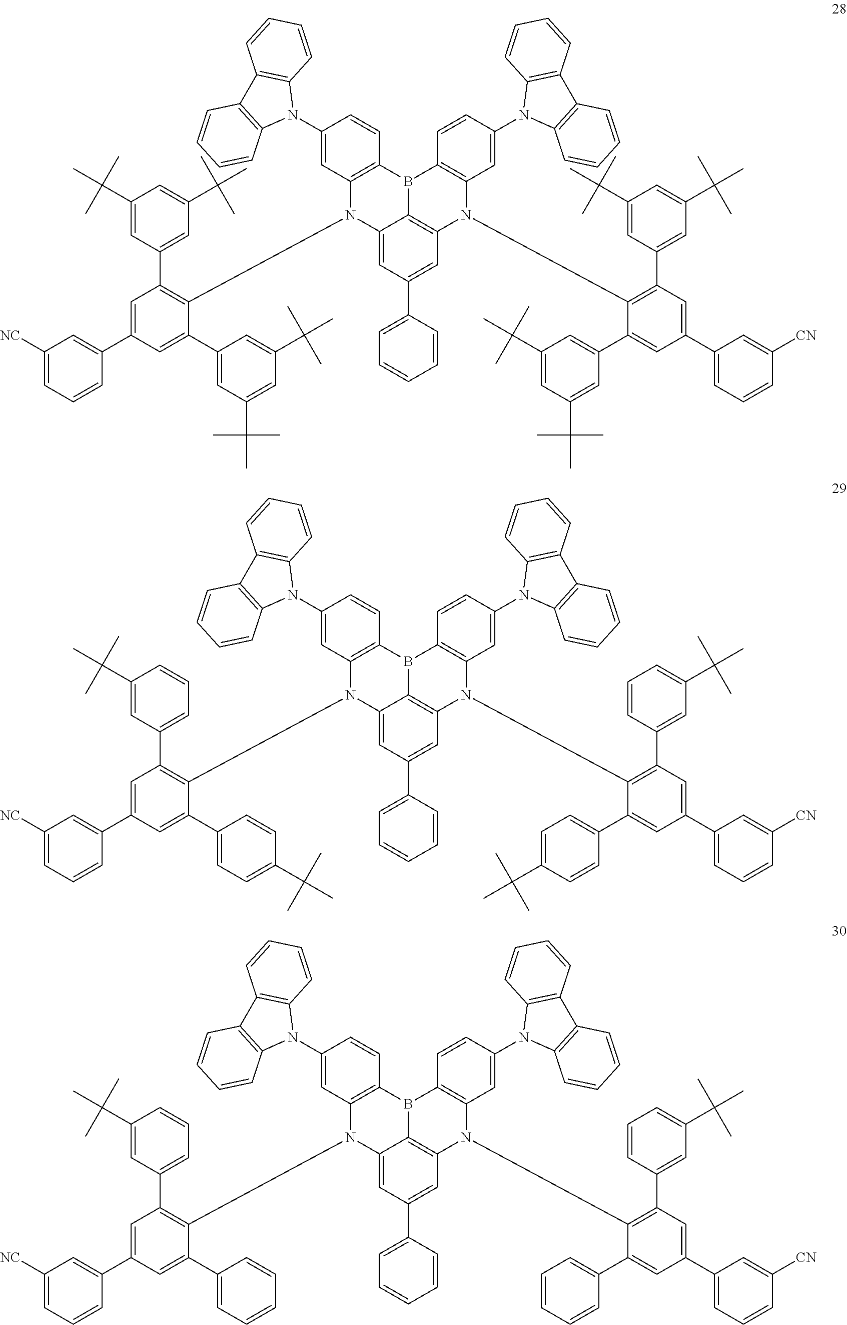

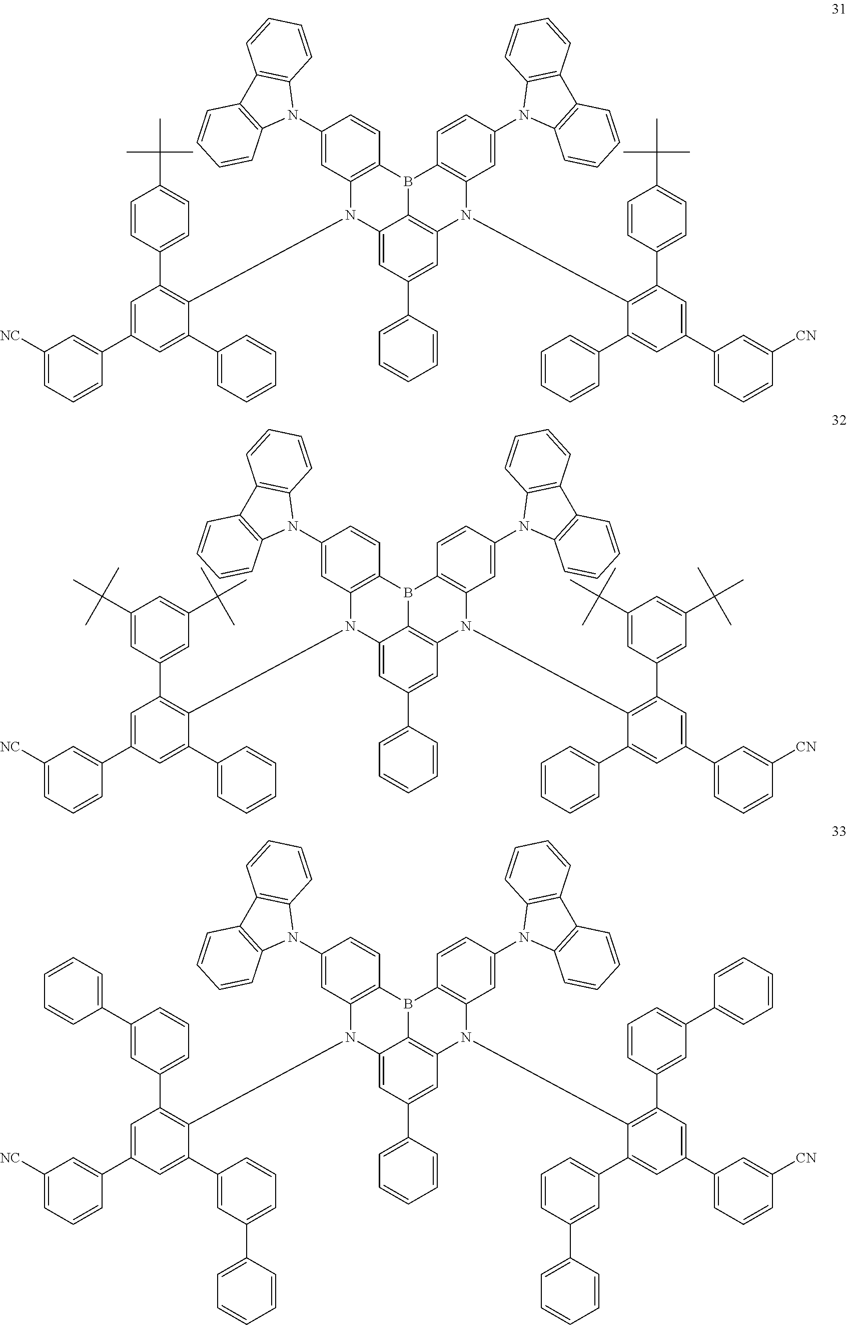

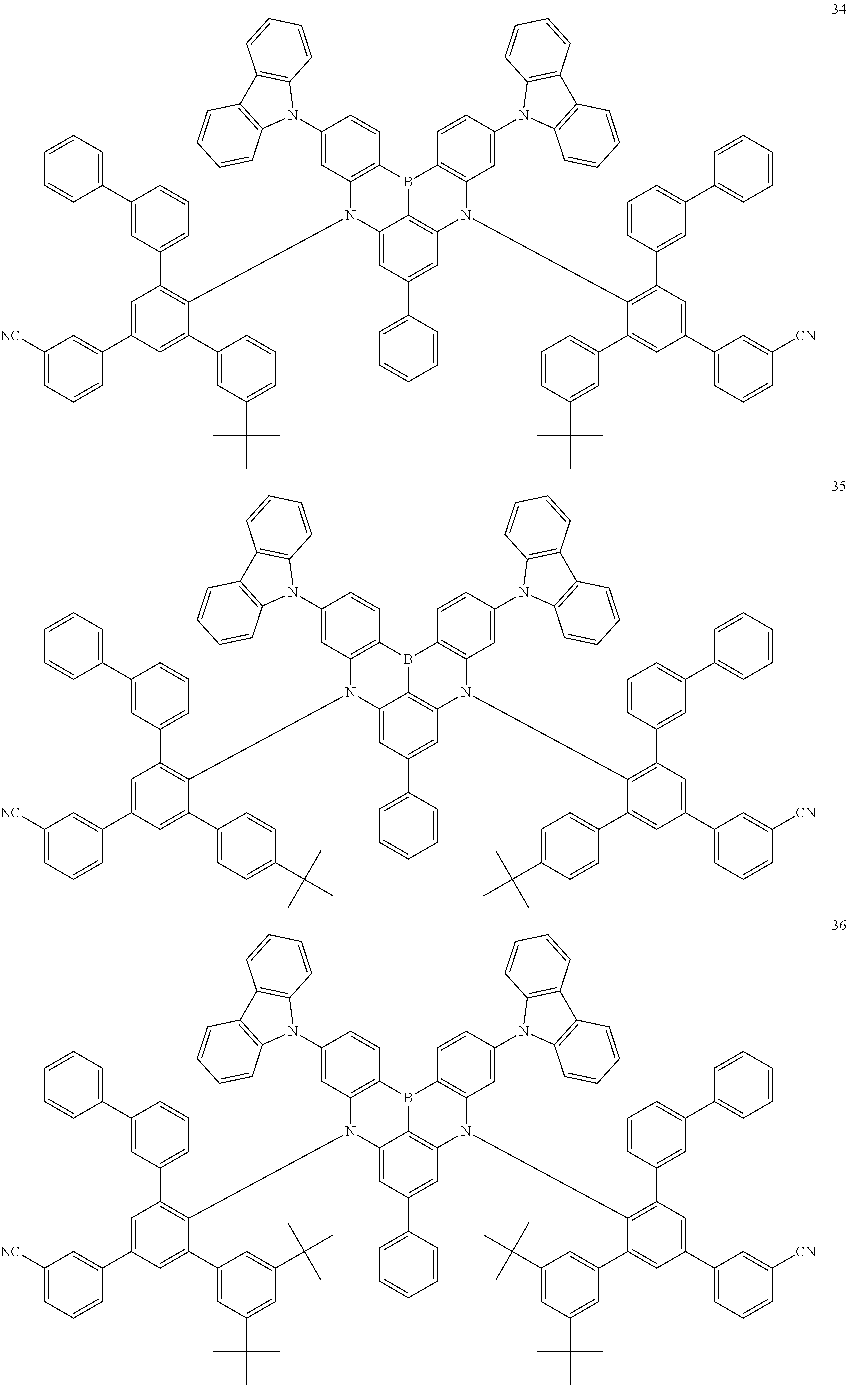

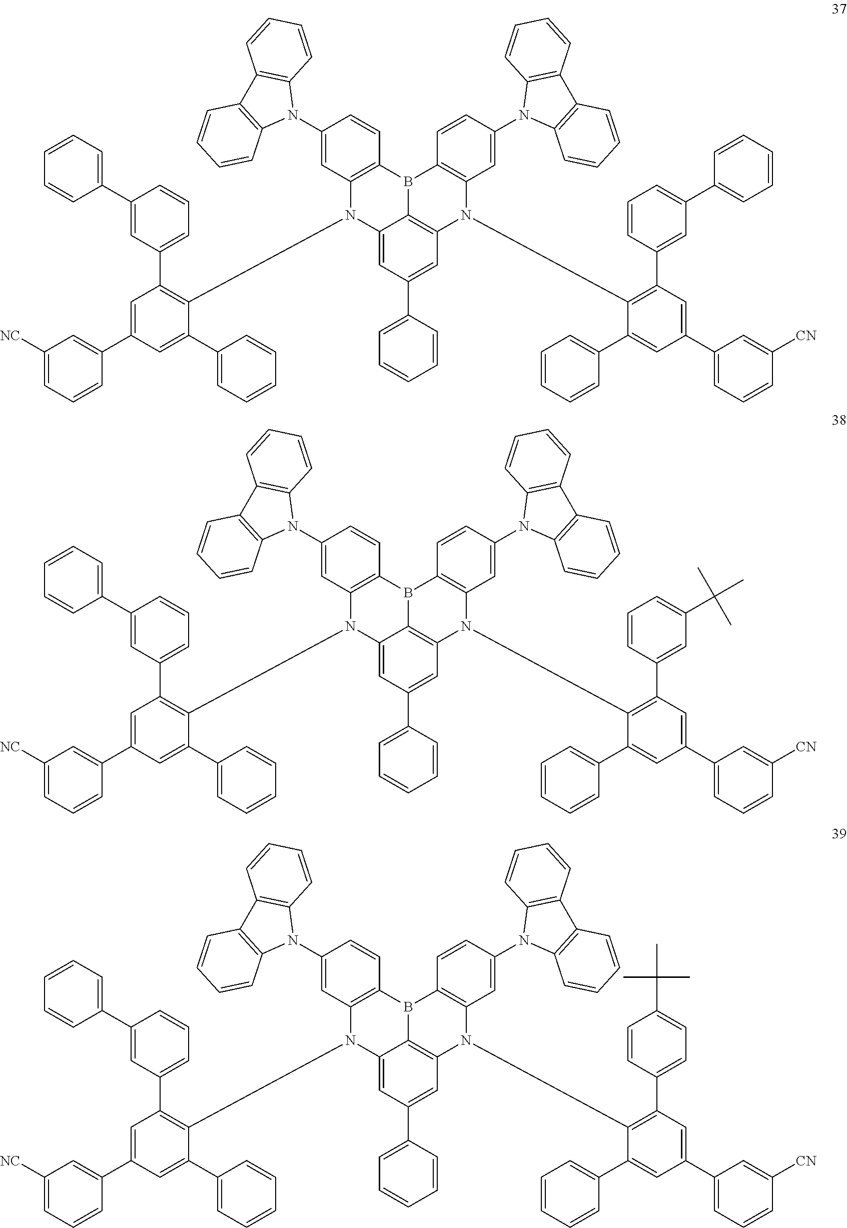

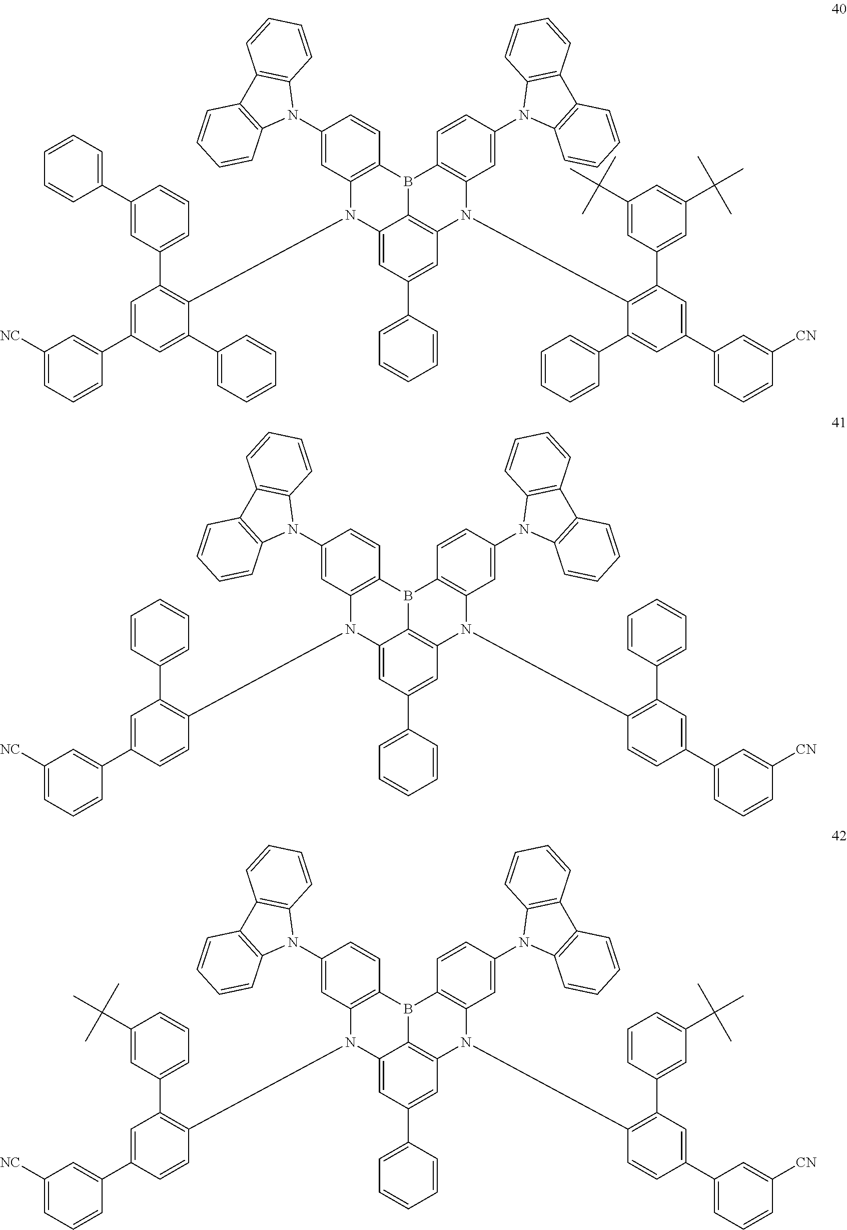

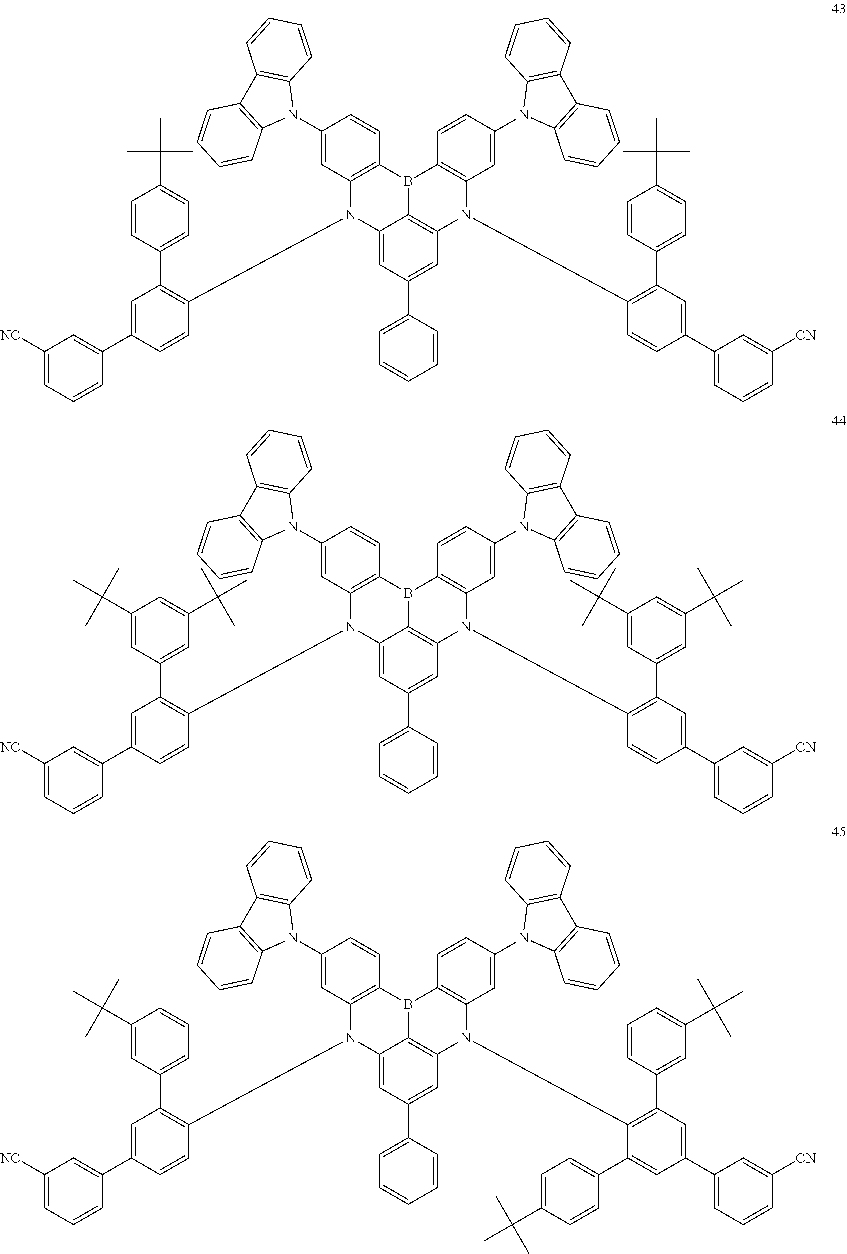

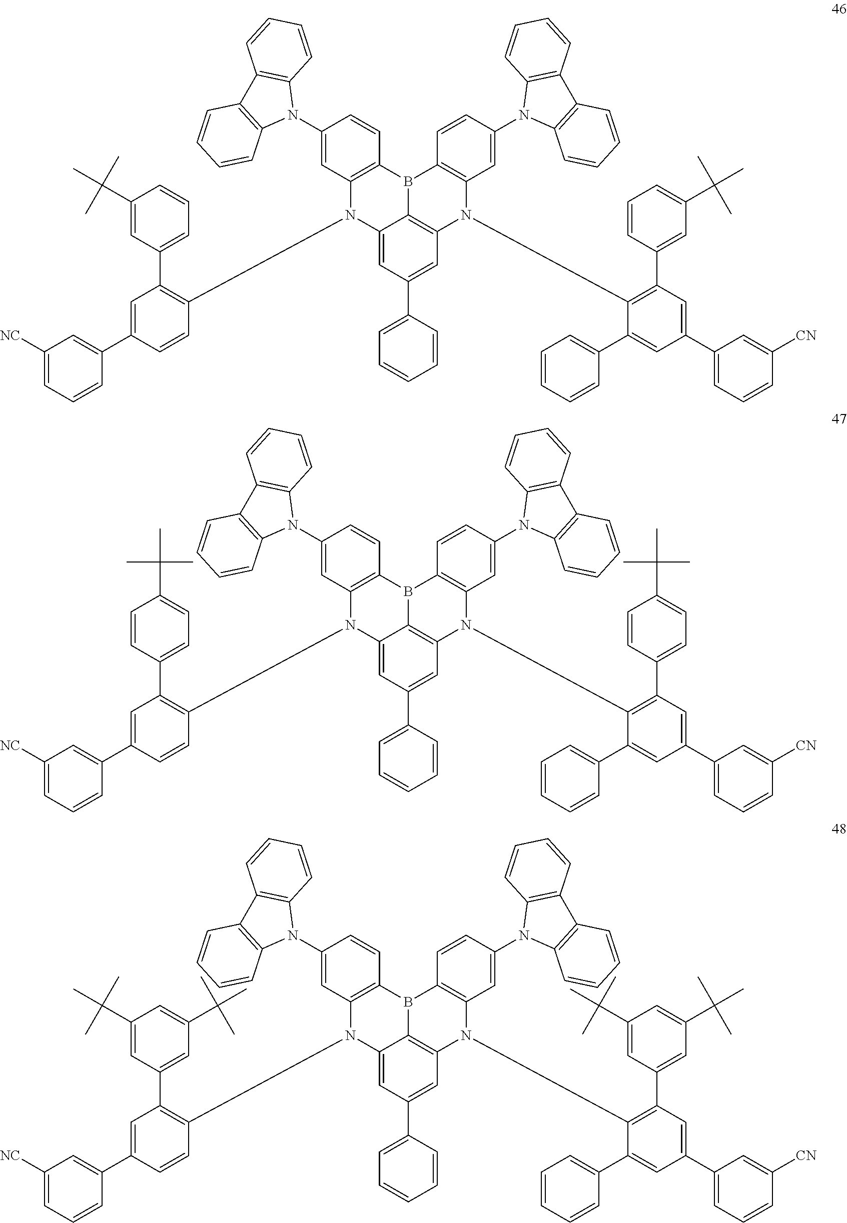

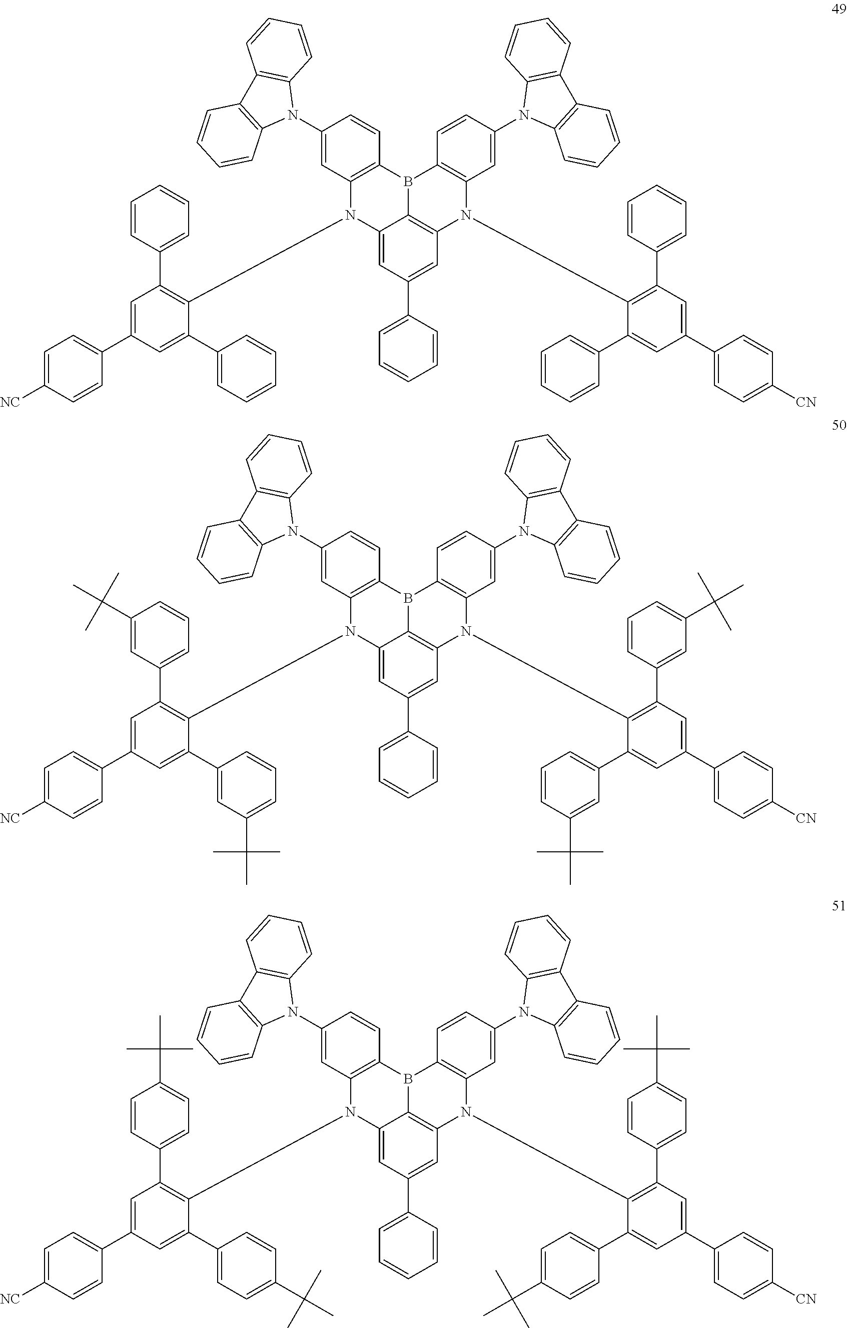

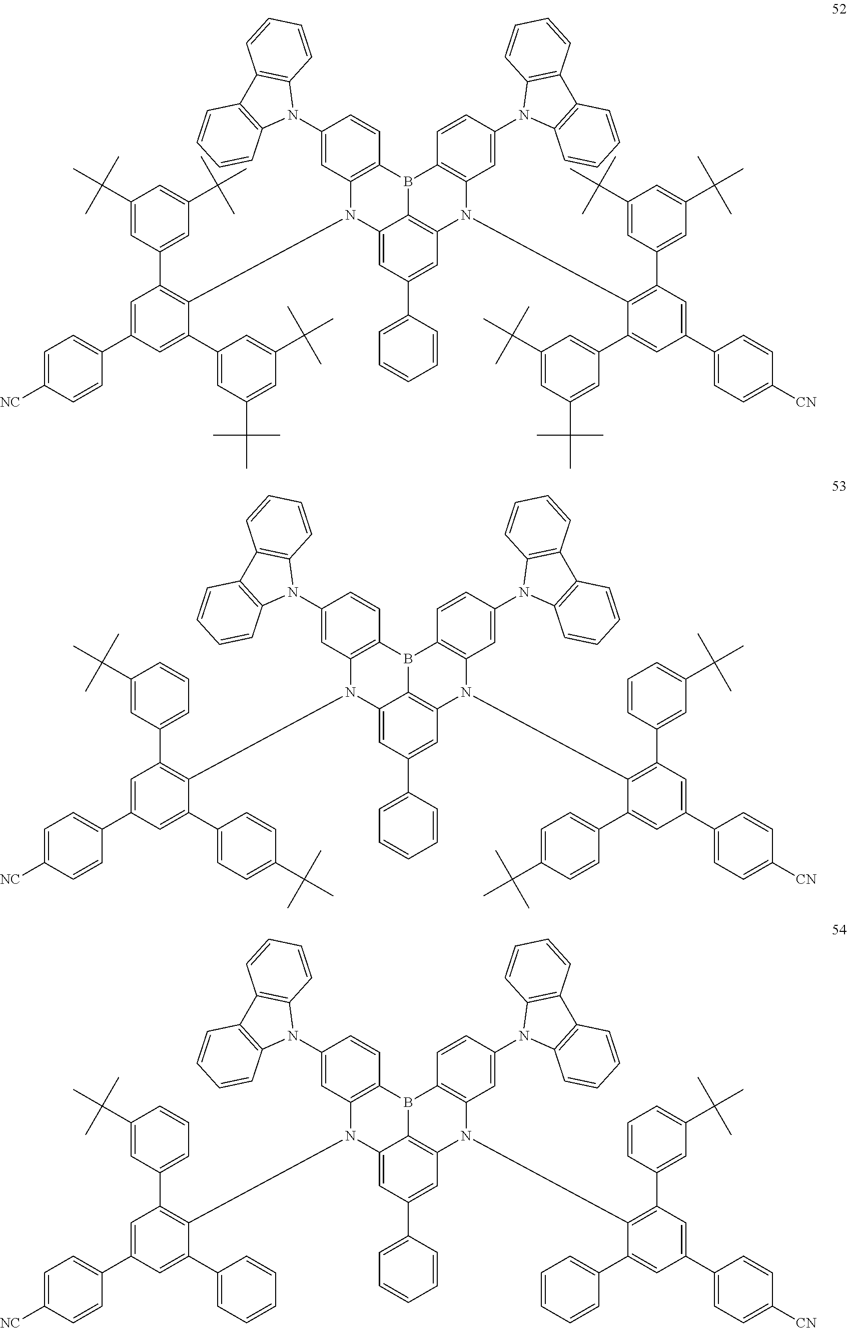

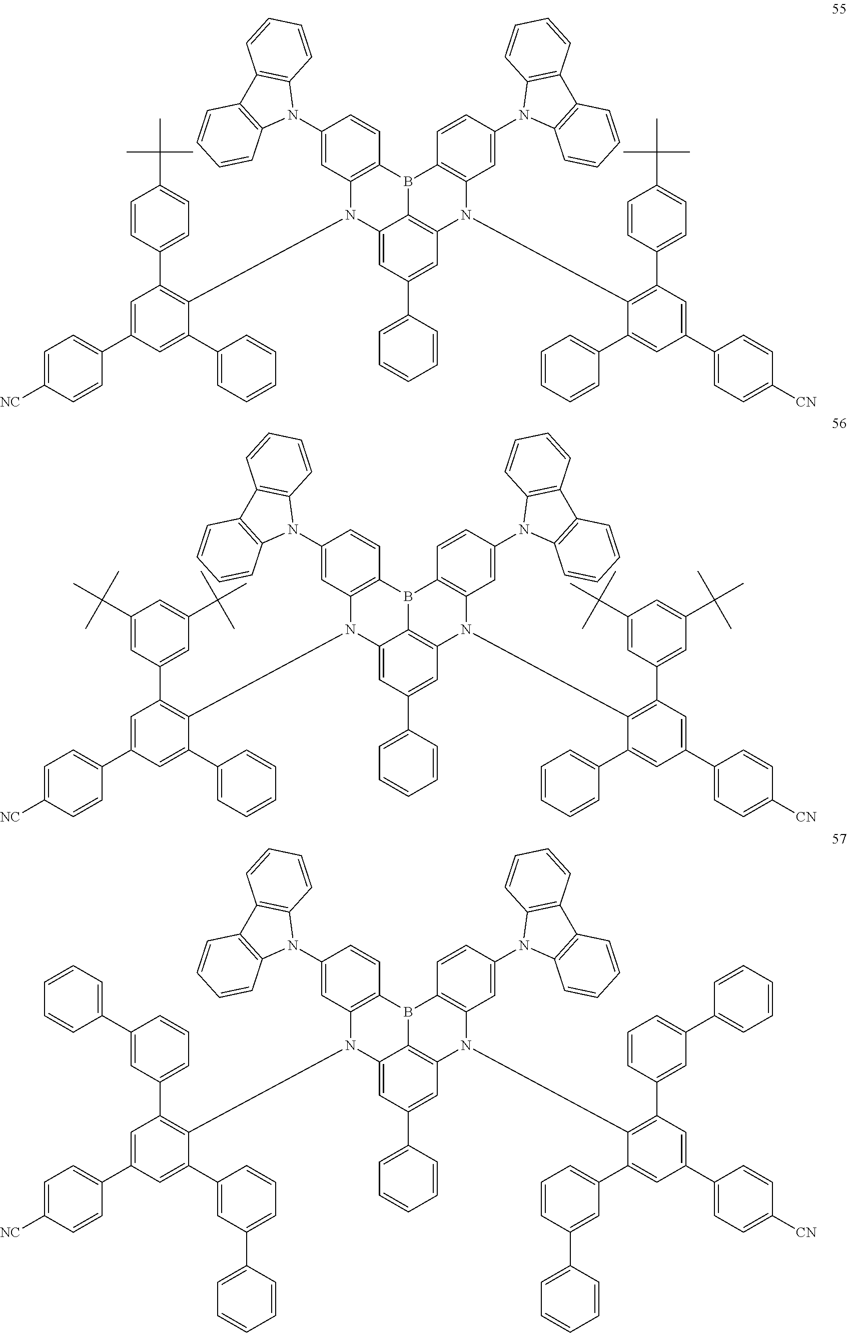

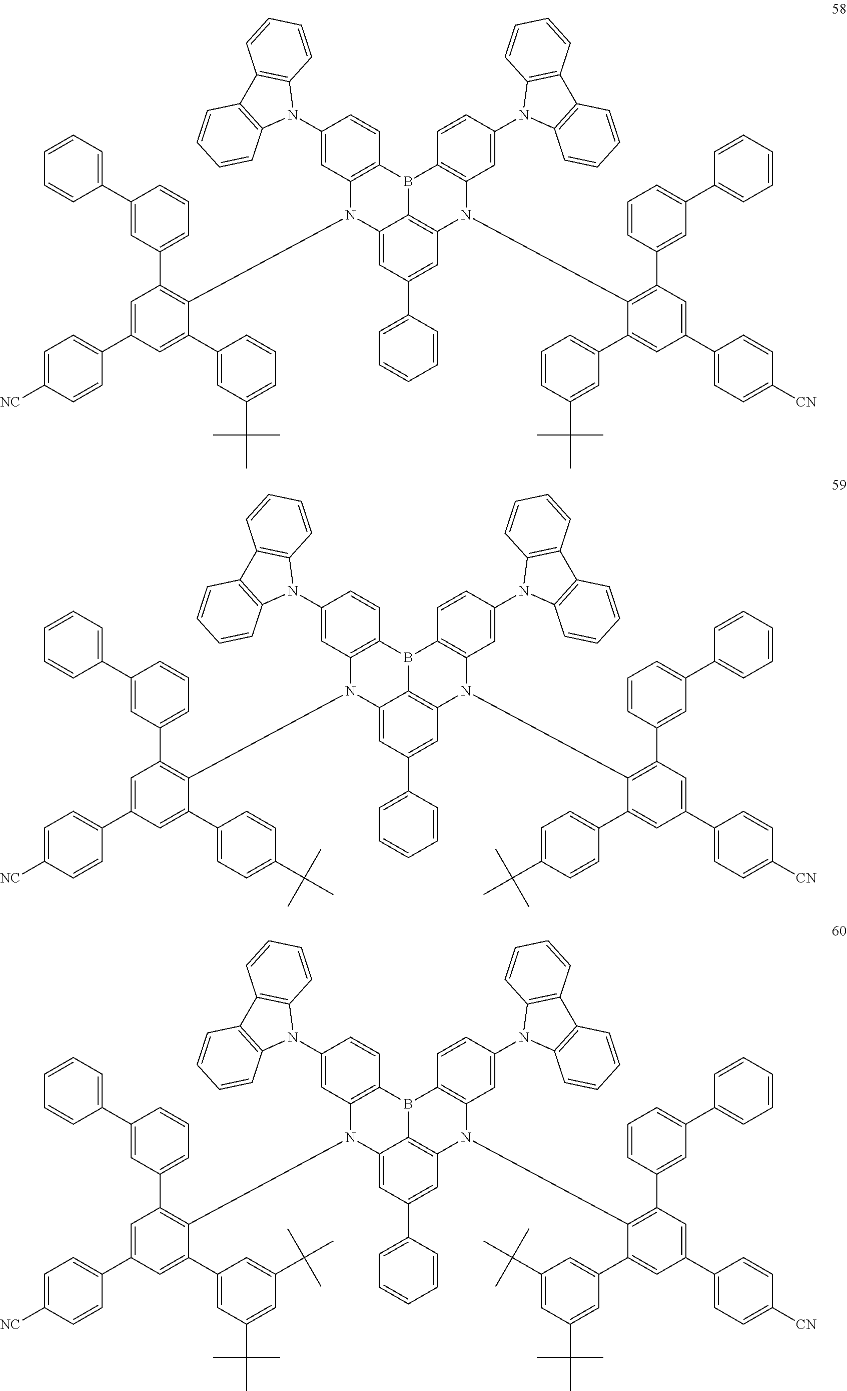

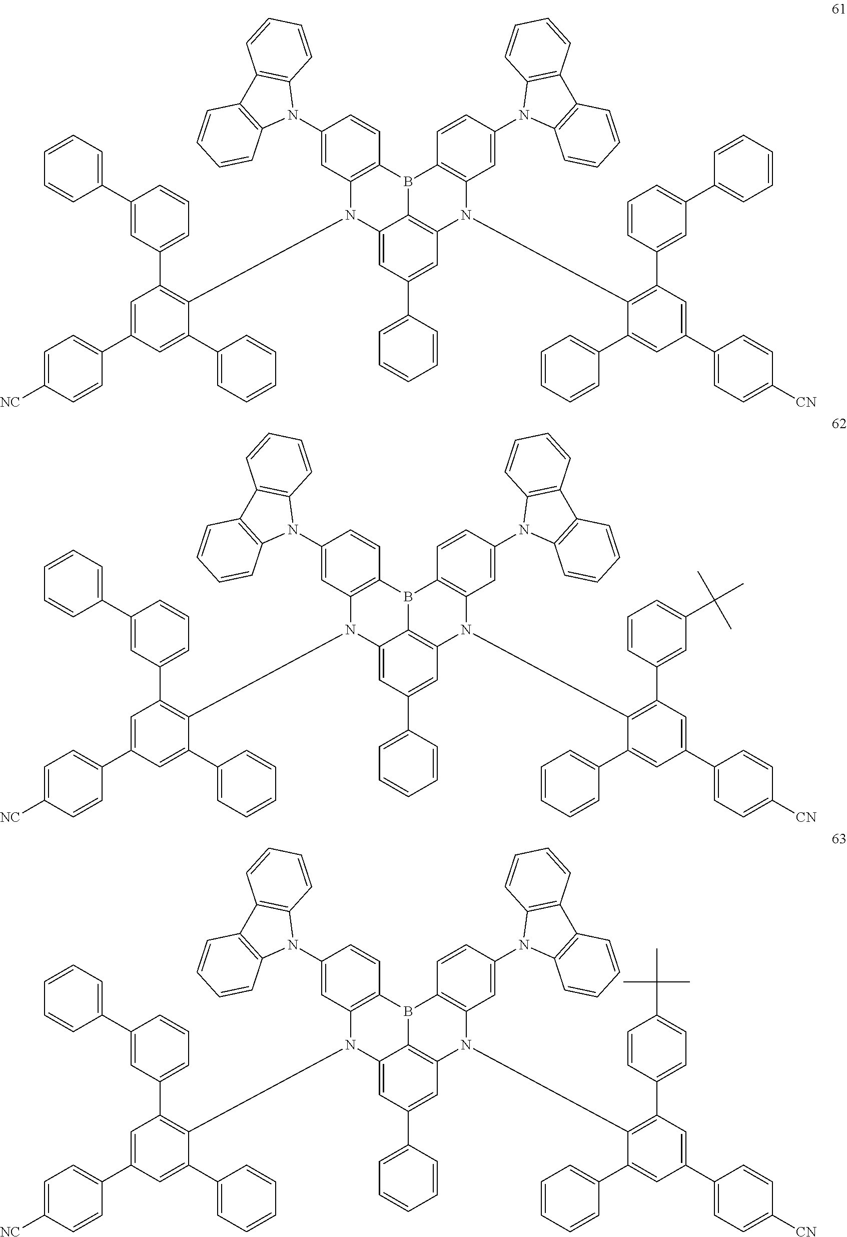

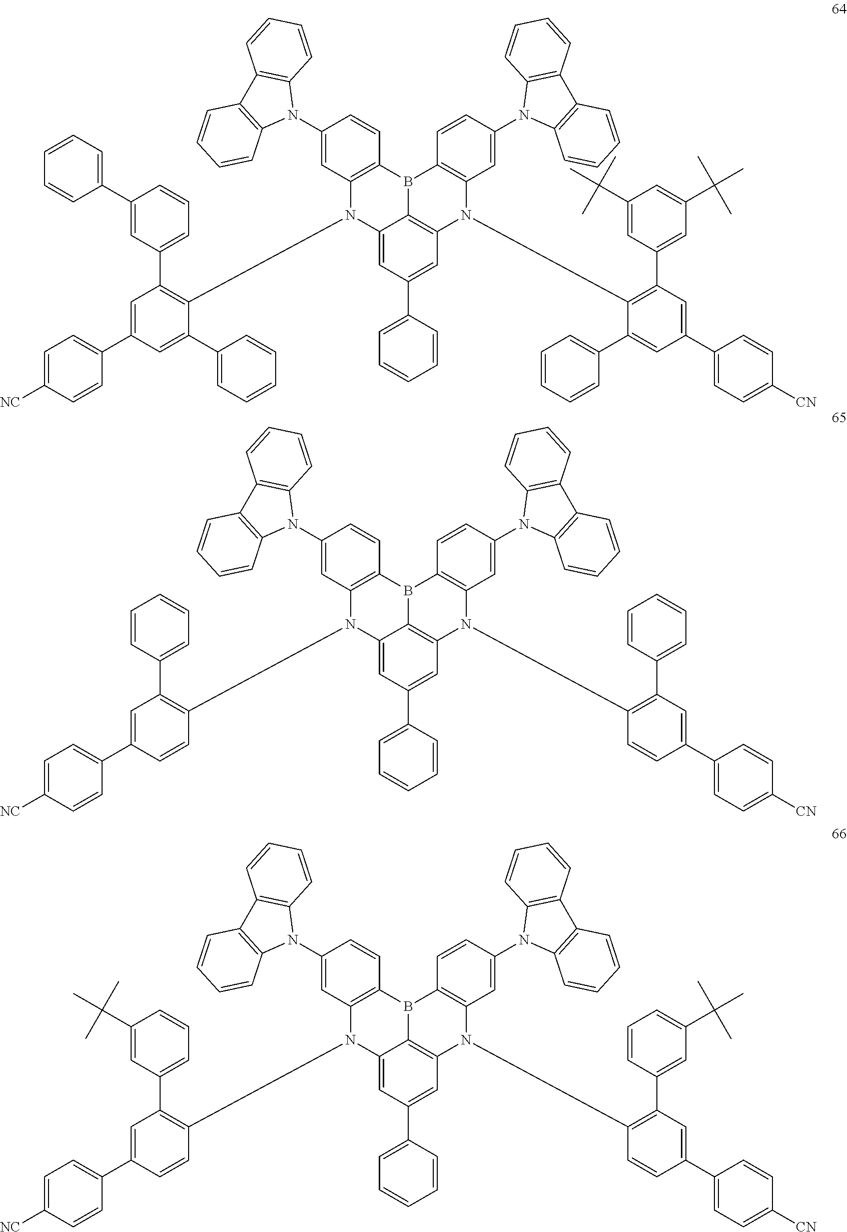

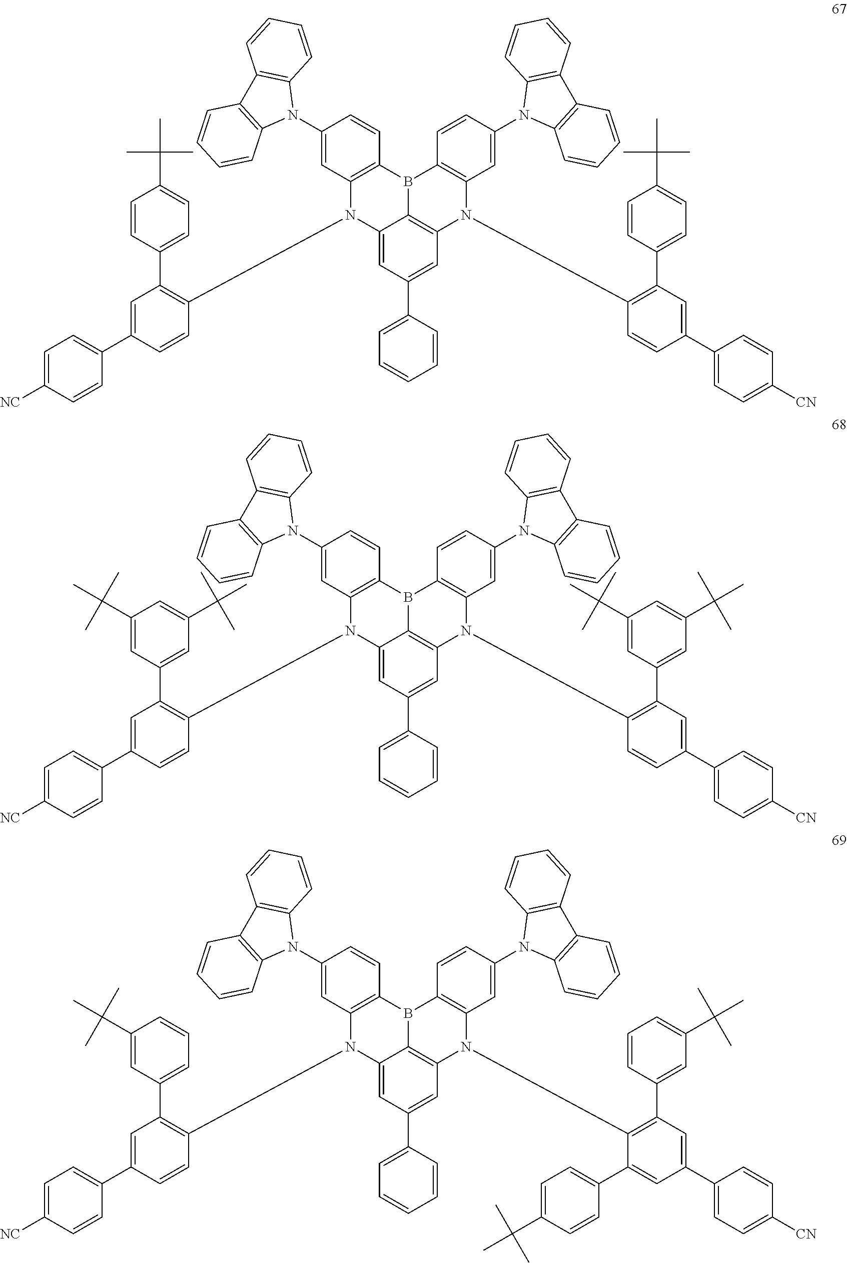

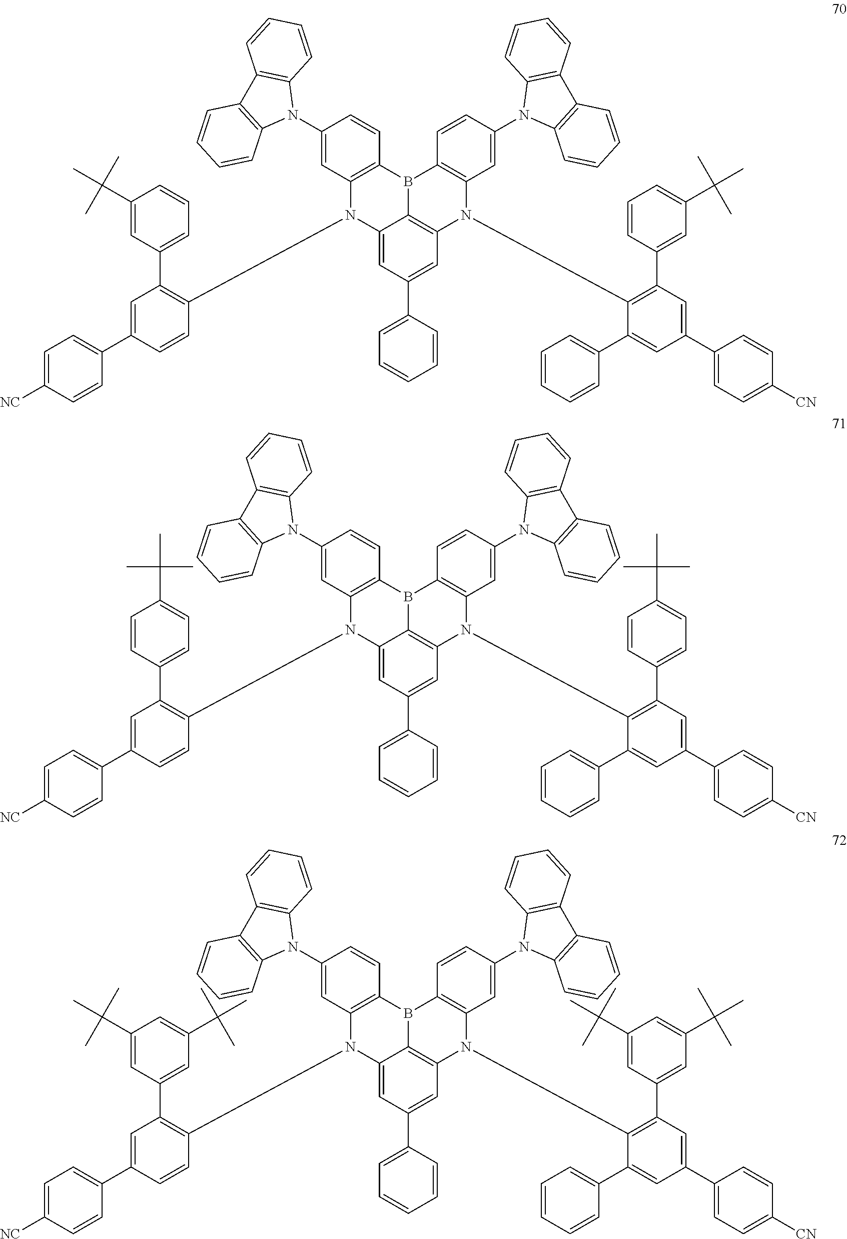

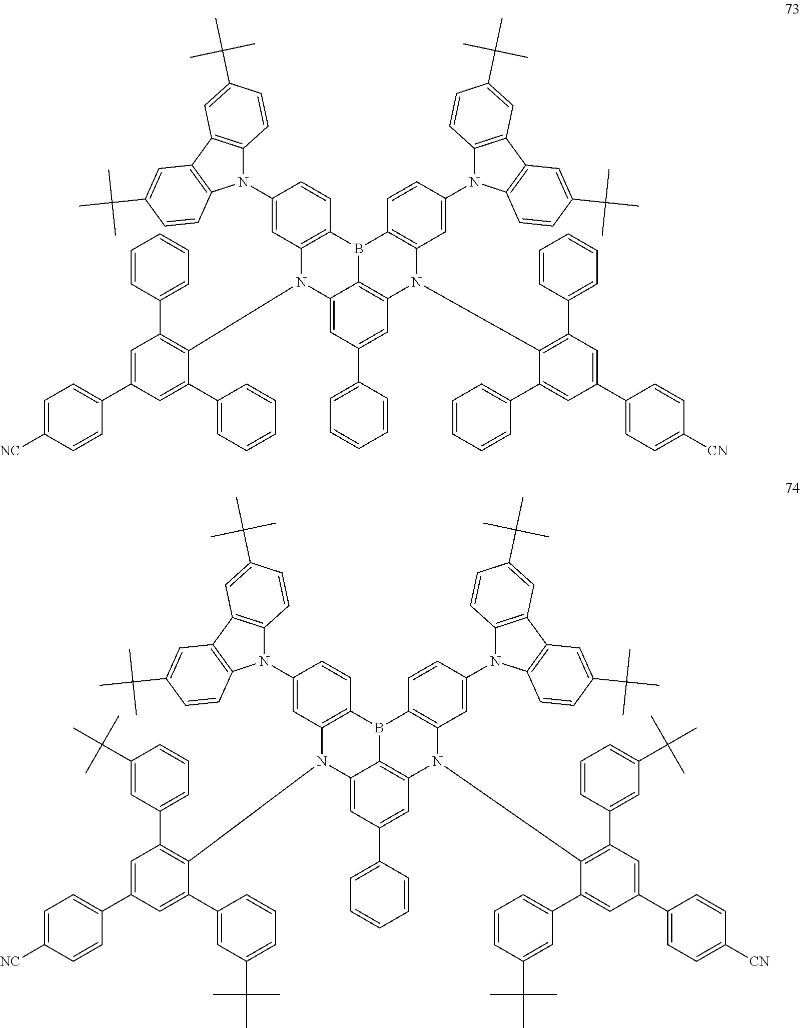 [SMILES: CC(C)(C)c1ccc2c(c1)c1cc(C(C)(C)C)ccc1n2-c1ccc2c(c1)N(c1c(-c3ccccc3)cc(-c3ccc(C#N)cc3)cc1-c1ccccc1)c1cc(-c3ccccc3)cc3c1B2c1ccc(-n2c4ccc(C(C)(C)C)cc4c4cc(C(C)(C)C)ccc42)cc1N3c1c(-c2ccccc2)cc(-c2ccc(C#N)cc2)cc1-c1ccccc1 ; CC(C)(C)c1cccc(-c2cc(-c3ccc(C#N)cc3)cc(-c3cccc(C(C)(C)C)c3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5cccc(C(C)(C)C)c5)cc(-c5ccc(C#N)cc5)cc4-c4cccc(C(C)(C)C)c4)c4cc(-c5ccccc5)cc2c43)c1]

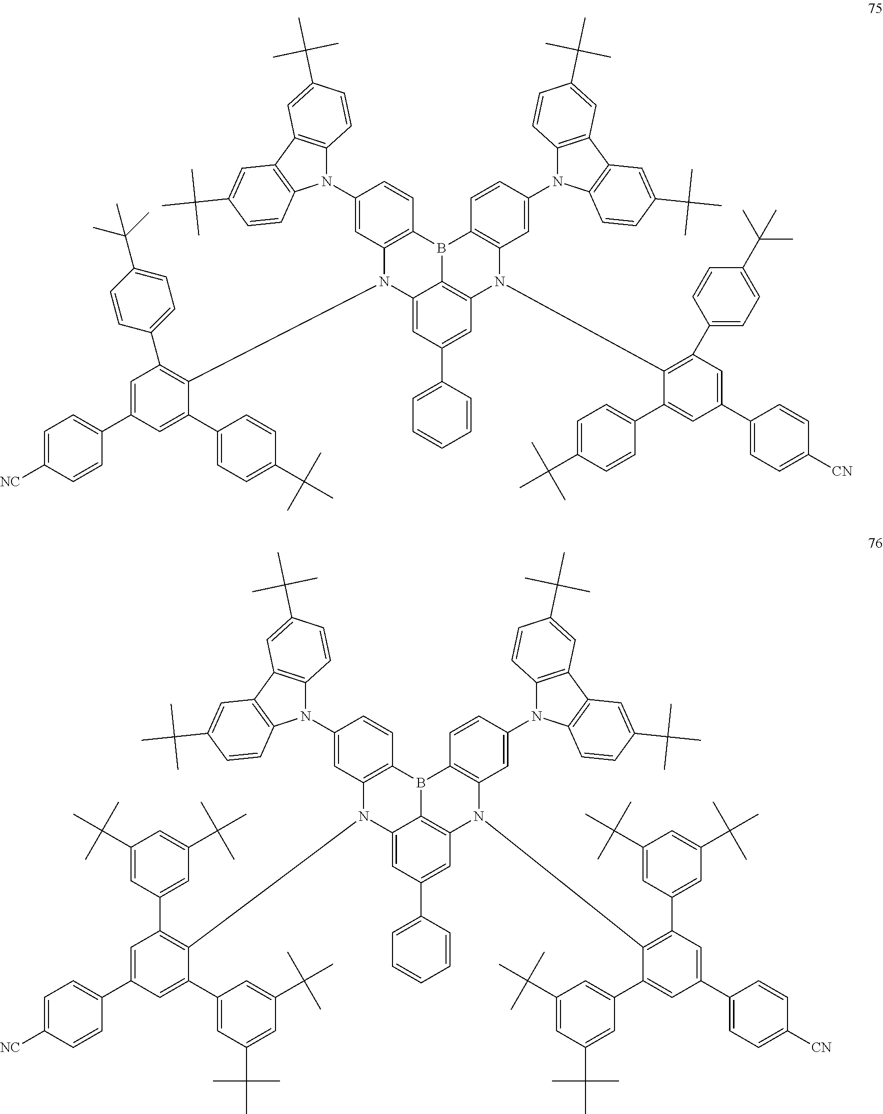

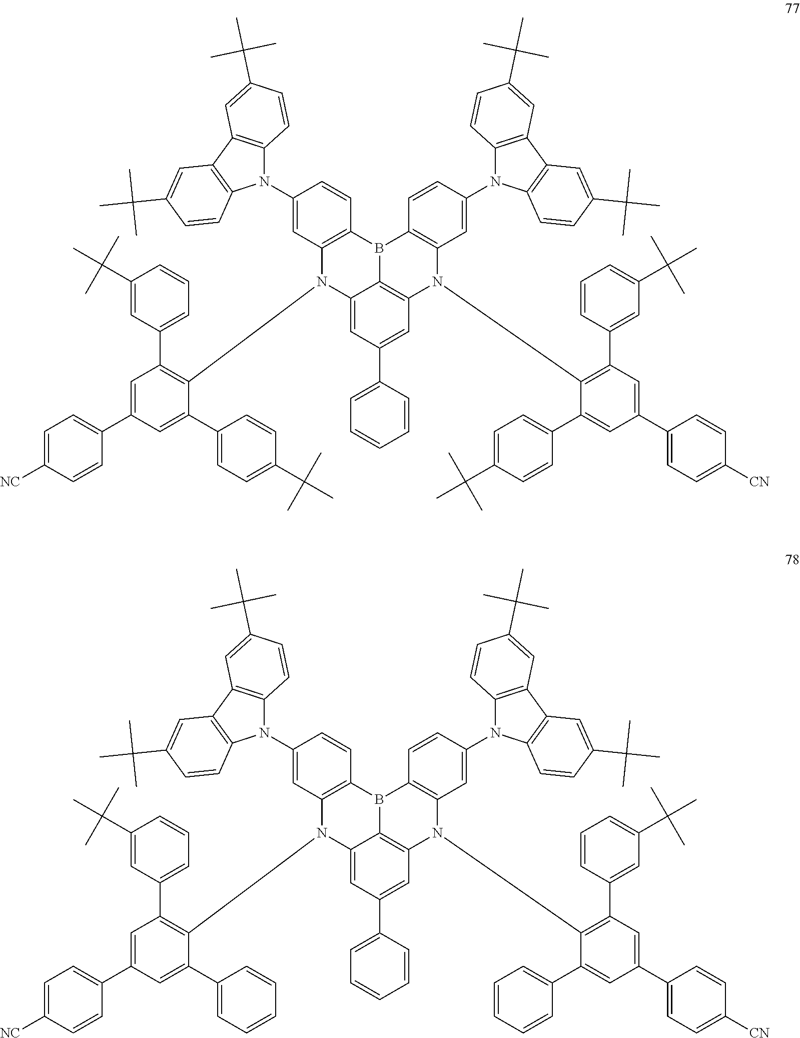 [SMILES: CC(C)(C)c1ccc(-c2cc(-c3ccc(C#N)cc3)cc(-c3cccc(C(C)(C)C)c3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccc(C(C)(C)C)cc5)cc(-c5ccc(C#N)cc5)cc4-c4cccc(C(C)(C)C)c4)c4cc(-c5ccccc5)cc2c43)cc1 ; CC(C)(C)c1cccc(-c2cc(-c3ccc(C#N)cc3)cc(-c3ccccc3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(-c5ccc(C#N)cc5)cc4-c4cccc(C(C)(C)C)c4)c4cc(-c5ccccc5)cc2c43)c1]

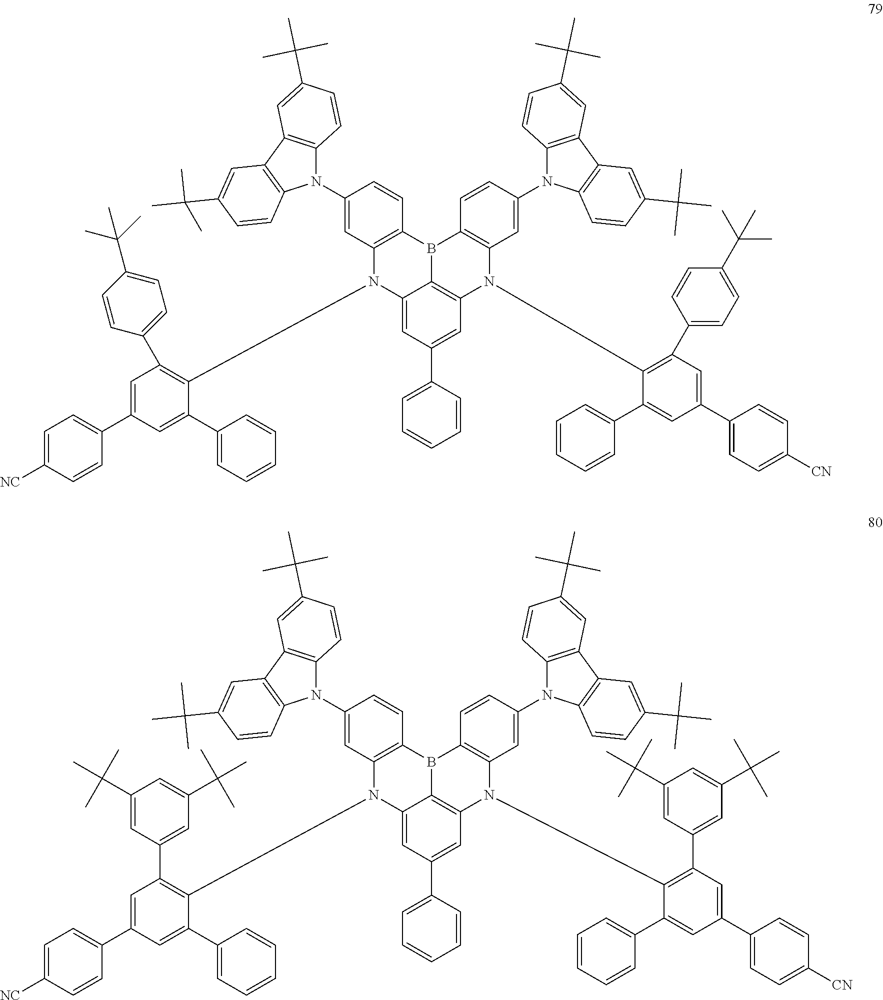 [SMILES: CC(C)(C)c1ccc(-c2cc(-c3ccc(C#N)cc3)cc(-c3ccccc3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(-c5ccc(C#N)cc5)cc4-c4ccc(C(C)(C)C)cc4)c4cc(-c5ccccc5)cc2c43)cc1 ; CC(C)(C)c1cc(-c2cc(-c3ccc(C#N)cc3)cc(-c3ccccc3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(-c5ccc(C#N)cc5)cc4-c4cc(C(C)(C)C)cc(C(C)(C)C)c4)c4cc(-c5ccccc5)cc2c43)cc(C(C)(C)C)c1]

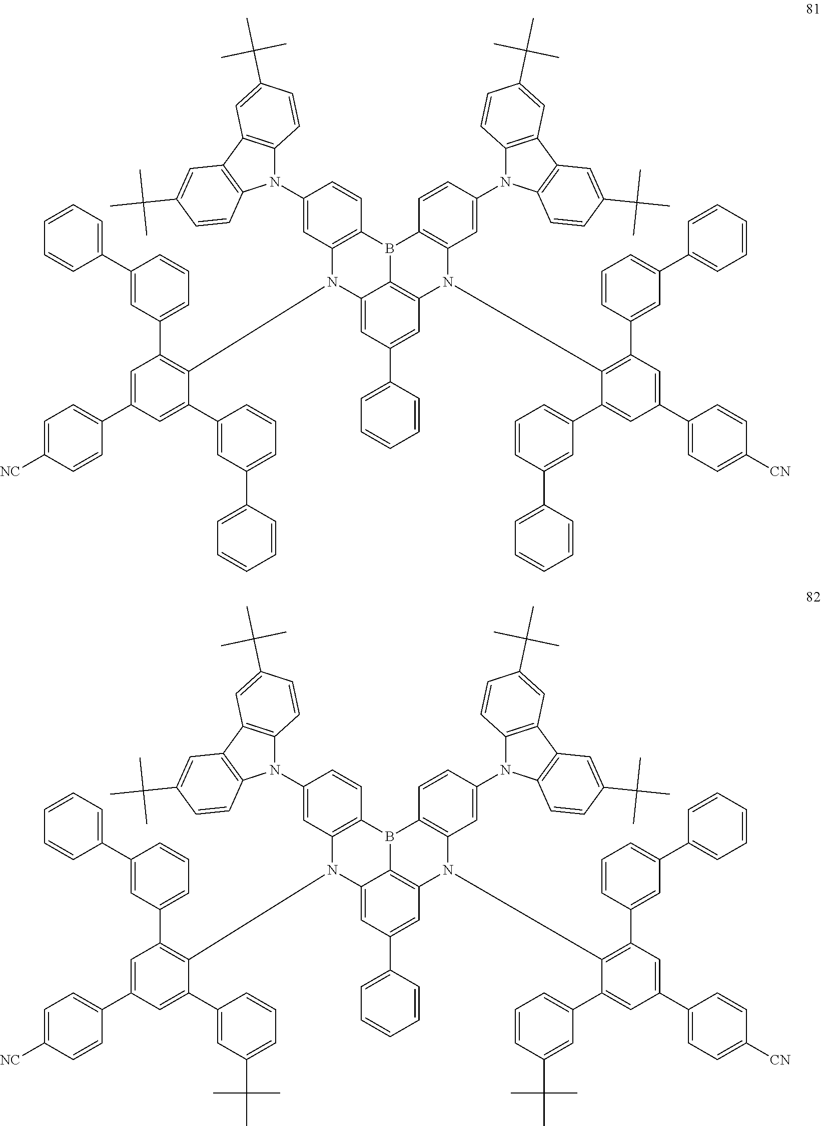

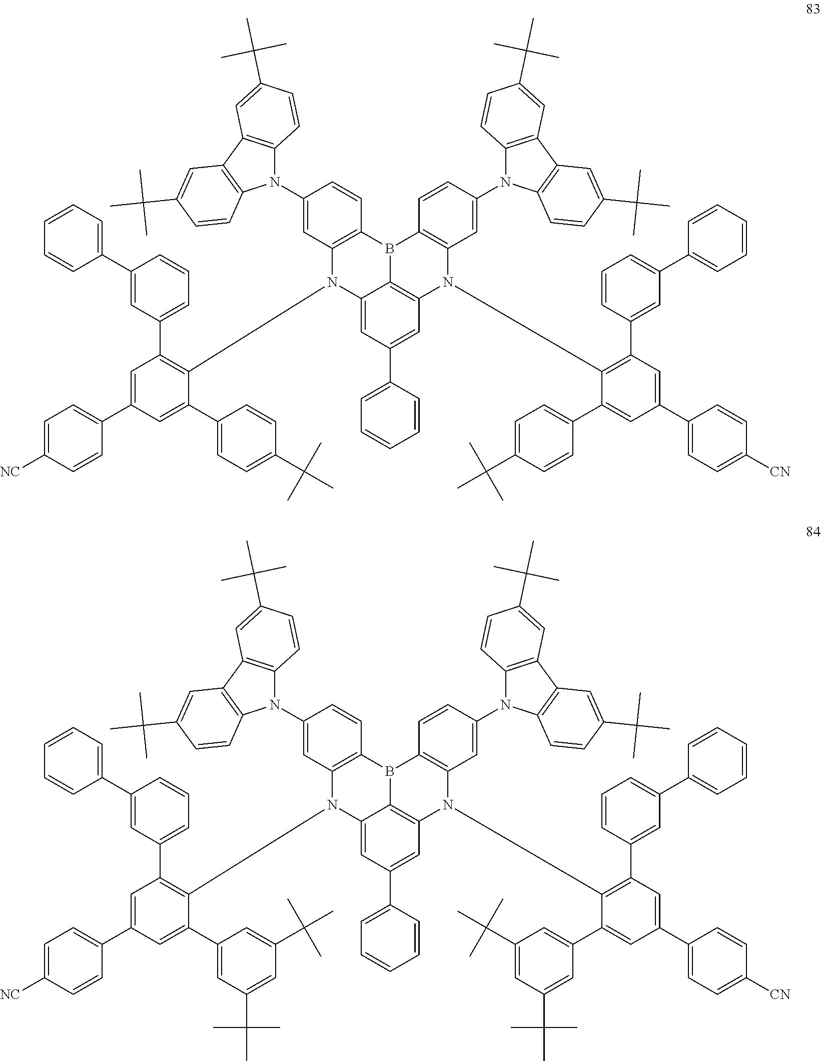

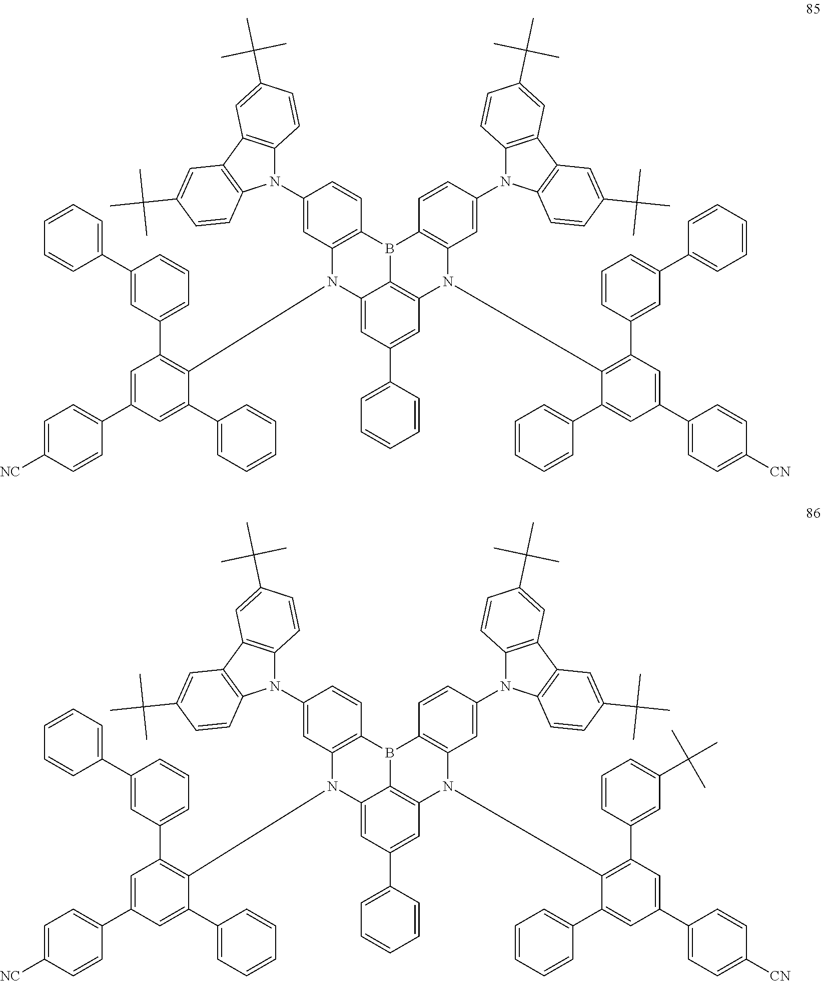 [SMILES: CC(C)(C)c1ccc2c(c1)c1cc(C(C)(C)C)ccc1n2-c1ccc2c(c1)N(c1c(-c3ccccc3)cc(-c3ccc(C#N)cc3)cc1-c1cccc(-c3ccccc3)c1)c1cc(-c3ccccc3)cc3c1B2c1ccc(-n2c4ccc(C(C)(C)C)cc4c4cc(C(C)(C)C)ccc42)cc1N3c1c(-c2ccccc2)cc(-c2ccc(C#N)cc2)cc1-c1cccc(-c2ccccc2)c1 ; CC(C)(C)c1cccc(-c2cc(-c3ccc(C#N)cc3)cc(-c3ccccc3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(-c5ccc(C#N)cc5)cc4-c4cccc(-c5ccccc5)c4)c4cc(-c5ccccc5)cc2c43)c1]

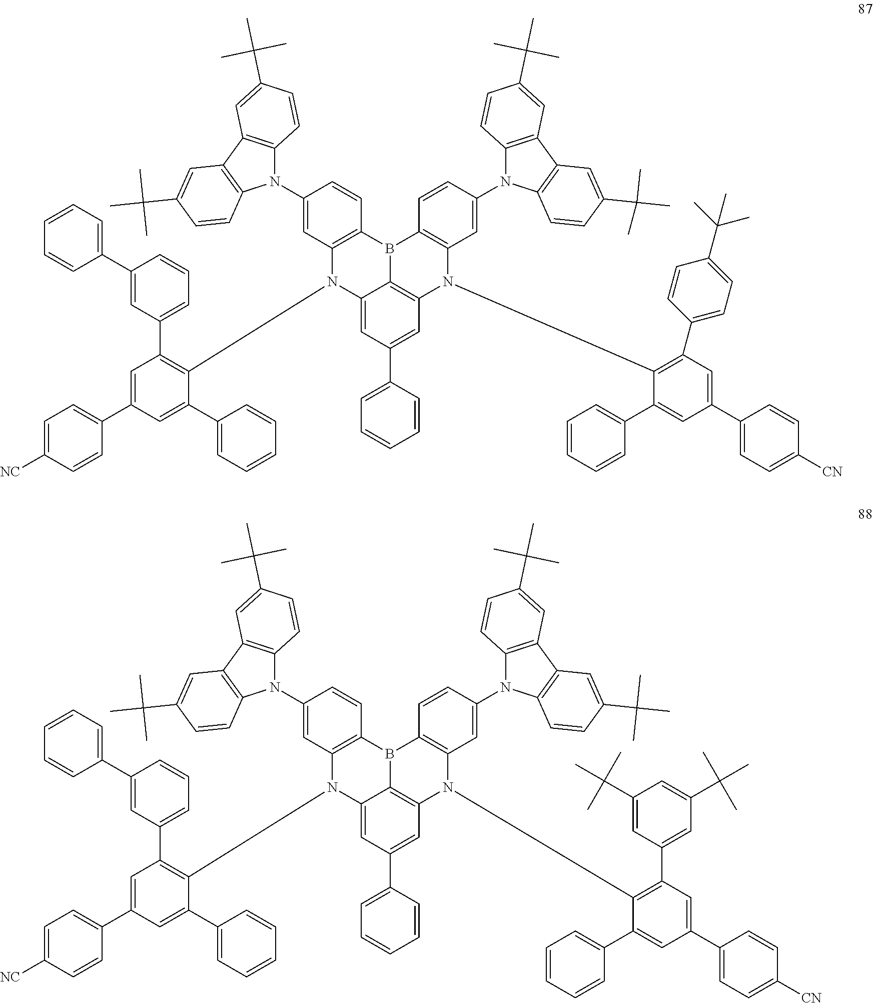 [SMILES: CC(C)(C)c1ccc(-c2cc(-c3ccc(C#N)cc3)cc(-c3ccccc3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(-c5ccc(C#N)cc5)cc4-c4cccc(-c5ccccc5)c4)c4cc(-c5ccccc5)cc2c43)cc1 ; CC(C)(C)c1cc(-c2cc(-c3ccc(C#N)cc3)cc(-c3ccccc3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(-c5ccc(C#N)cc5)cc4-c4cccc(-c5ccccc5)c4)c4cc(-c5ccccc5)cc2c43)cc(C(C)(C)C)c1]

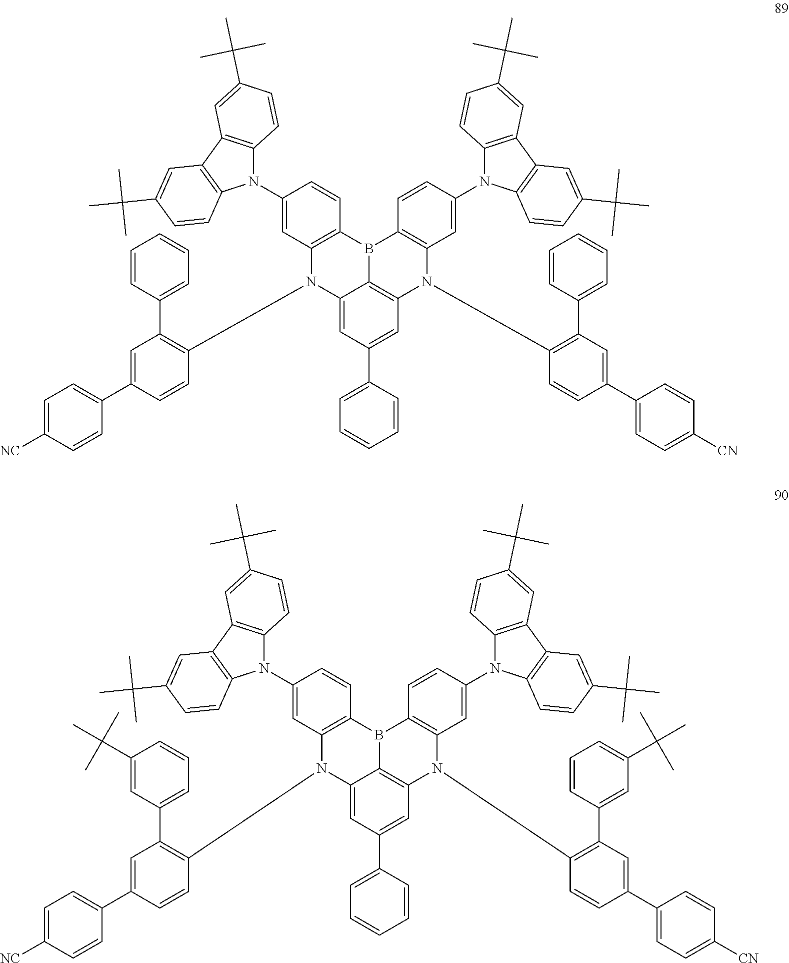 [SMILES: CC(C)(C)c1ccc2c(c1)c1cc(C(C)(C)C)ccc1n2-c1ccc2c(c1)N(c1ccc(-c3ccc(C#N)cc3)cc1-c1ccccc1)c1cc(-c3ccccc3)cc3c1B2c1ccc(-n2c4ccc(C(C)(C)C)cc4c4cc(C(C)(C)C)ccc42)cc1N3c1ccc(-c2ccc(C#N)cc2)cc1-c1ccccc1 ; CC(C)(C)c1cccc(-c2cc(-c3ccc(C#N)cc3)ccc2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(-c5ccc(C#N)cc5)cc4-c4cccc(C(C)(C)C)c4)c4cc(-c5ccccc5)cc2c43)c1]

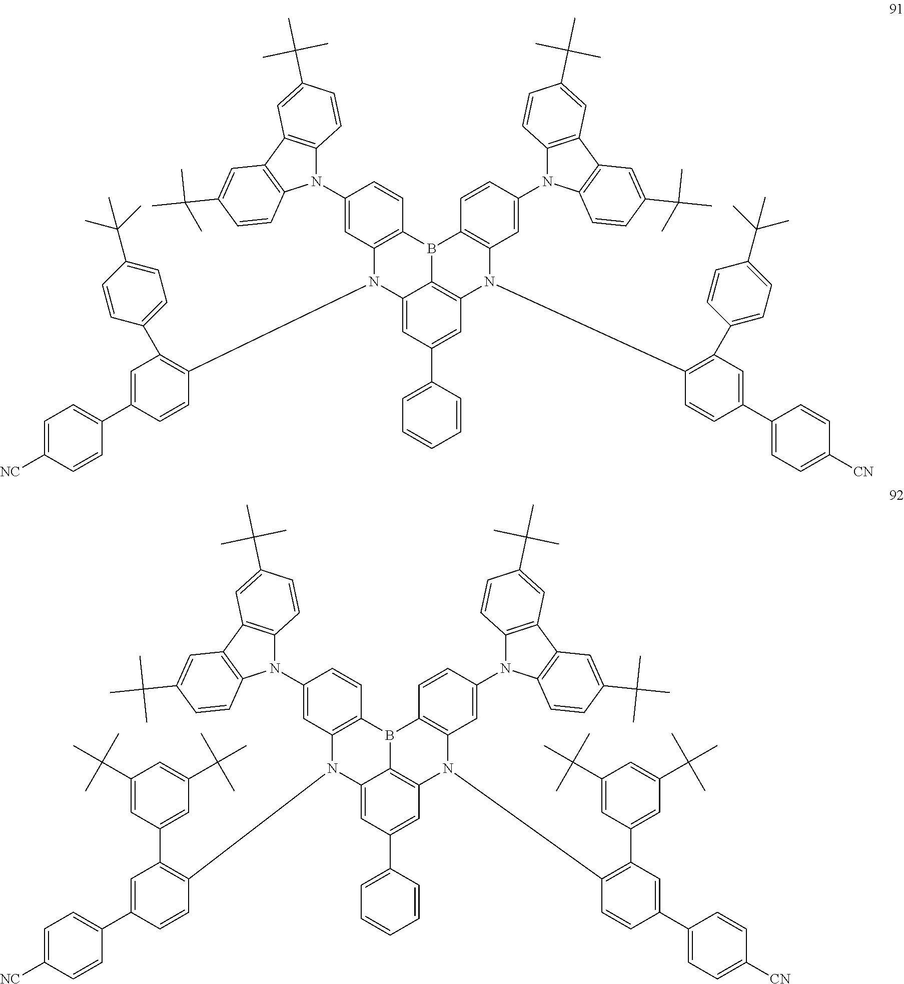 [SMILES: CC(C)(C)c1ccc(-c2cc(-c3ccc(C#N)cc3)ccc2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(-c5ccc(C#N)cc5)cc4-c4ccc(C(C)(C)C)cc4)c4cc(-c5ccccc5)cc2c43)cc1 ; CC(C)(C)c1cc(-c2cc(-c3ccc(C#N)cc3)ccc2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(-c5ccc(C#N)cc5)cc4-c4cc(C(C)(C)C)cc(C(C)(C)C)c4)c4cc(-c5ccccc5)cc2c43)cc(C(C)(C)C)c1]

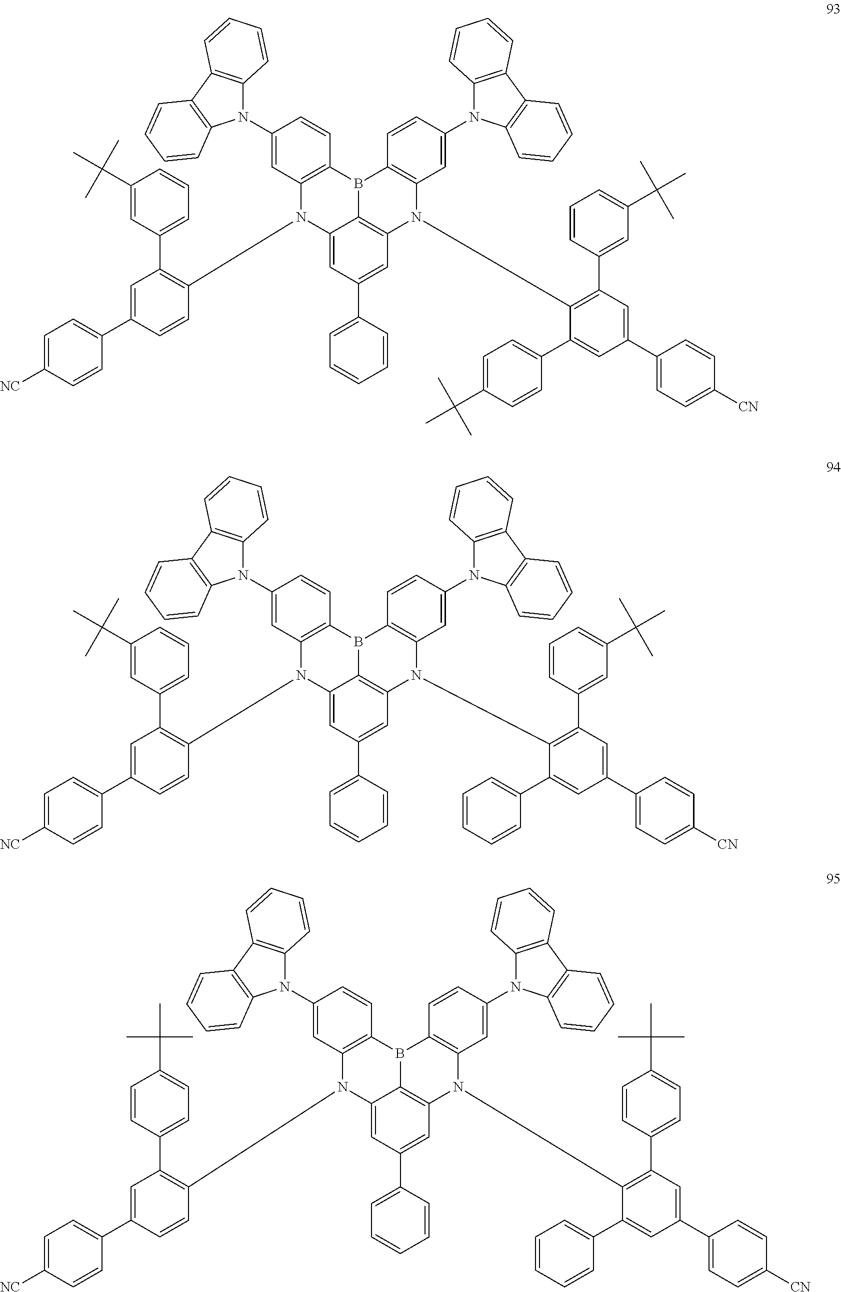

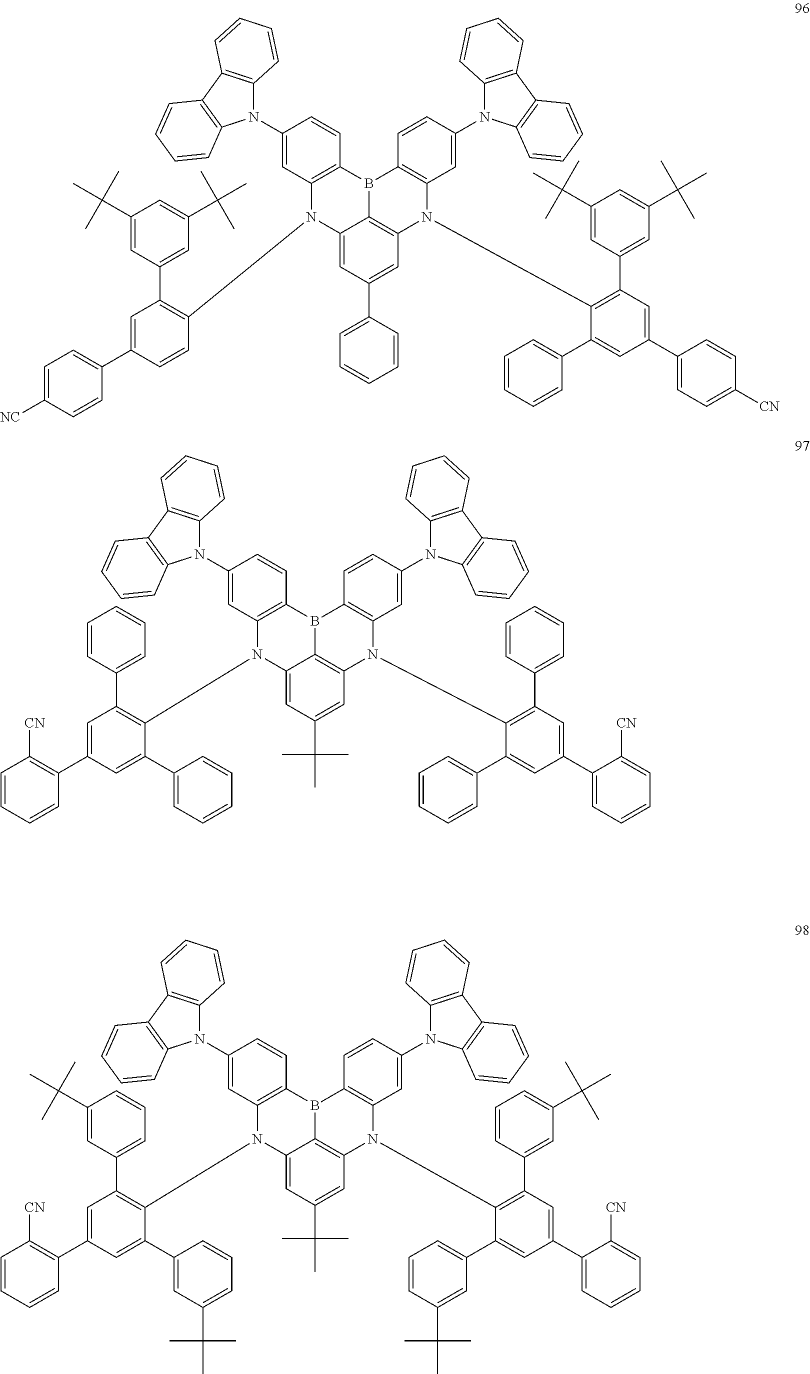

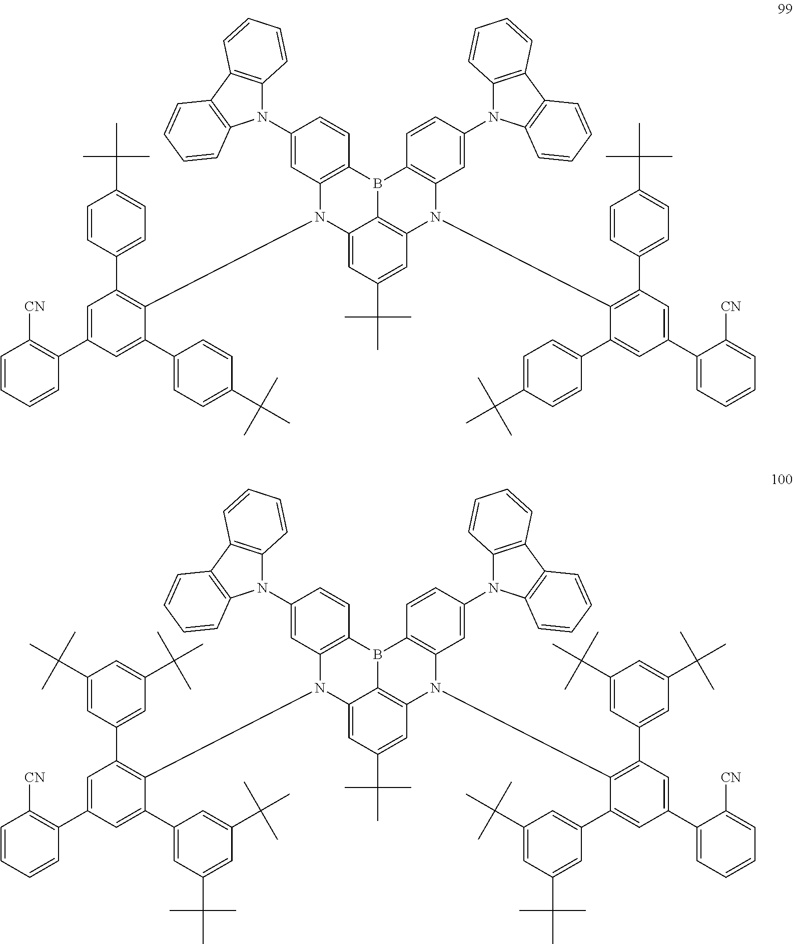 [SMILES: CC(C)(C)c1ccc(-c2cc(-c3ccccc3C#N)cc(-c3ccc(C(C)(C)C)cc3)c2N2c3cc(-n4c5ccccc5c5ccccc54)ccc3B3c4ccc(-n5c6ccccc6c6ccccc65)cc4N(c4c(-c5ccc(C(C)(C)C)cc5)cc(-c5ccccc5C#N)cc4-c4ccc(C(C)(C)C)cc4)c4cc(C(C)(C)C)cc2c43)cc1 ; CC(C)(C)c1cc(-c2cc(-c3ccccc3C#N)cc(-c3cc(C(C)(C)C)cc(C(C)(C)C)c3)c2N2c3cc(-n4c5ccccc5c5ccccc54)ccc3B3c4ccc(-n5c6ccccc6c6ccccc65)cc4N(c4c(-c5cc(C(C)(C)C)cc(C(C)(C)C)c5)cc(-c5ccccc5C#N)cc4-c4cc(C(C)(C)C)cc(C(C)(C)C)c4)c4cc(C(C)(C)C)cc2c43)cc(C(C)(C)C)c1]

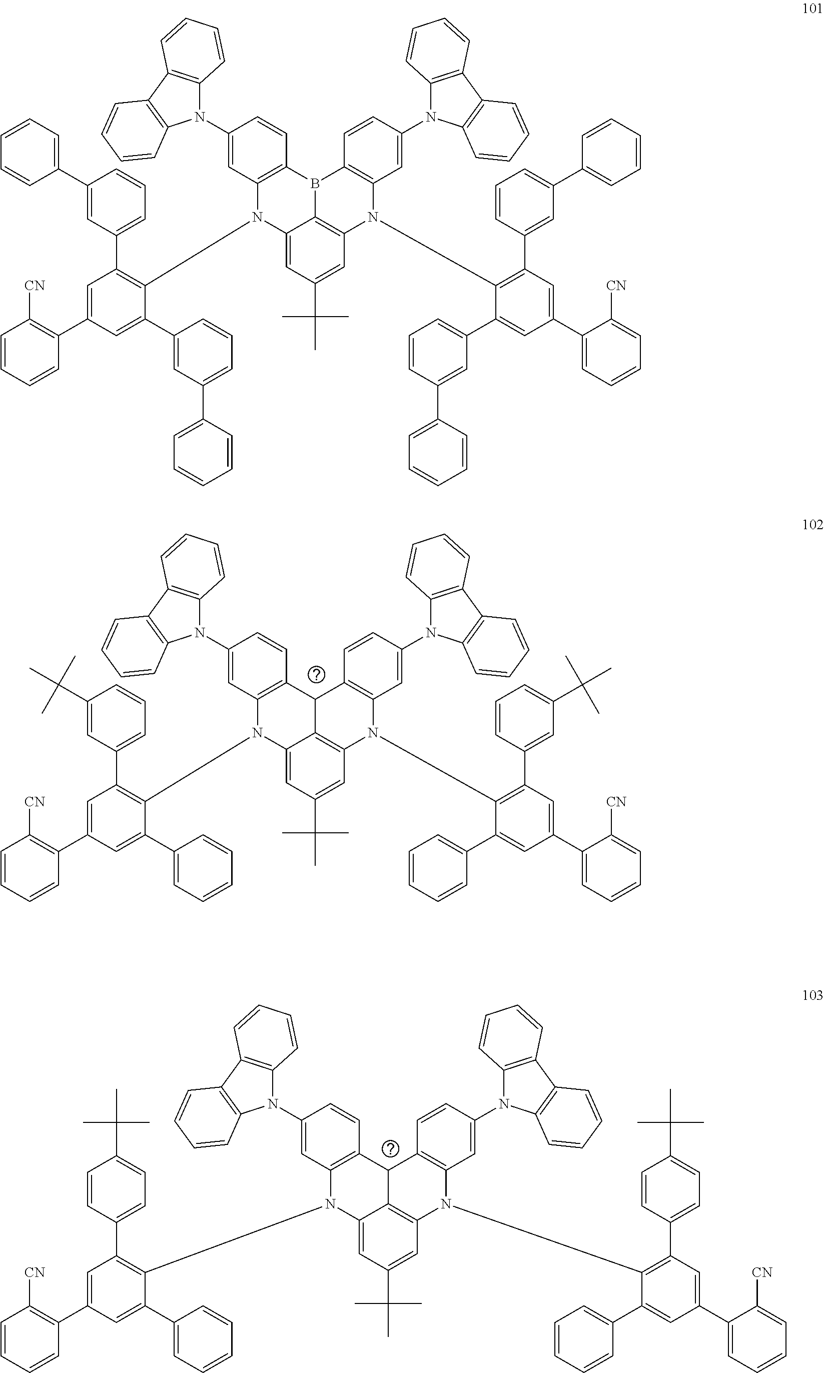

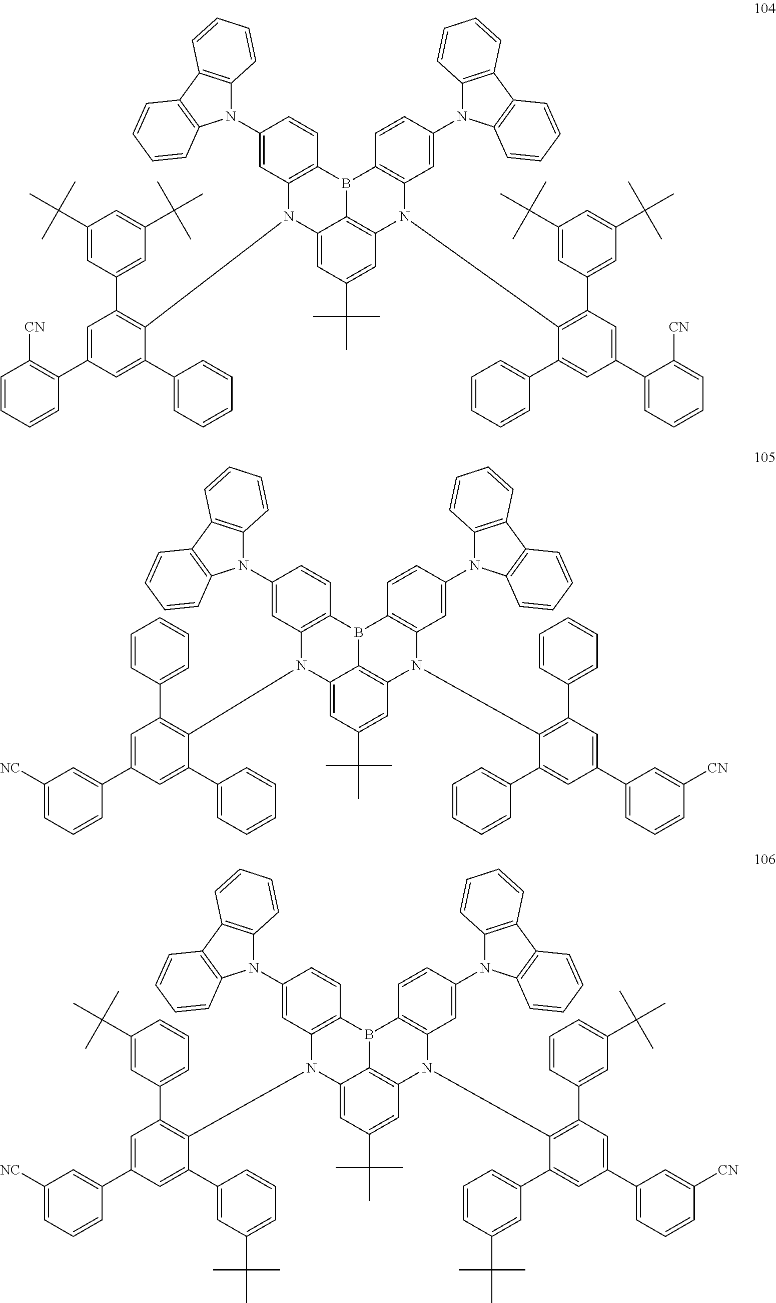

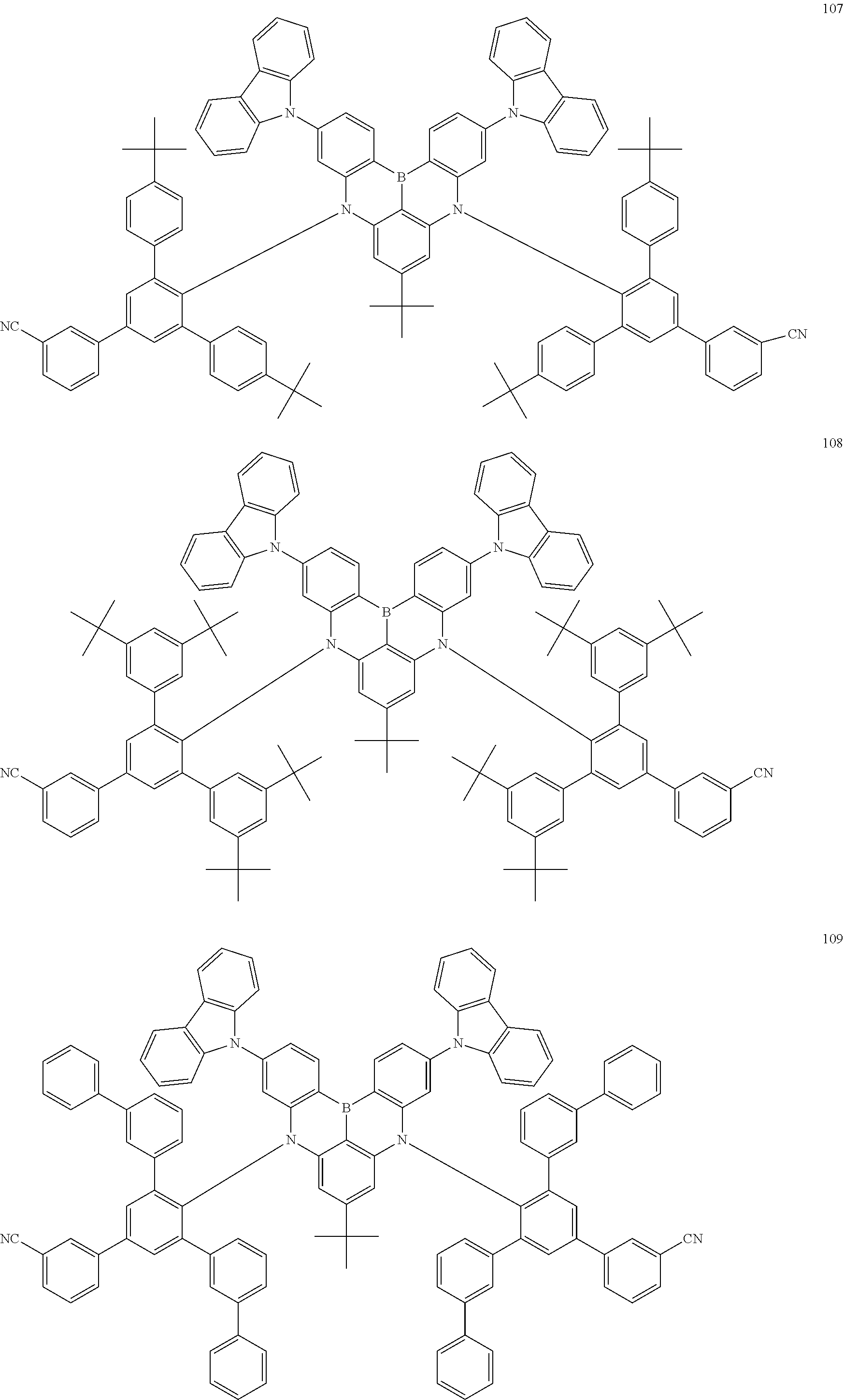

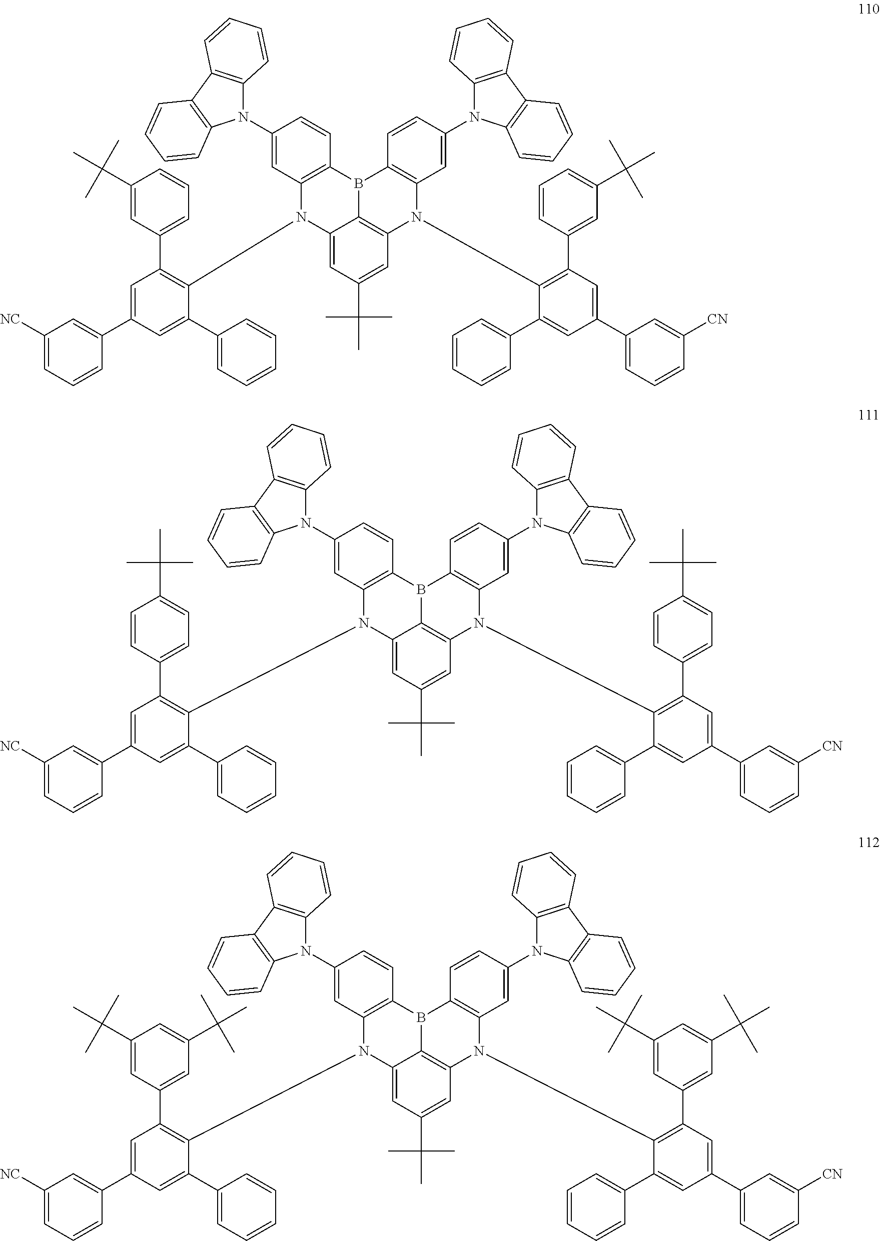

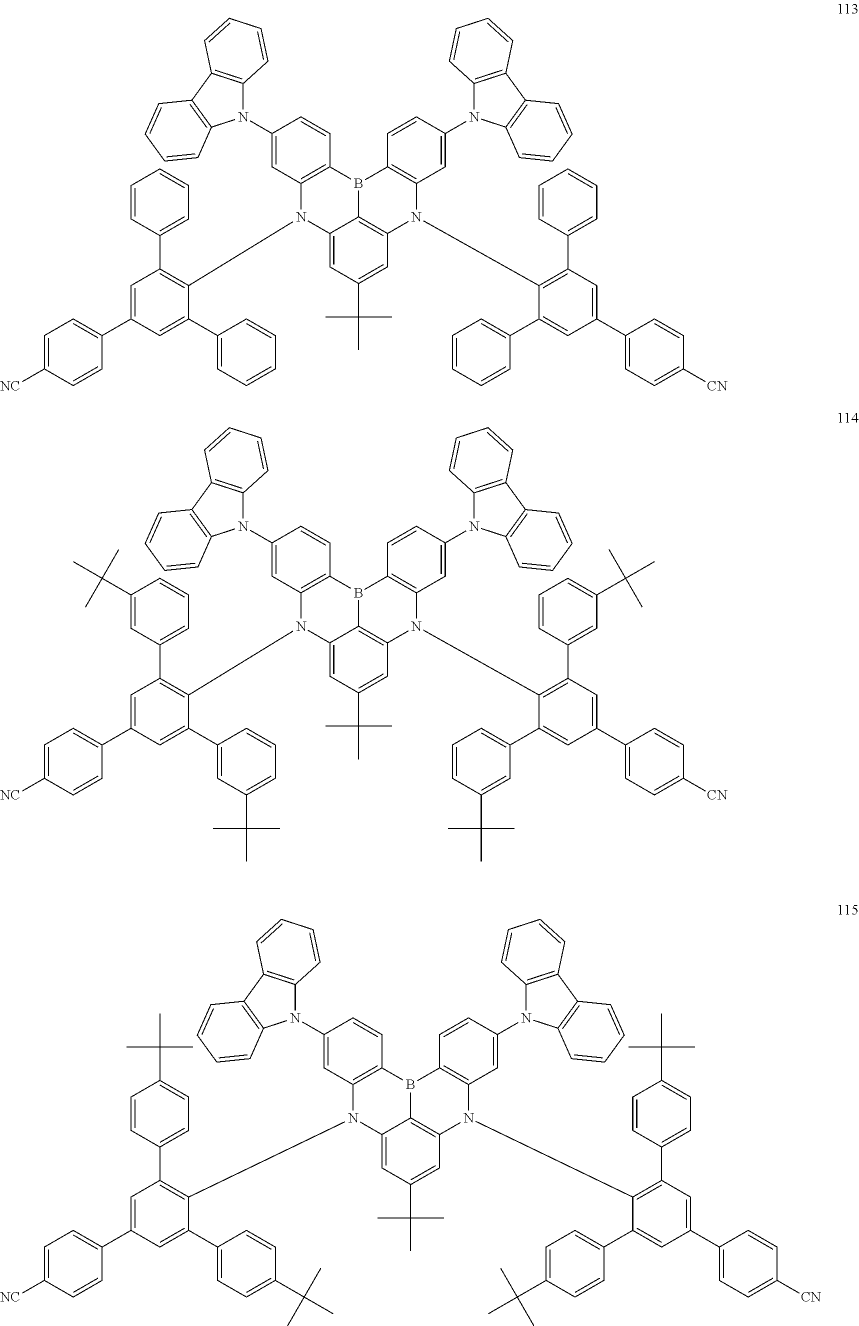

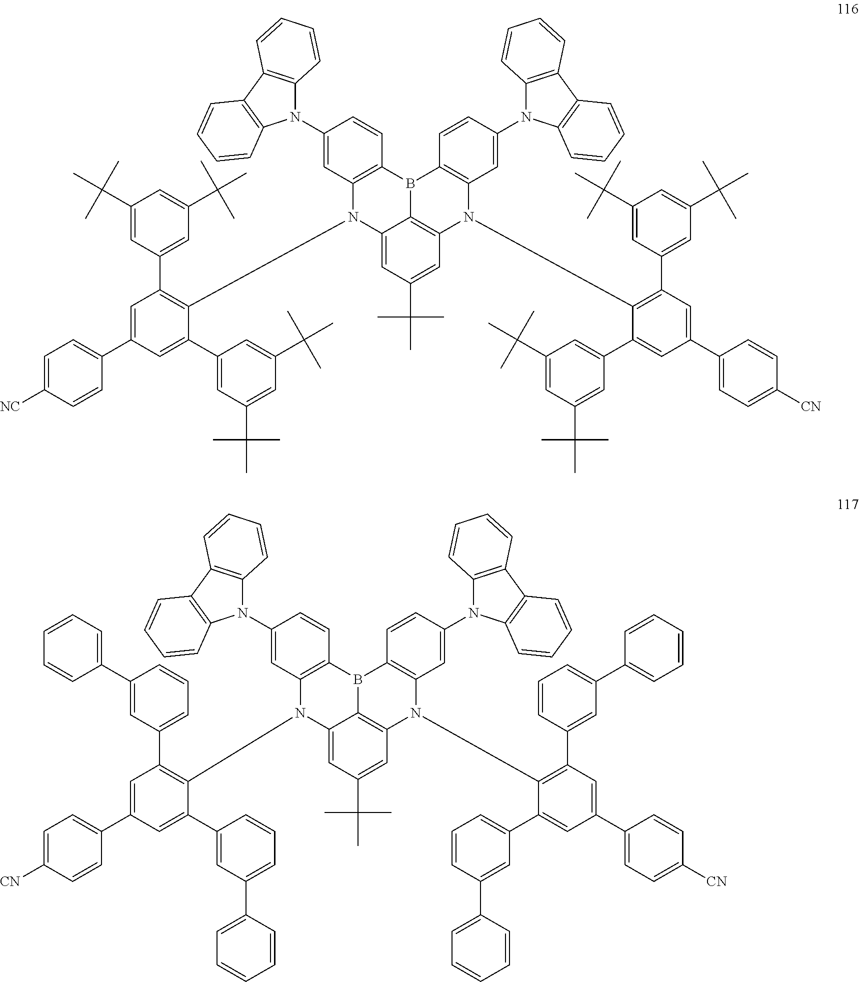

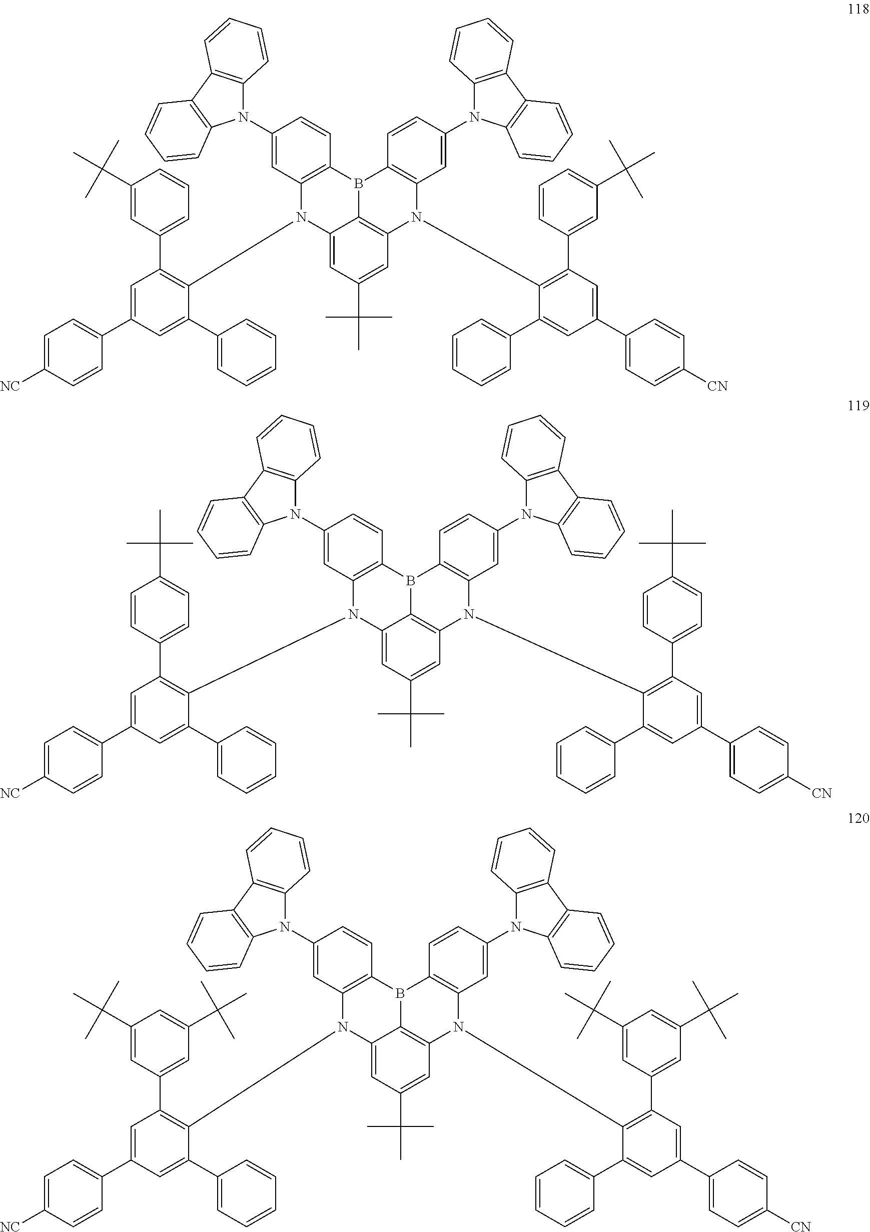

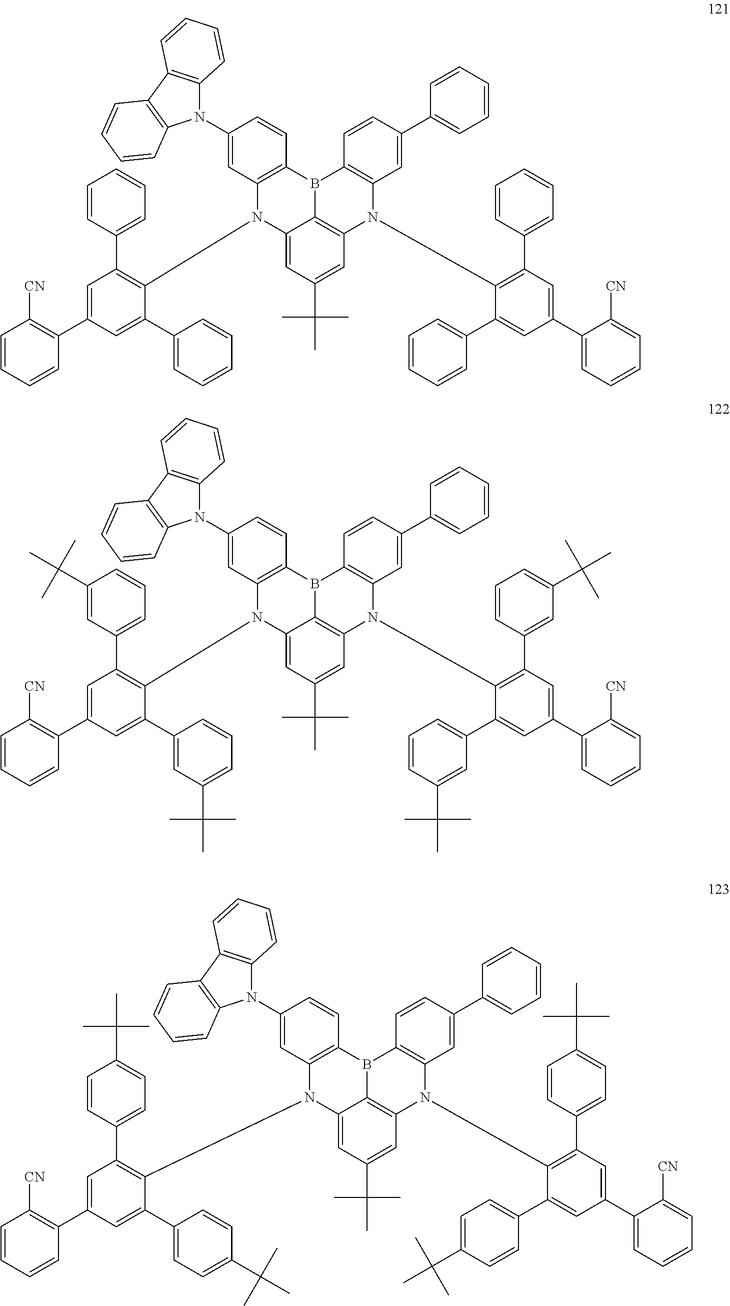

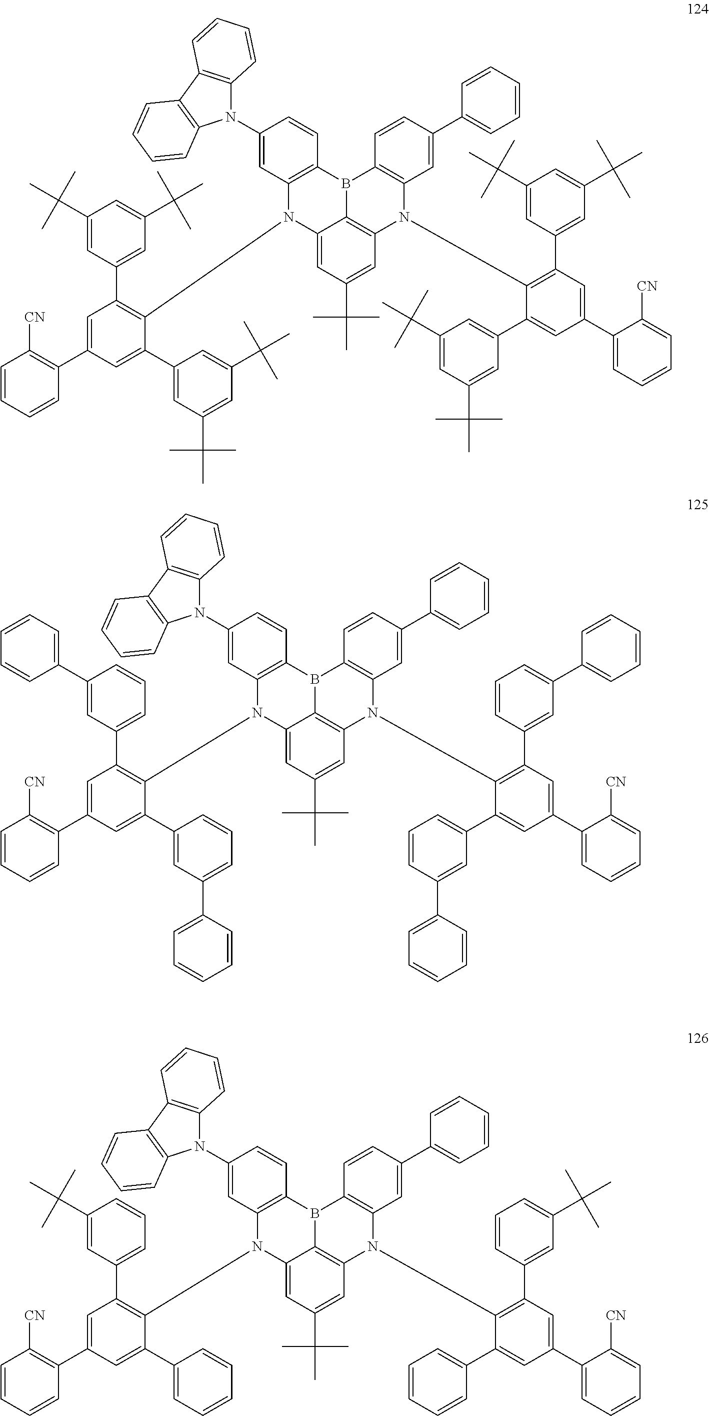

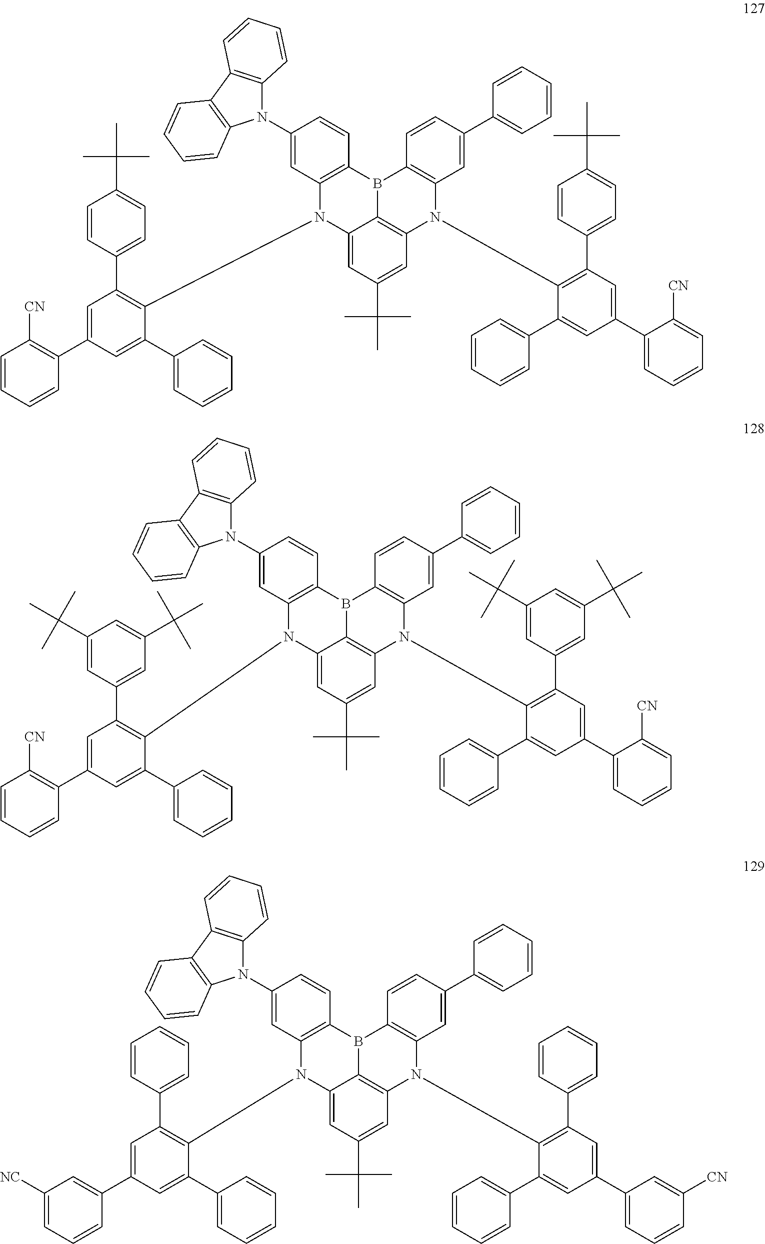

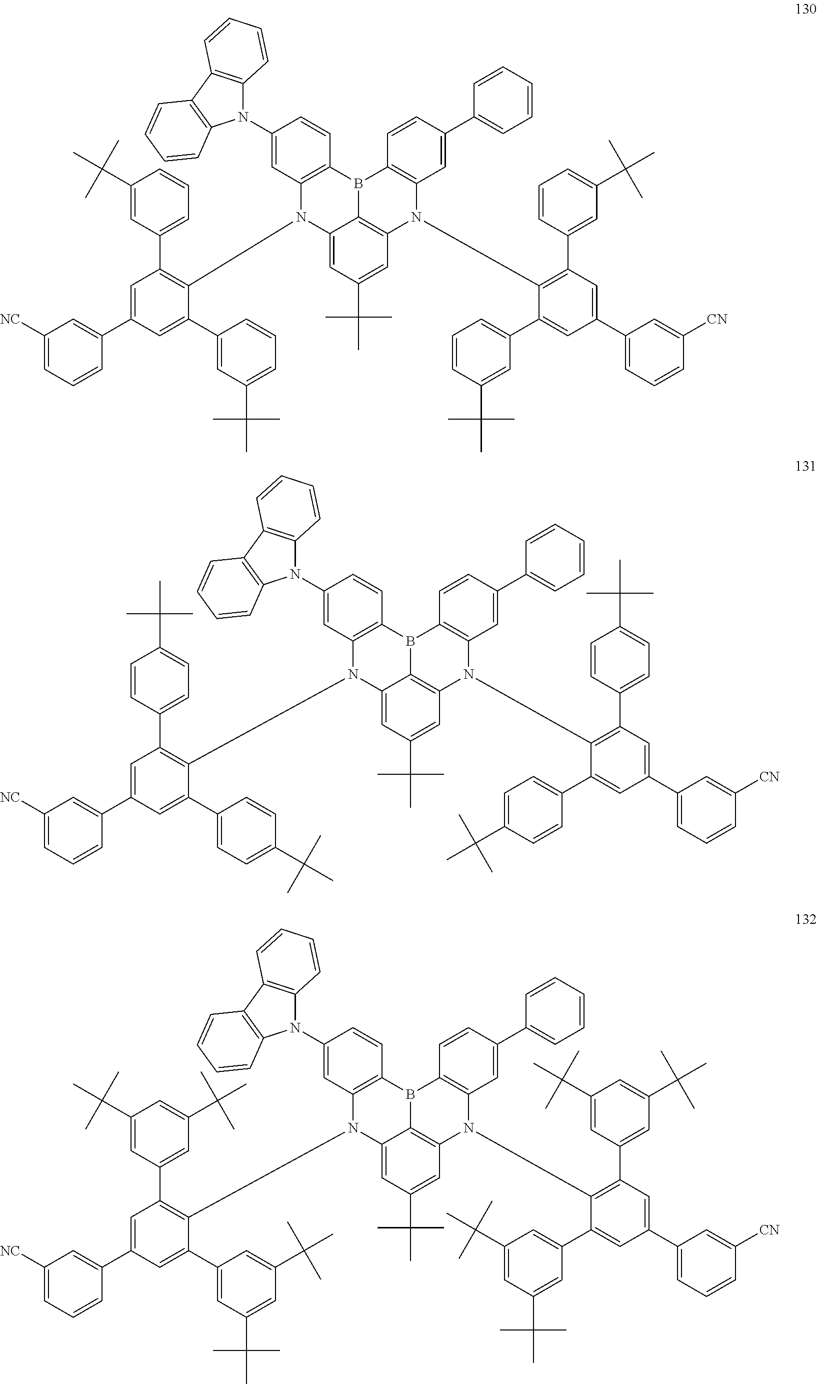

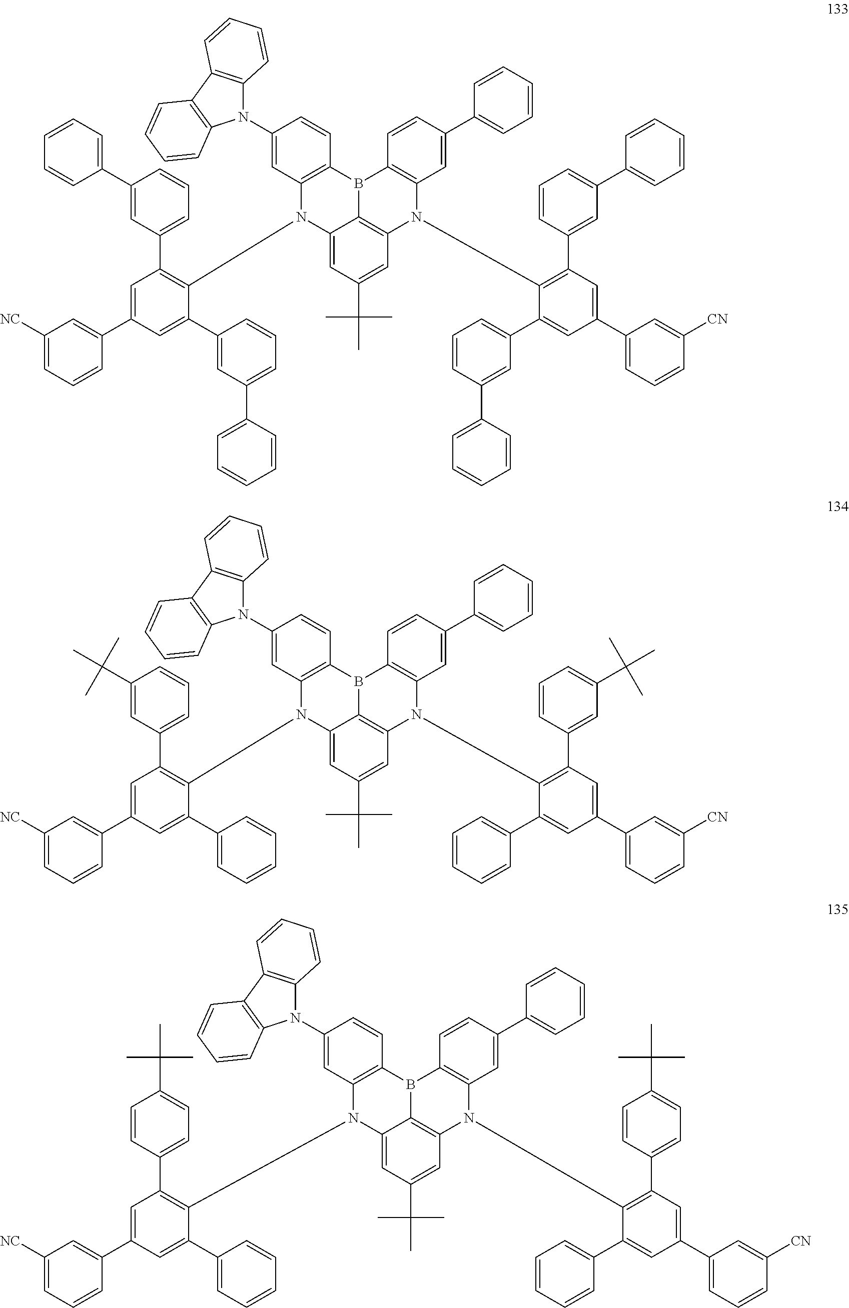

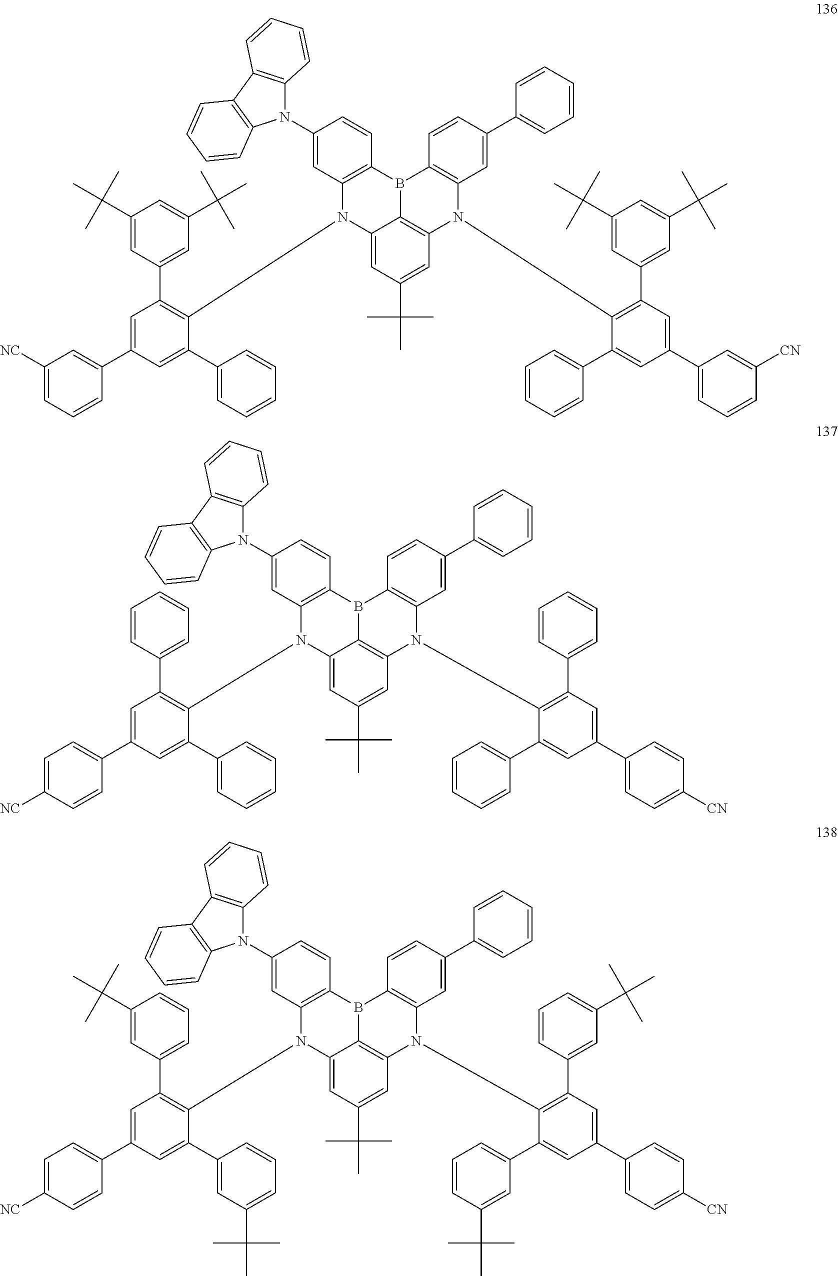

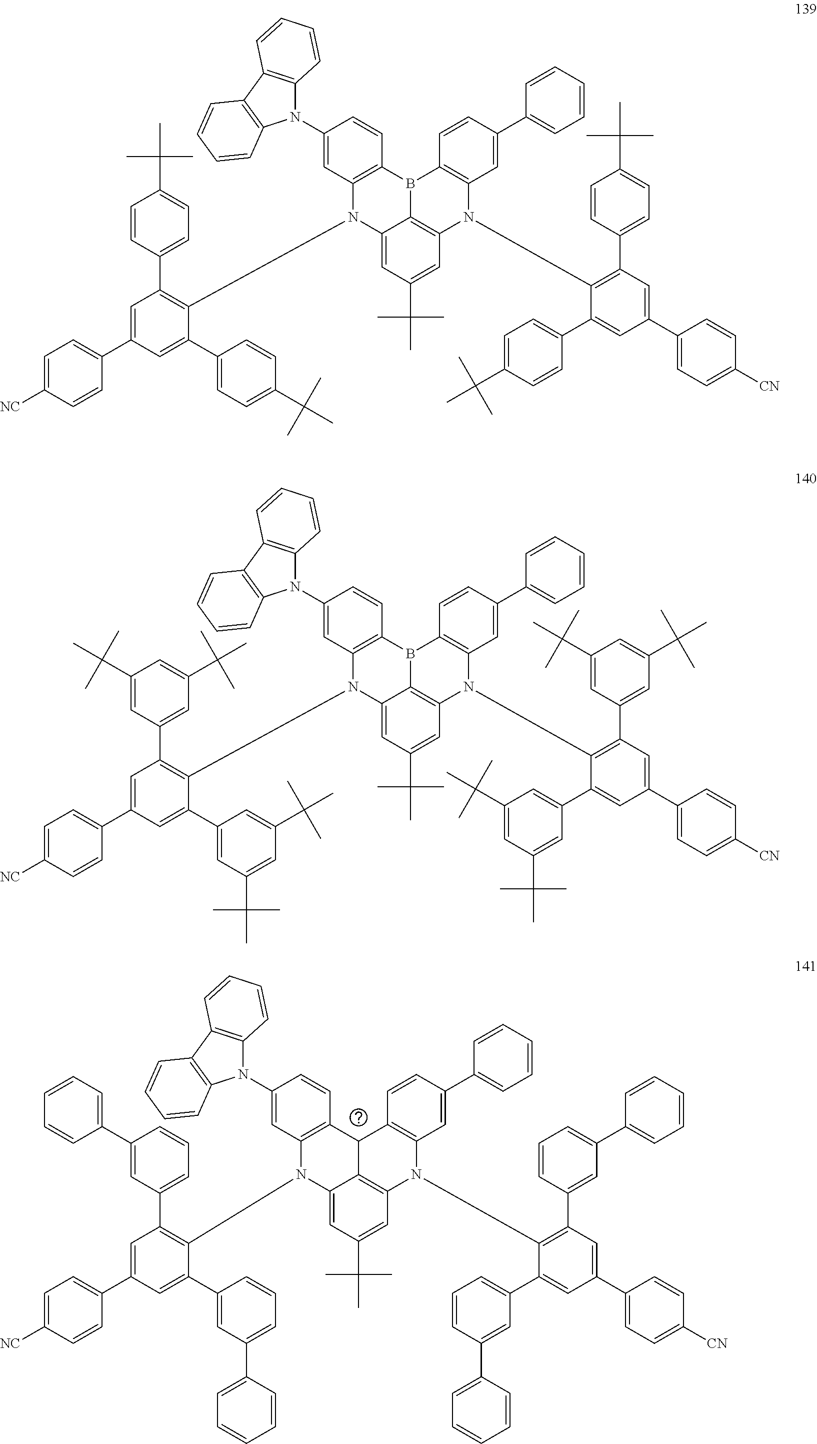

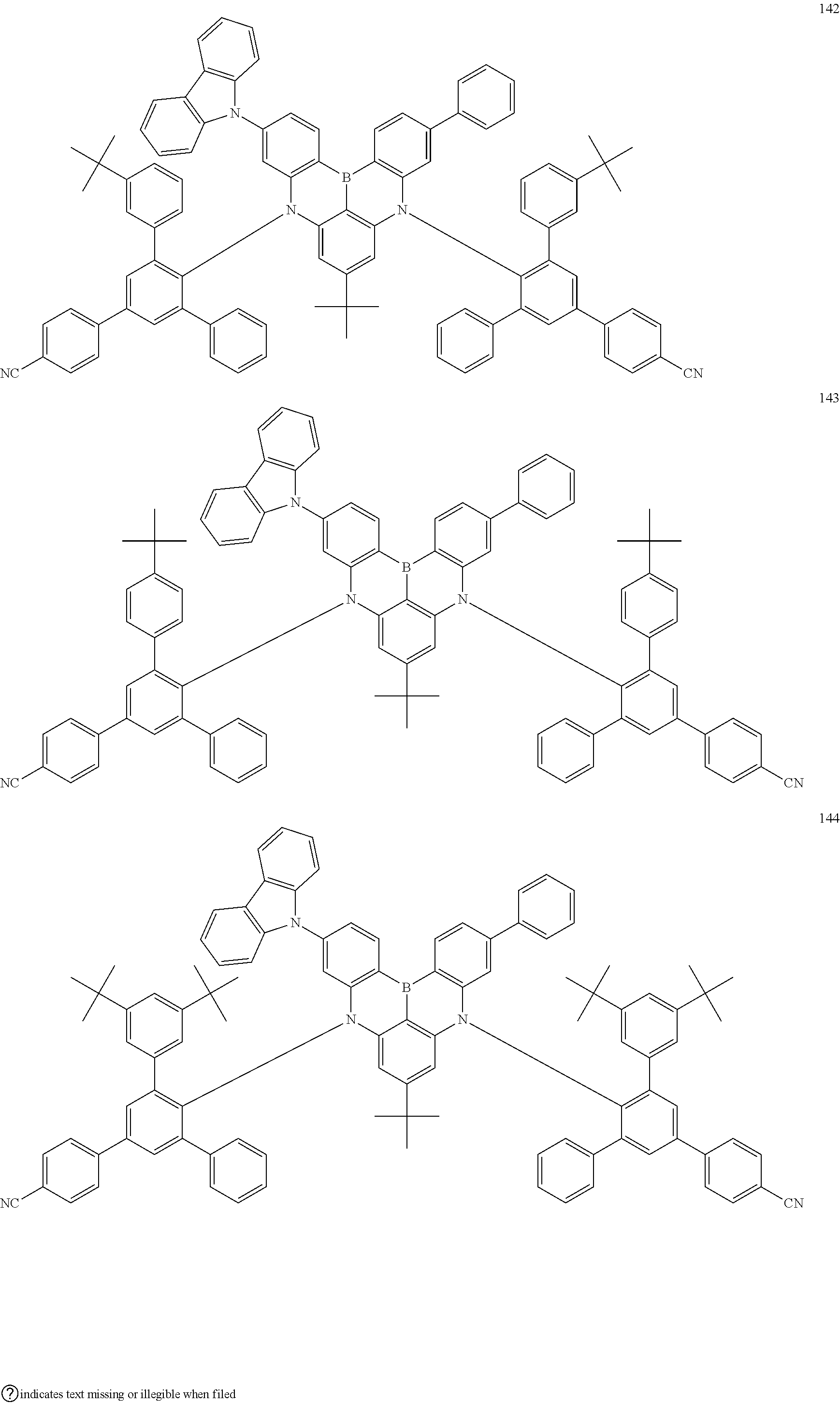

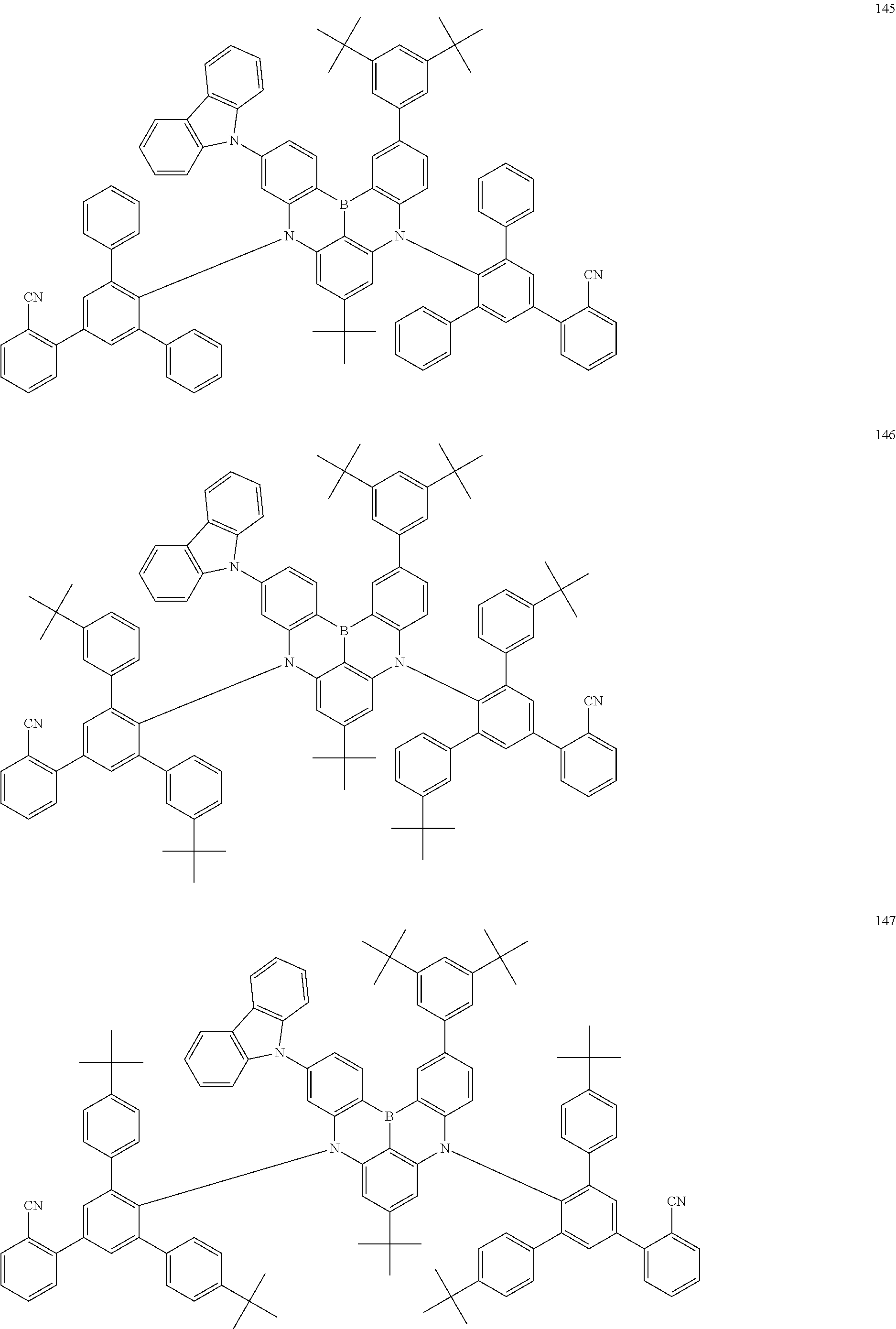

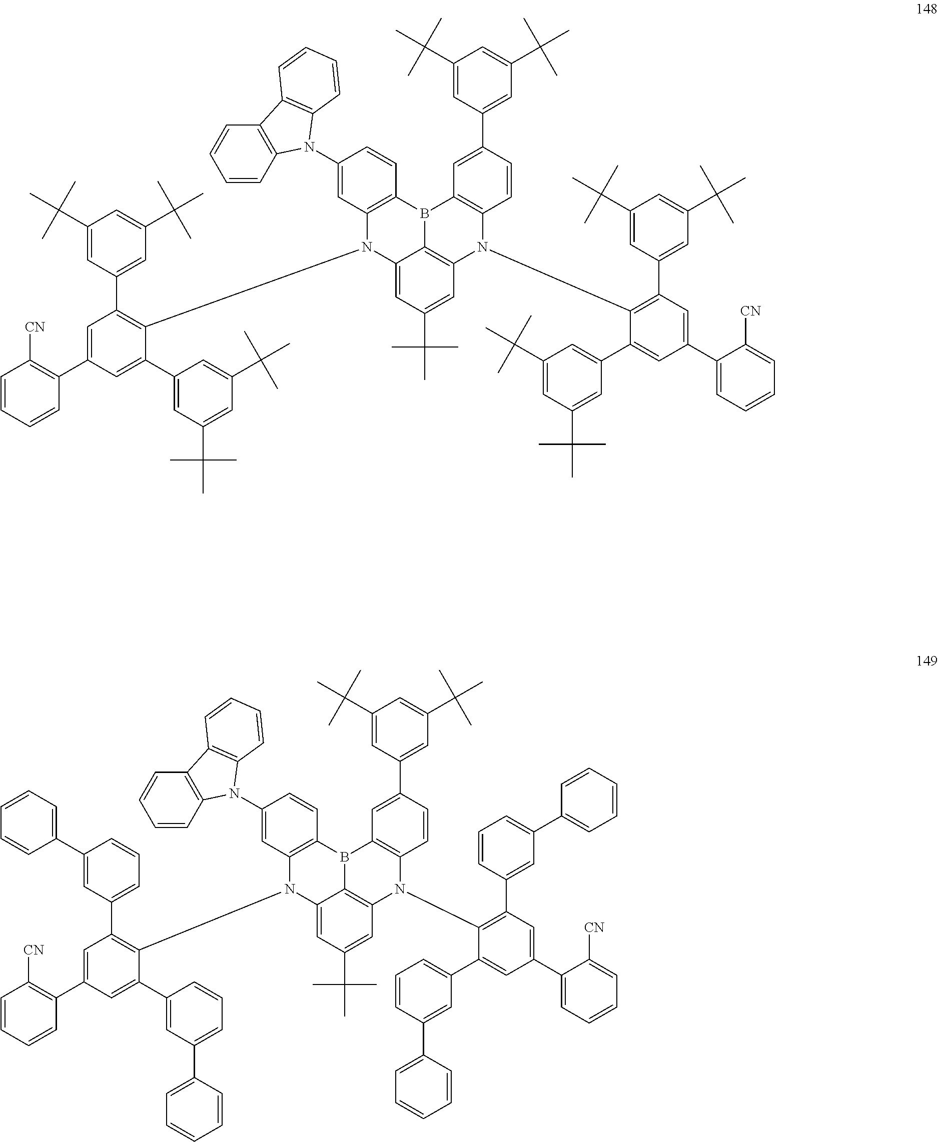 [SMILES: CC(C)(C)c1cc(-c2ccc3c(c2)B2c4ccc(-n5c6ccccc6c6ccccc65)cc4N(c4c(-c5cc(C(C)(C)C)cc(C(C)(C)C)c5)cc(-c5ccccc5C#N)cc4-c4cc(C(C)(C)C)cc(C(C)(C)C)c4)c4cc(C(C)(C)C)cc(c42)N3c2c(-c3cc(C(C)(C)C)cc(C(C)(C)C)c3)cc(-c3ccccc3C#N)cc2-c2cc(C(C)(C)C)cc(C(C)(C)C)c2)cc(C(C)(C)C)c1 ; CC(C)(C)c1cc(-c2ccc3c(c2)B2c4ccc(-n5c6ccccc6c6ccccc65)cc4N(c4c(-c5cccc(-c6ccccc6)c5)cc(-c5ccccc5C#N)cc4-c4cccc(-c5ccccc5)c4)c4cc(C(C)(C)C)cc(c42)N3c2c(-c3cccc(-c4ccccc4)c3)cc(-c3ccccc3C#N)cc2-c2cccc(-c3ccccc3)c2)cc(C(C)(C)C)c1]

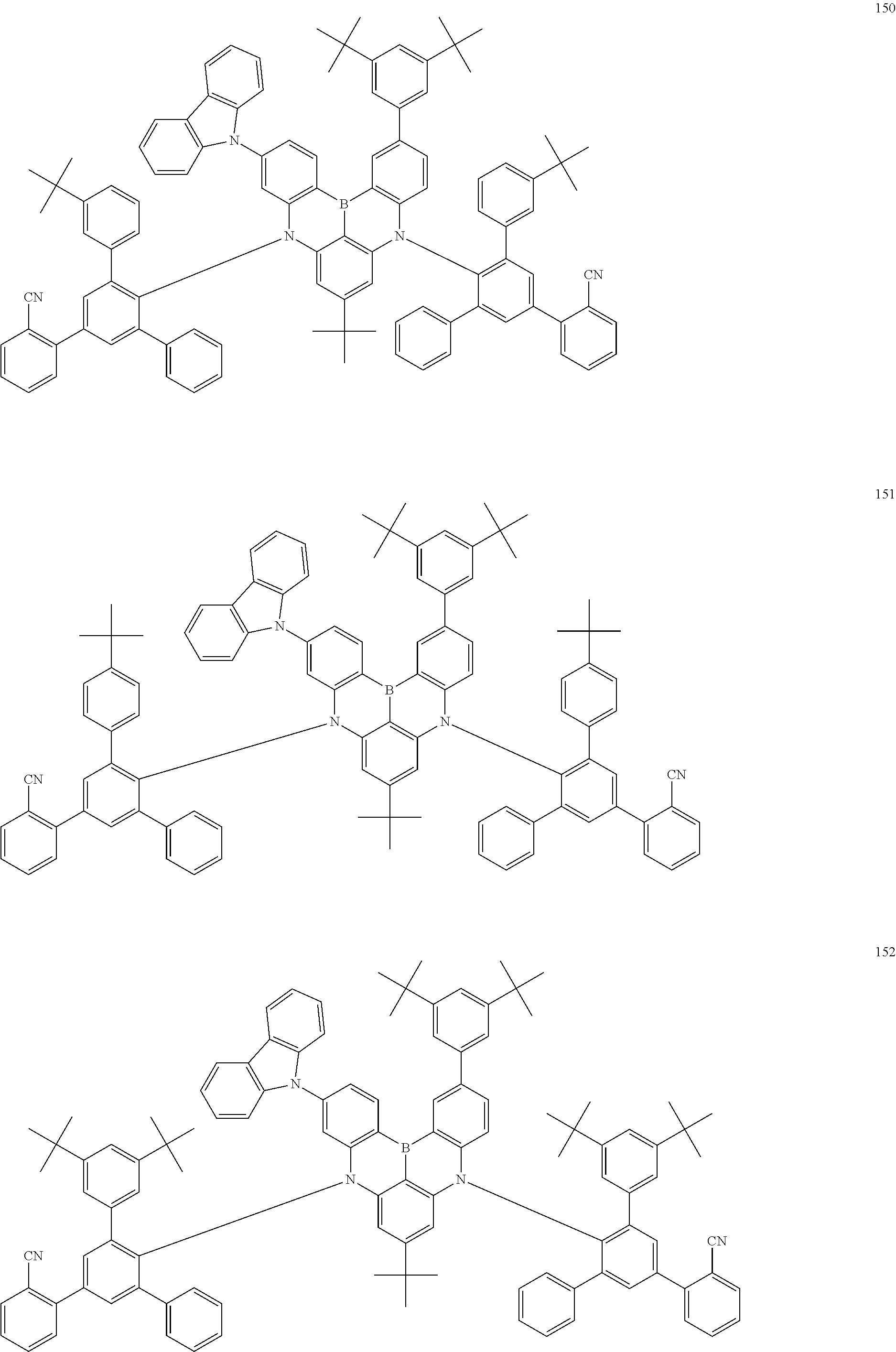

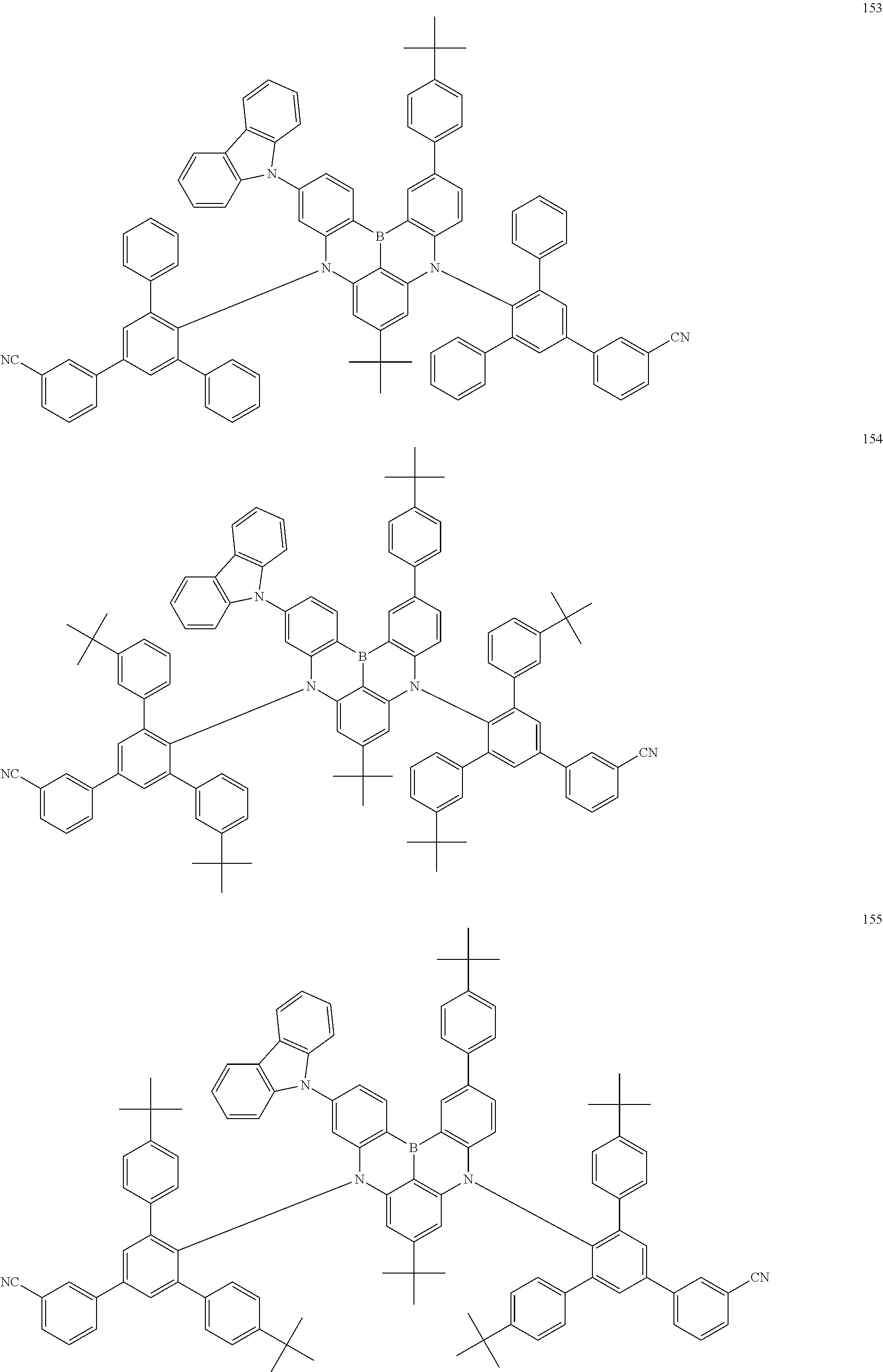

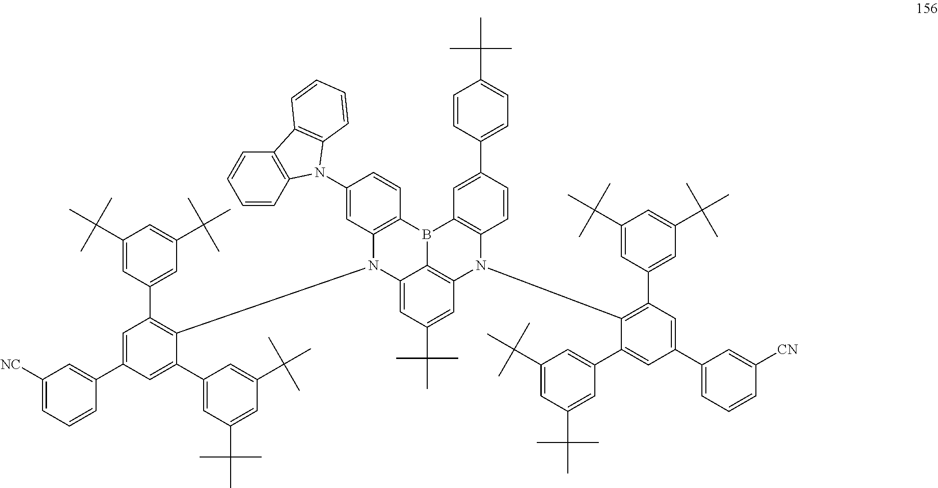 [SMILES: CC(C)(C)c1ccc(-c2ccc3c(c2)B2c4ccc(-n5c6ccccc6c6ccccc65)cc4N(c4c(-c5cc(C(C)(C)C)cc(C(C)(C)C)c5)cc(-c5cccc(C#N)c5)cc4-c4cc(C(C)(C)C)cc(C(C)(C)C)c4)c4cc(C(C)(C)C)cc(c42)N3c2c(-c3cc(C(C)(C)C)cc(C(C)(C)C)c3)cc(-c3cccc(C#N)c3)cc2-c2cc(C(C)(C)C)cc(C(C)(C)C)c2)cc1]

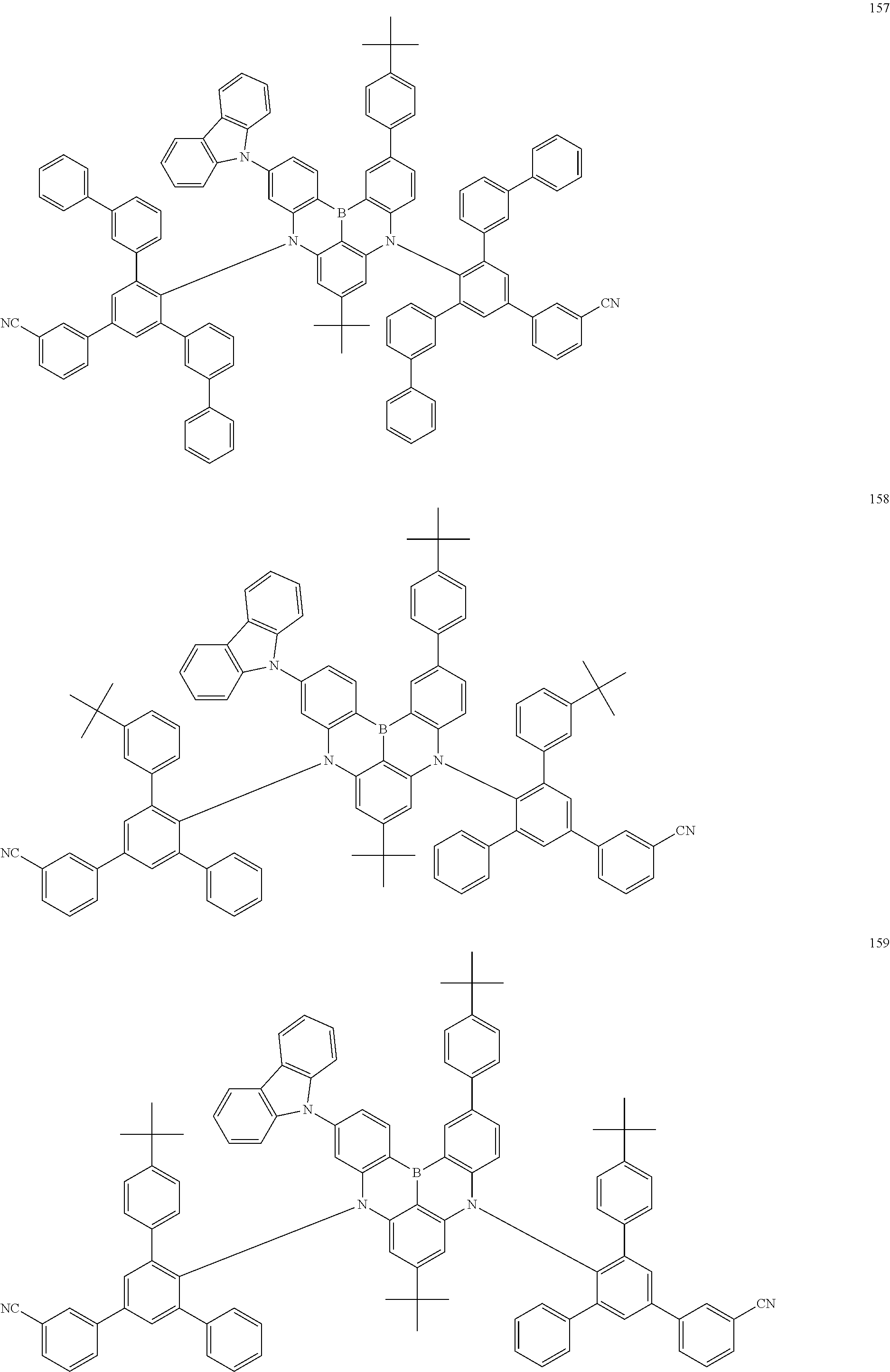

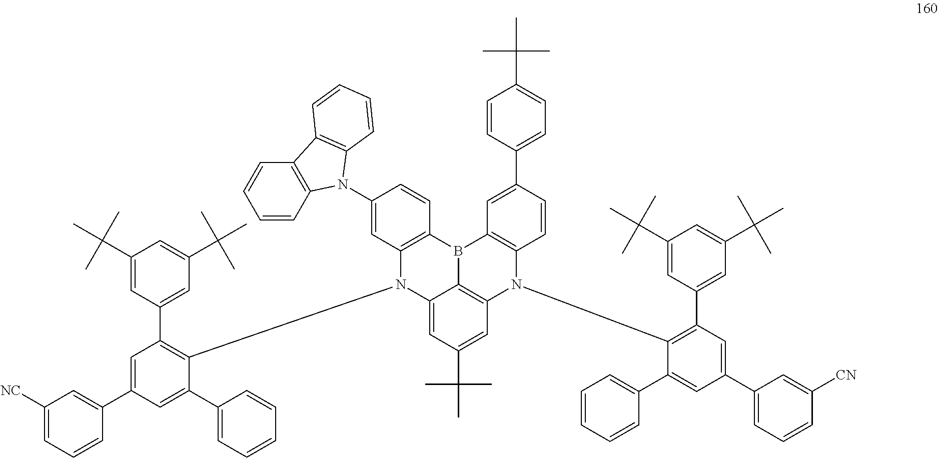 [SMILES: CC(C)(C)c1ccc(-c2ccc3c(c2)B2c4ccc(-n5c6ccccc6c6ccccc65)cc4N(c4c(-c5ccccc5)cc(-c5cccc(C#N)c5)cc4-c4cc(C(C)(C)C)cc(C(C)(C)C)c4)c4cc(C(C)(C)C)cc(c42)N3c2c(-c3ccccc3)cc(-c3cccc(C#N)c3)cc2-c2cc(C(C)(C)C)cc(C(C)(C)C)c2)cc1]

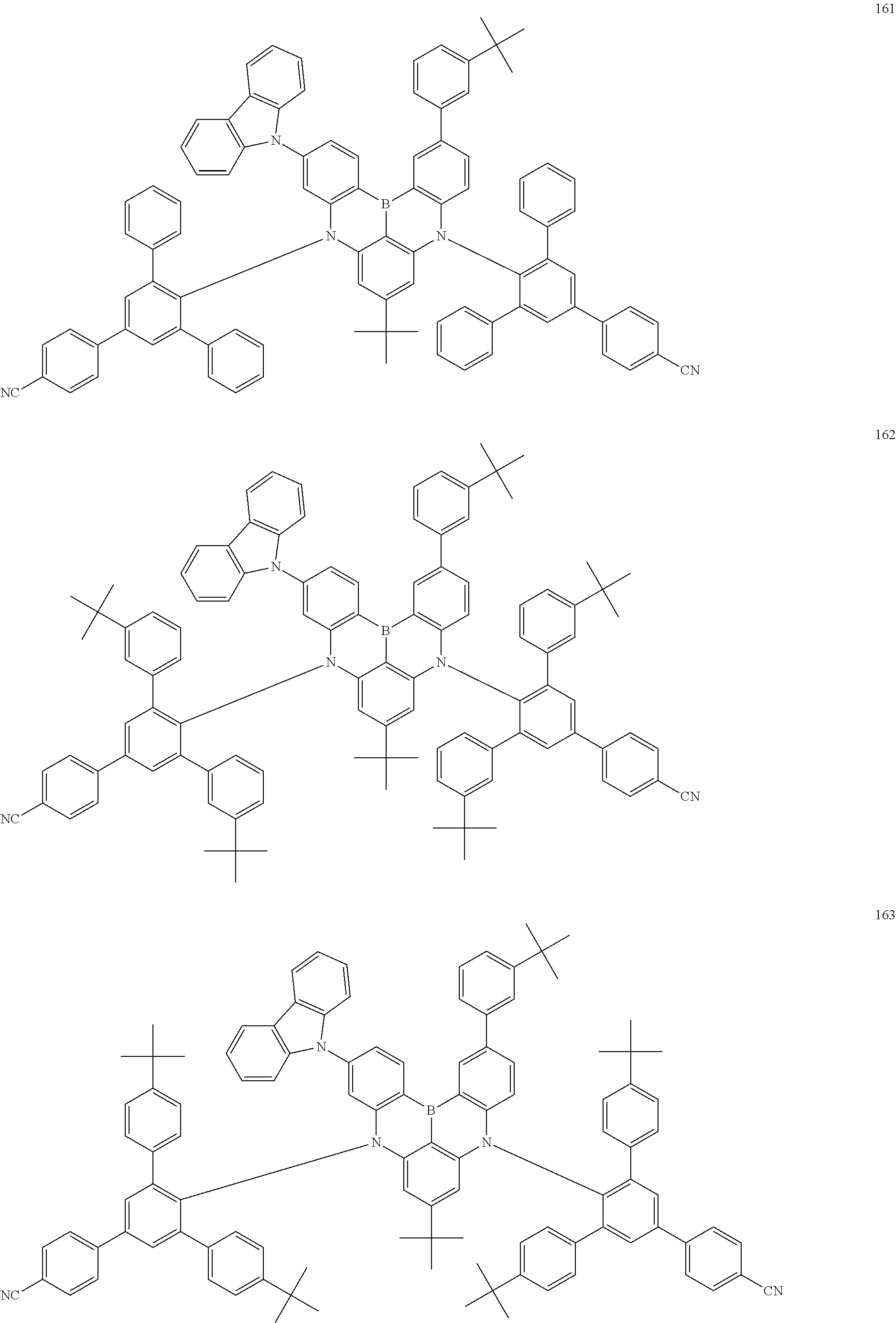

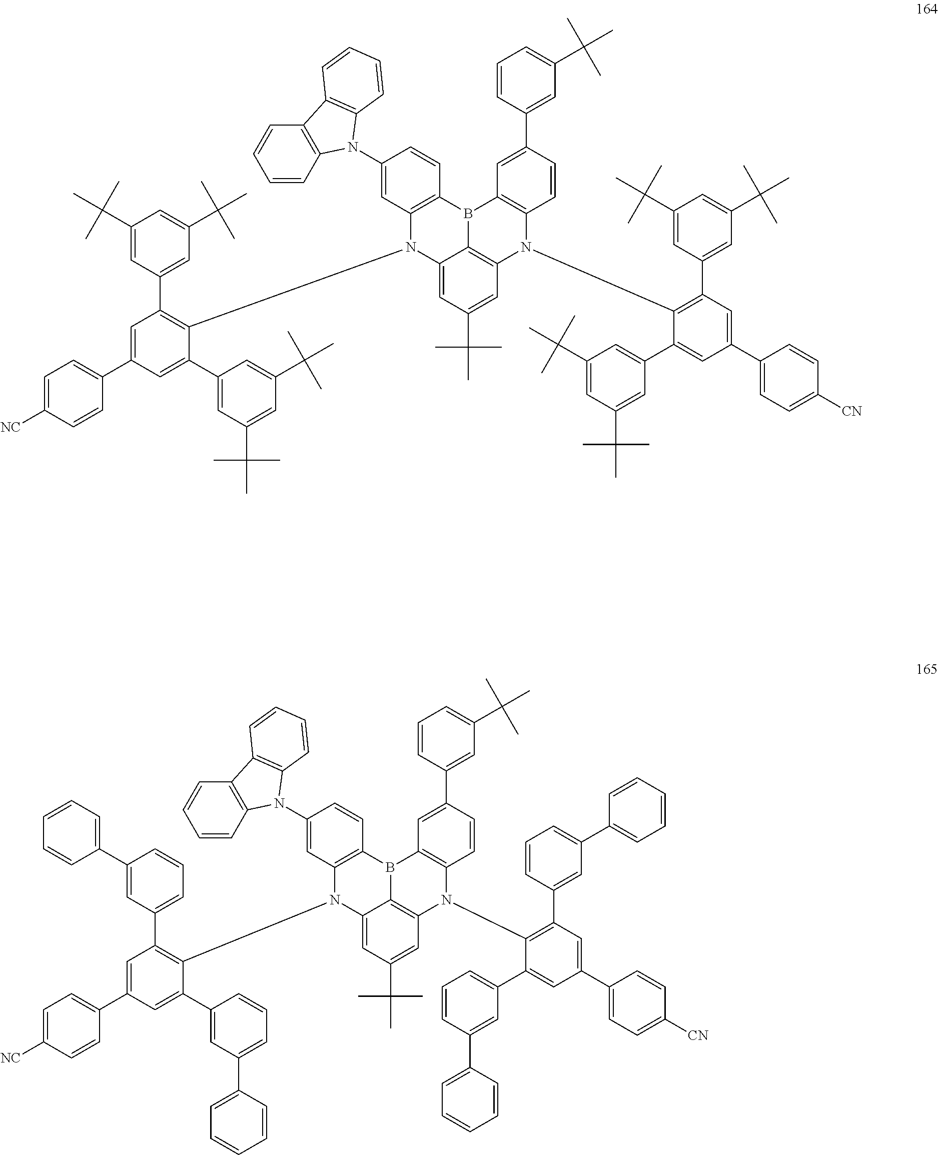 [SMILES: CC(C)(C)c1cccc(-c2ccc3c(c2)B2c4ccc(-n5c6ccccc6c6ccccc65)cc4N(c4c(-c5cc(C(C)(C)C)cc(C(C)(C)C)c5)cc(-c5ccc(C#N)cc5)cc4-c4cc(C(C)(C)C)cc(C(C)(C)C)c4)c4cc(C(C)(C)C)cc(c42)N3c2c(-c3cc(C(C)(C)C)cc(C(C)(C)C)c3)cc(-c3ccc(C#N)cc3)cc2-c2cc(C(C)(C)C)cc(C(C)(C)C)c2)c1 ; CC(C)(C)c1cccc(-c2ccc3c(c2)B2c4ccc(-n5c6ccccc6c6ccccc65)cc4N(c4c(-c5cccc(-c6ccccc6)c5)cc(-c5ccc(C#N)cc5)cc4-c4cccc(-c5ccccc5)c4)c4cc(C(C)(C)C)cc(c42)N3c2c(-c3cccc(-c4ccccc4)c3)cc(-c3ccc(C#N)cc3)cc2-c2cccc(-c3ccccc3)c2)c1]

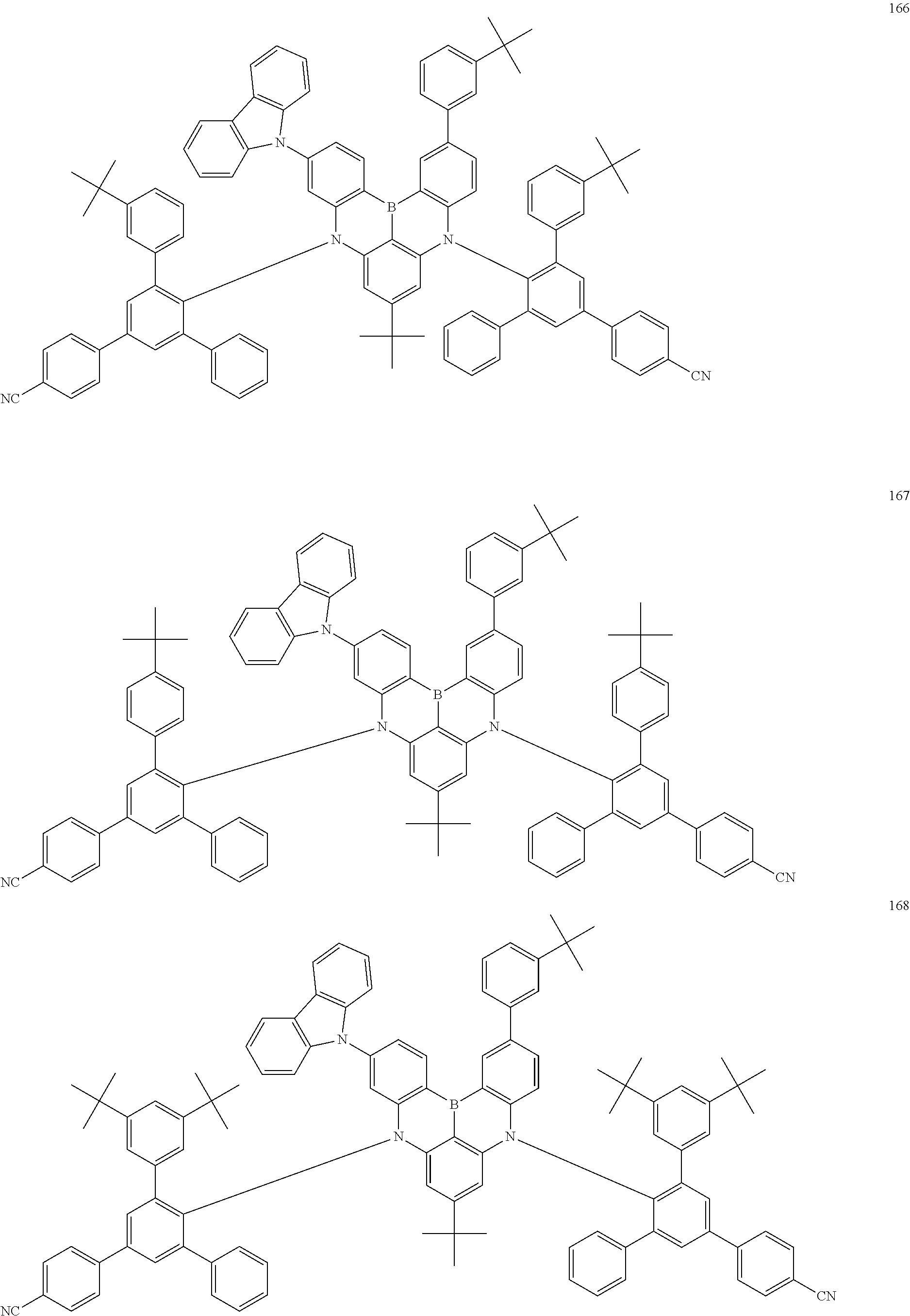

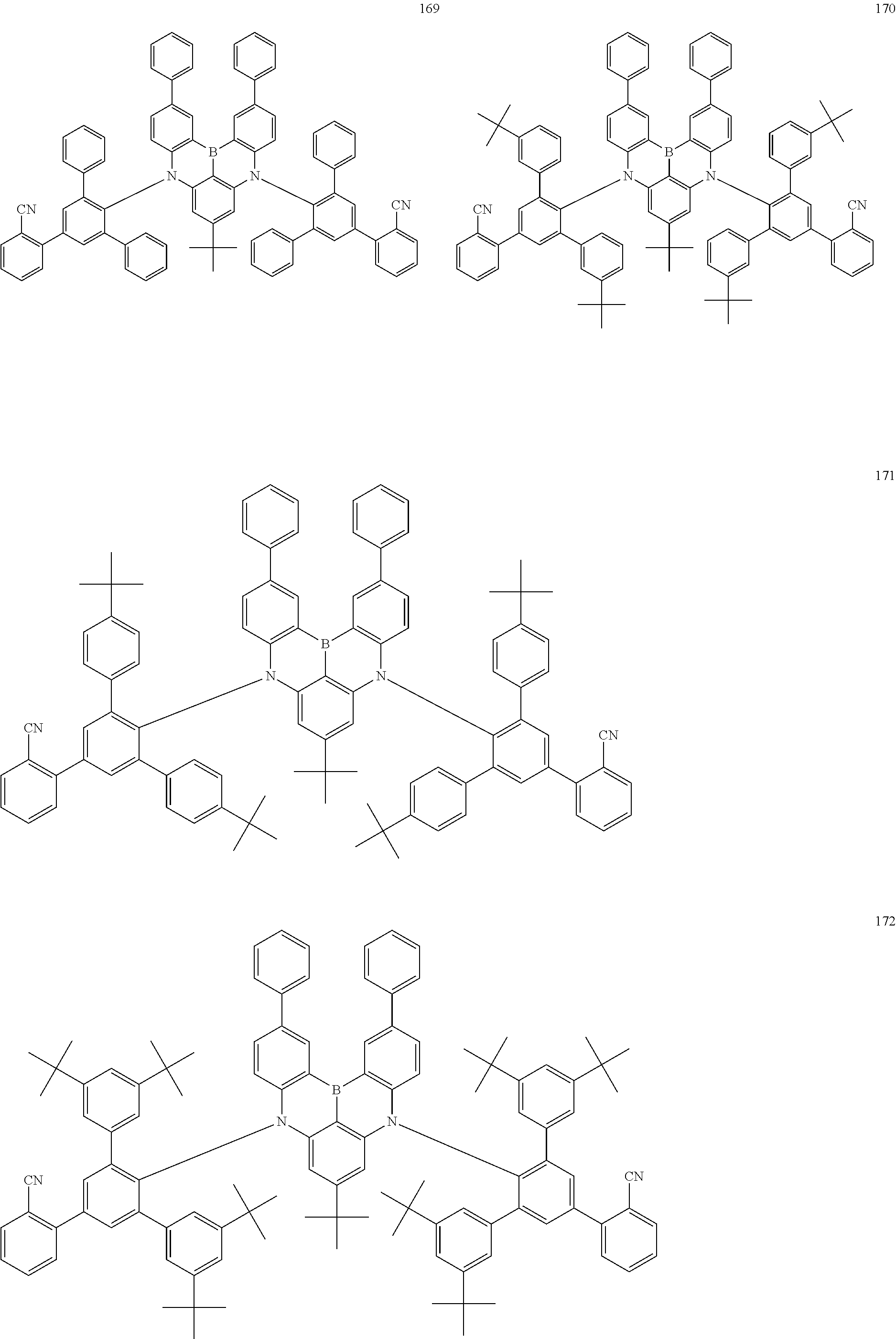

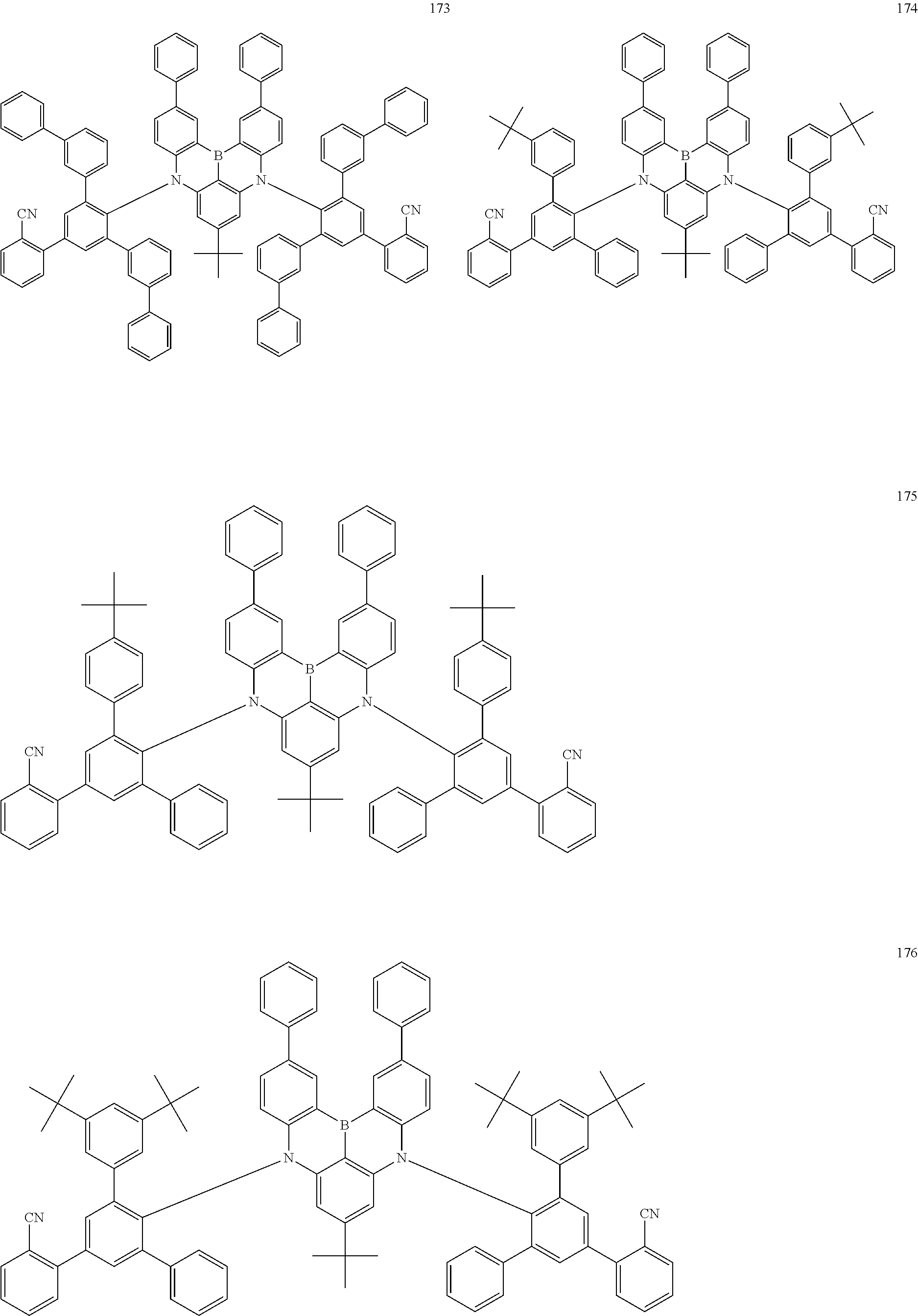

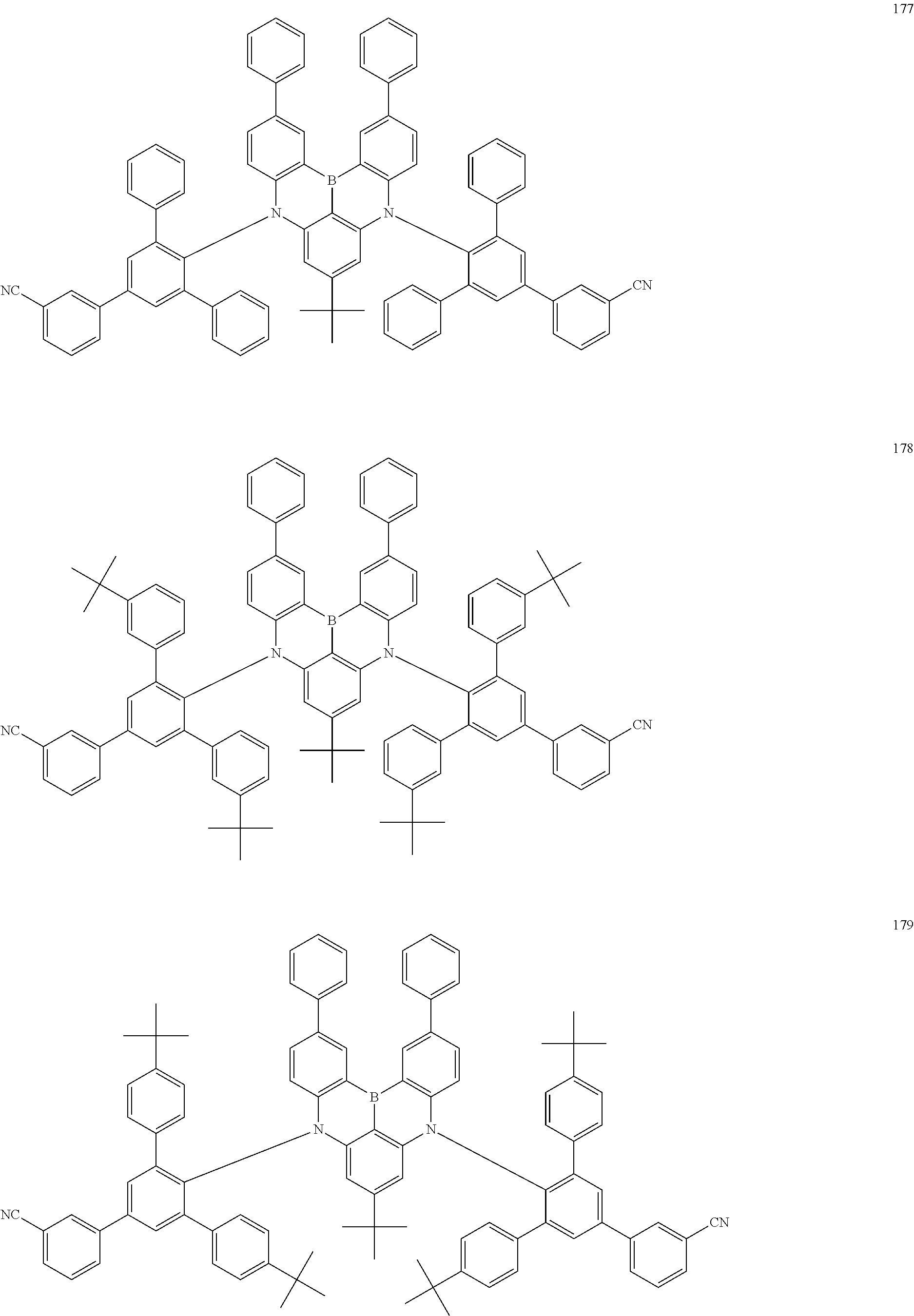

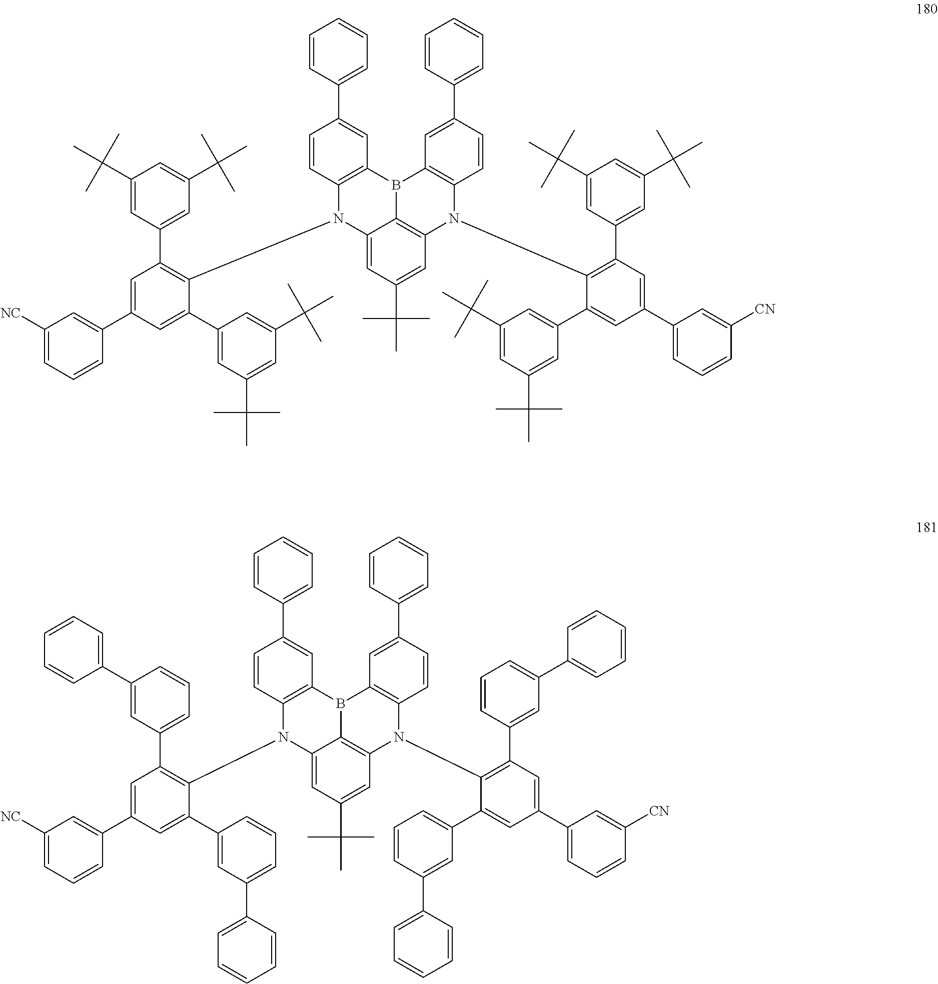 [SMILES: CC(C)(C)c1cc(-c2cc(-c3cccc(C#N)c3)cc(-c3cc(C(C)(C)C)cc(C(C)(C)C)c3)c2N2c3ccc(-c4ccccc4)cc3B3c4cc(-c5ccccc5)ccc4N(c4c(-c5cc(C(C)(C)C)cc(C(C)(C)C)c5)cc(-c5cccc(C#N)c5)cc4-c4cc(C(C)(C)C)cc(C(C)(C)C)c4)c4cc(C(C)(C)C)cc2c43)cc(C(C)(C)C)c1 ; CC(C)(C)c1cc2c3c(c1)N(c1c(-c4cccc(-c5ccccc5)c4)cc(-c4cccc(C#N)c4)cc1-c1cccc(-c4ccccc4)c1)c1ccc(-c4ccccc4)cc1B3c1cc(-c3ccccc3)ccc1N2c1c(-c2cccc(-c3ccccc3)c2)cc(-c2cccc(C#N)c2)cc1-c1cccc(-c2ccccc2)c1]

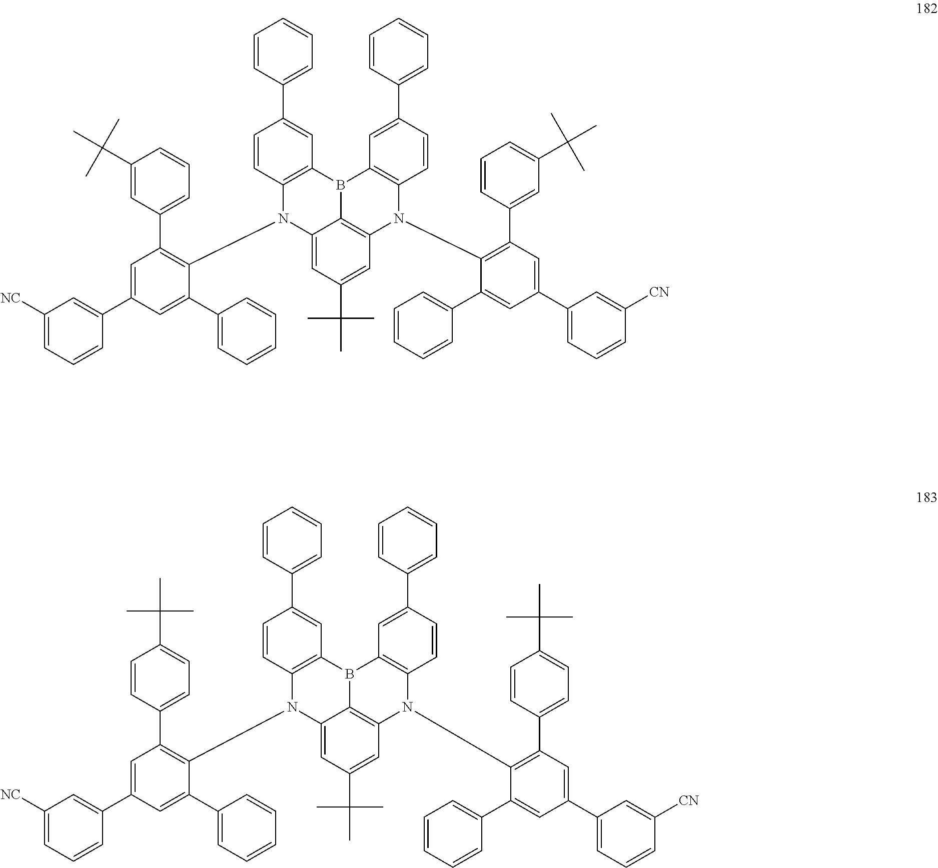 [SMILES: CC(C)(C)c1cccc(-c2cc(-c3cccc(C#N)c3)cc(-c3ccccc3)c2N2c3ccc(-c4ccccc4)cc3B3c4cc(-c5ccccc5)ccc4N(c4c(-c5ccccc5)cc(-c5cccc(C#N)c5)cc4-c4cccc(C(C)(C)C)c4)c4cc(C(C)(C)C)cc2c43)c1 ; CC(C)(C)c1ccc(-c2cc(-c3cccc(C#N)c3)cc(-c3ccccc3)c2N2c3ccc(-c4ccccc4)cc3B3c4cc(-c5ccccc5)ccc4N(c4c(-c5ccccc5)cc(-c5cccc(C#N)c5)cc4-c4ccc(C(C)(C)C)cc4)c4cc(C(C)(C)C)cc2c43)cc1]

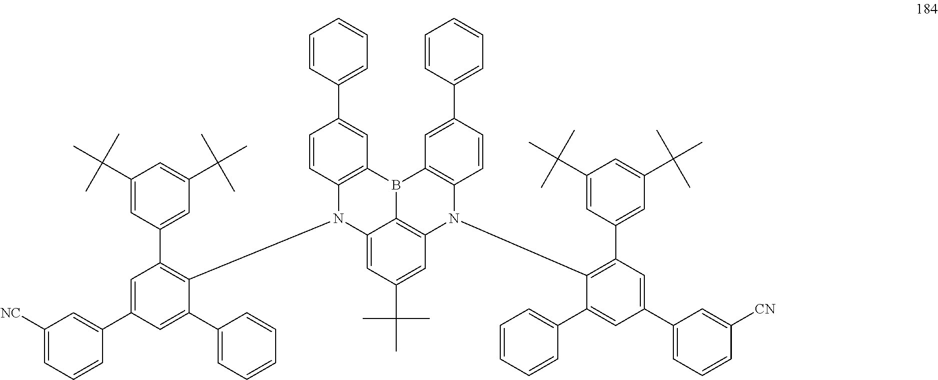 [SMILES: CC(C)(C)c1cc(-c2cc(-c3cccc(C#N)c3)cc(-c3ccccc3)c2N2c3ccc(-c4ccccc4)cc3B3c4cc(-c5ccccc5)ccc4N(c4c(-c5ccccc5)cc(-c5cccc(C#N)c5)cc4-c4cc(C(C)(C)C)cc(C(C)(C)C)c4)c4cc(C(C)(C)C)cc2c43)cc(C(C)(C)C)c1]

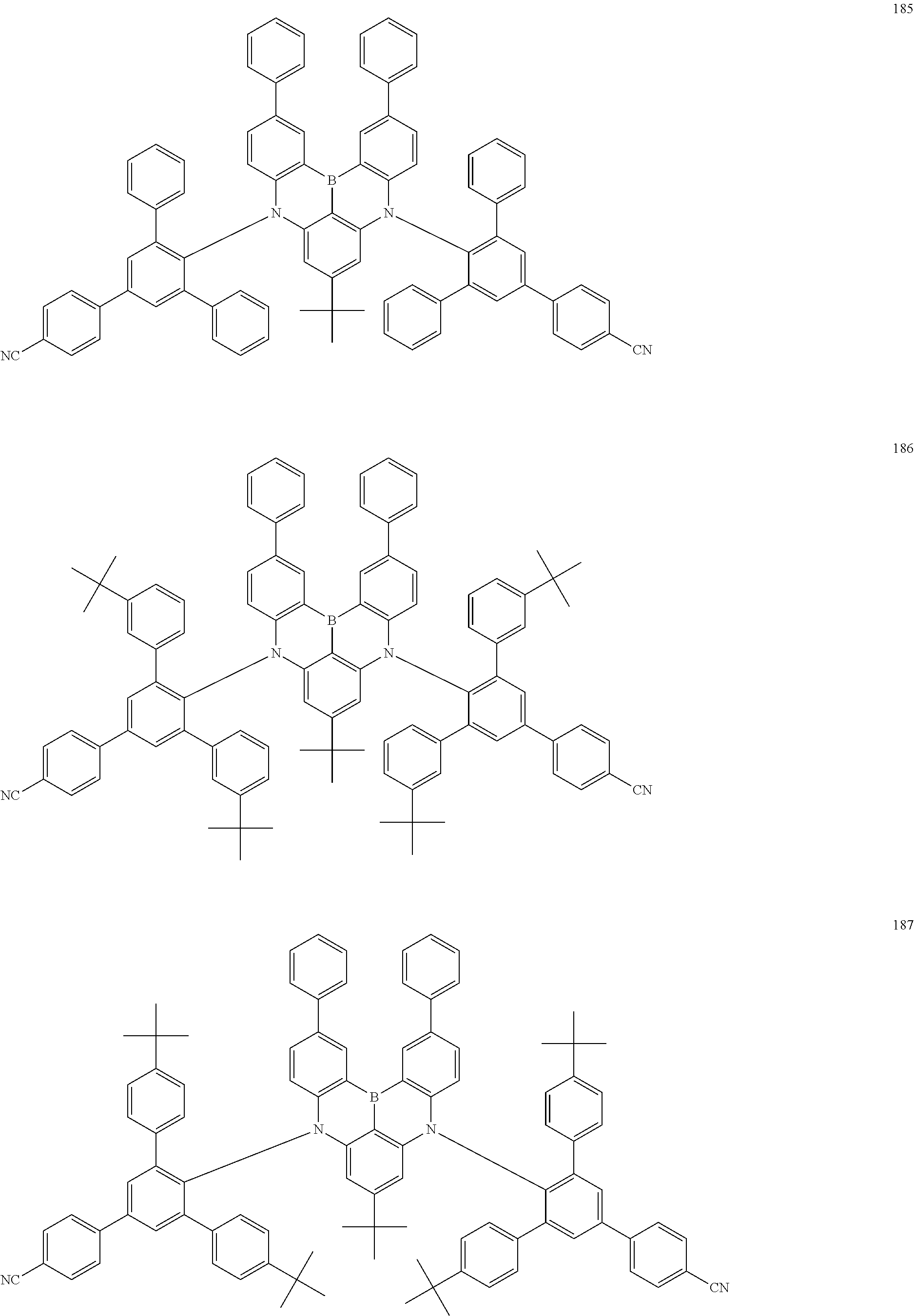

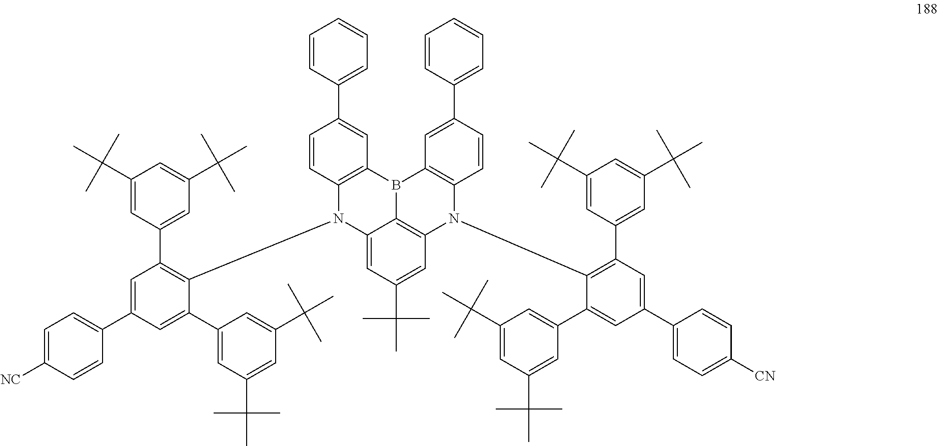 [SMILES: CC(C)(C)c1cc(-c2cc(-c3ccc(C#N)cc3)cc(-c3cc(C(C)(C)C)cc(C(C)(C)C)c3)c2N2c3ccc(-c4ccccc4)cc3B3c4cc(-c5ccccc5)ccc4N(c4c(-c5cc(C(C)(C)C)cc(C(C)(C)C)c5)cc(-c5ccc(C#N)cc5)cc4-c4cc(C(C)(C)C)cc(C(C)(C)C)c4)c4cc(C(C)(C)C)cc2c43)cc(C(C)(C)C)c1]

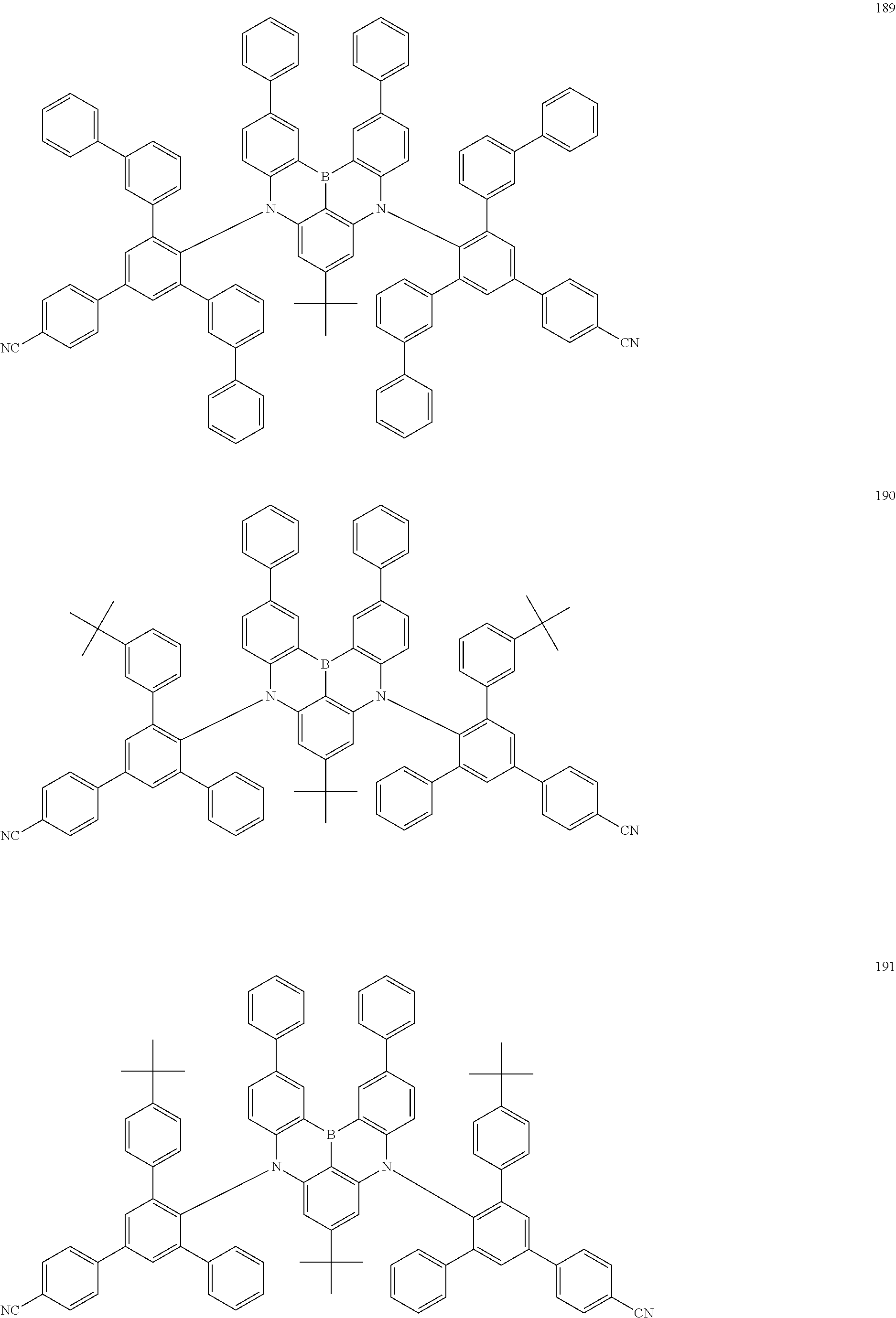

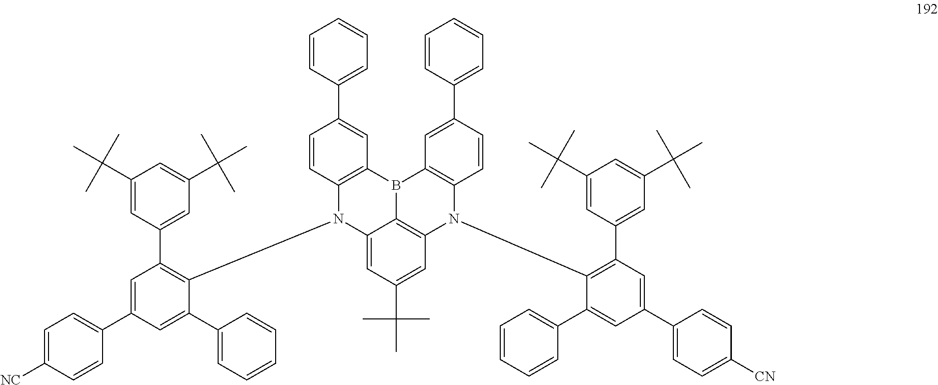 [SMILES: CC(C)(C)c1cc(-c2cc(-c3ccc(C#N)cc3)cc(-c3ccccc3)c2N2c3ccc(-c4ccccc4)cc3B3c4cc(-c5ccccc5)ccc4N(c4c(-c5ccccc5)cc(-c5ccc(C#N)cc5)cc4-c4cc(C(C)(C)C)cc(C(C)(C)C)c4)c4cc(C(C)(C)C)cc2c43)cc(C(C)(C)C)c1]

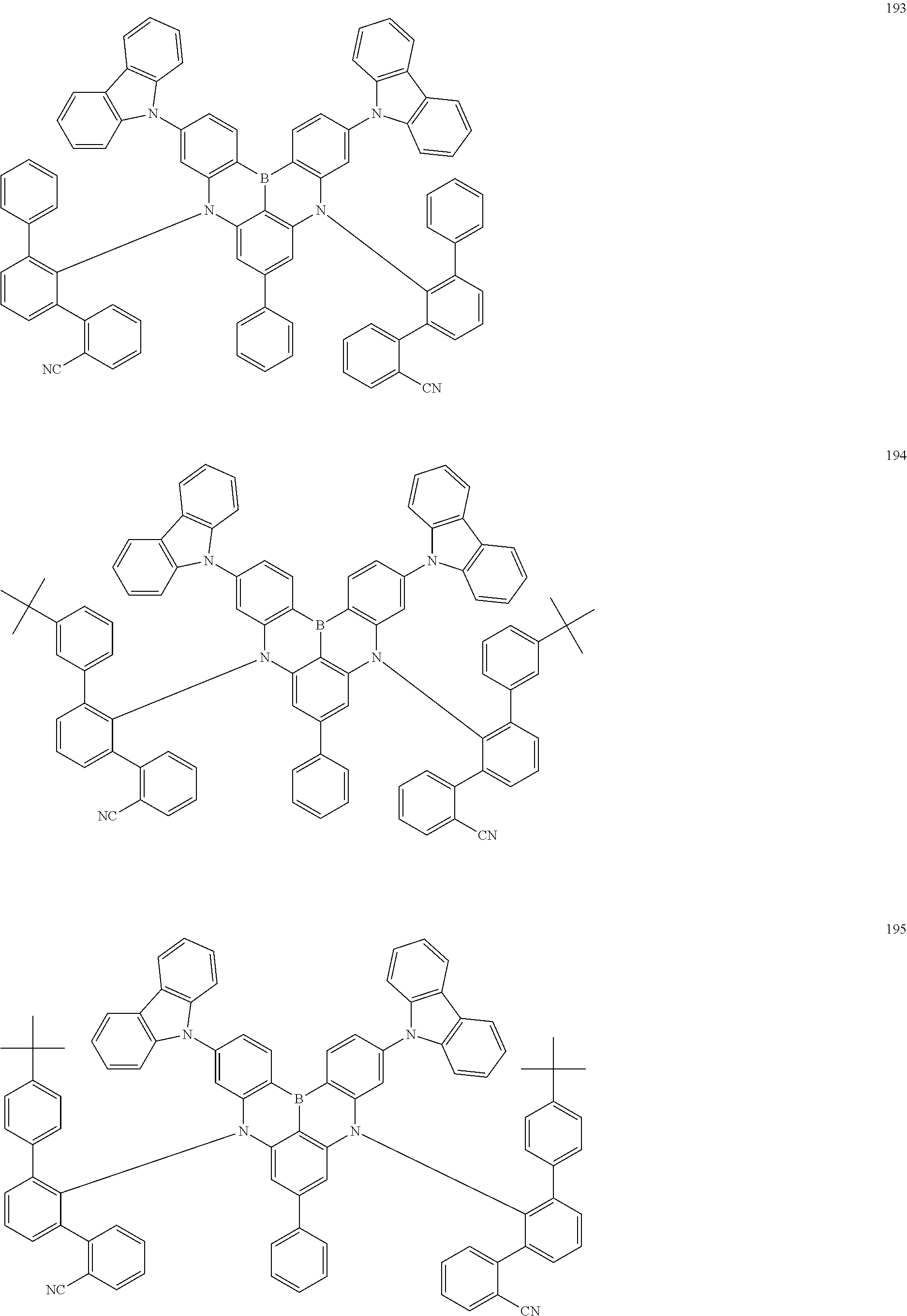

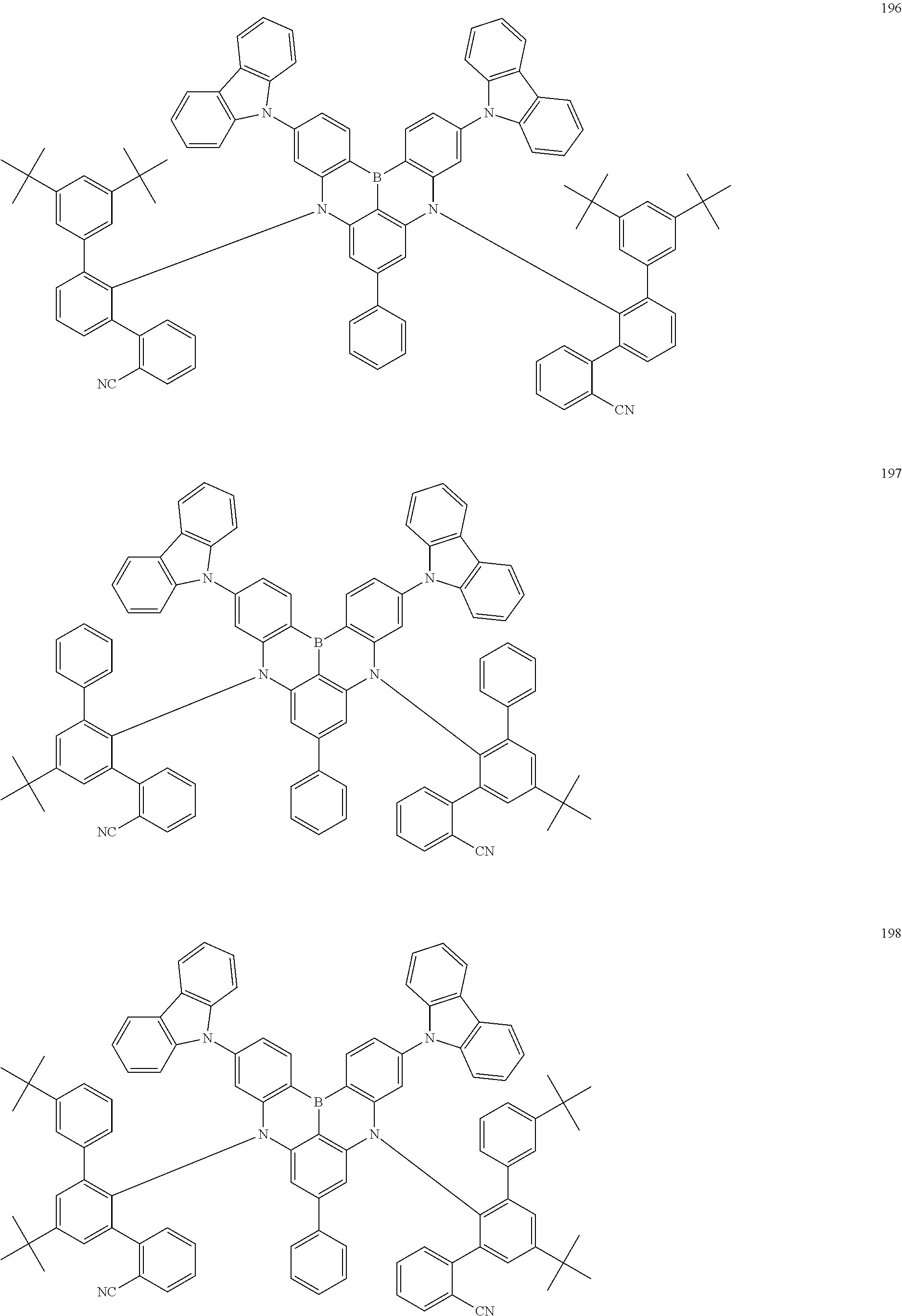

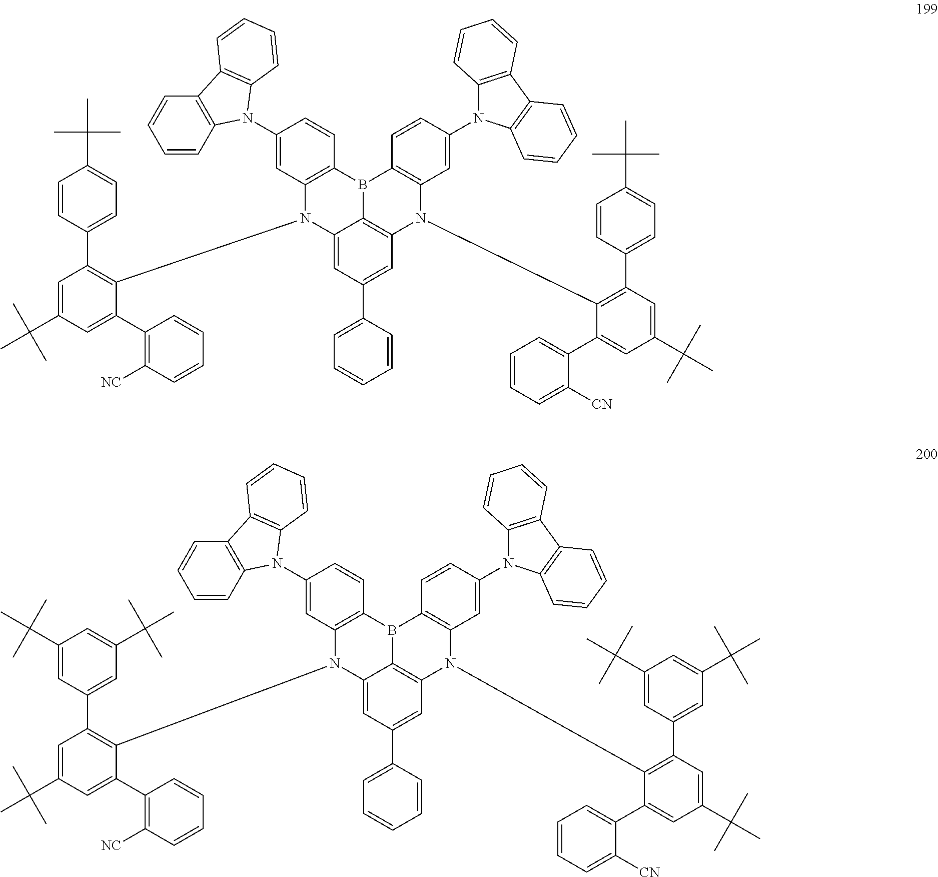

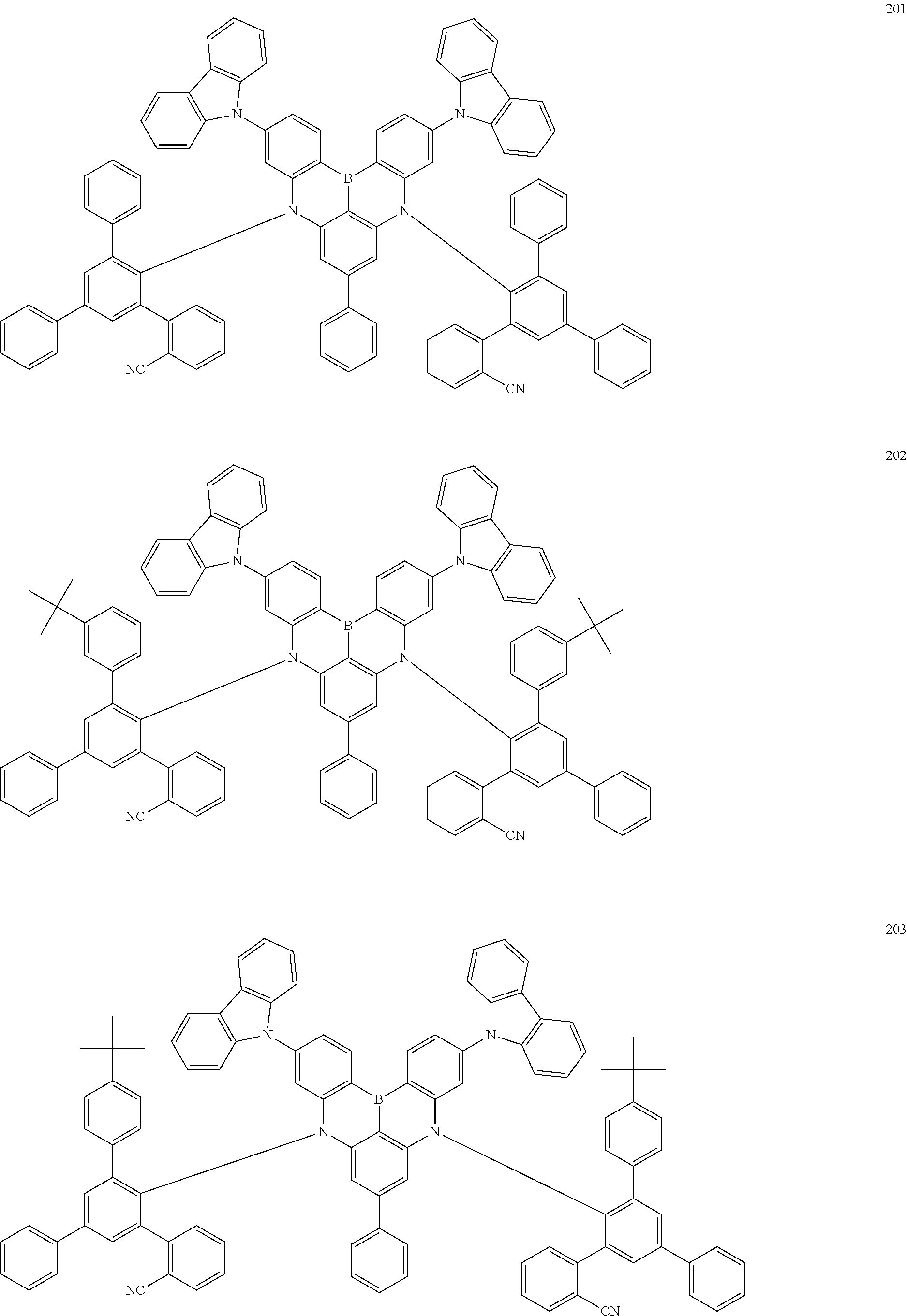

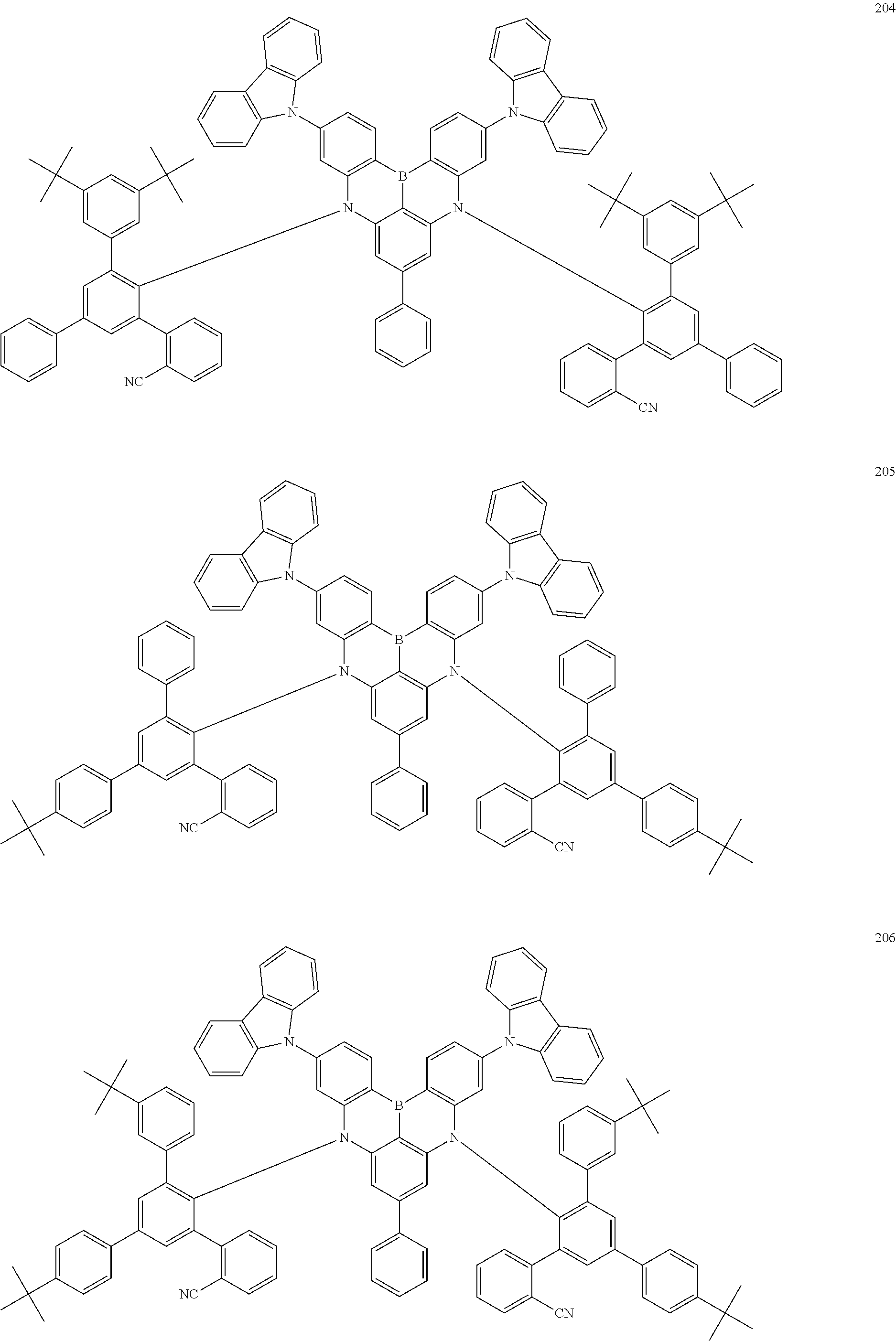

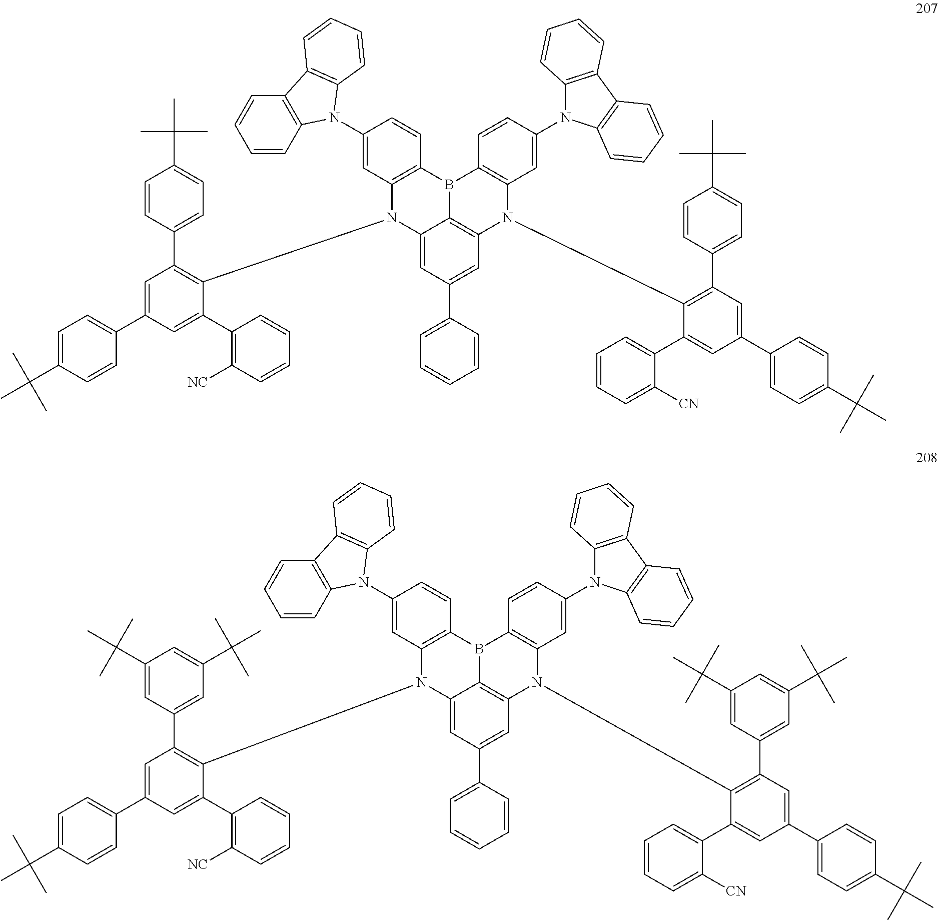

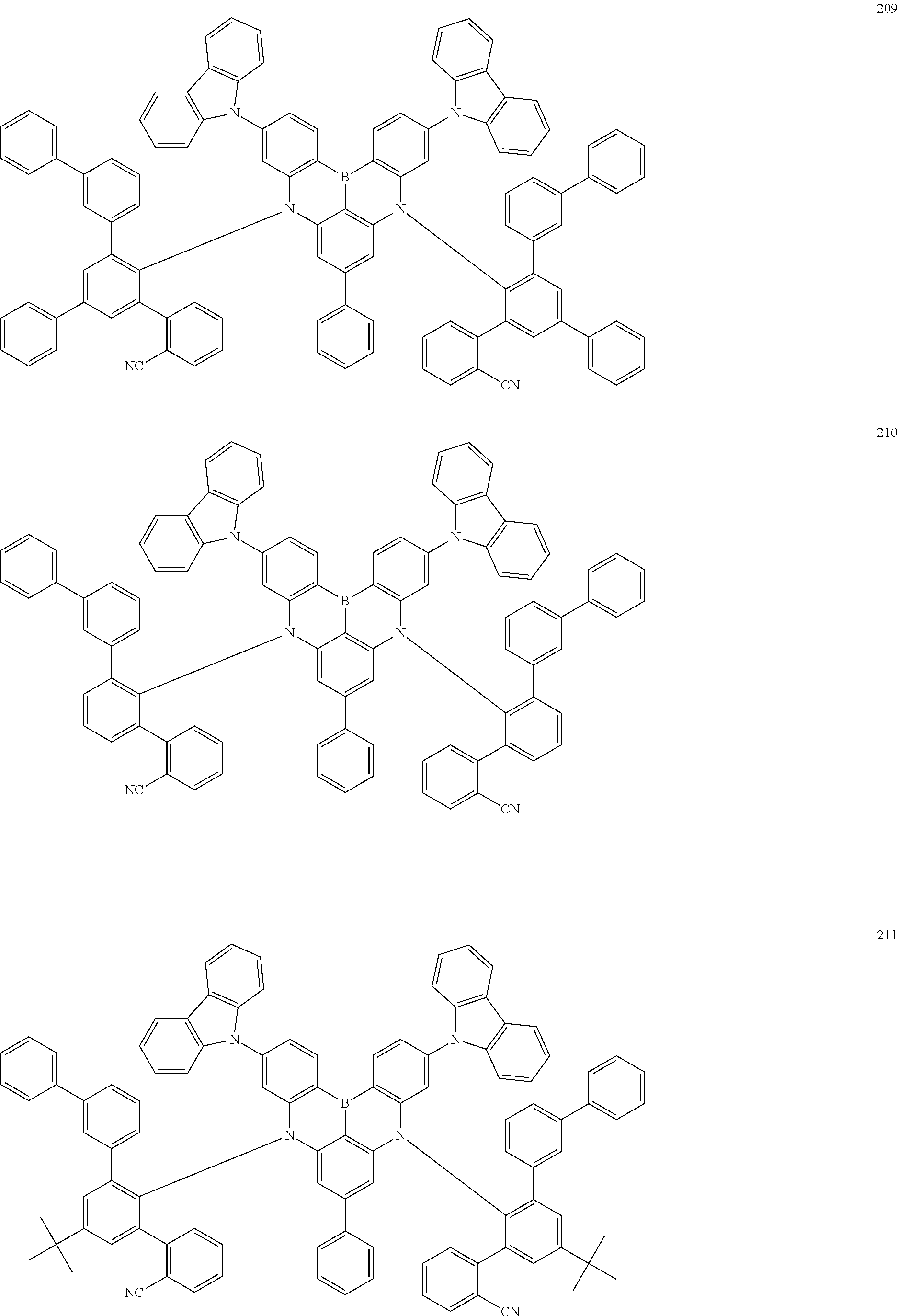

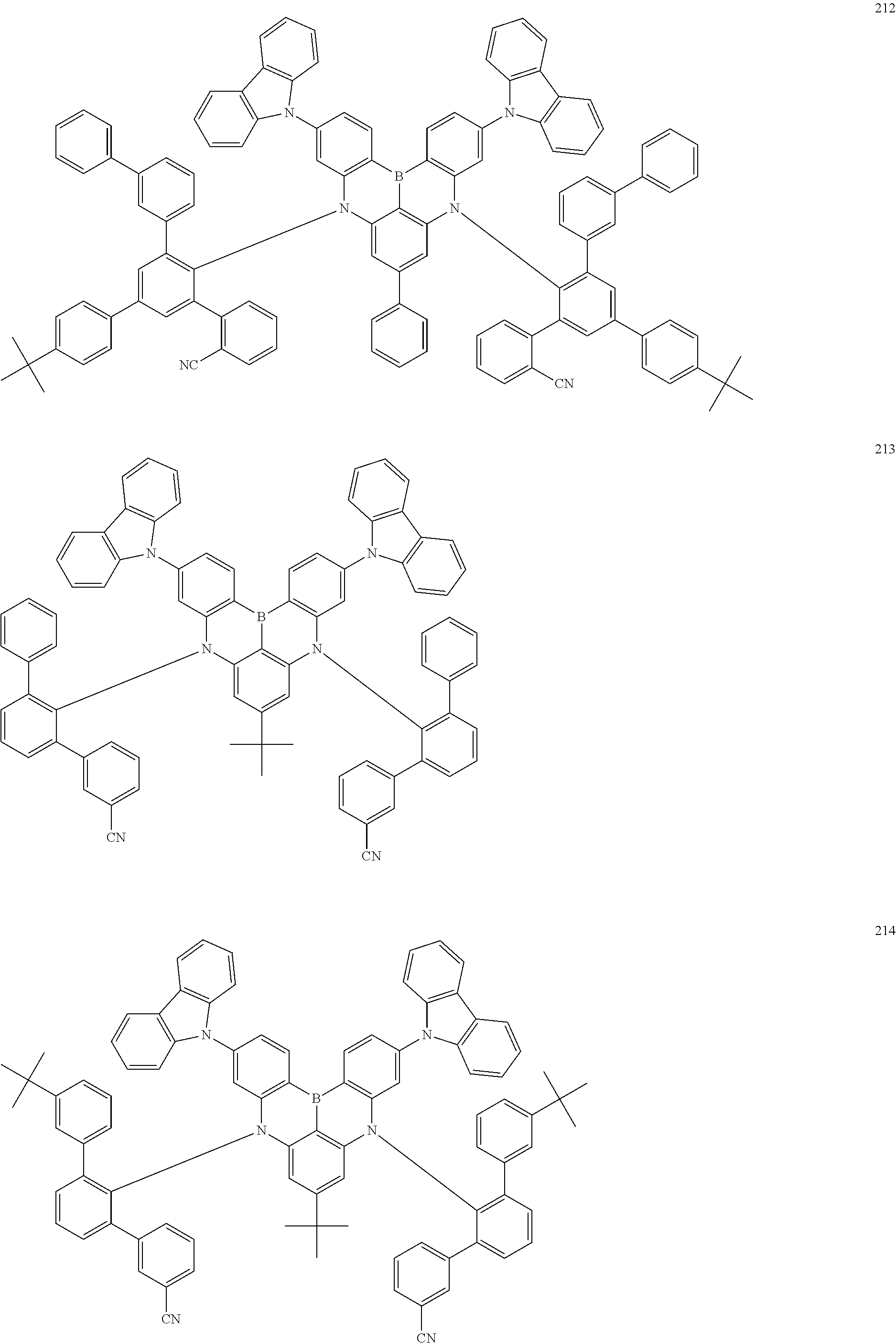

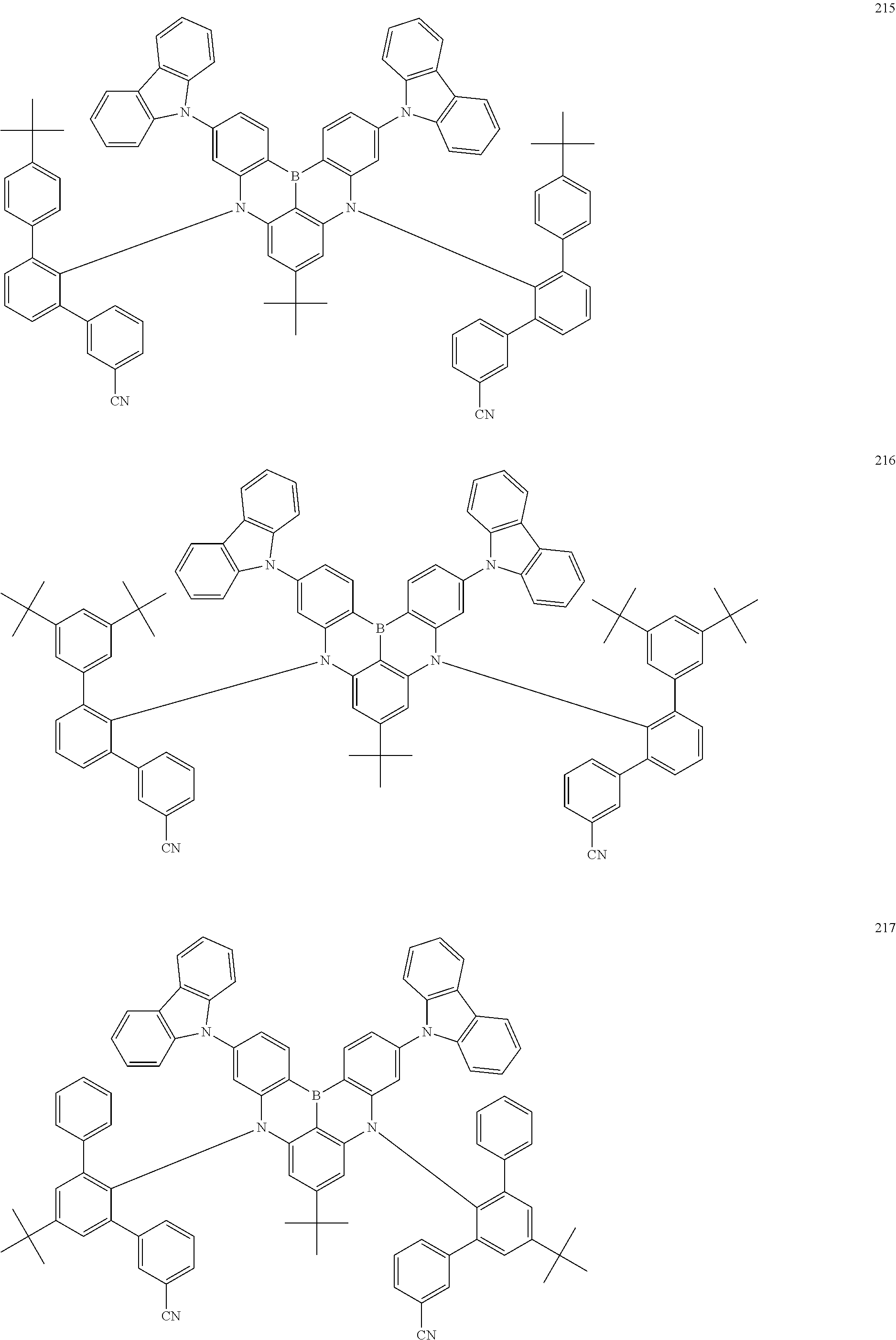

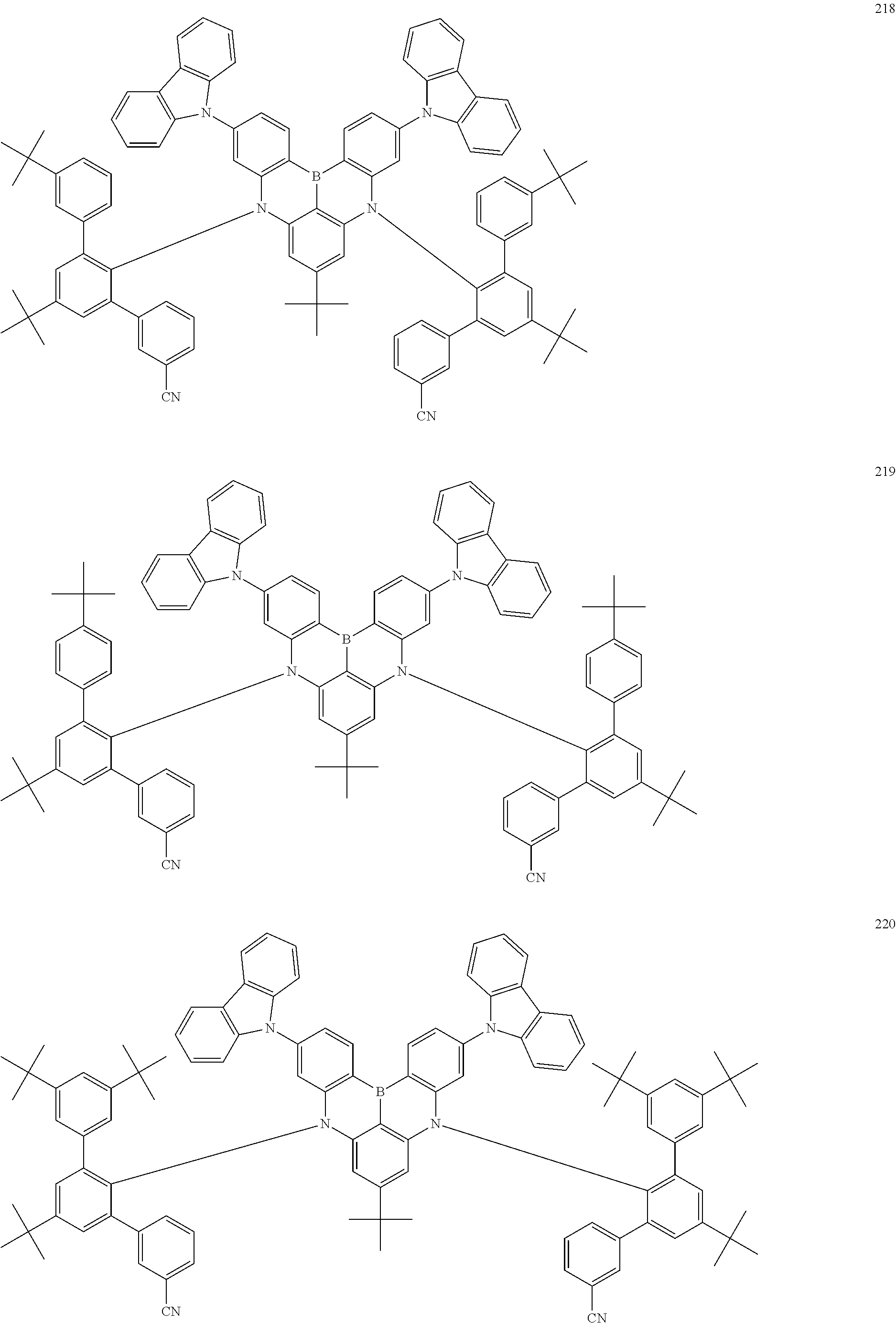

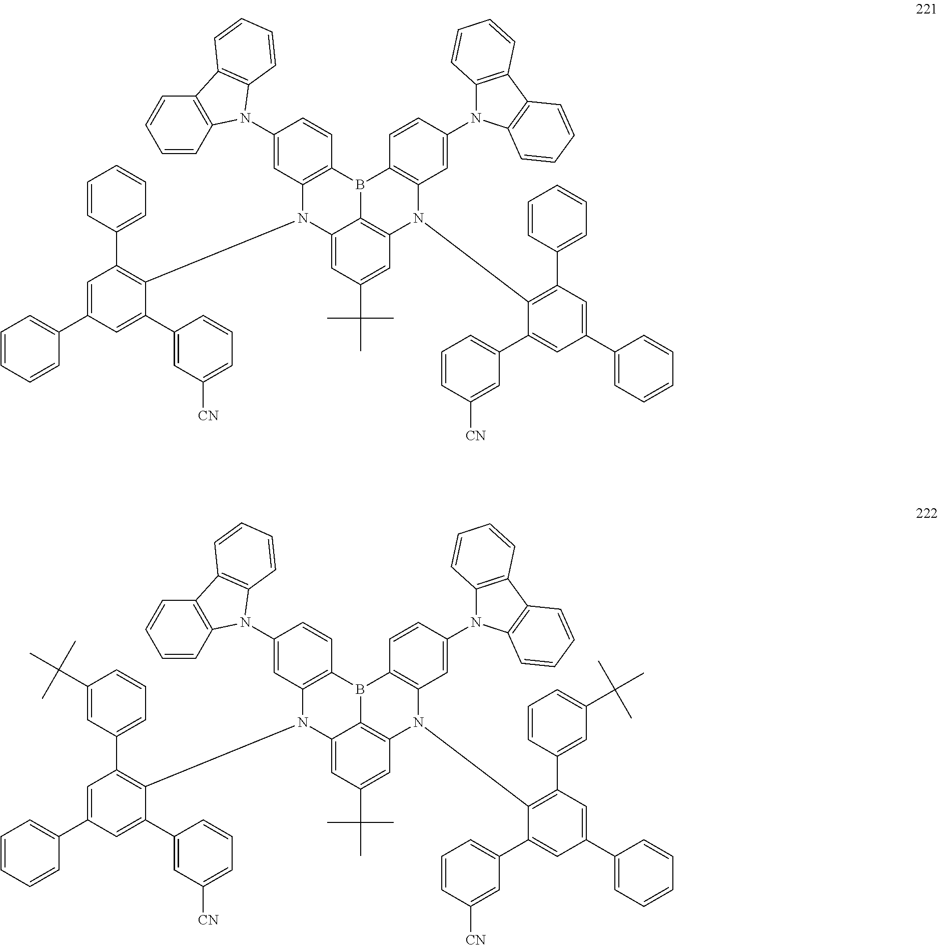 [SMILES: CC(C)(C)c1cc2c3c(c1)N(c1c(-c4ccccc4)cc(-c4ccccc4)cc1-c1cccc(C#N)c1)c1cc(-n4c5ccccc5c5ccccc54)ccc1B3c1ccc(-n3c4ccccc4c4ccccc43)cc1N2c1c(-c2ccccc2)cc(-c2ccccc2)cc1-c1cccc(C#N)c1 ; CC(C)(C)c1cccc(-c2cc(-c3ccccc3)cc(-c3cccc(C#N)c3)c2N2c3cc(-n4c5ccccc5c5ccccc54)ccc3B3c4ccc(-n5c6ccccc6c6ccccc65)cc4N(c4c(-c5cccc(C#N)c5)cc(-c5ccccc5)cc4-c4cccc(C(C)(C)C)c4)c4cc(C(C)(C)C)cc2c43)c1]

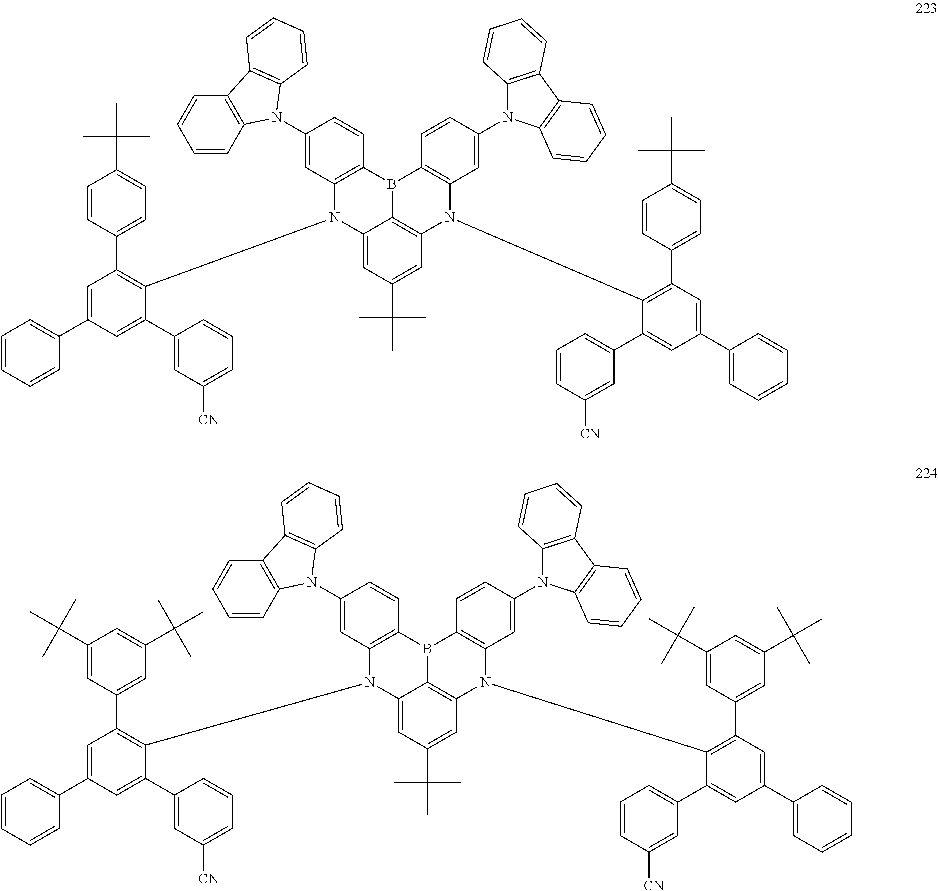 [SMILES: CC(C)(C)c1ccc(-c2cc(-c3ccccc3)cc(-c3cccc(C#N)c3)c2N2c3cc(-n4c5ccccc5c5ccccc54)ccc3B3c4ccc(-n5c6ccccc6c6ccccc65)cc4N(c4c(-c5ccc(C(C)(C)C)cc5)cc(-c5ccccc5)cc4-c4cccc(C#N)c4)c4cc(C(C)(C)C)cc2c43)cc1 ; CC(C)(C)c1cc(-c2cc(-c3ccccc3)cc(-c3cccc(C#N)c3)c2N2c3cc(-n4c5ccccc5c5ccccc54)ccc3B3c4ccc(-n5c6ccccc6c6ccccc65)cc4N(c4c(-c5cccc(C#N)c5)cc(-c5ccccc5)cc4-c4cc(C(C)(C)C)cc(C(C)(C)C)c4)c4cc(C(C)(C)C)cc2c43)cc(C(C)(C)C)c1]

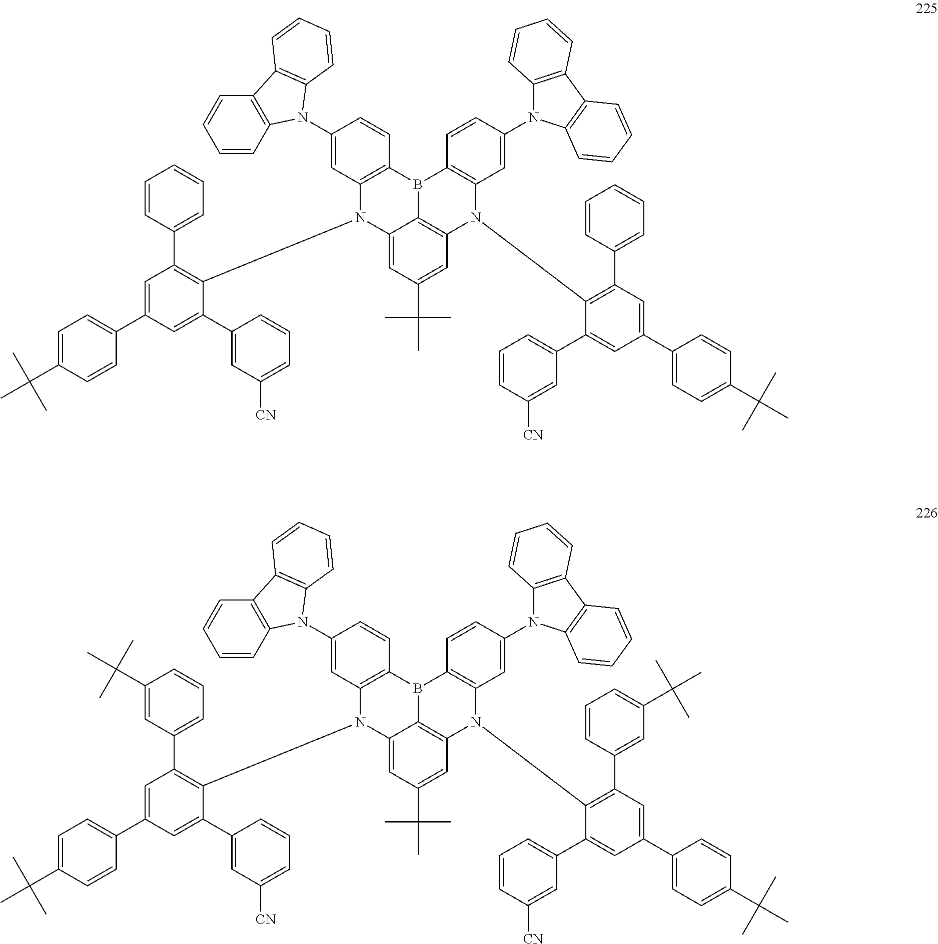

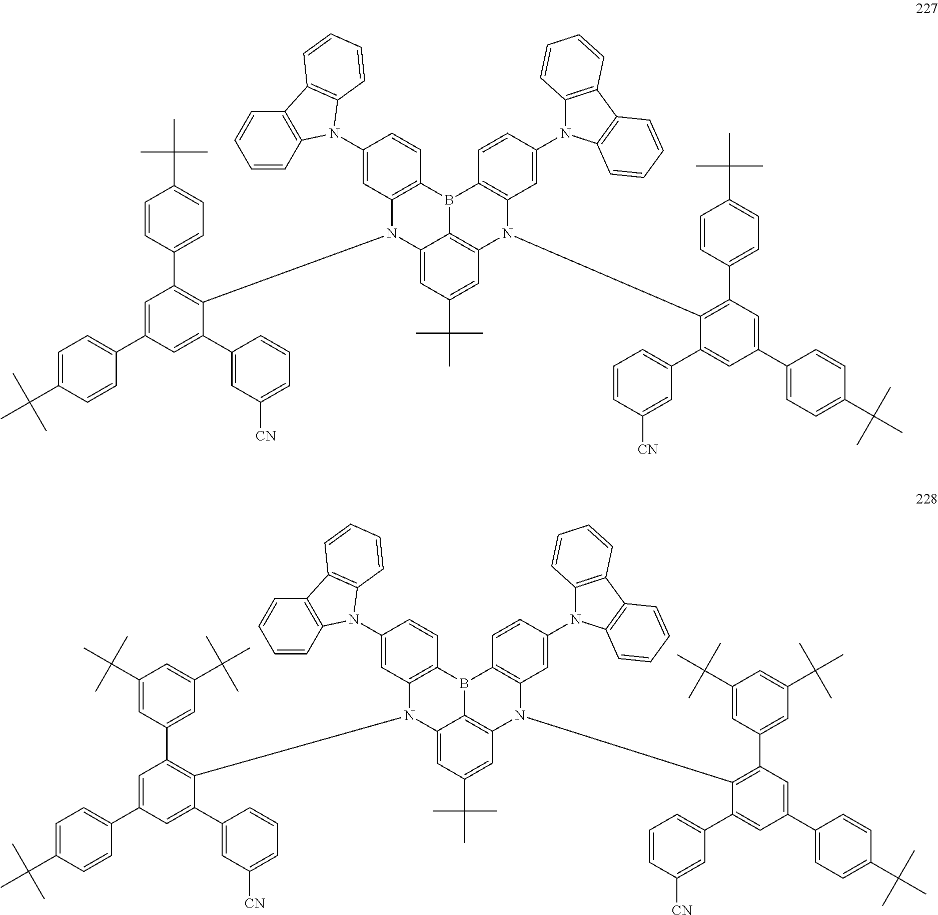

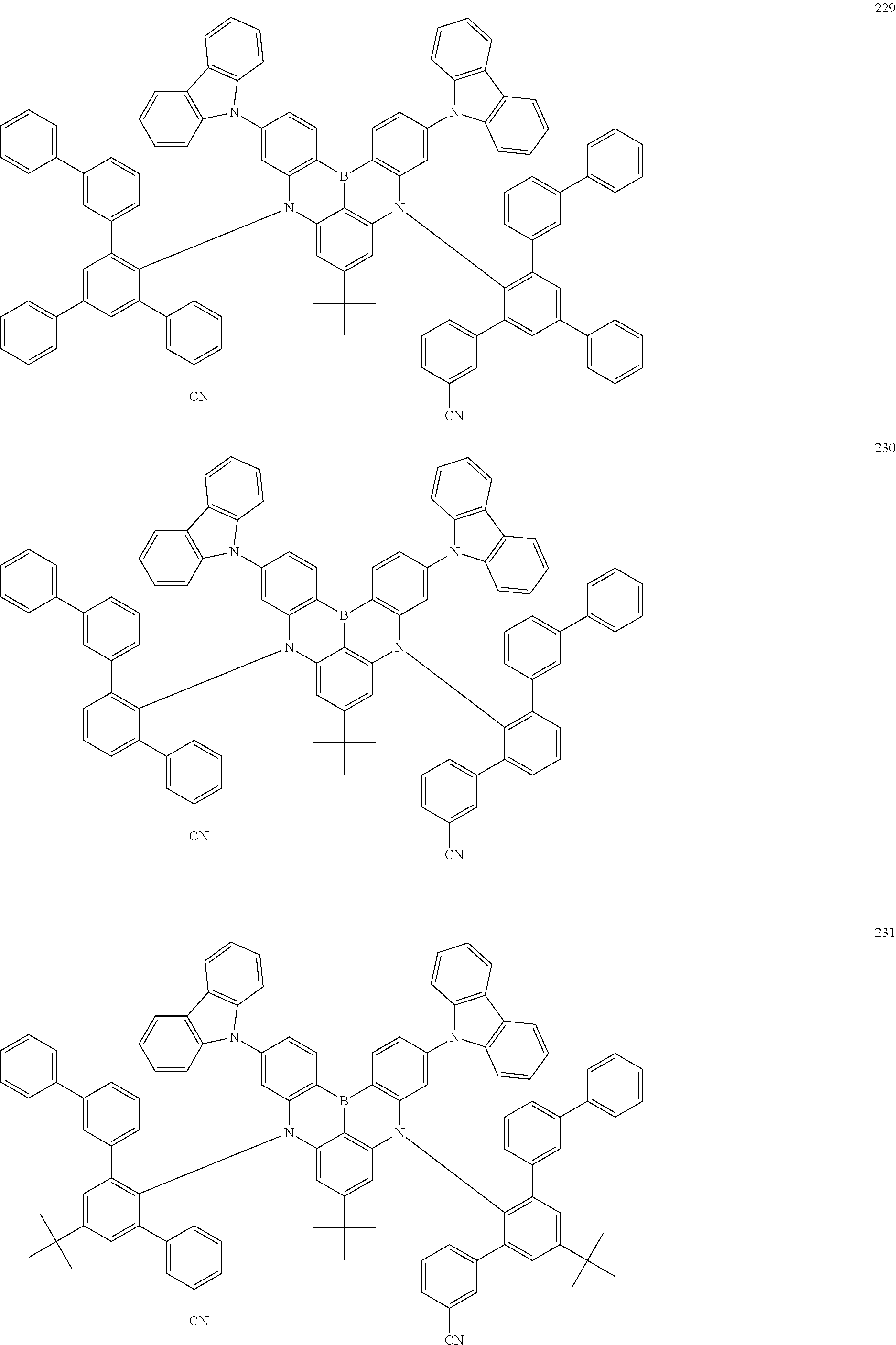

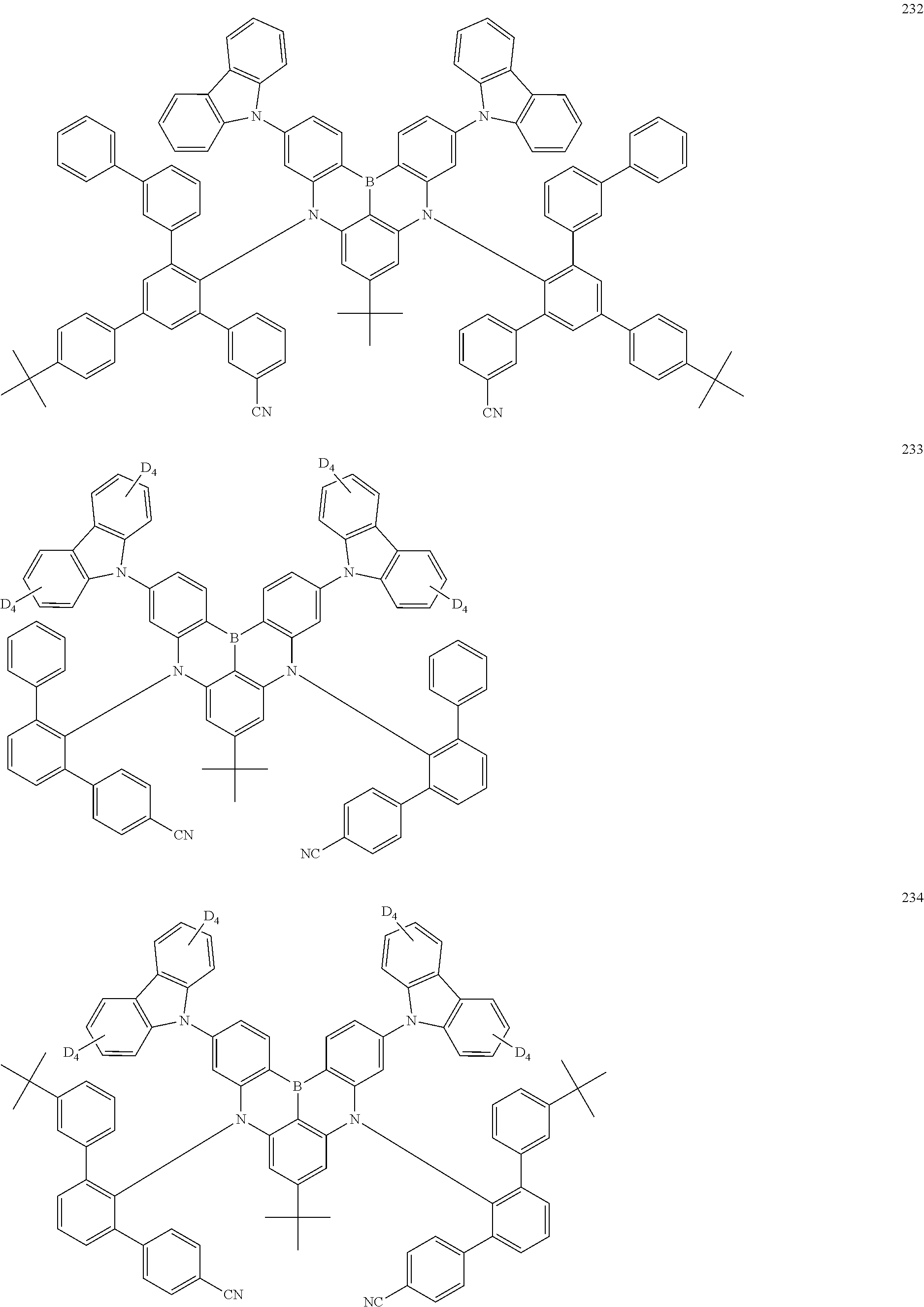

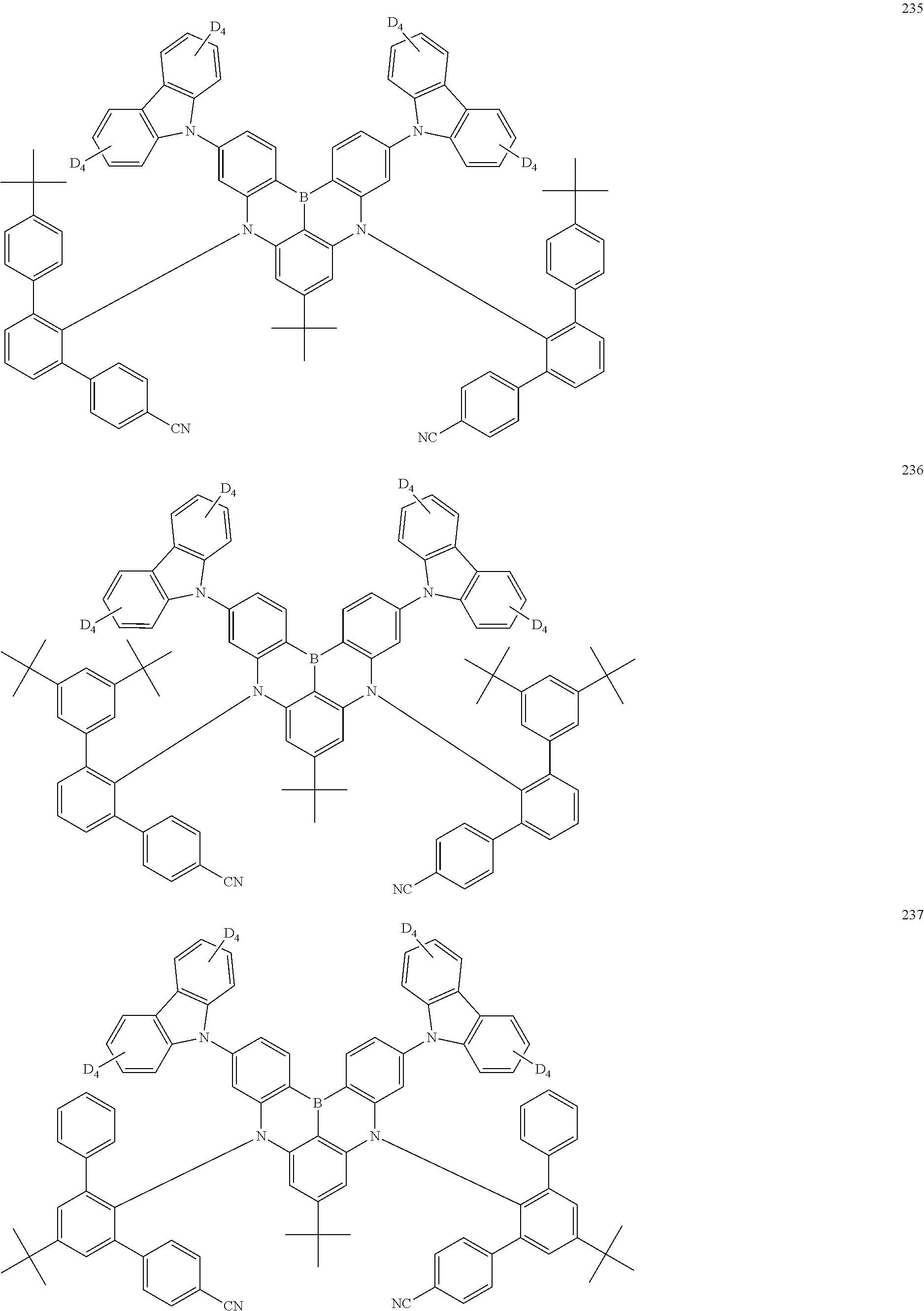

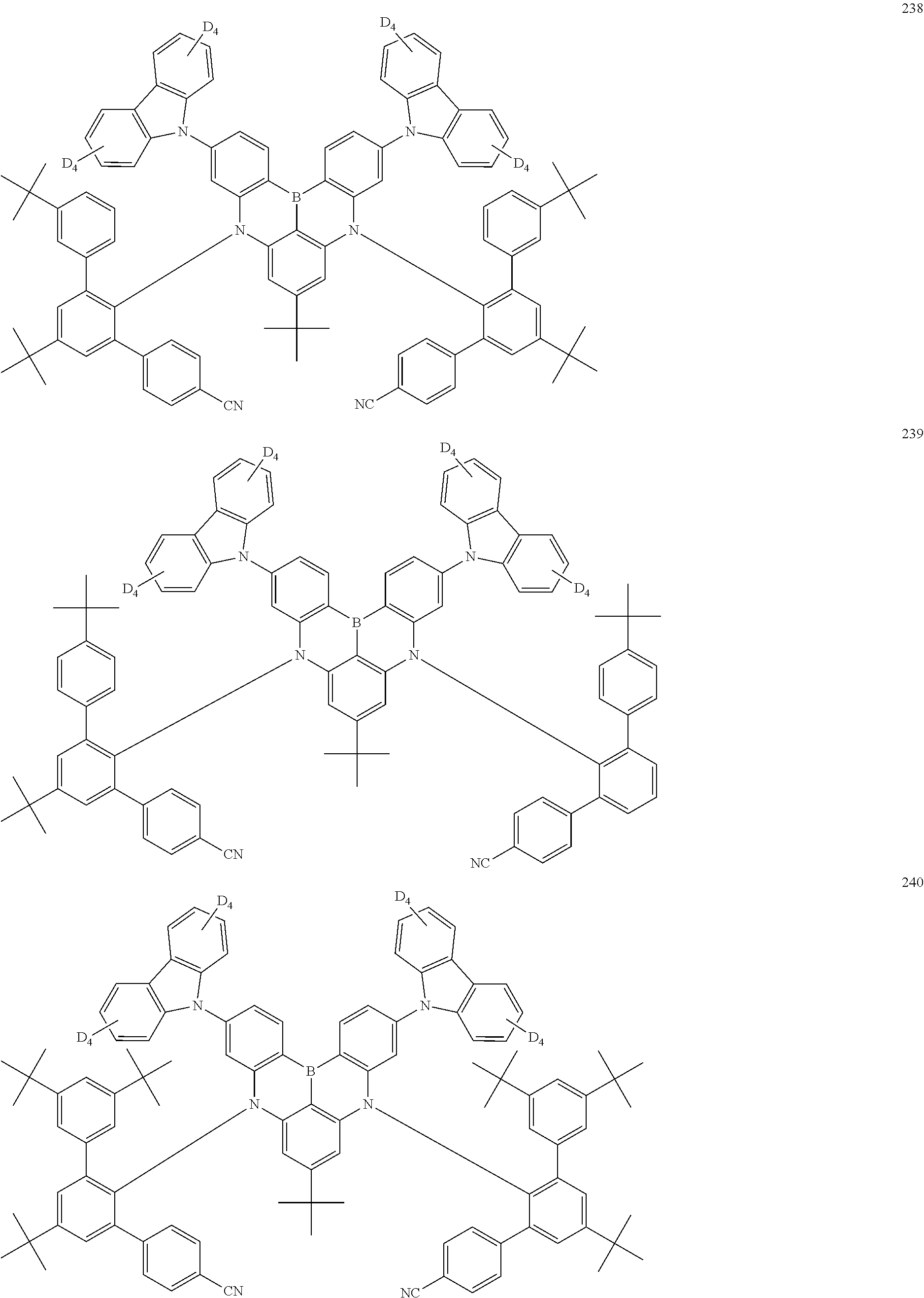

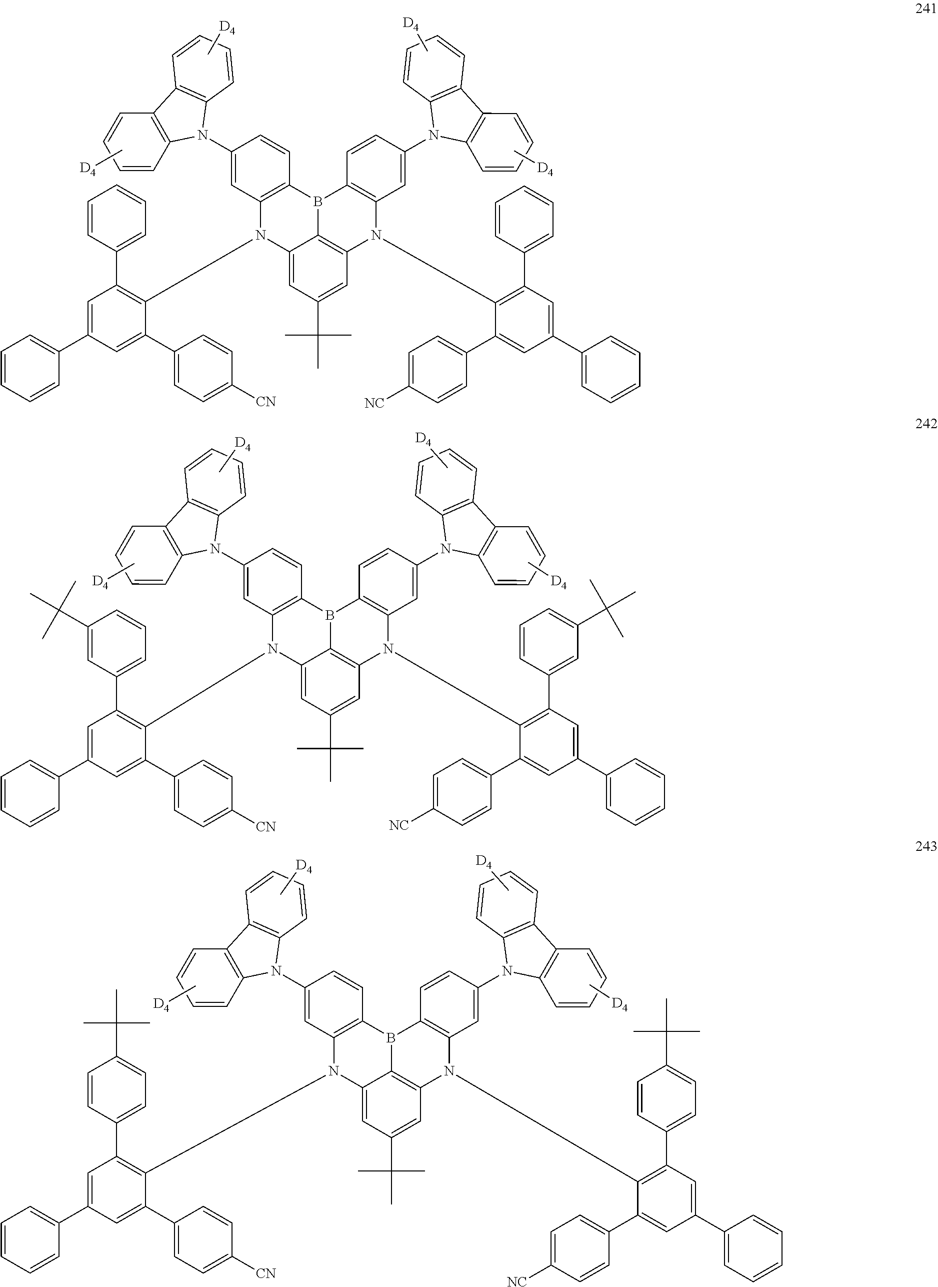

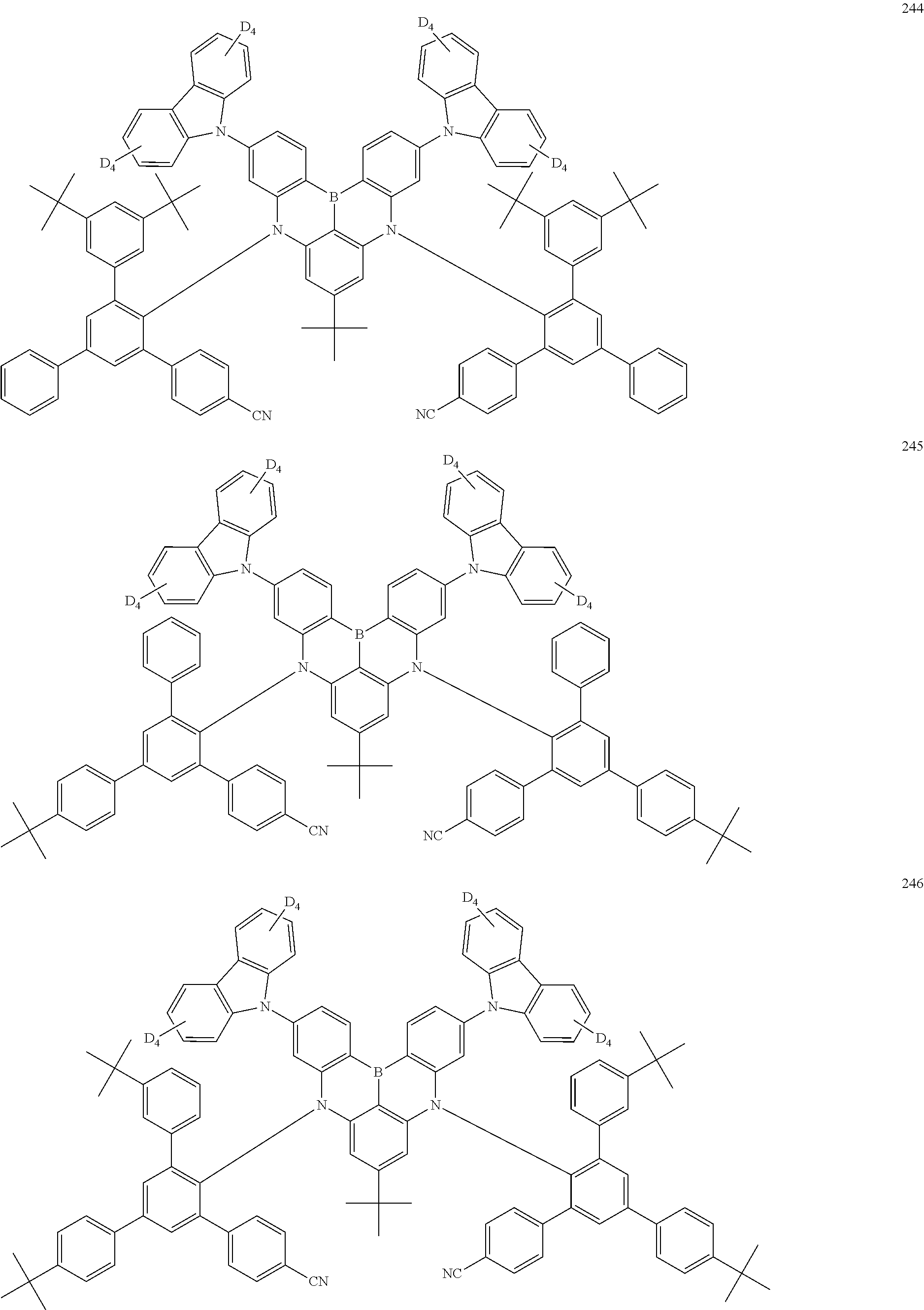

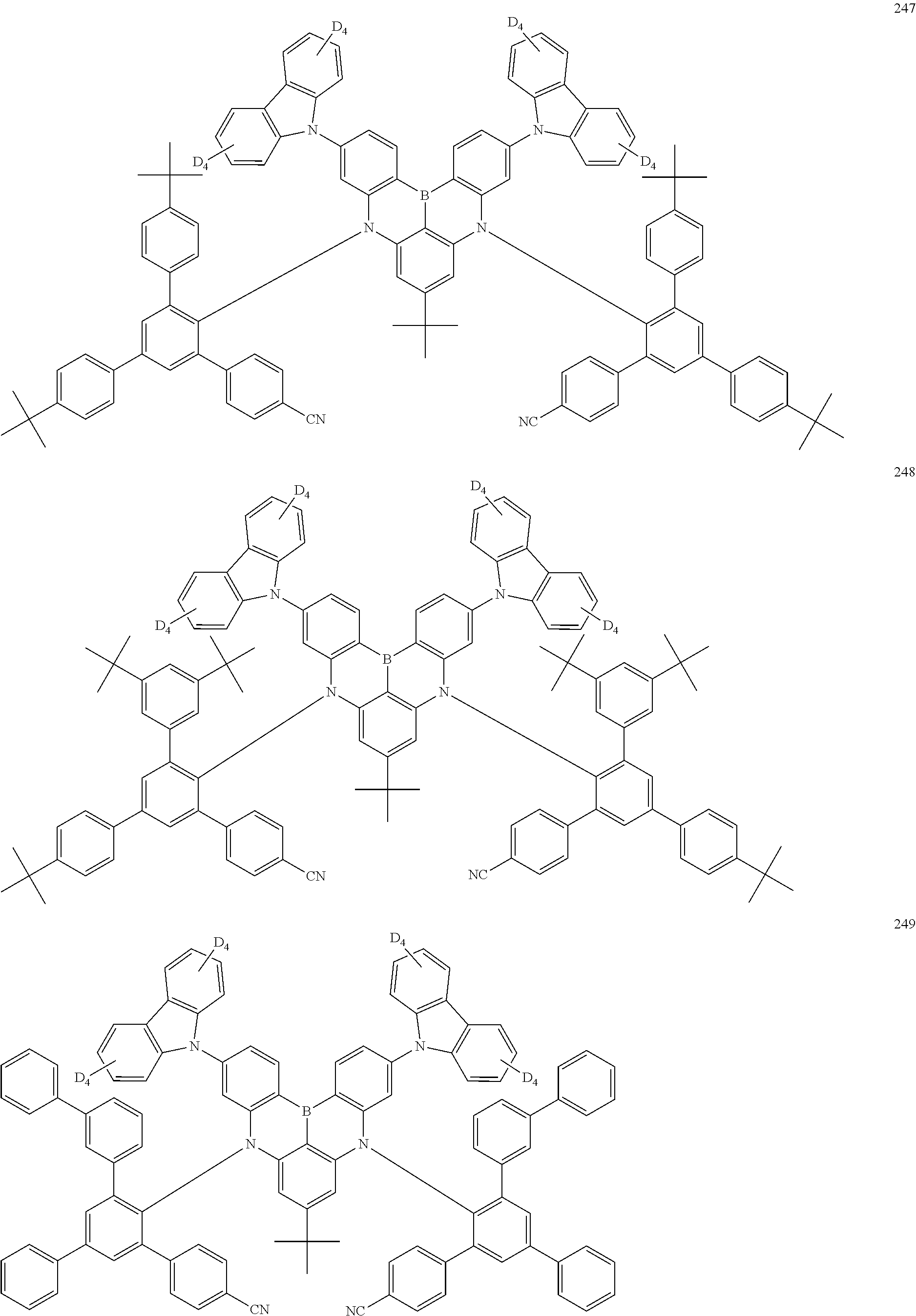

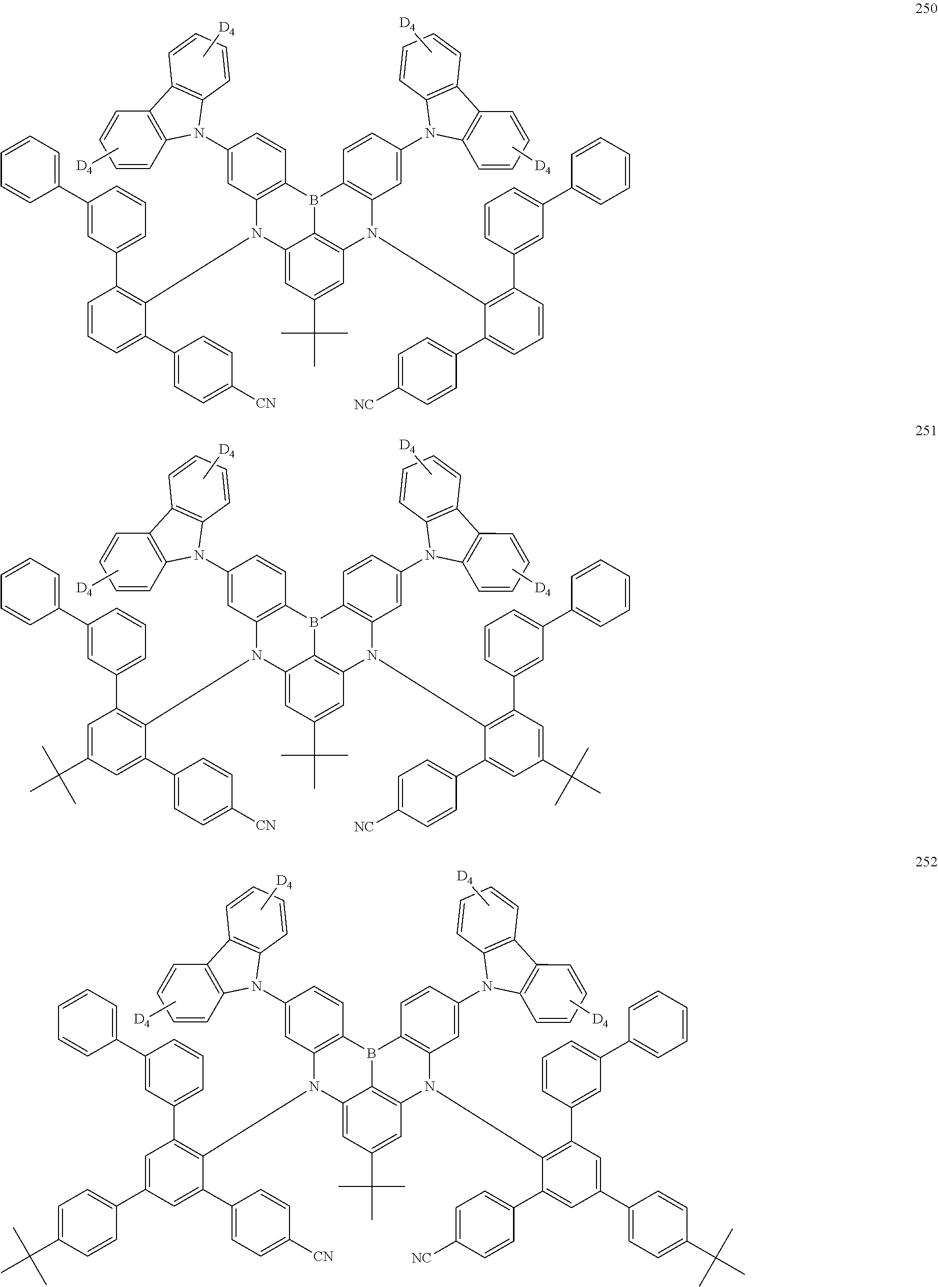

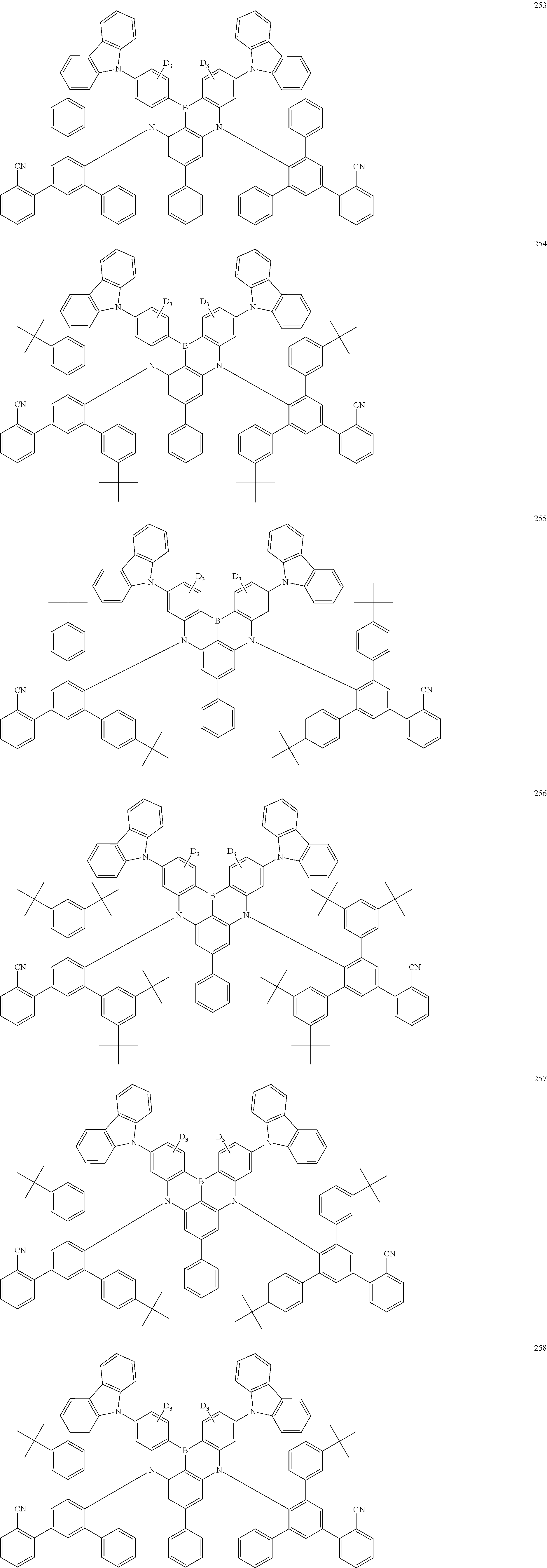

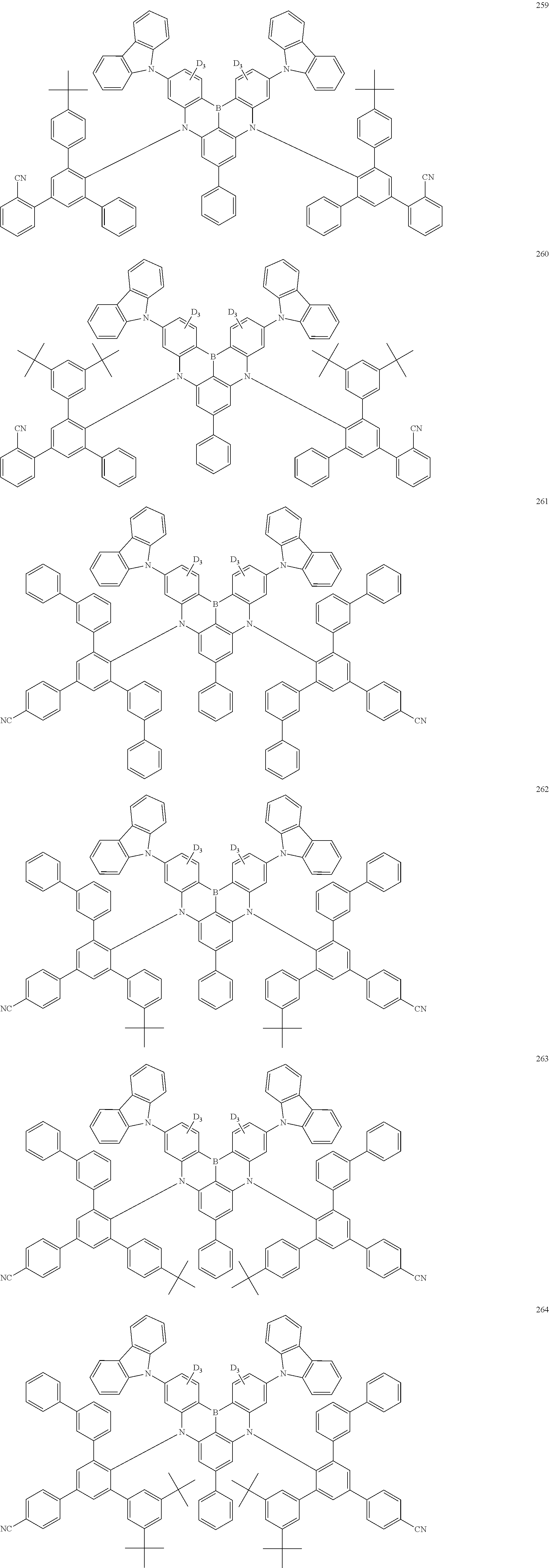

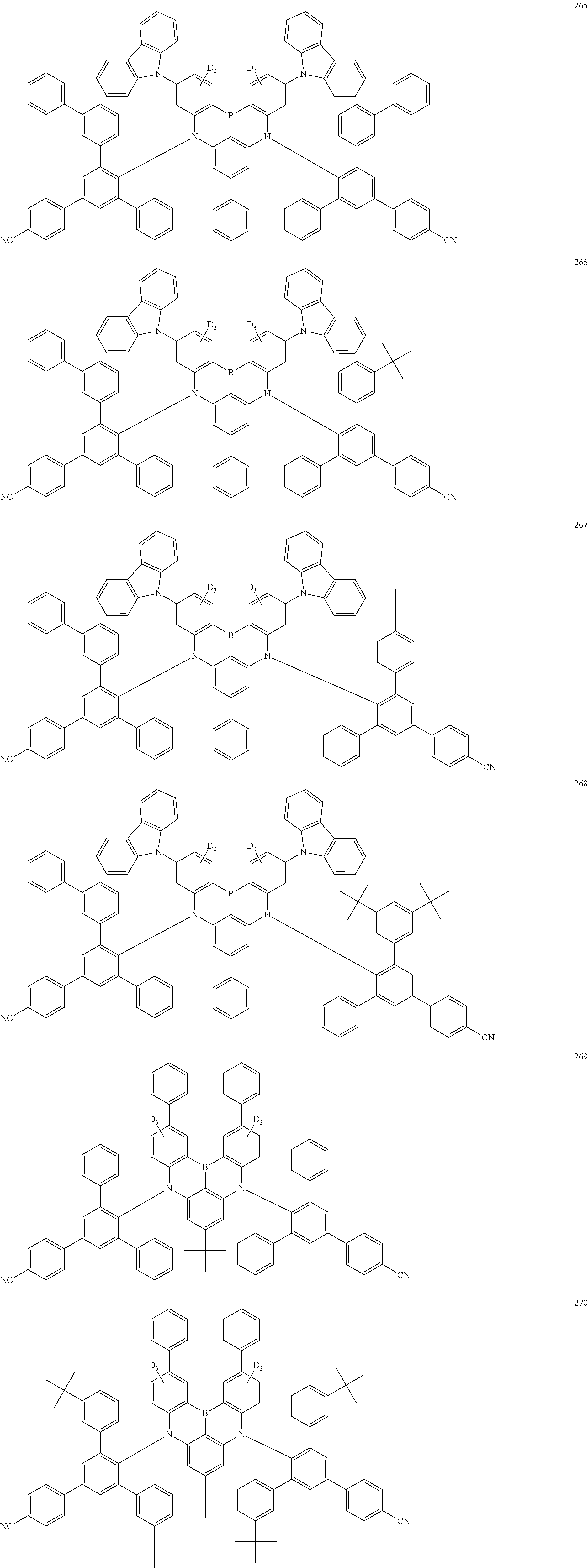

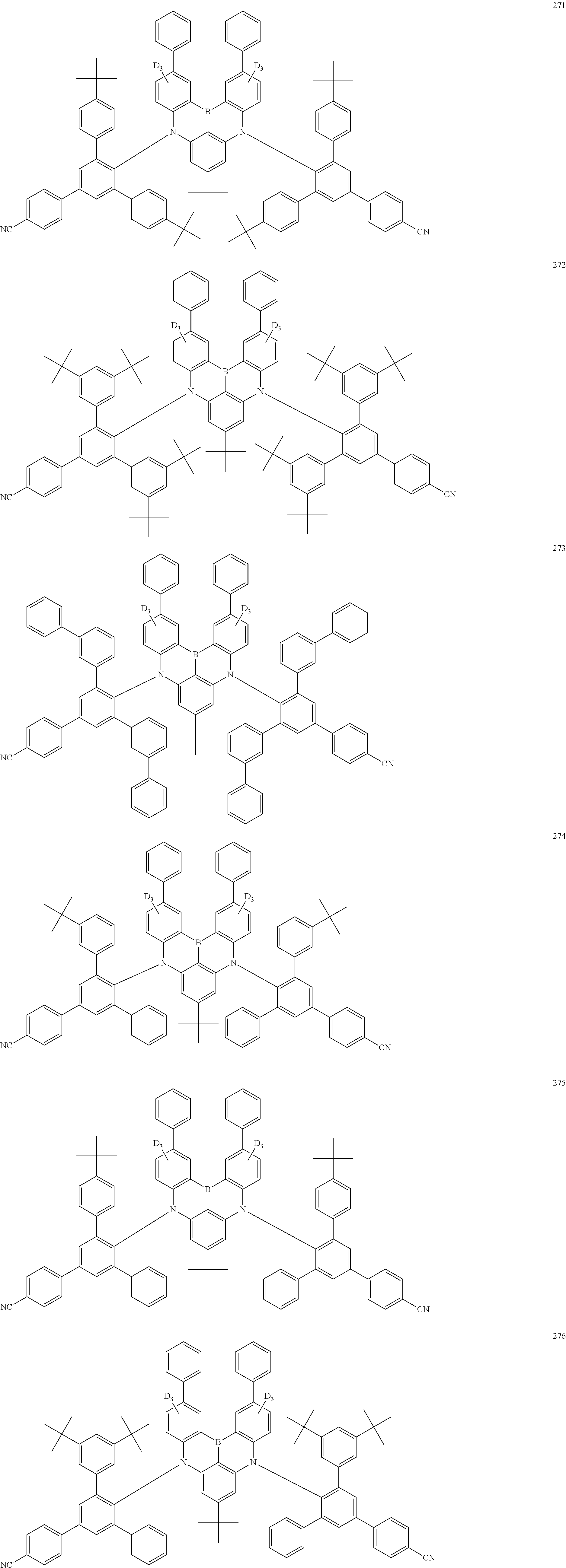

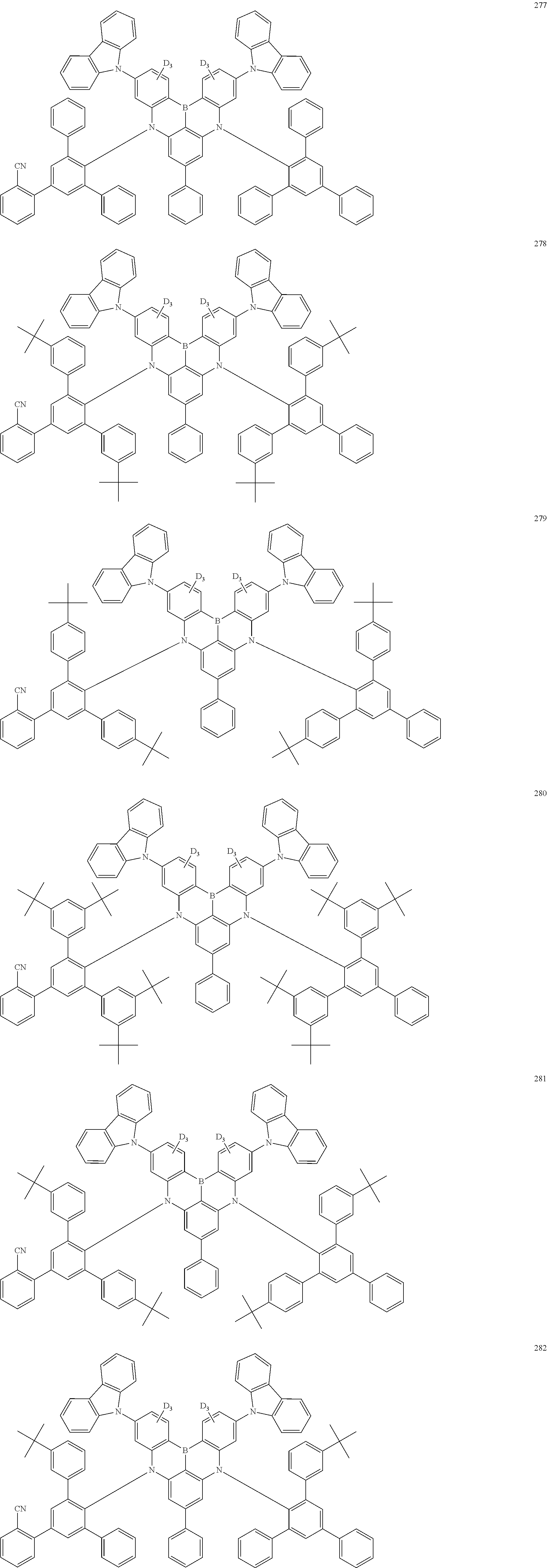

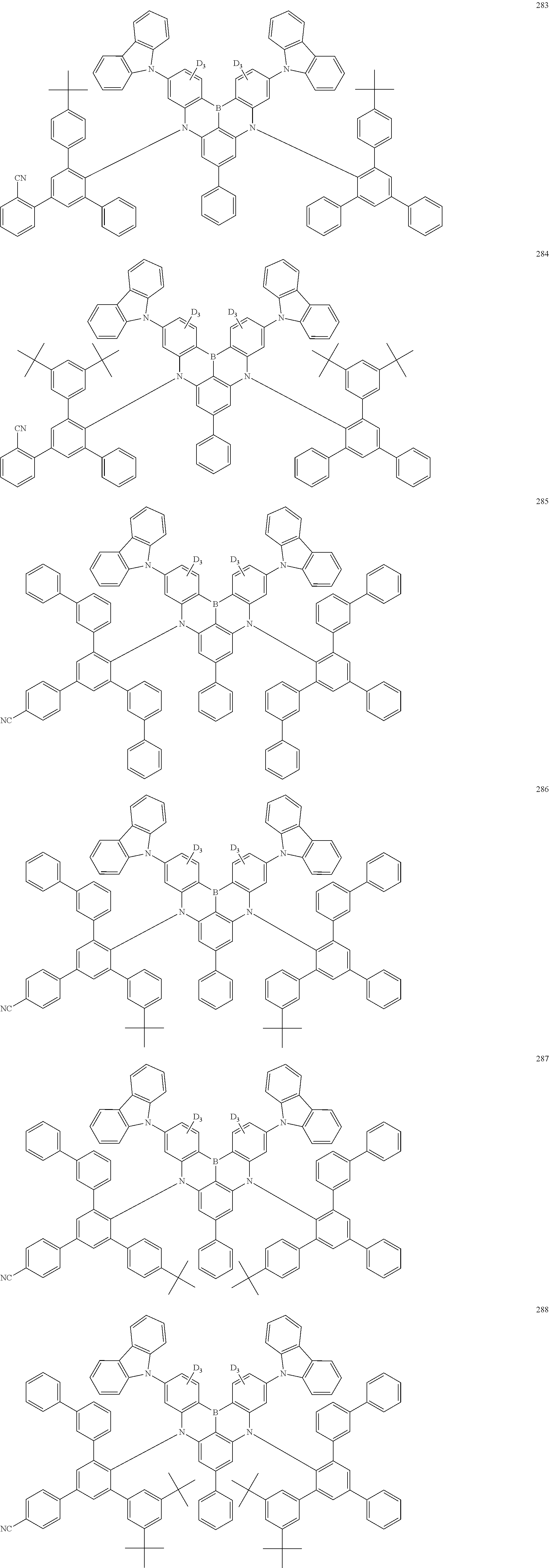

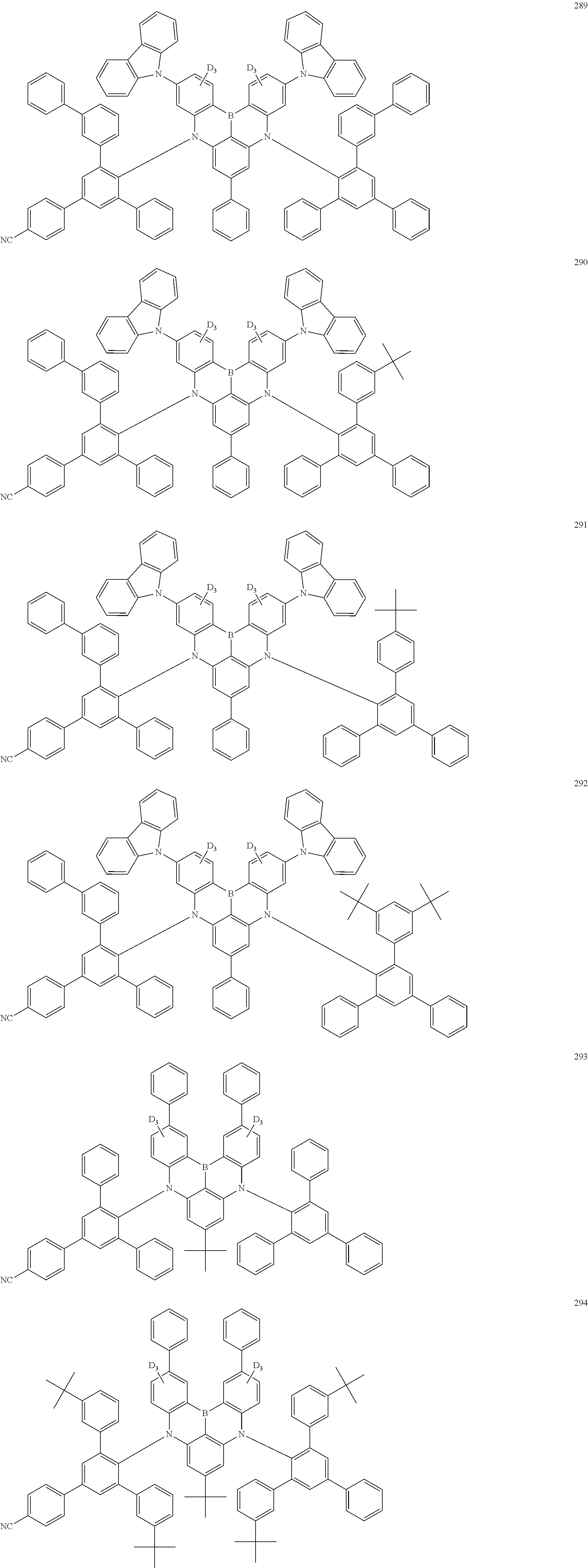

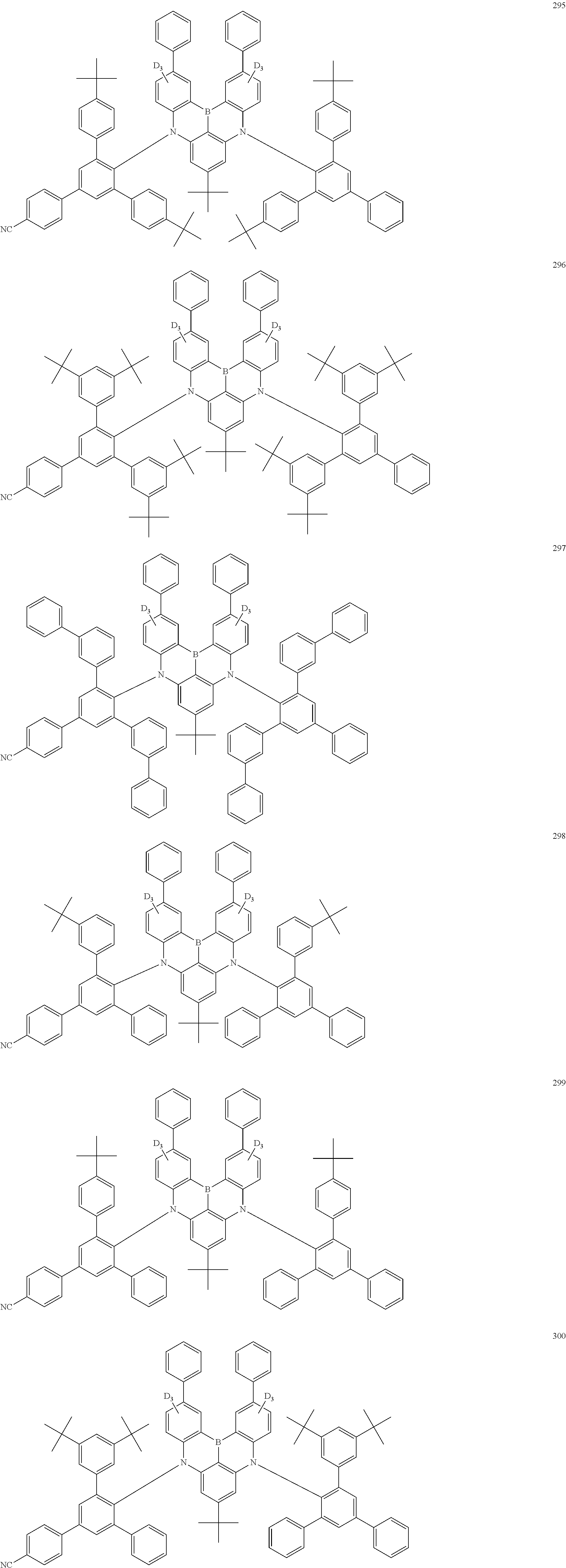

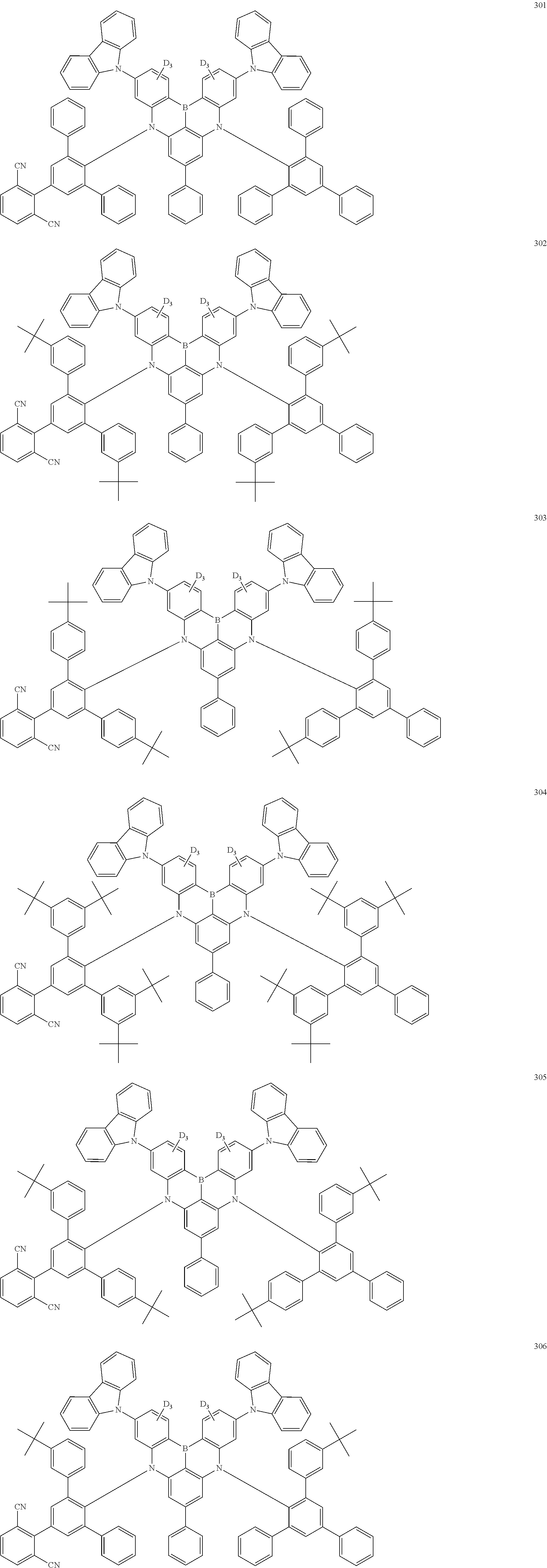

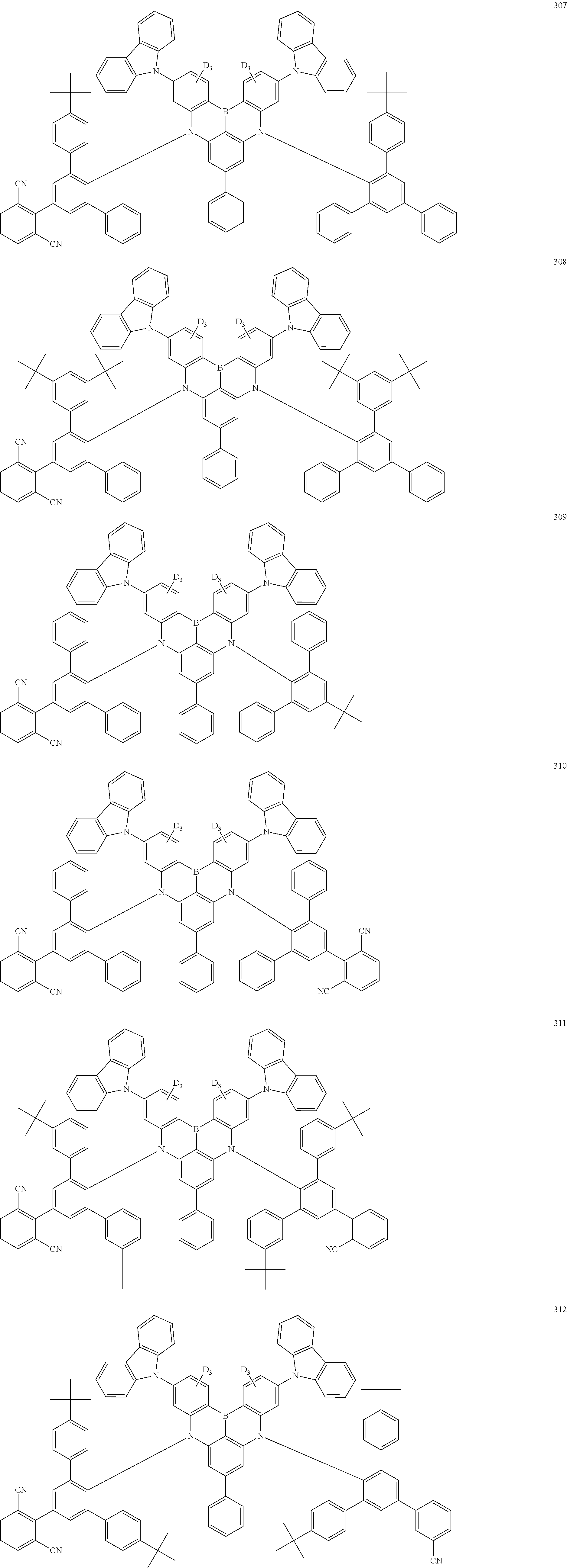

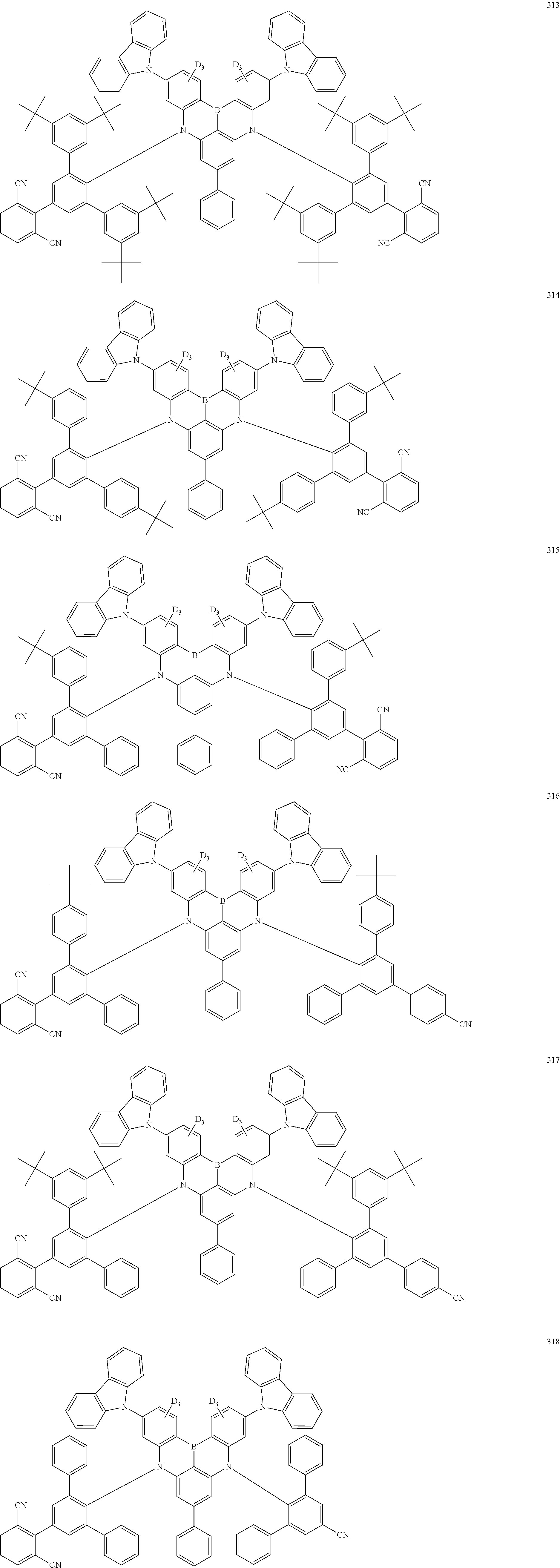

In Compound Group 1, D represents a deuterium atom, and —CN or NC— represents a cyano group.

The fused polycyclic compound represented by Formula 1 has a structure of a fused ring core that includes at least one first substituent, and may thus contribute to high emission efficiency and long lifespan.

The fused polycyclic compound represented by Formula 1 has a structure in which three aromatic rings are fused together through a boron atom and two nitrogen atoms, and includes at least one first substituent in the molecular structure thereof. The fused polycyclic compound has a structure in which a first phenyl group and a second phenyl group are respectively bonded to the first and second nitrogen atoms, and the at least one first substituent is substituted on at least one of the first phenyl group and the second phenyl group. The first substituent includes a phenyl group at least one cyano group as a substituent of the phenyl group.

The fused polycyclic compound has a structure in which the first phenyl group and the second phenyl group are respectively bonded to the first and second nitrogen atoms of the fused ring core, and the at least one first substituent is bonded to at least one of the first phenyl group and the second phenyl group, and thus may exhibit improved emission efficiency and improved element lifespan. The first phenyl group and the second phenyl group that are linked to the nitrogen atoms and the at least one first substituent linked to at least one of the first phenyl group and the second phenyl group constitute a bulky structure and also a long elongated structure, and may thus have a structure that surrounds the fused ring core. Accordingly, a vacant p-orbital of a boron atom as a central atom in the fused ring core may be shielded and protected. Distance between adjacent molecules increases with the introduction of steric hindrance and bulky substituents, and accordingly, Dexter energy transfer may be suppressed to prevent lifespan deterioration caused by an increase in triplet concentration.

The first substituent has a structure that includes a cyano group, which is an electron withdrawing group, as a substituent, resulting in the fused polycyclic compound having a deep HOMO energy level, and may thus suppress trap-assisted recombination to further improve lifespan of a light emitting element when used as a dopant material of an emission layer, and preventing a HOMO energy level from being shallow, thereby satisfying both a desired emission wavelength and HOMO energy level. The deep HOMO energy level promotes energy transfer from a host in a light emitting element, and efficiency may thus be improved. In the specification, the term “shallow” in relation to an energy level may indicate that an absolute value of the energy level decreases in a negative direction from a vacuum level. In the specification, the term “deep” in relation to an energy level may indicate that an absolute value of the energy level increases in a negative direction from a vacuum level.

A full width at half maximum (FWHM) of an emission spectrum of the fused polycyclic compound represented by Formula 1 may be in a range of about 10 to about 50 nm. For example, a FWHM of an emission spectrum of the fused polycyclic compound represented by Formula 1 may be in a range of about 20 to about 40 nm. When the FWHM of the emission spectrum of the polycyclic compound satisfies any of the above ranges, emission efficiency may be improved when the fused polycyclic compound is applied to an element. Element service life may be improved when the fused polycyclic compound is used as a blue light emitting element material for a light emitting element.

The fused polycyclic compound represented by Formula 1 may be a thermally activated delayed fluorescence (TADF) emitting material. The fused polycyclic compound may be a thermally activated delayed fluorescence dopant having a difference (expressed as ΔE_{ST}) between a lowest triplet excitation energy level (T1 level) and a lowest singlet excitation energy level (S1 level) equal to or less than about 0.6 eV. For example, the fused polycyclic compound may be a thermally activated delayed fluorescence dopant having a difference (ΔE_{ST}) between a lowest triplet excitation energy level (T1 level) and a lowest singlet excitation energy level (S1 level) equal to or less than about 0.5 eV.

The fused polycyclic compound represented by Formula 1 may be a light emitting material having a central emission wavelength in a range of about 430 nm to about 490 nm. For example, the fused polycyclic compound may be a blue thermally activated delayed fluorescence (TADF) dopant. However, the embodiments are not limited thereto, and when the fused polycyclic compound is used as a light emitting material, a first dopant may be used as a dopant material emitting light in various wavelength ranges, such as a red light emitting dopant or a green light emitting dopant.

In the light emitting element ED, the emission layer EML may emit delayed fluorescence. For example, the emission layer EML may emit thermally activated delayed fluorescence (TADF).

The emission layer EML of the light emitting element ED may emit blue light. The emission layer EML of the light emitting element ED may emit blue light having a central wavelength equal to or less than about 490 nm. In an embodiment, the emission layer EML of the light emitting element ED may emit light having a central wavelength in a range of about 430 nm to about 490 nm. However, embodiments are not limited thereto, and the emission layer EML may emit green light or red light.

The fused polycyclic compound may be included in an emission layer EML. The fused polycyclic compound may be included in an emission layer EML as a dopant material. The fused polycyclic compound may be a thermally activated delayed fluorescence material. The fused polycyclic compound may be used as a thermally activated delayed fluorescence dopant. For example, in the light emitting element ED, the emission layer EML may include at least one fused polycyclic compound selected from Compound Group 1 as a thermally activated delayed fluorescence dopant. However, the use of the fused polycyclic compound is not limited thereto.

In an embodiment, the emission layer EML may include multiple compounds. In an embodiment, the emission layer EML may include the fused polycyclic compound represented by Formula 1 as a first compound, and at least one of a second compound represented by Formula HT-1, a third compound represented by Formula ET-1, and a fourth compound represented by Formula D-1.

In an embodiment, the emission layer EML may include the first compound represented by Formula 1, and may further include at least one of a second compound represented by Formula HT-1, a third compound represented by Formula ET-1, and a fourth compound represented by Formula D-1.

In an embodiment, the emission layer EML may further include a second compound represented by Formula HT-1. In an embodiment, the second compound may be used as a hole transporting host material in the emission layer EML.

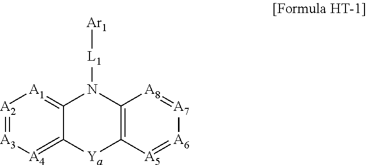

In Formula HT-1, A₁ to A₈ may each independently be N or C(R₄₁). For example, all of A₁ to A₈ may each independently be C(R₄₁). In an embodiment, one of A₁ to A₈ may be N, and the remainder of A₁ to A₈ may each independently be C(R₄₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT-1, Yₐ may be a direct linkage, C(R₄₂)(R₄₃), or Si(R₄₄)(R₄₅). For example, the two benzene rings that are bonded to the nitrogen atom in Formula HT-1 may be bonded to each other via a direct linkage,

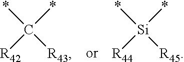

In Formula HT-1, when Yₐ is a direct linkage, the second compound represented by Formula HT-1 may include a carbazole moiety.

In Formula HT-1, An may be a substituted or unsubstituted aryl group having 6 to 30 ring-forming carbon atoms or a substituted or unsubstituted heteroaryl group having 2 to 30 ring-forming carbon atoms. For example, An may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, R₄₁ to R₄₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring. For example, R₄₁ to R₄₅ may each independently be a hydrogen atom or a deuterium atom. For example, R₄₁ to R₄₅ may each independently be an unsubstituted methyl group or an unsubstituted phenyl group.

In an embodiment, the second compound represented by Formula HT-1 may be selected from Compound Group 2. In an embodiment, in the light emitting element ED, the second compound may include at least one compound selected from Compound Group 2.

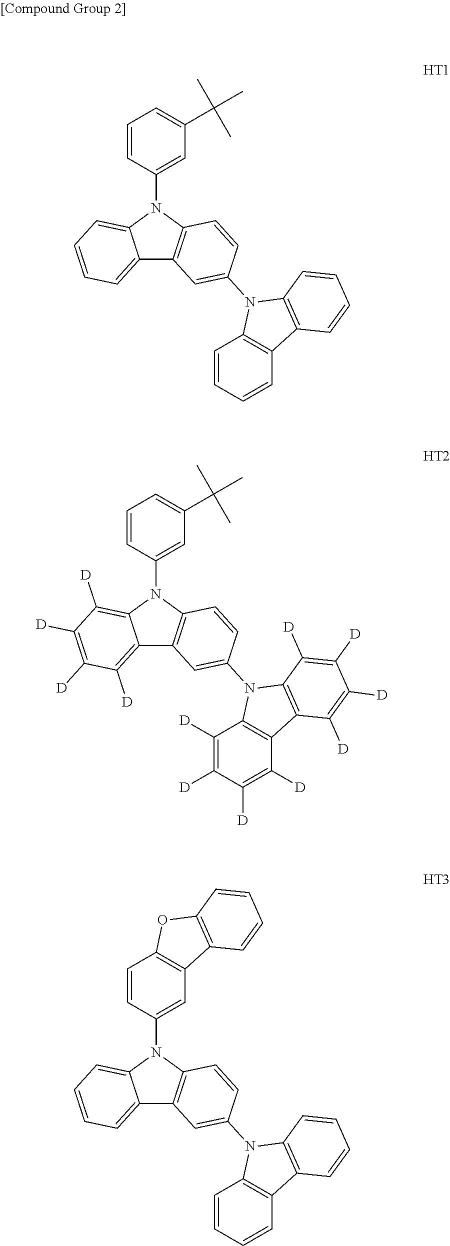 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

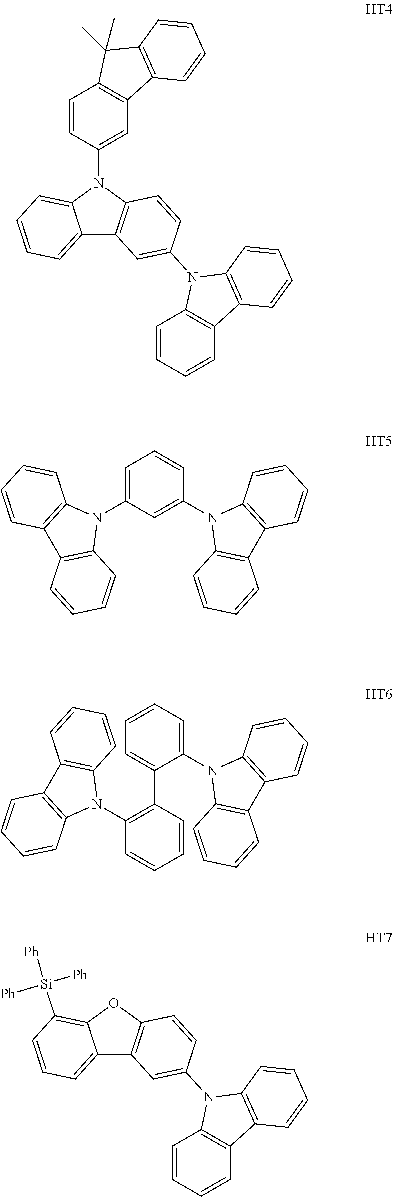 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

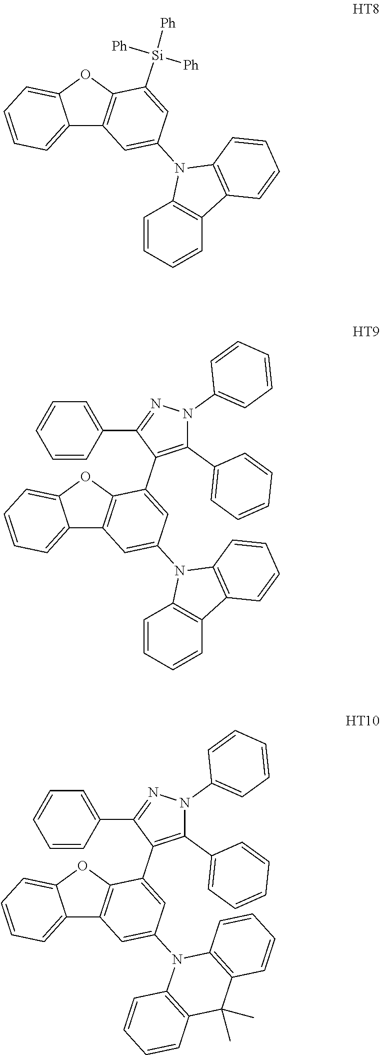 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21]

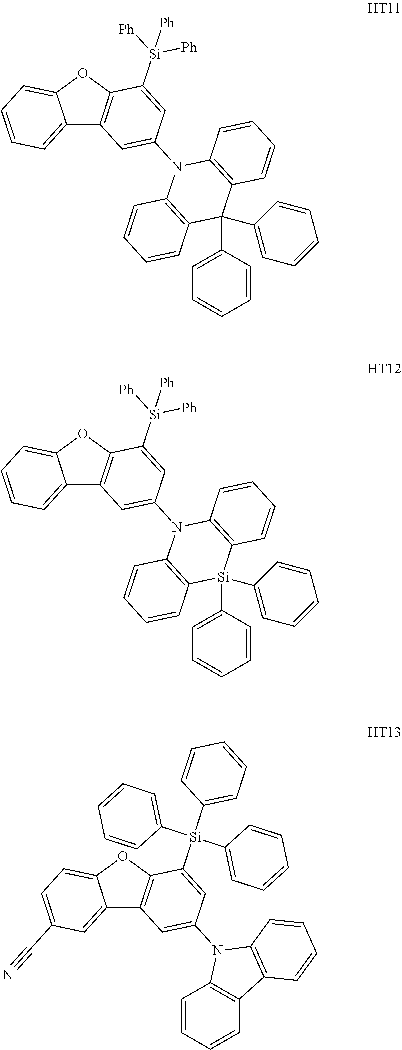 [SMILES: c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1]

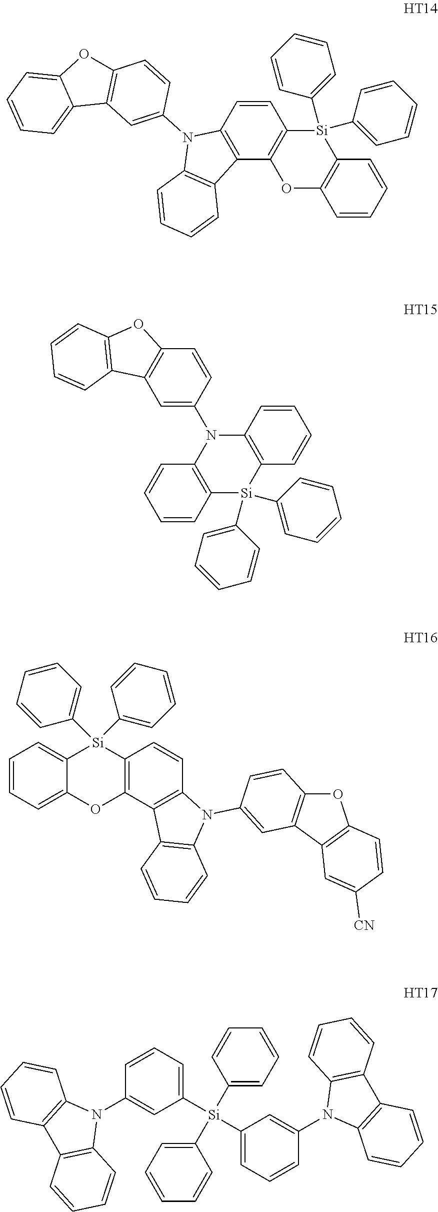 [SMILES: c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1]

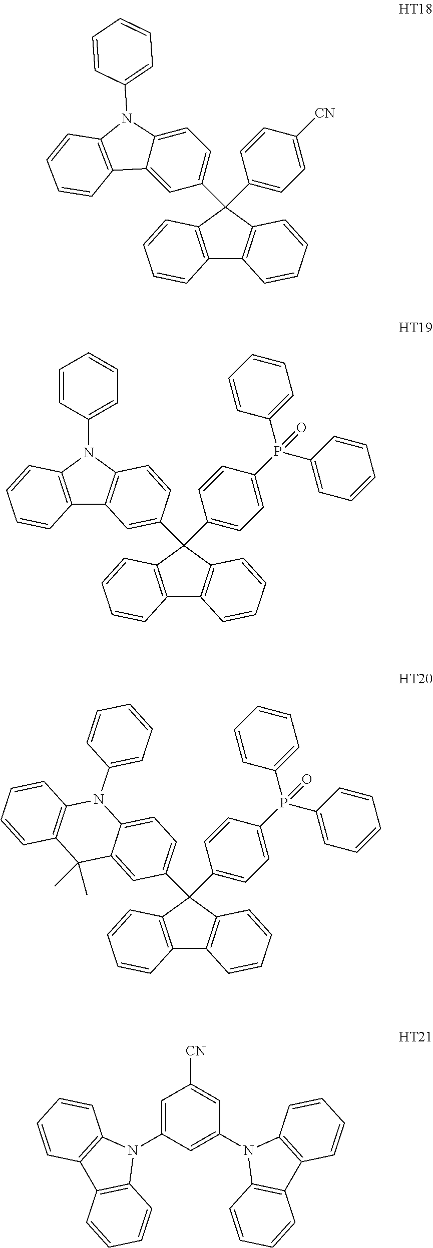 [SMILES: N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1]

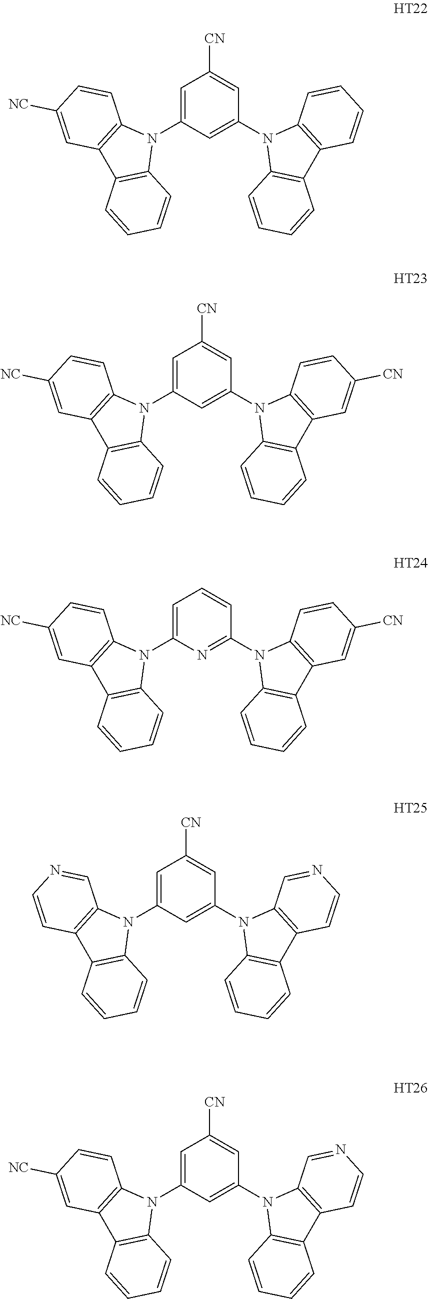 [SMILES: N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

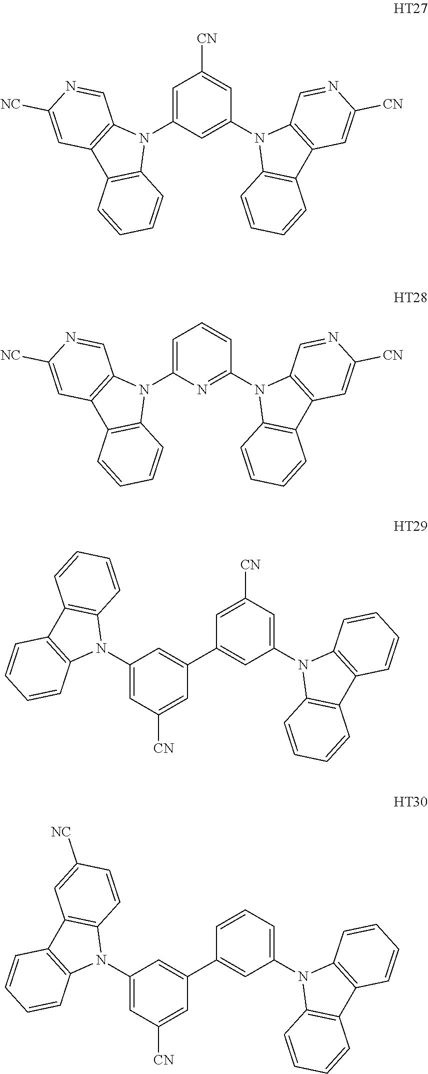 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1]

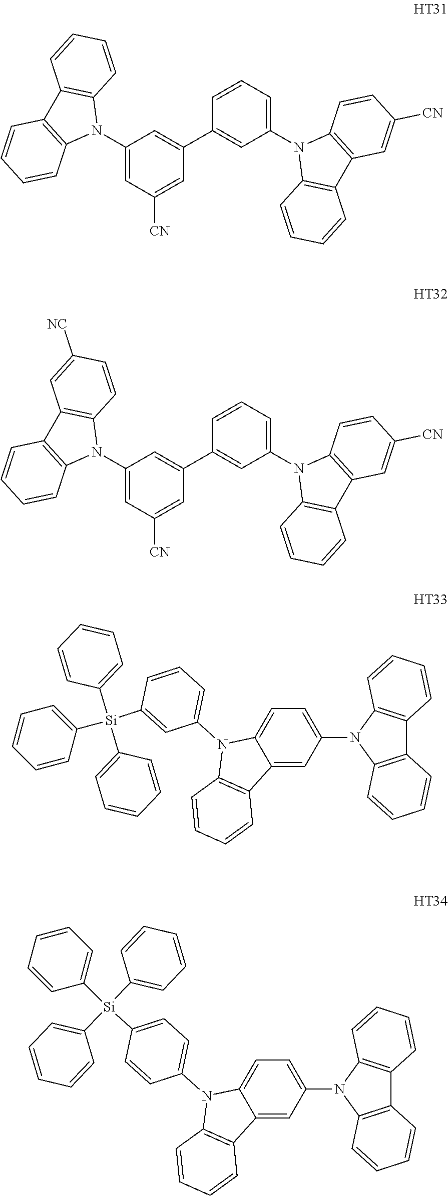 [SMILES: N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2ccc(-n3c4ccccc4c4cc(-n5c6ccccc6c6ccccc65)ccc43)cc2)cc1]

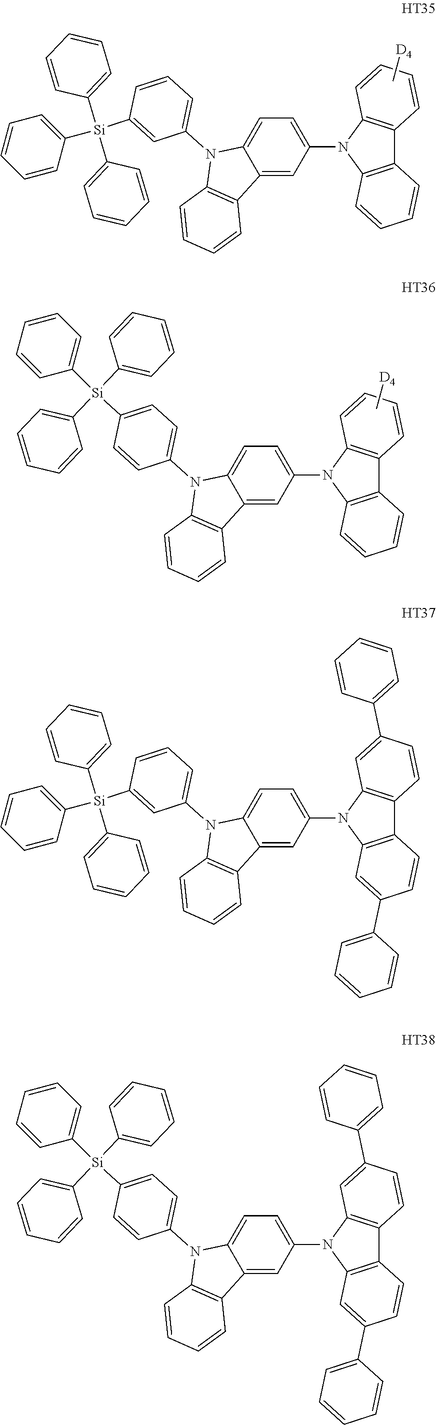

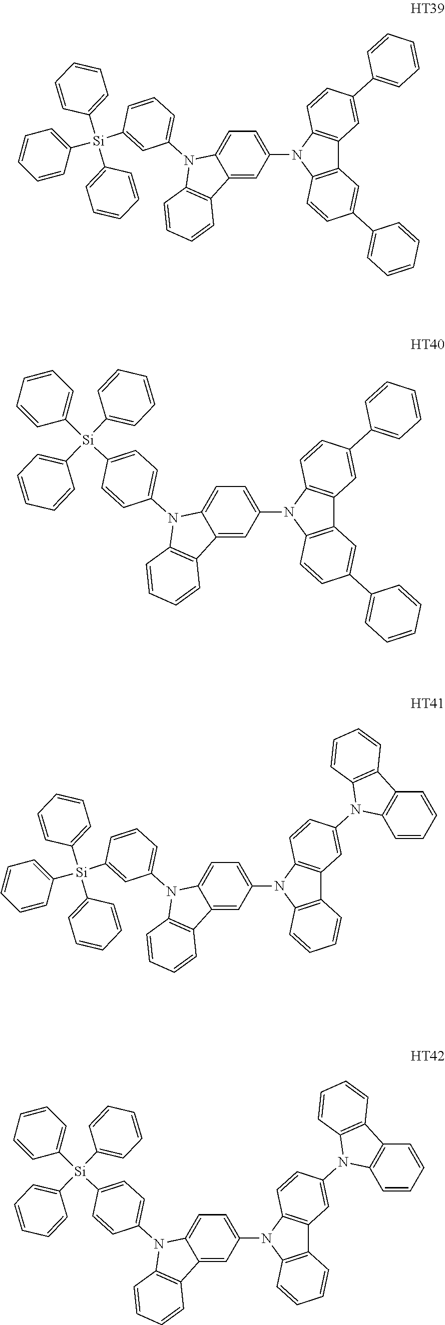 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

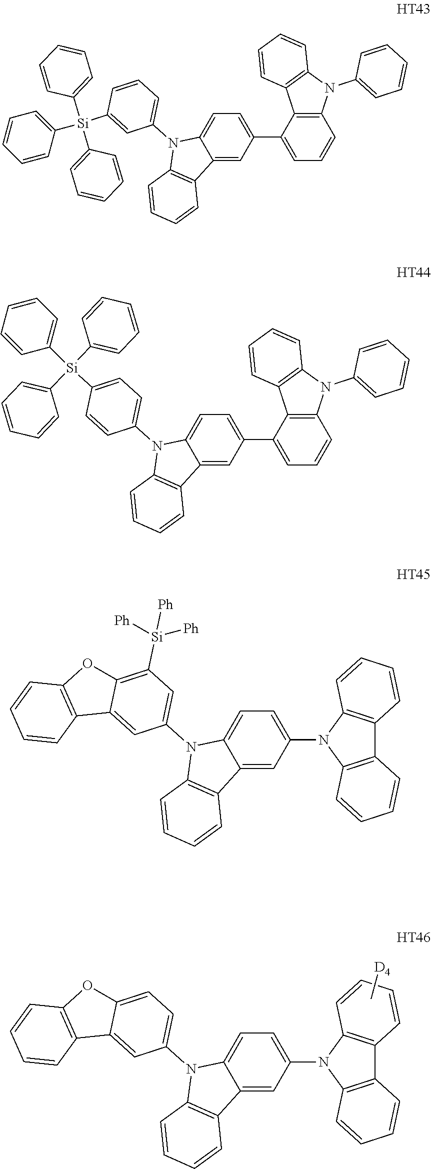

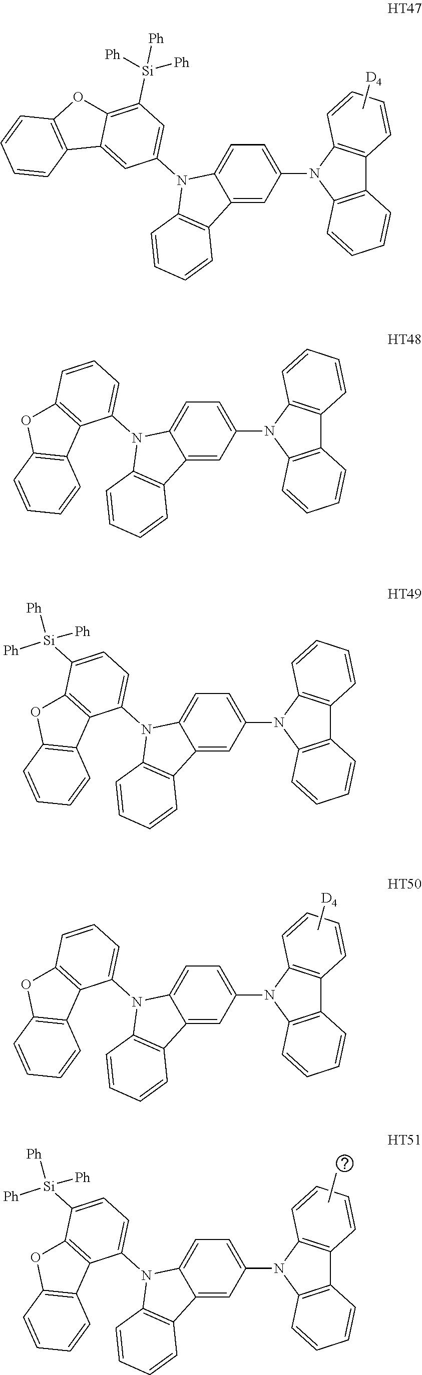

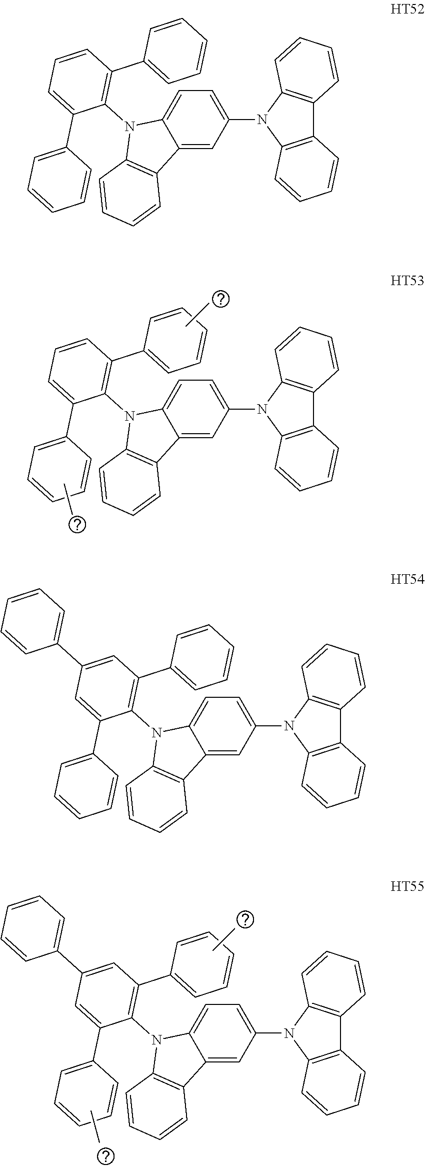

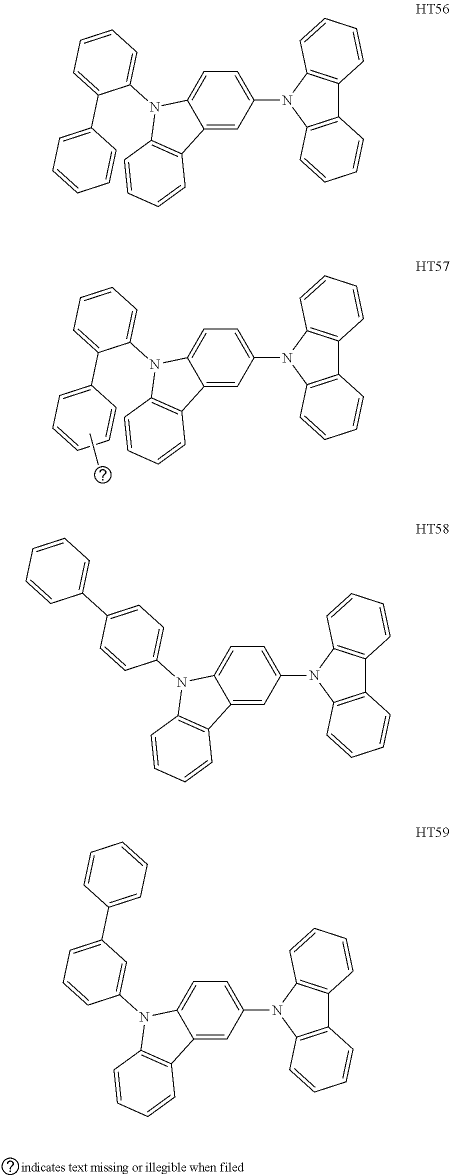

In Compound Group 2, D represents a deuterium atom, and Ph represents a substituted or unsubstituted phenyl group. For example, in Compound Group 2, Ph may represent an unsubstituted phenyl group.

In an embodiment, the emission layer EML may further include a third compound represented by Formula ET-1. In an embodiment, the third compound may be used as an electron transport host material in the emission layer EML.

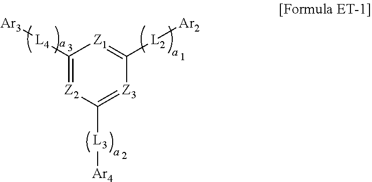

In Formula ET-1, at least one of Z₁ to Z₃ may each be N, and the remainder of Z₁ to Z₃ may each independently be C(R₄₆). For example, one of X₁ to X₃ may be N, and the remainder of Z₁ to Z₃ may each independently be C(R₄₆). Thus, the third compound represented by Formula ET-1 may include a pyridine moiety. As another example, two of Z₁ to Z₃ may each be N, and the remainder of Z₁ to Z₃ may be C(R₄₆). Thus, the third compound represented by Formula ET-1 may include a pyrimidine moiety. As yet another example, Z₁ to Z₃ may each be N. Thus, the third compound represented by Formula ET-1 may include a triazine moiety.

In Formula ET-1, R₄₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, a₁ to a₃ may each independently be an integer from 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may be each independently a direct linkage, a substituted or unsubstituted arylene group having 6 to 30 ring-forming carbon atoms, or a substituted or unsubstituted heteroarylene group having 2 to 30 ring-forming carbon atoms. When a₁ is 2 or greater, L₂ may be a substituted or unsubstituted arylene group having 6 to 30 ring-forming carbon atoms or a substituted or unsubstituted heteroarylene group having 2 to 30 ring-forming carbon atoms; when a₂ is 2 or greater, L₃ may be a substituted or unsubstituted arylene group having 6 to 30 ring-forming carbon atoms or a substituted or unsubstituted heteroarylene group having 2 to 30 ring-forming carbon atoms; and when a₃ is 2 or greater, L₄ may be a substituted or unsubstituted arylene group having 6 to 30 ring-forming carbon atoms or a substituted or unsubstituted heteroarylene group having 2 to 30 ring-forming carbon atoms,

In an embodiment, the third compound represented by Formula ET-1 may be selected from Compound Group 3. In an embodiment, in the light emitting element ED, the third compound may include at least one compound selected from Compound Group 3.

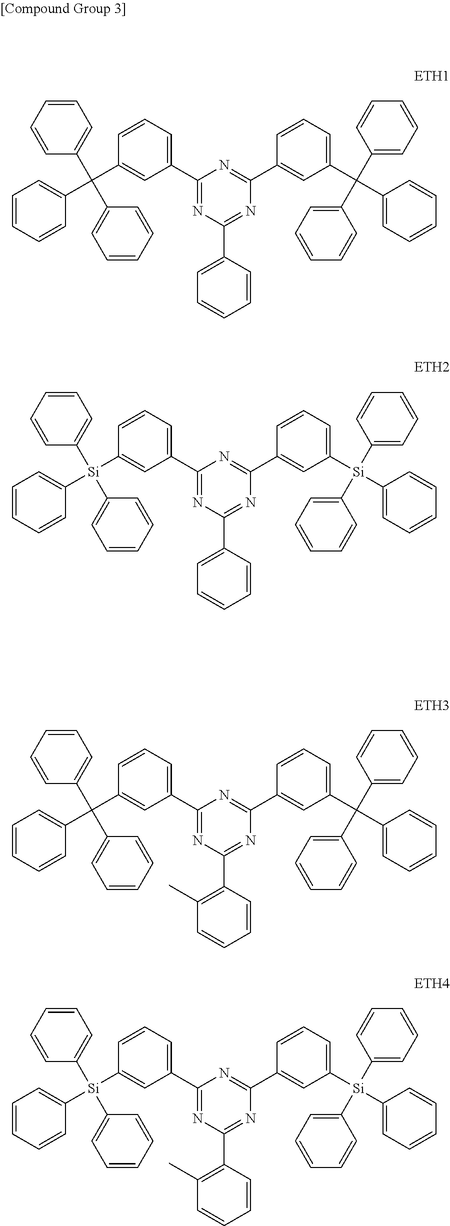 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

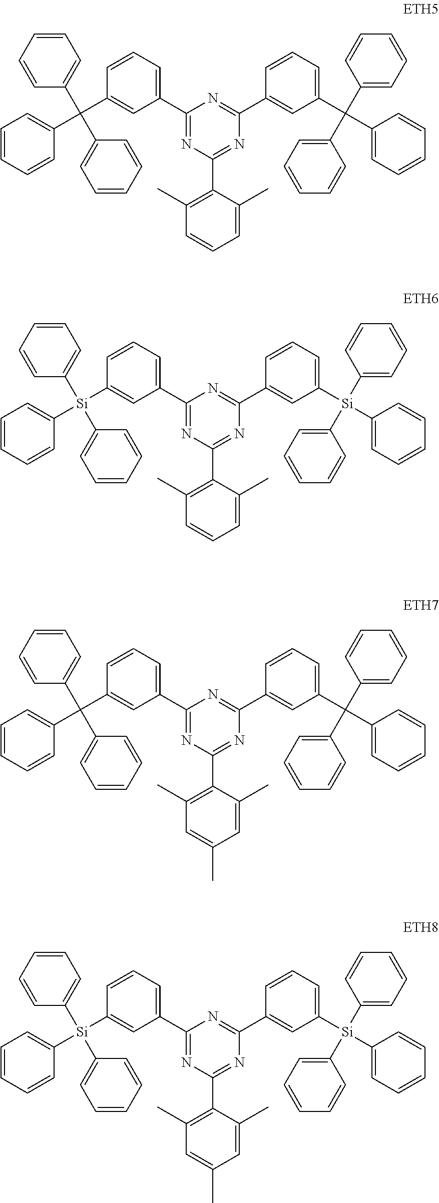 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

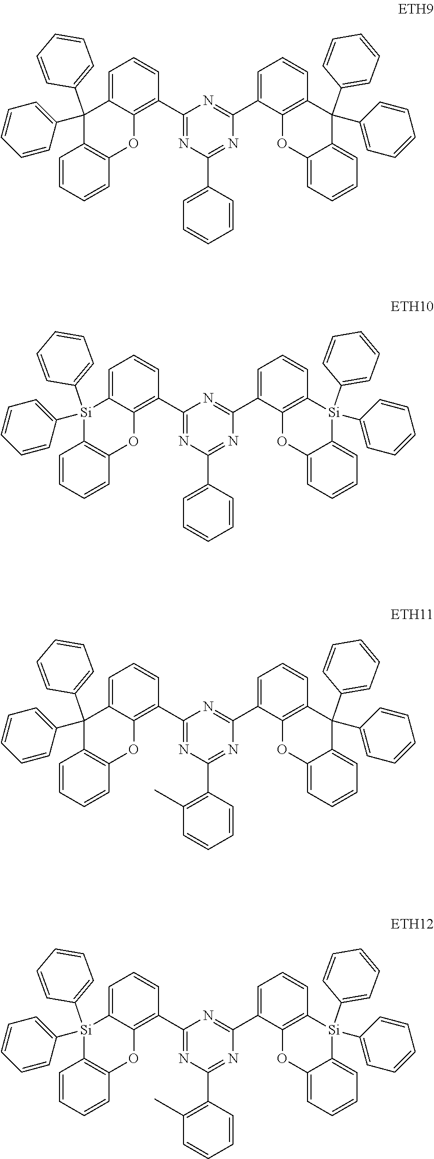 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

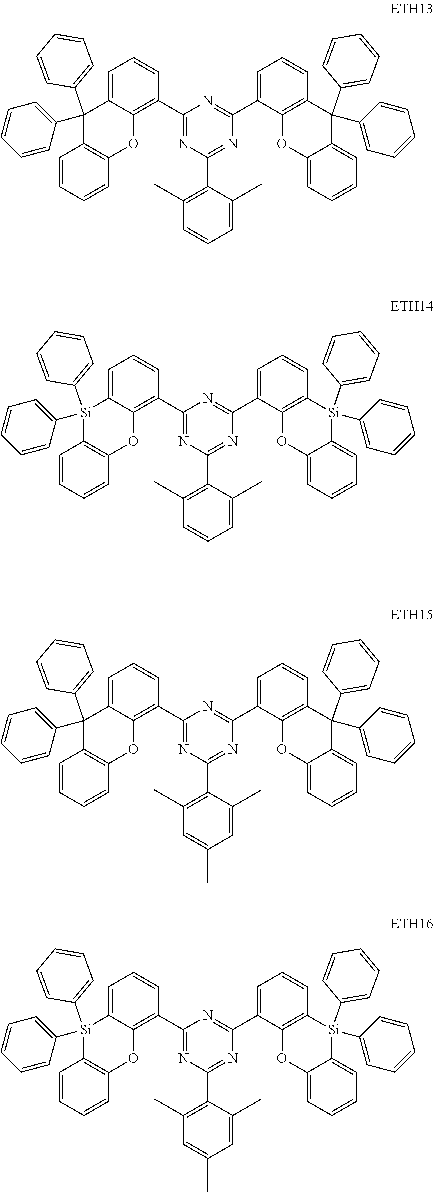 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

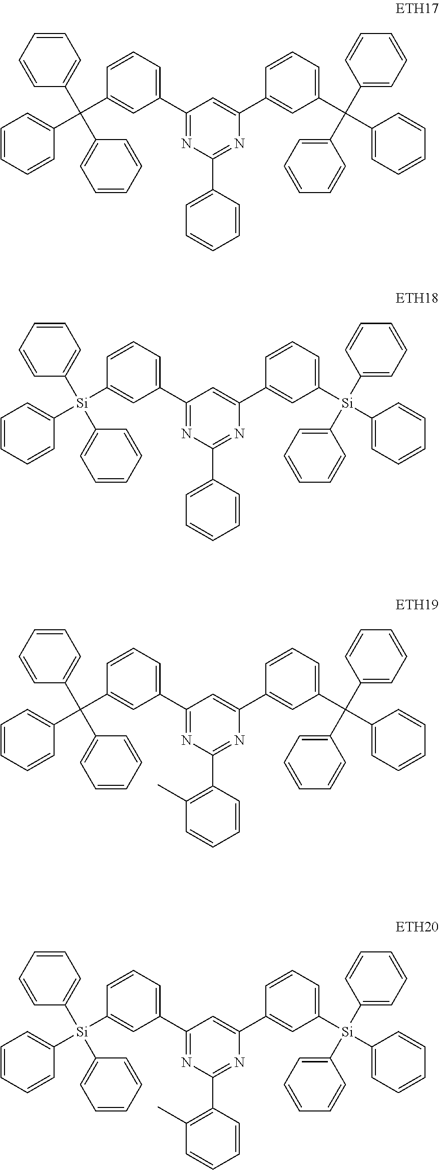 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

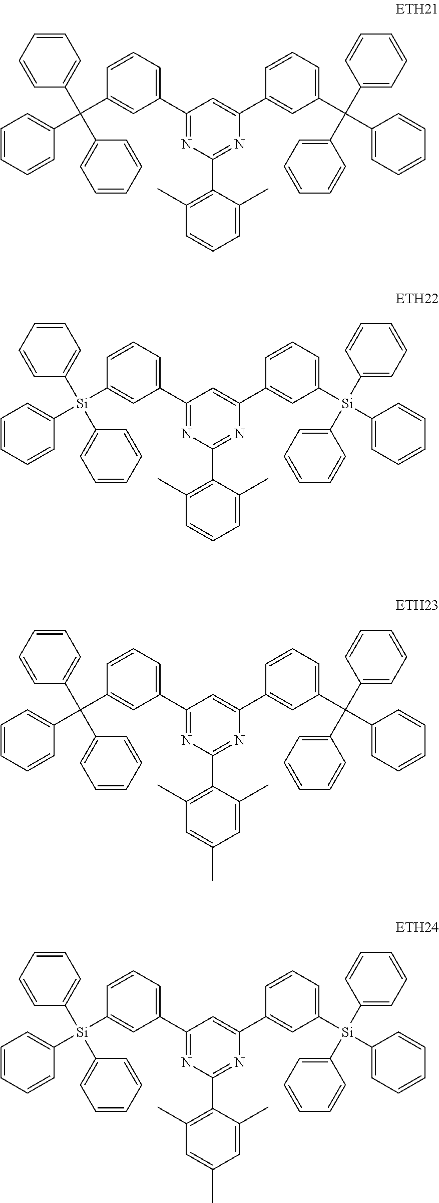 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

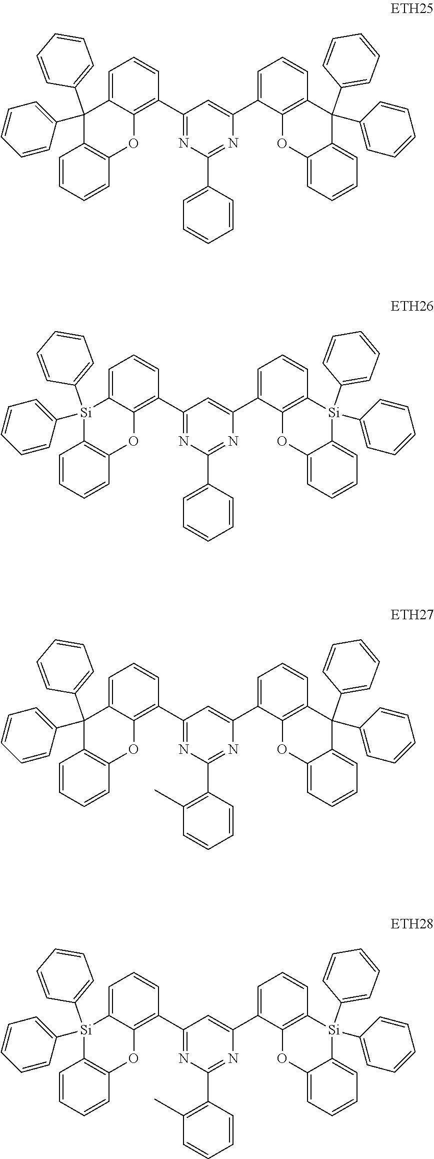 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

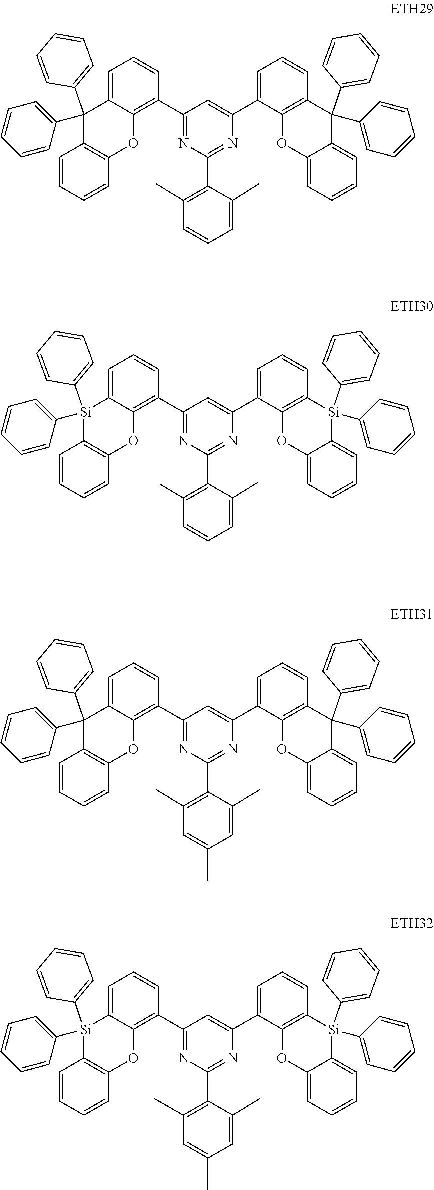 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

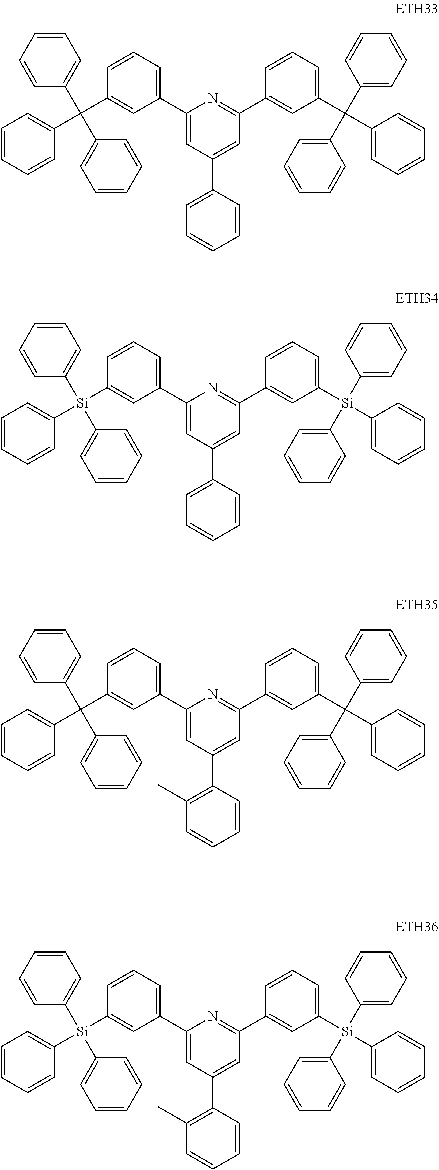 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

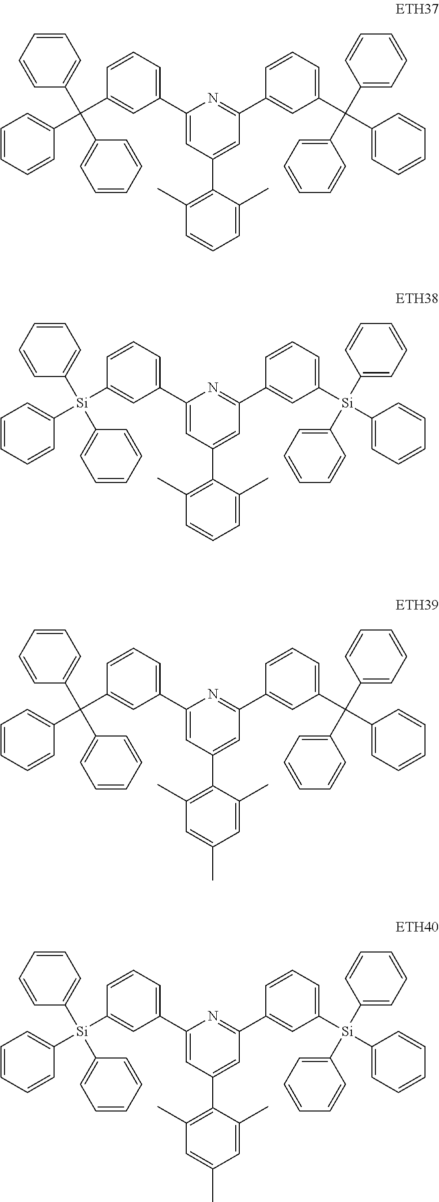 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

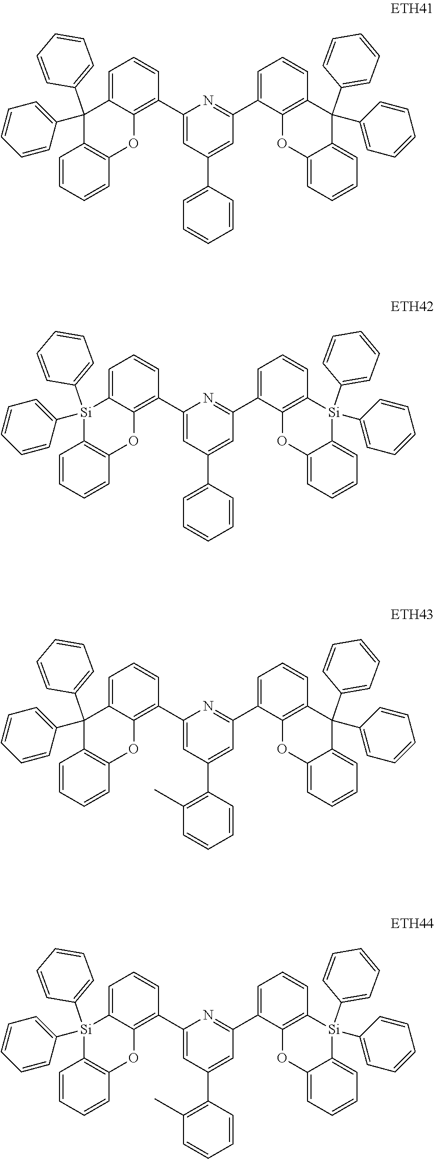 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

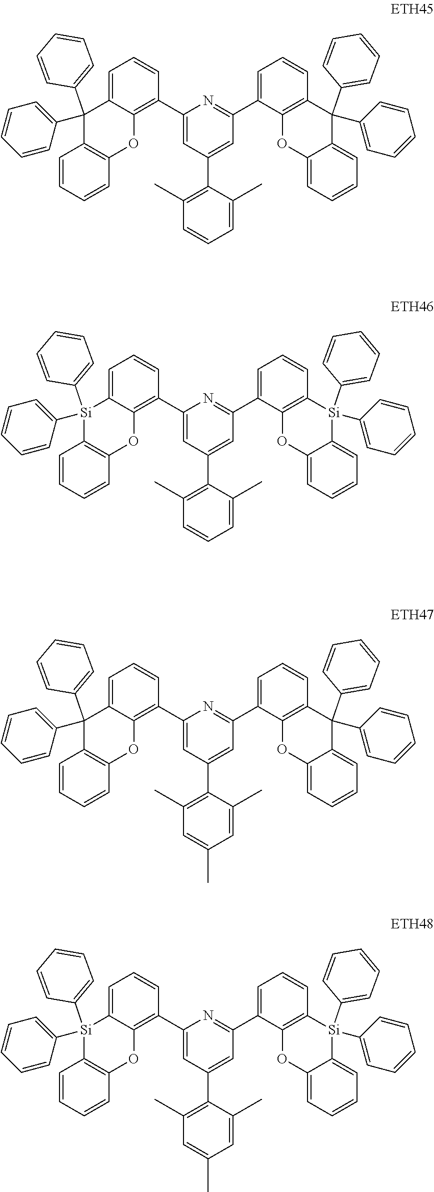 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

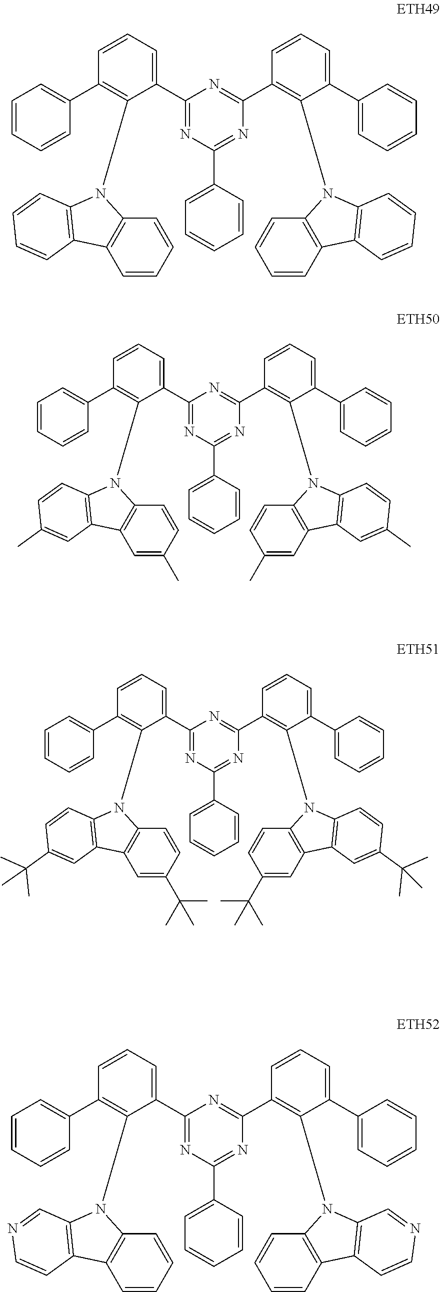

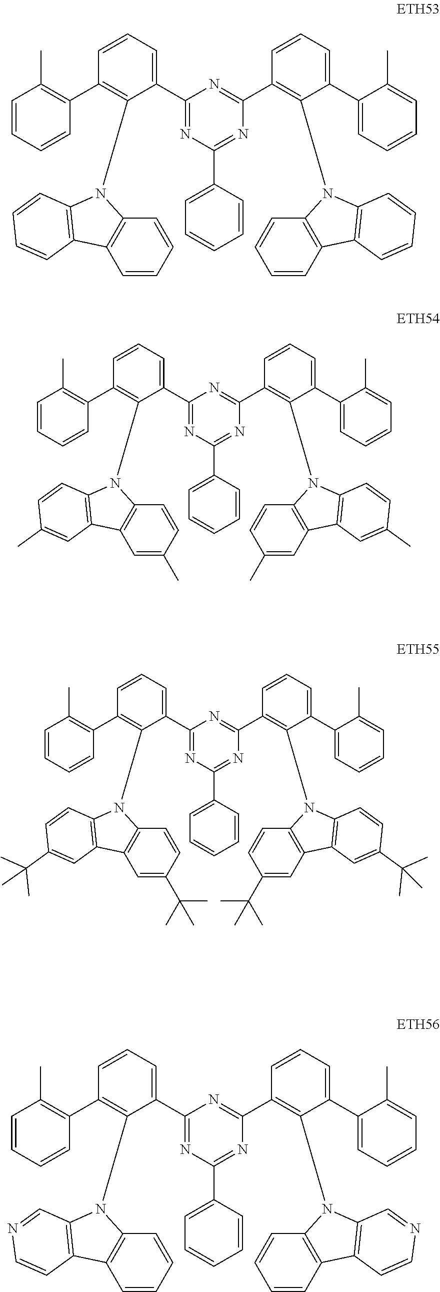

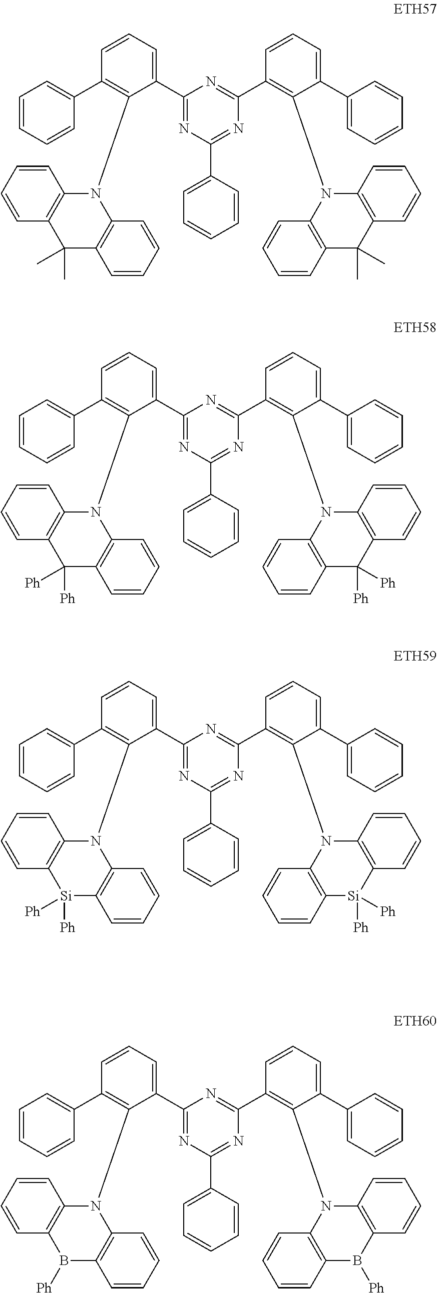

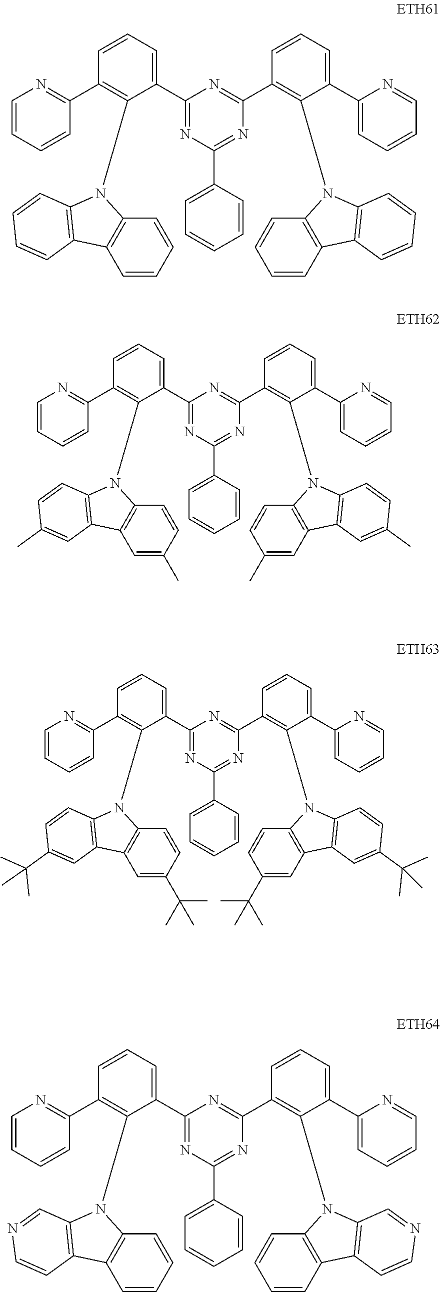

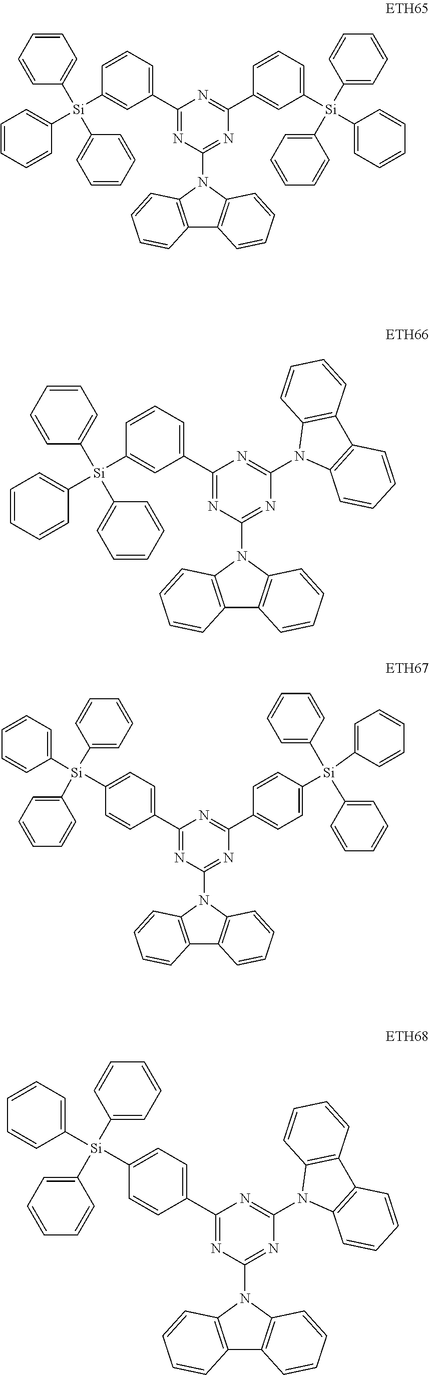 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

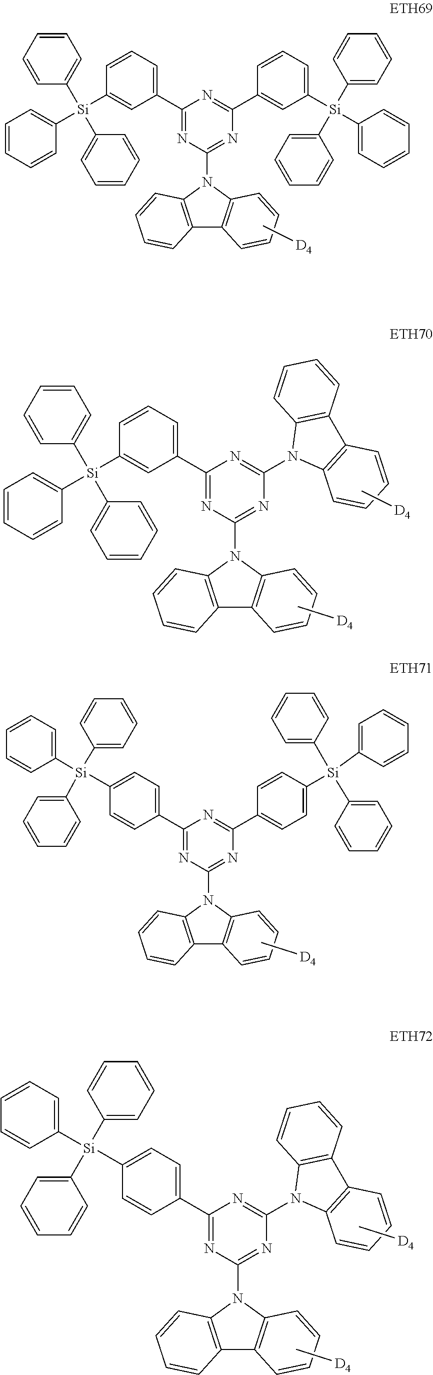

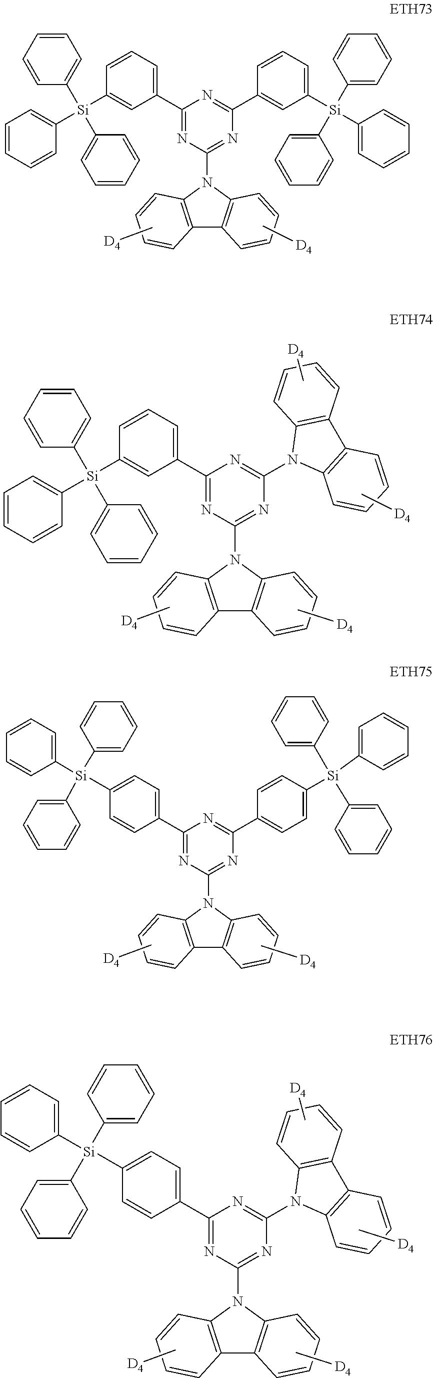

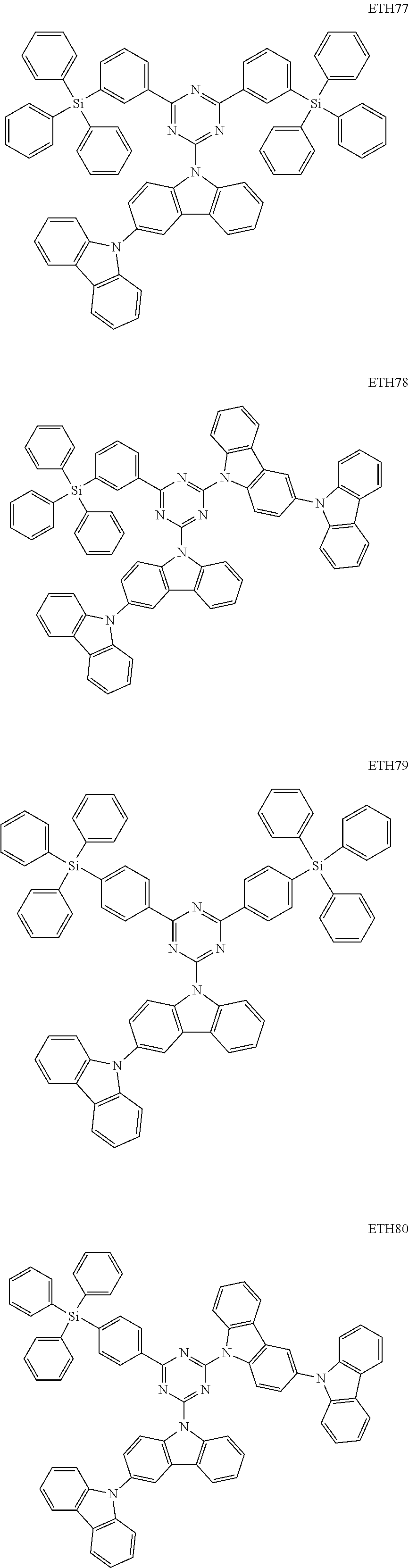

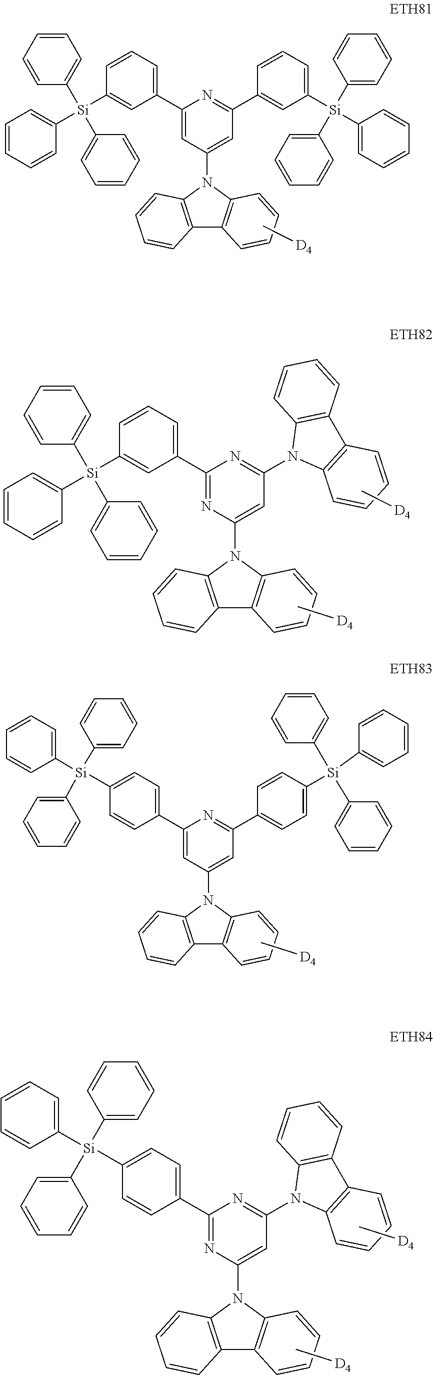

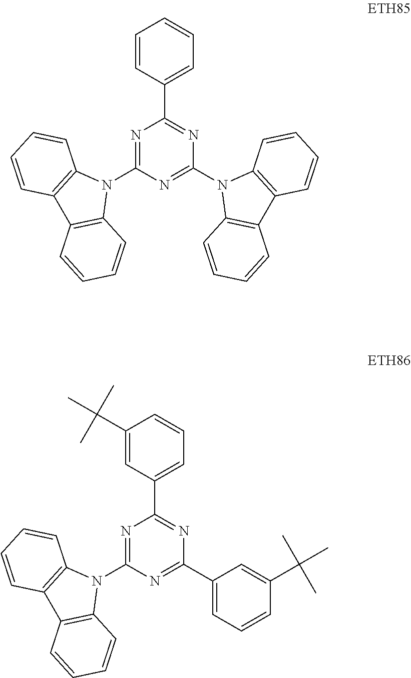 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy level of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of a triplet energy level (T1) of the exciplex formed by the hole transporting host and the electron transporting host may be in a range of about 2.4 eV to about 3.0 eV. The triplet energy level of the exciplex may have a value that is smaller than an energy gap of each host material. The exciplex may have a triplet energy level equal to or less than about 3.0 eV, which is an energy gap between the hole transporting host and the electron transporting host.

In an embodiment, the emission layer EML may include a fourth compound, in addition to the first compound, the second compound, and the third compound as described above. The fourth compound may be used as a phosphorescent sensitizer in the emission layer EML. Energy may be transferred from the fourth compound to the first compound, thereby emitting light.

The emission layer EML may include, as a fourth compound, an organometallic complex that includes platinum (Pt) as a central metal atom and ligands connected to the central metal atom. In an embodiment, the emission layer EML may further include a fourth compound represented by Formula D-1:

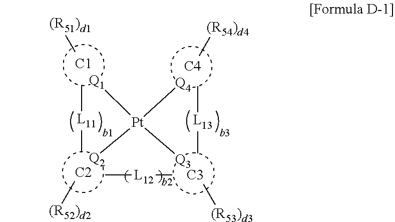

In Formula D-1, Q₁ to Q₄ may each independently be C or N.

In Formula D-1, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula D-1, L₁₁ to L₁₃ may each independently be a direct linkage,

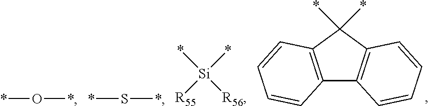

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, [symbol] represents a bond to one of C1 to C4.

In Formula D-1, b1 to b3 may each independently be 0 or 1. If b1 is 0, C1 and C2 may not be directly linked to each other. If b2 is 0, C2 and C3 may not be directly linked to each other. If b3 is 0, C3 and C4 may not be directly linked to each other.

In Formula D-1, R₅₁ to R₅₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring. For example, R₅₁ to R₅₆ may each independently be a substituted or unsubstituted methyl group or a substituted or unsubstituted t-butyl group.

In Formula D-1, d1 to d4 may each independently be an integer from 0 to 4. In Formula D-1, if d1 to d4 are each 0, the fourth compound may not be substituted with any of R₅₁ to R₅₄. A case where d1 to d4 are each 4 and groups of each of R₅₁ to R₅₄ are hydrogen atoms may be the same as a case where d1 to d4 are each 0. When d1 to d4 are each 2 or more, multiple groups of each of R₅₁ to R₅₄ may be the same as each other, or at least one group thereof may be different from the remainder.

In an embodiment, in Formula D-1, C1 to C4 may each independently be a substituted or unsubstituted hydrocarbon ring or a substituted or unsubstituted heterocycle that is represented by one of Formula C-1 to Formula C-4:

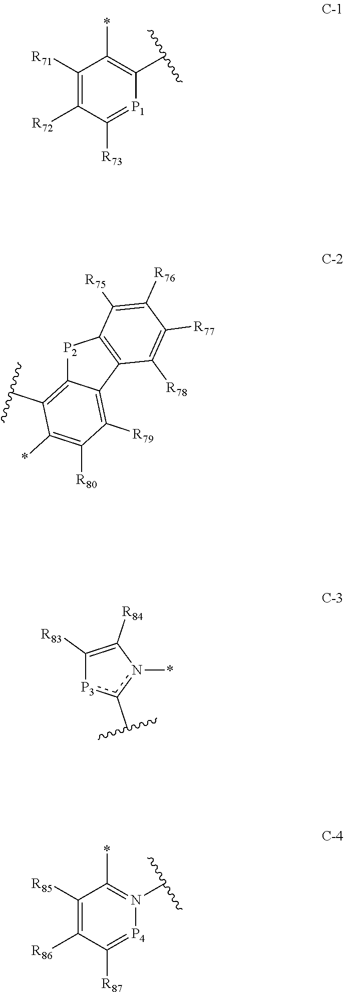

In Formula C-1 to Formula C-4, P₁ may be [symbol] or C(R₇₄), P₂ may be [symbol] or N(R₈₁), P₃ may be [symbol] or N(R₈₂), and P₄ may be [symbol] or C(R₈₈).

In Formula C-1 to Formula C-4, R₇₁ to R₈₈ may each independently be a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In Formula C-1 to Formula C-4, [symbol] represents a bond to Pt, which is a central metal atom, and [symbol] represents a bond to a neighboring cyclic group (C1 to C4) or to a linker (L₁₁ to L₁₃).

In an embodiment, the emission layer EML may include the first compound represented by Formula 1, and at least one of the second compound, the third compound, and the fourth compound. In an embodiment, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. In an embodiment, the fourth compound may be a sensitizer. The fourth compound included in the emission layer EML of the light emitting element ED may serve as a sensitizer to transfer energy from the host to the first compound, which is a light emitting dopant. For example, the fourth compound, which serves as an auxiliary dopant, accelerates energy transfer to the first compound, which serves as a light emitting dopant, thereby increasing an emission ratio of the first compound. Therefore, the emission layer EML may have improved luminous efficiency. When energy transfer to the first compound is increased, excitons formed in the emission layer EML may not accumulate inside the emission layer EML and may emit light rapidly, so that deterioration of the light emitting element ED may be reduced. Therefore, the service life of the light emitting element ED may increase.

The light emitting element ED may include the first compound, the second compound, the third compound, and the fourth compound, and the emission layer EML may include the combination of two host materials and two dopant materials. In the light emitting element ED, the emission layer EML may include the second compound and the third compound, which are two different hosts, the first compound which emits delayed fluorescence, and the fourth compound which includes an organometallic complex, and thus the light emitting element ED may exhibit excellent luminous efficiency characteristics.

In an embodiment, the fourth compound represented by Formula D-1 may be selected from Compound Group 4. In an embodiment, in the light emitting element ED, the fourth compound may include at least one compound selected from Compound Group 4.

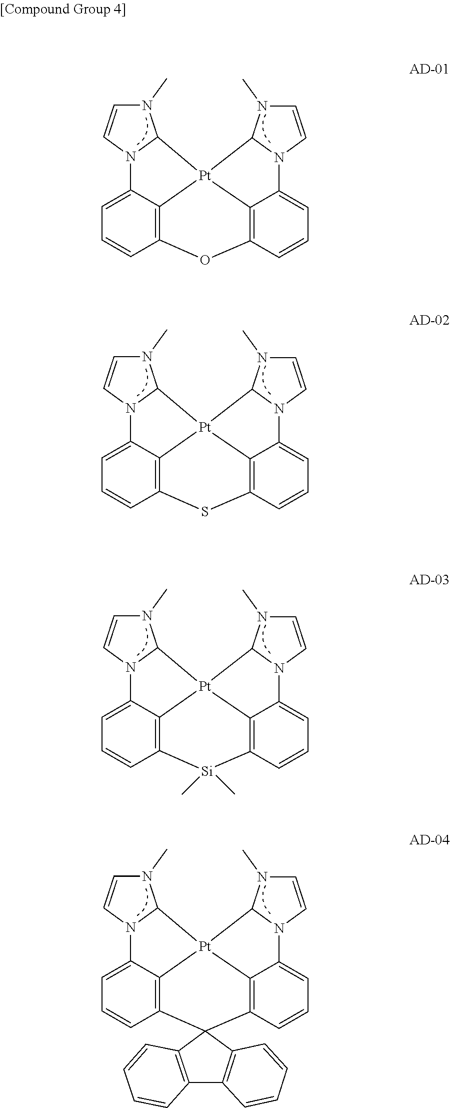

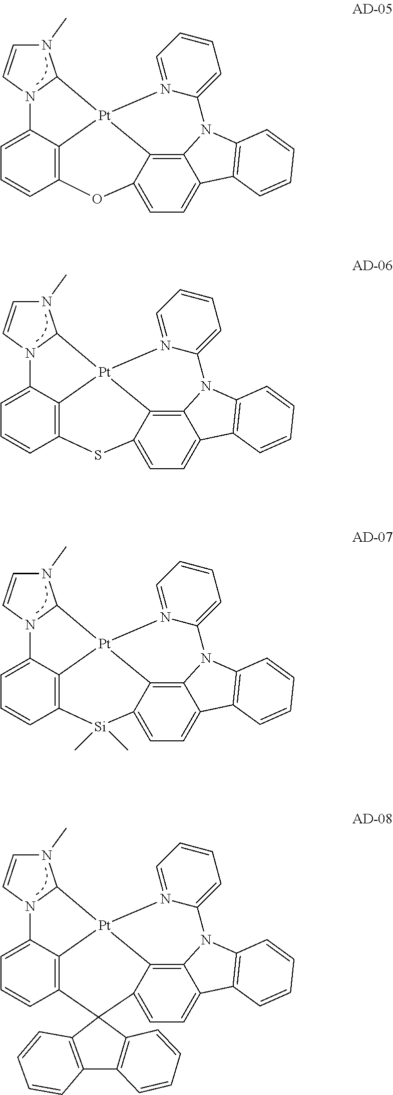

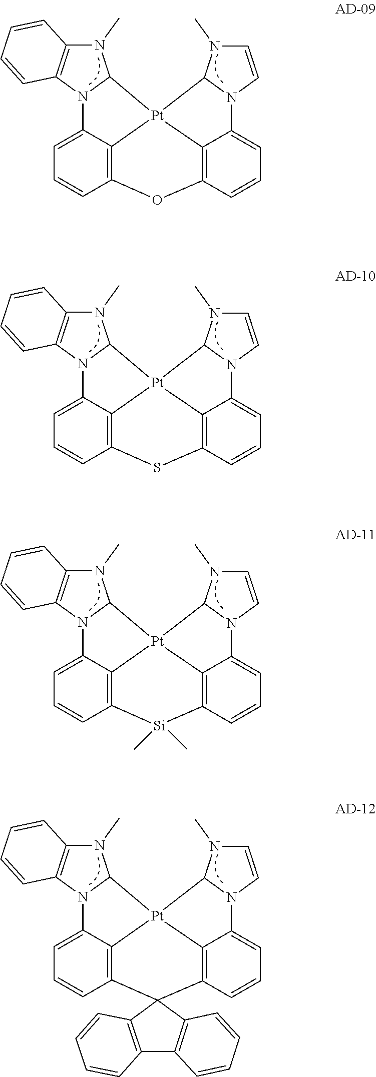

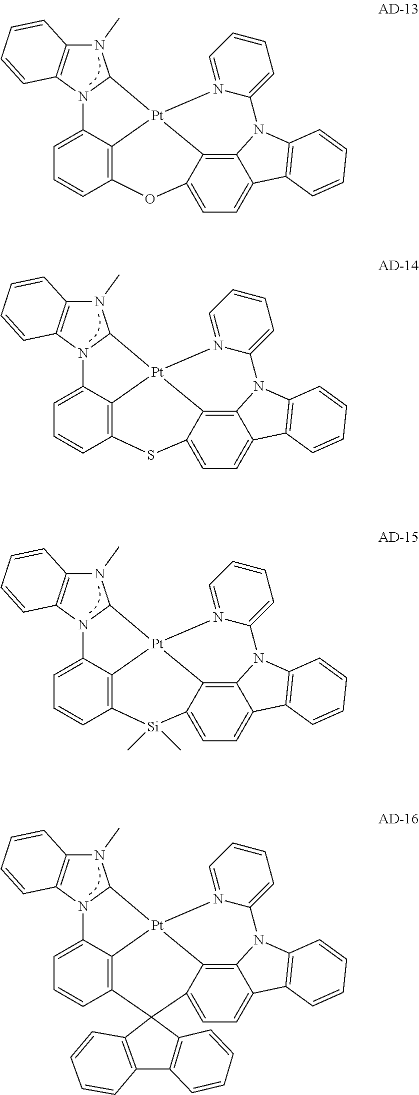

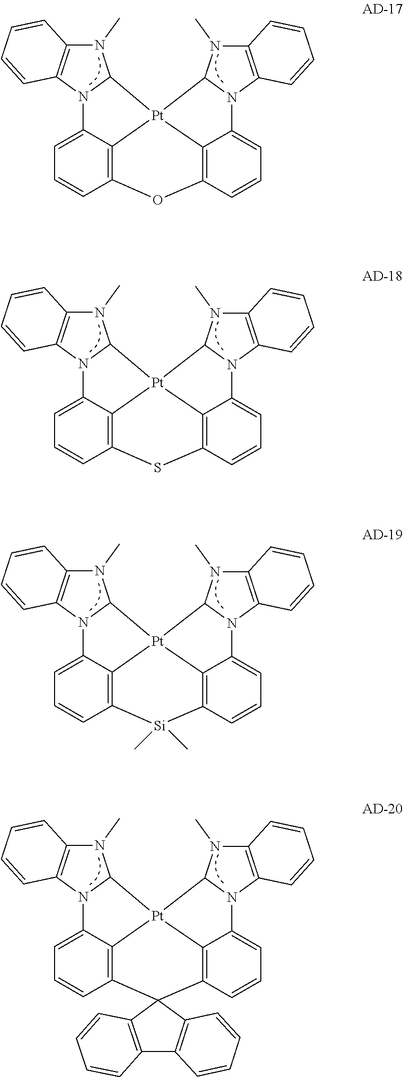

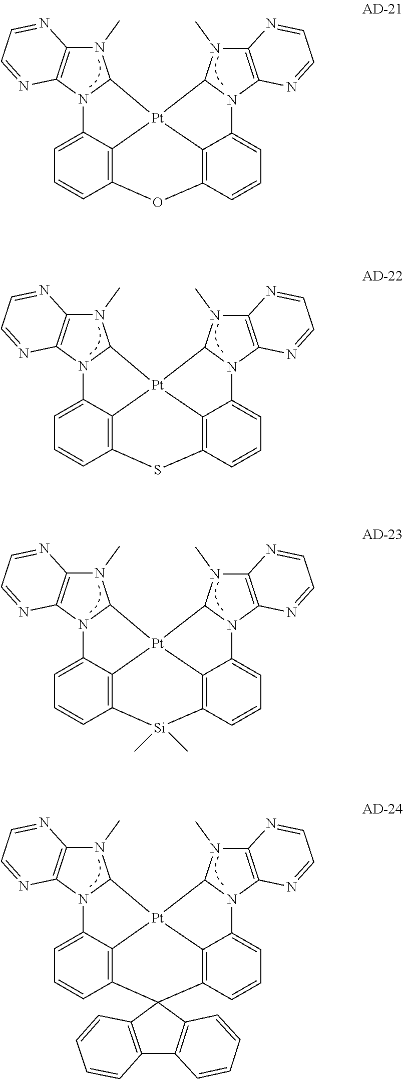

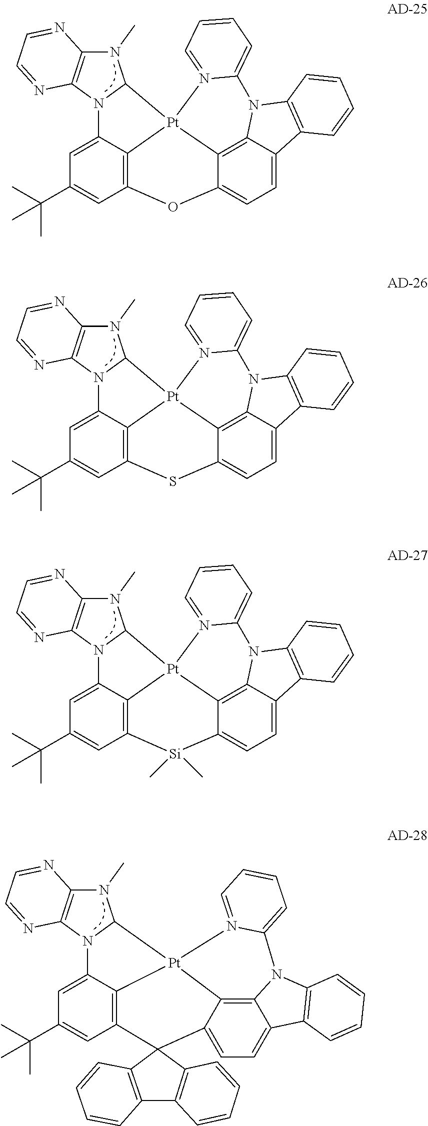

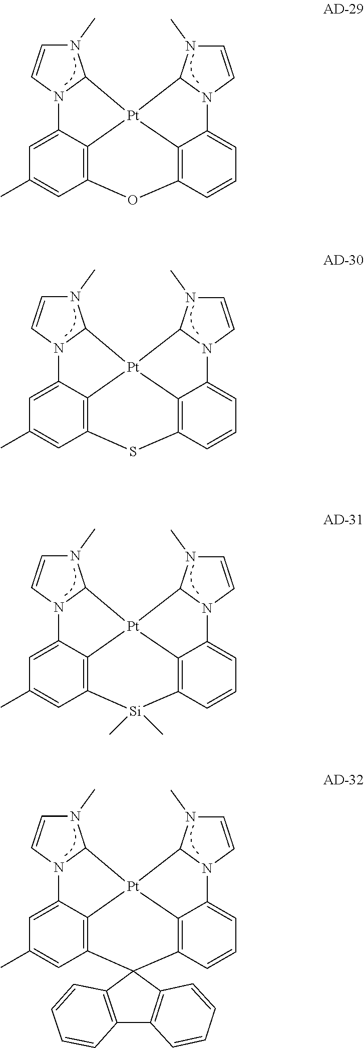

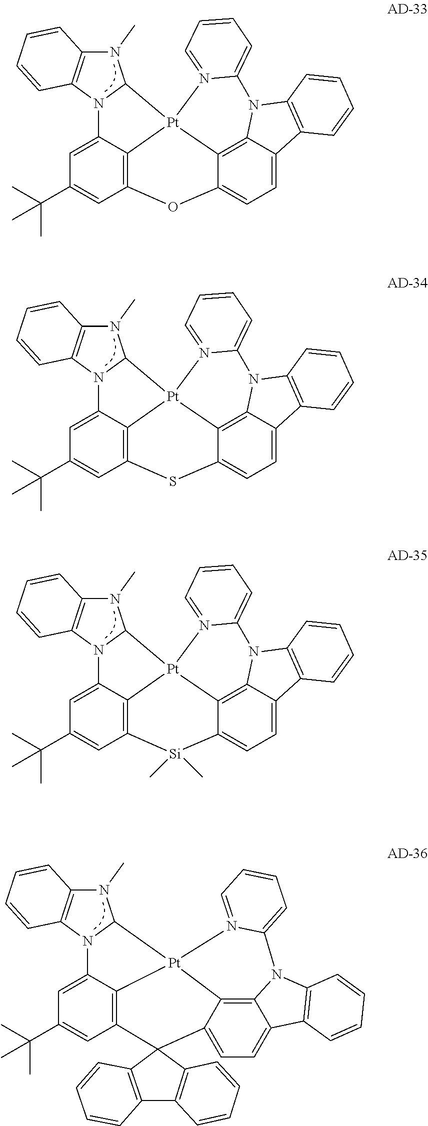

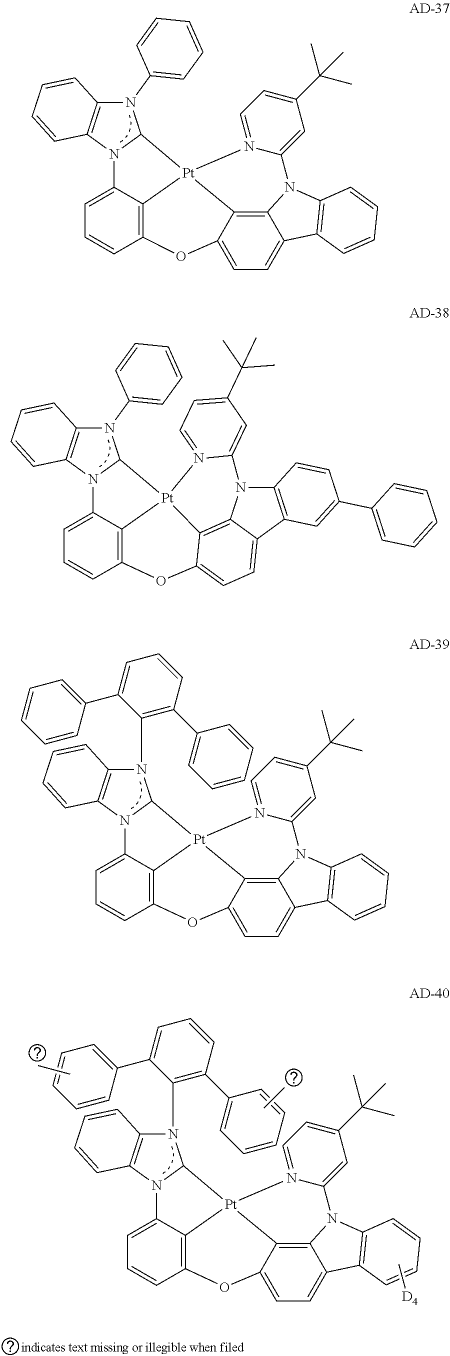

In Compound Group 4, D represents a deuterium atom.

When the emission layer EML in the light emitting element ED includes the first compound, the second compound, and the third compound, an amount of the first compound may be in a range of about 0.1 wt % to about 5 wt %, with respect to a total weight of the first compound, the second compound, and the third compound. However, embodiments are not limited thereto. When an amount of the first compound satisfies the above-described range, energy transfer from the second compound and the third compound to the first compound may increase, and thus the luminous efficiency and device service life may increase.

The combined amounts of the second compound and the third compound in the emission layer EML may be the remainder of the total weight of the first compound, the second compound, and the third compound, excluding the amount of the first compound. For example, a combined amount of the second compound and the third compound in the emission layer EML may be in a range of about 65 wt % to about 95 wt %, with respect to a total weight of the first compound, the second compound, and the third compound.

Within the combined amount of the second compound and the third compound in the emission layer EML, a weight ratio of the second compound to the third compound may be in a range of about 3:7 to about 7:3.

When the amounts of the second compound and the third compound satisfy the above-described ranges and ratios, a charge balance characteristic in the emission layer EML may be improved, and thus the luminous efficiency and device service life may increase. When the amounts of the second compound and the third compound deviate from the above-described ranges and ratios, charge balance in the emission layer EML may not be achieved, and thus the luminous efficiency may be reduced and the device may readily deteriorate.

When the emission layer EML includes the fourth compound, an amount of the fourth compound in the emission layer EML may be in a range of about 10 wt % to about 30 wt %, with respect to a total weight of the first compound, the second compound, the third compound, and the fourth compound. However, embodiments are not limited thereto. When an amount of the fourth compound satisfies the above-described range, energy transfer from the host to the first compound, which is a light emitting dopant, may increase, so that a luminous ratio may be improved, and thus, luminous efficiency of the emission layer EML may be improved. When the amounts of the first compound, the second compound, the third compound, and the fourth compound included in the emission layer EML satisfy the above-described ranges and ratios, excellent luminous efficiency and long service life may be achieved.

In the light emitting element ED, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting element ED according to embodiments as shown in each of FIGS. 3 to 6, the emission layer EML may further include a host and a dopant of the related art, in addition to the above-described host and dopant.

In an embodiment, the emission layer EML may include a compound represented by Formula E-1. The compound represented by Formula E-1 may be used as a fluorescent host material.

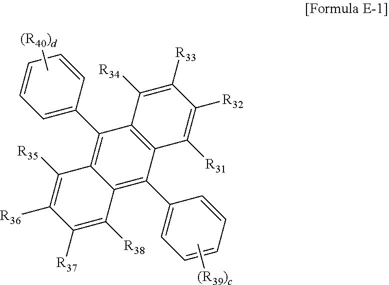

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, in Formula E-1, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19:

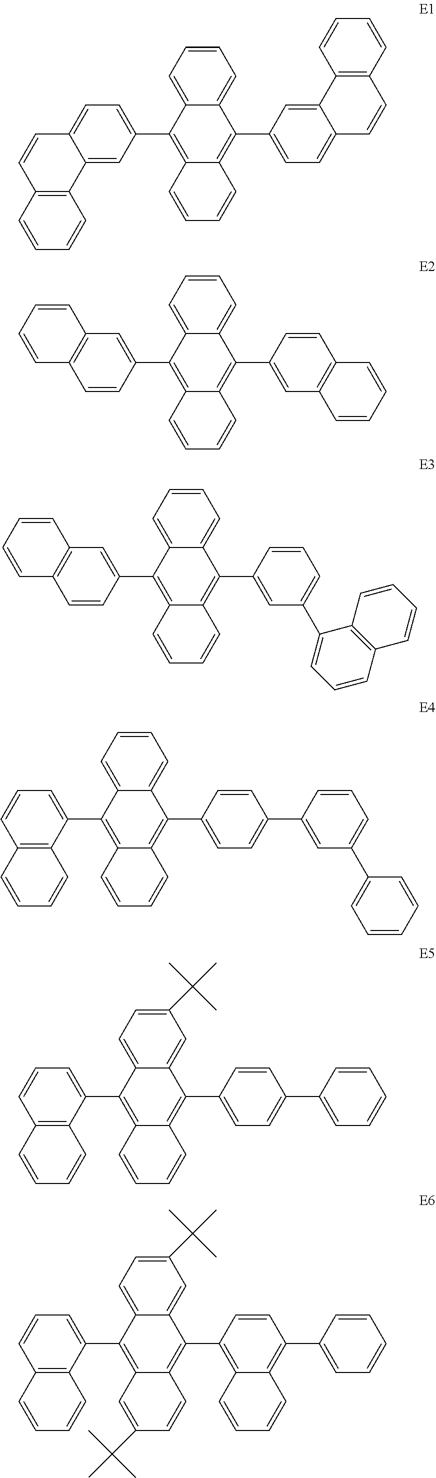

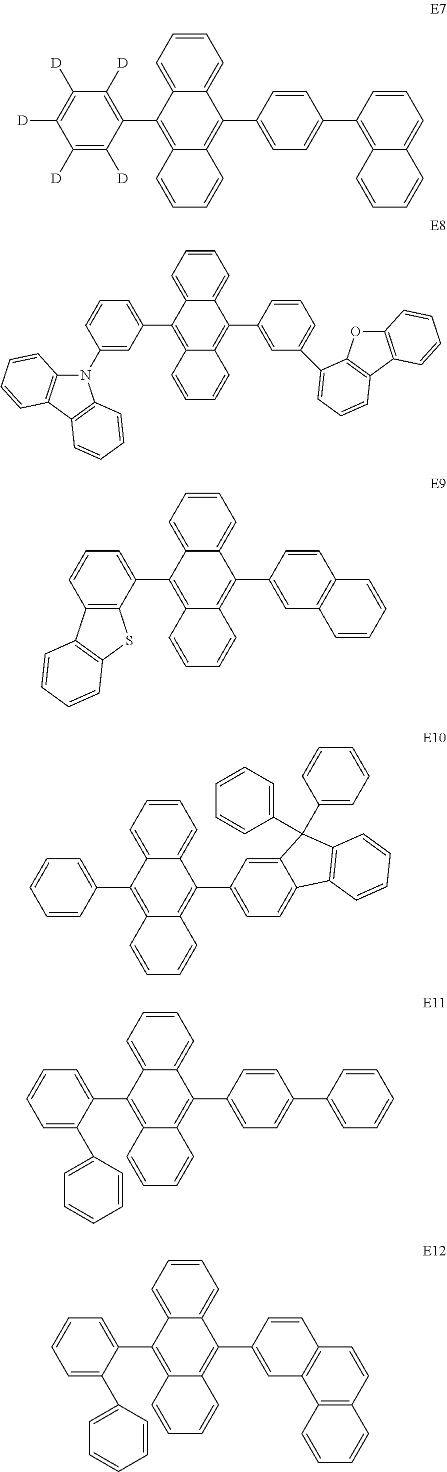

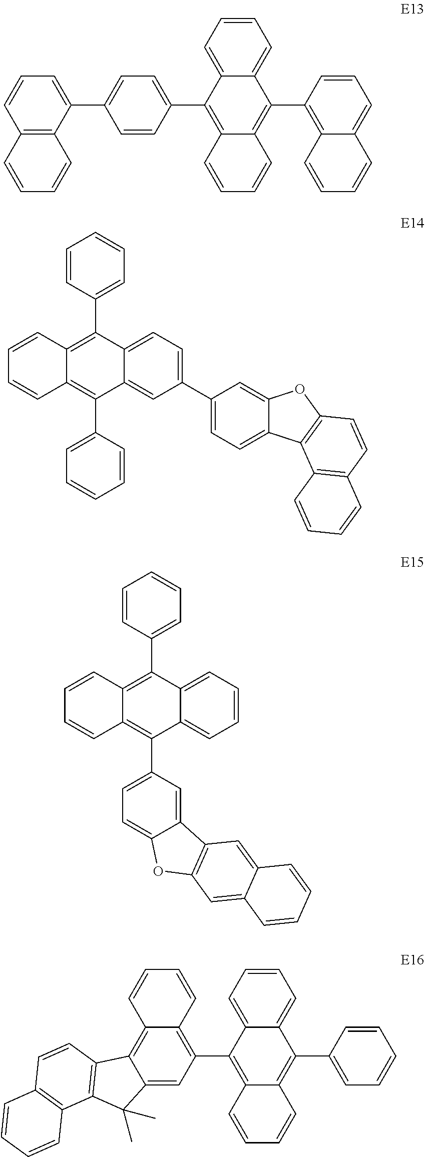

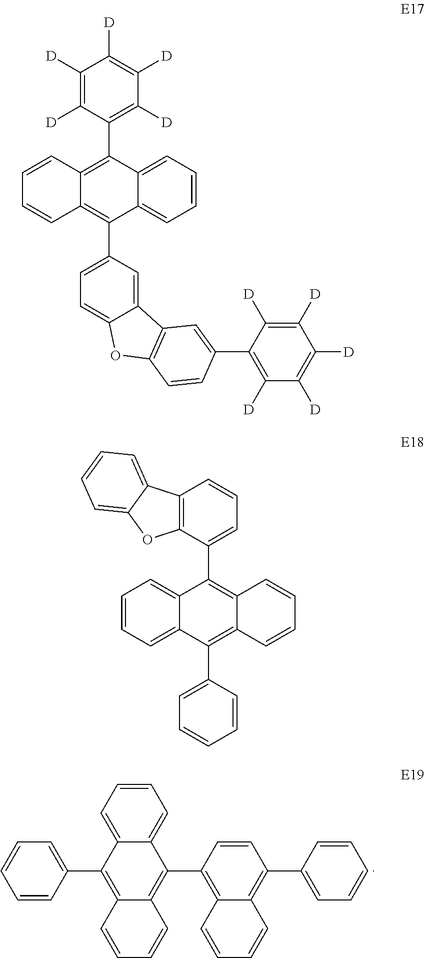

In an embodiment, the emission layer EML may include a compound represented by Formula E-2a or Formula E-2b. The compound represented by Formula E-2a or Formula E-2b may be used as a phosphorescent host material.

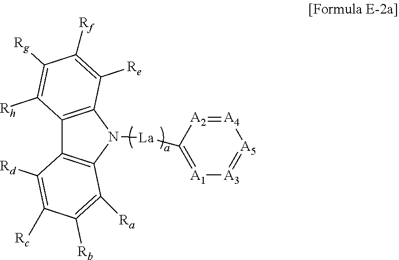

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(R₁). In Formula E-2a, Rₐ to R₁ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, Rₐ to R₁ may be bonded to an adjacent group to form a hydrocarbon ring or a heterocycle including N, O, S, etc., as a ring-forming atom.

In Formula E-2a, two or three of A₁ to A₅ may each be N, and the remainder of A₁ to A₅ may each independently be C(R₁).

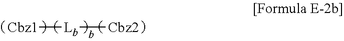

In Formula E-2b, Cbz1 and Cbz2 may each independently be an unsubstituted carbazole group or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or more, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

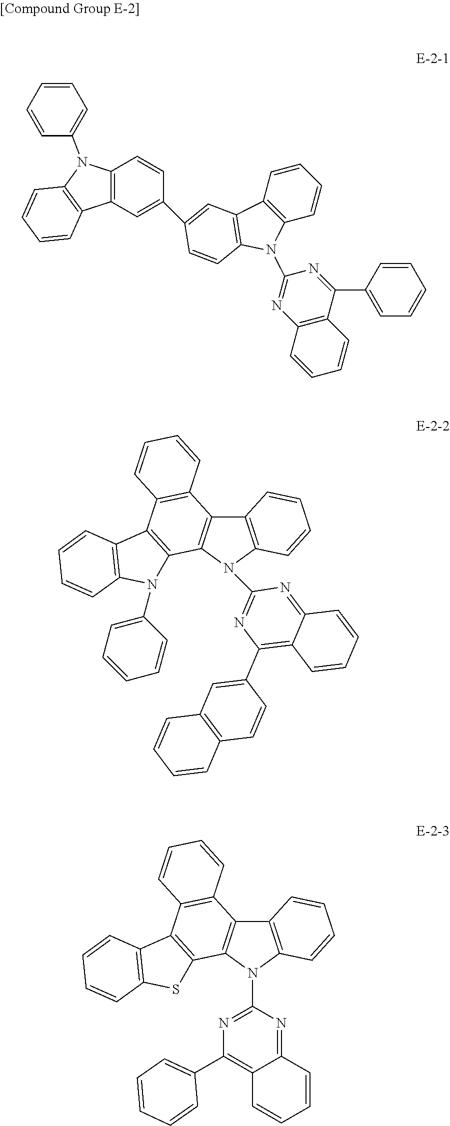 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

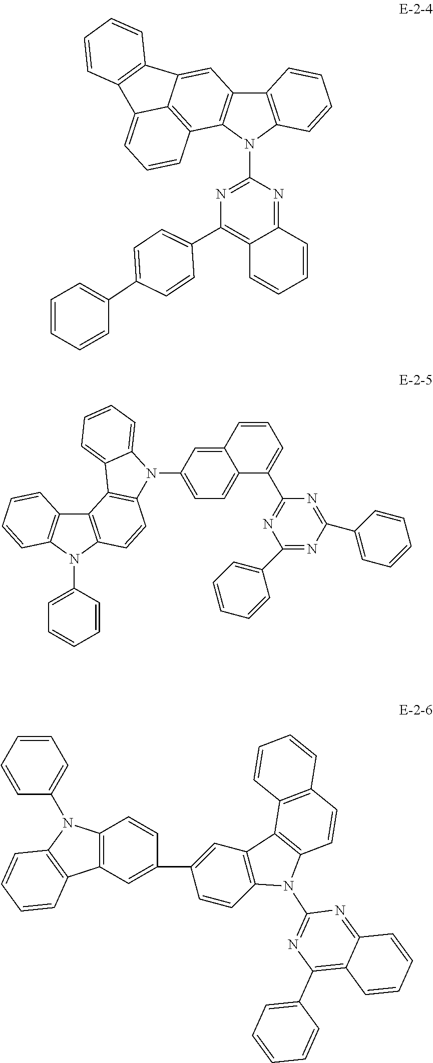 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

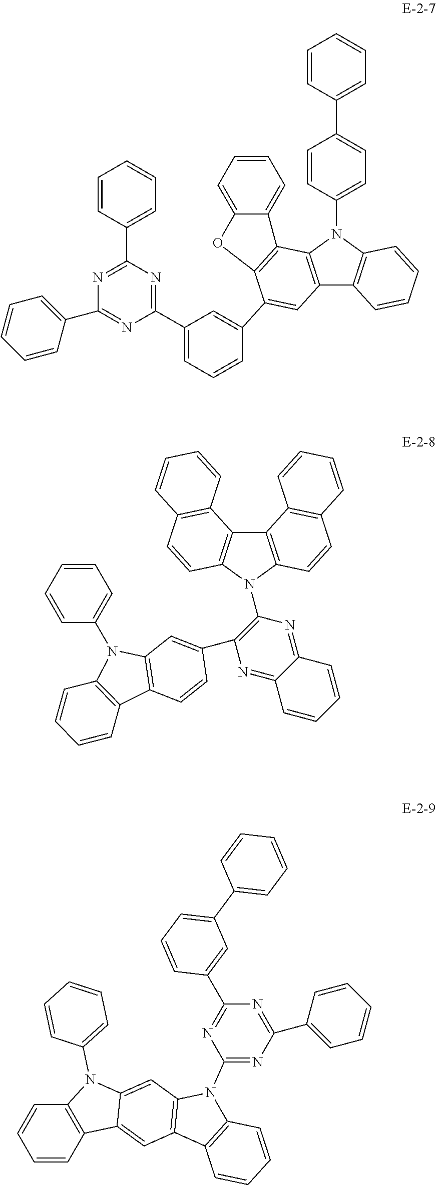 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

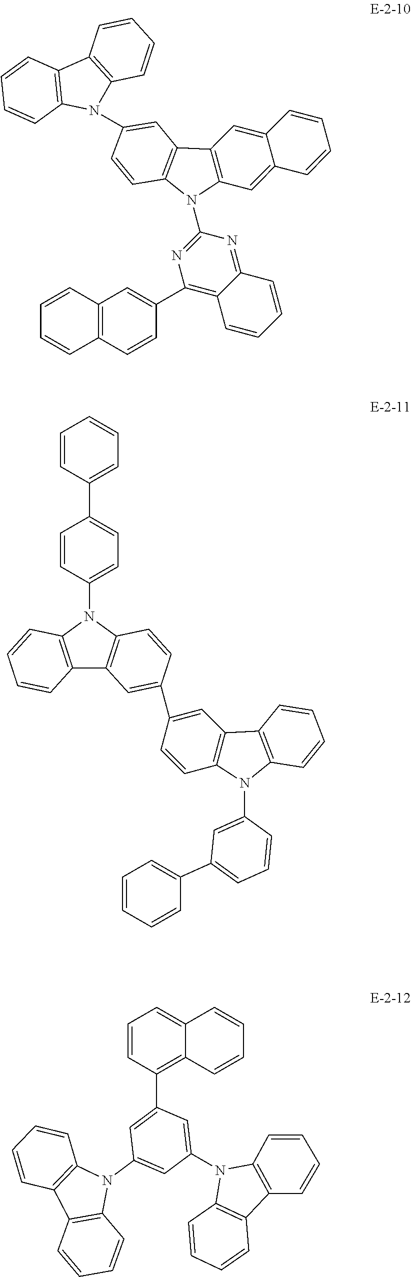 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

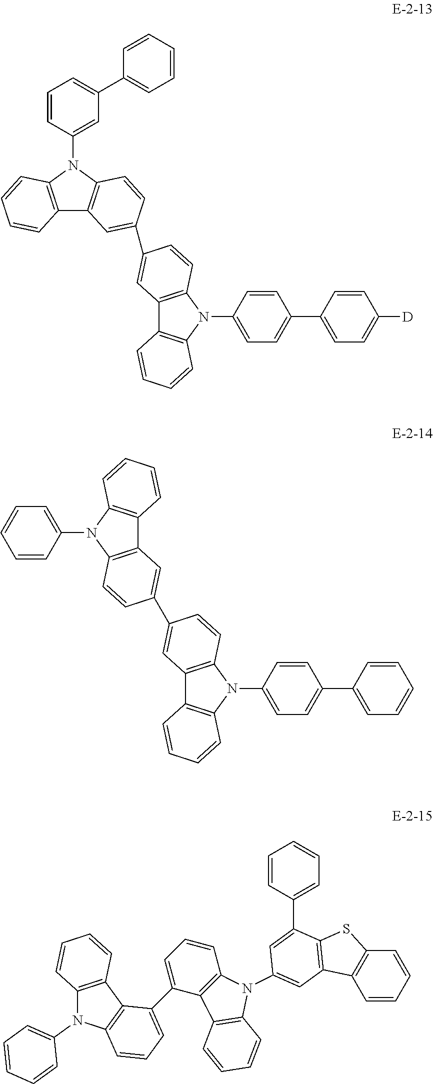 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

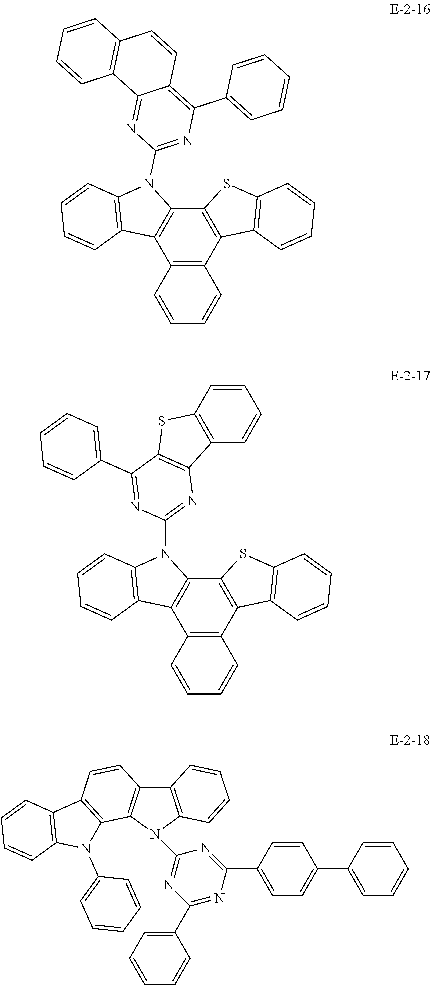 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

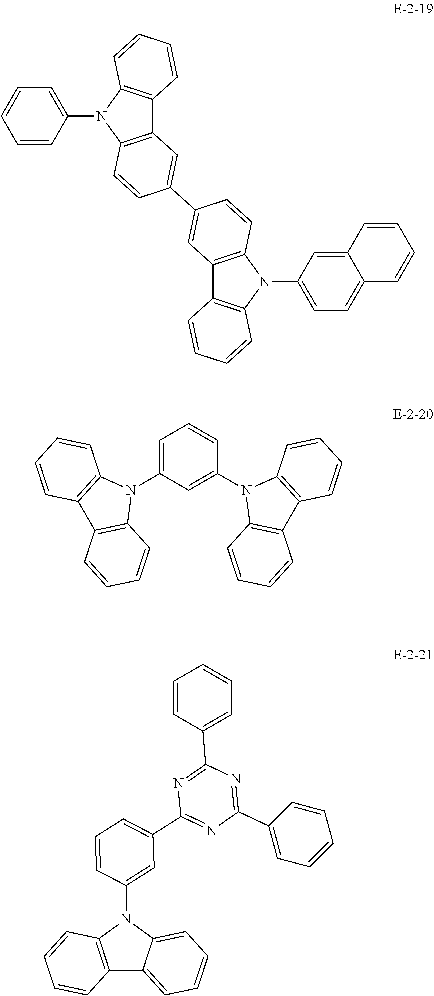 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

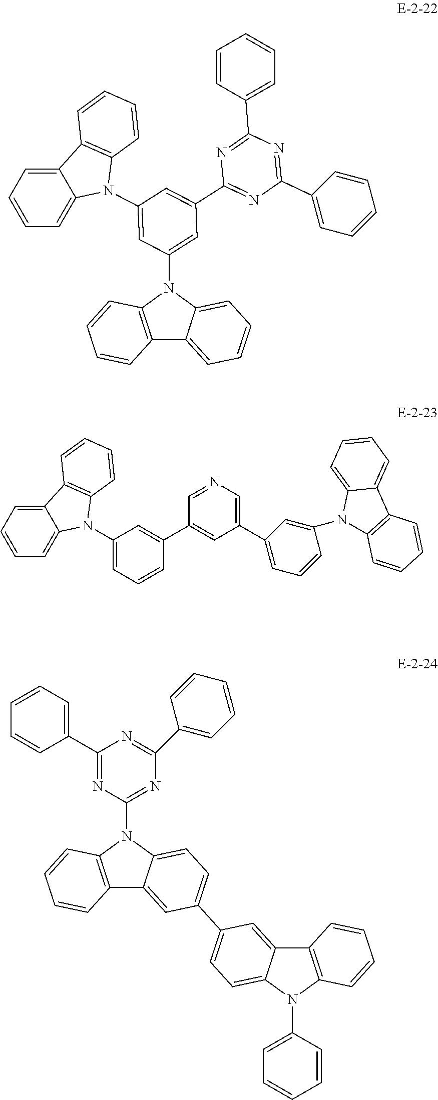 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

In an embodiment, the emission layer EML may include a compound represented by Formula M-a. The compound represented by Formula M-a may be used as a phosphorescent dopant material.

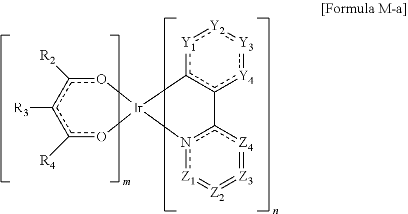

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

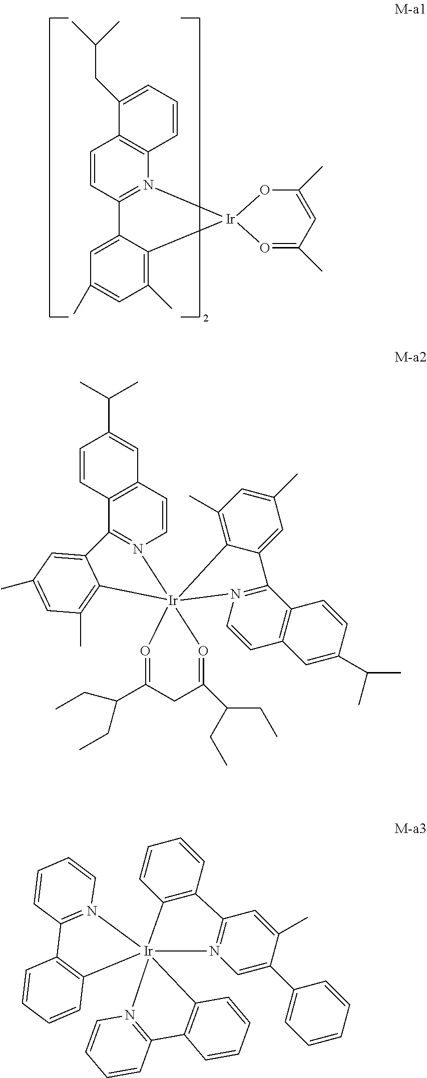

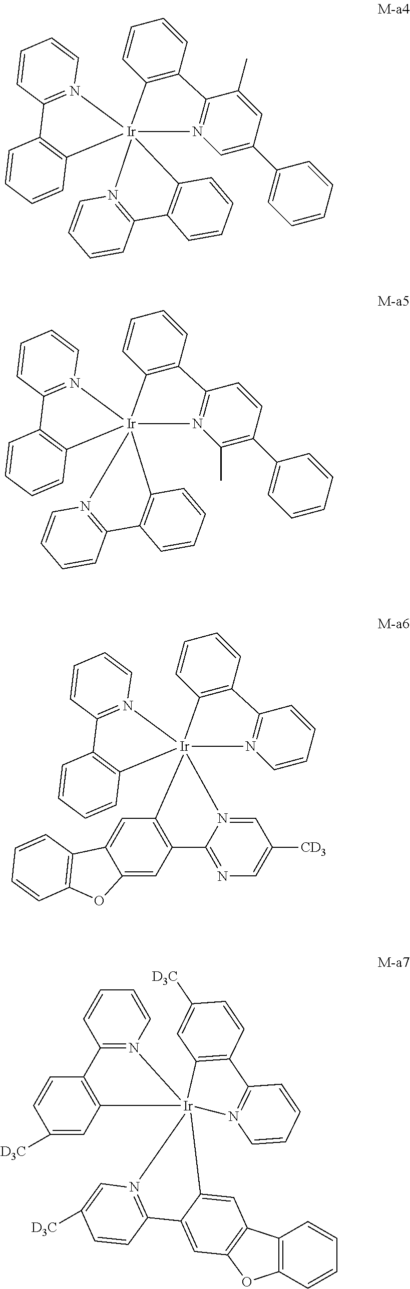

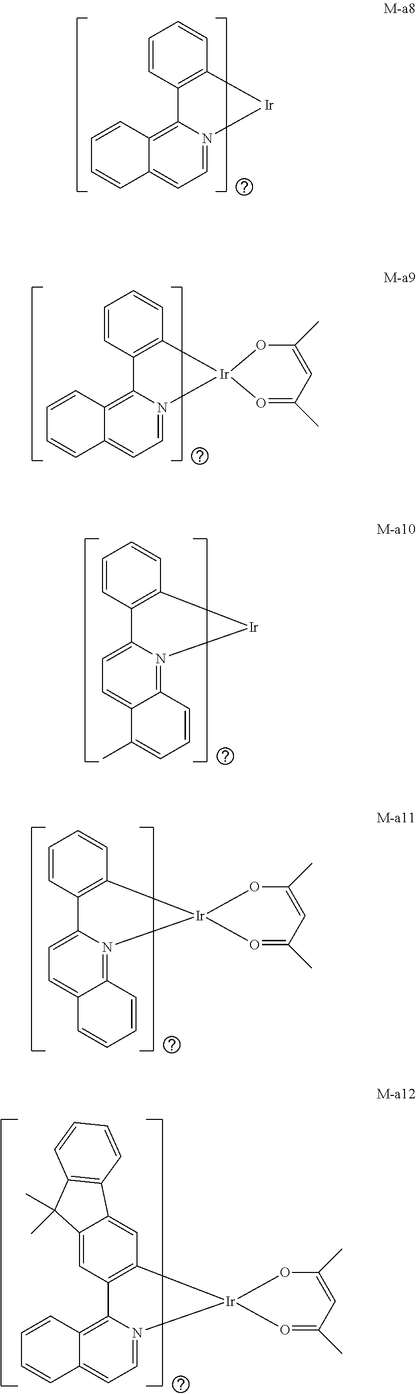

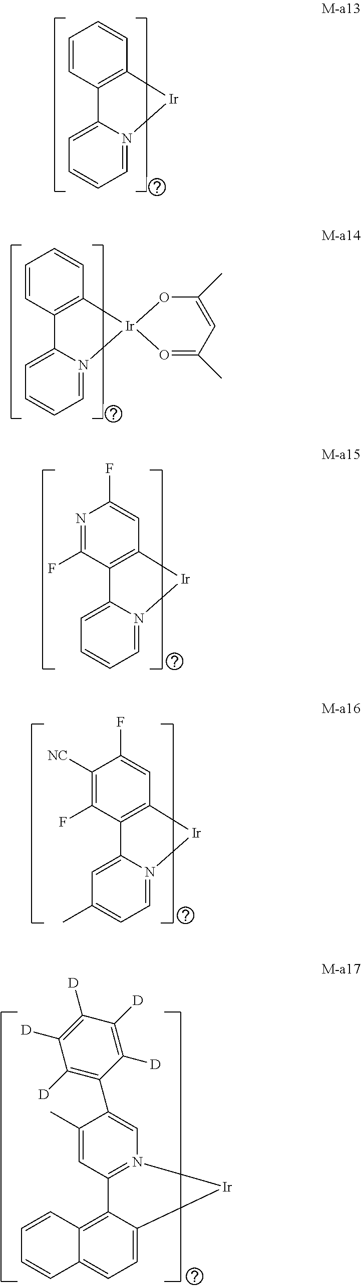

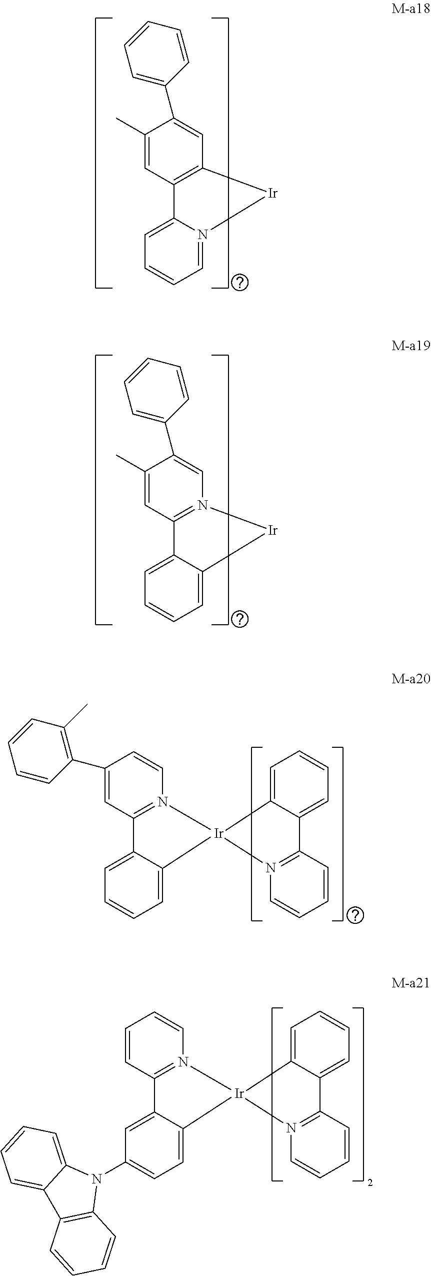

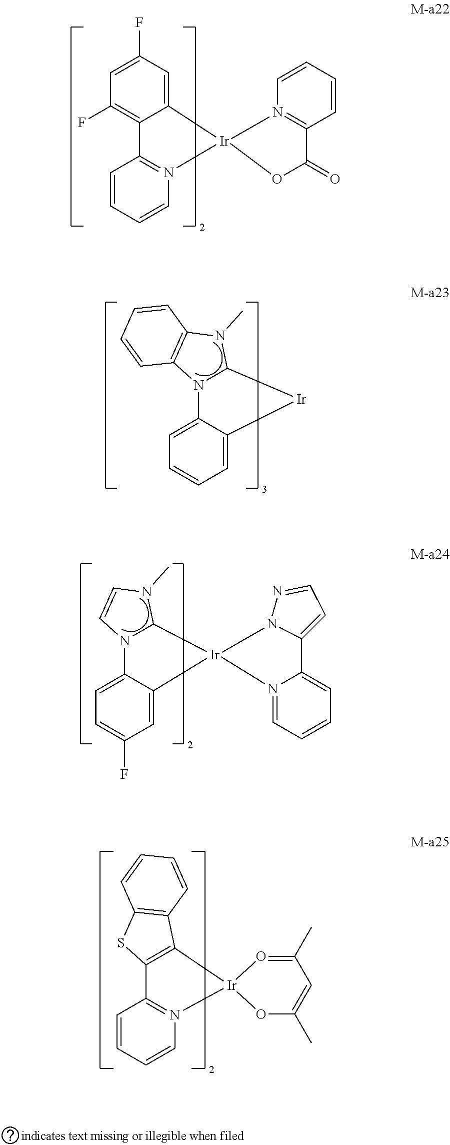

In an embodiment, the emission layer EML may include a compound represented by one of Formula F-a to Formula F-c. The compound represented by one of Formula F-a to Formula F-c may be used as a fluorescence dopant material.

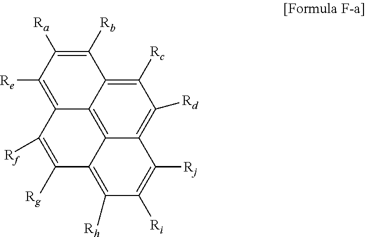

In Formula F-a, two of Rₐ to Rⱼ may each independently be substituted with a group represented by [symbol] . The remainder of Rₐ to Rⱼ which are not substituted with the group represented by [symbol] may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by [symbol] and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may each independently be a heteroaryl group including O or S as a ring-forming atom.

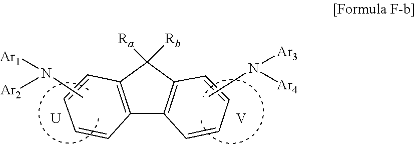

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ to Ar₄ may be a heteroaryl group including O or S as a ring-forming atom.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. When the number of U or V is 1, a fused ring may be present at a portion indicated by U or V, and when the number of U or V is 0, a fused ring may not be present at the portion indicated by U or V. When the number of U is 0 and the number of V is 1, or when the number of U is 1 and the number of V is 0, a fused ring having a fluorene core of Formula F-b may be a cyclic compound having four rings. When the number of U and V is each 0, a fused ring having a fluorene core of Formula F-b may be a cyclic compound having three rings. When the number of U and V is each 1, a fused ring having a fluorene core of Formula F-b may be a cyclic compound having five rings.

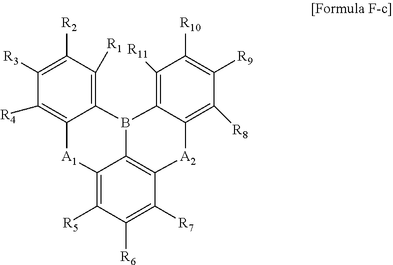

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In Formula F-c, A₁ and A₂ may each independently be bonded to a substituent of an adjacent ring to form a fused ring. For example, when A₁ and A₂ are each independently N(Rₘ), A₁ may be bonded to R₄ or R₅ to form a ring. For example, A₂ may be bonded to R₇ or R₈ to form a ring.

In an embodiment, the emission layer EML may further include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex including iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2) (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

In an embodiment, the emission layer EML may include a quantum dot. The quantum dot may be a Group II-VI compound, a Group III-VI compound, a Group 1-III-VI compound, a Group III-V compound, a Group III-II-V compound, a Group IV-VI compound, a Group IV element, a Group IV compound, or a combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof; or any combination thereof.

Examples of a Group III-VI compound may include: a binary compound such as In₂S₃ or In₂Se₃; a ternary compound such as InGaS₃ or InGaSe₃; or any combination thereof.

Examples of a Group 1-III-VI compound may include: a ternary compound selected from the group consisting of AgInS, AgInS₂, CuInS, CuInS₂, AgGaS₂, CuGaS₂ CuGaO₂, AgGaO₂, AgAlO₂, and a mixture thereof; a quaternary compound such as AgInGaS₂ or CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; or any combination thereof. In an embodiment, a Group III-V compound may further include a Group II metal. For example, InZnP, etc., may be selected as a Group III-II-V compound.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof. Examples of a Group IV element may include Si, Ge, and a mixture thereof. Examples of a Group IV compound may include a binary compound selected from the group consisting of SiC, SiGe, and a mixture thereof.

Each element included in a polynary compound, such as a binary compound, a ternary compound, or a quaternary compound, may be present in a particle at a uniform concentration distribution or at a non-uniform concentration distribution. For example, a formula may indicate the elements included in a compound, but an elemental ratio in the compound may be different. For example, AgInGaS₂ may mean AgInₓGa₁₋ₓS₂ (where x is a real number from 0 to 1).

In an embodiment, a quantum dot may have a single structure, in which the concentration of each element included in the quantum dot is uniform, or a quantum dot may have a core-shell structure in which a quantum dot surrounds another quantum dot. For example, a material included in the core may be different from a material included in the shell.

The shell of the quantum dot may serve as a protection layer to prevent the chemical deformation of the core to maintain semiconductor properties, and/or may serve as a charging layer to impart electrophoresis properties to the quantum dot. The shell may be a single layer or multiple layers. An interface between the core and the shell may have a concentration gradient in which the concentration of an element that is present in the shell decreases towards the core.

In embodiments, the quantum dot may have the above-described core/shell structure including a core includes nanocrystals and a shell surrounding the core. Examples of a shell of a quantum dot may include a metal oxide, a non-metal oxide, a semiconductor compound, or a combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, or CoMn₂O₄; or any combination thereof. However, embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Color purity or color reproducibility may be improved in any of the above ranges. Light emitted through a quantum dot may be emitted in all directions, so that a wide viewing angle may be improved.

The form of a quantum dot is not particularly limited and may be any form used in the related art. For example, the quantum dot may have a spherical shape, a pyramidal shape, a multi-arm shape, or a cubic shape, or the quantum dot may be in the form of nanoparticles, nanotubes, nanowires, nanofibers, nanoplate particles, etc.

As a size of the quantum dot is adjusted or an elemental ratio of a quantum dot compound is adjusted, it is possible to control the energy band gap, and thus light in various wavelength ranges may be obtained from a quantum dot emission layer. Therefore, a quantum dot as described above (using different sizes of quantum dots or different elemental ratios in the quantum dot compound) may be implemented, so that a light emitting element may emit light in various wavelengths. For example, a size of a quantum dot or an elemental ratio of a quantum dot compound may each independently be adjusted to emit red light, green light, and/or blue light. For example, quantum dots may be configured to emit white light by combining various colors of light.

In the light emitting element ED according to an embodiment as shown in each of FIGS. 3 to 6, the electron transport region ETR may be provided on the emission layer EML. The electron transport region ETR may include at least one of a hole blocking layer HBL, an electron transport layer ETL, and an electron injection layer EIL, but embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In other embodiment, the electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. The electron transport region ETR may have a thickness in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-2:

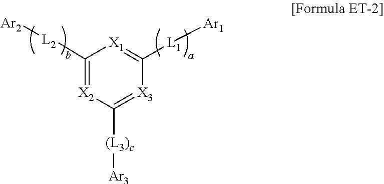

In Formula ET-2, at least one of X₁ to X₃ may each be N; and the remainder of X₁ to X₃ may each independently be C(Rₐ). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include at least one compound selected from Compound ET1 to Compound ET36:

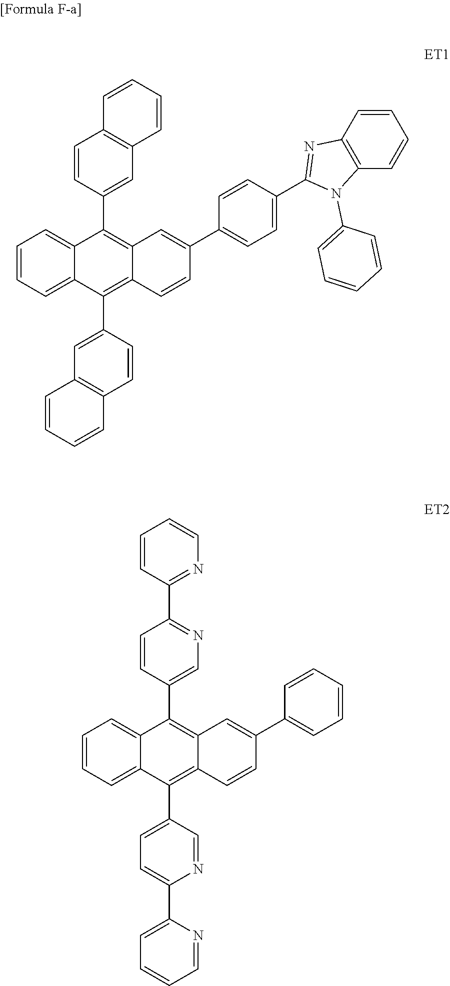 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1]

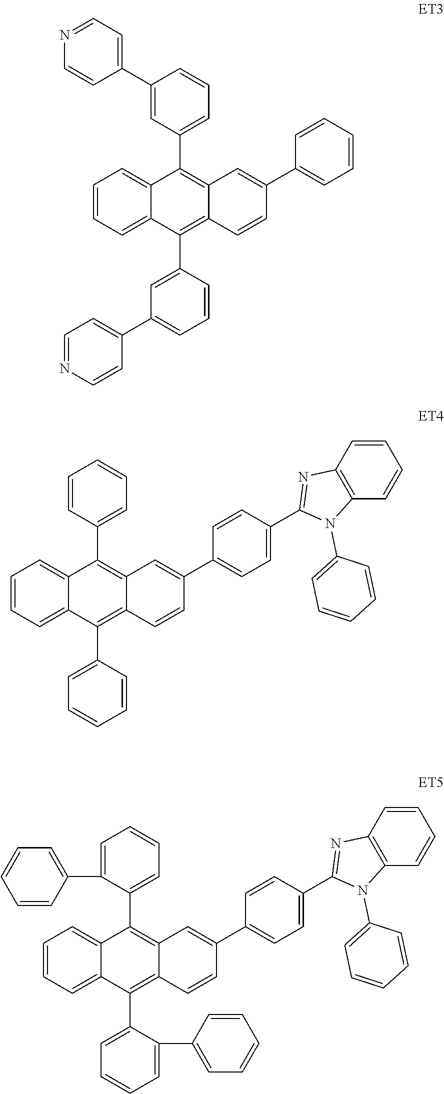 [SMILES: c1ccc(-c2ccc3c(-c4cccc(-c5ccncc5)c4)c4ccccc4c(-c4cccc(-c5ccncc5)c4)c3c2)cc1 ; c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1]

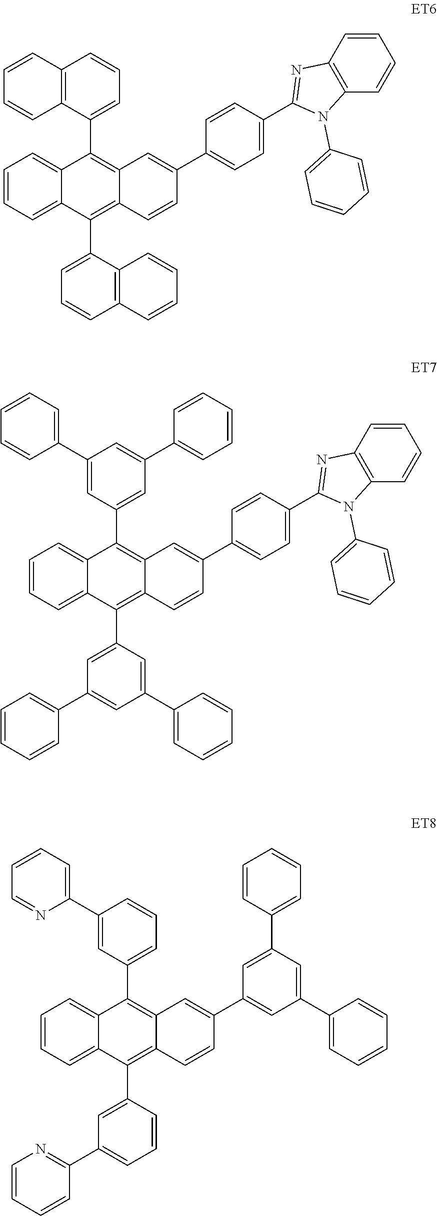 [SMILES: c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1]

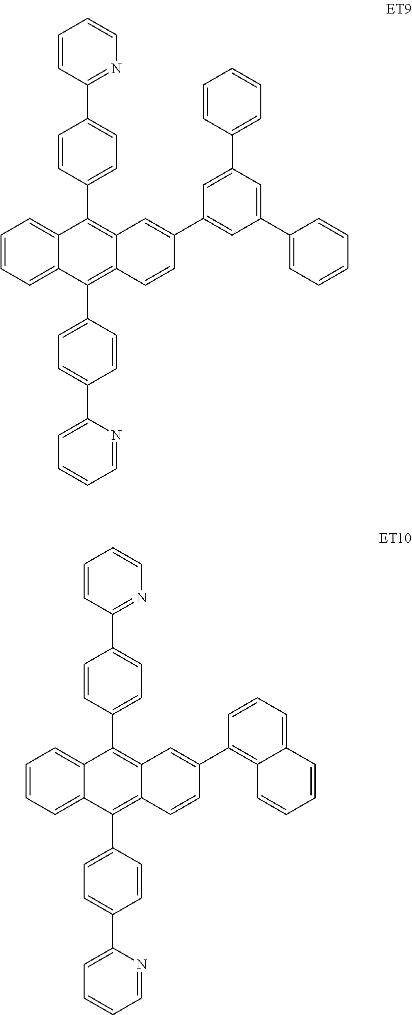 [SMILES: c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

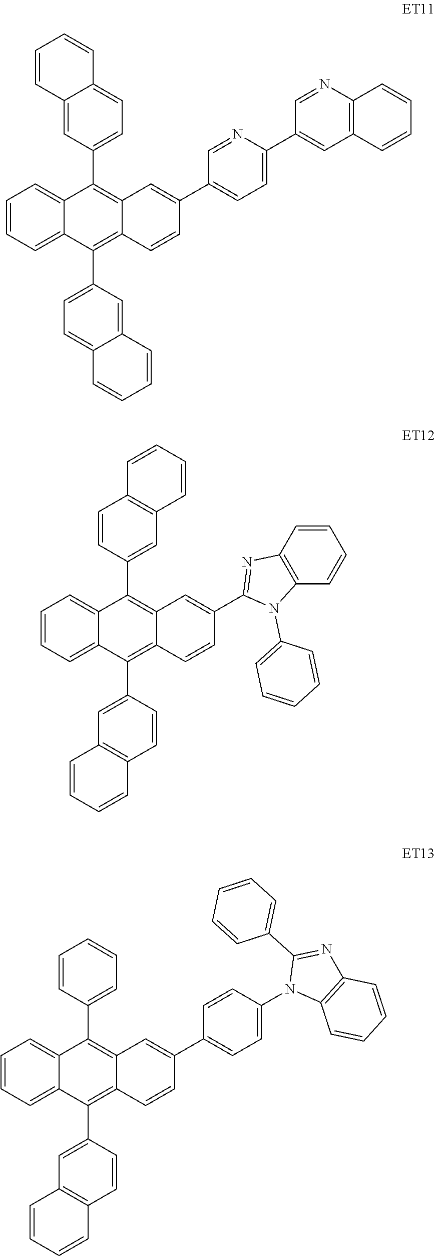 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

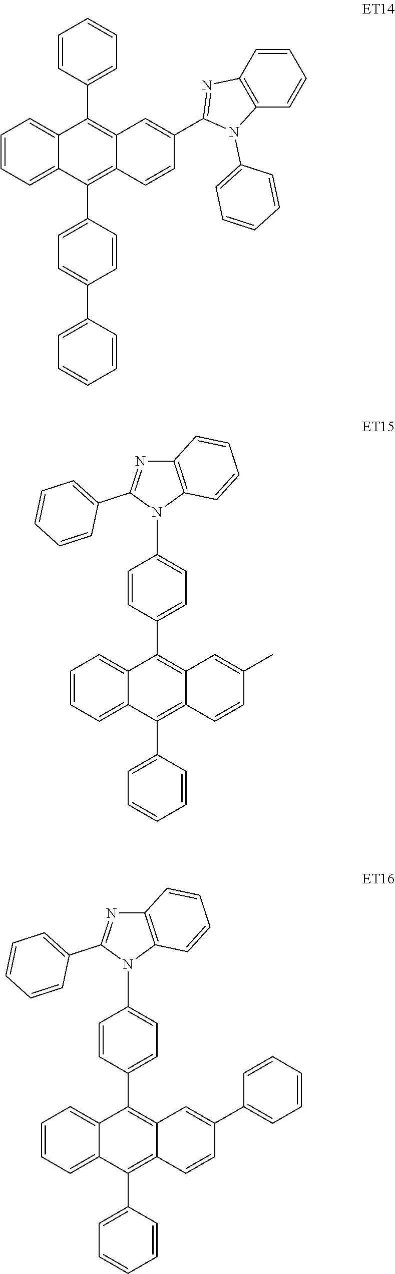 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

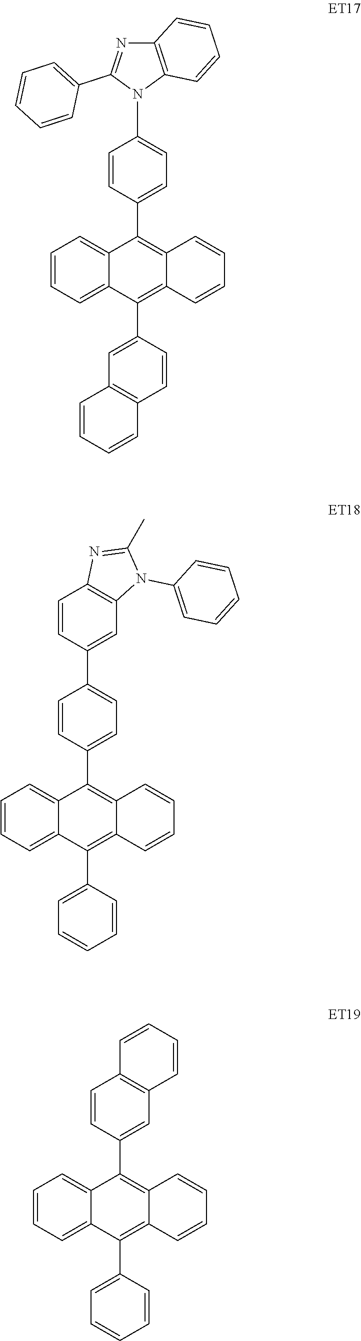

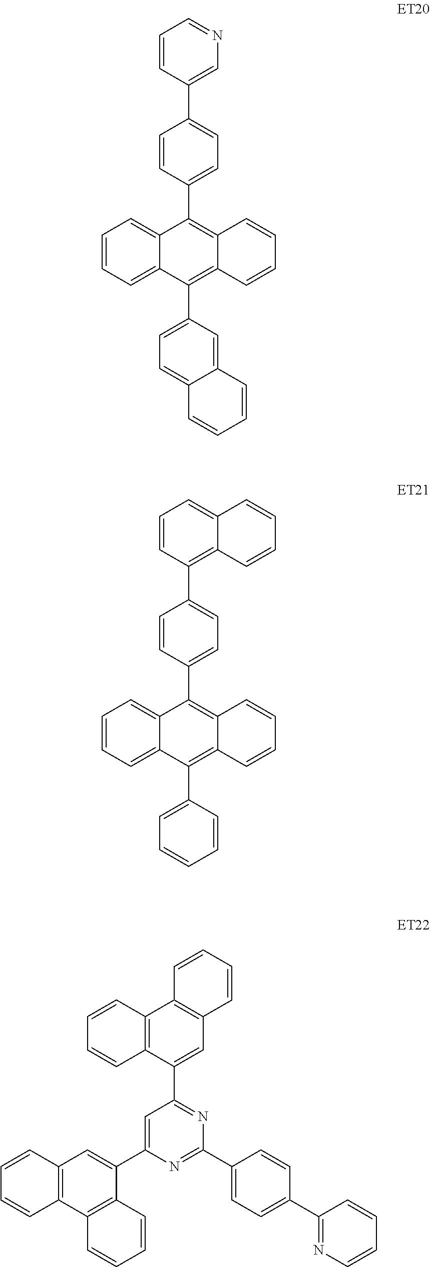

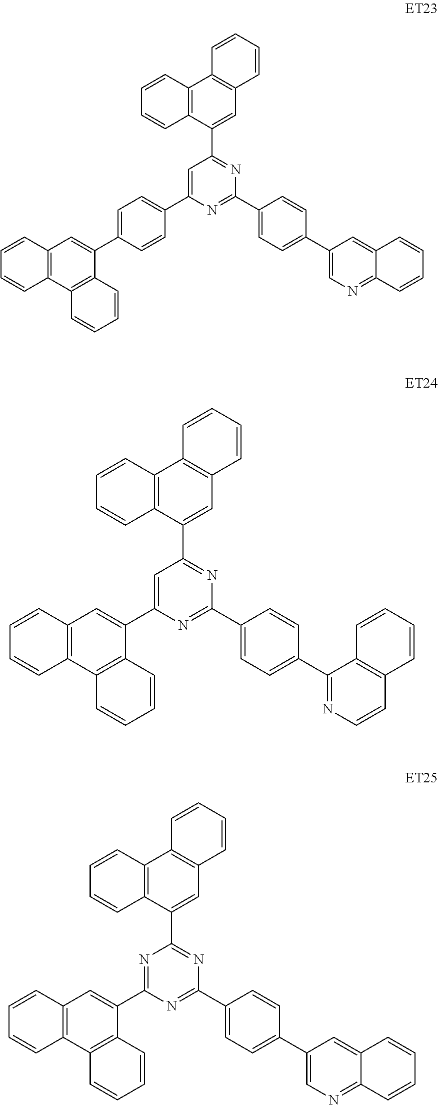 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

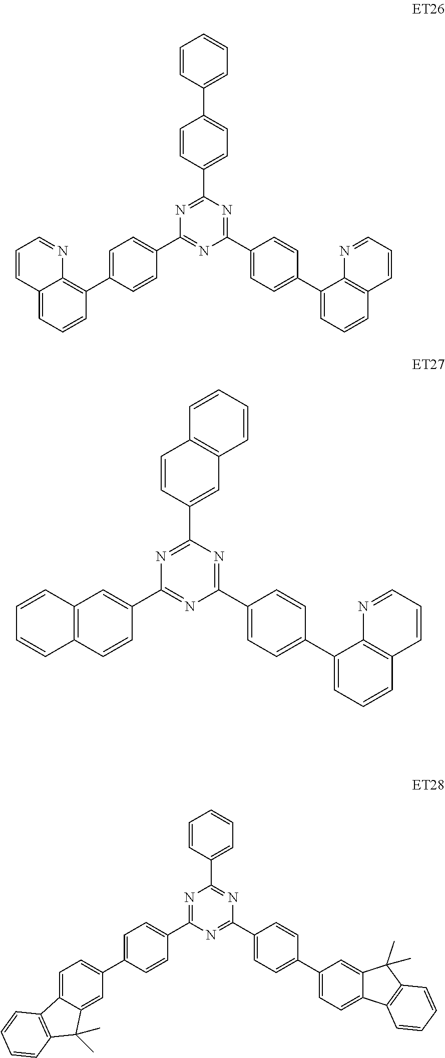 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

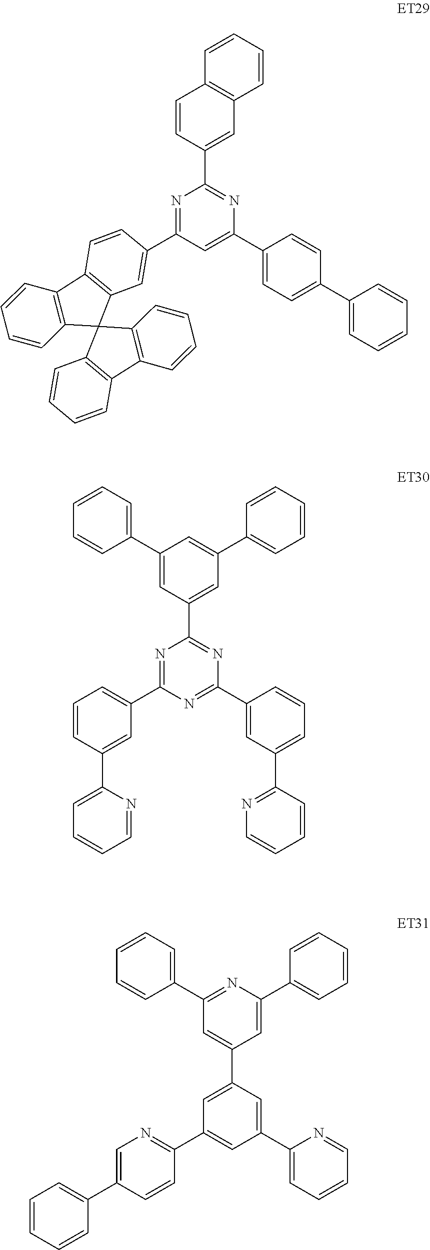 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

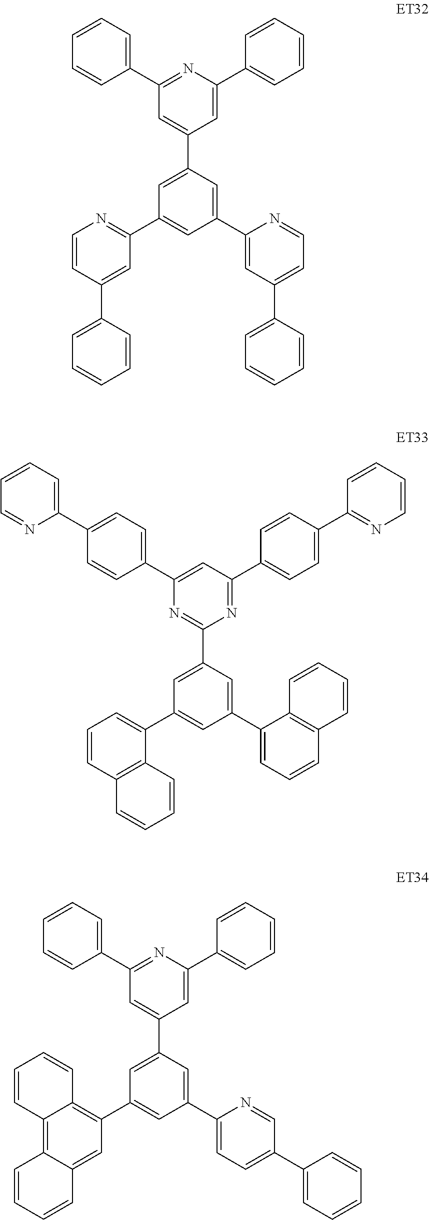 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

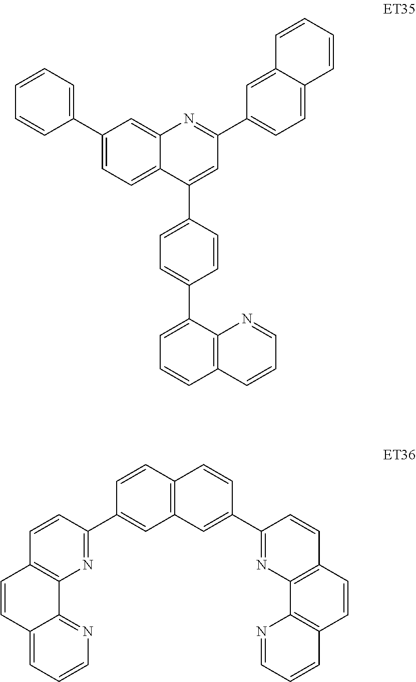 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a metal halide such as LiF, NaCl, CsF, RbCl, RbI, CuI, and KI; a lanthanide metal such as Yb; or a co-deposited material of a metal halide and a lanthanide metal. For example, the electron transport region ETR may include KI:Yb, RbI:Yb, LiF:Yb, etc., as a co-deposited material. The electron transport region ETR may be formed of a metal oxide such as Li₂O or BaO, or 8-hydroxyl-lithium quinolate (Liq), etc., but embodiments are not limited thereto. The electron transport region ETR may also be formed of a mixture material of an electron transport material and an insulating organometallic salt. The insulating organometallic salt may be a material having an energy band gap equal to or greater than about 4 eV. For example, the insulating organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the above-described materials, but embodiments are not limited thereto.

The electron transport region ETR may include the above-described compounds of the electron transport region in at least one of an electron injection layer EIL, an electron transport layer ETL, and a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb).

In an embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL includes an inorganic material, the inorganic material may include an alkaline metal compound (e.g., LiF), an alkaline earth metal compound (e.g., MgF₂), SiON, SiNₓ, SiO_{y}, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as methacrylate. However, embodiments are not limited thereto. In an embodiment, the capping layer CPL may include at least one of Compounds P1 to P5:

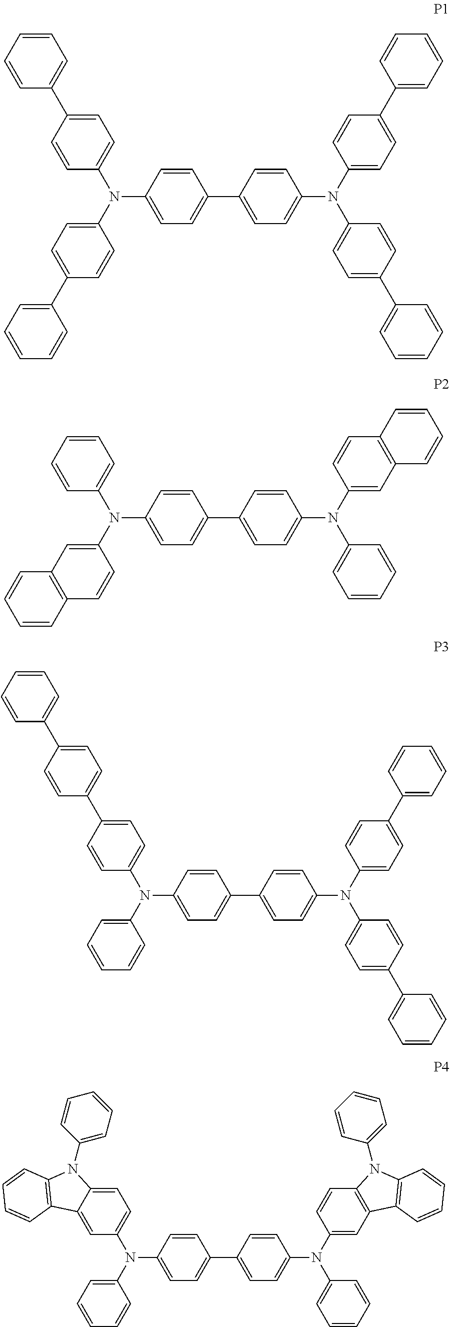 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

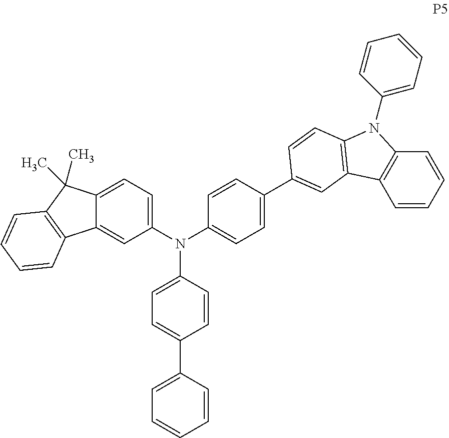 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6.

For example, the refractive index of the capping layer CPL may be equal to or greater than about 1.6 with respect to light in a wavelength range of about 550 nm to about 660 nm.

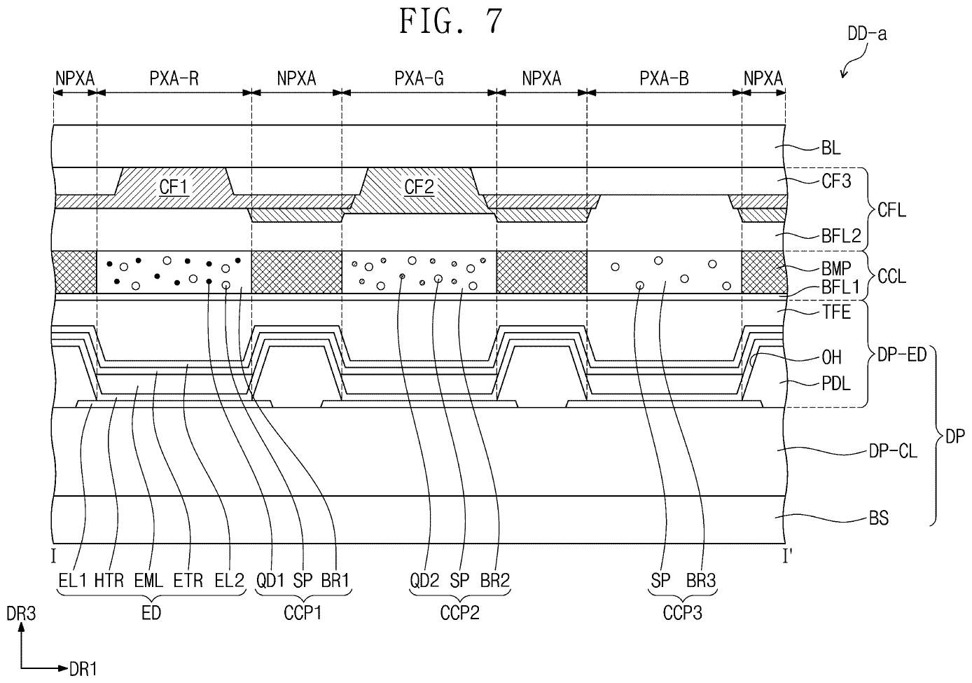

FIGS. 7 to 10 are each a schematic cross-sectional view of a display apparatus according to an embodiment. In the descriptions of the display apparatuses according to embodiments as shown in FIGS. 7 to 10, the features which have been described above with respect to FIGS. 1 to 6 will not be explained again, and the differing features will be described.

Referring to FIG. 7, the display apparatus DD-a according to an embodiment may include a display panel DP including a display device layer DP-ED, a light control layer CCL disposed on the display panel DP, and a color filter layer CFL.

In an embodiment shown in FIG. 7, the display panel DP may include a base layer BS, a circuit layer DP-CL provided on the base layer BS, and the display device layer DP-ED, and the display device layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 7 may be the same as a structure of a light emitting element ED according to one of FIGS. 3 to 6 as described above.

The emission layer EML of the light emitting element ED included in a display apparatus DD-a according to an embodiment may include the fused polycyclic compound according to an embodiment described above.

Referring to FIG. 7, the emission layer EML may be disposed in an opening OH defined in a pixel defining film PDL. For example, the emission layer EML, which is separated by the pixel defining film PDL and correspondingly provided to each of the light emitting regions PXA-R, PXA-G, and PXA-B, may emit light in a same wavelength range. In the display apparatus DD-a, the emission layer EML may emit blue light. Although not shown in the drawings, in an embodiment, the emission layer EML may be provided as a common layer for each of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and emit the resulting light. For example, the light control layer CCL may be a layer including a quantum dot or a layer including a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3, which are spaced apart from each other, but embodiments are not limited thereto. In FIG. 7, it is shown that the divided patterns BMP do not overlap the light control parts CCP1, CCP2, and CCP3, but the edges of the light control parts CCP1, CCP2, and CCP3 may overlap at least a portion of the divided patterns BMP.

The light control layer CCL may include a first light control part CCP1 including a first quantum dot QD1 that converts first color light provided from the light emitting element ED into second color light, a second light control part CCP2 including a second quantum dot QD2 that converts the first color light into third color light, and a third light control part CCP3 that transmits the first color light.

In an embodiment, the first light control part CCP1 may provide red light, which is the second color light, and the second light control part CCP2 may provide green light, which is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include a quantum dot but may include the scatterer SP.

The scatterer SP may be inorganic particles. For example, the scatterer SP may include at least one of TiO₂, ZnO, Al₂O₃, SiO₂, and hollow silica. The scatterer SP may include one of TiO₂, ZnO, Al₂O₃, SiO₂, and hollow silica, or may be a mixture of at least two materials selected from TiO₂, ZnO, Al₂O₃, SiO₂, and hollow silica.

The first light control part CCP1, the second light control part CCP2, and the third light control part CCP3 may each include base resins BR1, BR2, and BR3, in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may block the light control parts CCP1, CCP2, and CCP3 from exposure to moisture/oxygen. The barrier layer BFL1 may cover the light control parts CCP1, CCP2, and CCP3. A barrier layer BFL2 may be provided between the light control parts CCP1, CCP2, and CCP3 and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may each independently further include an organic film. The barrier layers BFL1 and BFL2 may each be formed of a single layer or of multiple layers.

In the display apparatus DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated but may be provided as one filter.

Although not shown in the drawings, the color filter layer CFL may further include a light shielding part (not shown). The light shielding part (not shown) may be a black matrix. The light shielding part (not shown) may include an organic light shielding material or an inorganic light shielding material, each including a black pigment or dye. The light shielding part (not shown) may prevent light leakage, and may separate boundaries between adjacent filters CF1, CF2, and CF3.

The first to third filters CF1, CF2, and CF3 may be disposed to respectively correspond to the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

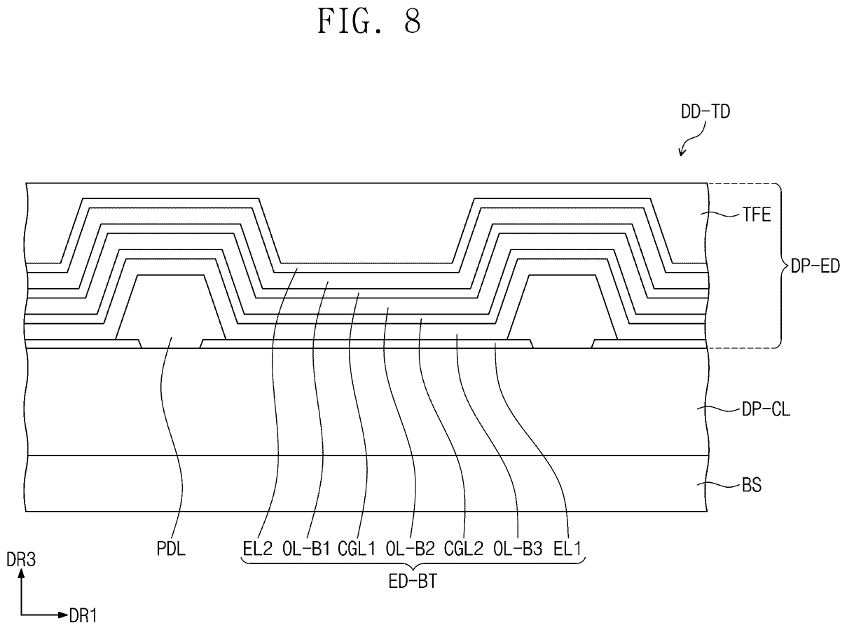

FIG. 8 is a schematic cross-sectional view of a portion of a display apparatus according to an embodiment. In the display apparatus DD-TD according to an embodiment, the light emitting element ED-BT may include light emitting structures OL-B1, OL-B2, and OL-B3. The light emitting element ED-BT may include a first electrode EL1 and a second electrode EL2 which face each other, and the light emitting structures OL-B1, OL-B2, and OL-B3 stacked in a thickness direction between the first electrode EL1 and the second electrode EL2. The light emitting structures OL-B1, OL-B2, and OL-B3 may each include an emission layer EML (see FIG. 7) and a hole transport region HTR and an electron transport region ETR disposed with the emission layer EML (see FIG. 7) located therebetween.

For example, the light emitting element ED-BT included in the display apparatus DD-TD may be a light emitting element having a tandem structure and including multiple emission layers.

In an embodiment illustrated in FIG. 8, light emitted from each of the light emitting structures OL-B1, OL-B2, and OL-B3 may be blue light. However, embodiments are not limited thereto, and the light emitted from each of the light emitting structures OL-B1, OL-B2, and OL-B3 may have wavelength ranges that are different from each other. For example, the light emitting element ED-BT that includes the light emitting structures OL-B1, OL-B2, and OL-B3, which emit light having wavelength ranges that are different from each other, may emit white light.

Charge generation layers CGL1 and CGL2 may each be disposed between adjacent light emitting structures among the light emitting structures OL-B1, OL-B2, and OL-B3. Charge generation layers CGL1 and CGL2 may each independently include a p-type charge generation layer and/or an n-type charge generation layer.

At least one of the light emitting structures OL-B1, OL-B2, and OL-B3 included in the display apparatus DD-TD may include the fused polycyclic compound according to an embodiment described above. For example, at least one of the emission layers included in the light emitting element ED-BT may include the fused polycyclic compound.

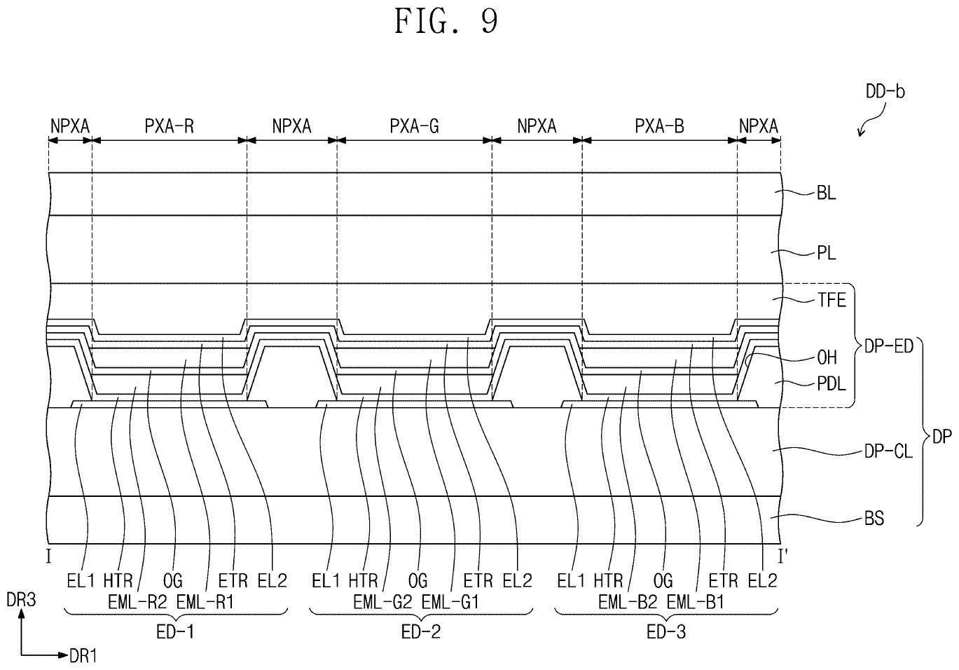

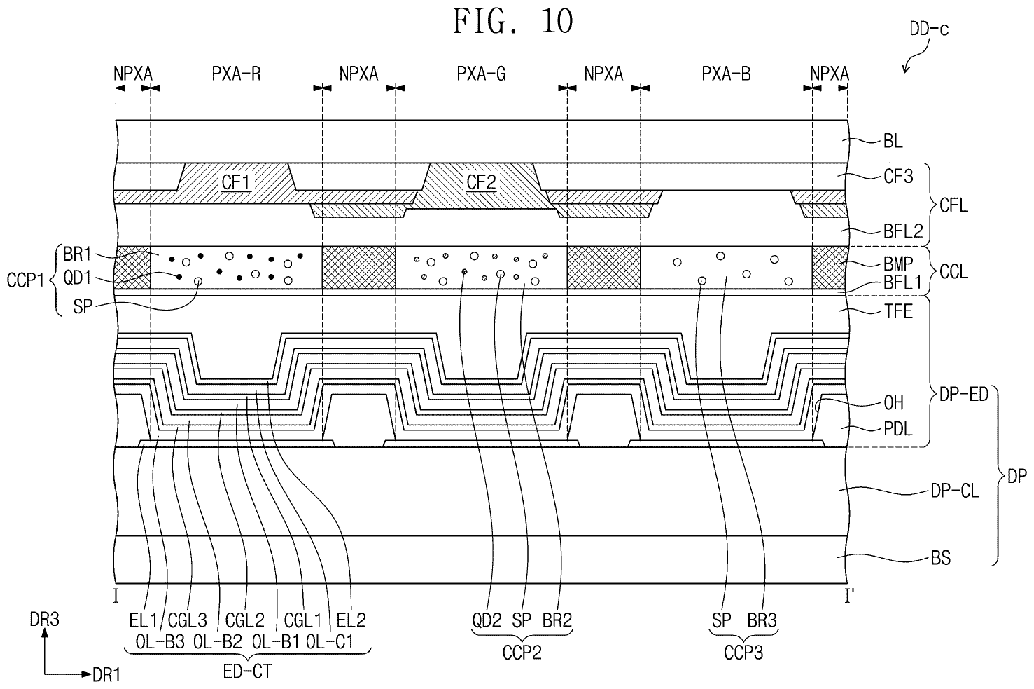

Referring to FIG. 9, the display apparatus DD-b according to an embodiment may include light emitting elements ED-1, ED-2, and ED-3 in which two emission layers are stacked. In comparison to the display apparatus DD shown in FIG. 2, the embodiment shown in FIG. 9 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength region.

The first light emitting element ED-1 may include a first red emission layer EML-R₁ and a second red emission layer EML-R₂. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer for each of the first to third light emitting elements ED-1, ED-2, and ED-3. However, embodiments are not limited thereto, and the emission auxiliary part OG may be provided by being patterned in the openings OH defined in the pixel defining film PDL.

The first red emission layer EML-R1, the first green emission layer EML-G1, and the first blue emission layer EML-B1 may each be disposed between the emission auxiliary part OG and the electron transport region ETR. The second red emission layer EML-R2, the second green emission layer EML-G2, and the second blue emission layer EML-B2 may each be disposed between the hole transport region HTR and the emission auxiliary part OG.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2, which are stacked in that order. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2, which are stacked in that order. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2, which are stacked in that order.

An optical auxiliary layer PL may be disposed on the display device layer DP-ED. The optical auxiliary layer PL may include a polarizing layer. The optical auxiliary layer PL may be disposed on the display panel DP and may control light that is reflected at the display panel DP from an external light. Although not shown in the drawings, in an embodiment, the optical auxiliary layer PL may be omitted from the display apparatus DD-b.

At least one emission layer included in the display apparatus DD-b shown in FIG. 9 may include the fused polycyclic compound according to an embodiment as described above. For example, at least one of the first blue emission layer EML-B1 and the second blue emission layer EML-B2 may include the fused polycyclic compound.

In contrast to FIGS. 8 and 9, FIG. 10 shows a display apparatus DD-c that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may each be disposed between adjacent light emitting structures among the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelength regions from each other.

The charge generation layers CGL1, CGL2, and CGL3 that are disposed between adjacent light emitting structures among the first to fourth light emitting structures OL-B1, OL-B2, OL-B3, and OL-C1 may each independently include a p-type charge generation layer and/or an n-type charge generation layer.

In the display apparatus DD-c, at least one of the light emitting structures OL-B1, OL-B2, OL-B3, and OL-C1 may each independently include the fused polycyclic compound according to an embodiment described above. For example, in an embodiment, at least one of the first to third light emitting structures OL-B1, OL-B2, and OL-B3 may each independently include the fused polycyclic compound.

The light emitting element ED according to an embodiment may include the fused polycyclic compound represented by Formula 1 in at least one functional layer disposed between the first electrode EL1 and the second electrode EL2, thereby exhibiting excellent emission efficiency and improved lifespan. For example, the emission layer EML of the light emitting element ED may include the fused polycyclic compound, and the light emitting element ED may exhibit a long lifespan.

In an embodiment, an electronic apparatus may include a display apparatus that includes multiple light emitting elements, and a control part which controls the display apparatus. The electronic apparatus may be a device that is activated according to an electrical signal. The electronic apparatus may include display apparatuses according to various embodiments. Examples of the electronic apparatus may include not only large-sized electronic apparatuses such as a television set, a monitor, or an outdoor billboard, but may also include small-sized and medium-sized electronic apparatuses such as a personal computer, a laptop computer, a personal digital terminal, a display apparatus for a vehicle, a game console, a portable electronic device, or a camera.

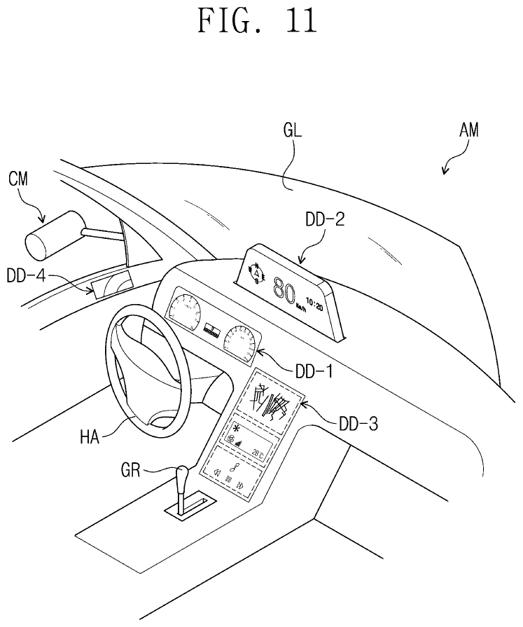

FIG. 11 is a schematic perspective view of a vehicle AM in which first to fourth display apparatuses DD-1, DD-2, DD-3, and DD-4 are disposed. At least one of the first to fourth display apparatuses DD-1, DD-2, DD-3, and DD-4 may have a structure according to one of display apparatuses DD, DD-TD, DD-a, DD-b, and DD-c, as described with reference to FIGS. 1, 2, and 7 to 10.

FIG. 11 illustrates a vehicle AM, but this is only an example, and the first to fourth display apparatuses DD-1, DD-2, DD-3, and DD-4 may be disposed in various transportation means such as bicycles, motorcycles, trains, ships, and airplanes. In an embodiment, at least one of the first to fourth display apparatuses DD-1, DD-2, DD-3, and DD-4 having a structure according to one of display apparatuses DD, DD-TD, DD-a, DD-b, and DD-c may be employed in a personal computer, a laptop computer, a personal digital terminal, a game console, a portable electronic device, a television, a monitor, an outdoor billboard, or the like. However, these are merely presented as examples, and thus may be employed in other electronic apparatuses.

At least one of the first to fourth display devices DD-1, DD-2, DD-3, and DD-4 may each independently include a light emitting element ED according to an embodiment as described with reference to any of FIGS. 3 to 6. The light emitting element ED may include the fused polycyclic compound according to an embodiment. At least one of the first to fourth display devices DD-1, DD-2, DD-3, and DD-4 may include a light emitting element ED that includes the fused polycyclic compound according to an embodiment, and may thus have increased display lifespan.

Referring to FIG. 11, the vehicle AM may include a steering wheel HA and a gearshift GR for driving the vehicle AM. The vehicle AM may include a front window GL that is disposed so as to face the driver.

The first display apparatus DD-1 may be disposed in a first region that overlaps the steering wheel HA. For example, the first display apparatus DD-1 may be a digital cluster which displays first information of the vehicle AM. The first information may include a first scale which indicates a driving speed of the vehicle AM, a second scale which indicates an engine speed (for example, as revolutions per minute (RPM)), a fuel gauge, etc. The first scale and the second scale may each be displayed as a digital image.

The second display apparatus DD-2 may be disposed in a second region facing the driver's seat and overlapping the front window GL. The driver's seat may be a seat where the steering wheel HA is disposed. For example, the second display apparatus DD-2 may be a head up display (HUD) that displays second information of the vehicle AM. The second display apparatus DD-2 may be optically transparent. The second information may include digital numbers that indicate a driving speed, and may further include information such as the current time. Although not shown in the drawings, in an embodiment, the second information of the second display apparatus DD-2 may be projected to the front window GL to be displayed.

The third display apparatus DD-3 may be disposed in a third region adjacent to the gearshift GR. For example, the third display apparatus DD-3 may be a center information display (CID) for a vehicle that displays third information, and the third display apparatus DD-3 may be disposed between the driver's seat and the passenger seat. The passenger seat may be a seat that is spaced apart from the driver's seat with the gearshift GR disposed therebetween. The third information may include information about traffic (e.g., navigation information), playing music or radio or a video (or an image), temperatures inside the vehicle AM, etc.

The fourth display apparatus DD-4 may be spaced apart from the steering wheel HA and the gearshift GR, and may be disposed in a fourth region that is adjacent to a side of the vehicle AM. For example, the fourth display apparatus DD-4 may be a digital side-view mirror that displays fourth information. The fourth display apparatus DD-4 may display an image outside the vehicle AM that is taken by a camera module CM disposed outside the vehicle AM. The fourth information may include an image outside of the vehicle AM.

The first to fourth information as described above are only presented as examples, and the first to fourth display apparatuses DD-1, DD-2, DD-3, and DD-4 may further display information about the interior and exterior of the vehicle AM. The first to fourth information may include information that is different from each other. However, embodiments are not limited thereto, and a part of the first to fourth information may include the same information as one another.

Hereinafter, a fused polycyclic compound according to an embodiment and a light emitting element according to an embodiment will be described with reference to the Examples and the Comparative Examples. The Examples described below are shown only provided as illustrations to assist in understanding the disclosure, and the scope thereof is not limited thereto.

### Examples

### 1. Synthesis of Fused Polycyclic Compounds

A process of synthesizing fused polycyclic compounds according to embodiments will be explained by describing a process of synthesizing Compounds 2, 81, 109, 217, and 294 as examples. The process of synthesizing fused polycyclic compounds as explained below are provided only as examples, and thus the process of synthesizing fused polycyclic compounds according to embodiments is not limited to the Examples below.

### (1) Synthesis of Compound 2

### Synthesis of Intermediate 2-1

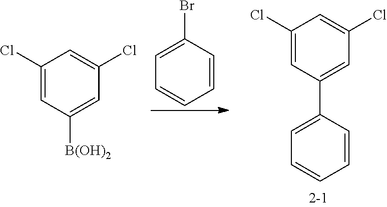

(3,5-dichlorophenyl)boronic acid (1.2 eq), bromobenzene (1 eq), tris(dibenzylideneacetone)dipalladium(0) (0.05 eq), Pd(PPh₃)₄ (0.05 eq), and potassium carbonate (1.5 eq) were added and dissolved in a solvent of toluene/H₂O, and the reaction solution was stirred at 100° C. for 12 hours. After cooling the resultant product, water (1 L) and ethyl acetate (300 mL) were added thereto for extraction, and the organic layer was collected, dried over MgSO₄, and filtered. The filtered solution was subjected to reduced pressure to remove the solvent, and using CH₂Cl₂ and hexane as a developing solvent, the obtained reactant was purified and separated through column chromatography using silica gel to obtain Intermediate Compound 2-1. (Yield: 89%)

### Synthesis of Intermediate 2-2

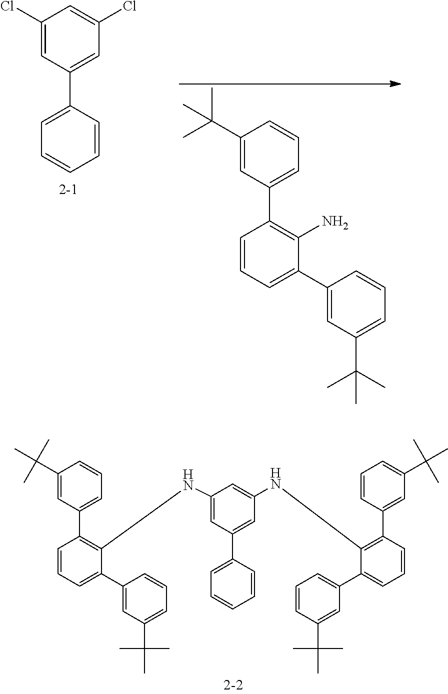 [SMILES: Clc1cc(Cl)cc(-c2ccccc2)c1 ; CC(C)(C)c1cccc(-c2cccc(-c3cccc(C(C)(C)C)c3)c2N)c1 ; CC(C)(C)c1cccc(-c2cccc(-c3cccc(C(C)(C)C)c3)c2Nc2cc(Nc3c(-c4cccc(C(C)(C)C)c4)cccc3-c3cccc(C(C)(C)C)c3)cc(-c3ccccc3)c2)c1]

In a nitrogen atmosphere, Compound 2-1 (1 eq), 3,3″-di-tert-butyl-[1,1′:3′,1″-terphenyl]-2′-amine (2.1 eq), Pd₂dba₃ (0.05 eq), tris-tert-butyl phosphine (0.1 eq), and sodium tert-butoxide (1.5 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 2-2. (Yield: 81%)

### Synthesis of Intermediate 2-3

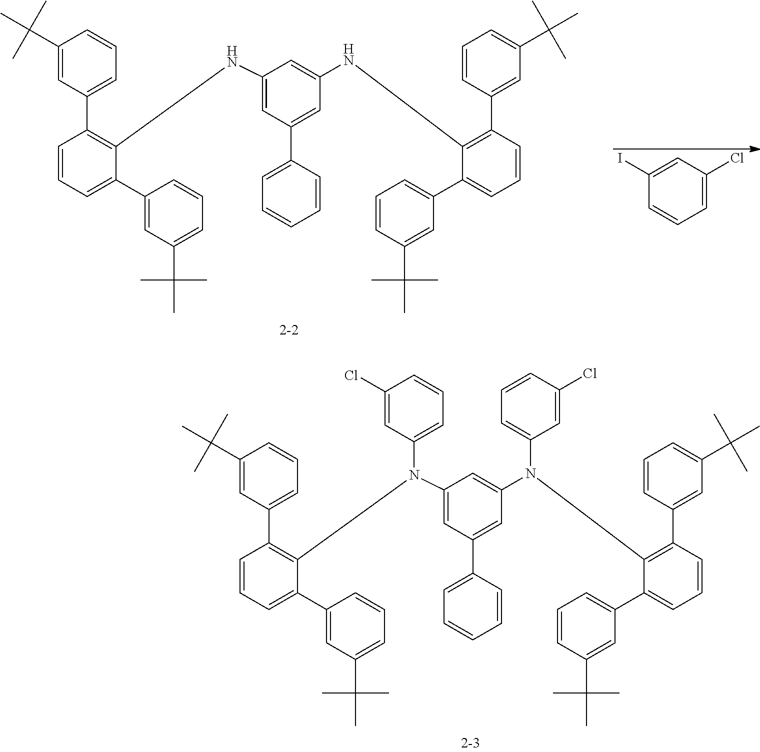

In a nitrogen atmosphere, Compound 2-2 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at 160° C. for 3 days. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 2-3. (Yield: 63%)

### Synthesis of Intermediate 2-4

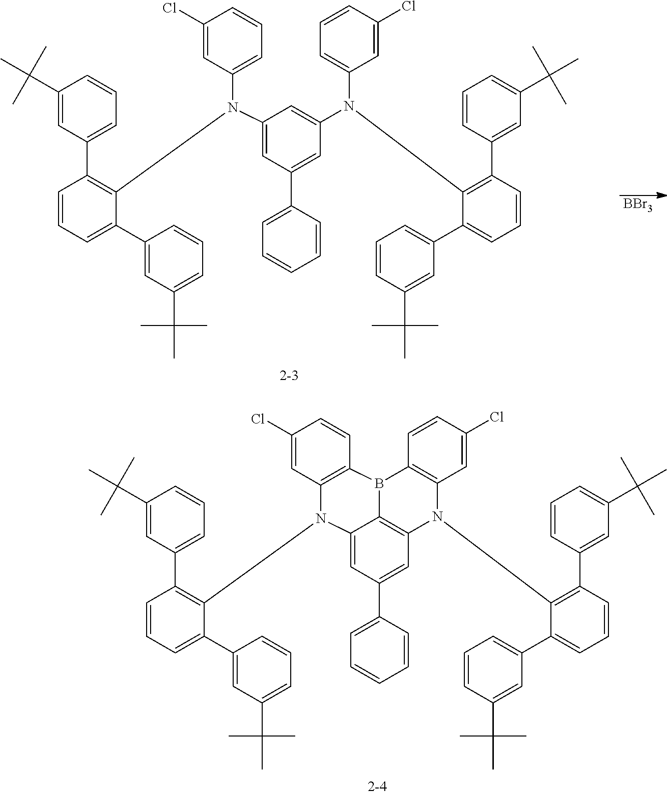

In a nitrogen atmosphere, Compound 2-3 (1 eq) was dissolved in o-dichlorobenzene and cooled using water and ice, and BBr₃ (5 equiv.) was slowly added dropwise, and the reaction solution was stirred at 180° C. for 24 hours. After cooling the resultant product, triethylamine (5 equiv.) was added thereto to terminate the reaction, and the organic layer was collected through extraction using water/CH₂Cl₂, dried over MgSO₄, and filtered. The filtered solution was subjected to reduced pressure to remove the solvent, and the obtained reactant was purified and separated through column chromatography using silica gel to obtain Intermediate Compound 2-4. (Yield: 45%)

### Synthesis of Intermediate 2-5

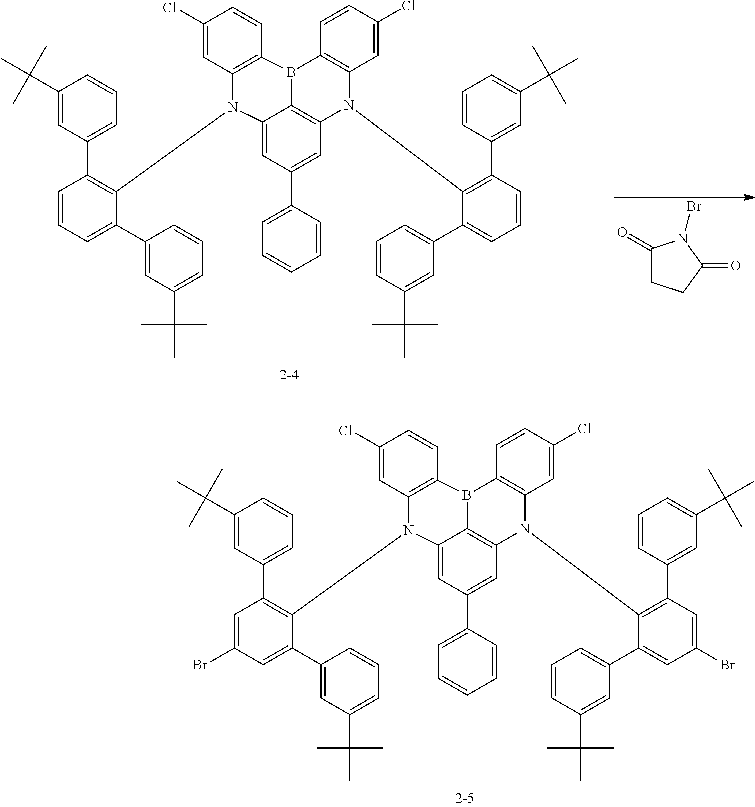

In a nitrogen atmosphere, Compound 2-4 (1 eq) was dissolved in dichloromethane and cooled using water and ice, and N-bromosuccinimide (2.1 equiv.) was slowly added dropwise, and the reaction solution was stirred at room temperature for 4 hours. Water was added to terminate the reaction, and the organic layer was collected through extraction using water/CH₂Cl₂, dried over MgSO₄, and filtered. The filtered solution was subjected to reduced pressure to remove the solvent, and the obtained reactant was purified and separated through column chromatography using silica gel to obtain Intermediate Compound 2-5. (Yield: 85%)

### Synthesis of Intermediate 2-6

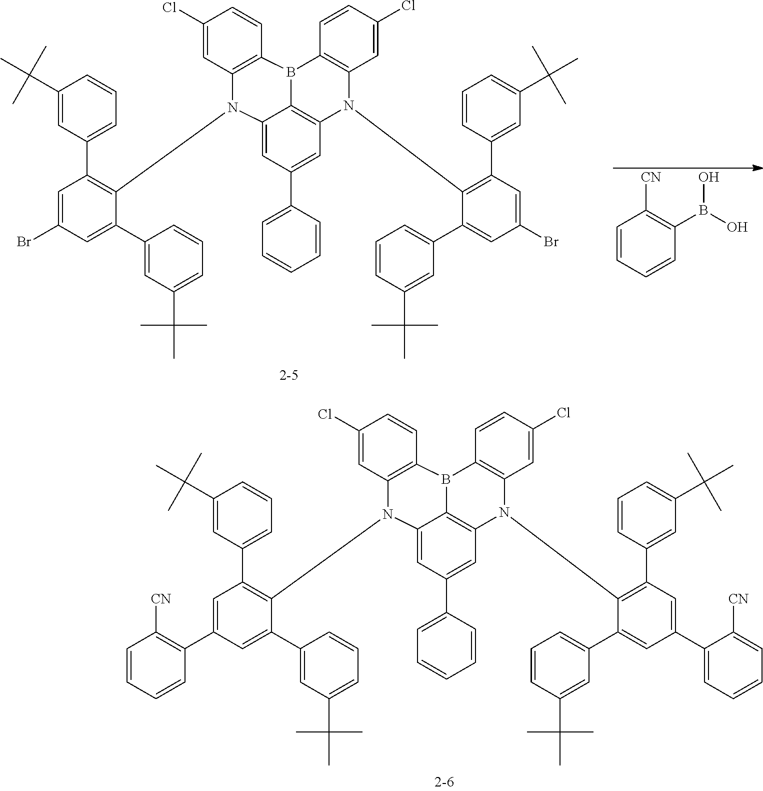 [SMILES: CC(C)(C)c1cccc(-c2cc(Br)cc(-c3cccc(C(C)(C)C)c3)c2N2c3cc(Cl)ccc3B3c4ccc(Cl)cc4N(c4c(-c5cccc(C(C)(C)C)c5)cc(Br)cc4-c4cccc(C(C)(C)C)c4)c4cc(-c5ccccc5)cc2c43)c1 ; N#Cc1ccccc1B(O)O ; CC(C)(C)c1cccc(-c2cc(-c3ccccc3C#N)cc(-c3cccc(C(C)(C)C)c3)c2N2c3cc(Cl)ccc3B3c4ccc(Cl)cc4N(c4c(-c5cccc(C(C)(C)C)c5)cc(-c5ccccc5C#N)cc4-c4cccc(C(C)(C)C)c4)c4cc(-c5ccccc5)cc2c43)c1]

(2-cyanophenyl)boronic acid (2.2 eq), Compound 2-5 (1 eq), tris(dibenzylideneacetone)dipalladium(0) (0.05 eq), Pd(PPh₃)₄ (0.05 eq), and potassium carbonate (1.5 eq) were added and dissolved in a solvent of toluene/H₂O, and the reaction solution was stirred at 100° C. for 12 hours. After cooling the resultant product, water (1 L) and ethyl acetate (300 mL) were added thereto for extraction, and the organic layer was collected, dried over MgSO₄, and filtered. The filtered solution was subjected to reduced pressure to remove the solvent, and using CH₂Cl₂ and hexane as a developing solvent, the obtained reactant was purified and separated through column chromatography using silica gel to obtain Intermediate Compound 2-6. (Yield: 81%)

### Synthesis of Compound 2

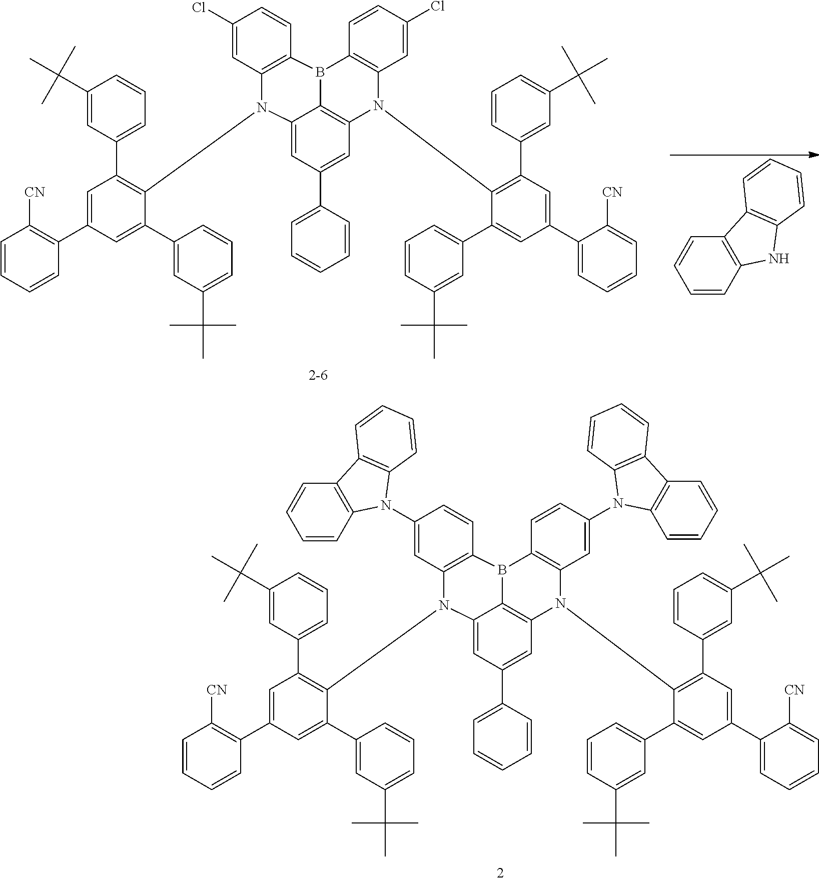

In a nitrogen atmosphere, Compound 2-6 (1 eq), carbazole (2.4 eq), Pd₂dba₃ (0.05 eq), tris-tert-butyl phosphine (0.1 eq), and sodium tert-butoxide (3 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Compound 2. (Yield: 80%)

### (2) Synthesis of Compound 81

### Synthesis of Intermediate 81-1

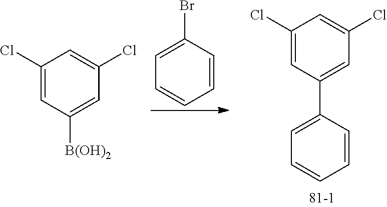

(3,5-dichlorophenyl)boronic acid (1.2 eq), bromobenzene (1 eq), tris(dibenzylideneacetone)dipalladium(0) (0.05 eq), Pd(PPh₃)₄ (0.05 eq), and potassium carbonate (1.5 eq) were added and dissolved in a solvent of toluene/H₂O, and the reaction solution was stirred at 100° C. for 12 hours. After cooling the resultant product, water (1 L) and ethyl acetate (300 mL) were added thereto for extraction, and the organic layer was collected, dried over MgSO₄, and filtered. The filtered solution was subjected to reduced pressure to remove the solvent, and using CH₂Cl₂ and hexane as a developing solvent, the obtained reactant was purified and separated through column chromatography using silica gel to obtain Intermediate Compound 81-1. (Yield: 85%)

### Synthesis of Intermediate 81-2

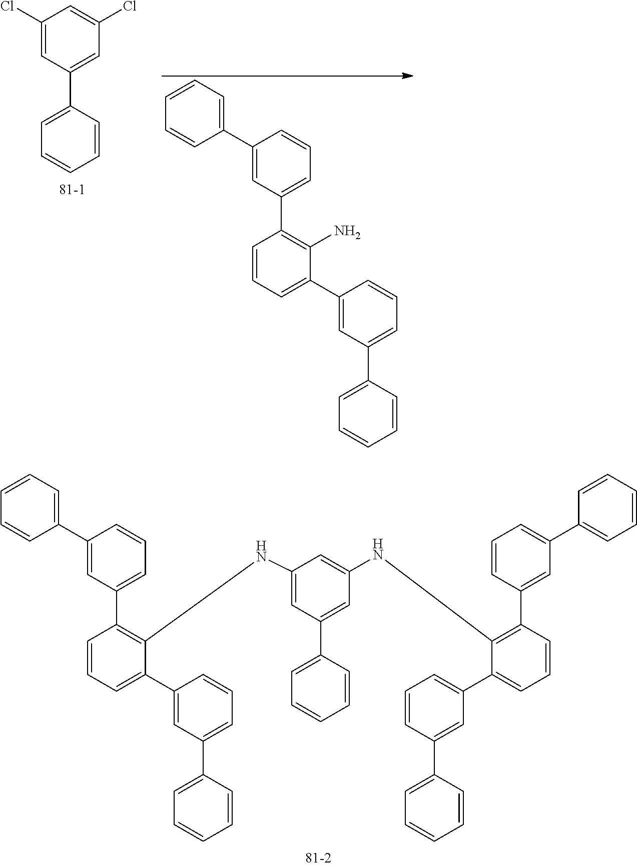 [SMILES: Clc1cc(Cl)cc(-c2ccccc2)c1 ; Nc1c(-c2cccc(-c3ccccc3)c2)cccc1-c1cccc(-c2ccccc2)c1 ; c1ccc(-c2cc(Nc3c(-c4cccc(-c5ccccc5)c4)cccc3-c3cccc(-c4ccccc4)c3)cc(Nc3c(-c4cccc(-c5ccccc5)c4)cccc3-c3cccc(-c4ccccc4)c3)c2)cc1]

In a nitrogen atmosphere, Compound 2-1 (1 eq), [1,1′:3′,1″:3″,1″′:3″′,1″″-quinquephenyl]-2″-amine (2.1 eq), Pd₂dba₃ (0.05 eq), tris-tert-butyl phosphine (0.1 eq), and sodium tert-butoxide (1.5 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 81-2. (Yield: 78%)

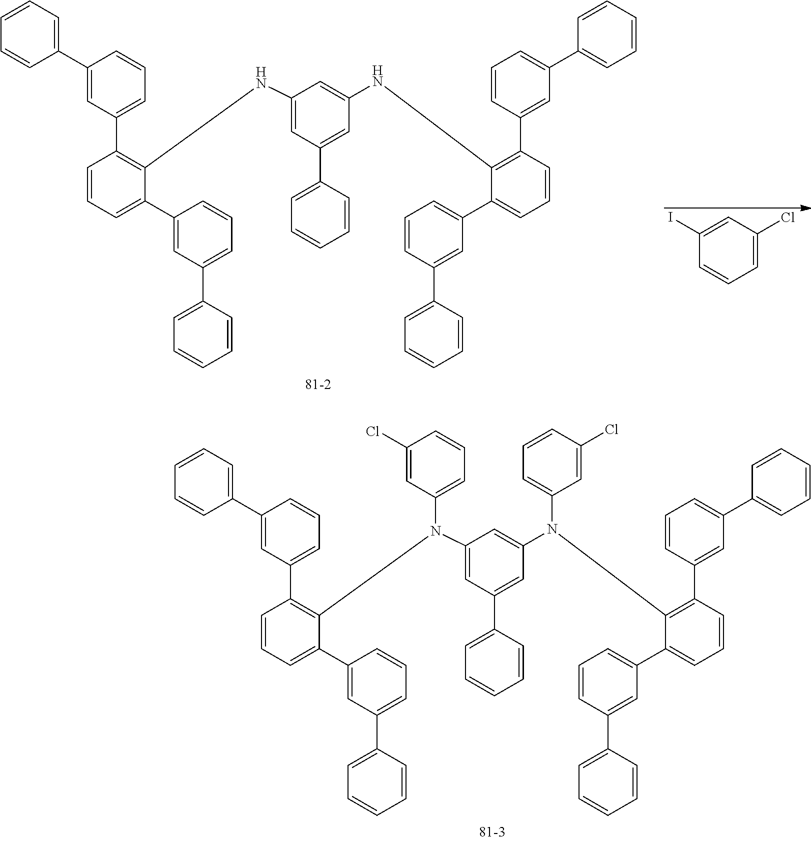 [SMILES: c1ccc(-c2cc(Nc3c(-c4cccc(-c5ccccc5)c4)cccc3-c3cccc(-c4ccccc4)c3)cc(Nc3c(-c4cccc(-c5ccccc5)c4)cccc3-c3cccc(-c4ccccc4)c3)c2)cc1 ; Clc1cccc(I)c1 ; Clc1cccc(N(c2cc(-c3ccccc3)cc(N(c3cccc(Cl)c3)c3c(-c4cccc(-c5ccccc5)c4)cccc3-c3cccc(-c4ccccc4)c3)c2)c2c(-c3cccc(-c4ccccc4)c3)cccc2-c2cccc(-c3ccccc3)c2)c1]

### Synthesis of Intermediate 81-3

In a nitrogen atmosphere, Compound 81-2 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at 160° C. for 3 days. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 81-3. (Yield: 60%)

### Synthesis of Intermediate 81-4

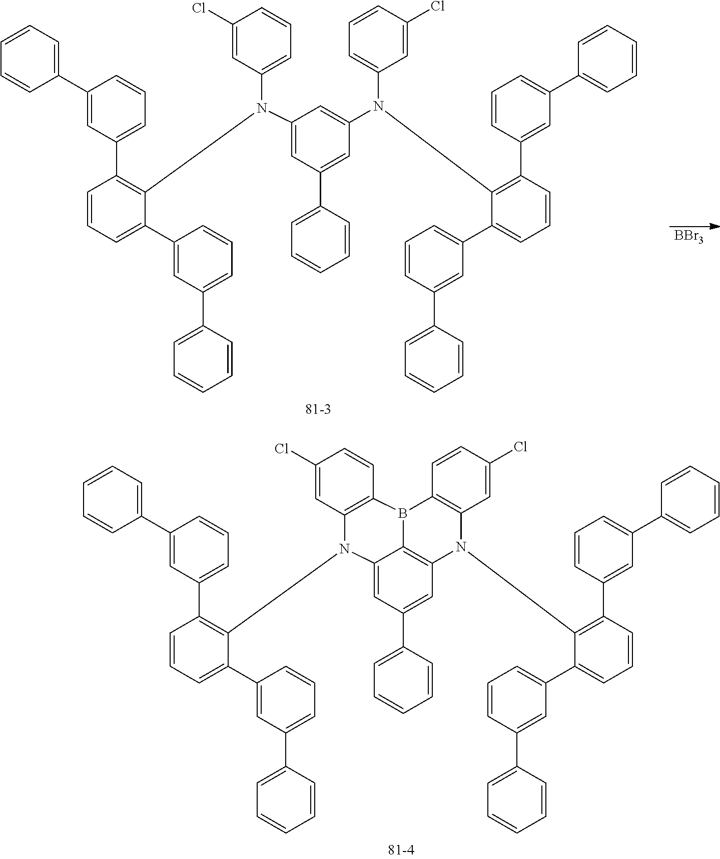 [SMILES: Clc1cccc(N(c2cc(-c3ccccc3)cc(N(c3cccc(Cl)c3)c3c(-c4cccc(-c5ccccc5)c4)cccc3-c3cccc(-c4ccccc4)c3)c2)c2c(-c3cccc(-c4ccccc4)c3)cccc2-c2cccc(-c3ccccc3)c2)c1 ; "BBr3" ; Clc1ccc2c(c1)N(c1c(-c3cccc(-c4ccccc4)c3)cccc1-c1cccc(-c3ccccc3)c1)c1cc(-c3ccccc3)cc3c1B2c1ccc(Cl)cc1N3c1c(-c2cccc(-c3ccccc3)c2)cccc1-c1cccc(-c2ccccc2)c1]

In a nitrogen atmosphere, Compound 81-3 (1 eq) was dissolved in o-dichlorobenzene and cooled using water and ice, and BBr₃ (5 equiv.) was slowly added dropwise, and the reaction solution was stirred at 180° C. for 24 hours. After cooling the resultant product, triethylamine (5 equiv.) was added thereto to terminate the reaction, and the organic layer was collected through extraction using water/CH₂Cl₂, dried over MgSO₄, and filtered. The filtered solution was subjected to reduced pressure to remove the solvent, and the obtained reactant was purified and separated through column chromatography using silica gel to obtain Intermediate Compound 81-4. (Yield: 43%)

### Synthesis of Intermediate 81-5

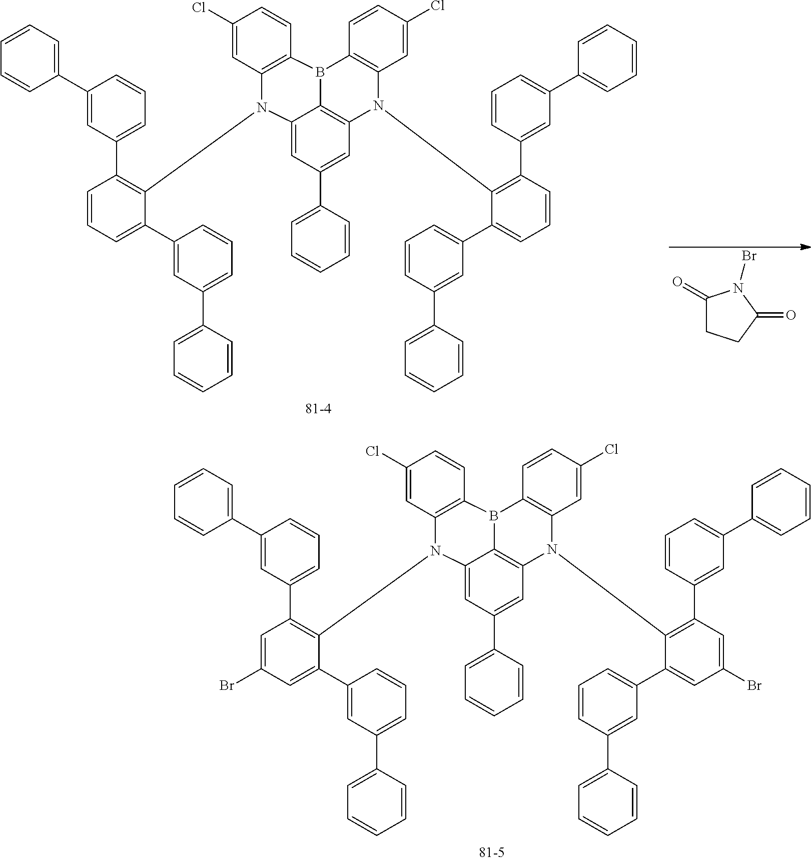 [SMILES: Clc1ccc2c(c1)N(c1c(-c3cccc(-c4ccccc4)c3)cccc1-c1cccc(-c3ccccc3)c1)c1cc(-c3ccccc3)cc3c1B2c1ccc(Cl)cc1N3c1c(-c2cccc(-c3ccccc3)c2)cccc1-c1cccc(-c2ccccc2)c1 ; O=C1CCC(=O)N1Br ; Clc1ccc2c(c1)N(c1c(-c3cccc(-c4ccccc4)c3)cc(Br)cc1-c1cccc(-c3ccccc3)c1)c1cc(-c3ccccc3)cc3c1B2c1ccc(Cl)cc1N3c1c(-c2cccc(-c3ccccc3)c2)cc(Br)cc1-c1cccc(-c2ccccc2)c1]

In a nitrogen atmosphere, Compound 81-4 (1 eq) was dissolved in dichloromethane and cooled using water and ice, and N-bromosuccinimide (2.1 equiv.) was slowly added dropwise, and the reaction solution was stirred at room temperature for 4 hours. Water was added to terminate the reaction, and the organic layer was collected through extraction using water/CH₂Cl₂, dried over MgSO₄, and filtered. The filtered solution was subjected to reduced pressure to remove the solvent, and the obtained reactant was purified and separated through column chromatography using silica gel to obtain Intermediate Compound 81-5. (Yield: 85%)

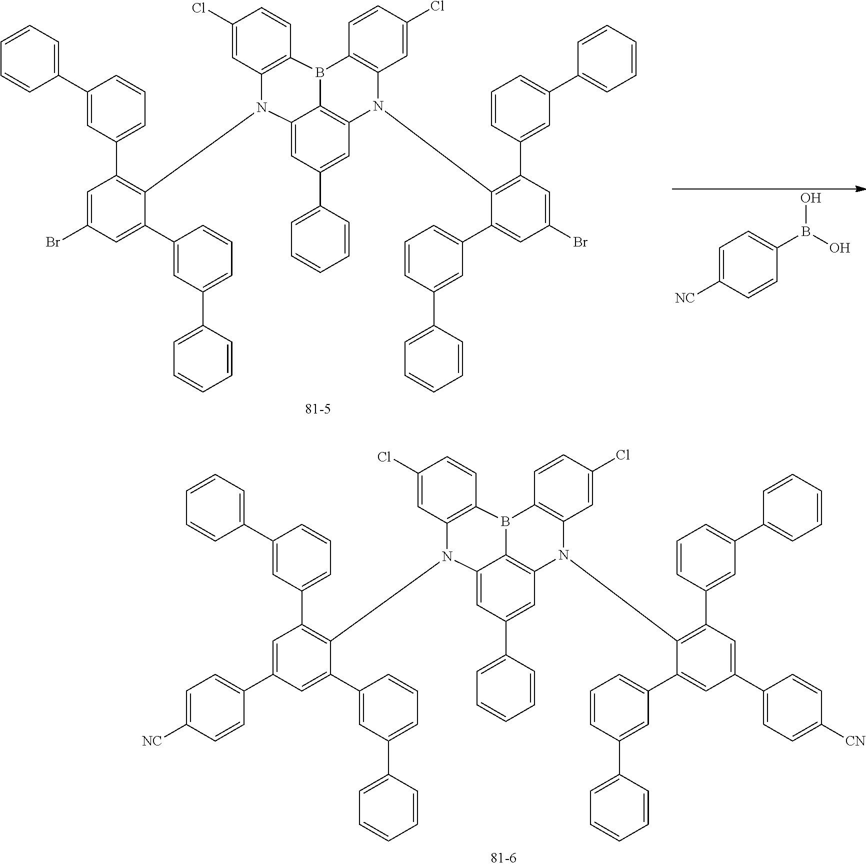 [SMILES: Clc1ccc2c(c1)N(c1c(-c3cccc(-c4ccccc4)c3)cc(Br)cc1-c1cccc(-c3ccccc3)c1)c1cc(-c3ccccc3)cc3c1B2c1ccc(Cl)cc1N3c1c(-c2cccc(-c3ccccc3)c2)cc(Br)cc1-c1cccc(-c2ccccc2)c1 ; N#Cc1ccc(B(O)O)cc1 ; N#Cc1ccc(-c2cc(-c3cccc(-c4ccccc4)c3)c(N3c4cc(Cl)ccc4B4c5ccc(Cl)cc5N(c5c(-c6cccc(-c7ccccc7)c6)cc(-c6ccc(C#N)cc6)cc5-c5cccc(-c6ccccc6)c5)c5cc(-c6ccccc6)cc3c54)c(-c3cccc(-c4ccccc4)c3)c2)cc1]

### Synthesis of Intermediate 81-6

(2-cyanophenyl)boronic acid (2.2 eq), Compound 81-5 (1 eq), tris(dibenzylideneacetone)dipalladium(0) (0.05 eq), Pd(PPh₃)₄ (0.05 eq), and potassium carbonate (1.5 eq) were added and dissolved in a solvent of toluene/H₂O, and the reaction solution was stirred at 100° C. for 12 hours. After cooling the resultant product, water (1 L) and ethyl acetate (300 mL) were added thereto for extraction, and the organic layer was collected, dried over MgSO₄, and filtered. The filtered solution was subjected to reduced pressure to remove the solvent, and using CH₂Cl₂ and hexane as a developing solvent, the obtained reactant was purified and separated through column chromatography using silica gel to obtain Intermediate Compound 81-6. (Yield: 81%)

### Synthesis of Compound 81

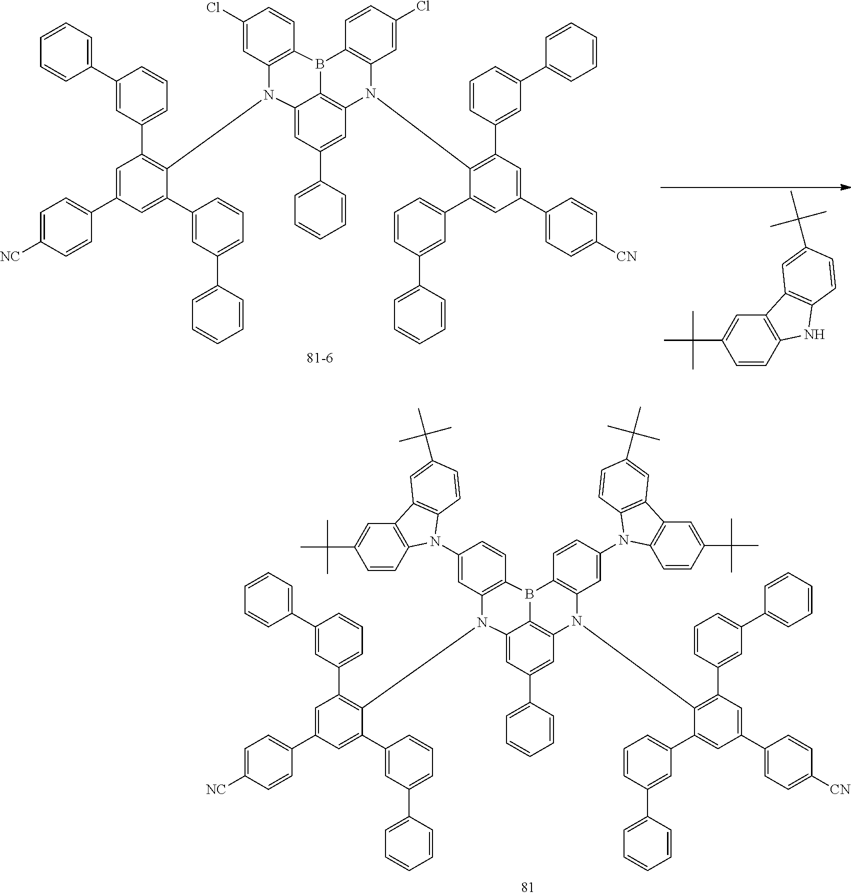 [SMILES: N#Cc1ccc(-c2cc(-c3cccc(-c4ccccc4)c3)c(N3c4cc(Cl)ccc4B4c5ccc(Cl)cc5N(c5c(-c6cccc(-c7ccccc7)c6)cc(-c6ccc(C#N)cc6)cc5-c5cccc(-c6ccccc6)c5)c5cc(-c6ccccc6)cc3c54)c(-c3cccc(-c4ccccc4)c3)c2)cc1 ; CC(C)(C)c1ccc2[nH]c3ccc(C(C)(C)C)cc3c2c1 ; CC(C)(C)c1ccc2c(c1)c1cc(C(C)(C)C)ccc1n2-c1ccc2c(c1)N(c1c(-c3cccc(-c4ccccc4)c3)cc(-c3ccc(C#N)cc3)cc1-c1cccc(-c3ccccc3)c1)c1cc(-c3ccccc3)cc3c1B2c1ccc(-n2c4ccc(C(C)(C)C)cc4c4cc(C(C)(C)C)ccc42)cc1N3c1c(-c2cccc(-c3ccccc3)c2)cc(-c2ccc(C#N)cc2)cc1-c1cccc(-c2ccccc2)c1]

In a nitrogen atmosphere, Compound 81-6 (1 eq), 3,6-di-tert-butyl-9H-carbazole (2.4 eq), Pd₂dba₃ (0.05 eq), tris-tert-butyl phosphine (0.1 eq), and sodium tert-butoxide (3 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Compound 81. (Yield: 80%)

### (3) Synthesis of Compound 109

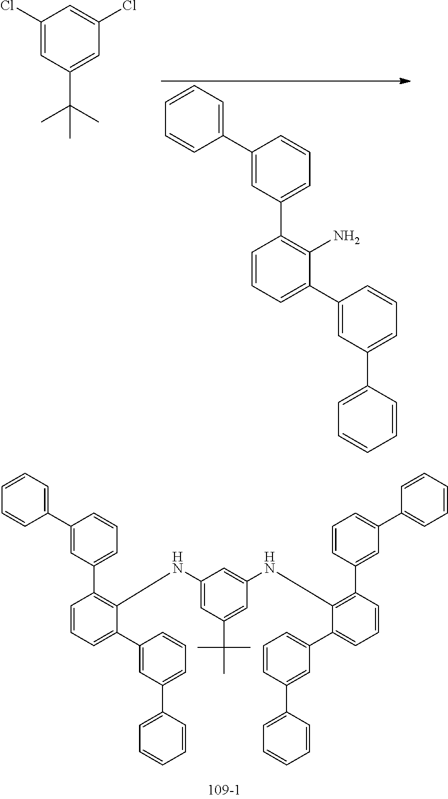 [SMILES: CC(C)(C)c1cc(Cl)cc(Cl)c1 ; Nc1c(-c2cccc(-c3ccccc3)c2)cccc1-c1cccc(-c2ccccc2)c1 ; CC(C)(C)c1cc(Nc2c(-c3cccc(-c4ccccc4)c3)cccc2-c2cccc(-c3ccccc3)c2)cc(Nc2c(-c3cccc(-c4ccccc4)c3)cccc2-c2cccc(-c3ccccc3)c2)c1]

### Synthesis of Intermediate 109-1

In a nitrogen atmosphere, 1-(tert-butyl)-3,5-dichlorobenzene (1 eq), [1,1′:3′,1″:3″,1′″:3″′,1″″-quinquephenyl]-2″-amine (2.1 eq), Pd₂dba₃ (0.05 eq), tris-tert-butyl phosphine (0.1 eq), and sodium tert-butoxide (1.5 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 109-1. (Yield: 78%)

### Synthesis of Intermediate 109-2

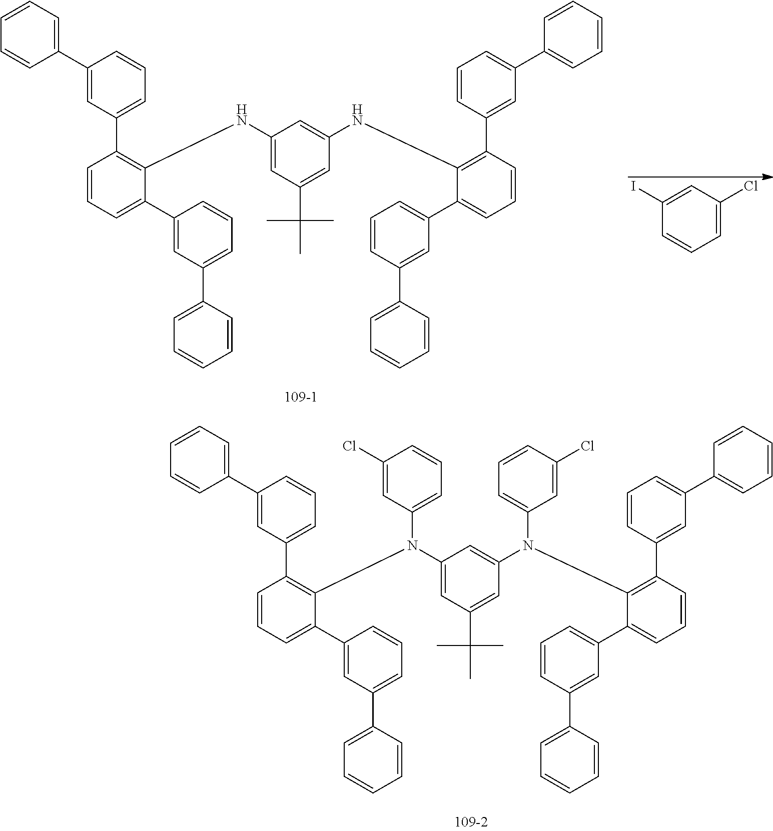 [SMILES: CC(C)(C)c1cc(Nc2c(-c3cccc(-c4ccccc4)c3)cccc2-c2cccc(-c3ccccc3)c2)cc(Nc2c(-c3cccc(-c4ccccc4)c3)cccc2-c2cccc(-c3ccccc3)c2)c1 ; Clc1cccc(I)c1 ; CC(C)(C)c1cc(N(c2cccc(Cl)c2)c2c(-c3cccc(-c4ccccc4)c3)cccc2-c2cccc(-c3ccccc3)c2)cc(N(c2cccc(Cl)c2)c2c(-c3cccc(-c4ccccc4)c3)cccc2-c2cccc(-c3ccccc3)c2)c1]

In a nitrogen atmosphere, Compound 109-1 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at 160° C. for 3 days. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 109-2. (Yield: 66%)

### Synthesis of Intermediate 109-3

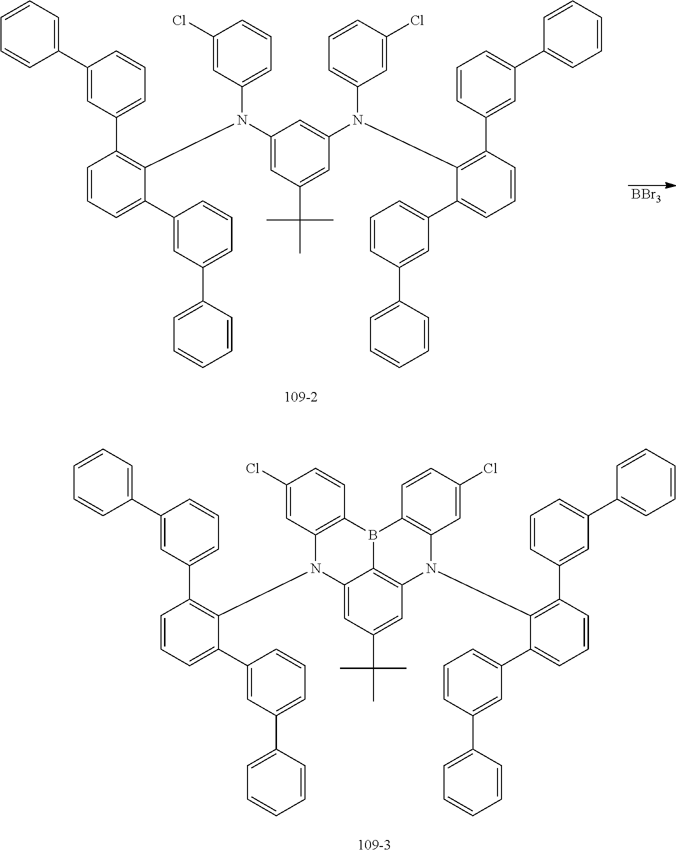 [SMILES: CC(C)(C)c1cc(N(c2cccc(Cl)c2)c2c(-c3cccc(-c4ccccc4)c3)cccc2-c2cccc(-c3ccccc3)c2)cc(N(c2cccc(Cl)c2)c2c(-c3cccc(-c4ccccc4)c3)cccc2-c2cccc(-c3ccccc3)c2)c1 ; "BBr3" ; CC(C)(C)c1cc2c3c(c1)N(c1c(-c4cccc(-c5ccccc5)c4)cccc1-c1cccc(-c4ccccc4)c1)c1cc(Cl)ccc1B3c1ccc(Cl)cc1N2c1c(-c2cccc(-c3ccccc3)c2)cccc1-c1cccc(-c2ccccc2)c1]

In a nitrogen atmosphere, Compound 109-2 (1 eq) was dissolved in o-dichlorobenzene and cooled using water and ice, and BBr₃ (5 equiv.) was slowly added dropwise, and the reaction solution was stirred at 180° C. for 24 hours. After cooling the resultant product, triethylamine (5 equiv.) was added thereto to terminate the reaction, and the organic layer was collected through extraction using water/CH₂Cl₂, dried over MgSO₄, and filtered. The filtered solution was subjected to reduced pressure to remove the solvent, and the obtained reactant was purified and separated through column chromatography using silica gel to obtain Intermediate Compound 109-3. (Yield: 39%)

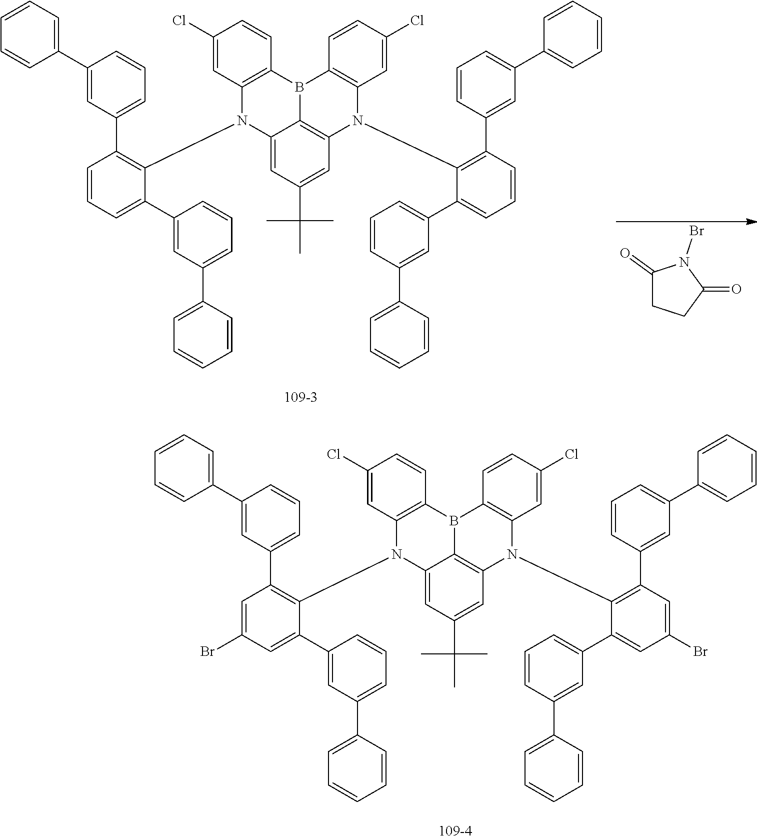 [SMILES: CC(C)(C)c1cc2c3c(c1)N(c1c(-c4cccc(-c5ccccc5)c4)cccc1-c1cccc(-c4ccccc4)c1)c1cc(Cl)ccc1B3c1ccc(Cl)cc1N2c1c(-c2cccc(-c3ccccc3)c2)cccc1-c1cccc(-c2ccccc2)c1 ; O=C1CCC(=O)N1Br ; CC(C)(C)c1cc2c3c(c1)N(c1c(-c4cccc(-c5ccccc5)c4)cc(Br)cc1-c1cccc(-c4ccccc4)c1)c1cc(Cl)ccc1B3c1ccc(Cl)cc1N2c1c(-c2cccc(-c3ccccc3)c2)cc(Br)cc1-c1cccc(-c2ccccc2)c1]

### Synthesis of Intermediate 109-4

In a nitrogen atmosphere, Compound 109-3 (1 eq) was dissolved in dichloromethane and cooled using water and ice, and N-bromosuccinimide (2.1 equiv.) was slowly added dropwise, and the reaction solution was stirred at room temperature for 4 hours. Water was added to terminate the reaction, and the organic layer was collected through extraction using water/CH₂Cl₂, dried over MgSO₄, and filtered. The filtered solution was subjected to reduced pressure to remove the solvent, and the obtained reactant was purified and separated through column chromatography using silica gel to obtain Intermediate Compound 109-4. (Yield: 85%)

### Synthesis of Intermediate 109-5

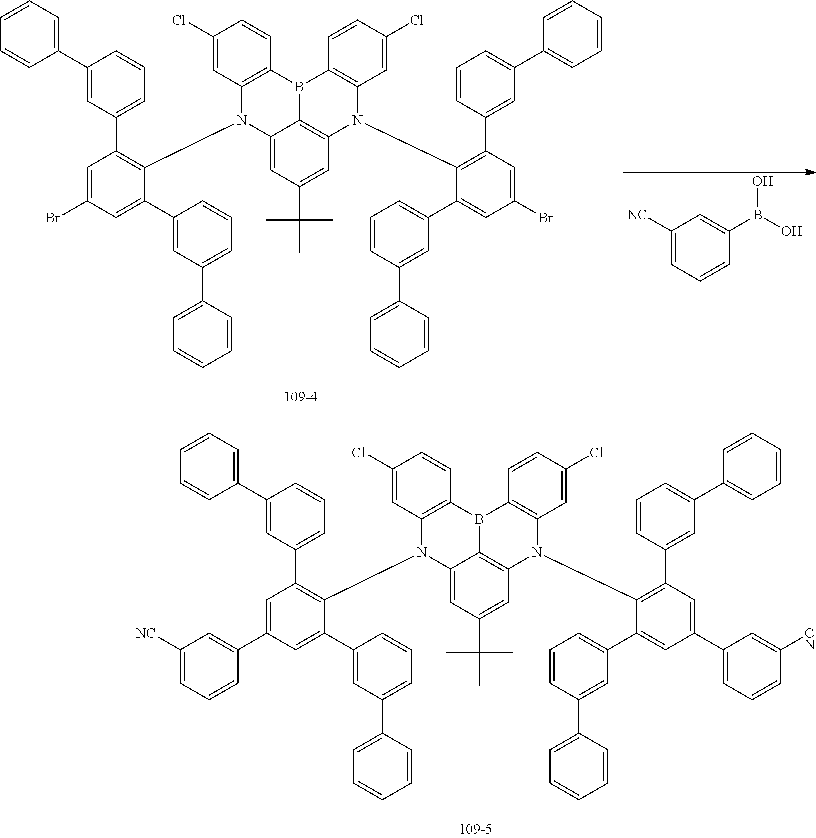 [SMILES: CC(C)(C)c1cc2c3c(c1)N(c1c(-c4cccc(-c5ccccc5)c4)cc(Br)cc1-c1cccc(-c4ccccc4)c1)c1cc(Cl)ccc1B3c1ccc(Cl)cc1N2c1c(-c2cccc(-c3ccccc3)c2)cc(Br)cc1-c1cccc(-c2ccccc2)c1 ; N#Cc1cccc(B(O)O)c1 ; CC(C)(C)c1cc2c3c(c1)N(c1c(-c4cccc(-c5ccccc5)c4)cc(-c4cccc(C#N)c4)cc1-c1cccc(-c4ccccc4)c1)c1cc(Cl)ccc1B3c1ccc(Cl)cc1N2c1c(-c2cccc(-c3ccccc3)c2)cc(-c2cccc(C#N)c2)cc1-c1cccc(-c2ccccc2)c1]

(3-cyanophenyl)boronic acid (2.2 eq), Compound 109-4 (1 eq), tris(dibenzylideneacetone)dipalladium(0) (0.05 eq), Pd(PPh₃)₄ (0.05 eq), and potassium carbonate (1.5 eq) were added and dissolved in a solvent of toluene/H₂O, and the reaction solution was stirred at 100° C. for 12 hours. After cooling the resultant product, water (1 L) and ethyl acetate (300 mL) were added thereto for extraction, and the organic layer was collected, dried over MgSO₄, and filtered. The filtered solution was subjected to reduced pressure to remove the solvent, and using CH₂Cl₂ and hexane as a developing solvent, the obtained reactant was purified and separated through column chromatography using silica gel to obtain Intermediate Compound 109-5. (Yield: 82%)

### Synthesis of Compound 109

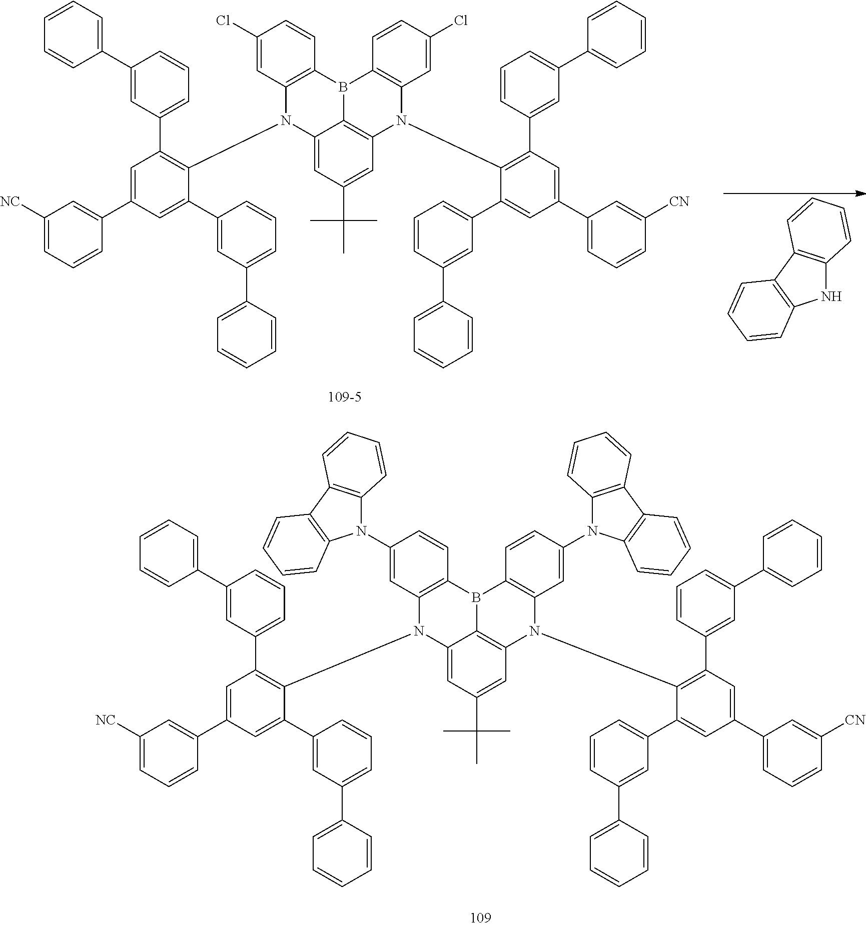 [SMILES: CC(C)(C)c1cc2c3c(c1)N(c1c(-c4cccc(-c5ccccc5)c4)cc(-c4cccc(C#N)c4)cc1-c1cccc(-c4ccccc4)c1)c1cc(Cl)ccc1B3c1ccc(Cl)cc1N2c1c(-c2cccc(-c3ccccc3)c2)cc(-c2cccc(C#N)c2)cc1-c1cccc(-c2ccccc2)c1 ; c1ccc2c(c1)[nH]c1ccccc12 ; CC(C)(C)c1cc2c3c(c1)N(c1c(-c4cccc(-c5ccccc5)c4)cc(-c4cccc(C#N)c4)cc1-c1cccc(-c4ccccc4)c1)c1cc(-n4c5ccccc5c5ccccc54)ccc1B3c1ccc(-n3c4ccccc4c4ccccc43)cc1N2c1c(-c2cccc(-c3ccccc3)c2)cc(-c2cccc(C#N)c2)cc1-c1cccc(-c2ccccc2)c1]

In a nitrogen atmosphere, Compound 109-5 (1 eq), carbazole (2.4 eq), Pd₂dba₃ (0.05 eq), tris-tert-butyl phosphine (0.1 eq), and sodium tert-butoxide (3 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Compound 109. (Yield: 82%)

### (4) Synthesis of Compound 217

### Synthesis of Compound 217-1

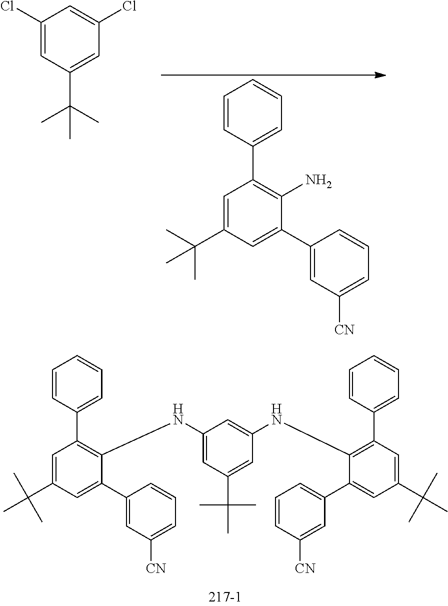 [SMILES: CC(C)(C)c1cc(Cl)cc(Cl)c1 ; CC(C)(C)c1cc(-c2ccccc2)c(N)c(-c2cccc(C#N)c2)c1 ; CC(C)(C)c1cc(Nc2c(-c3ccccc3)cc(C(C)(C)C)cc2-c2cccc(C#N)c2)cc(Nc2c(-c3ccccc3)cc(C(C)(C)C)cc2-c2cccc(C#N)c2)c1]

In a nitrogen atmosphere, 1-(tert-butyl)-3,5-dichlorobenzene (1 eq), 2′-amino-5′-(tert-butyl)-[1,1′:3′,1″-terphenyl]-3-carbonitrile (2.1 eq), Pd₂dba₃ (0.1 eq), tris-tert-butyl phosphine (0.2 eq), and sodium tert-butoxide (3 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 217-1. (Yield: 71%)

### Synthesis of Compound 217-2

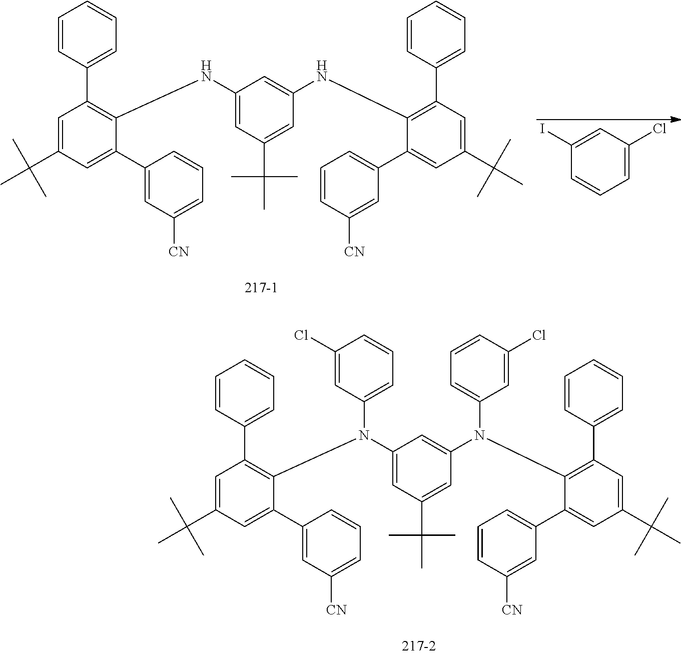

In a nitrogen atmosphere, Compound 217-1 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at 160° C. for 3 days. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 217-2. (Yield: 60%)

### Synthesis of Compound 217-3

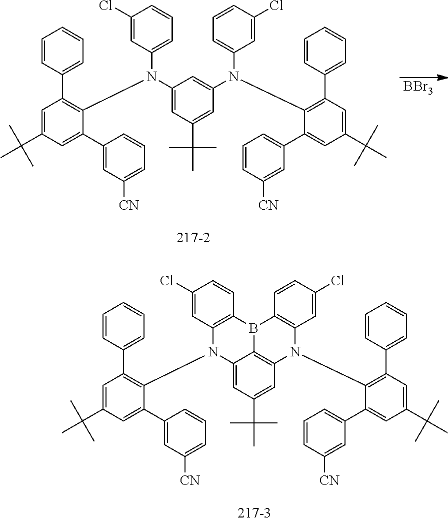

In a nitrogen atmosphere, Compound 217-2 (1 eq) was dissolved in o-dichlorobenzene and cooled using water and ice, and BBr₃ (5 equiv.) was slowly added dropwise, and the reaction solution was stirred at 180° C. for 24 hours. After cooling the resultant product, triethylamine (5 equiv.) was added thereto to terminate the reaction, and the organic layer was collected through extraction using water/CH₂Cl₂, dried over MgSO₄, and filtered. The filtered solution was subjected to reduced pressure to remove the solvent, and the obtained reactant was purified and separated through column chromatography using silica gel to obtain Intermediate Compound 217-3. (Yield: 35%)

### Synthesis of Compound 217

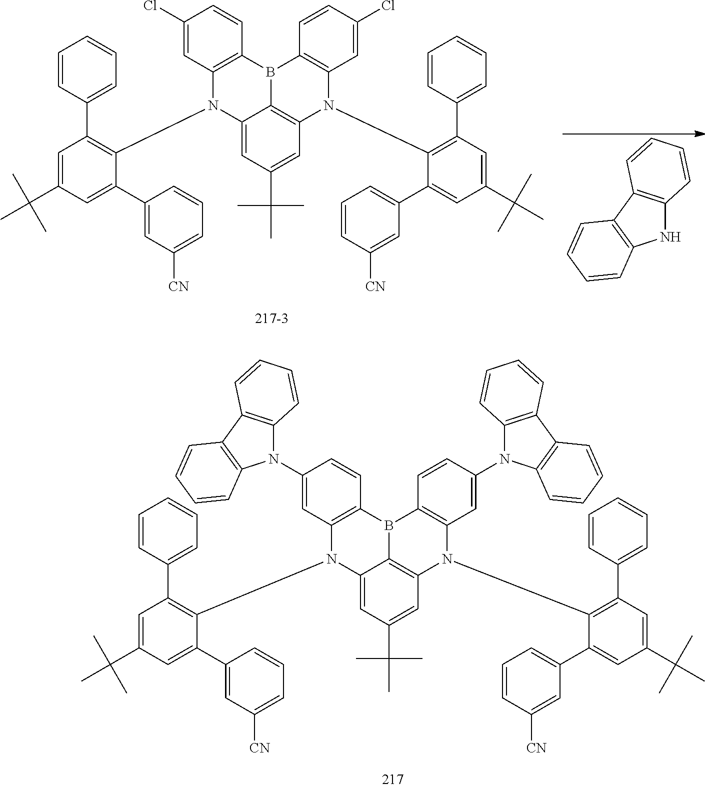

In a nitrogen atmosphere, Compound 217-3 (1 eq), carbazole (2.4 eq), Pd₂dba₃ (0.05 eq), tris-tert-butyl phosphine (0.1 eq), and sodium tert-butoxide (3 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Compound 217. (Yield: 84%)

### (5) Synthesis of Compound 294

### Synthesis of Compound 294-1

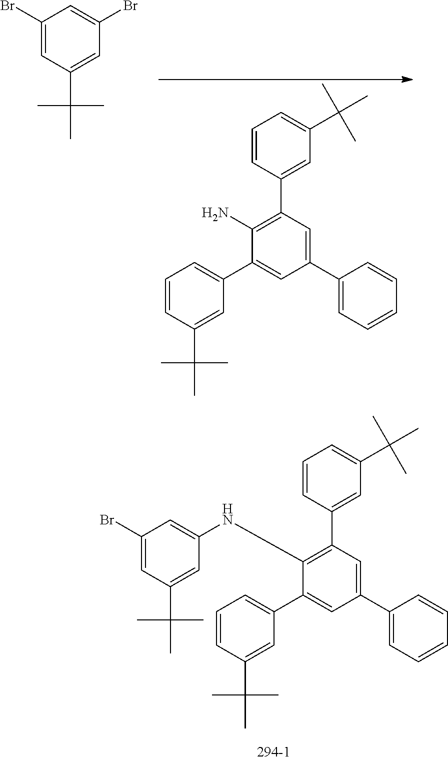 [SMILES: CC(C)(C)c1cc(Br)cc(Br)c1 ; CC(C)(C)c1cccc(-c2cc(-c3ccccc3)cc(-c3cccc(C(C)(C)C)c3)c2N)c1 ; CC(C)(C)c1cc(Br)cc(Nc2c(-c3cccc(C(C)(C)C)c3)cc(-c3ccccc3)cc2-c2cccc(C(C)(C)C)c2)c1]

In a nitrogen atmosphere, 1-(tert-butyl)-3,5-dibromobenzene (1 eq), 3,3″-di-tert-butyl-5′-phenyl-[1,1′:3′,1″-terphenyl]-2′-amine (1.1 eq), Pd₂dba₃ (0.05 eq), tris-tert-butyl phosphine (0.05 eq), and sodium tert-butoxide (1.5 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 294-1. (Yield: 61%)

### Synthesis of Compound 294-2

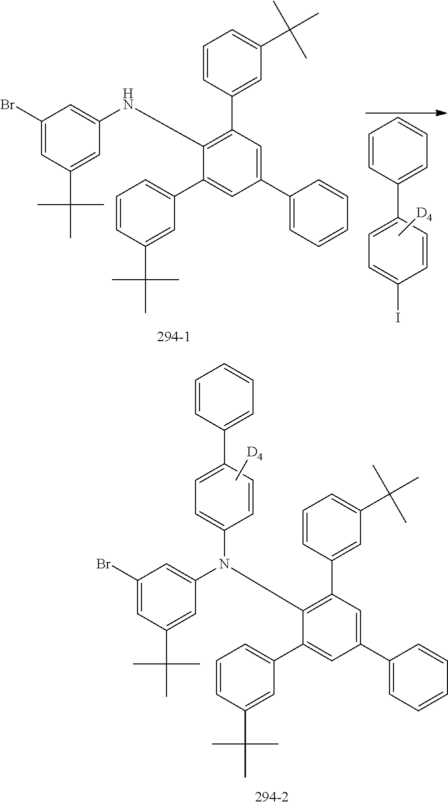

In a nitrogen atmosphere, Compound 294-1 (1 eq), 4-iodo-1,1′-biphenyl-2,3,5,6-d4 (5 eq), Pd₂(dba)₃ (0.5 eq), tris-tert-butyl phosphine (1 eq), and sodium tert-butoxide (2 eq) were added and dissolved in o-xylene, and the reaction solution was stirred at 160° C. for 3 days. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 217-2. (Yield: 63%)

### Synthesis of Compound 294-3

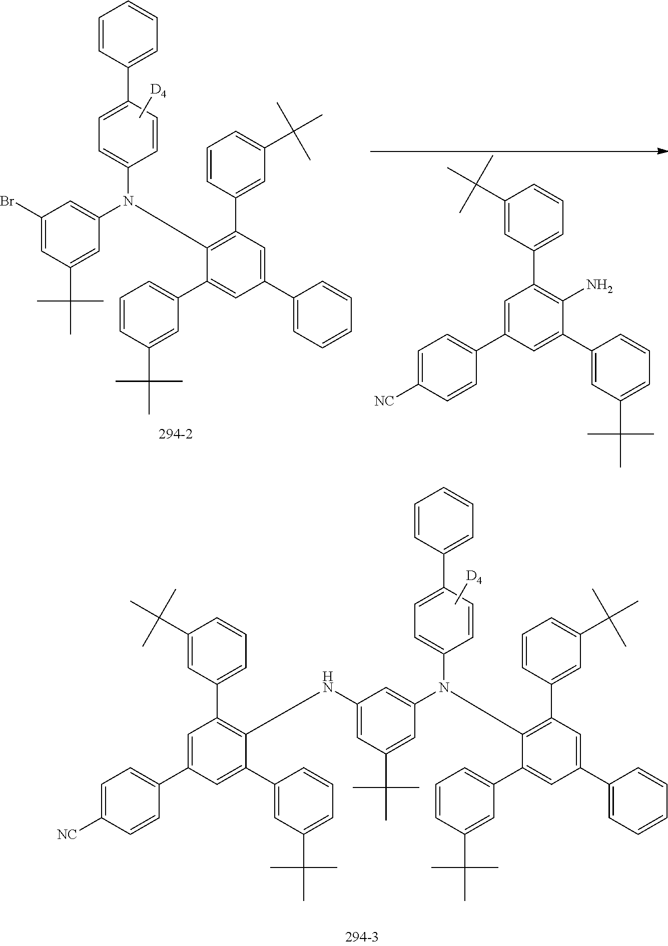

In a nitrogen atmosphere, Compound 294-2 (1 eq), 4′-amino-3″-(tert-butyl)-5′-(3-(tert-butyl)phenyl)-[1,1′:3′,1″-terphenyl]-4-carbonitrile (1.1 eq), Pd₂dba₃ (0.05 eq), tris-tert-butyl phosphine (0.05 eq), and sodium tert-butoxide (1.5 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 294-3. (Yield: 71%)

### Synthesis of Compound 294-4

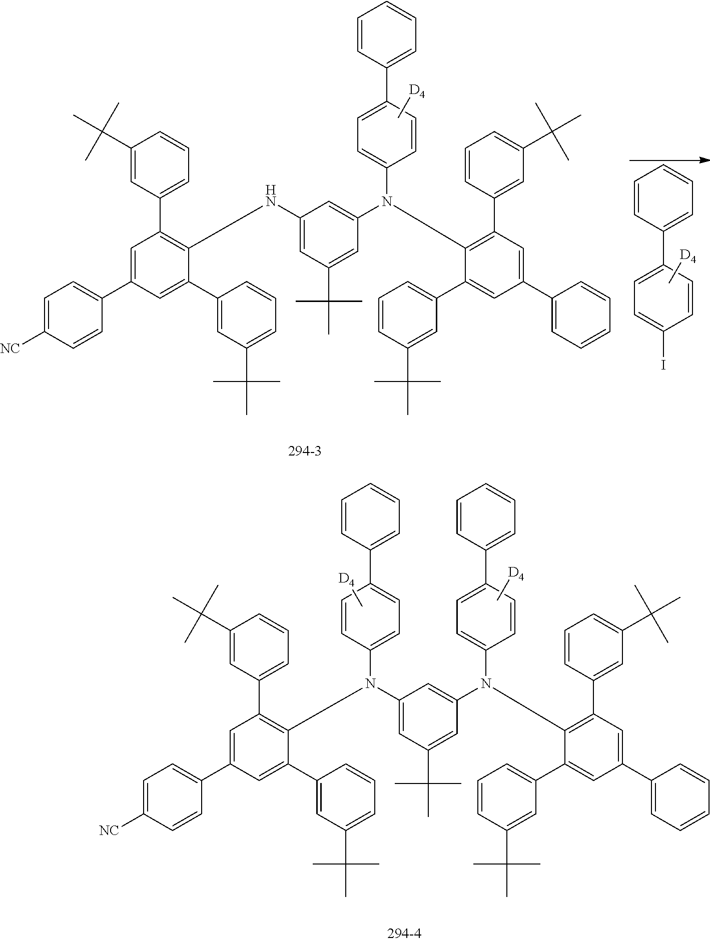

In a nitrogen atmosphere, Compound 294-3 (1 eq), 4-iodo-1,1′-biphenyl-2,3,5,6-d4 (5 eq), Pd₂(dba)₃ (0.5 eq), tris-tert-butyl phosphine (1 eq), and sodium tert-butoxide (2 eq) were added and dissolved in o-xylene, and the reaction solution was stirred at 160° C. for 3 days. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 217-3. (Yield: 65%)

### Synthesis of Compound 294

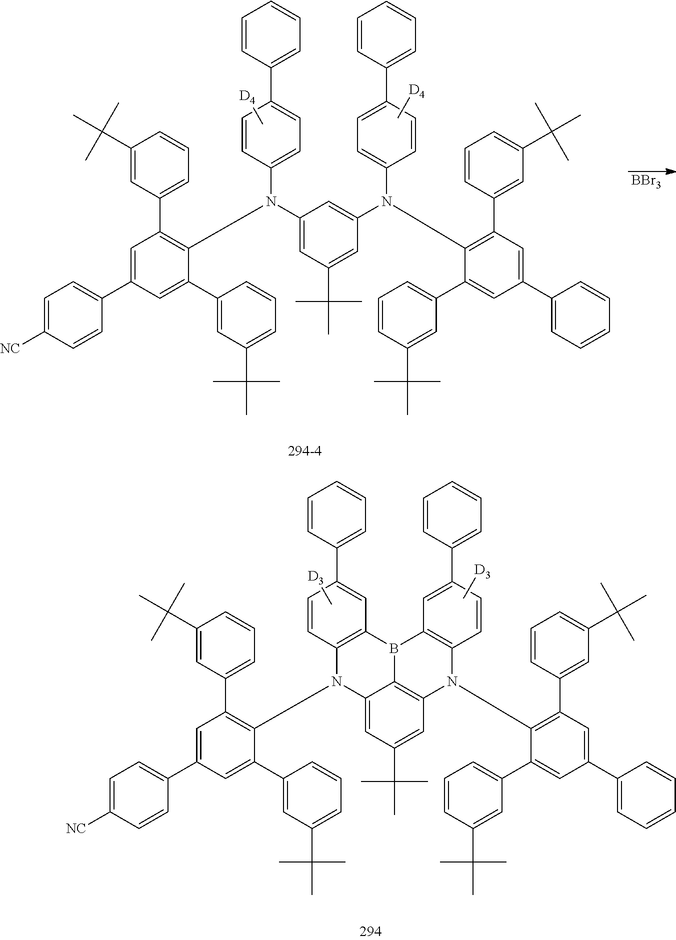

In a nitrogen atmosphere, Compound 294-4 (1 eq) was dissolved in o-dichlorobenzene and cooled using water and ice, and BBr₃ (5 equiv.) was slowly added dropwise, and the reaction solution was stirred at 180° C. for 24 hours. After cooling the resultant product, triethylamine (5 equiv.) was added thereto to terminate the reaction, and the organic layer was collected through extraction using water/CH₂Cl₂, dried over MgSO₄, and filtered. The filtered solution was subjected to reduced pressure to remove the solvent, and the obtained reactant was purified and separated through column chromatography using silica gel to obtain Compound 294. (Yield: 31%)

### 2. Preparation and Evaluation of Light Emitting Elements

Light emitting elements according to an embodiment including a fused polycyclic compound according to an embodiment in an emission layer were prepared using the method described below. Light emitting elements of Examples 1 to 5 were prepared using fused polycyclic compounds of Compounds 2, 81, 109, 217, and 294, which are Example Compounds as described above, as a dopant material of an emission layer. Comparative Examples 1 and 5 correspond to light emitting elements prepared using Comparative Example Compound X-1 to X-5 as a dopant material of an emission layer.

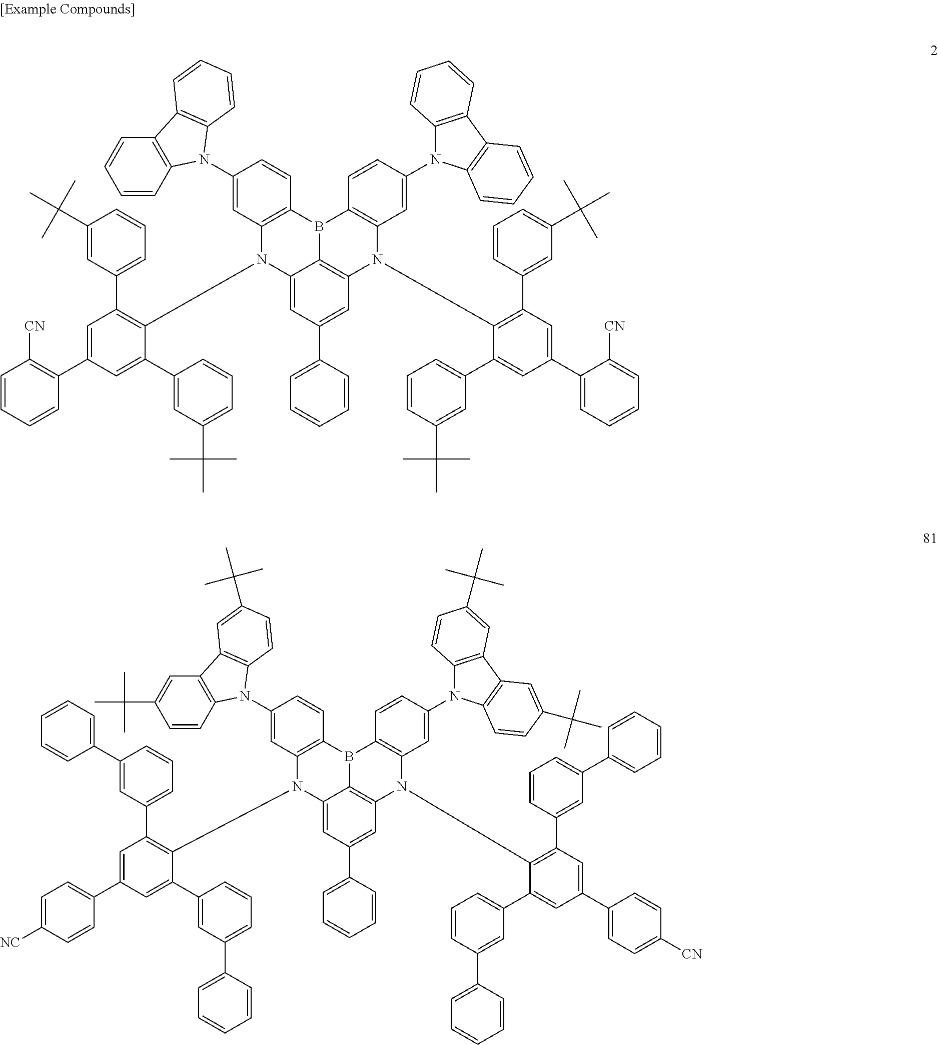 [SMILES: CC(C)(C)c1cccc(-c2cc(-c3ccccc3C#N)cc(-c3cccc(C(C)(C)C)c3)c2N2c3cc(-n4c5ccccc5c5ccccc54)ccc3B3c4ccc(-n5c6ccccc6c6ccccc65)cc4N(c4c(-c5cccc(C(C)(C)C)c5)cc(-c5ccccc5C#N)cc4-c4cccc(C(C)(C)C)c4)c4cc(-c5ccccc5)cc2c43)c1 ; CC(C)(C)c1ccc2c(c1)c1cc(C(C)(C)C)ccc1n2-c1ccc2c(c1)N(c1c(-c3cccc(-c4ccccc4)c3)cc(-c3ccc(C#N)cc3)cc1-c1cccc(-c3ccccc3)c1)c1cc(-c3ccccc3)cc3c1B2c1ccc(-n2c4ccc(C(C)(C)C)cc4c4cc(C(C)(C)C)ccc42)cc1N3c1c(-c2cccc(-c3ccccc3)c2)cc(-c2ccc(C#N)cc2)cc1-c1cccc(-c2ccccc2)c1]

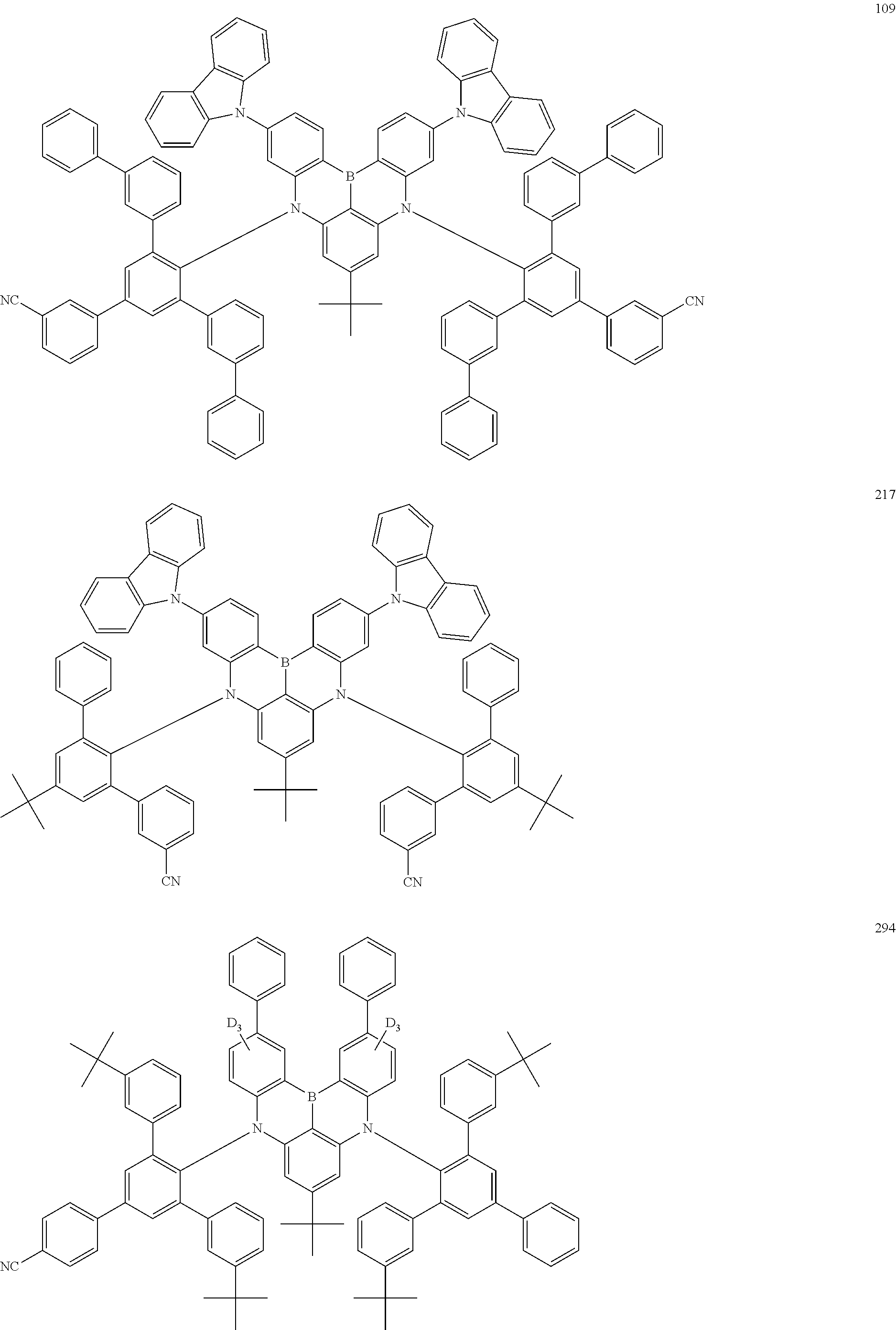

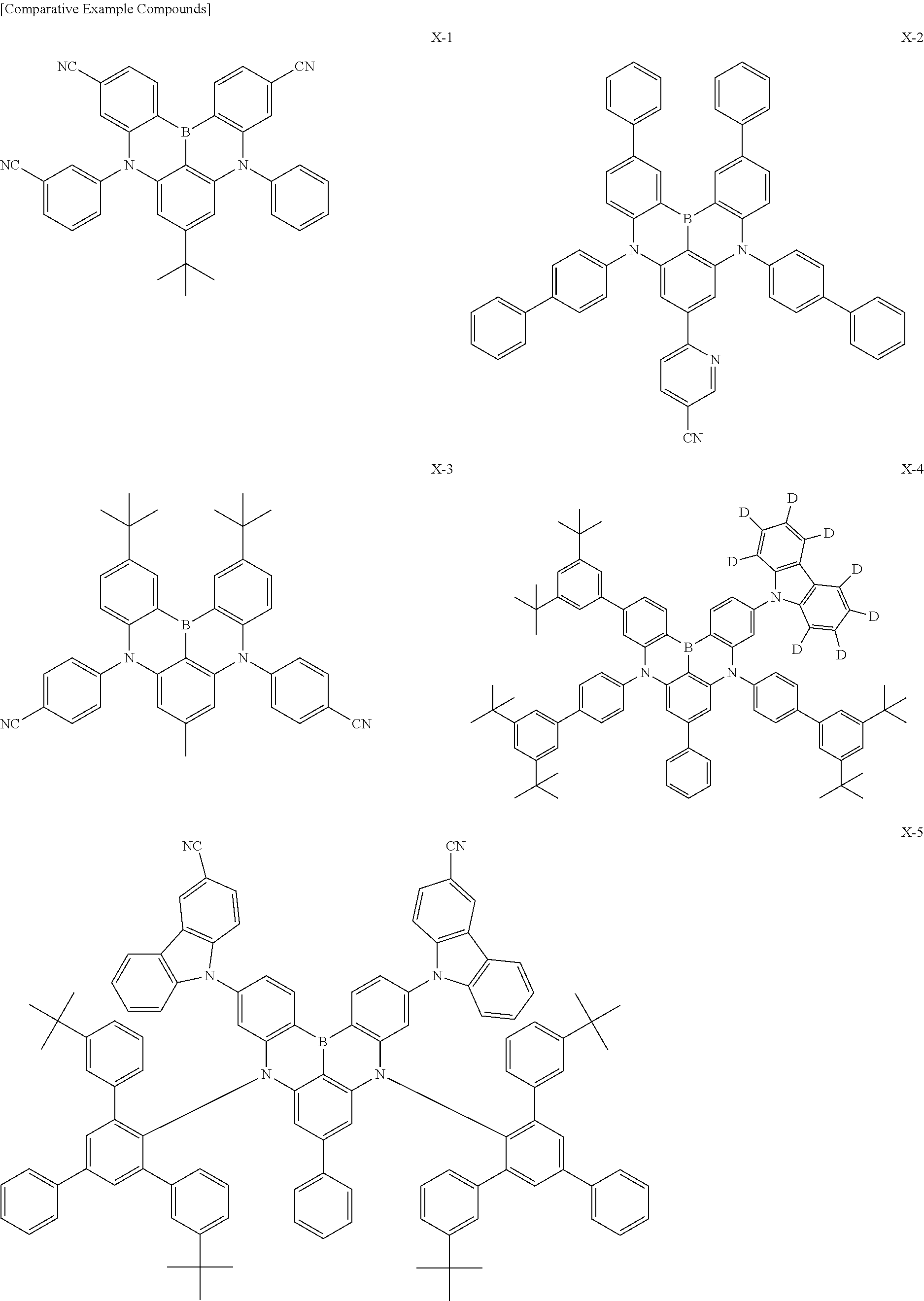

### (Light Emitting Element Preparation 1)

In the preparation of the light emitting elements of the Examples and the Comparative Examples, as an anode, a glass substrate having an ITO electrode (Corning, 15 Ω/cm², 1200 Å) formed thereon was cut to a size of about 50 mm×50 mm×0.7 mm, subjected to ultrasonic cleaning using isopropyl alcohol and pure water for 5 minutes each and ultraviolet irradiation for 30 minutes, and exposed to ozone. The anode was mounted on a vacuum deposition apparatus.

On the anode, a hole injection layer having a thickness of 300 Å was formed through the deposition of NPD. On the hole injection layer, a hole transport layer having a thickness of 200 Å was formed through the deposition of a hole transport material included in the Compound Group H as described above. On the hole transport layer, an auxiliary emission layer having a thickness of 100 Å was formed through the deposition of CzSi.

An emission layer having a thickness of 200 Å was formed through the co-deposition of a host compound in which a second compound and a third compound according to an embodiment were mixed in a ratio of 1:1, a fourth compound, and an Example Compound or a Comparative Example Compound in a weight ratio of 85:14:1. On the emission layer, a hole blocking layer having a thickness of 200 Å was formed through the deposition of TSPO1. On the hole blocking layer, an electron transport layer having a thickness of 300 Å was formed through the deposition of TPBI. On the electron transport layer, an electron injection layer having a thickness of 10 Å was formed through the deposition of LiF. On the electron injection layer, a cathode having a thickness of 3,000 Å was formed through the deposition of Al. A capping layer having a thickness of 700 Å was formed through the deposition of P4 described above to prepare a light emitting element.

Each layer was formed through vacuum evaporation. Among the compounds of Compound Group H, Compounds H-1-1 to H-1-5 were used as the hole transport layer material. Among the compounds of Compound Group 2, Compounds HT1, HT2, and HT3 were used as the second compound. Among the compounds of Compound Group 3, Compounds ETH66, ETH85, and ETH86 were used as the third compound. Among the compounds of Compound Group 4, Compounds AD-37 and AD-38 were used as the fourth compound.

The compounds used in the preparation of the light emitting elements of the Examples and the Comparative Examples are disclosed below. The following materials were used for the preparation of the elements after performing sublimation purification of commercially available products.

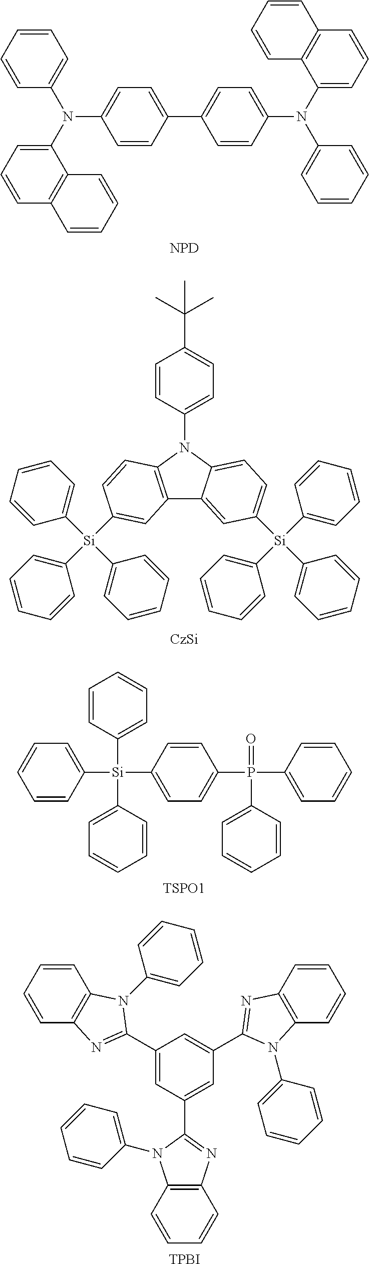

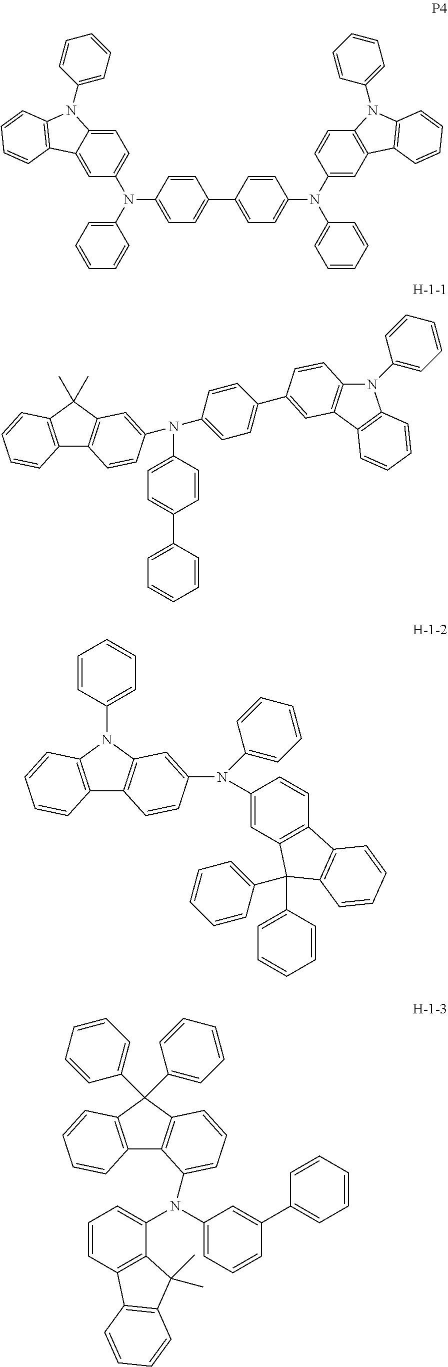 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

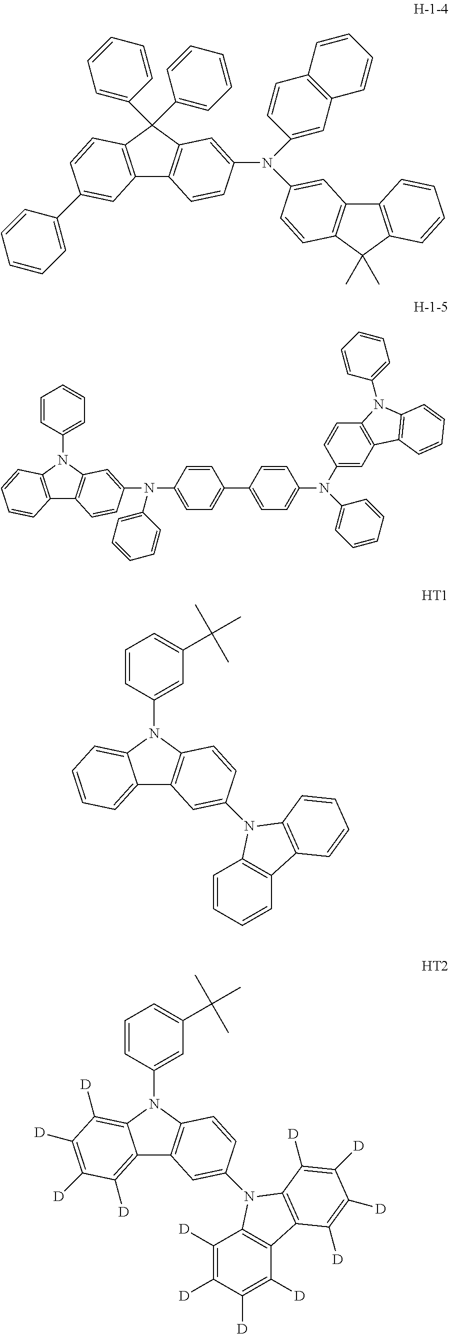 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1]

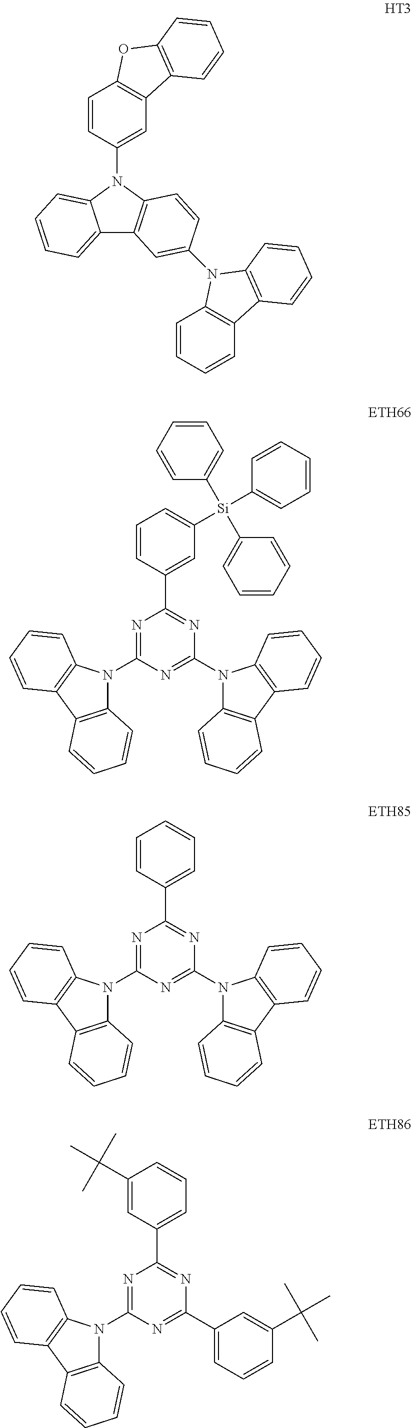 [SMILES: c1ccc2c(c1)oc1ccc(-n3c4ccccc4c4cc(-n5c6ccccc6c6ccccc65)ccc43)cc12 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

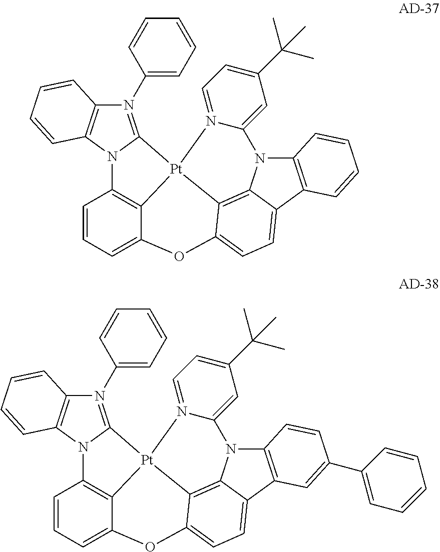

### (Light Emitting Element Property Evaluation 1)

Element efficiency and element lifespan of the light emitting elements prepared using Example Compounds 2, 81, 109, 217, and 294, and Comparative Example Compounds X-1 to X-5 as described above were evaluated. Table 1 shows the evaluation results of the light emitting elements for Examples 1 to 5 and Comparative Examples 1 to 5. In order to evaluate the properties of the light emitting elements prepared for Examples 1 to 5 and Comparative Examples 1 to 5, at a current density of 1000 cd/m², driving voltage (V), light emitting efficiency (Cd/A), and emission wavelength were each determined using Keithley MU 236 and a luminance meter PR650, and the results are shown in Table 1. A time taken for luminance to reach 95% with respect to an initial luminance was determined as lifespan (T95), and in Table 1, relative lifespan was calculated with respect to Comparative Example 1, and the results are shown in Table 1.

TABLE 1

| | | | | | | | Maximum | | |
|---|---|---|---|---|---|---|---|---|---|
| | Hole | Host | | | | | external | | |
| | transport | (2nd | | | Driving | | quantum | Element | |
| | layer | compound:3rd | 4th | 1st | voltage | Efficiency | efficiency | lifespan | Emitted |
| | material | compound = 5:5) | compound | compound | (V) | (cd/A) | (%) | (%) | color |
| Example 1 | H-1-2 | HT1/ETH85 | AD-37 | Compound 2 | 4.3 | 22.5 | 21.3 | 209 | Blue |
| Example 2 | H-1-3 | HT2/ETH85 | AD-38 | Compound 81 | 4.4 | 21.8 | 20.2 | 198 | Blue |
| Example 3 | H-1-1 | HT2/ETH86 | AD-37 | Compound 109 | 4.3 | 23.4 | 22.1 | 217 | Blue |
| Example 4 | H-1-3 | HT2/ETH86 | AD-38 | Compound 217 | 4.5 | 23.1 | 21.8 | 213 | Blue |
| Example 5 | H-1-2 | HT2/ETH86 | AD-37 | Compound 294 | 4.2 | 21.5 | 19.7 | 192 | Blue |
| Comparative | H-1-3 | HT3/ETH66 | AD-38 | Comparative | 4.3 | 11.1 | 10.2 | 100 | Blue |
| Example 1 | | | | Example | | | | | |
| | | | | Compound X-1 | | | | | |
| Comparative | H-1-5 | HT2/ETH66 | AD-37 | Comparative | 4.4 | 10.8 | 9.8 | 96 | Blue |
| Example 2 | | | | Example | | | | | |
| | | | | Compound X-2 | | | | | |
| Comparative | H-1-3 | HT2/ETH86 | AD-38 | Comparative | 4.1 | 12.2 | 10.8 | 120 | Blue |
| Example 3 | | | | Example | | | | | |
| | | | | Compound X-3 | | | | | |
| Comparative | H-1-2 | HT2/ETH85 | AD-37 | Comparative | 4.3 | 15.8 | 13.7 | 135 | Blue |
| Example 4 | | | | Example | | | | | |
| | | | | Compound X-4 | | | | | |
| Comparative | H-1-4 | HT2/ETH85 | AD-38 | Comparative | 4.4 | 20.3 | 18.6 | 183 | Blue |
| Example 5 | | | | Example | | | | | |
| | | | | Compound X-5 | | | | | |

Referring to the results of Table 1, it can be seen that the light emitting elements of the Examples using the fused polycyclic compound according to an embodiment as light emitting materials had greater light emitting efficiency and lifespan than the light emitting elements of the Comparative Examples.

It can be seen that the Example Compounds have a structure in which a first phenyl group and a second phenyl group are substituents of a fused ring core, and at least one first substituent is substituted on at least one of the first phenyl group and the second phenyl group. Thus, when the Example Compounds were applied to light emitting elements, the light emitting elements of Examples 1 to 5 exhibited greater light emitting efficiency and lifespan than the Comparative Examples. The Example Compounds include a fused ring core including a boron atom and two nitrogen atoms as ring-forming atoms and further include at least one first substituent substituted on a phenyl group bonded to a ring-forming nitrogen atom of the fused ring core, wherein the first substituent includes a cyano group. Accordingly, a deep HOMO energy level is shown to prevent trap-assisted recombination, which causes element deterioration, resulting in greater light emitting efficiency and lifespan. Accordingly, when the Example Compounds are applied to a light emitting element, high light emitting efficiency and long lifespan may be achieved. The light emitting element according to an embodiment includes a fused polycyclic compound according to an embodiment as a light emitting dopant of a thermally activated delayed fluorescence (TADF) light emitting element, and may thus achieve high element efficiency, for example, in a blue light wavelength range.

It can be seen that Comparative Example Compounds X-1 to X-3 and X-5 included in Comparative Examples 1 to 3, and Comparative Example 5 included a core structure similar to that of the fused polycyclic compound according to an embodiment, and included a cyano group. However, unlike the Example Compounds, Comparative Example Compounds X-1 to X-3 and X-5 were not formed to have a structure in which a cyano-substituted phenyl group was substituted on a phenyl group bonded to a ring-forming nitrogen atom of the core structure, and thus, when applied to light emitting elements, exhibited low light emitting efficiency and lifespan, and high driving voltage.

It can be seen that Comparative Example Compound X-4 included in Comparative Example 4 included a core structure similar to that of the fused polycyclic compound according to an embodiment, but did not include a cyano group in the molecular structure thereof, and thus, when applied to a light emitting element, exhibited low light emitting efficiency and lifespan, and high driving voltage.

### (Light Emitting Element Preparation 2)

In the preparation of the light emitting elements of the Examples and the Comparative Examples, as an anode, a glass substrate having an ITO electrode (Corning, 15 Ω/cm², 1200 Å) formed thereon was cut to a size of about 50 mm×50 mm×0.7 mm, subjected to ultrasonic cleaning using isopropyl alcohol and pure water for 5 minutes each and ultraviolet irradiation for 30 minutes, and exposed to ozone. The anode was mounted on a vacuum deposition apparatus.

On the anode, a hole injection layer having a thickness of 300 Å was formed through the deposition of NPD. On the hole injection layer, a hole transport layer having a thickness of 200 Å was formed through the deposition of a hole transport material included in the Compound Group H as described above. On the hole transport layer, an auxiliary emission layer having a thickness of 100 Å was formed through the deposition of CzSi.

An emission layer having a thickness of 200 Å was formed through the co-deposition of a host compound in which a second compound and a third compound according to an embodiment were mixed in a ratio of 1:1, and an Example Compound or a Comparative Example Compound in a weight ratio of 99:1. On the emission layer, a hole blocking layer having a thickness of 200 Å was formed through the deposition of TSPO1. On the hole blocking layer, an electron transport layer having a thickness of 300 Å was formed through the deposition of TPBI. On the electron transport layer, an electron injection layer having a thickness of 10 Å was formed through the deposition of LiF. On the electron injection layer, a cathode having a thickness of 3,000 Å was formed through the deposition of Al. A capping layer having a thickness of 700 Å was formed through the deposition of P4 described above to prepare a light emitting element.

Each layer was formed through vacuum evaporation. Among the compounds of Compound Group H, Compounds H-1-1 to H-1-5 were used as the hole transport layer material. Among the compounds of Compound Group 2, Compounds HT1, HT2, and HT3 were used as the second compound. Among the compounds of Compound Group 3, Compounds ETH66, ETH85, and ETH86 were used as the third compound.

### (Light Emitting Element Property Evaluation 2)

Element efficiency and element lifespan of the light emitting elements prepared using Example Compounds 2, 81, 109, 217, and 294, and Comparative Example Compounds X-1 to X-5 as described above were evaluated. Table 2 shows the evaluation results of the light emitting elements for Examples 6 to 10 and Comparative Examples 6 to 10. In order to evaluate the properties of the light emitting elements prepared for Examples 6 to 10 and Comparative Examples 6 to 10, at a current density of 1000 cd/m², light emitting efficiency (Cd/A) and emission wavelength were each determined using Keithley MU 236 and a luminance meter PR650, and the results are shown in Table 2.

TABLE 2

| | | | | | Maximum | |
|---|---|---|---|---|---|---|
| | Hole | Host | | | external | |
| | transport | (2nd | | | quantum | |
| | layer | compound:3rd | 1st | Efficiency | efficiency | Emitted |
| | material | compound = 5:5) | compound | (cd/A) | (%) | color |
| Example 6 | H-1-2 | HT1/ETH85 | Compound 2 | 8.8 | 8.3 | Blue |
| Example 7 | H-1-3 | HT2/ETH85 | Compound 81 | 8.6 | 8.1 | Blue |
| Example 8 | H-1-1 | HT2/ETH86 | Compound 109 | 8.9 | 8.5 | Blue |
| Example 9 | H-1-3 | HT2/ETH86 | Compound 217 | 8.7 | 8.3 | Blue |
| Example 10 | H-1-2 | HT2/ETH86 | Compound 294 | 8.5 | 8.2 | Blue |
| Comparative | H-1-3 | HT2/ETH66 | Comparative | 4.2 | 3.8 | Blue |
| Example 6 | | | Example | | | |
| | | | Compound X-1 | | | |
| Comparative | H-1-4 | HT2/ETH86 | Comparative | 4.0 | 3.6 | Blue |
| Example 7 | | | Example | | | |
| | | | Compound X-2 | | | |
| Comparative | H-1-3 | HT2/ETH86 | Comparative | 4.5 | 4.3 | Blue |
| Example 8 | | | Example | | | |
| | | | Compound X-3 | | | |
| Comparative | H-1-2 | HT2/ETH85 | Comparative | 6.1 | 5.8 | Blue |
| Example 9 | | | Example | | | |
| | | | Compound X-4 | | | |
| Comparative | H-1-4 | HT2/ETH85 | Comparative | 8.2 | 7.9 | Blue |
| Example 10 | | | Example | | | |
| | | | Compound X-5 | | | |

Referring to the results of Table 2, it can be seen that the light emitting elements of the Examples using the fused polycyclic compound according to an embodiment as light emitting materials had greater light emitting efficiency than the light emitting elements of the Comparative Examples.

It can be seen that Comparative Example Compounds X-6 to X-8 and X-10 included in Comparative Examples 6 to 8, and Comparative Example 10 included a core structure similar to that of the fused polycyclic compound according to an embodiment, and included a cyano group. However, unlike the Example Compounds, Comparative Example Compounds X-6 to X-8 and X-10 were not formed to have a structure in which a cyano-substituted phenyl group was substituted on a phenyl group bonded to a ring-forming nitrogen atom of the core structure, and thus, when applied to light emitting elements, exhibited low light emitting efficiency and lifespan, and high driving voltage.

It can be seen that Comparative Example Compound X-9 included in Comparative Example 9 included a core structure similar to that of the fused polycyclic compound according to an embodiment, but did not include a cyano group in the molecular structure thereof, and thus, when applied to a light emitting element, exhibited low light emitting efficiency and lifespan, and high driving voltage.

A light emitting element according to an embodiment may exhibit improved element characteristics of high efficiency and long service life.

A fused polycyclic compound according to an embodiment may be included in an emission layer of a light emitting element, and may thus contribute to high efficiency and long service life.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode facing the first electrode; and
an emission layer disposed between the first electrode and the second electrode, wherein
the emission layer includes a first compound represented by Formula 1: 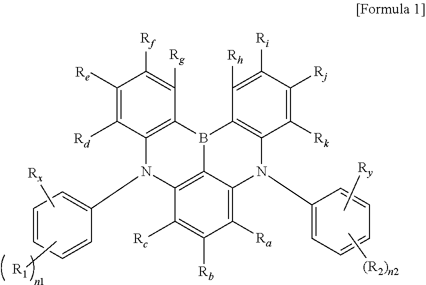
wherein in Formula 1,
R₁, R₂, and Rₐ to Rₖ are each independently a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring,
Rₓ and R_{y} are each independently a substituted or unsubstituted aryl group having 6 to 30 ring-forming carbon atoms, a substituted or unsubstituted heteroaryl group having 2 to 30 ring-forming carbon atoms, or a group represented by Formula 2,
n1 and n2 are each independently an integer from 0 to 4, and
at least one of Rₓ and R_{y} is each independently a group represented by Formula 2: 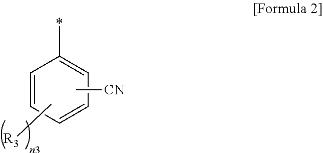
wherein in Formula 2,
R₃ is a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
CN is a cyano group,
n3 is an integer from 0 to 4, and [symbol]
represents a bond to Formula 1.

2. The light emitting element of claim 1, further comprising:
a hole transport region disposed between the first electrode and the emission layer; and
an electron transport region disposed between the emission layer and the second electrode.

3. The light emitting element of claim 1, wherein the emission layer emits delayed fluorescence.

4. The light emitting element of claim 1, wherein the emission layer emits light having a central wavelength in a range of about 430 nm to about 490 nm.

5. The light emitting element of claim 1, wherein a group represented by Formula 2 is a group represented by one of Formulas 2-1 to 2-3: 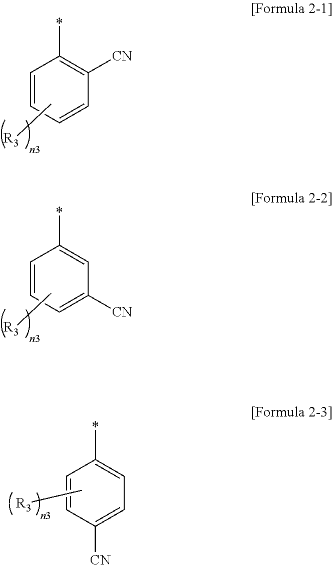
wherein in Formulas 2-1 to 2-3,
CN is a cyano group, and
R₃ and n3 are the same as defined in Formula 2.

6. The light emitting element of claim 1, wherein the first compound is represented by Formula 1-1 or Formula 1-2: 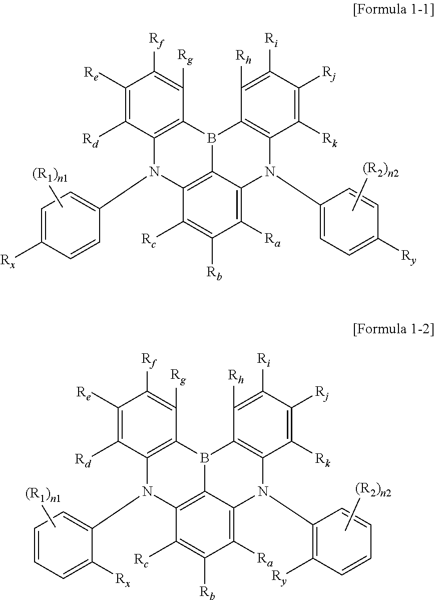
wherein in Formulas 1-1 and 1-2,
R₁, R₂, Rₐ to Rₖ, Rₓ, R_{y}, n1, and n2 are the same as defined in Formula 1.

7. The light emitting element of claim 1, wherein the first compound is represented by Formula 3-1 or Formula 3-2: 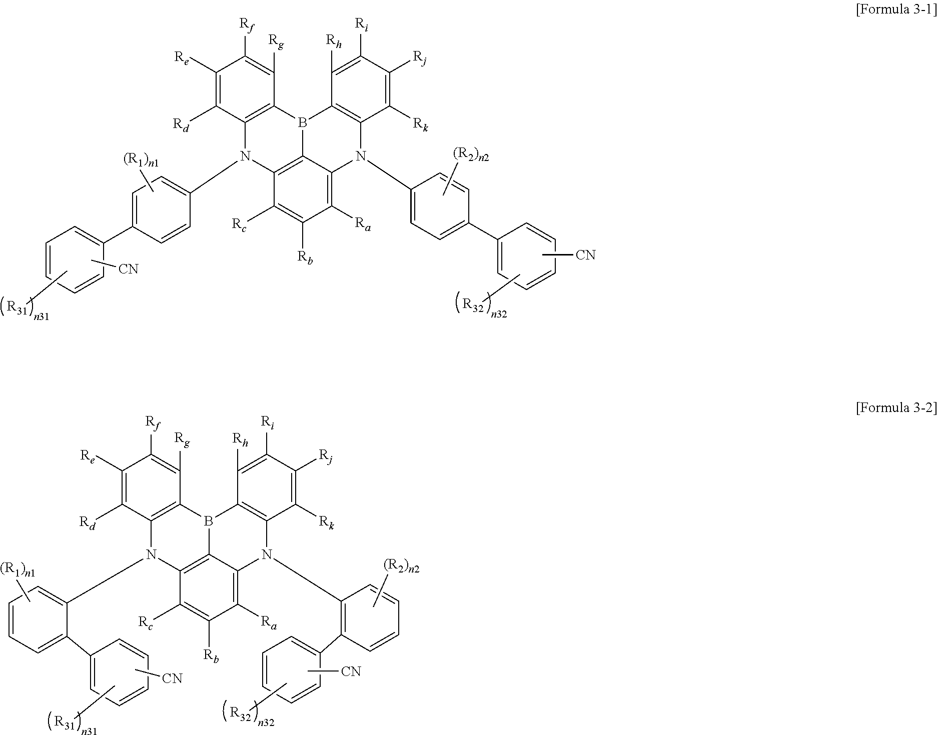
wherein in Formulas 3-1 and 3-2,
R₃₁ and R₃₂ are each independently a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n31 and n32 are each independently an integer from 0 to 4, and
R₁, R₂, Rₐ to Rₖ, n1, and n2 are the same as defined in Formula 1.

8. The light emitting element of claim 1, wherein the first compound is represented by one of Formulas 4-1 to 4-6: 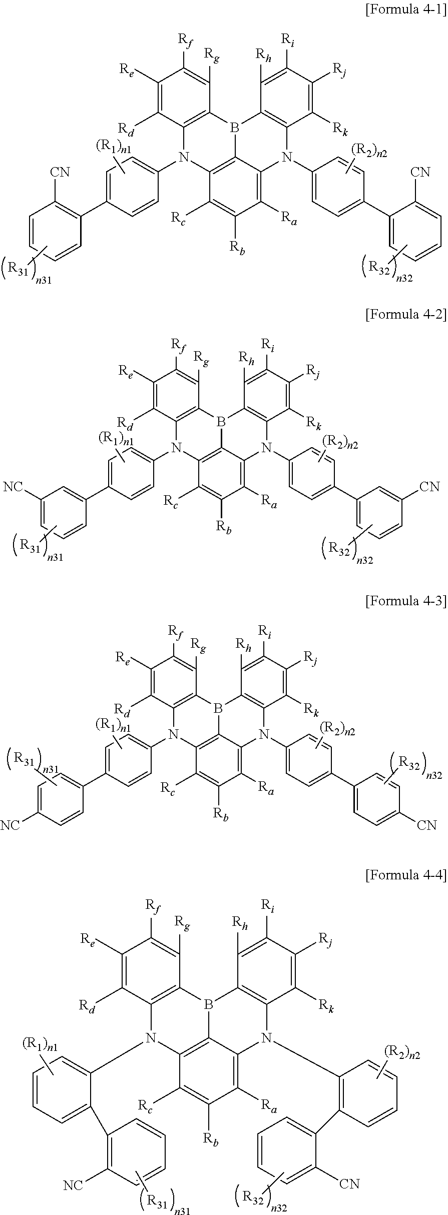 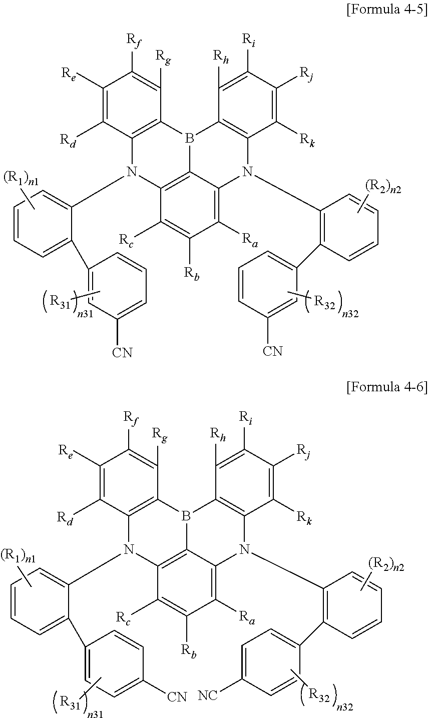
wherein in Formulas 4-1 to 4-6,
R₃₁ and R₃₂ are each independently a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n31 and n32 are each independently an integer from 0 to 4, and
R₁, R₂, Rₐ to Rₖ, n1, and n2 are the same as defined in Formula 1.

9. The light emitting element of claim 1, wherein the first compound is represented by Formula 5: 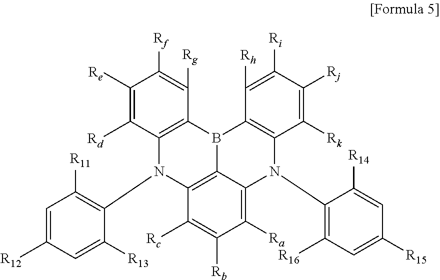
wherein in Formula 5,
R₁₁ to R₁₆ are each independently a hydrogen atom, a deuterium atom, a substituted or unsubstituted aryl group having 6 to 30 ring-forming carbon atoms, a substituted or unsubstituted heteroaryl group having 2 to 30 ring-forming carbon atoms, or a group represented by Formula 2,
at least one of R₁₁ to R₁₆ is each independently a group represented by Formula 2, and
Rₐ to Rₖ are the same as defined in Formula 1.

10. The light emitting element of claim 9, wherein R₁₁ to R₁₆ are each independently a hydrogen atom, a deuterium atom, a group represented by Formula 2, or a group represented by one of Formulas a-1 to a-7: 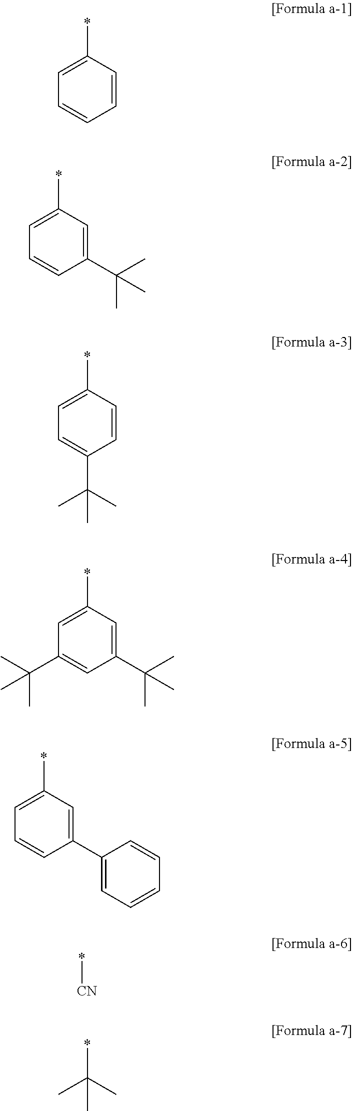
wherein in Formulas a-1 to a-7, [symbol]
represents a bond to Formula 5.

11. The light emitting element of claim 1, wherein the first compound is represented by one of Formulas 6-1 to 6-3: 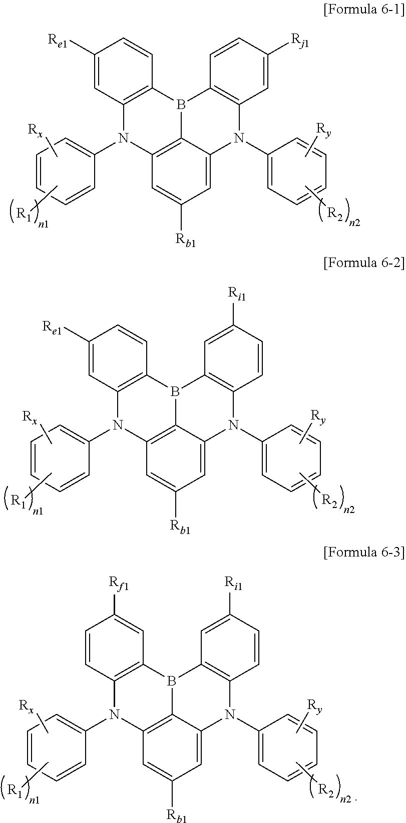
wherein in Formulas 6-1 to 6-3,
R_{b1}, Rₑ₁, R_{f1}, Rᵢ₁, and Rⱼ₁ are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
R₁, R₂, Rₓ, R_{y}, n1, and n2 are the same as defined in Formula 1.

12. The light emitting element of claim 11, wherein Rei, Rei, R_{f1}, Rᵢ₁, and Rⱼ₁ are each independently a group represented by one of Formulas b-1 to b-5: 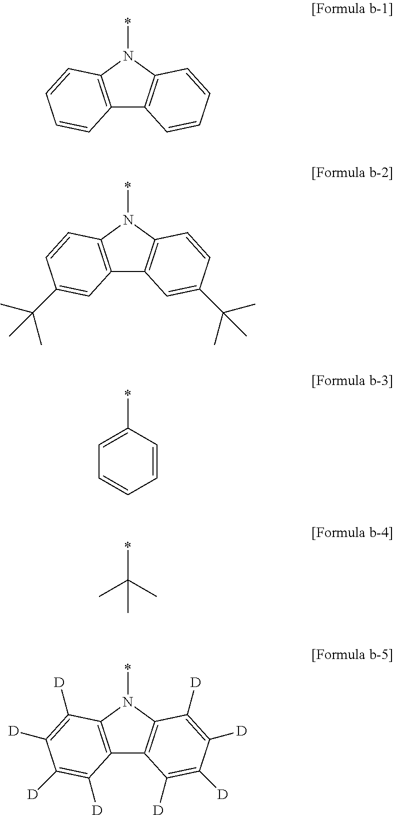
wherein in Formulas b-1 to b-5, [symbol]
represents a bond to one of Formulas 6-1 to 6-3.

13. The light emitting element of claim 1, wherein the first compound comprises at least one compound selected from Compound Group 1:

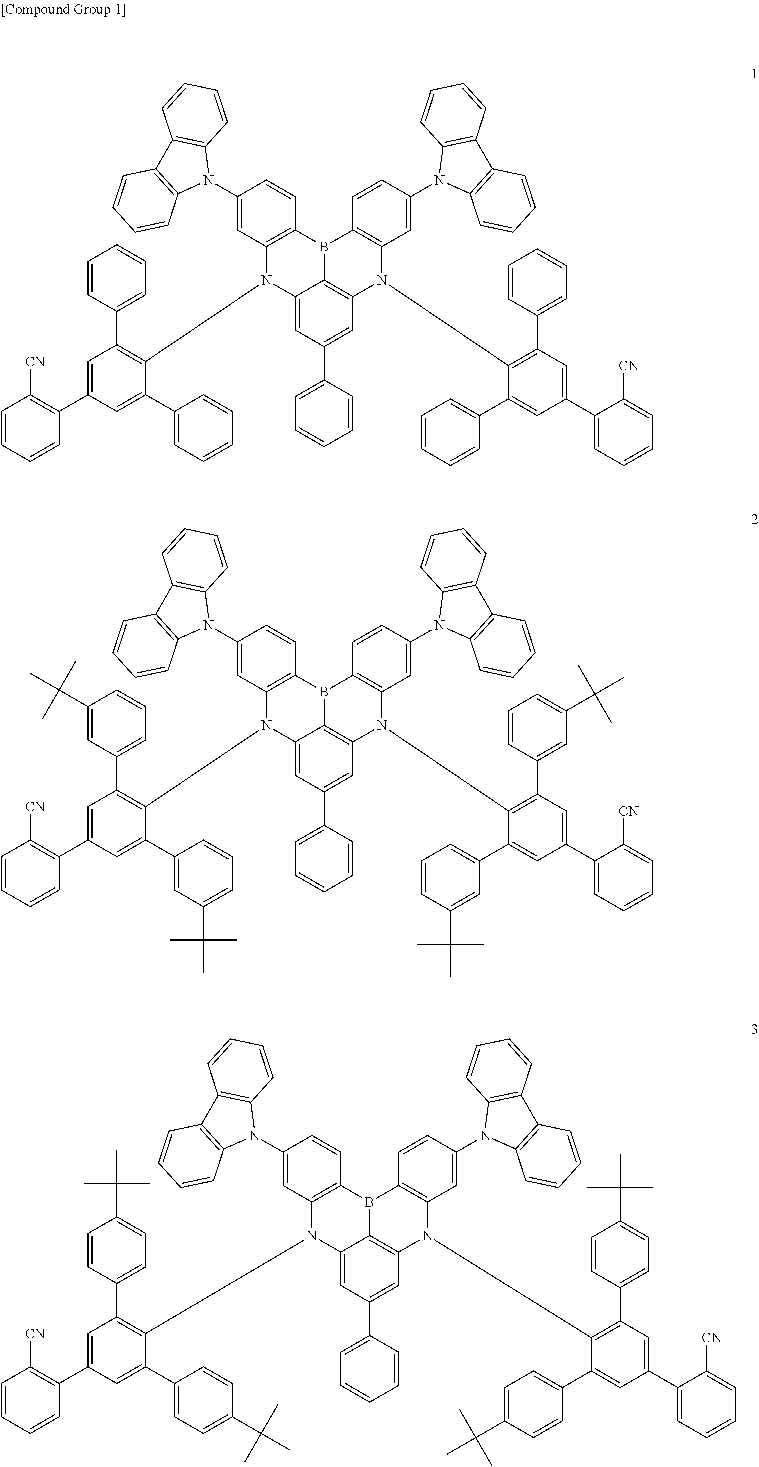

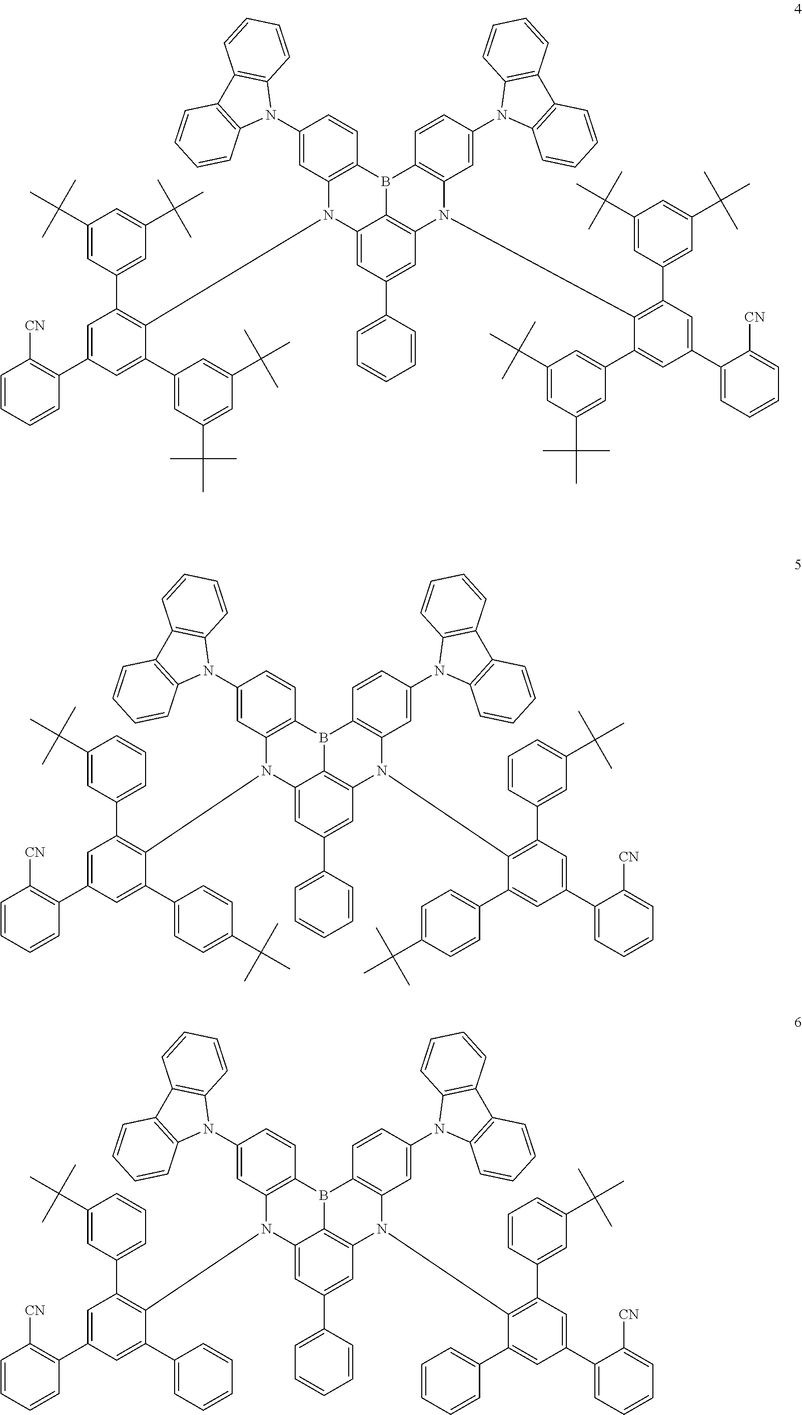

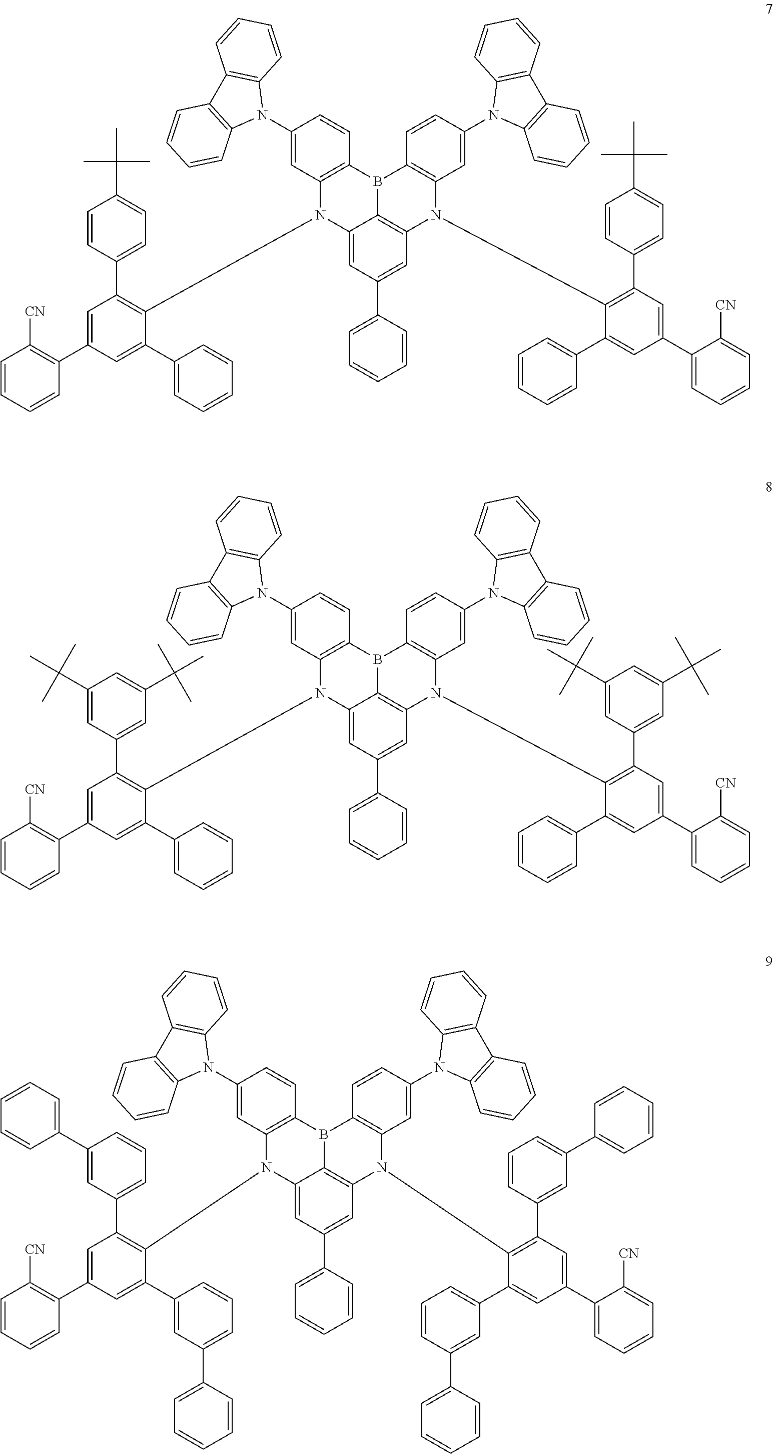

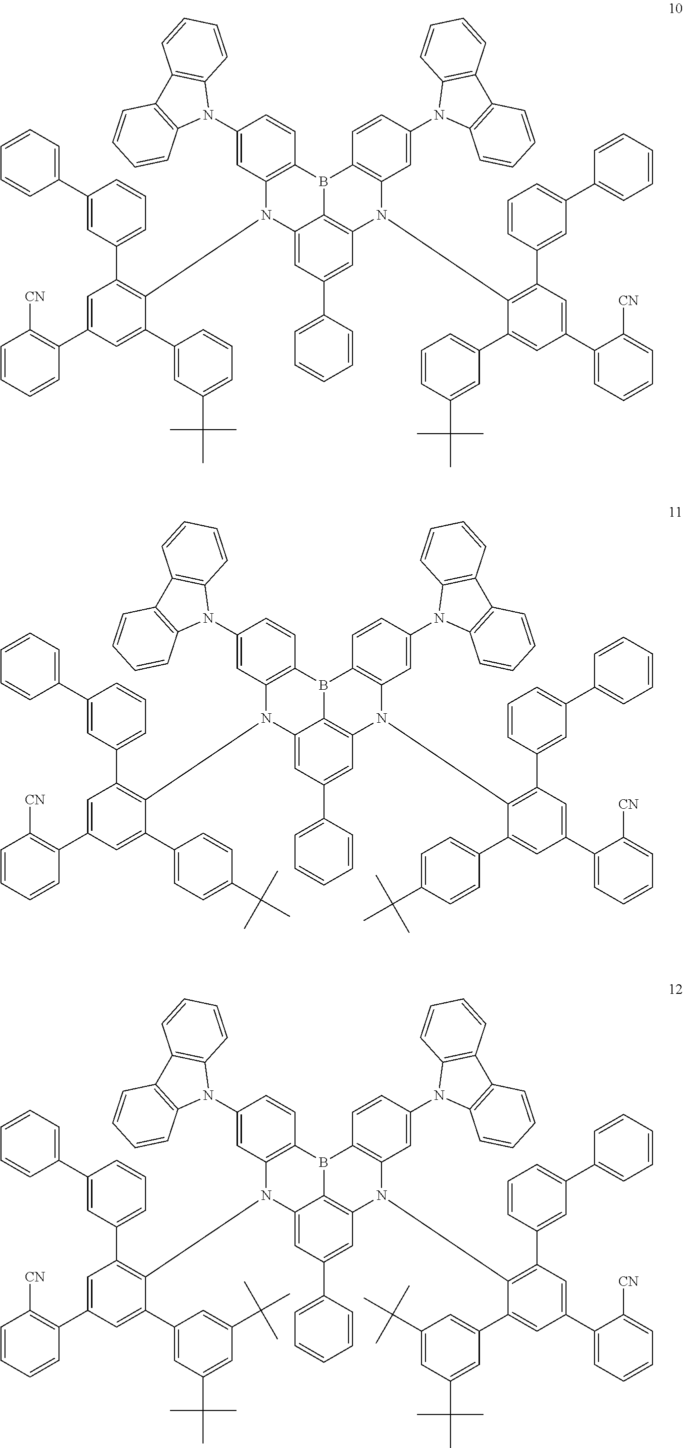

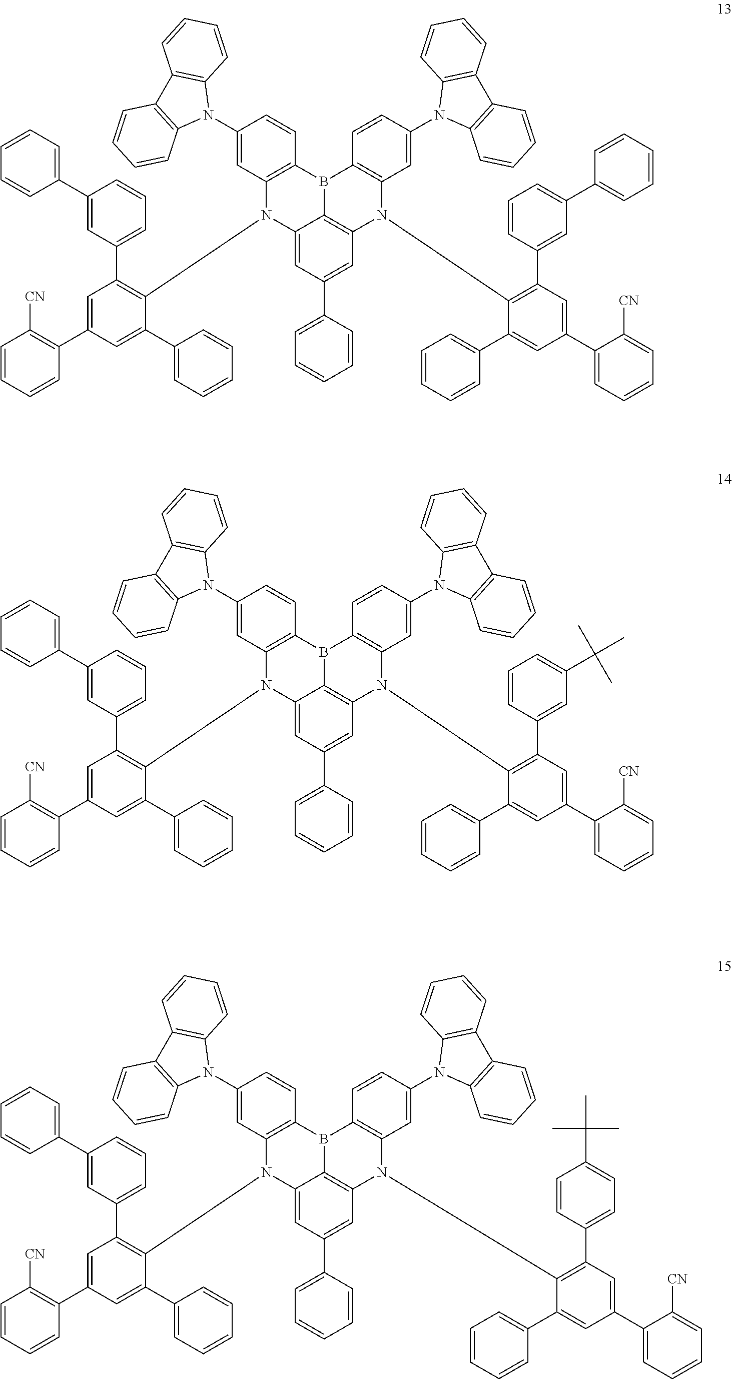

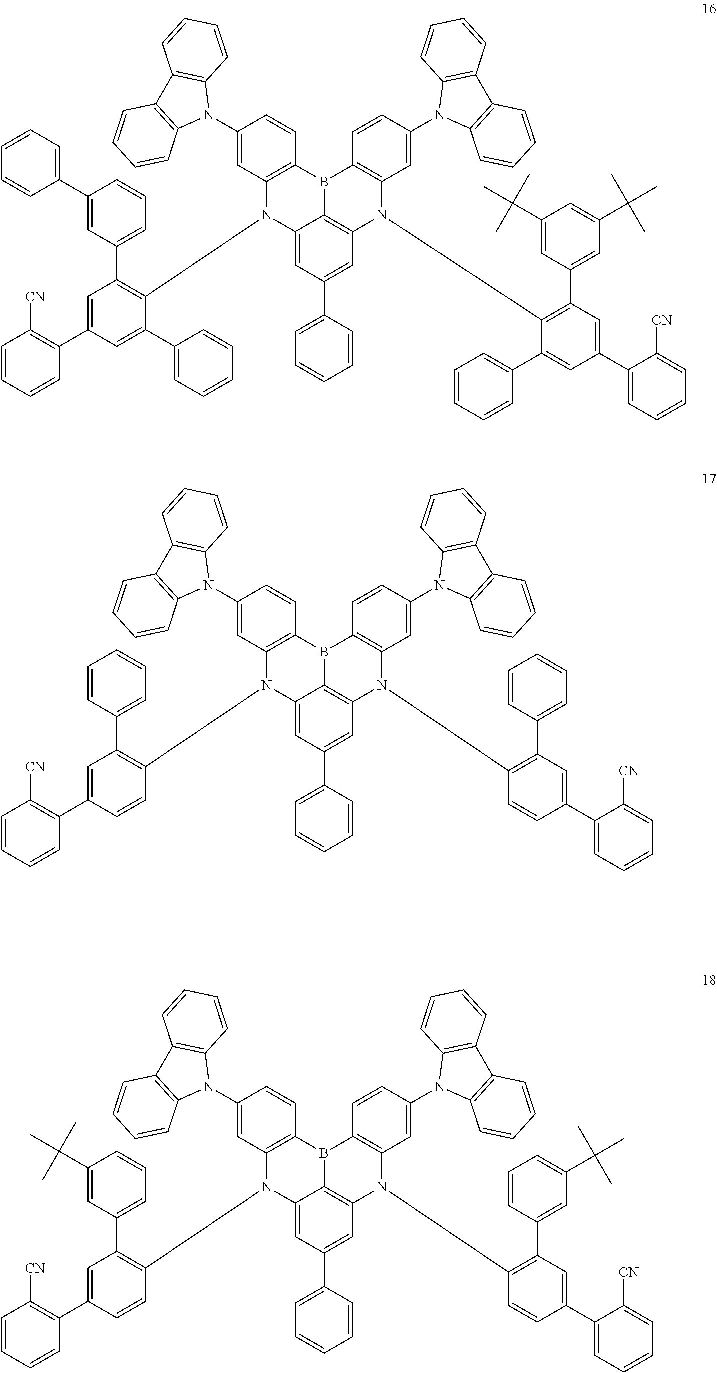

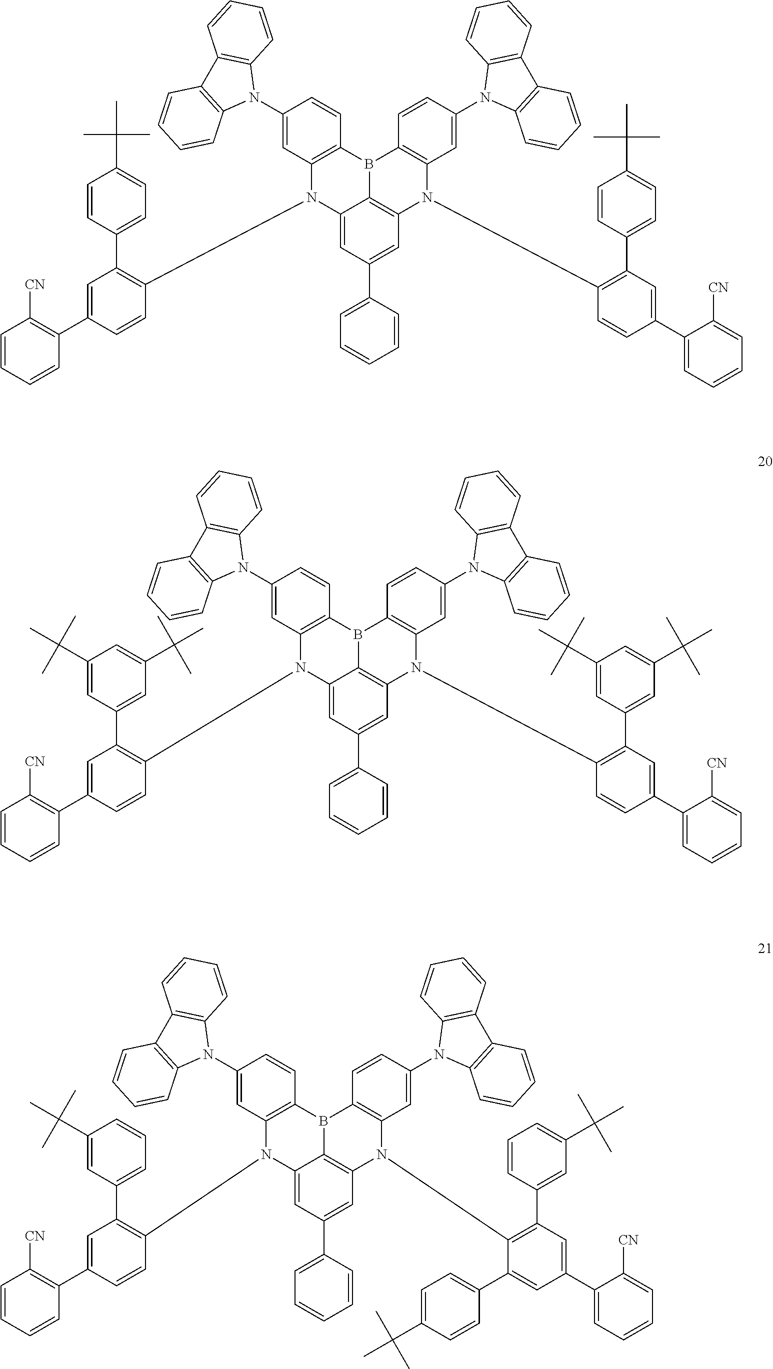

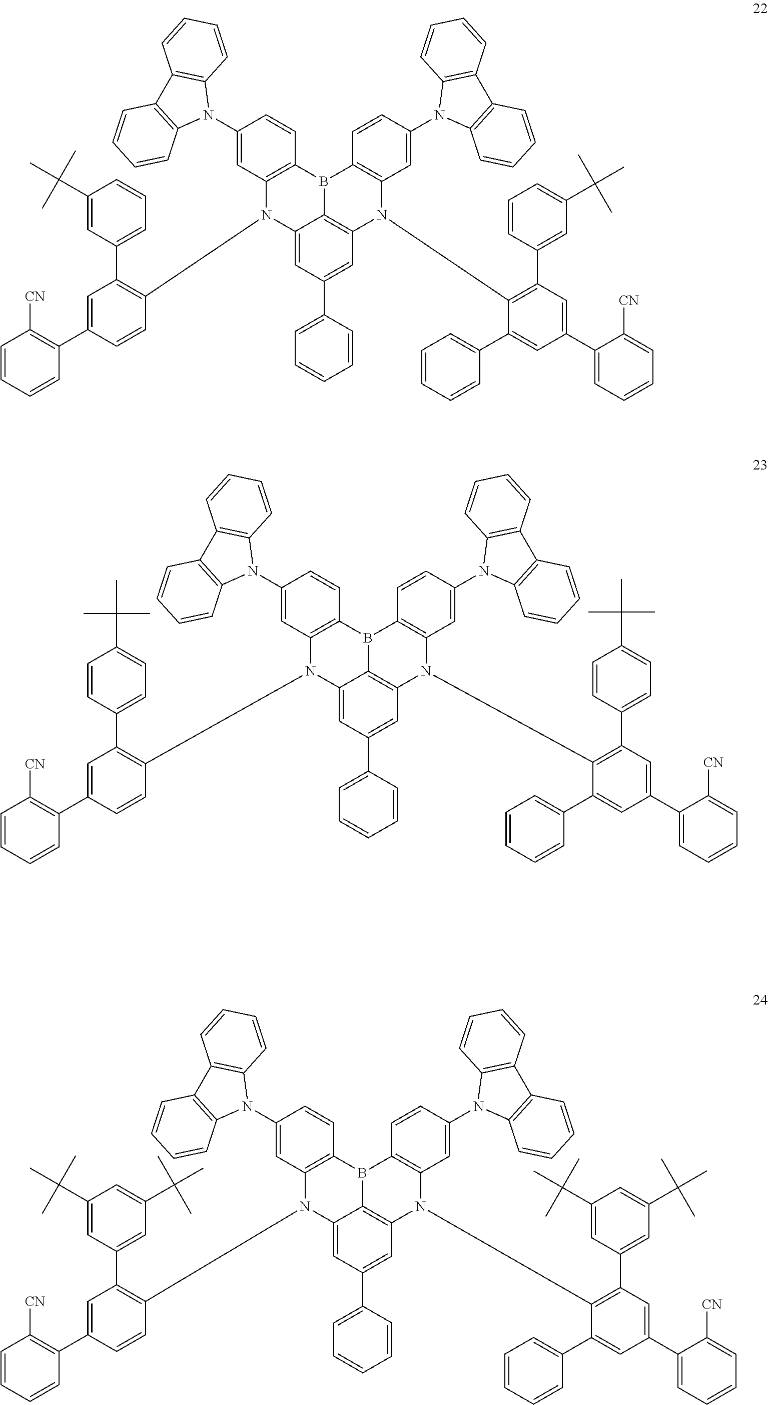

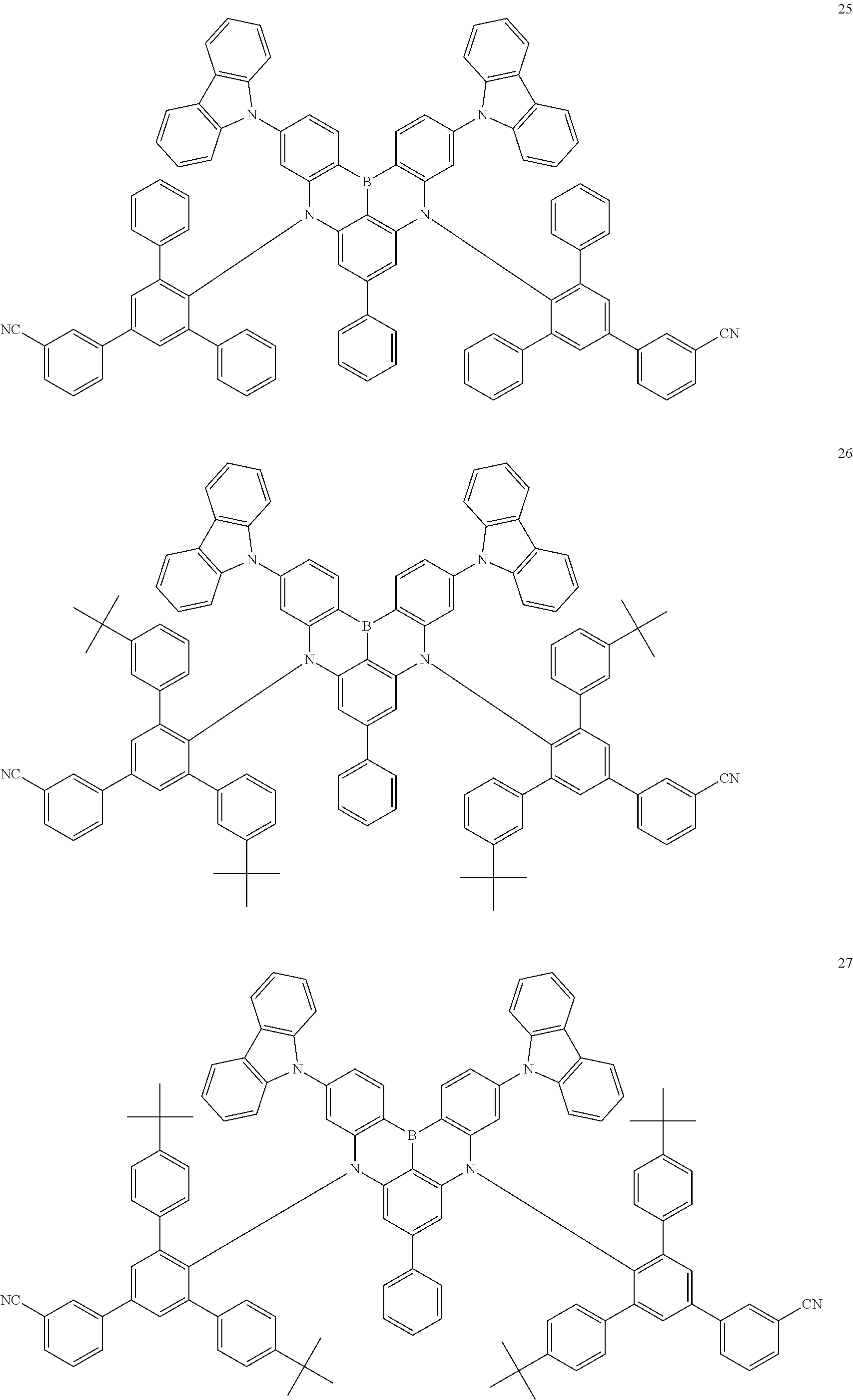

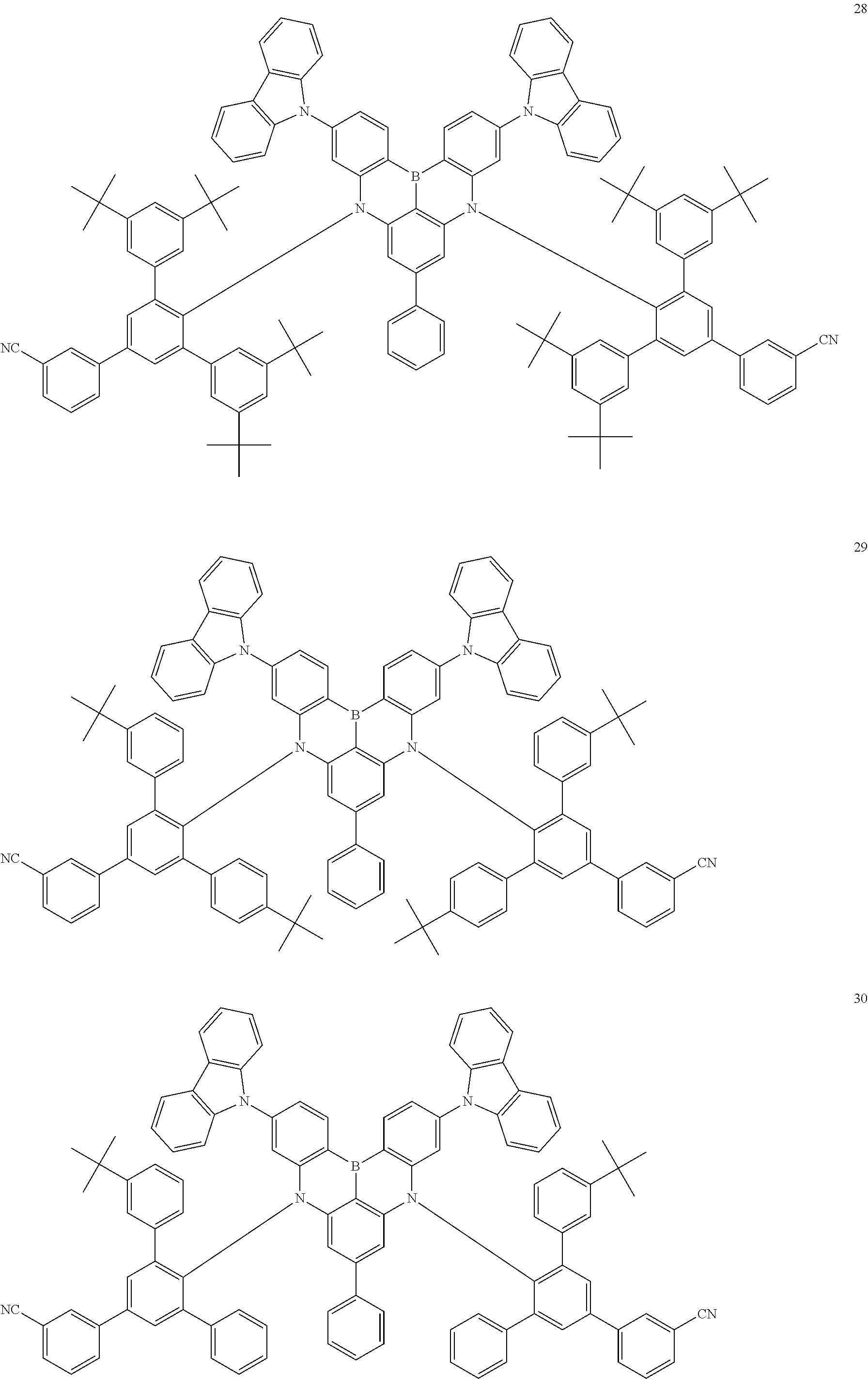

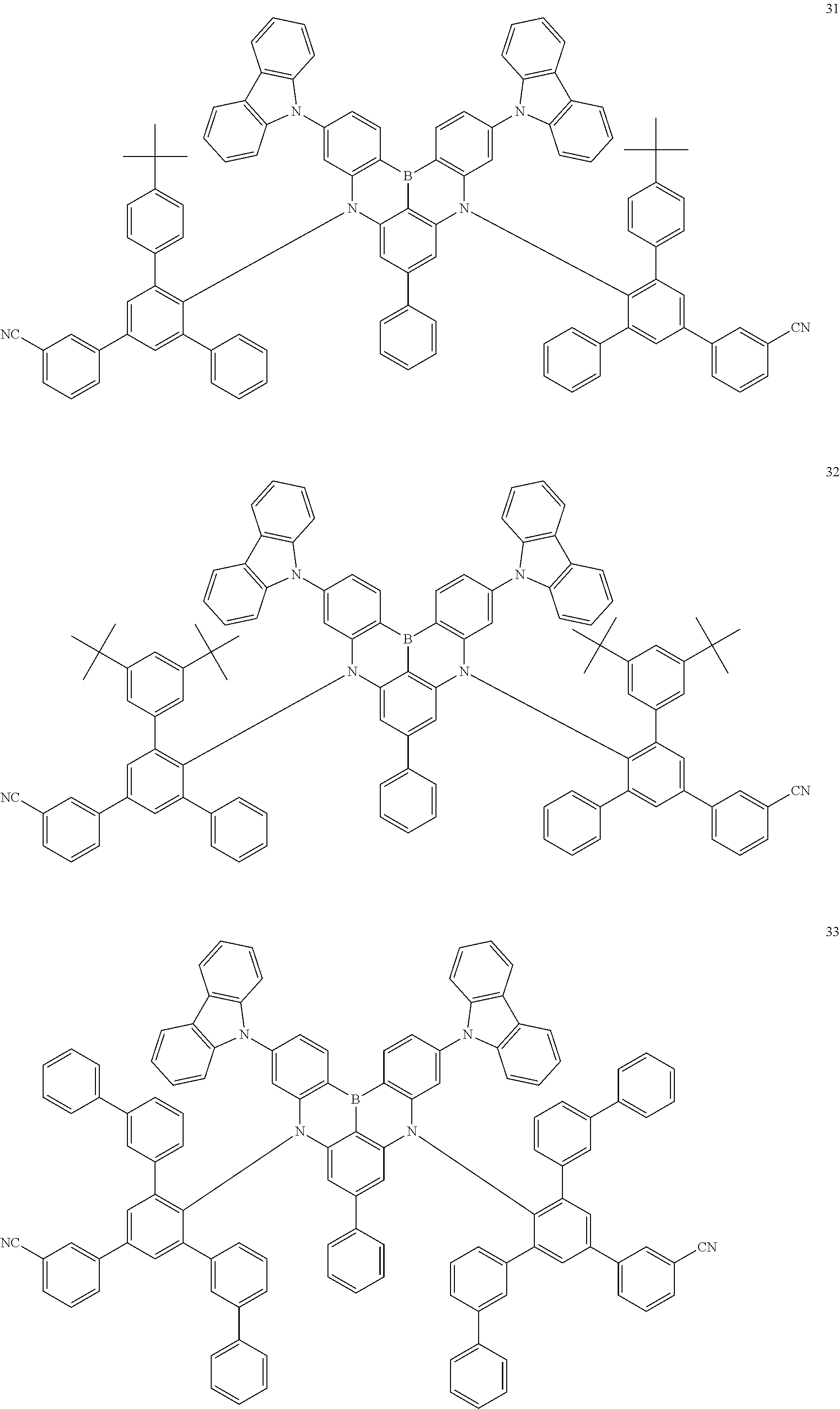

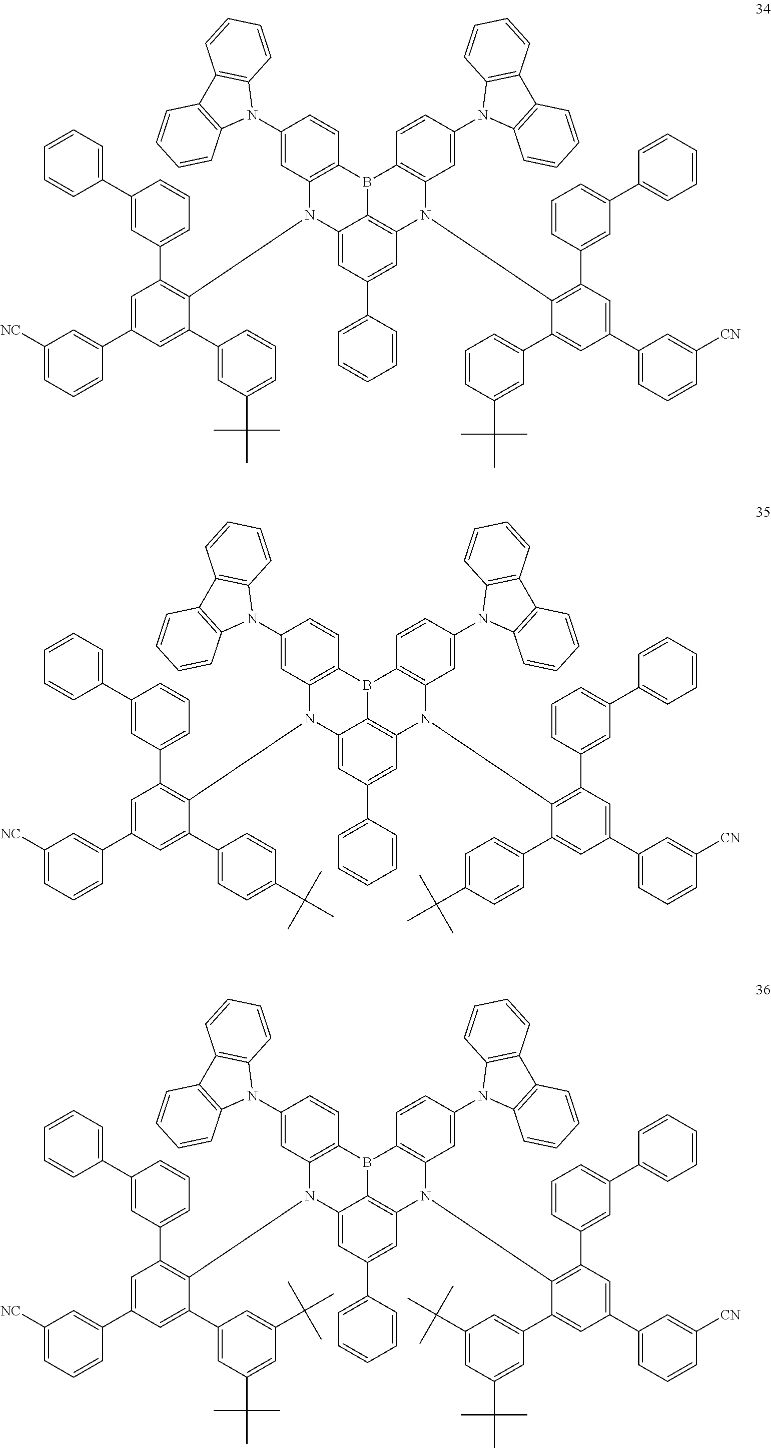

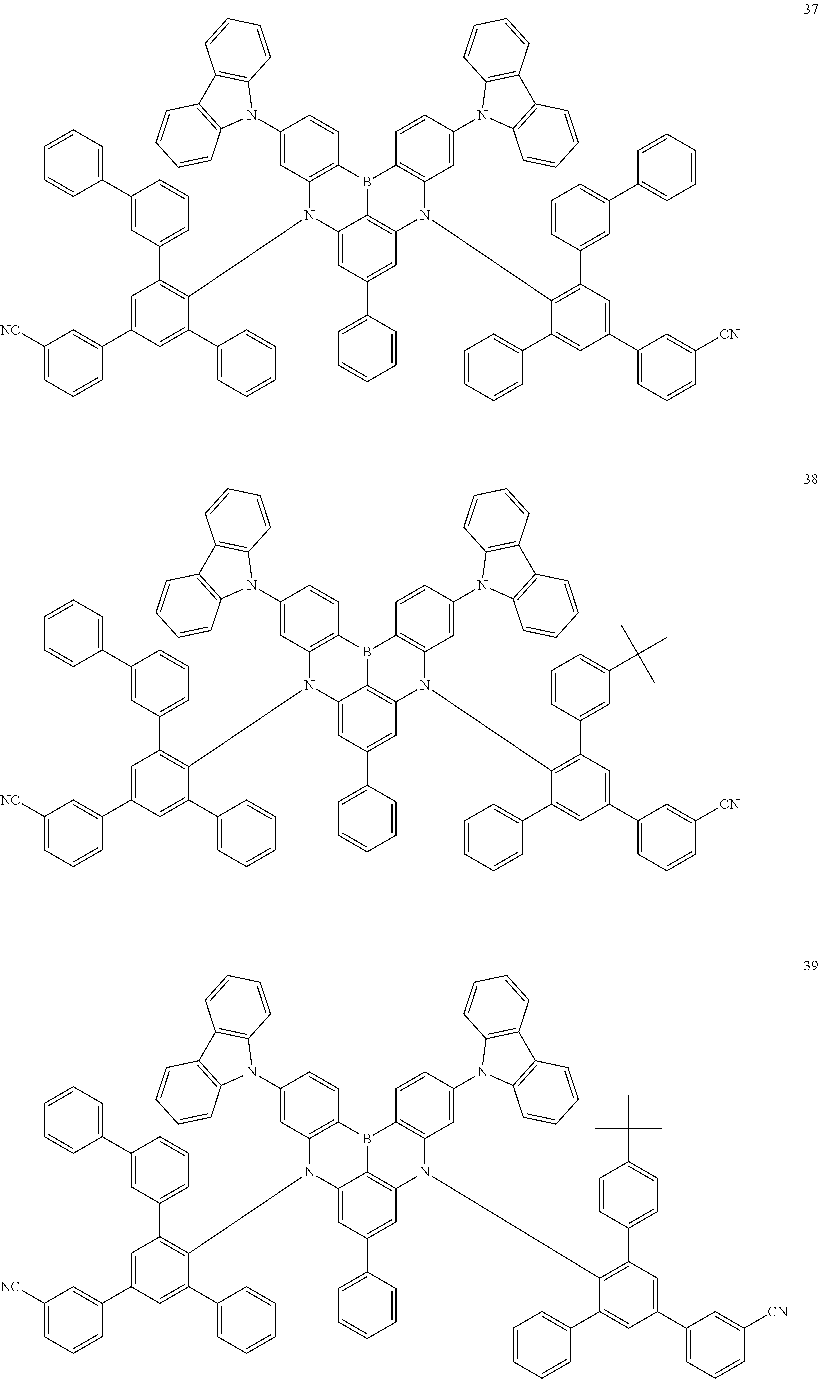

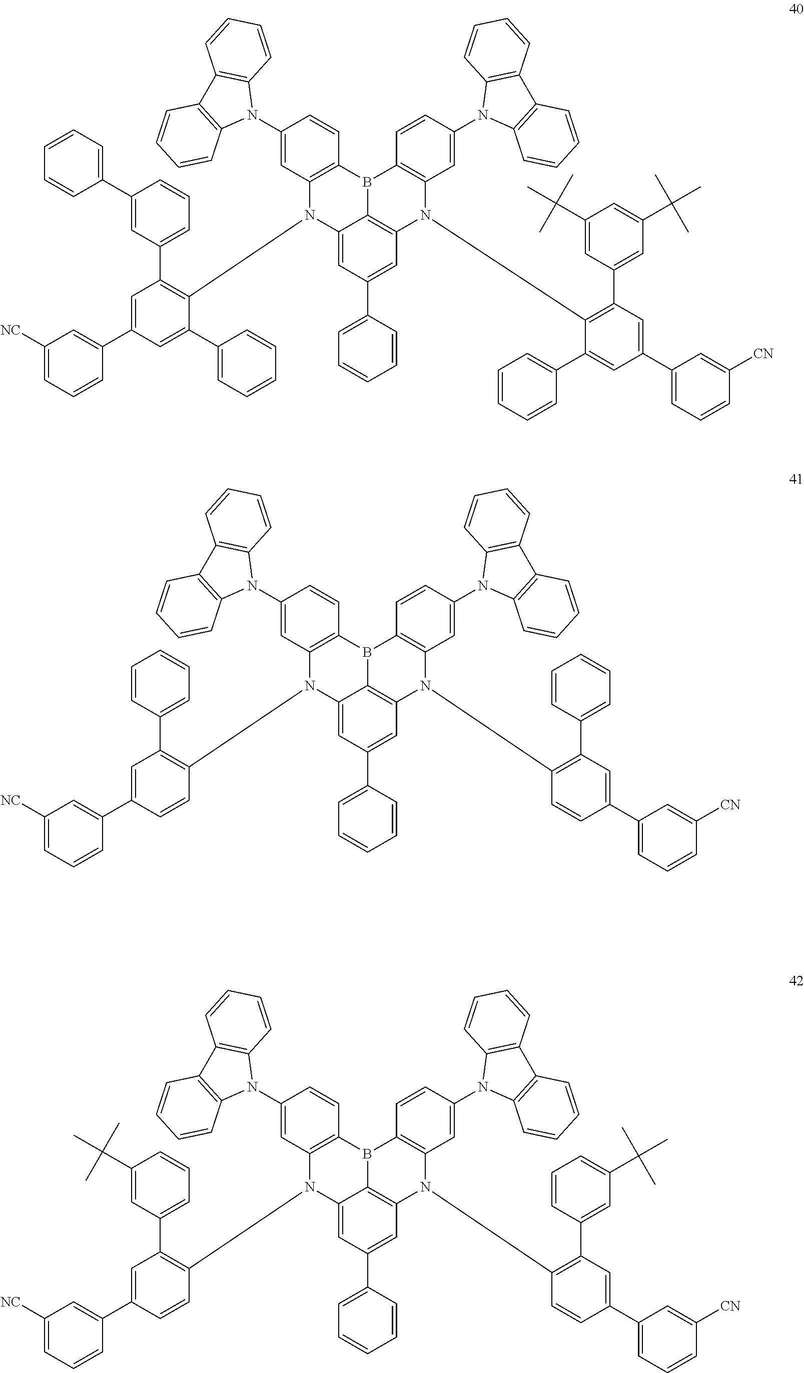

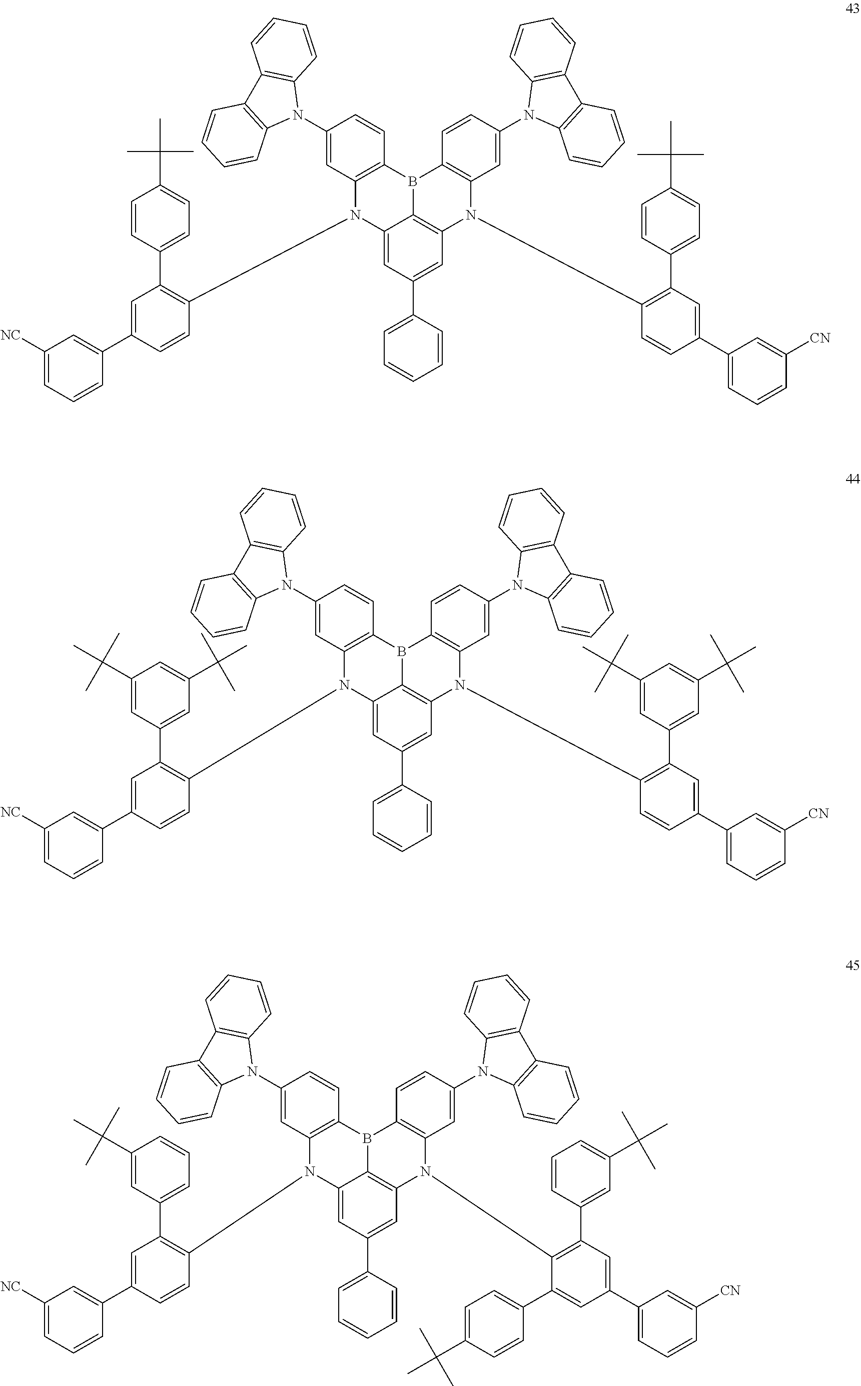

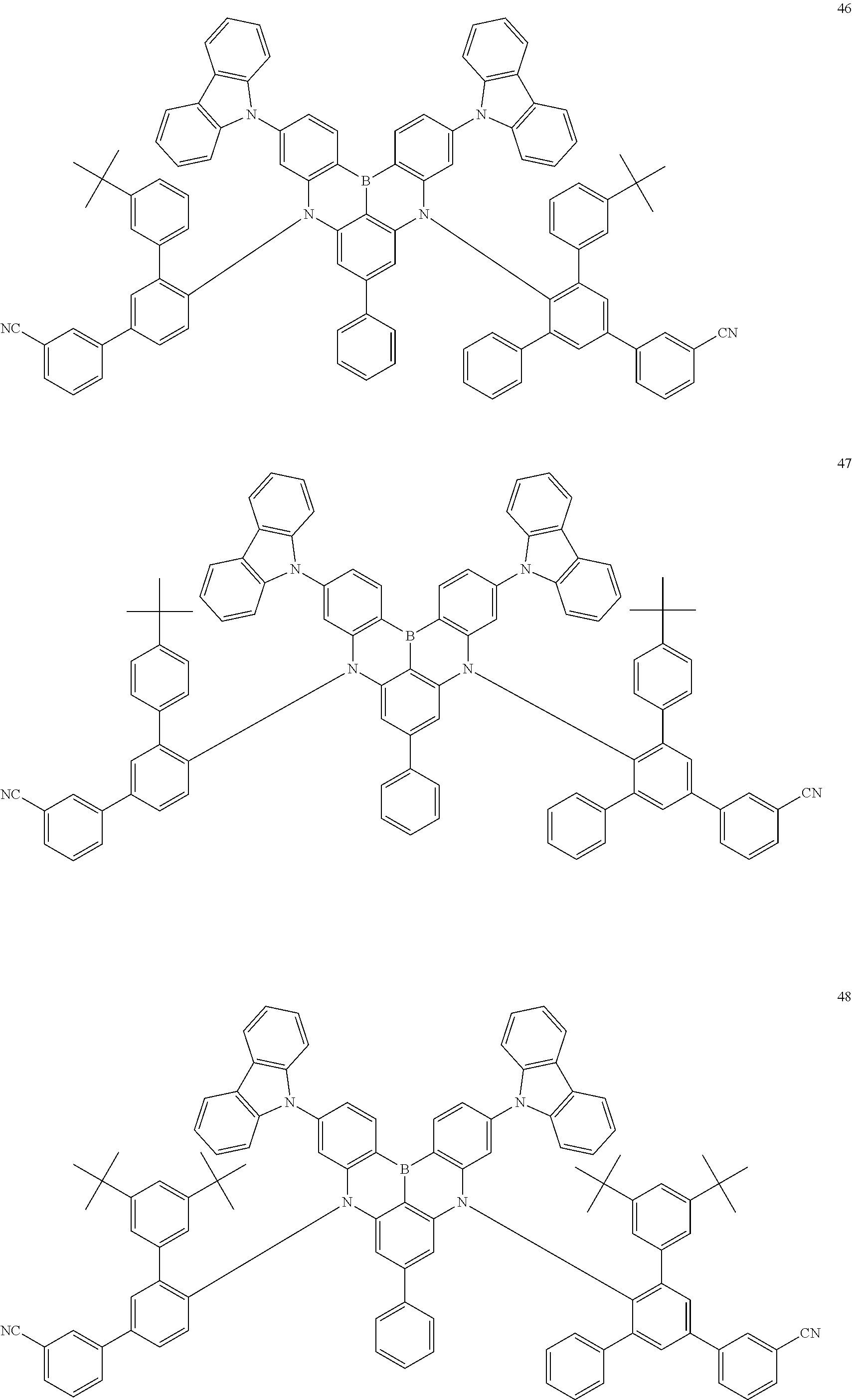

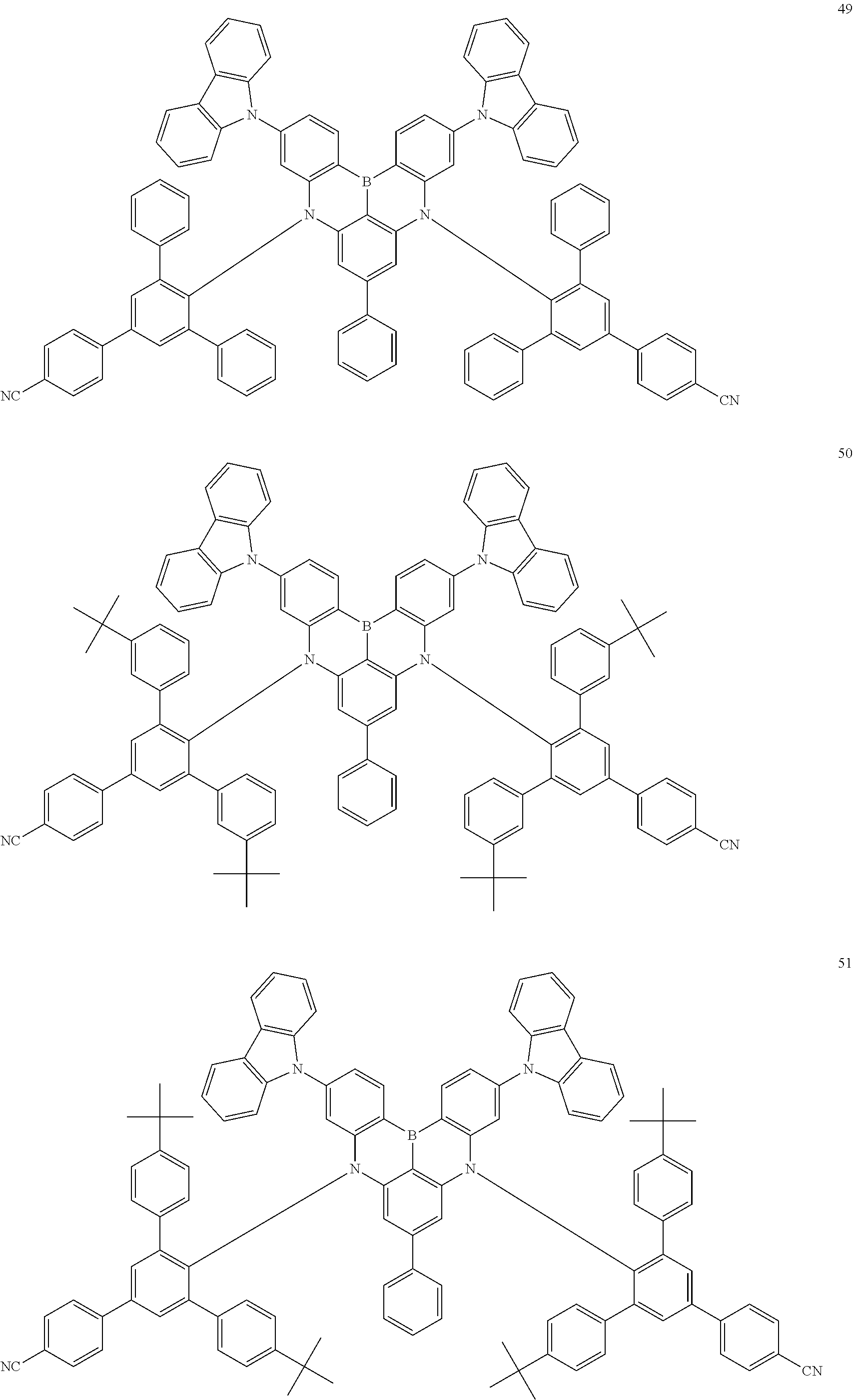

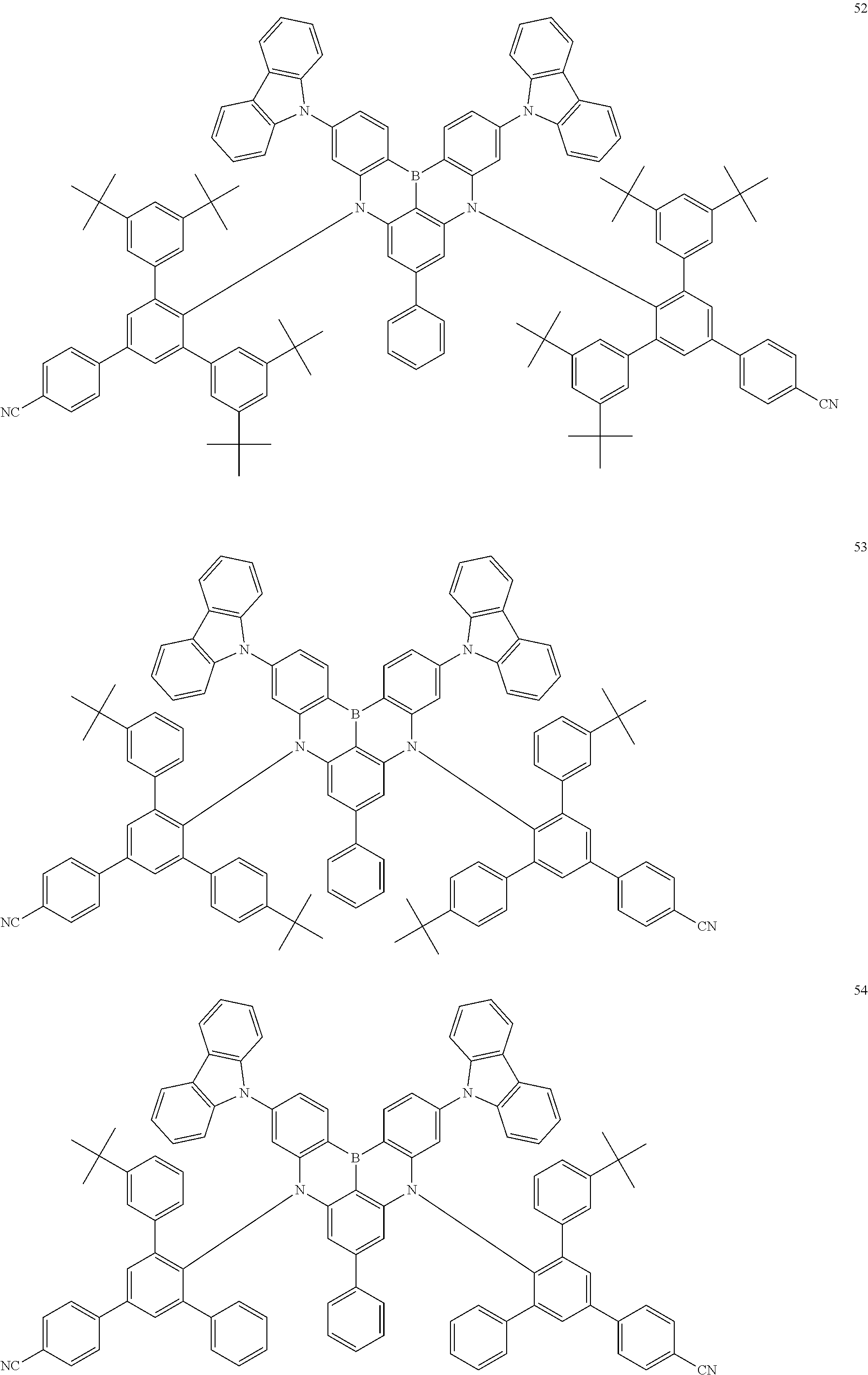

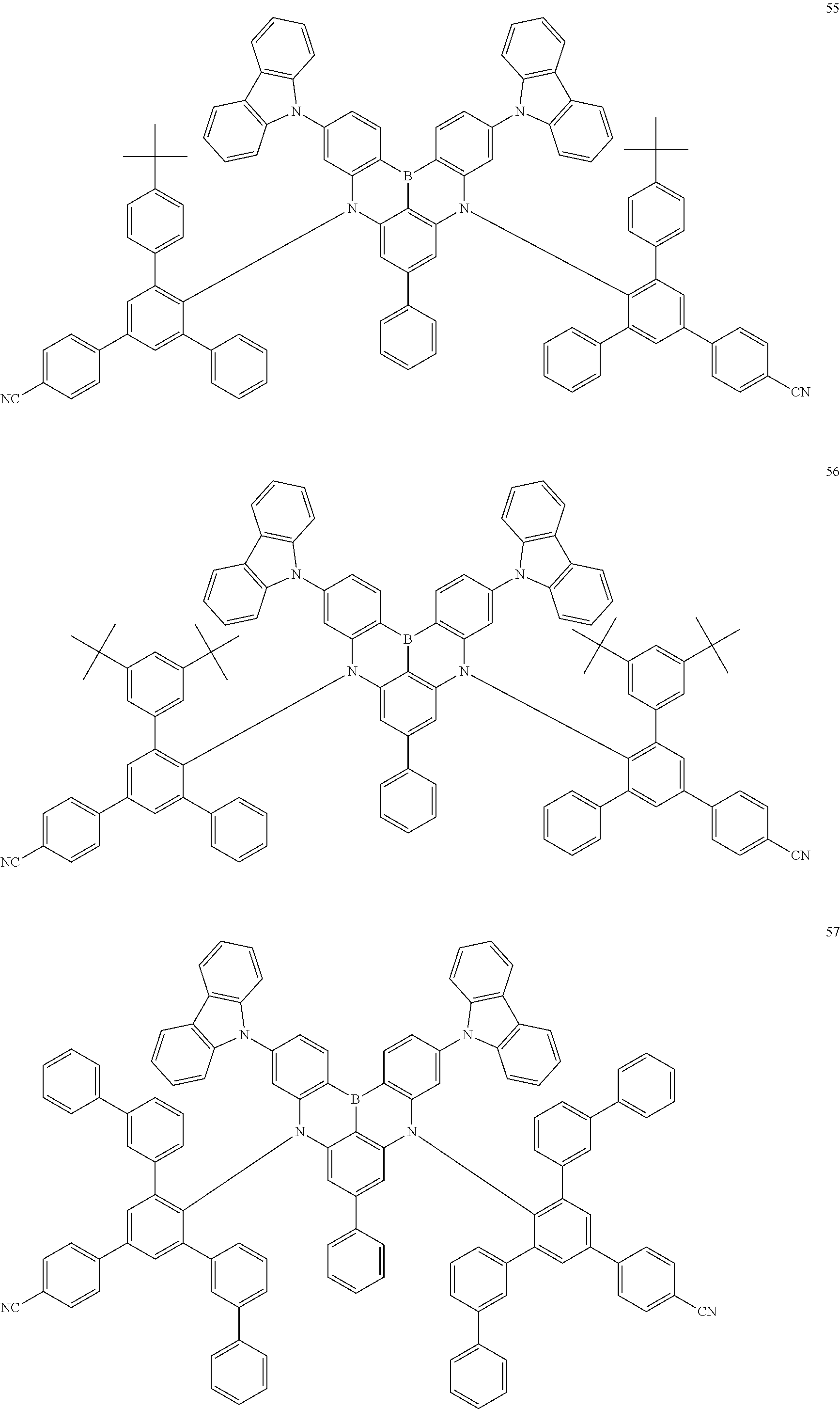

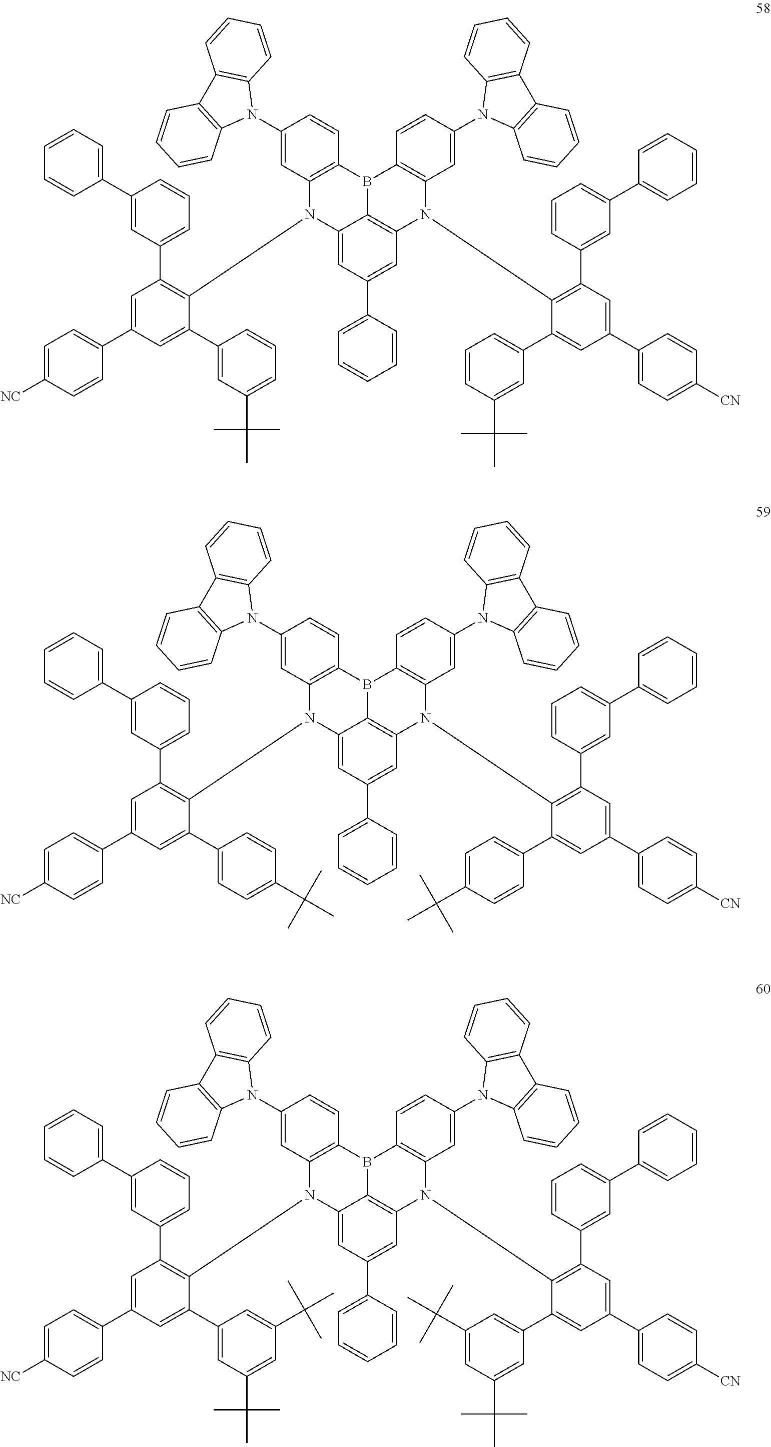

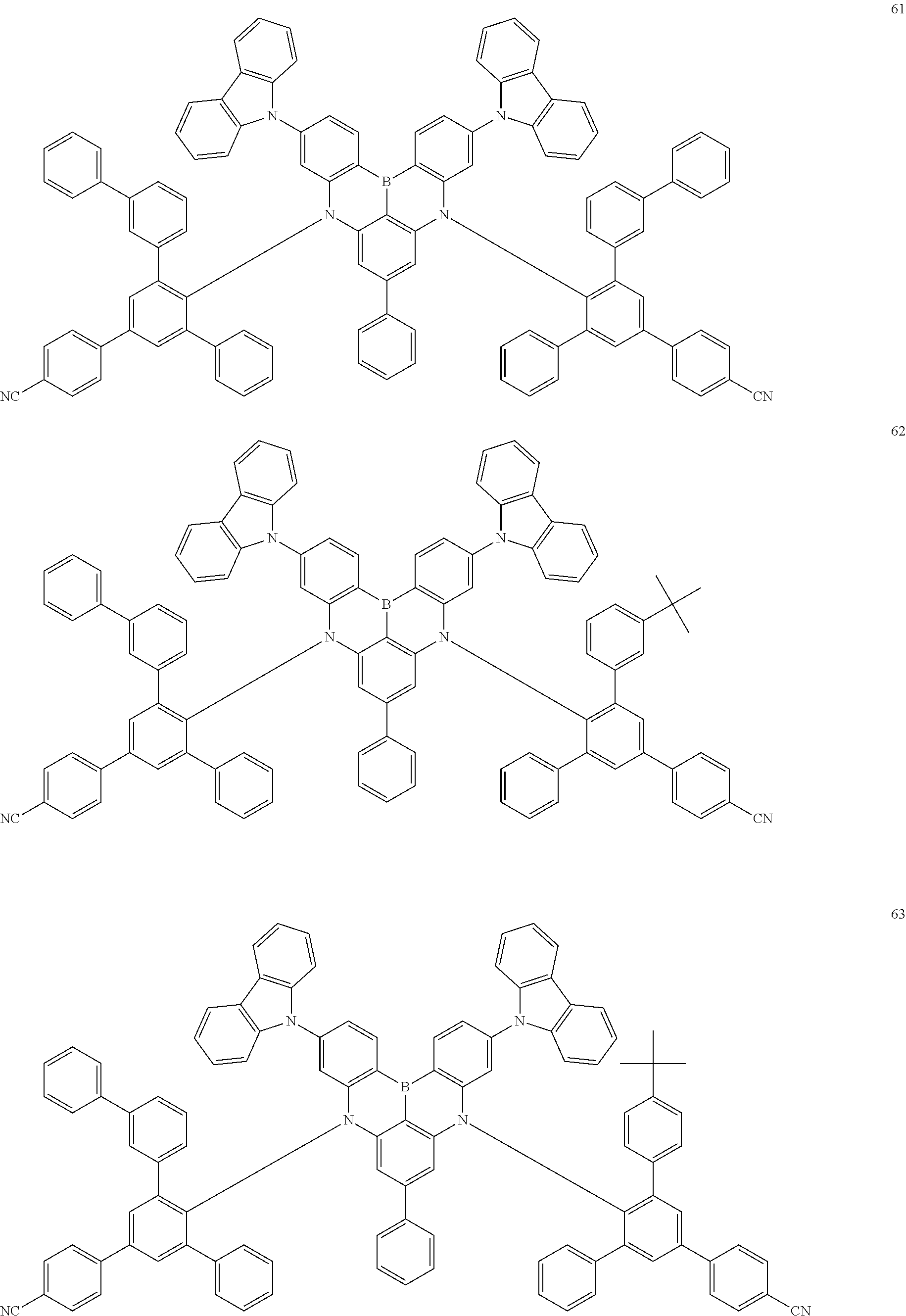

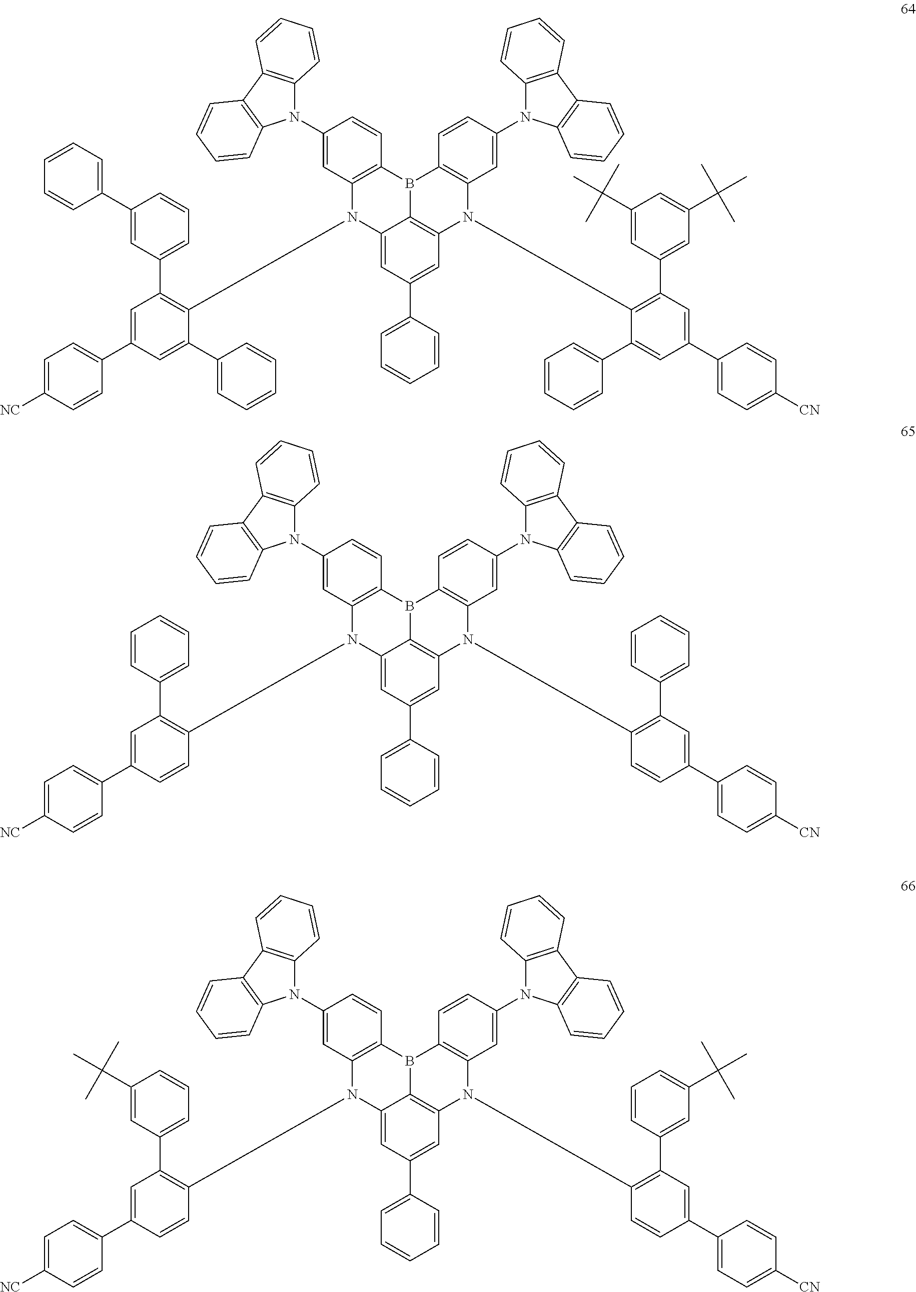

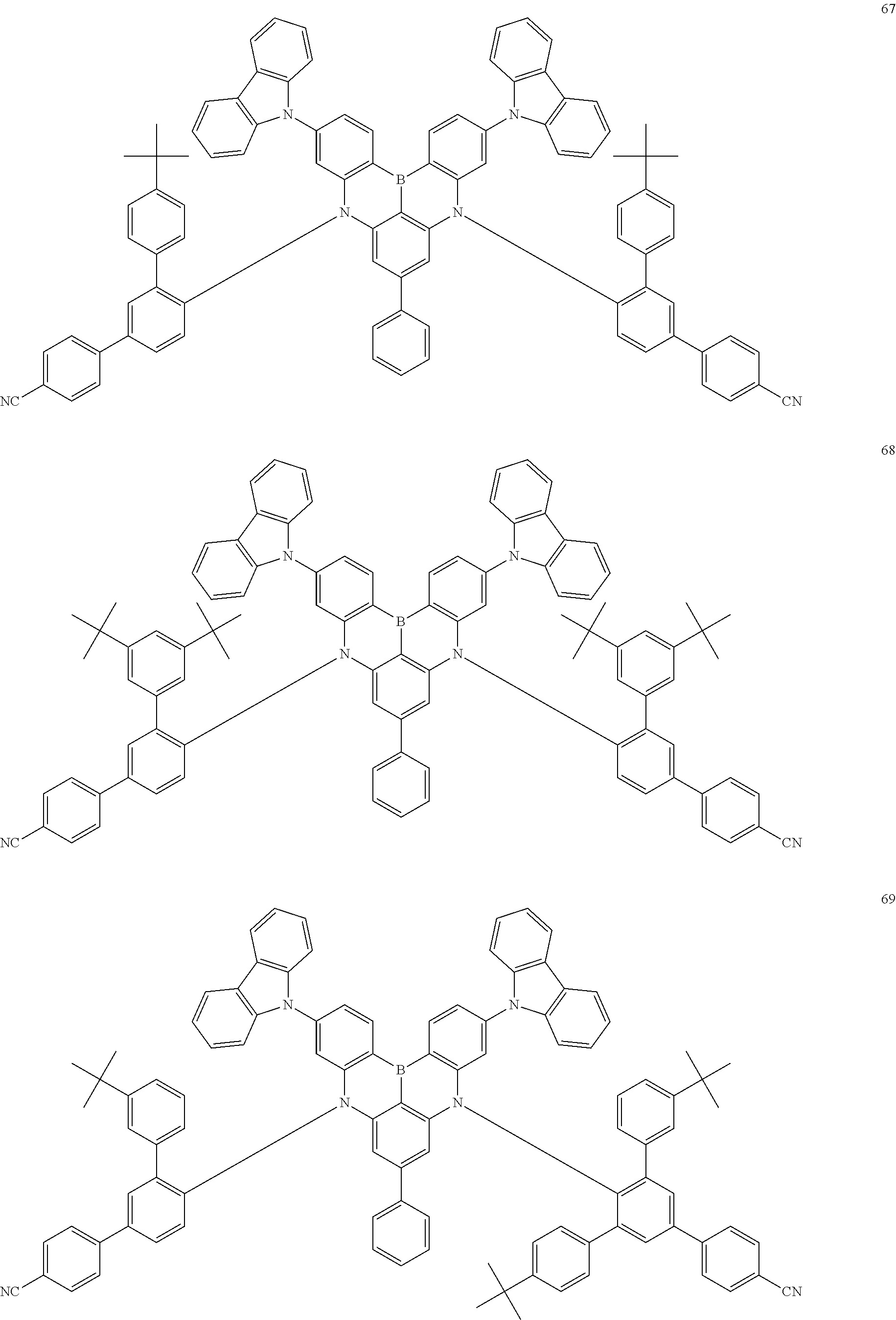

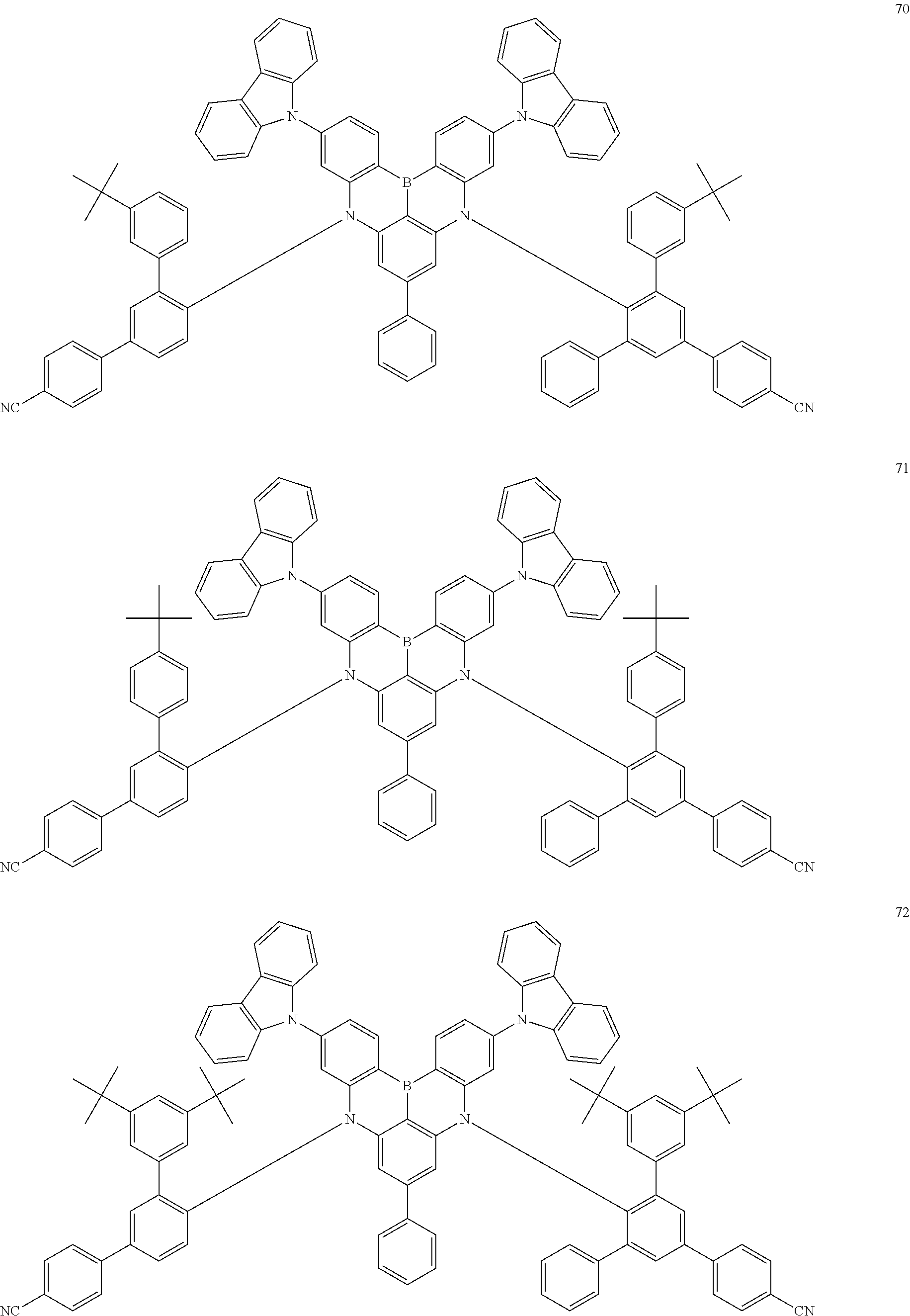

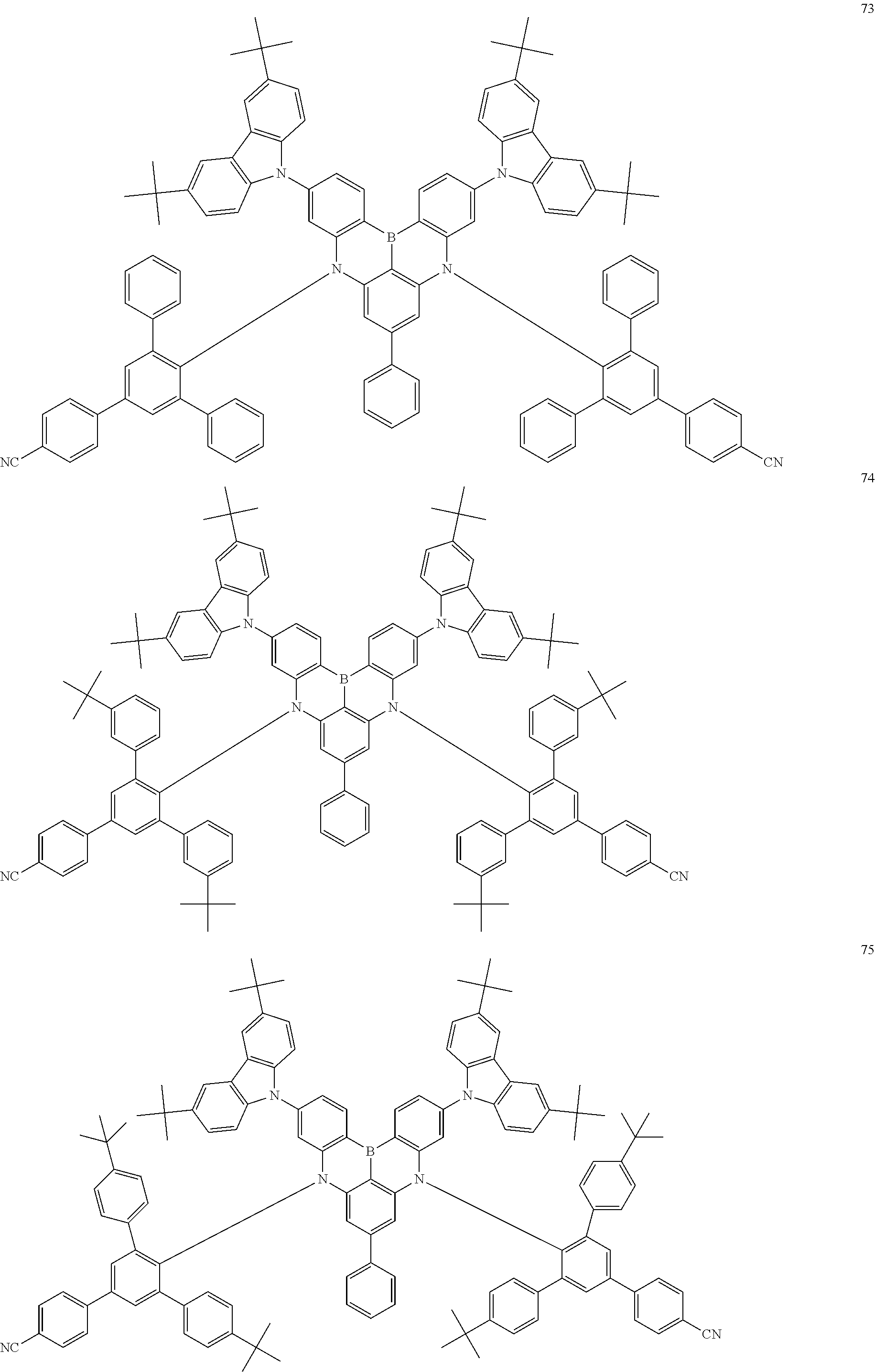

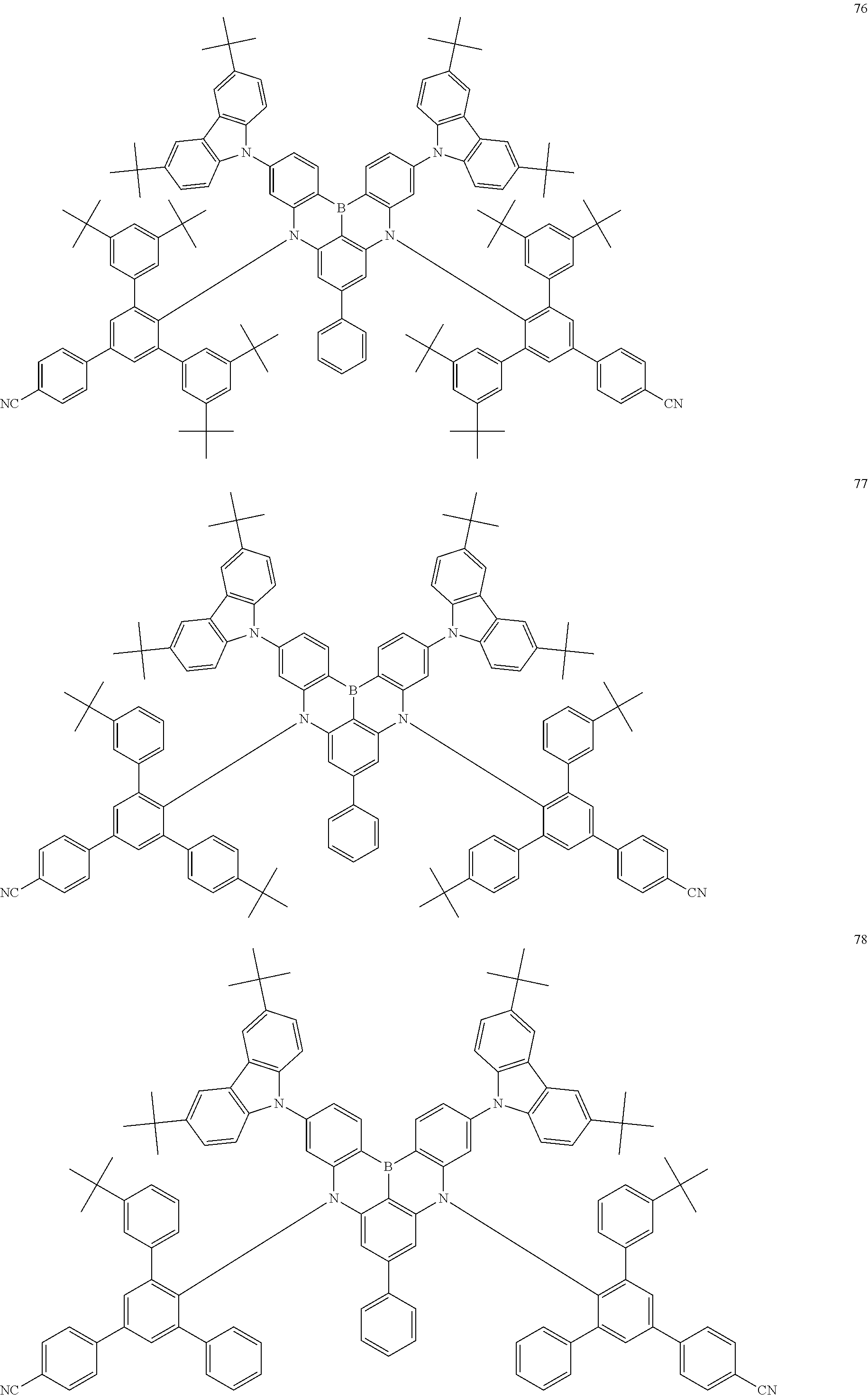

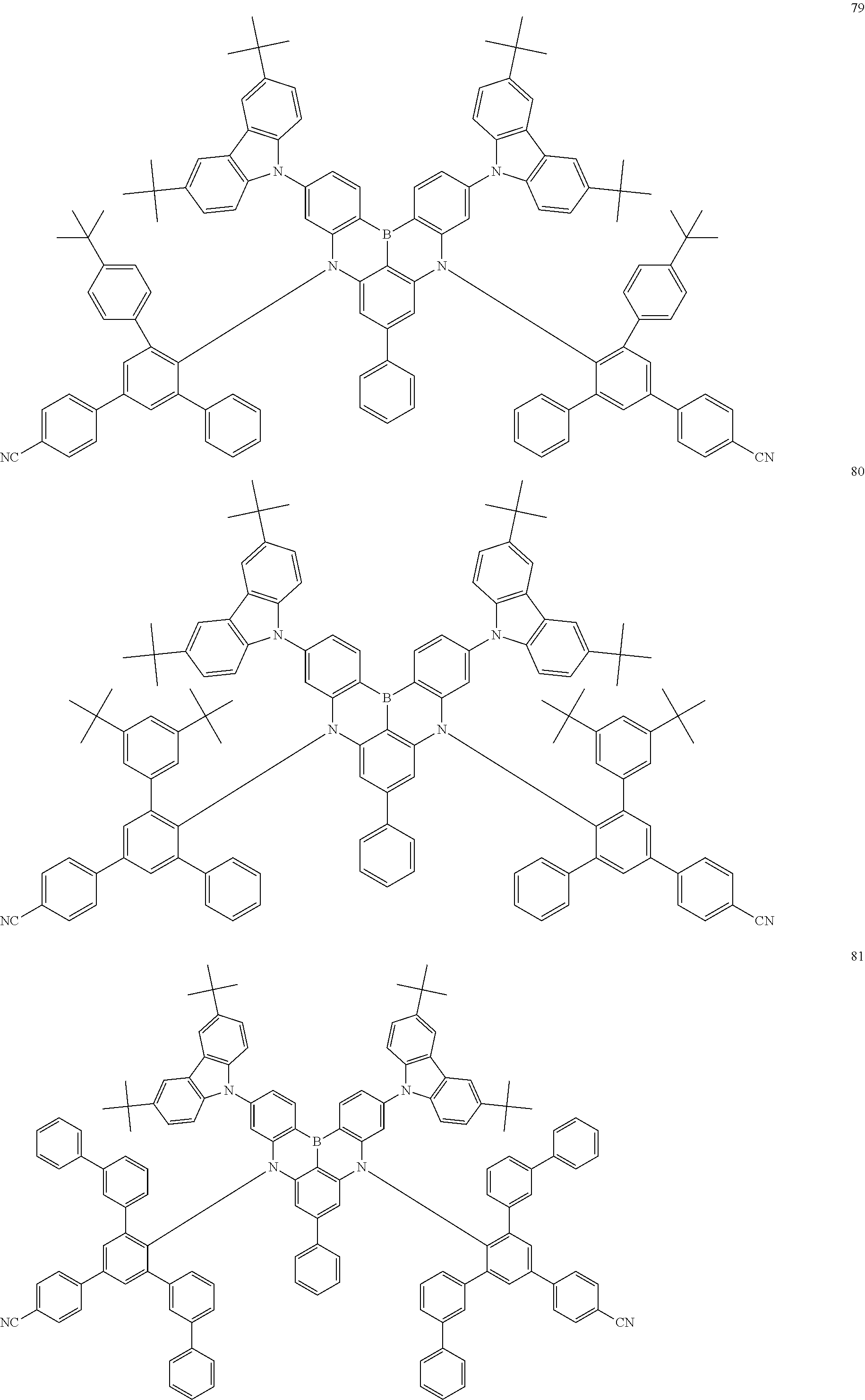

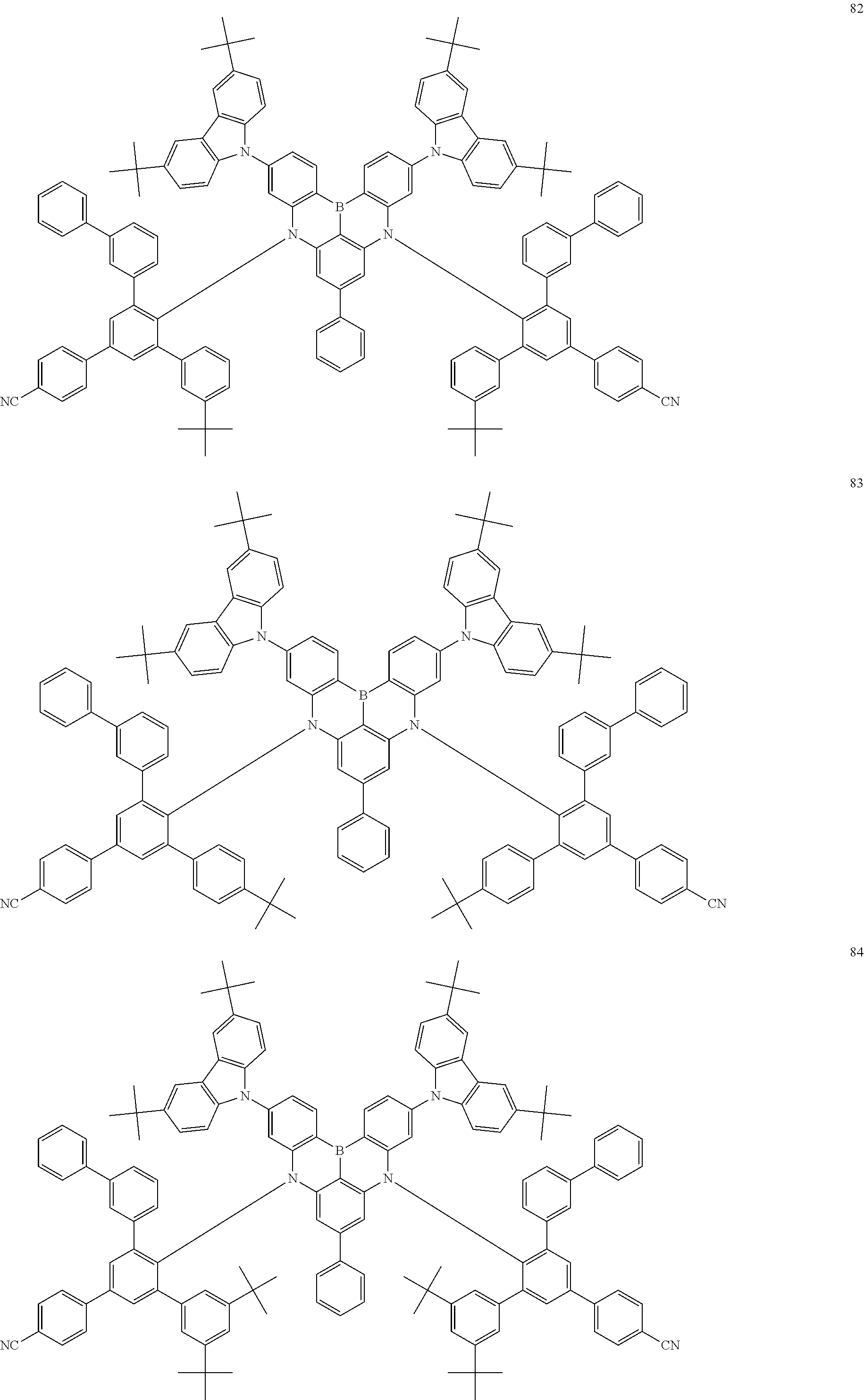

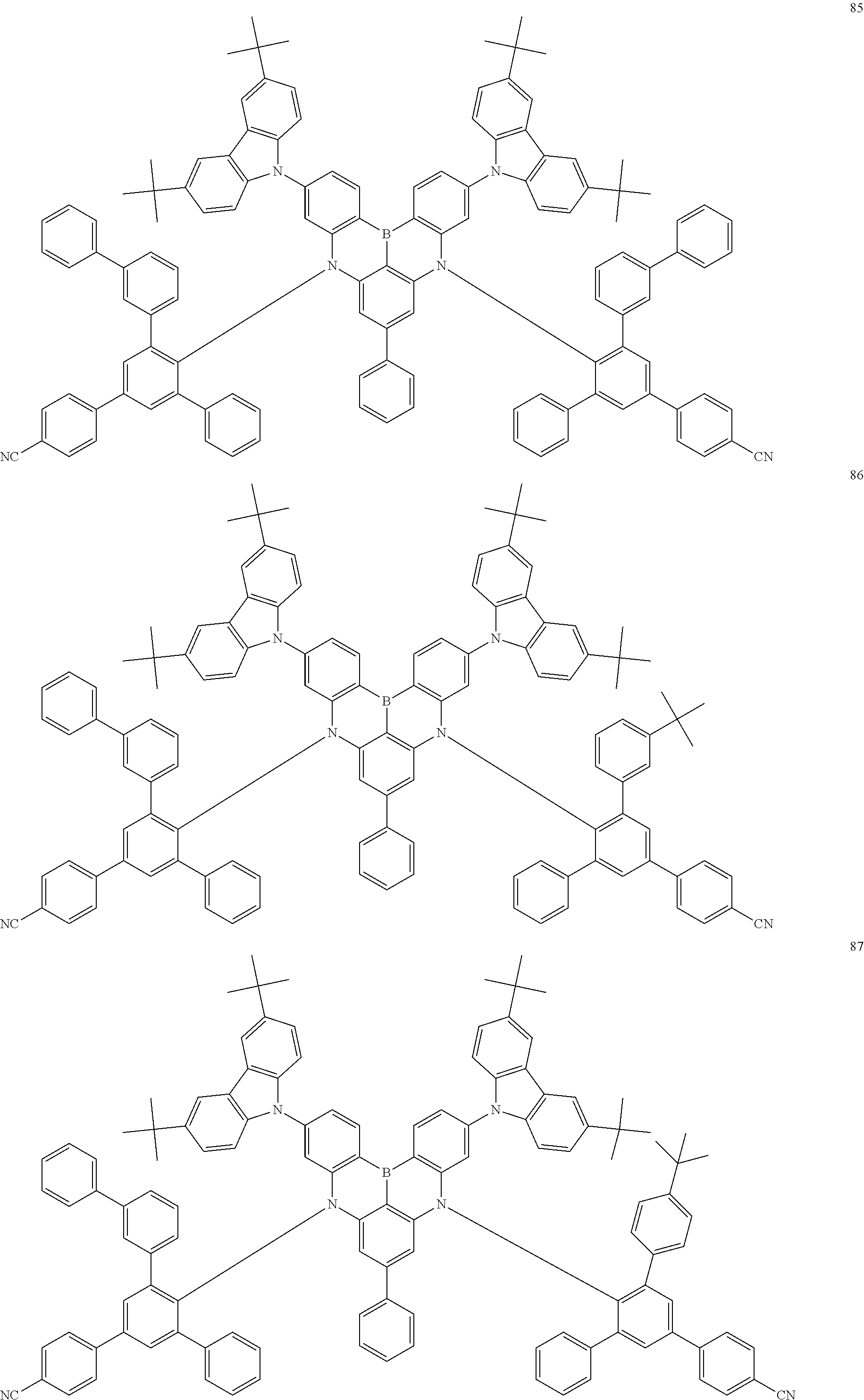

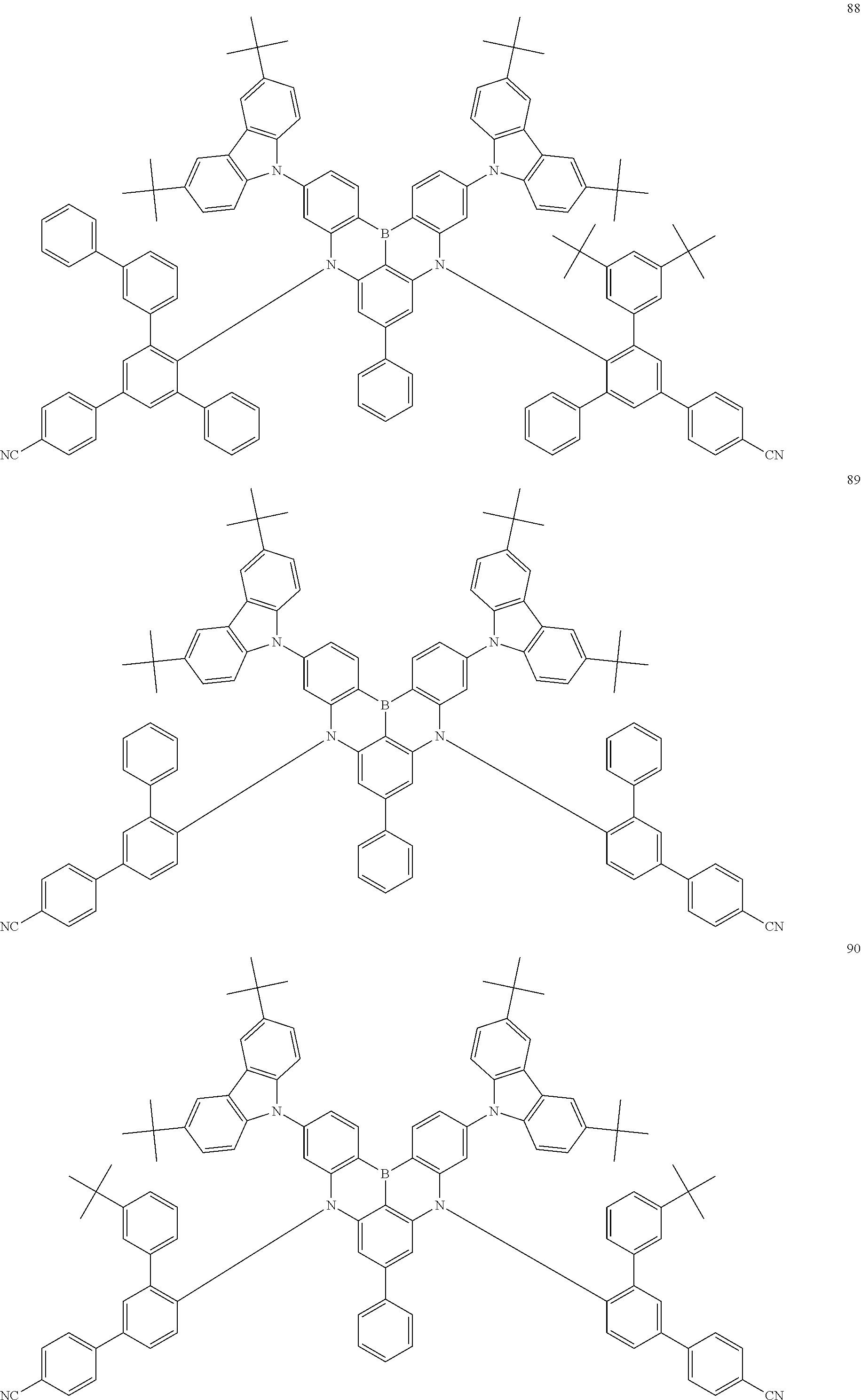

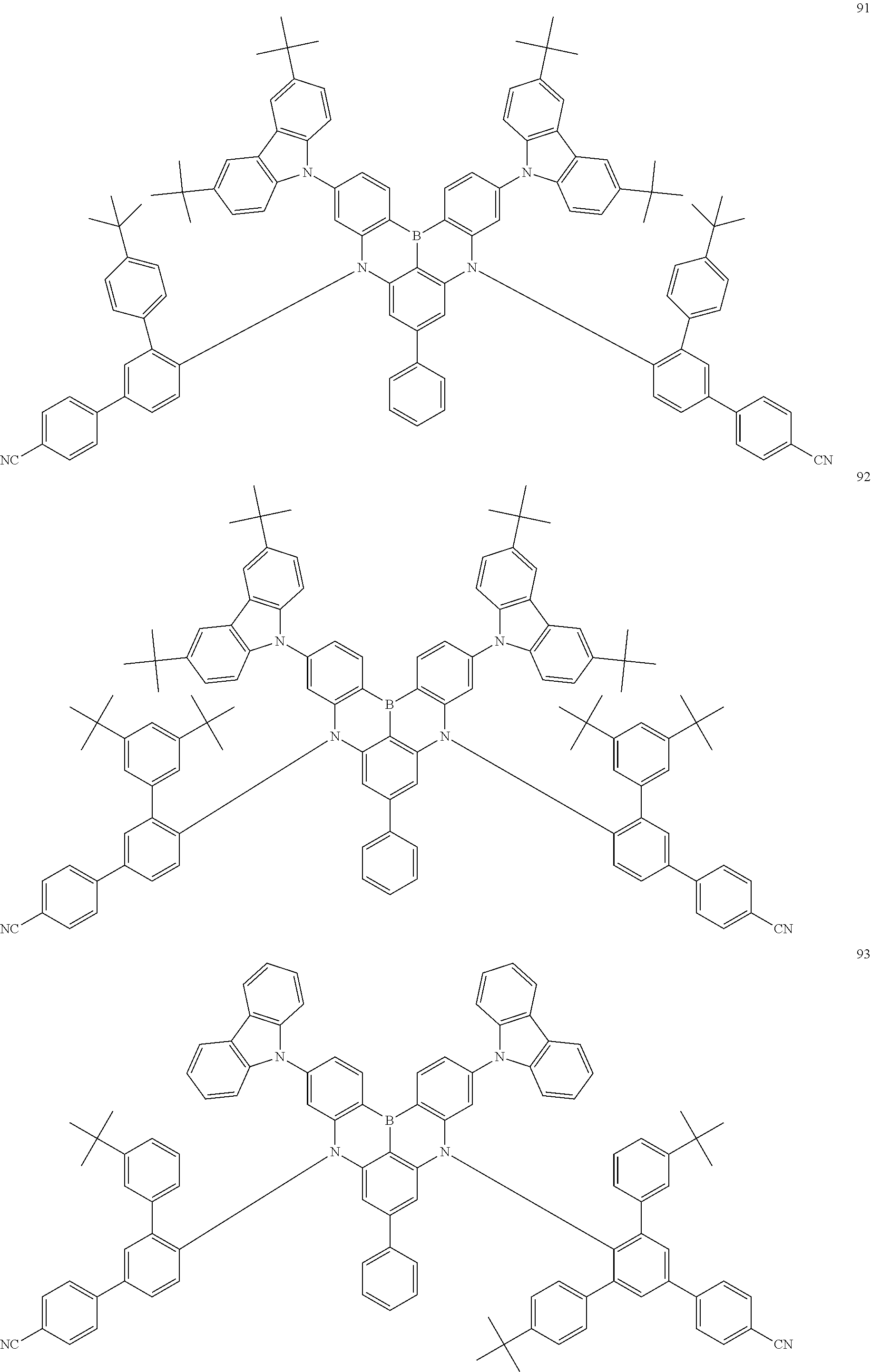

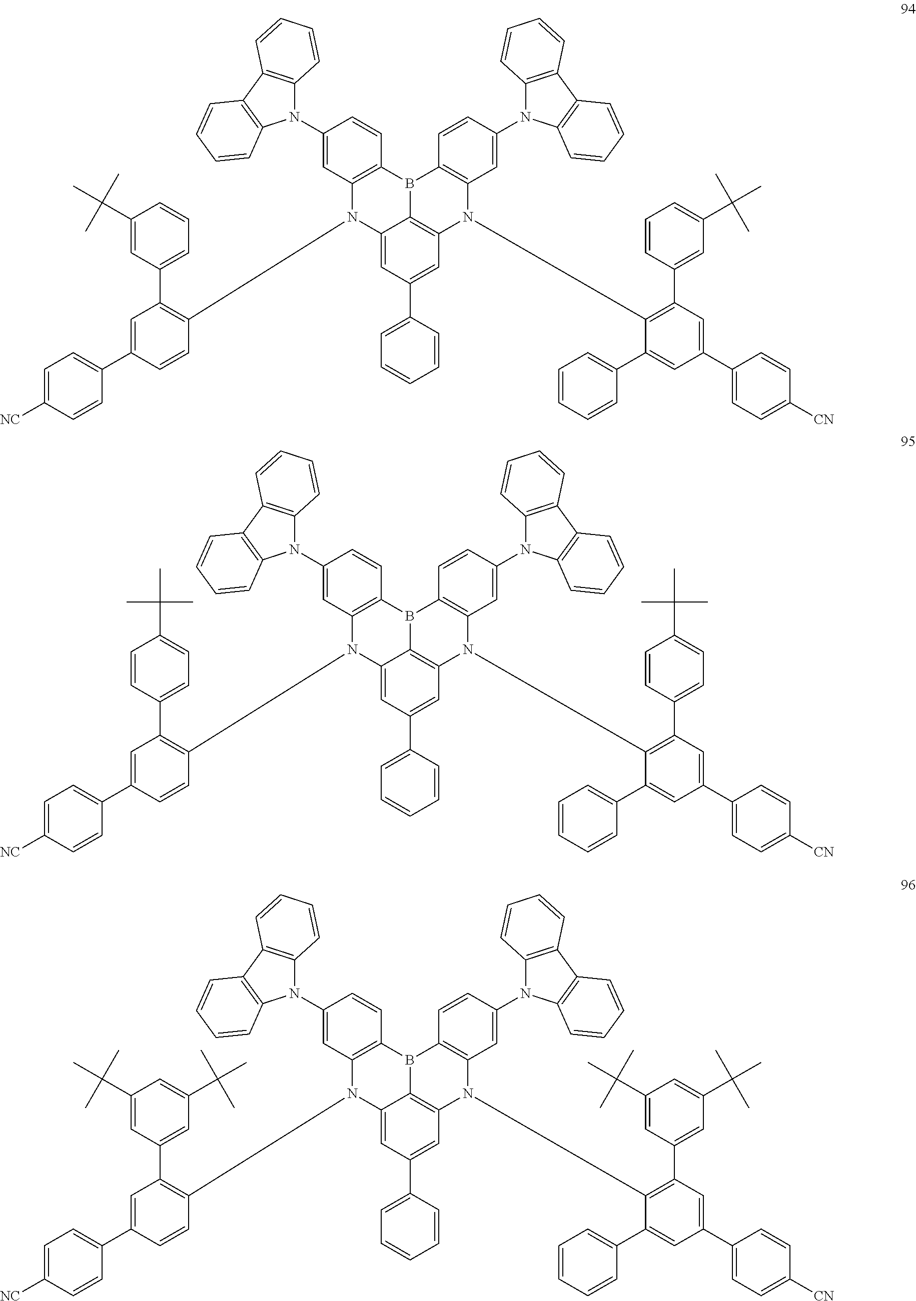

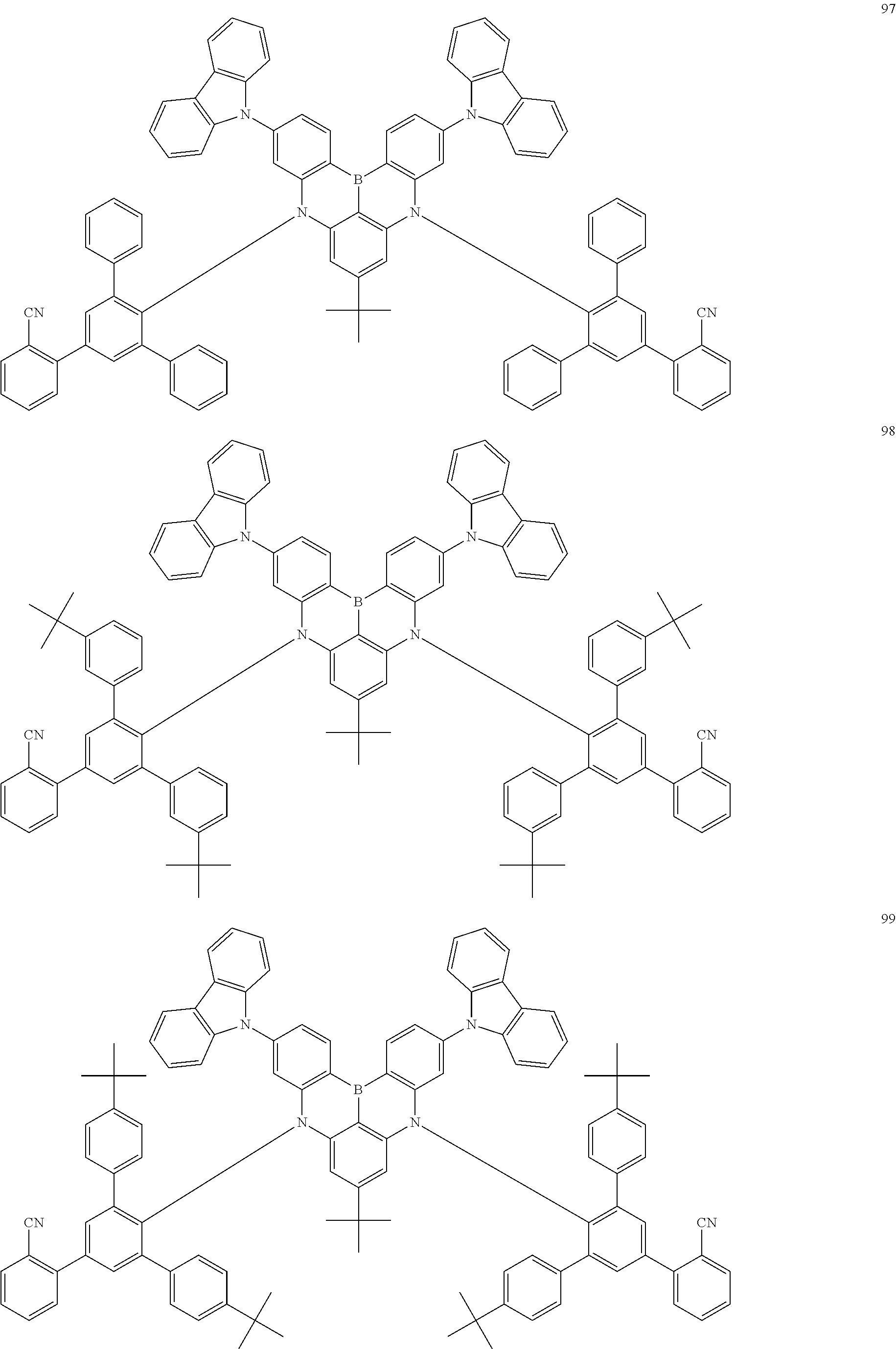

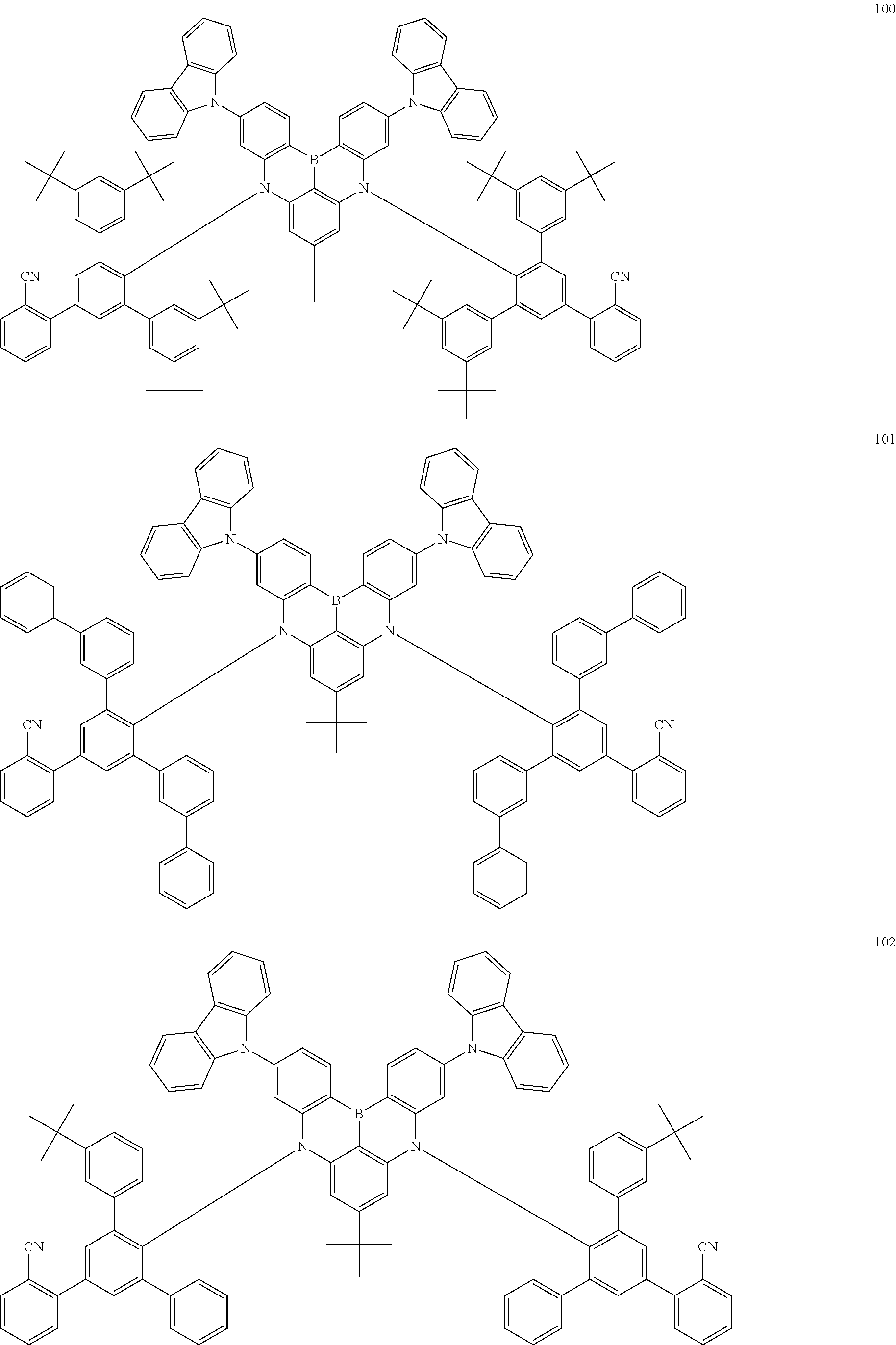

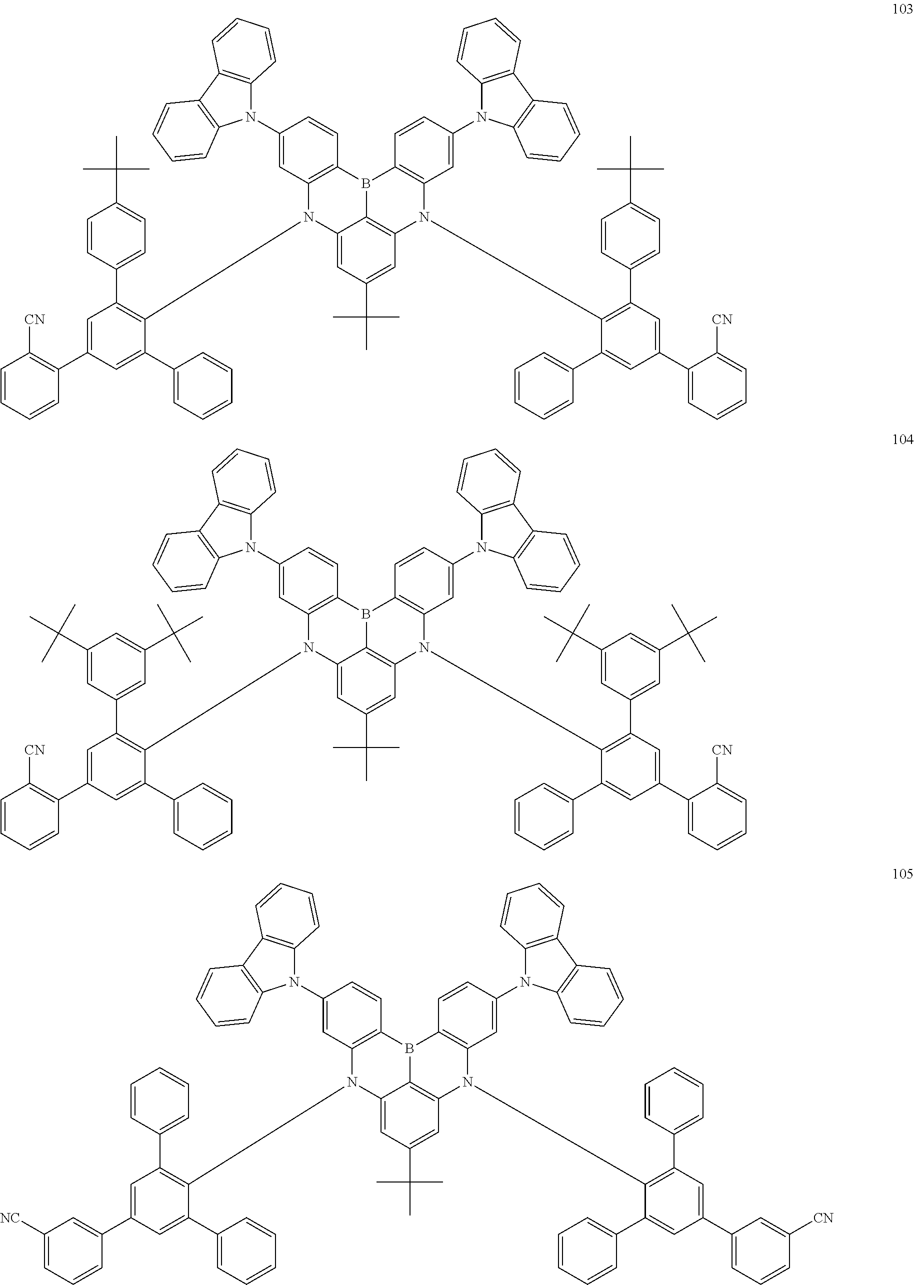

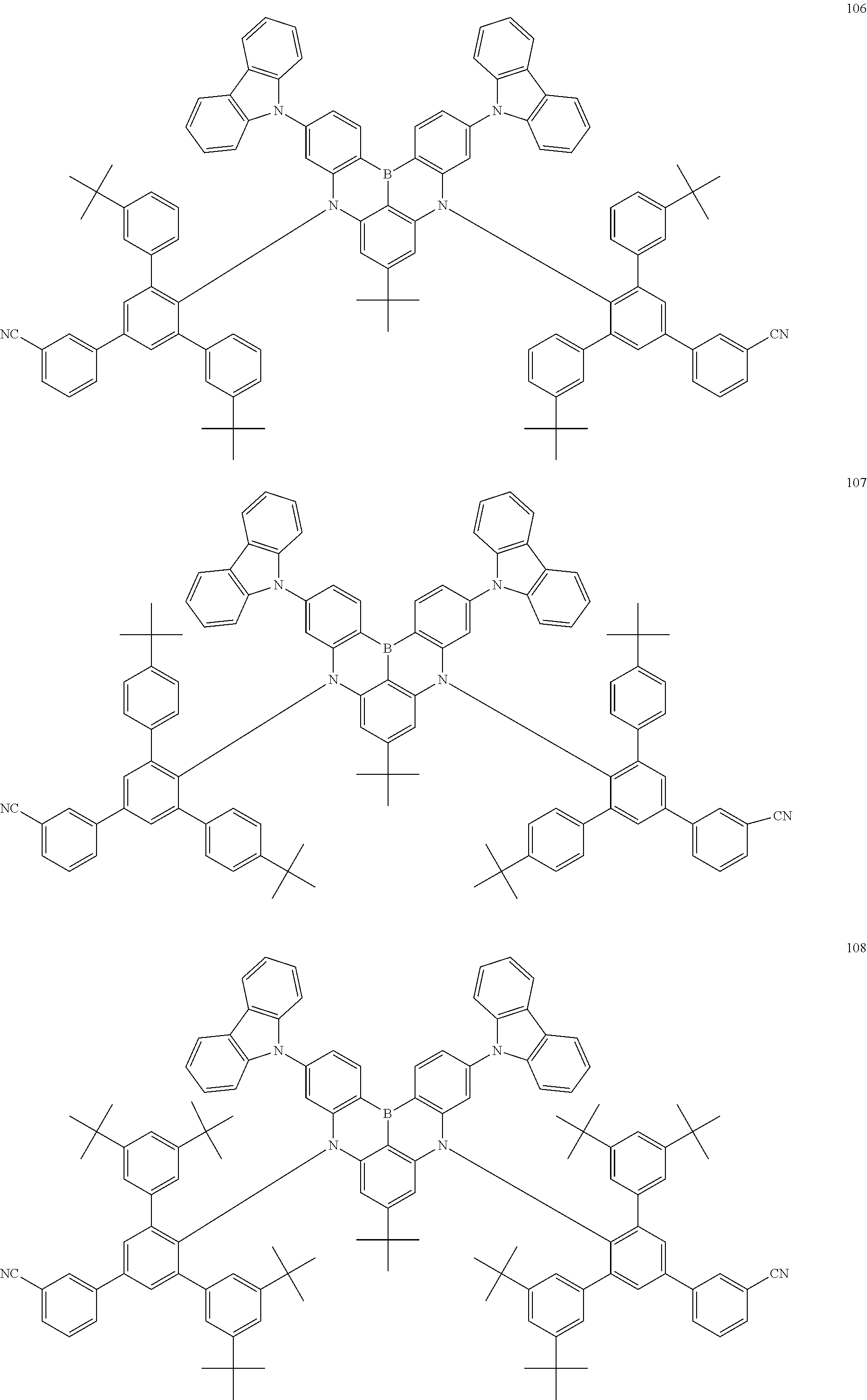

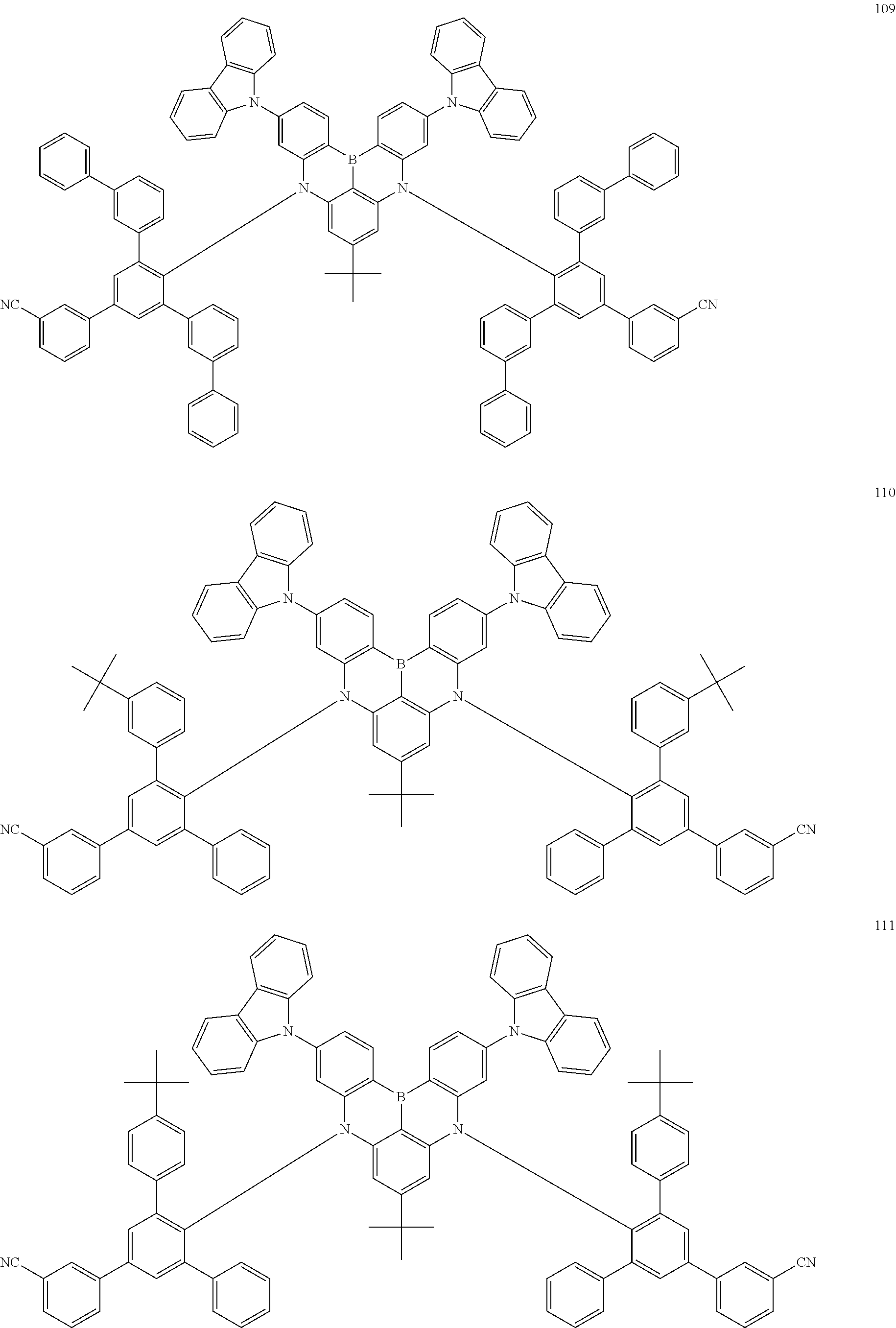

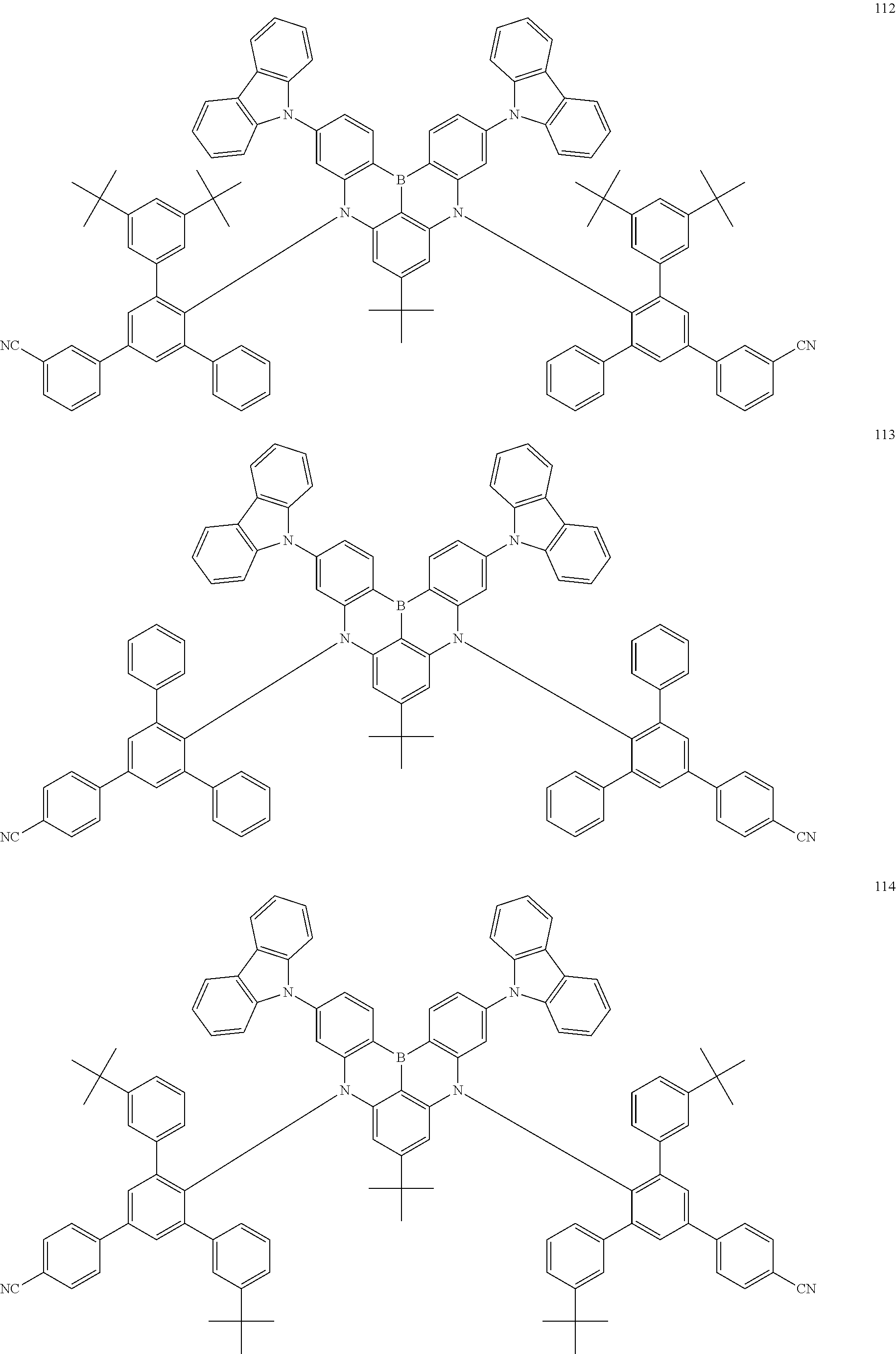

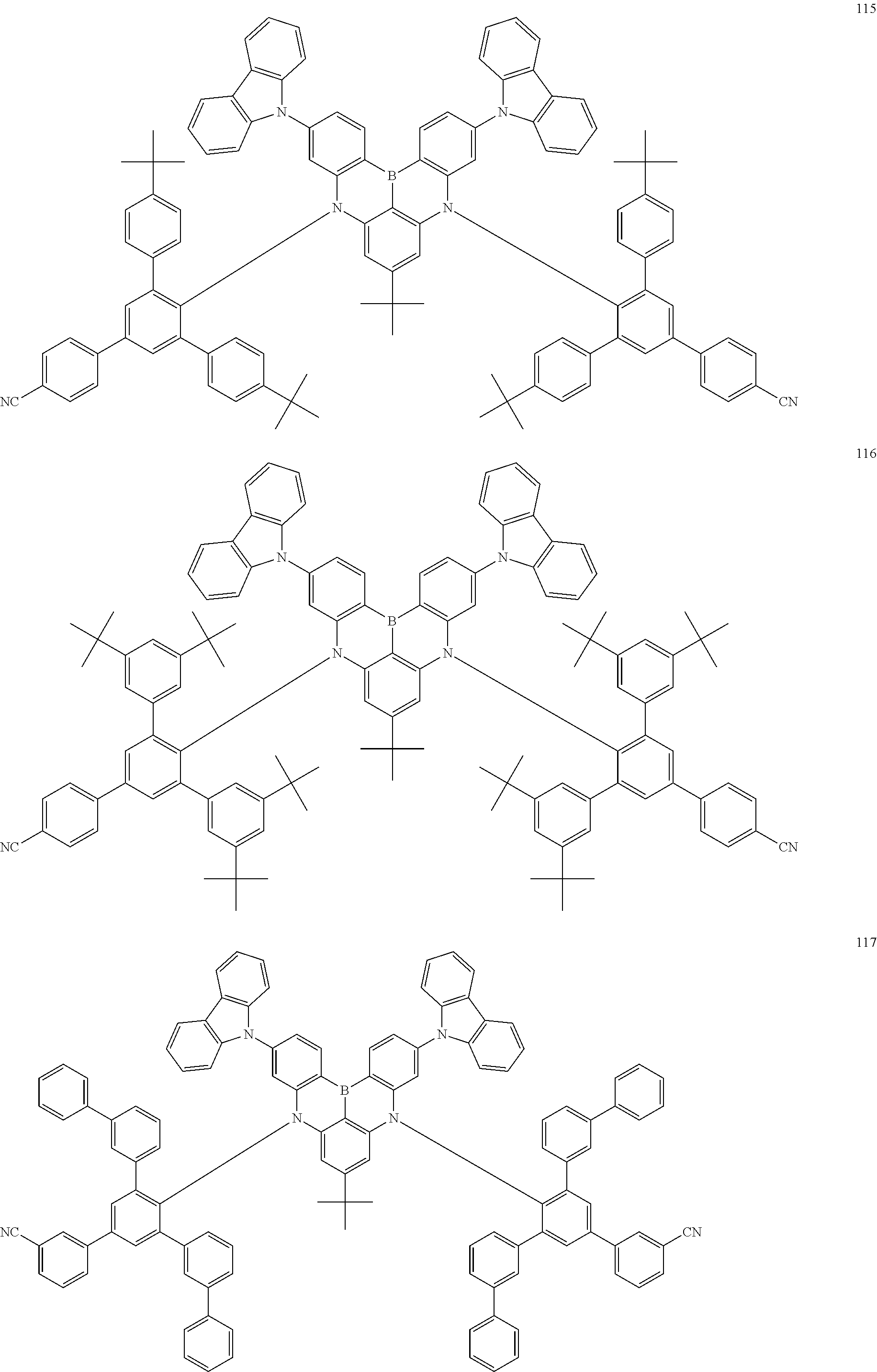

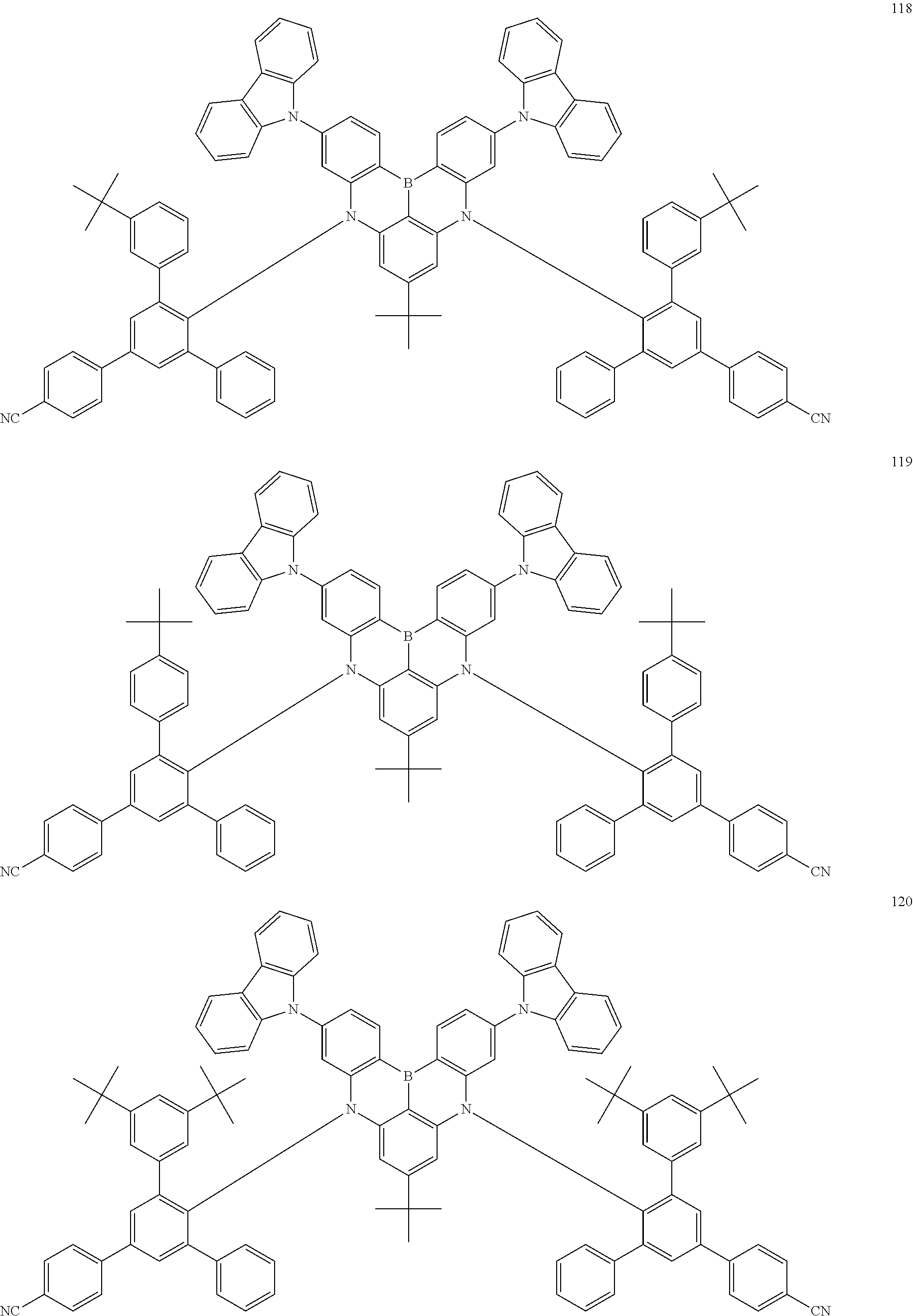

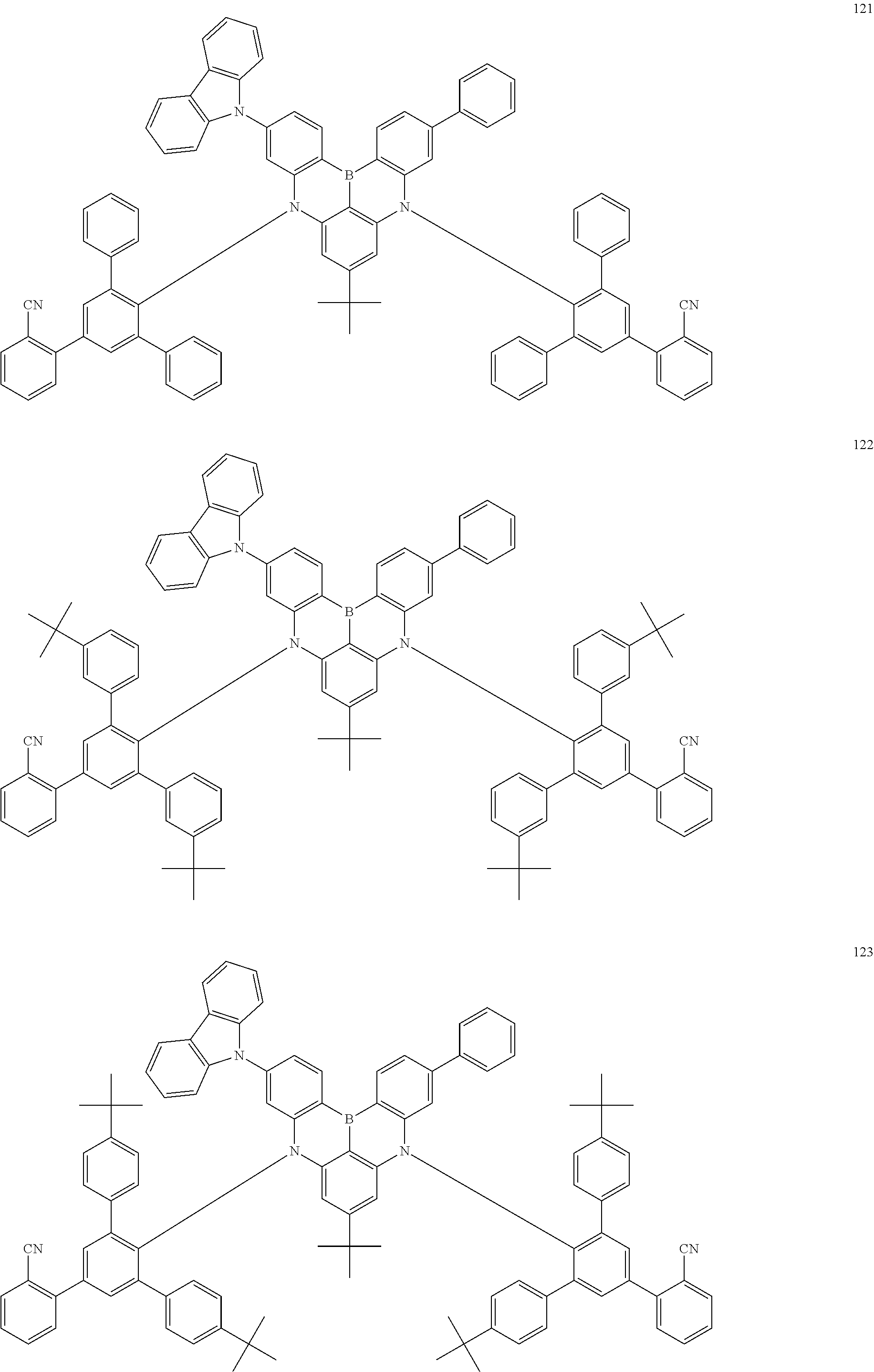

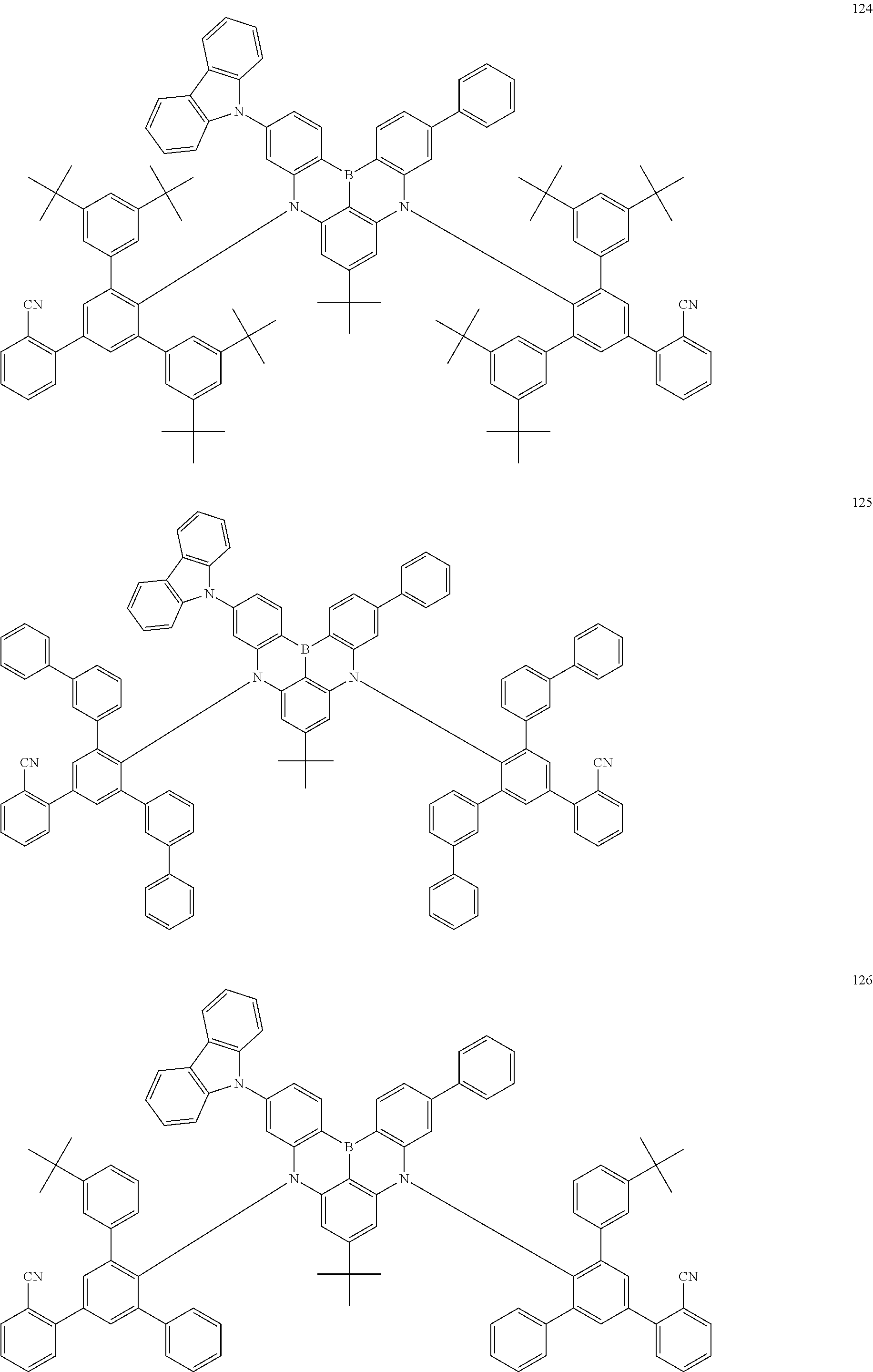

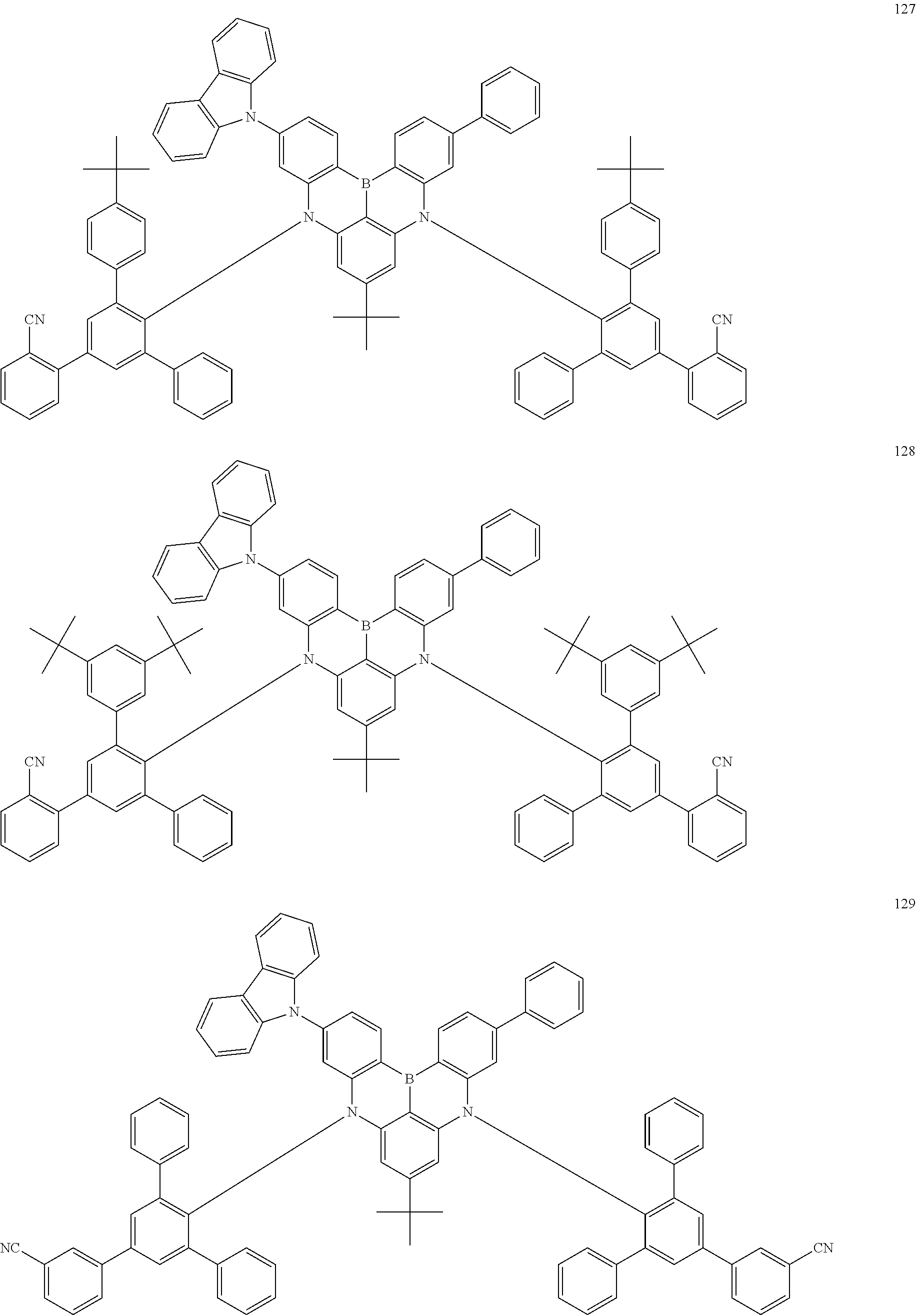

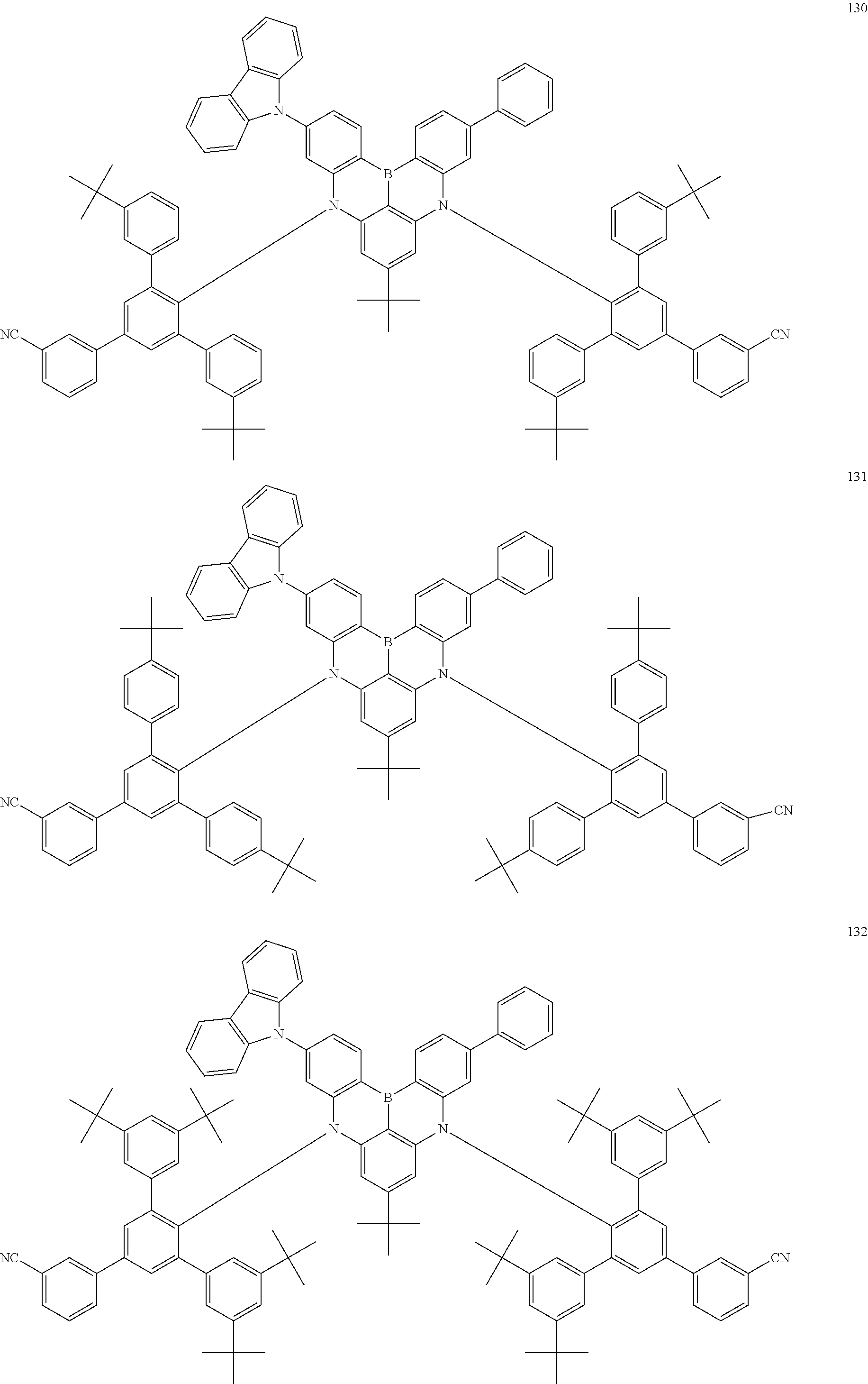

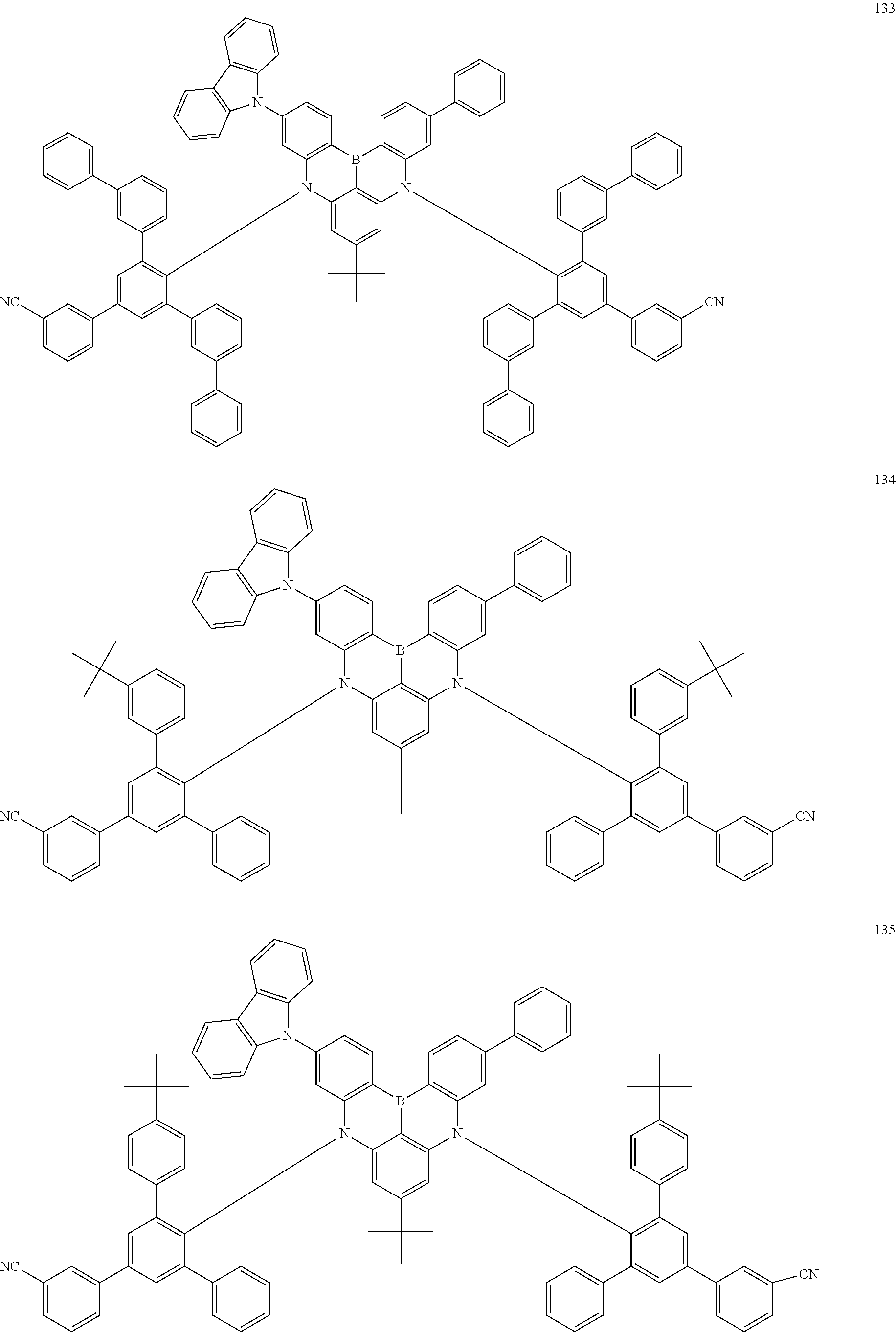

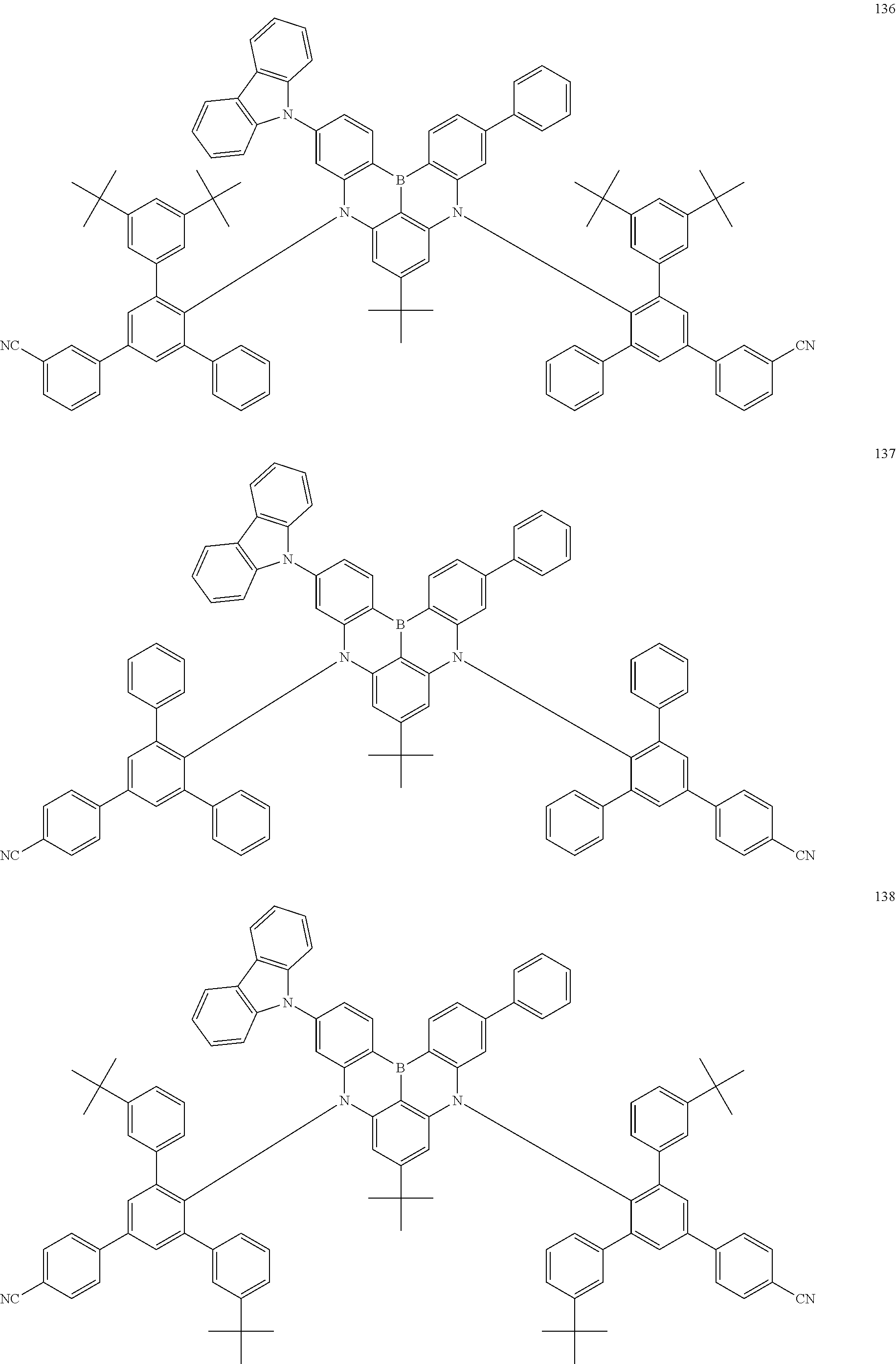

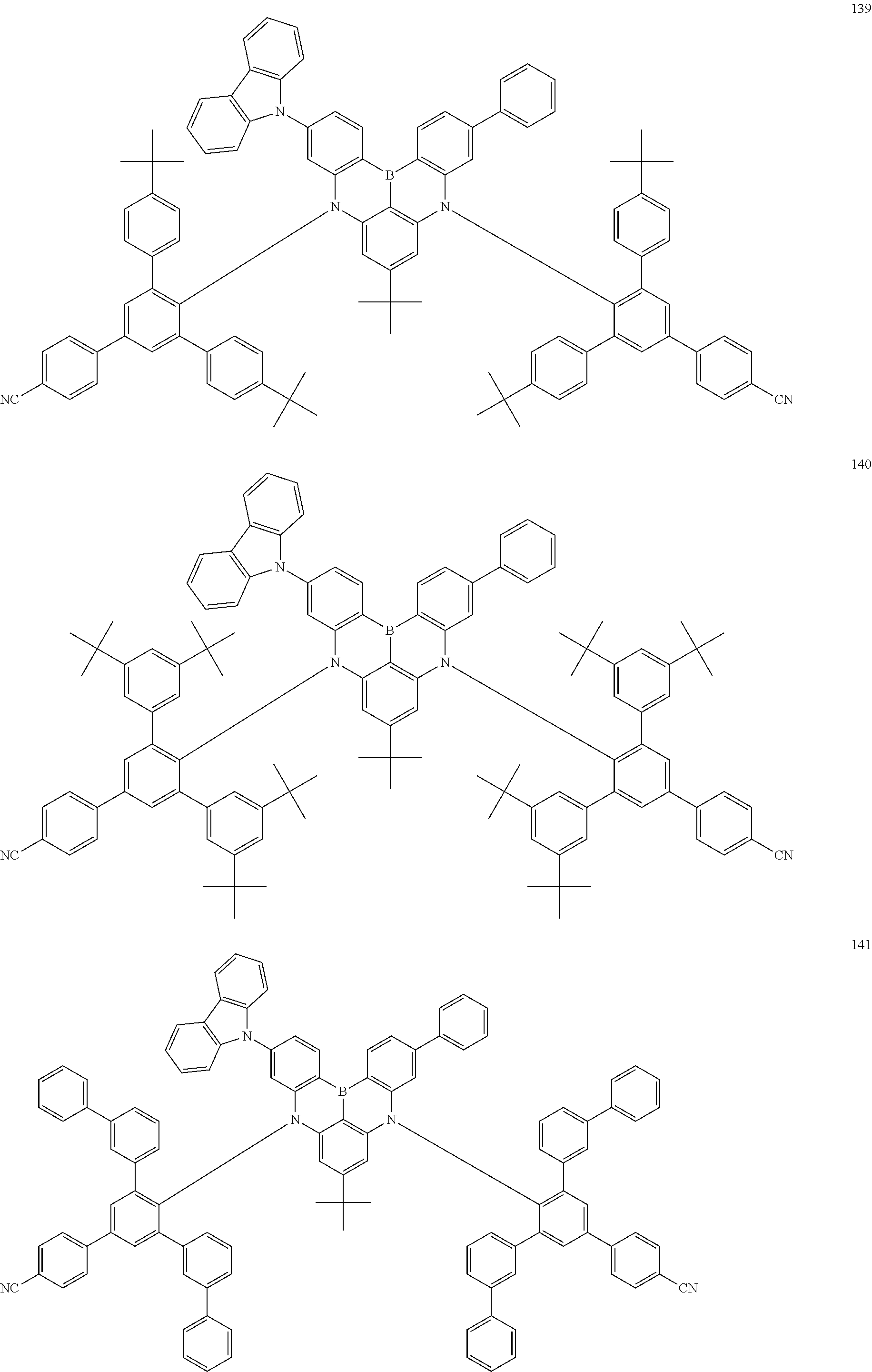

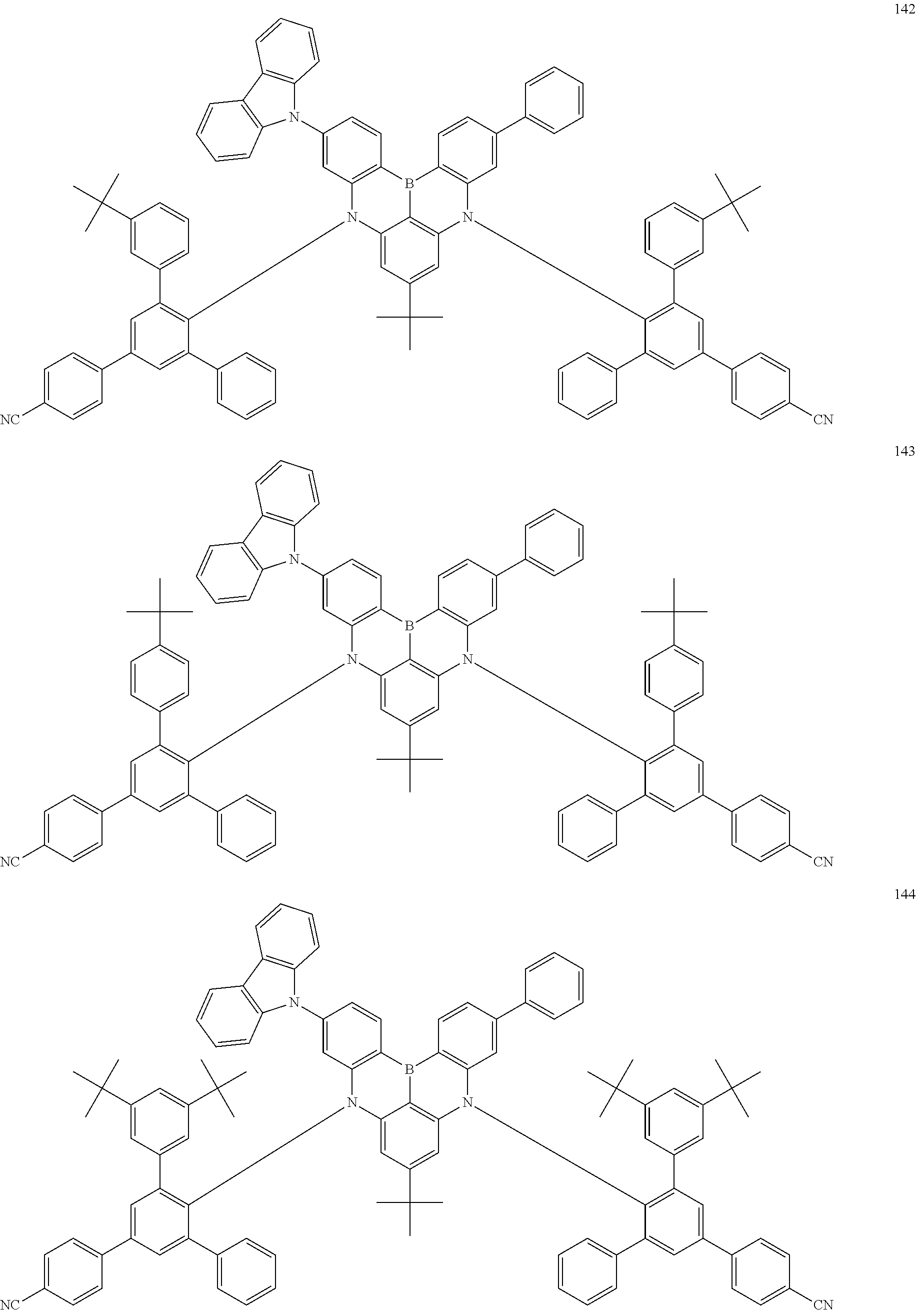

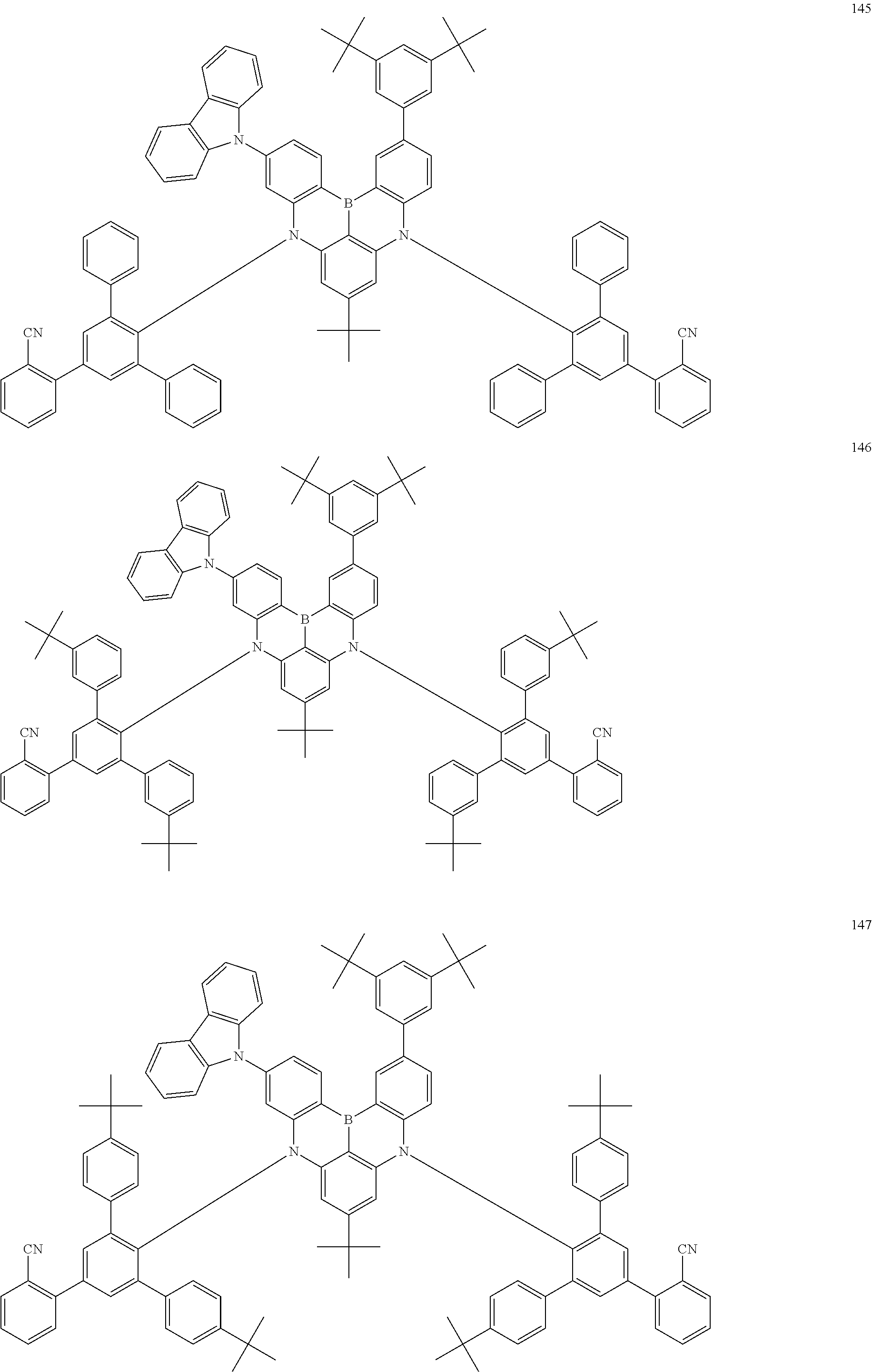

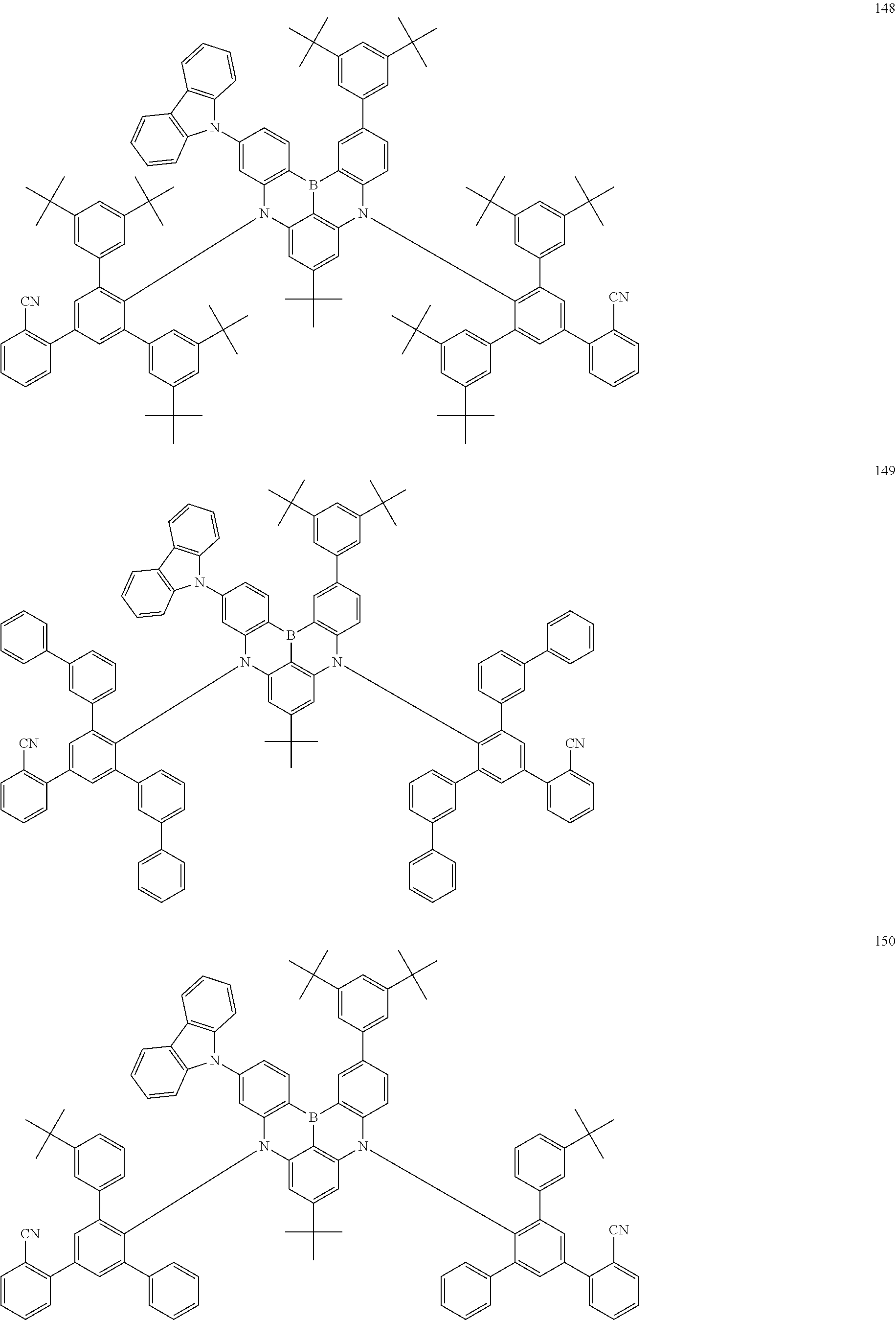

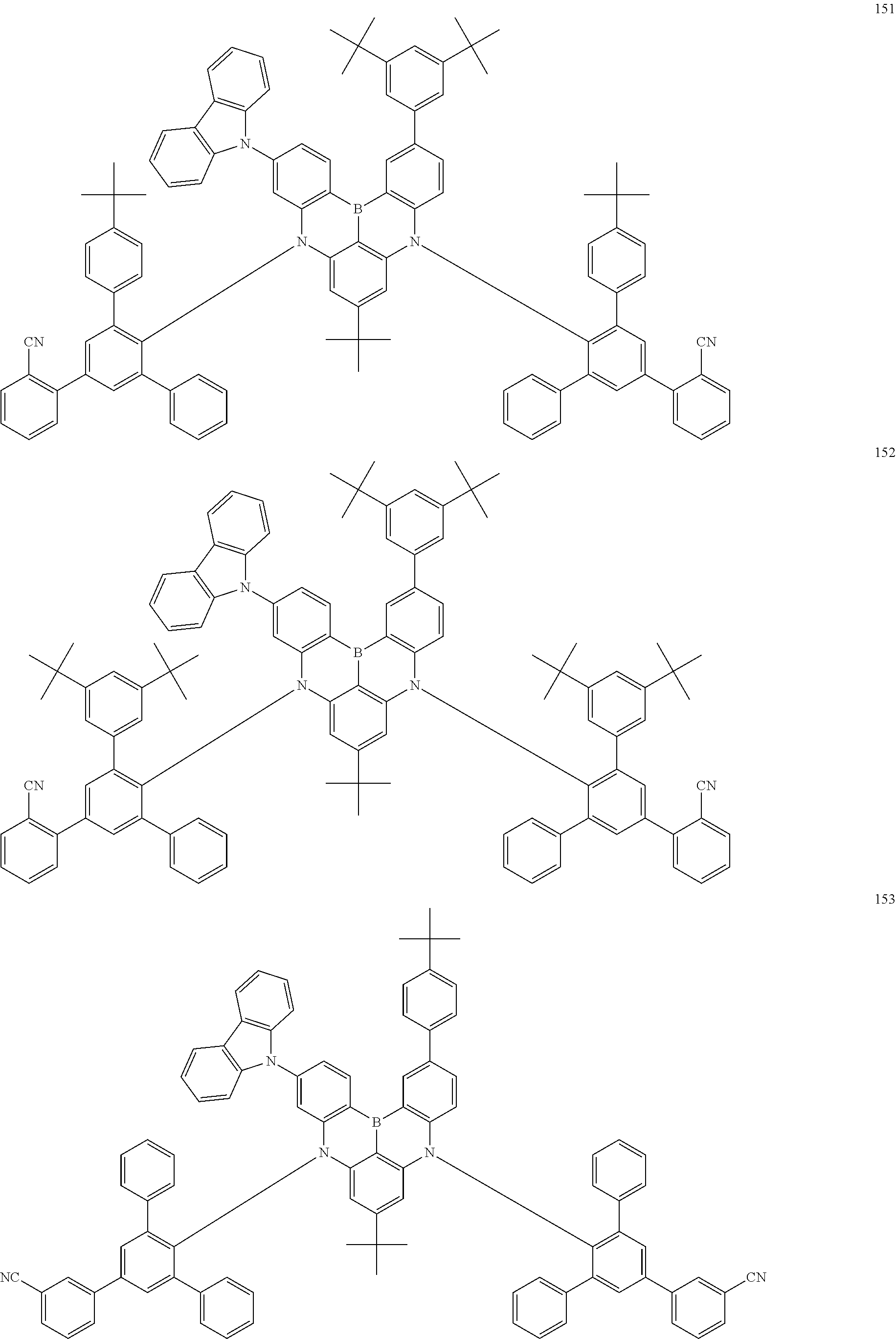

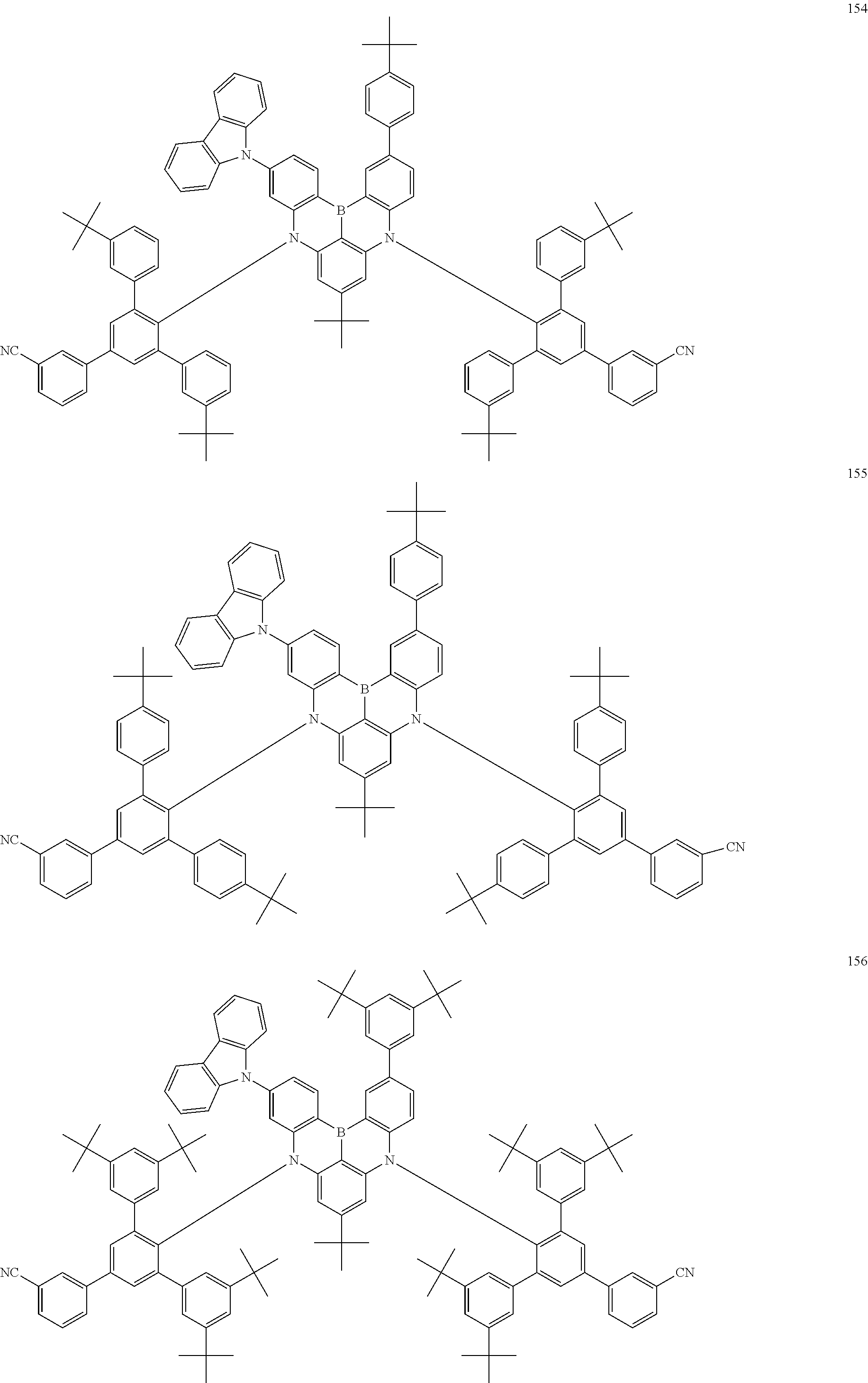

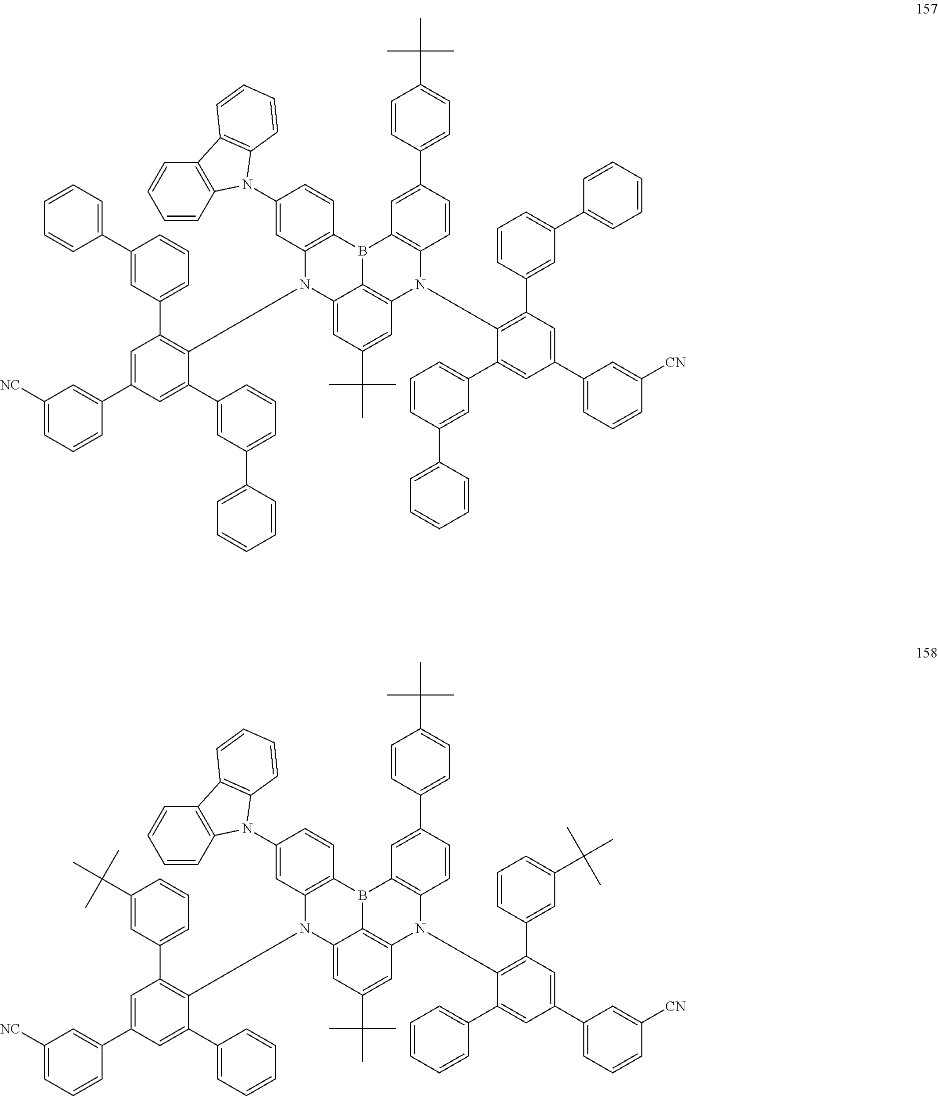 [SMILES: CC(C)(C)c1ccc(-c2ccc3c(c2)B2c4ccc(-n5c6ccccc6c6ccccc65)cc4N(c4c(-c5cccc(-c6ccccc6)c5)cc(-c5cccc(C#N)c5)cc4-c4cccc(-c5ccccc5)c4)c4cc(C(C)(C)C)cc(c42)N3c2c(-c3cccc(-c4ccccc4)c3)cc(-c3cccc(C#N)c3)cc2-c2cccc(-c3ccccc3)c2)cc1 ; CC(C)(C)c1ccc(-c2ccc3c(c2)B2c4ccc(-n5c6ccccc6c6ccccc65)cc4N(c4c(-c5ccccc5)cc(-c5cccc(C#N)c5)cc4-c4cccc(C(C)(C)C)c4)c4cc(C(C)(C)C)cc(c42)N3c2c(-c3ccccc3)cc(-c3cccc(C#N)c3)cc2-c2cccc(C(C)(C)C)c2)cc1]

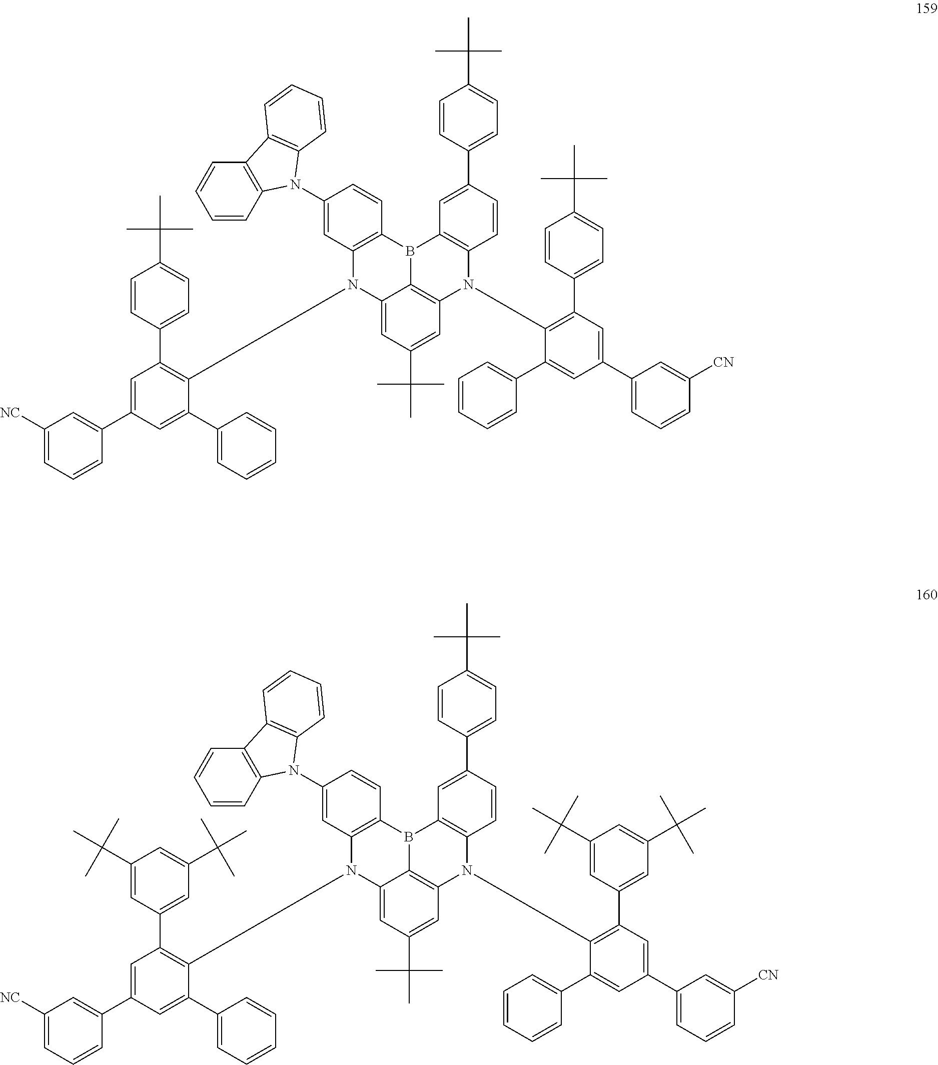 [SMILES: CC(C)(C)c1ccc(-c2ccc3c(c2)B2c4ccc(-n5c6ccccc6c6ccccc65)cc4N(c4c(-c5ccccc5)cc(-c5cccc(C#N)c5)cc4-c4ccc(C(C)(C)C)cc4)c4cc(C(C)(C)C)cc(c42)N3c2c(-c3ccccc3)cc(-c3cccc(C#N)c3)cc2-c2ccc(C(C)(C)C)cc2)cc1 ; CC(C)(C)c1ccc(-c2ccc3c(c2)B2c4ccc(-n5c6ccccc6c6ccccc65)cc4N(c4c(-c5ccccc5)cc(-c5cccc(C#N)c5)cc4-c4cc(C(C)(C)C)cc(C(C)(C)C)c4)c4cc(C(C)(C)C)cc(c42)N3c2c(-c3ccccc3)cc(-c3cccc(C#N)c3)cc2-c2cc(C(C)(C)C)cc(C(C)(C)C)c2)cc1]

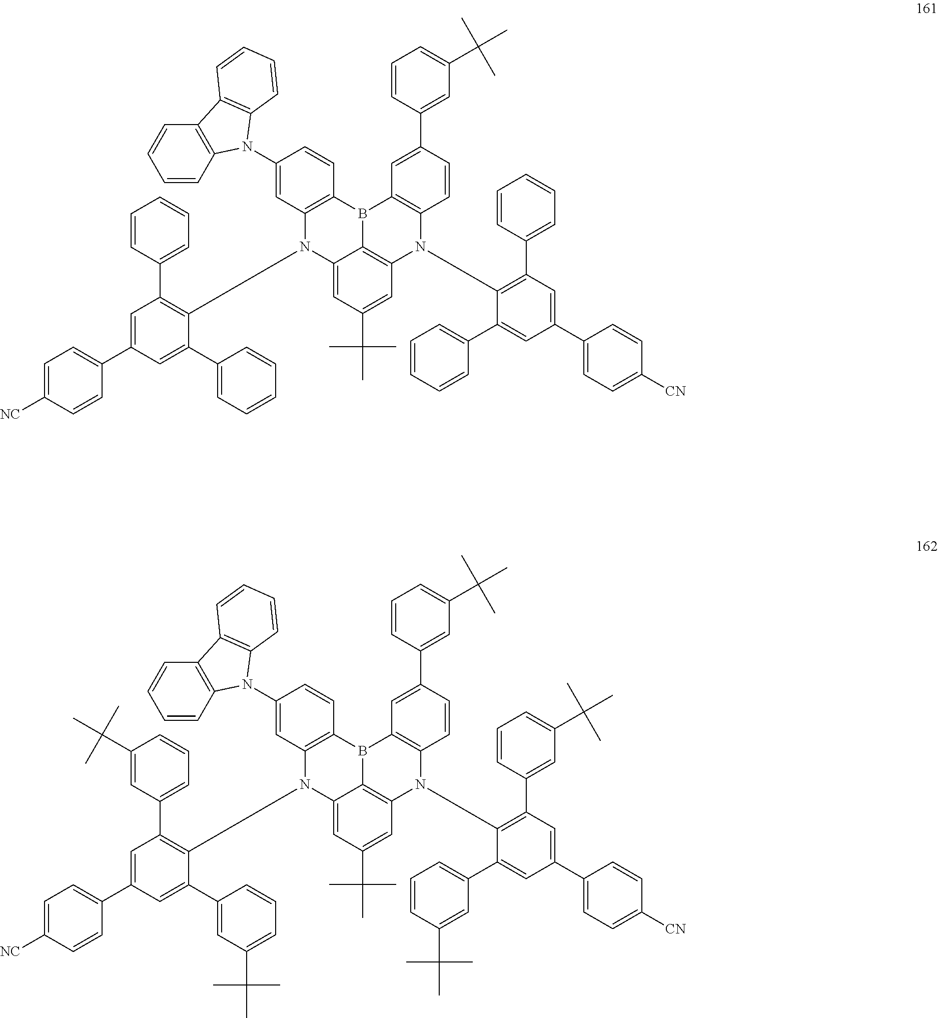 [SMILES: CC(C)(C)c1cccc(-c2ccc3c(c2)B2c4ccc(-n5c6ccccc6c6ccccc65)cc4N(c4c(-c5ccccc5)cc(-c5ccc(C#N)cc5)cc4-c4ccccc4)c4cc(C(C)(C)C)cc(c42)N3c2c(-c3ccccc3)cc(-c3ccc(C#N)cc3)cc2-c2ccccc2)c1 ; CC(C)(C)c1cccc(-c2ccc3c(c2)B2c4ccc(-n5c6ccccc6c6ccccc65)cc4N(c4c(-c5cccc(C(C)(C)C)c5)cc(-c5ccc(C#N)cc5)cc4-c4cccc(C(C)(C)C)c4)c4cc(C(C)(C)C)cc(c42)N3c2c(-c3cccc(C(C)(C)C)c3)cc(-c3ccc(C#N)cc3)cc2-c2cccc(C(C)(C)C)c2)c1]

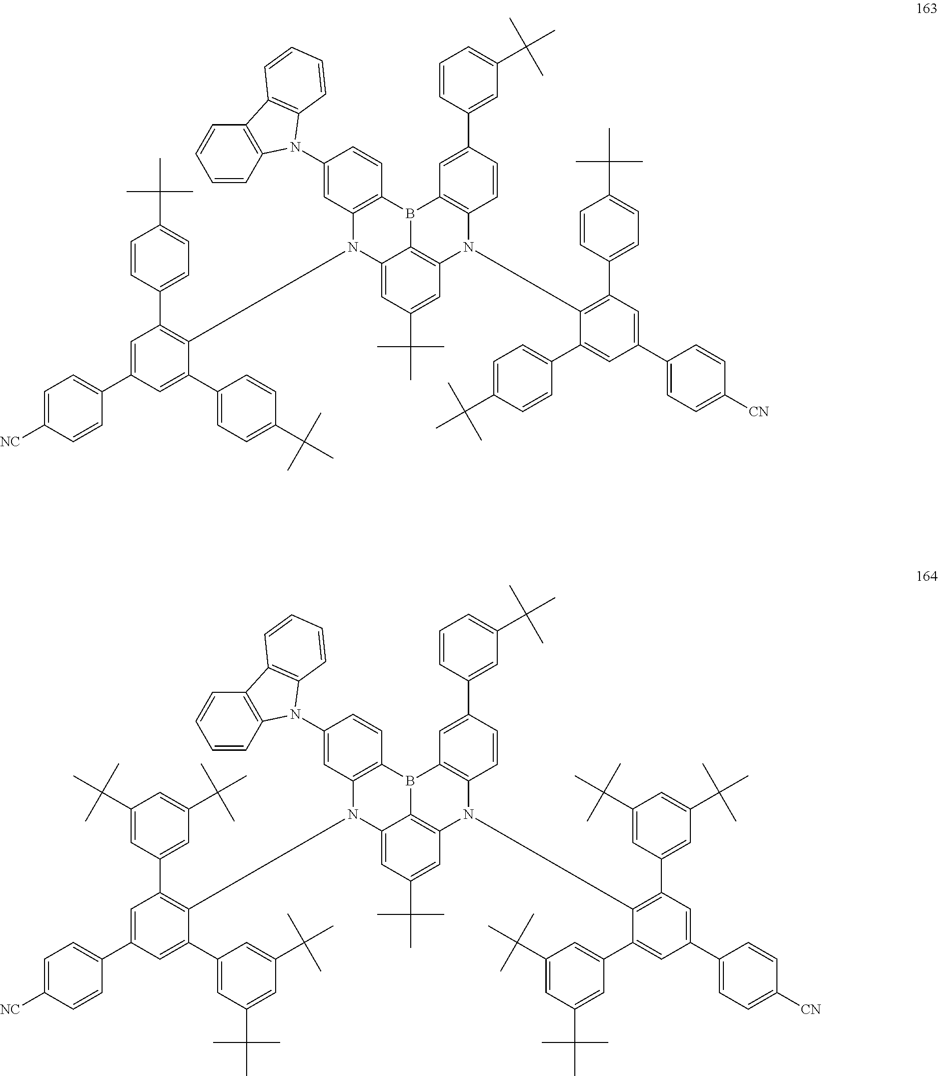 [SMILES: CC(C)(C)c1ccc(-c2cc(-c3ccc(C#N)cc3)cc(-c3ccc(C(C)(C)C)cc3)c2N2c3ccc(-c4cccc(C(C)(C)C)c4)cc3B3c4ccc(-n5c6ccccc6c6ccccc65)cc4N(c4c(-c5ccc(C(C)(C)C)cc5)cc(-c5ccc(C#N)cc5)cc4-c4ccc(C(C)(C)C)cc4)c4cc(C(C)(C)C)cc2c43)cc1 ; CC(C)(C)c1cccc(-c2ccc3c(c2)B2c4ccc(-n5c6ccccc6c6ccccc65)cc4N(c4c(-c5cc(C(C)(C)C)cc(C(C)(C)C)c5)cc(-c5ccc(C#N)cc5)cc4-c4cc(C(C)(C)C)cc(C(C)(C)C)c4)c4cc(C(C)(C)C)cc(c42)N3c2c(-c3cc(C(C)(C)C)cc(C(C)(C)C)c3)cc(-c3ccc(C#N)cc3)cc2-c2cc(C(C)(C)C)cc(C(C)(C)C)c2)c1]

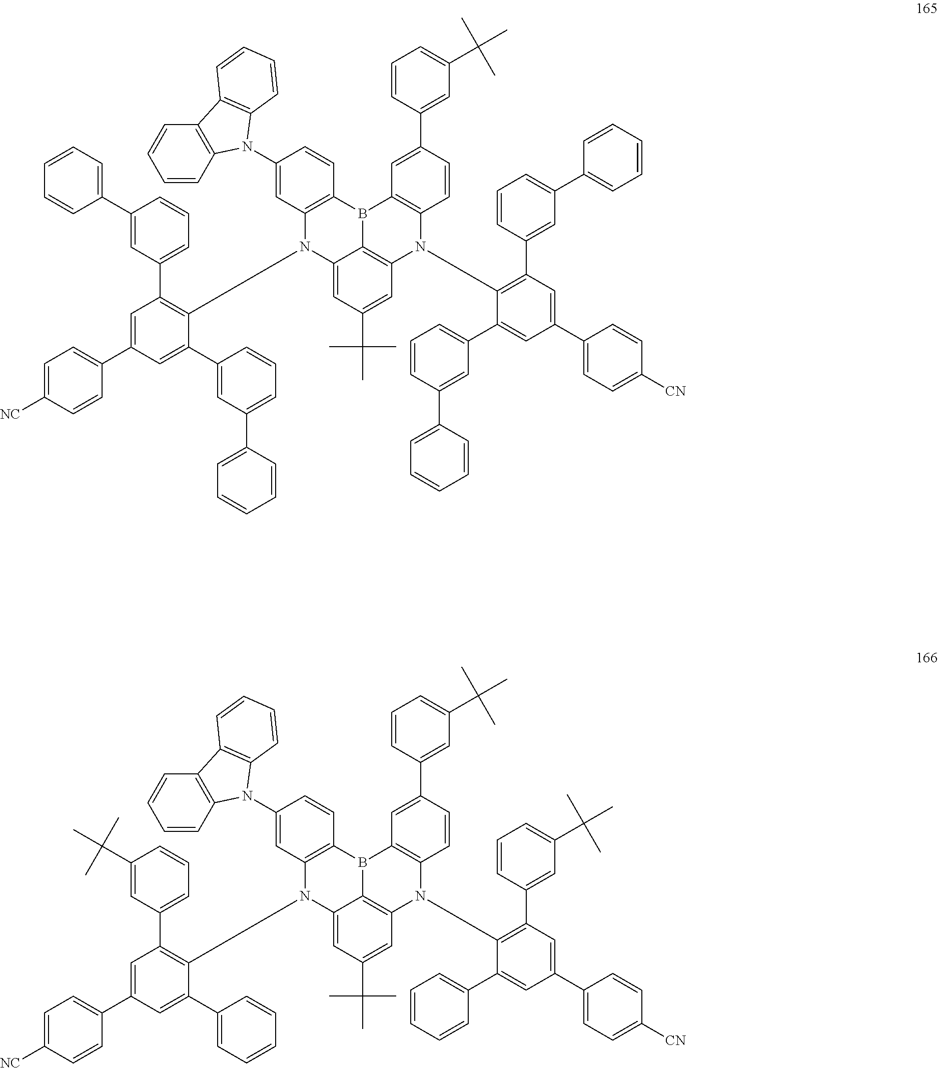 [SMILES: CC(C)(C)c1cccc(-c2ccc3c(c2)B2c4ccc(-n5c6ccccc6c6ccccc65)cc4N(c4c(-c5cccc(-c6ccccc6)c5)cc(-c5ccc(C#N)cc5)cc4-c4cccc(-c5ccccc5)c4)c4cc(C(C)(C)C)cc(c42)N3c2c(-c3cccc(-c4ccccc4)c3)cc(-c3ccc(C#N)cc3)cc2-c2cccc(-c3ccccc3)c2)c1 ; CC(C)(C)c1cccc(-c2ccc3c(c2)B2c4ccc(-n5c6ccccc6c6ccccc65)cc4N(c4c(-c5ccccc5)cc(-c5ccc(C#N)cc5)cc4-c4cccc(C(C)(C)C)c4)c4cc(C(C)(C)C)cc(c42)N3c2c(-c3ccccc3)cc(-c3ccc(C#N)cc3)cc2-c2cccc(C(C)(C)C)c2)c1]

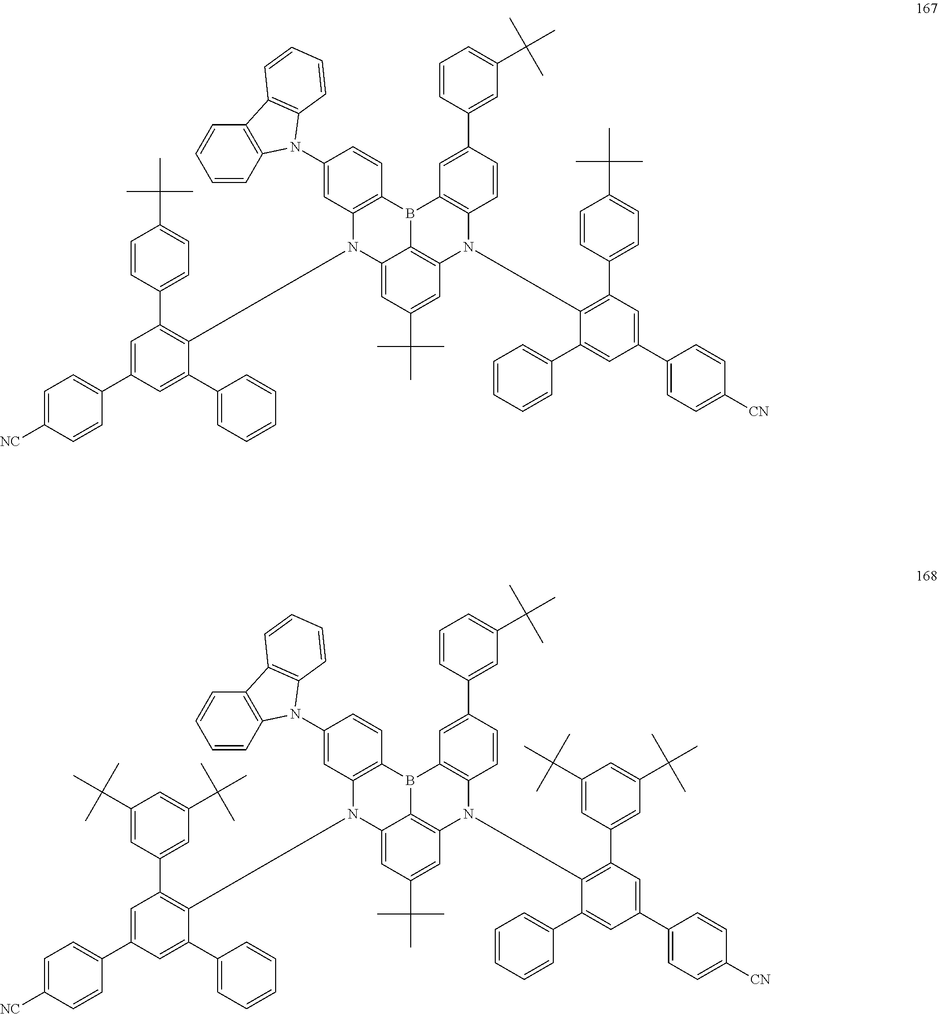 [SMILES: CC(C)(C)c1ccc(-c2cc(-c3ccc(C#N)cc3)cc(-c3ccccc3)c2N2c3ccc(-c4cccc(C(C)(C)C)c4)cc3B3c4ccc(-n5c6ccccc6c6ccccc65)cc4N(c4c(-c5ccccc5)cc(-c5ccc(C#N)cc5)cc4-c4ccc(C(C)(C)C)cc4)c4cc(C(C)(C)C)cc2c43)cc1 ; CC(C)(C)c1cccc(-c2ccc3c(c2)B2c4ccc(-n5c6ccccc6c6ccccc65)cc4N(c4c(-c5ccccc5)cc(-c5ccc(C#N)cc5)cc4-c4cc(C(C)(C)C)cc(C(C)(C)C)c4)c4cc(C(C)(C)C)cc(c42)N3c2c(-c3ccccc3)cc(-c3ccc(C#N)cc3)cc2-c2cc(C(C)(C)C)cc(C(C)(C)C)c2)c1]

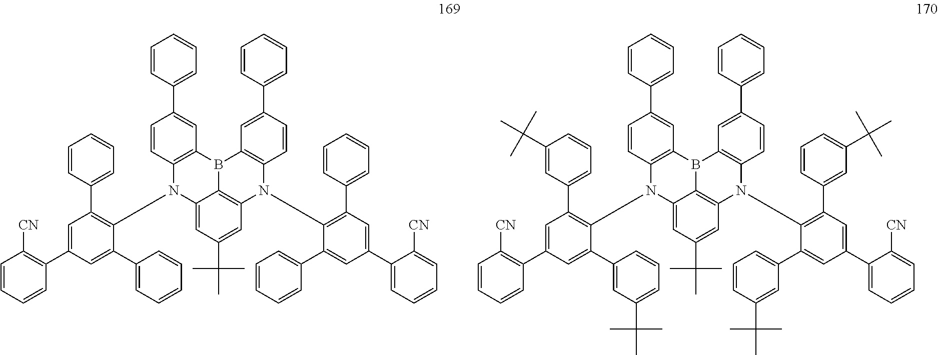 [SMILES: CC(C)(C)c1cc2c3c(c1)N(c1c(-c4ccccc4)cc(-c4ccccc4C#N)cc1-c1ccccc1)c1ccc(-c4ccccc4)cc1B3c1cc(-c3ccccc3)ccc1N2c1c(-c2ccccc2)cc(-c2ccccc2C#N)cc1-c1ccccc1 ; CC(C)(C)c1cccc(-c2cc(-c3ccccc3C#N)cc(-c3cccc(C(C)(C)C)c3)c2N2c3ccc(-c4ccccc4)cc3B3c4cc(-c5ccccc5)ccc4N(c4c(-c5cccc(C(C)(C)C)c5)cc(-c5ccccc5C#N)cc4-c4cccc(C(C)(C)C)c4)c4cc(C(C)(C)C)cc2c43)c1]

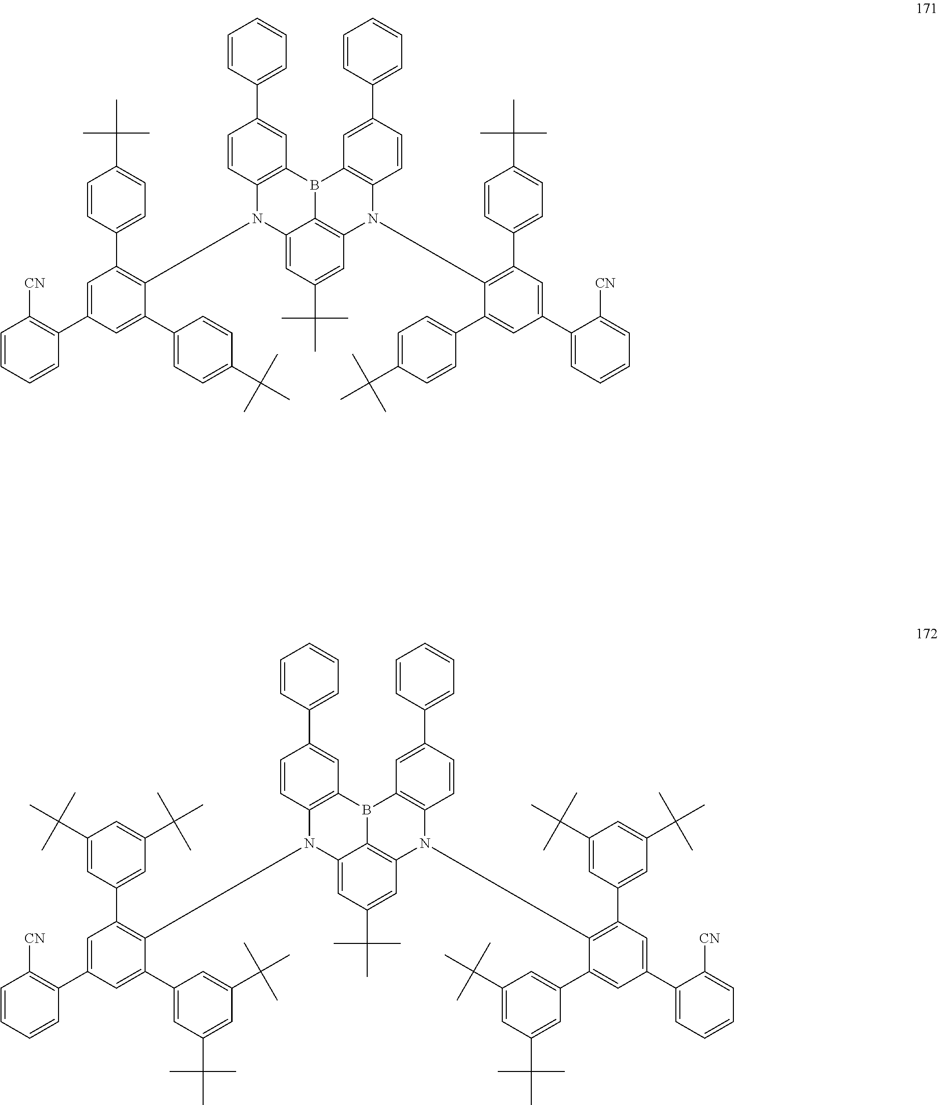 [SMILES: CC(C)(C)c1ccc(-c2cc(-c3ccccc3C#N)cc(-c3ccc(C(C)(C)C)cc3)c2N2c3ccc(-c4ccccc4)cc3B3c4cc(-c5ccccc5)ccc4N(c4c(-c5ccc(C(C)(C)C)cc5)cc(-c5ccccc5C#N)cc4-c4ccc(C(C)(C)C)cc4)c4cc(C(C)(C)C)cc2c43)cc1 ; CC(C)(C)c1cc(-c2cc(-c3ccccc3C#N)cc(-c3cc(C(C)(C)C)cc(C(C)(C)C)c3)c2N2c3ccc(-c4ccccc4)cc3B3c4cc(-c5ccccc5)ccc4N(c4c(-c5cc(C(C)(C)C)cc(C(C)(C)C)c5)cc(-c5ccccc5C#N)cc4-c4cc(C(C)(C)C)cc(C(C)(C)C)c4)c4cc(C(C)(C)C)cc2c43)cc(C(C)(C)C)c1]

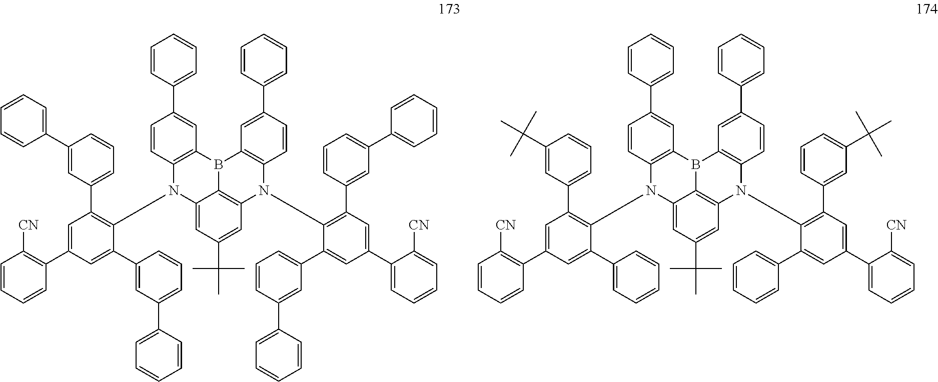 [SMILES: CC(C)(C)c1cc2c3c(c1)N(c1c(-c4cccc(-c5ccccc5)c4)cc(-c4ccccc4C#N)cc1-c1cccc(-c4ccccc4)c1)c1ccc(-c4ccccc4)cc1B3c1cc(-c3ccccc3)ccc1N2c1c(-c2cccc(-c3ccccc3)c2)cc(-c2ccccc2C#N)cc1-c1cccc(-c2ccccc2)c1 ; CC(C)(C)c1cccc(-c2cc(-c3ccccc3C#N)cc(-c3ccccc3)c2N2c3ccc(-c4ccccc4)cc3B3c4cc(-c5ccccc5)ccc4N(c4c(-c5ccccc5)cc(-c5ccccc5C#N)cc4-c4cccc(C(C)(C)C)c4)c4cc(C(C)(C)C)cc2c43)c1]

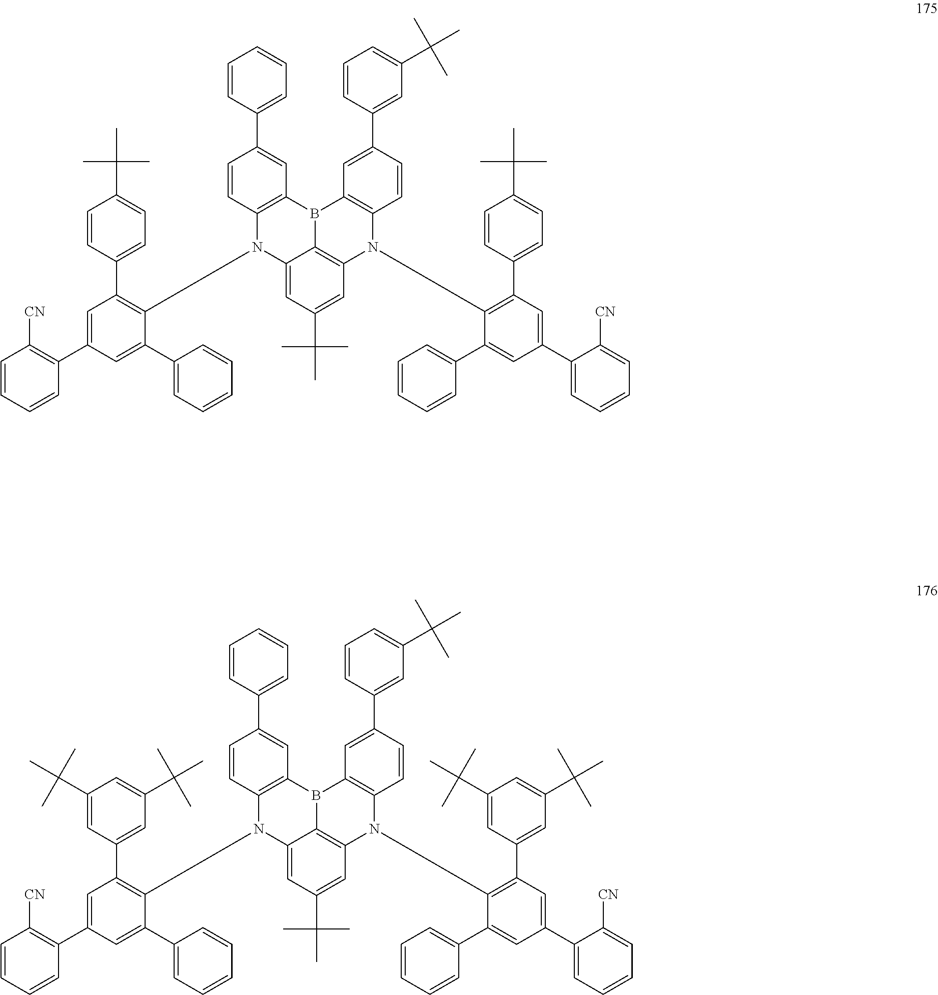 [SMILES: CC(C)(C)c1ccc(-c2cc(-c3ccccc3C#N)cc(-c3ccccc3)c2N2c3ccc(-c4ccccc4)cc3B3c4cc(-c5cccc(C(C)(C)C)c5)ccc4N(c4c(-c5ccccc5)cc(-c5ccccc5C#N)cc4-c4ccc(C(C)(C)C)cc4)c4cc(C(C)(C)C)cc2c43)cc1 ; CC(C)(C)c1cccc(-c2ccc3c(c2)B2c4cc(-c5ccccc5)ccc4N(c4c(-c5ccccc5)cc(-c5ccccc5C#N)cc4-c4cc(C(C)(C)C)cc(C(C)(C)C)c4)c4cc(C(C)(C)C)cc(c42)N3c2c(-c3ccccc3)cc(-c3ccccc3C#N)cc2-c2cc(C(C)(C)C)cc(C(C)(C)C)c2)c1]

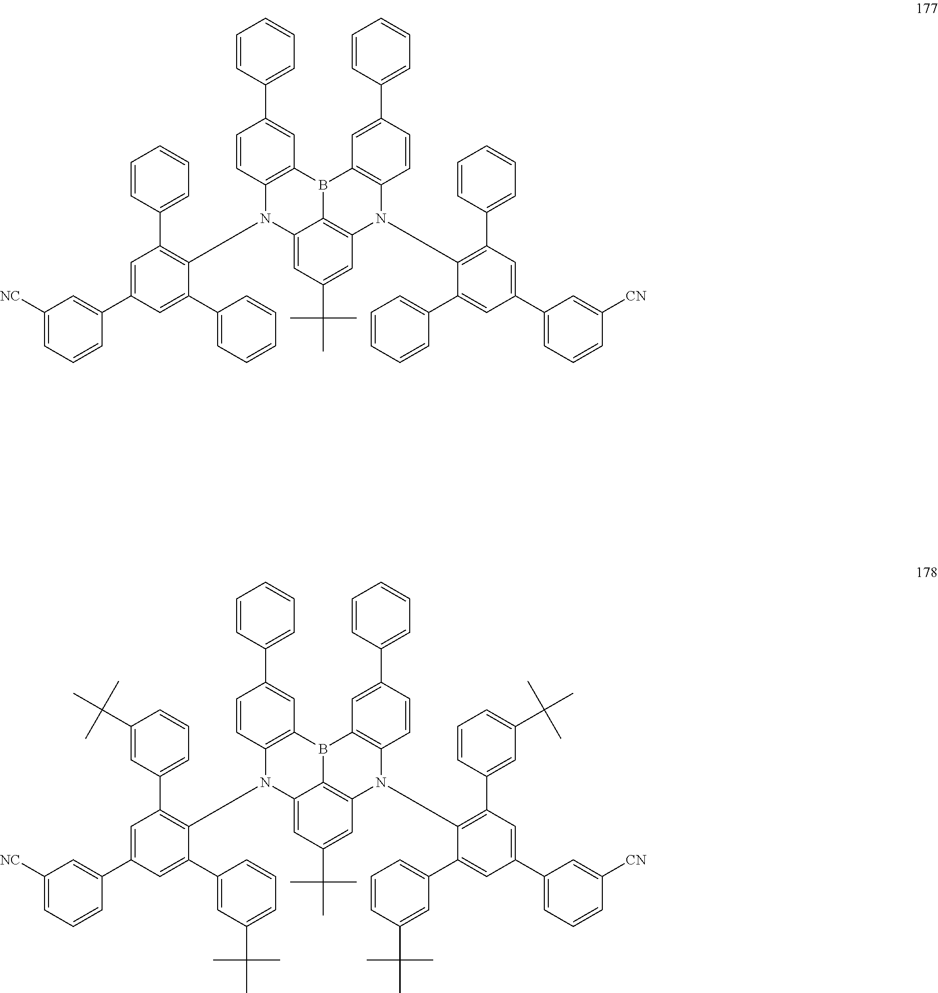 [SMILES: CC(C)(C)c1cc2c3c(c1)N(c1c(-c4ccccc4)cc(-c4cccc(C#N)c4)cc1-c1ccccc1)c1ccc(-c4ccccc4)cc1B3c1cc(-c3ccccc3)ccc1N2c1c(-c2ccccc2)cc(-c2cccc(C#N)c2)cc1-c1ccccc1 ; CC(C)(C)c1cccc(-c2cc(-c3cccc(C#N)c3)cc(-c3cccc(C(C)(C)C)c3)c2N2c3ccc(-c4ccccc4)cc3B3c4cc(-c5ccccc5)ccc4N(c4c(-c5cccc(C(C)(C)C)c5)cc(-c5cccc(C#N)c5)cc4-c4cccc(C(C)(C)C)c4)c4cc(C(C)(C)C)cc2c43)c1]

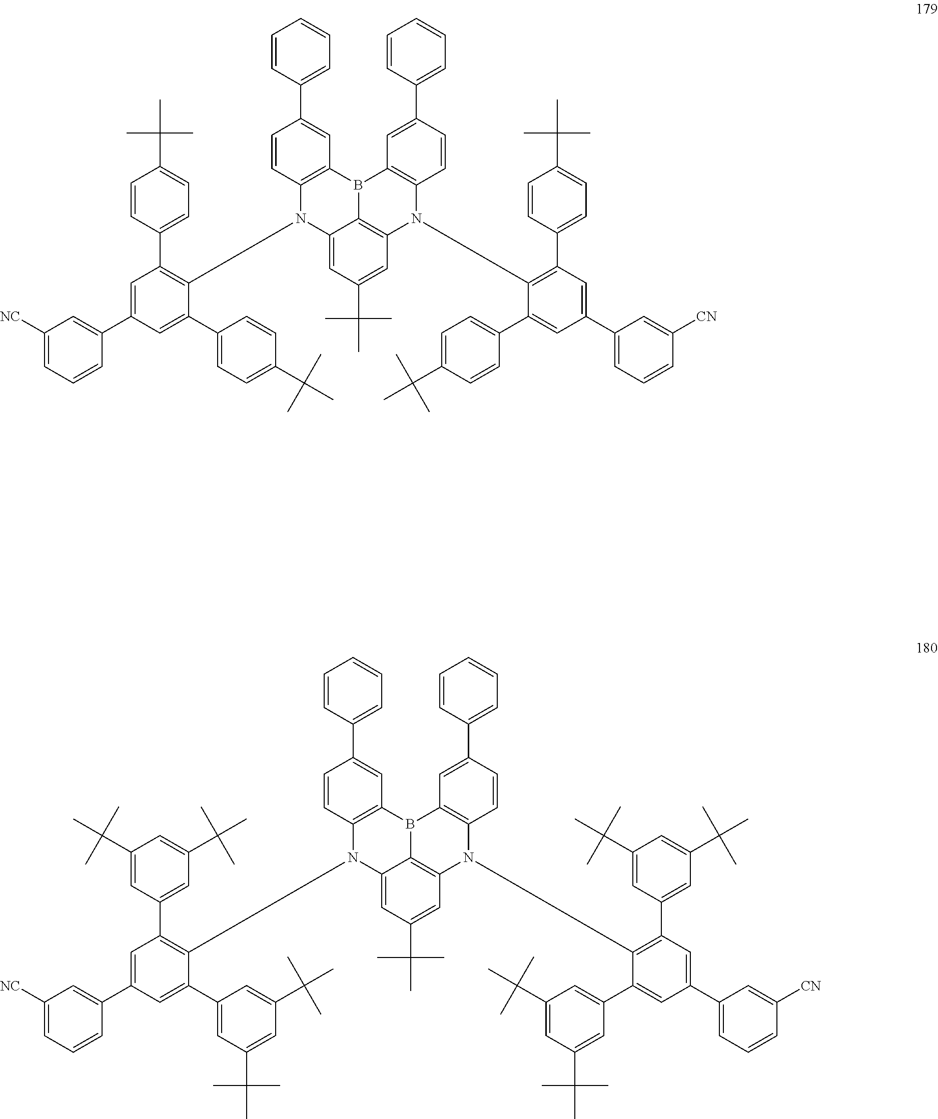 [SMILES: CC(C)(C)c1ccc(-c2cc(-c3cccc(C#N)c3)cc(-c3ccc(C(C)(C)C)cc3)c2N2c3ccc(-c4ccccc4)cc3B3c4cc(-c5ccccc5)ccc4N(c4c(-c5ccc(C(C)(C)C)cc5)cc(-c5cccc(C#N)c5)cc4-c4ccc(C(C)(C)C)cc4)c4cc(C(C)(C)C)cc2c43)cc1 ; CC(C)(C)c1cc(-c2cc(-c3cccc(C#N)c3)cc(-c3cc(C(C)(C)C)cc(C(C)(C)C)c3)c2N2c3ccc(-c4ccccc4)cc3B3c4cc(-c5ccccc5)ccc4N(c4c(-c5cc(C(C)(C)C)cc(C(C)(C)C)c5)cc(-c5cccc(C#N)c5)cc4-c4cc(C(C)(C)C)cc(C(C)(C)C)c4)c4cc(C(C)(C)C)cc2c43)cc(C(C)(C)C)c1]

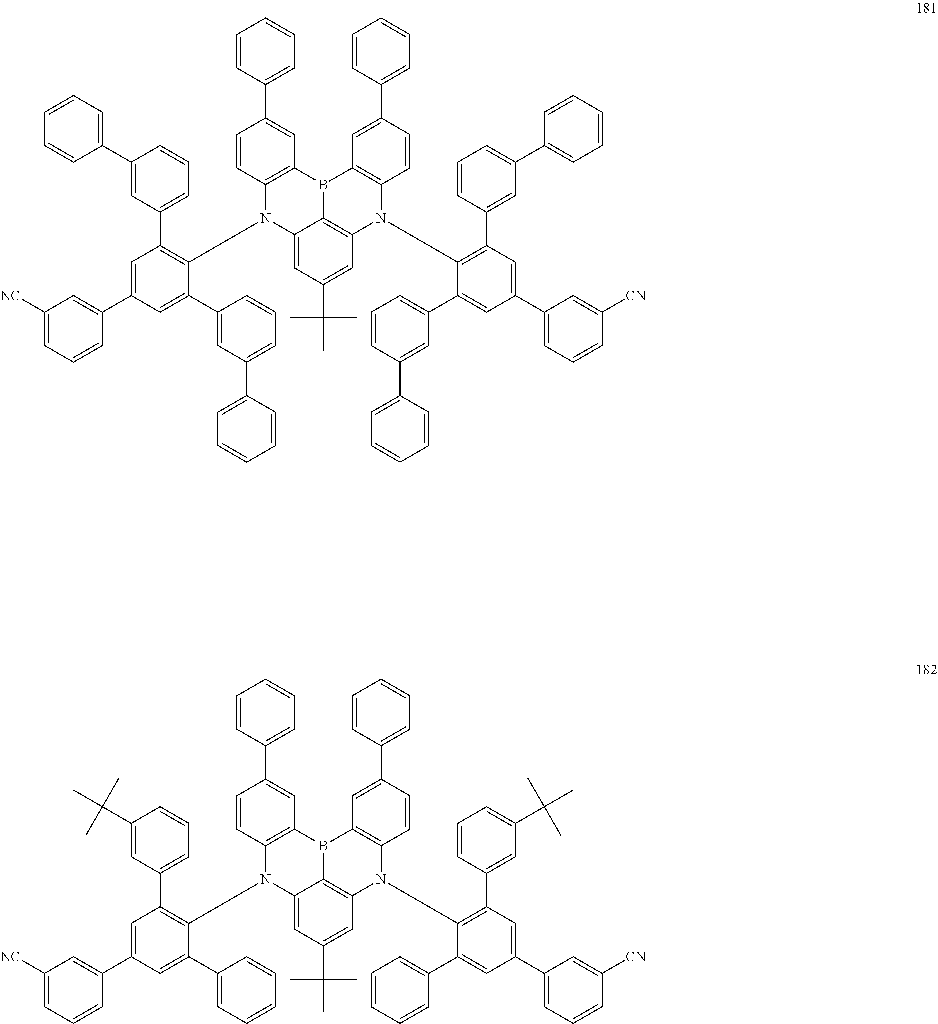 [SMILES: CC(C)(C)c1cc2c3c(c1)N(c1c(-c4cccc(-c5ccccc5)c4)cc(-c4cccc(C#N)c4)cc1-c1cccc(-c4ccccc4)c1)c1ccc(-c4ccccc4)cc1B3c1cc(-c3ccccc3)ccc1N2c1c(-c2cccc(-c3ccccc3)c2)cc(-c2cccc(C#N)c2)cc1-c1cccc(-c2ccccc2)c1 ; CC(C)(C)c1cccc(-c2cc(-c3cccc(C#N)c3)cc(-c3ccccc3)c2N2c3ccc(-c4ccccc4)cc3B3c4cc(-c5ccccc5)ccc4N(c4c(-c5ccccc5)cc(-c5cccc(C#N)c5)cc4-c4cccc(C(C)(C)C)c4)c4cc(C(C)(C)C)cc2c43)c1]

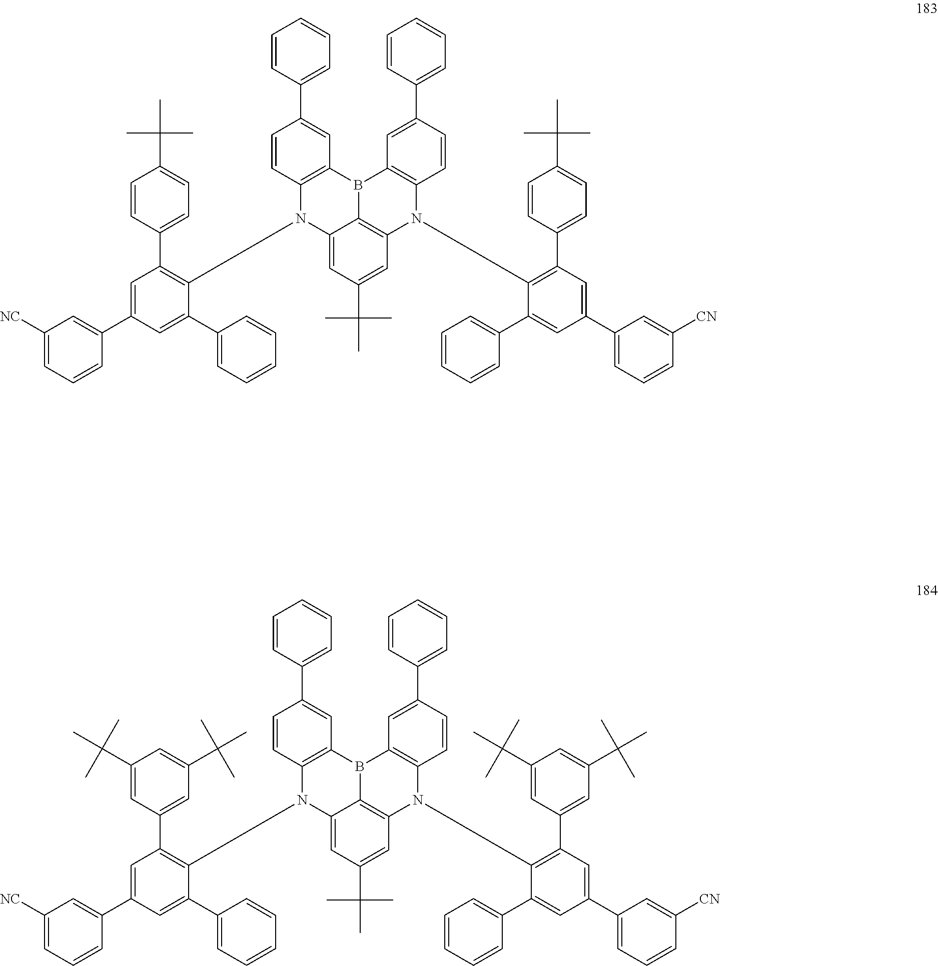 [SMILES: CC(C)(C)c1ccc(-c2cc(-c3cccc(C#N)c3)cc(-c3ccccc3)c2N2c3ccc(-c4ccccc4)cc3B3c4cc(-c5ccccc5)ccc4N(c4c(-c5ccccc5)cc(-c5cccc(C#N)c5)cc4-c4ccc(C(C)(C)C)cc4)c4cc(C(C)(C)C)cc2c43)cc1 ; CC(C)(C)c1cc(-c2cc(-c3cccc(C#N)c3)cc(-c3ccccc3)c2N2c3ccc(-c4ccccc4)cc3B3c4cc(-c5ccccc5)ccc4N(c4c(-c5ccccc5)cc(-c5cccc(C#N)c5)cc4-c4cc(C(C)(C)C)cc(C(C)(C)C)c4)c4cc(C(C)(C)C)cc2c43)cc(C(C)(C)C)c1]

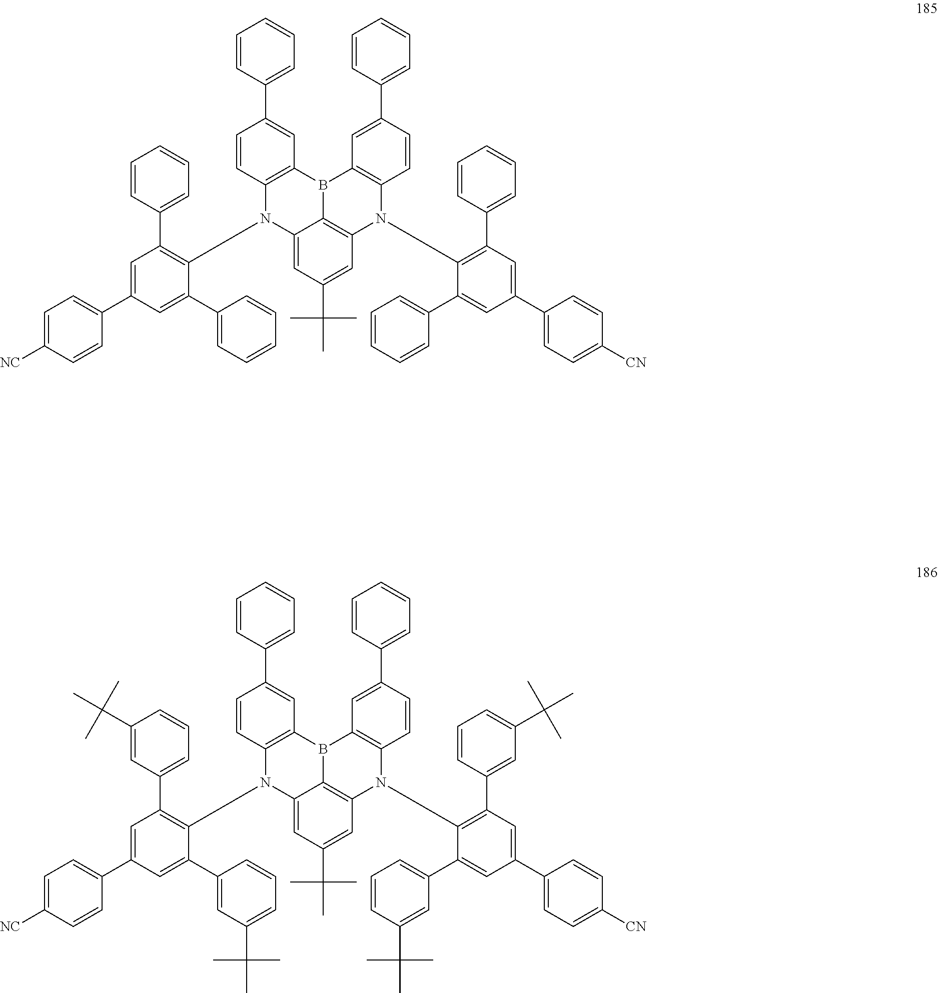 [SMILES: CC(C)(C)c1cc2c3c(c1)N(c1c(-c4ccccc4)cc(-c4ccc(C#N)cc4)cc1-c1ccccc1)c1ccc(-c4ccccc4)cc1B3c1cc(-c3ccccc3)ccc1N2c1c(-c2ccccc2)cc(-c2ccc(C#N)cc2)cc1-c1ccccc1 ; CC(C)(C)c1cccc(-c2cc(-c3ccc(C#N)cc3)cc(-c3cccc(C(C)(C)C)c3)c2N2c3ccc(-c4ccccc4)cc3B3c4cc(-c5ccccc5)ccc4N(c4c(-c5cccc(C(C)(C)C)c5)cc(-c5ccc(C#N)cc5)cc4-c4cccc(C(C)(C)C)c4)c4cc(C(C)(C)C)cc2c43)c1]

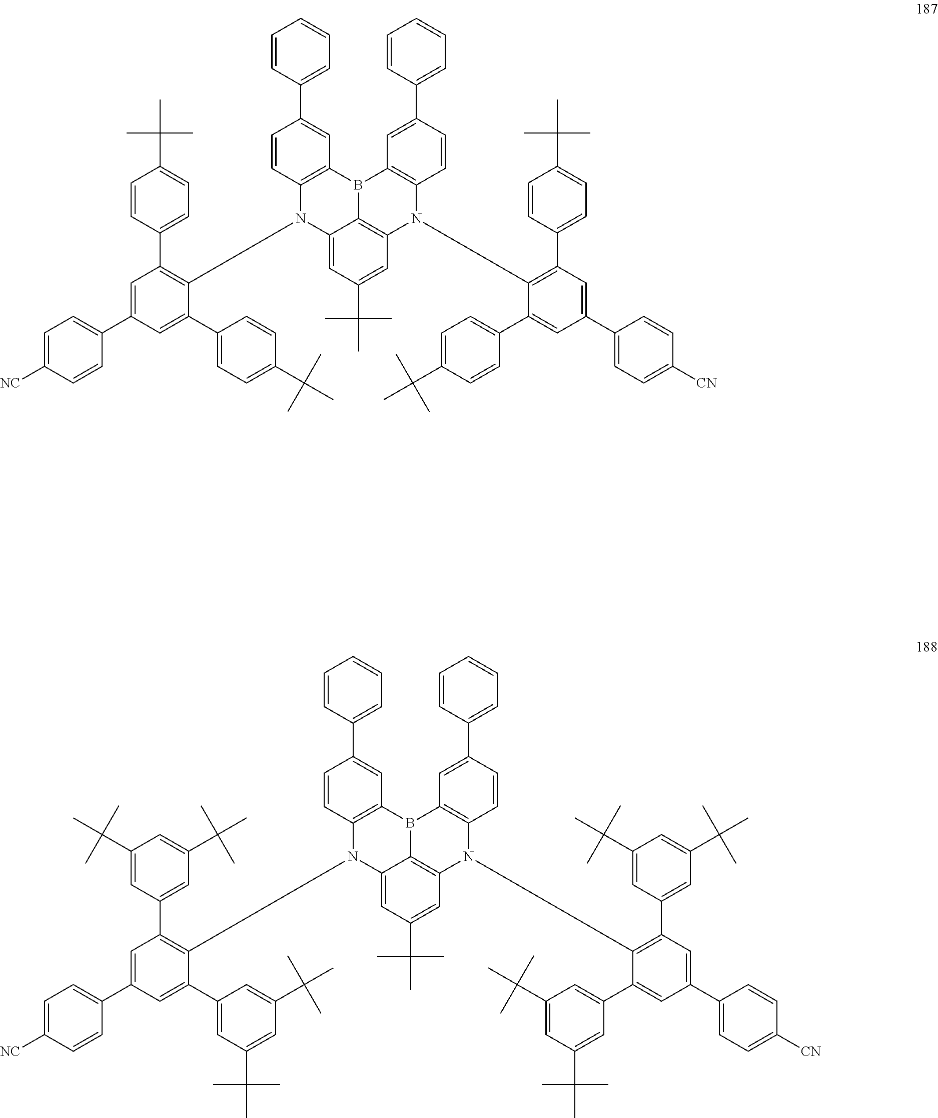 [SMILES: CC(C)(C)c1ccc(-c2cc(-c3ccc(C#N)cc3)cc(-c3ccc(C(C)(C)C)cc3)c2N2c3ccc(-c4ccccc4)cc3B3c4cc(-c5ccccc5)ccc4N(c4c(-c5ccc(C(C)(C)C)cc5)cc(-c5ccc(C#N)cc5)cc4-c4ccc(C(C)(C)C)cc4)c4cc(C(C)(C)C)cc2c43)cc1 ; CC(C)(C)c1cc(-c2cc(-c3ccc(C#N)cc3)cc(-c3cc(C(C)(C)C)cc(C(C)(C)C)c3)c2N2c3ccc(-c4ccccc4)cc3B3c4cc(-c5ccccc5)ccc4N(c4c(-c5cc(C(C)(C)C)cc(C(C)(C)C)c5)cc(-c5ccc(C#N)cc5)cc4-c4cc(C(C)(C)C)cc(C(C)(C)C)c4)c4cc(C(C)(C)C)cc2c43)cc(C(C)(C)C)c1]

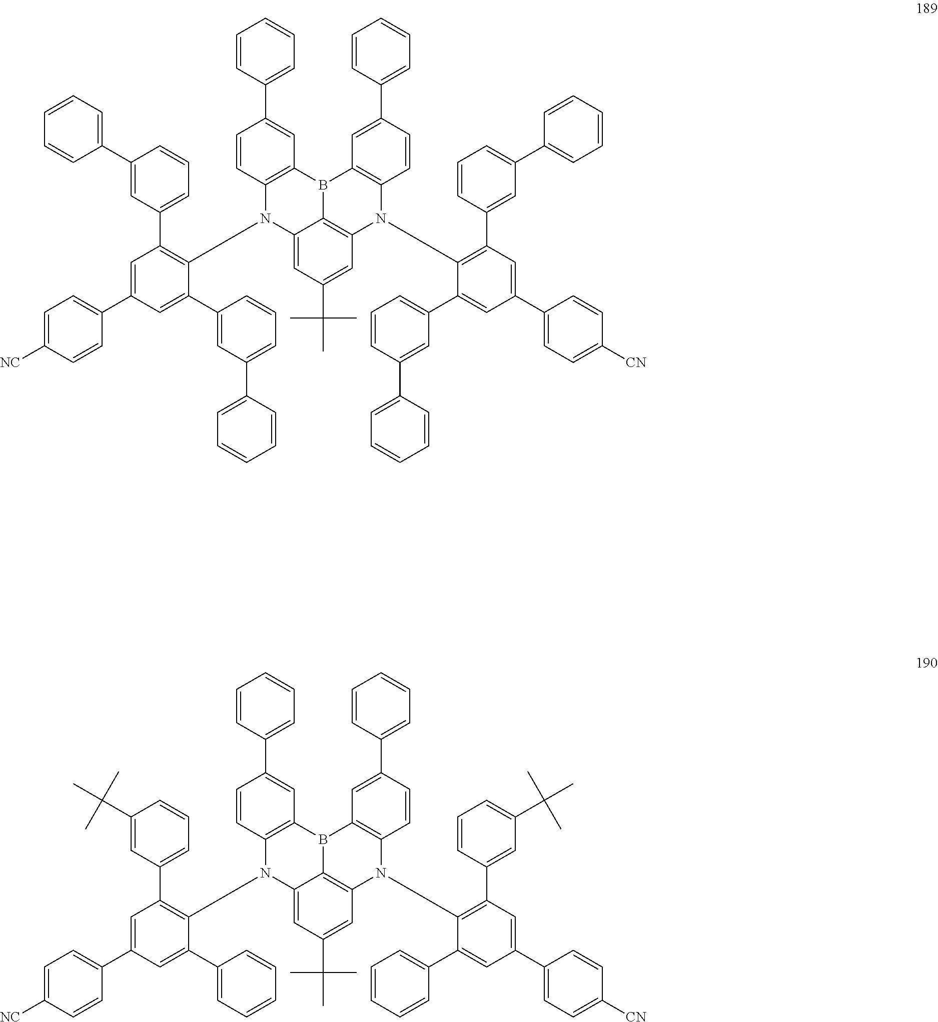 [SMILES: CC(C)(C)c1cc2c3c(c1)N(c1c(-c4cccc(-c5ccccc5)c4)cc(-c4ccc(C#N)cc4)cc1-c1cccc(-c4ccccc4)c1)c1ccc(-c4ccccc4)cc1B3c1cc(-c3ccccc3)ccc1N2c1c(-c2cccc(-c3ccccc3)c2)cc(-c2ccc(C#N)cc2)cc1-c1cccc(-c2ccccc2)c1 ; CC(C)(C)c1cccc(-c2cc(-c3ccc(C#N)cc3)cc(-c3ccccc3)c2N2c3ccc(-c4ccccc4)cc3B3c4cc(-c5ccccc5)ccc4N(c4c(-c5ccccc5)cc(-c5ccc(C#N)cc5)cc4-c4cccc(C(C)(C)C)c4)c4cc(C(C)(C)C)cc2c43)c1]

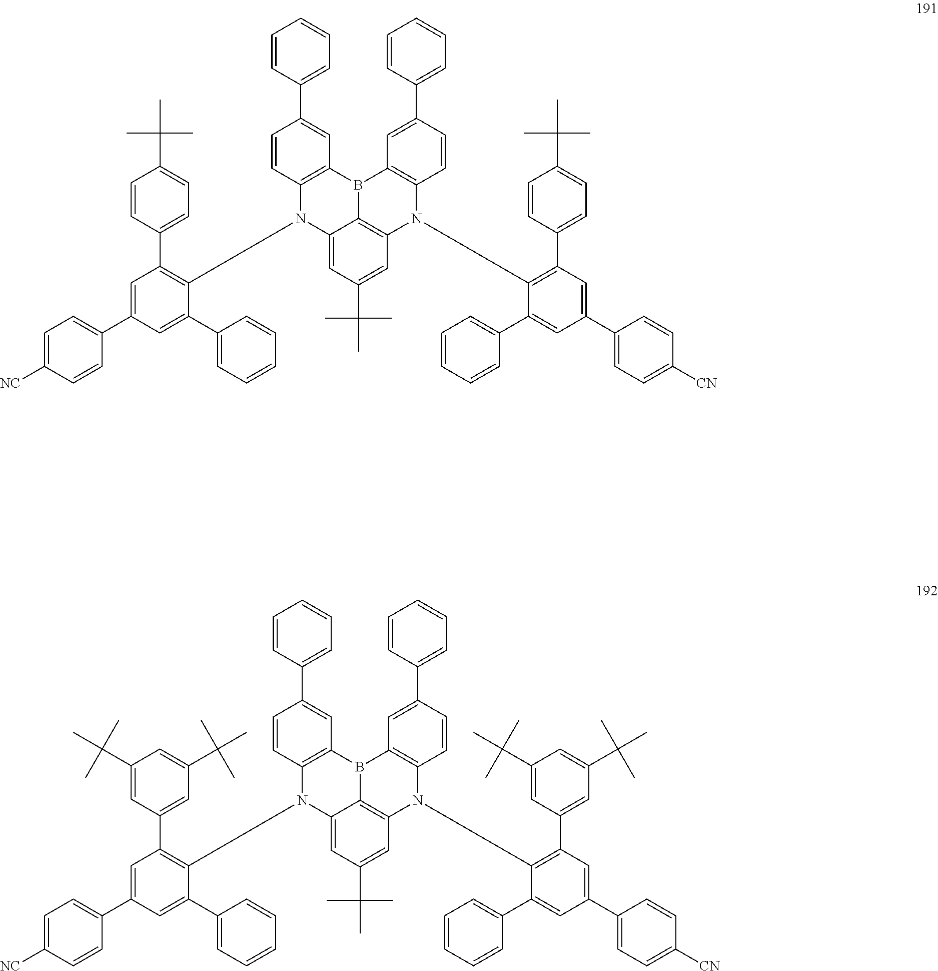 [SMILES: CC(C)(C)c1ccc(-c2cc(-c3ccc(C#N)cc3)cc(-c3ccccc3)c2N2c3ccc(-c4ccccc4)cc3B3c4cc(-c5ccccc5)ccc4N(c4c(-c5ccccc5)cc(-c5ccc(C#N)cc5)cc4-c4ccc(C(C)(C)C)cc4)c4cc(C(C)(C)C)cc2c43)cc1 ; CC(C)(C)c1cc(-c2cc(-c3ccc(C#N)cc3)cc(-c3ccccc3)c2N2c3ccc(-c4ccccc4)cc3B3c4cc(-c5ccccc5)ccc4N(c4c(-c5ccccc5)cc(-c5ccc(C#N)cc5)cc4-c4cc(C(C)(C)C)cc(C(C)(C)C)c4)c4cc(C(C)(C)C)cc2c43)cc(C(C)(C)C)c1]

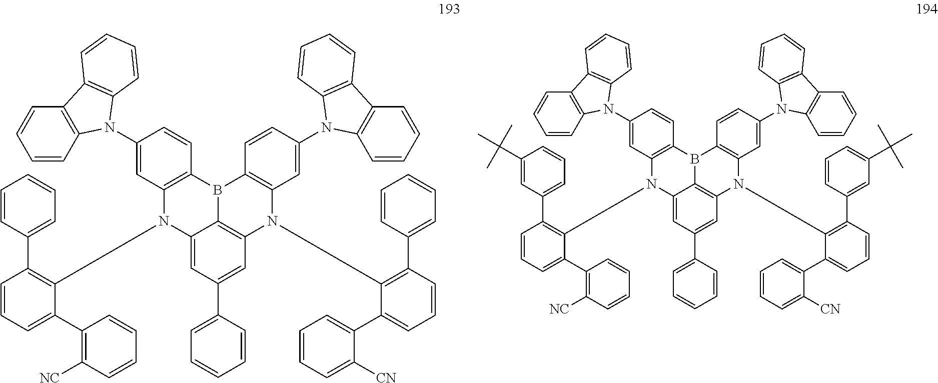 [SMILES: N#Cc1ccccc1-c1cccc(-c2ccccc2)c1N1c2cc(-n3c4ccccc4c4ccccc43)ccc2B2c3ccc(-n4c5ccccc5c5ccccc54)cc3N(c3c(-c4ccccc4)cccc3-c3ccccc3C#N)c3cc(-c4ccccc4)cc1c32 ; CC(C)(C)c1cccc(-c2cccc(-c3ccccc3C#N)c2N2c3cc(-n4c5ccccc5c5ccccc54)ccc3B3c4ccc(-n5c6ccccc6c6ccccc65)cc4N(c4c(-c5cccc(C(C)(C)C)c5)cccc4-c4ccccc4C#N)c4cc(-c5ccccc5)cc2c43)c1]

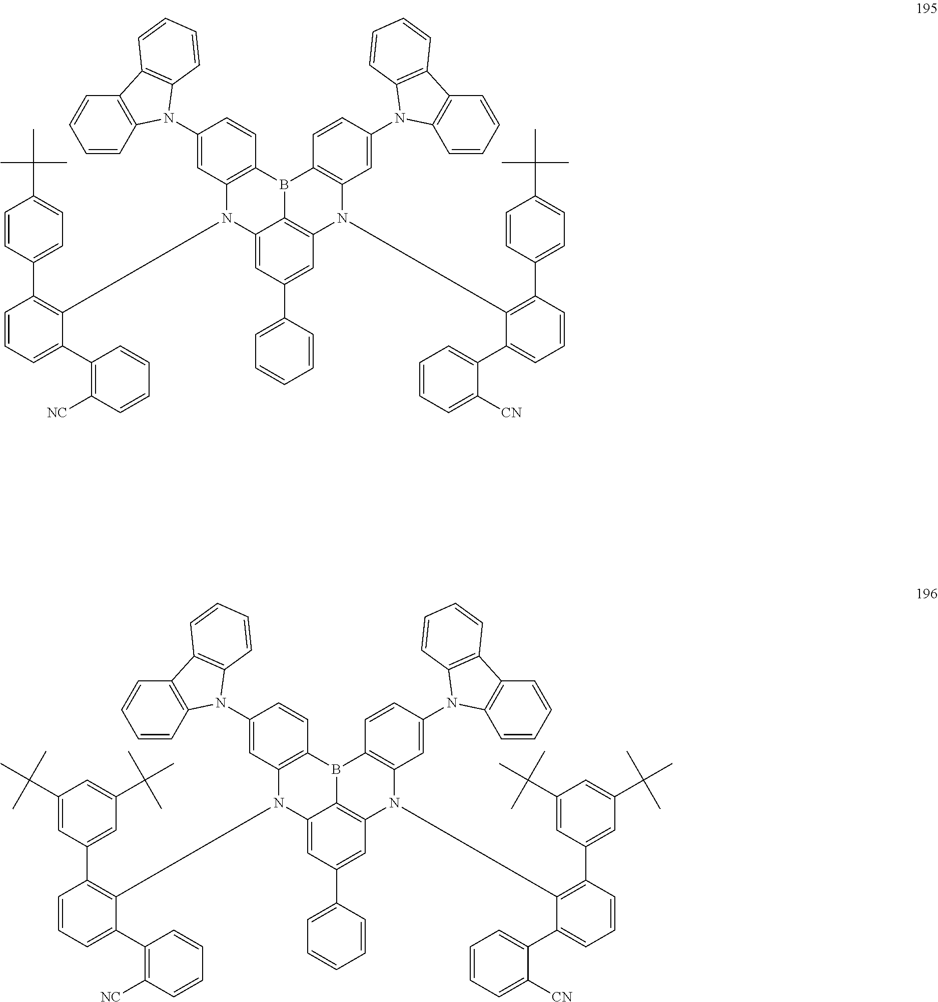

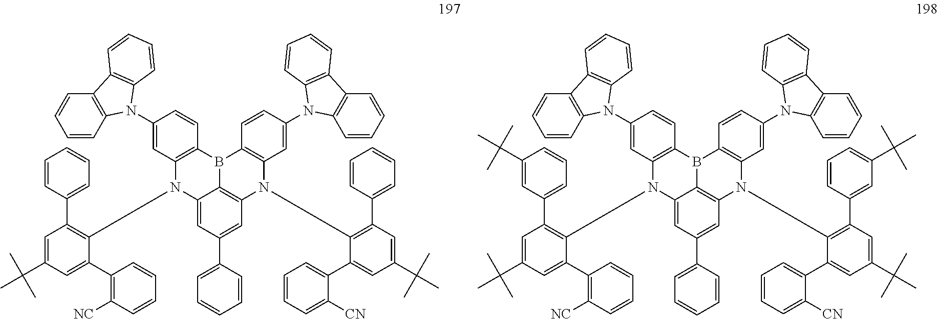 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(C(C)(C)C)cc4-c4ccccc4C#N)c4cc(-c5ccccc5)cc2c43)c(-c2ccccc2C#N)c1 ; CC(C)(C)c1cccc(-c2cc(C(C)(C)C)cc(-c3ccccc3C#N)c2N2c3cc(-n4c5ccccc5c5ccccc54)ccc3B3c4ccc(-n5c6ccccc6c6ccccc65)cc4N(c4c(-c5cccc(C(C)(C)C)c5)cc(C(C)(C)C)cc4-c4ccccc4C#N)c4cc(-c5ccccc5)cc2c43)c1]

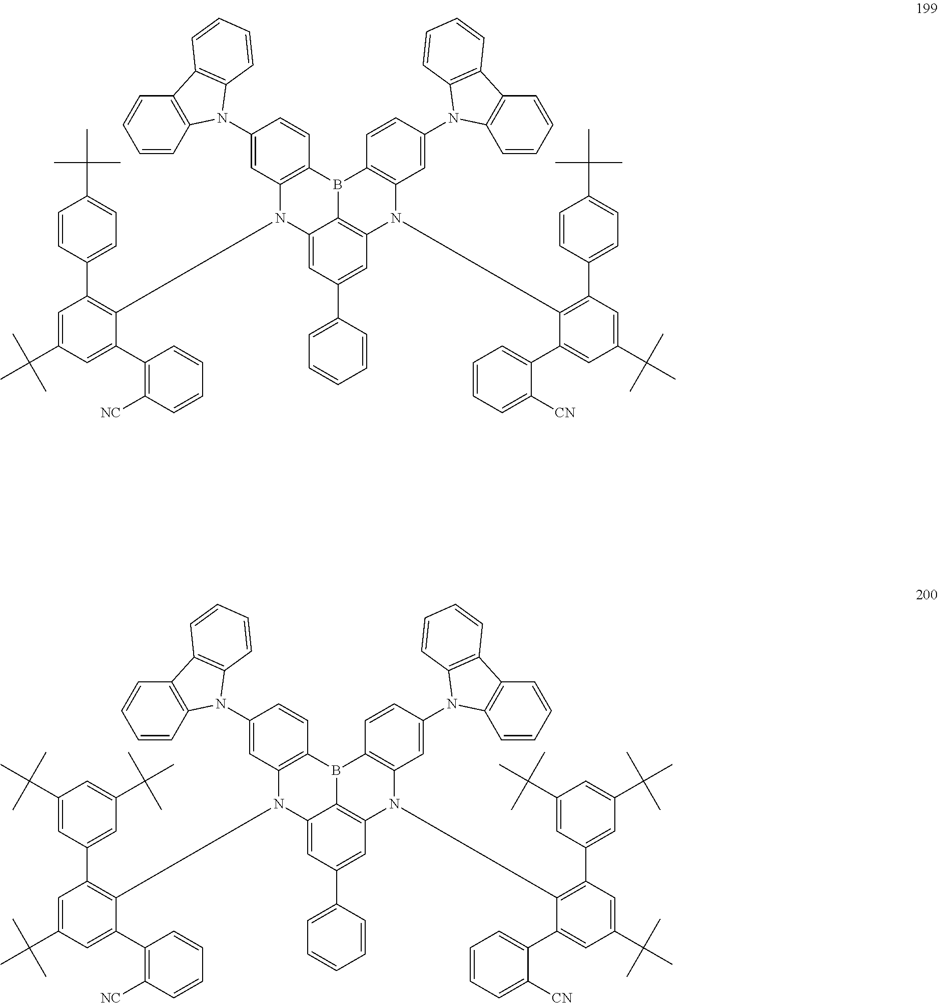

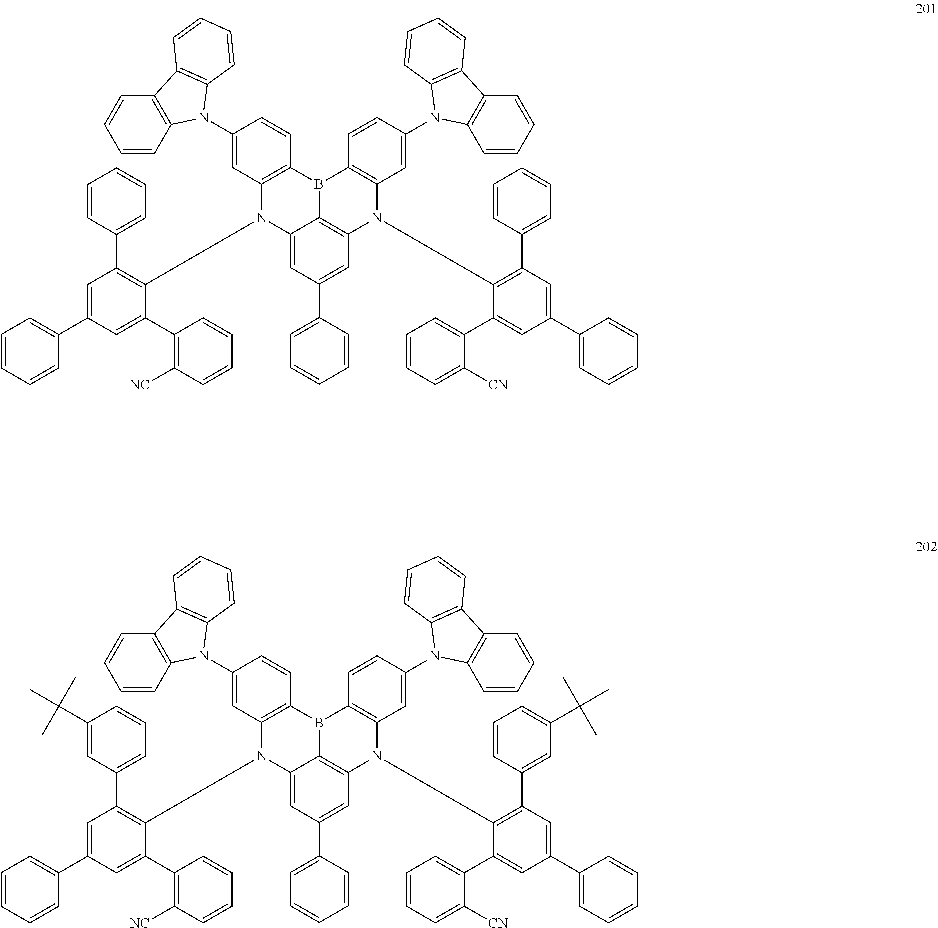 [SMILES: N#Cc1ccccc1-c1cc(-c2ccccc2)cc(-c2ccccc2)c1N1c2cc(-n3c4ccccc4c4ccccc43)ccc2B2c3ccc(-n4c5ccccc5c5ccccc54)cc3N(c3c(-c4ccccc4)cc(-c4ccccc4)cc3-c3ccccc3C#N)c3cc(-c4ccccc4)cc1c32 ; CC(C)(C)c1cccc(-c2cc(-c3ccccc3)cc(-c3ccccc3C#N)c2N2c3cc(-n4c5ccccc5c5ccccc54)ccc3B3c4ccc(-n5c6ccccc6c6ccccc65)cc4N(c4c(-c5cccc(C(C)(C)C)c5)cc(-c5ccccc5)cc4-c4ccccc4C#N)c4cc(-c5ccccc5)cc2c43)c1]

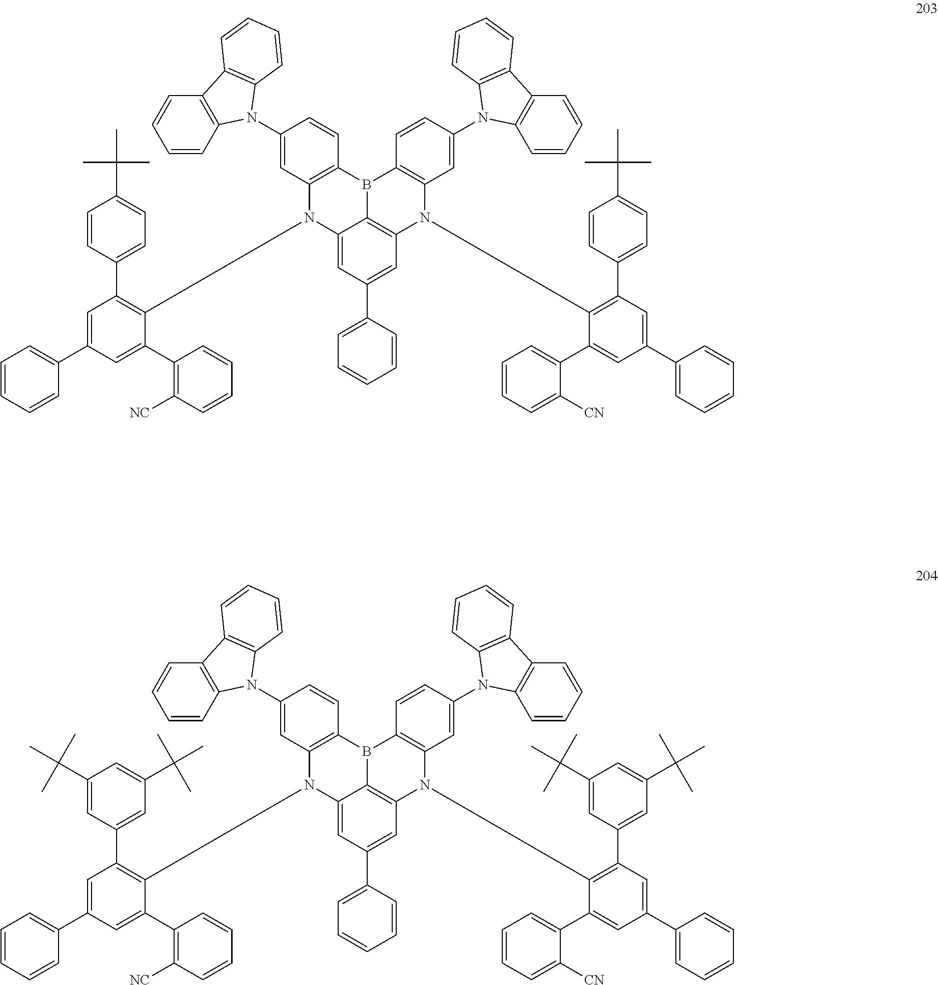 [SMILES: CC(C)(C)c1ccc(-c2cc(-c3ccccc3)cc(-c3ccccc3C#N)c2N2c3cc(-n4c5ccccc5c5ccccc54)ccc3B3c4ccc(-n5c6ccccc6c6ccccc65)cc4N(c4c(-c5ccc(C(C)(C)C)cc5)cc(-c5ccccc5)cc4-c4ccccc4C#N)c4cc(-c5ccccc5)cc2c43)cc1 ; CC(C)(C)c1cc(-c2cc(-c3ccccc3)cc(-c3ccccc3C#N)c2N2c3cc(-n4c5ccccc5c5ccccc54)ccc3B3c4ccc(-n5c6ccccc6c6ccccc65)cc4N(c4c(-c5cc(C(C)(C)C)cc(C(C)(C)C)c5)cc(-c5ccccc5)cc4-c4ccccc4C#N)c4cc(-c5ccccc5)cc2c43)cc(C(C)(C)C)c1]

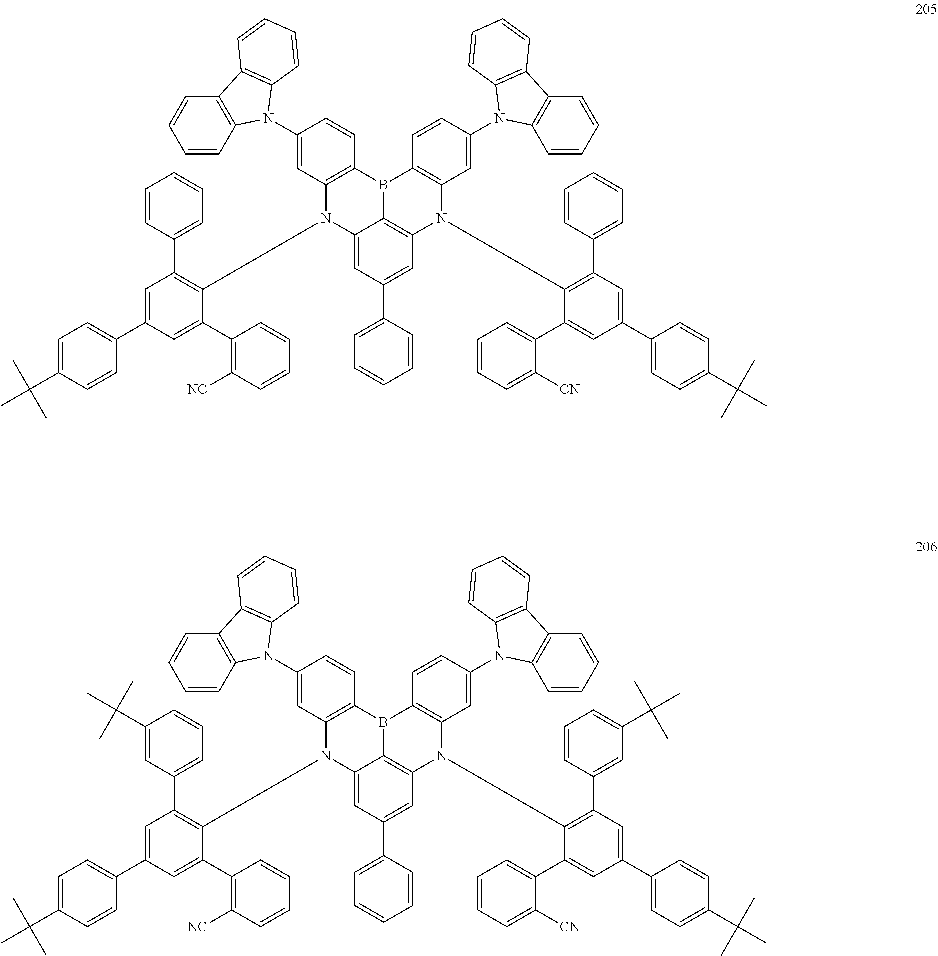

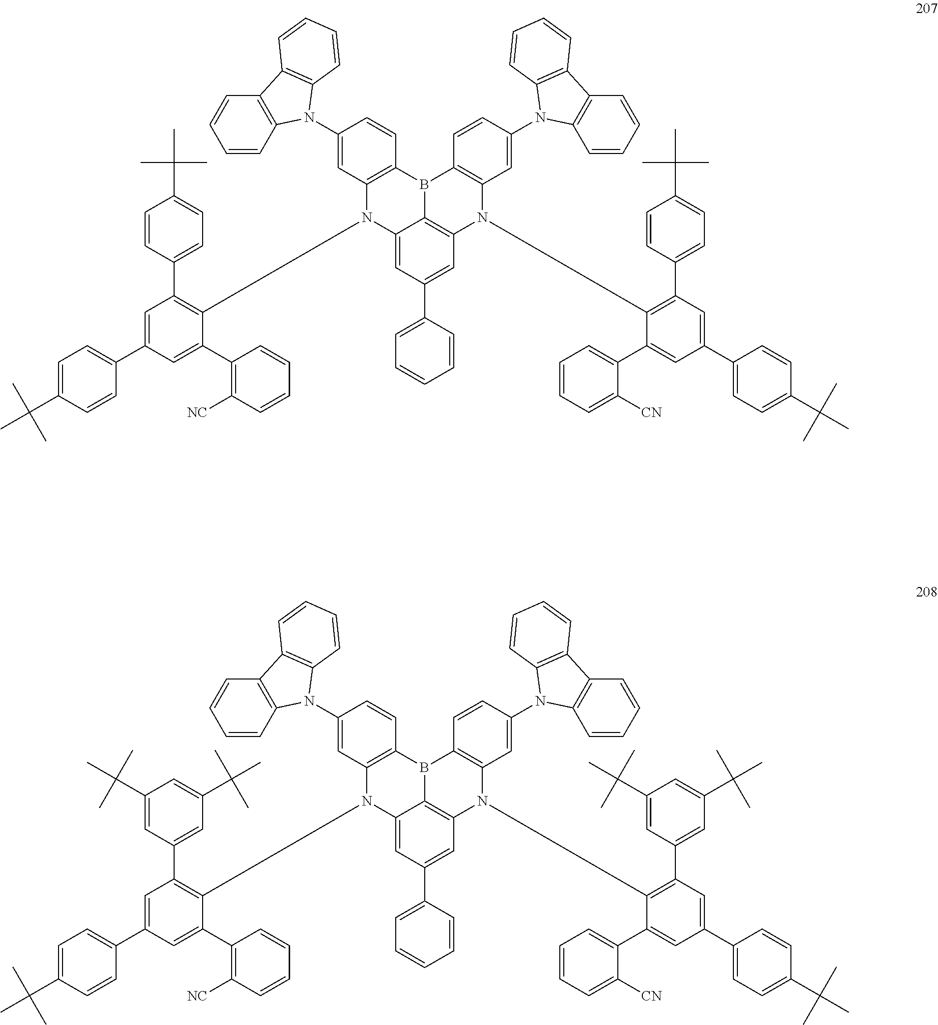

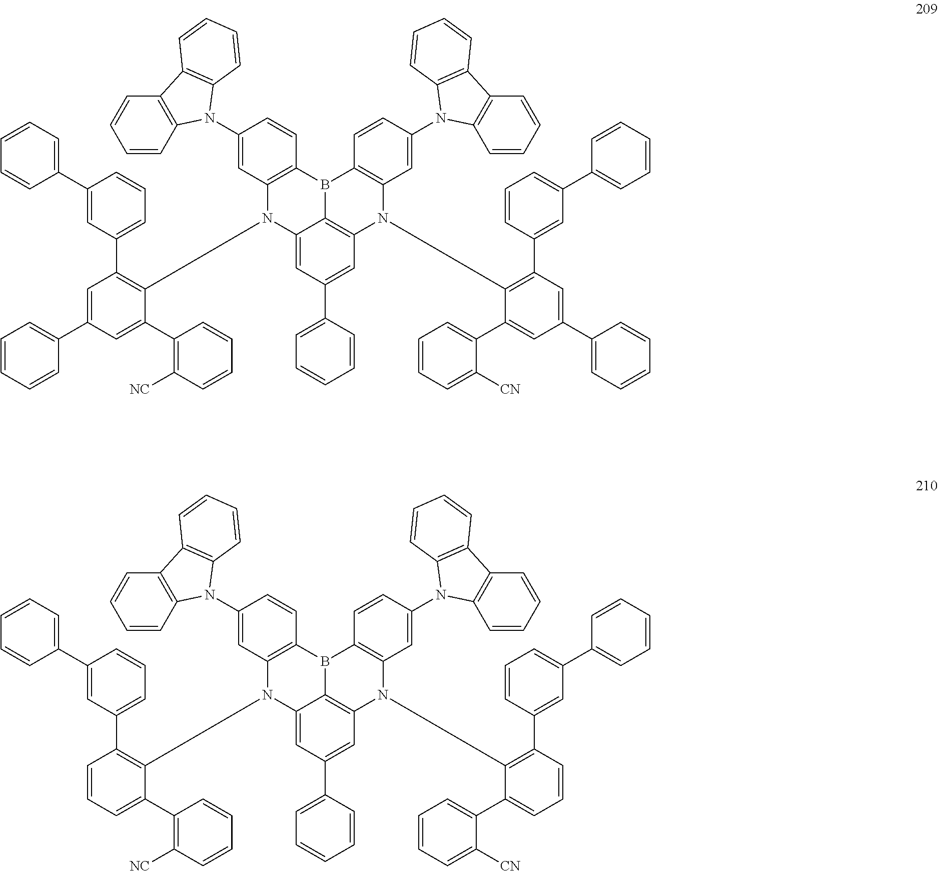

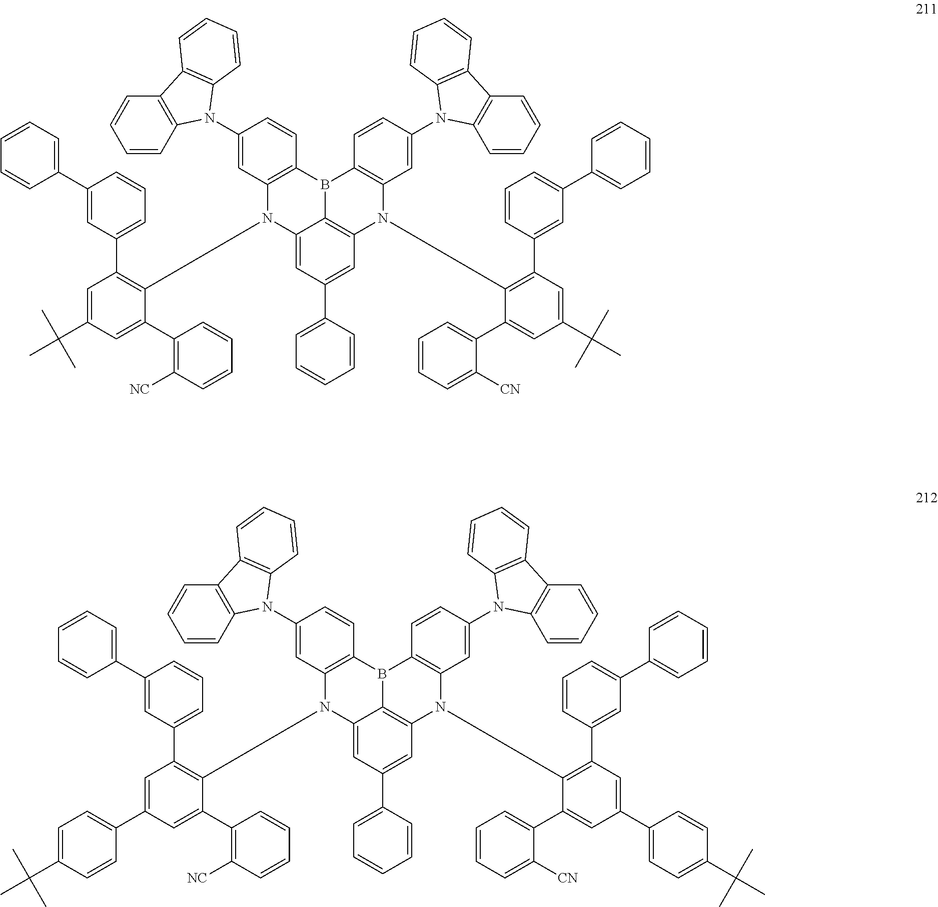

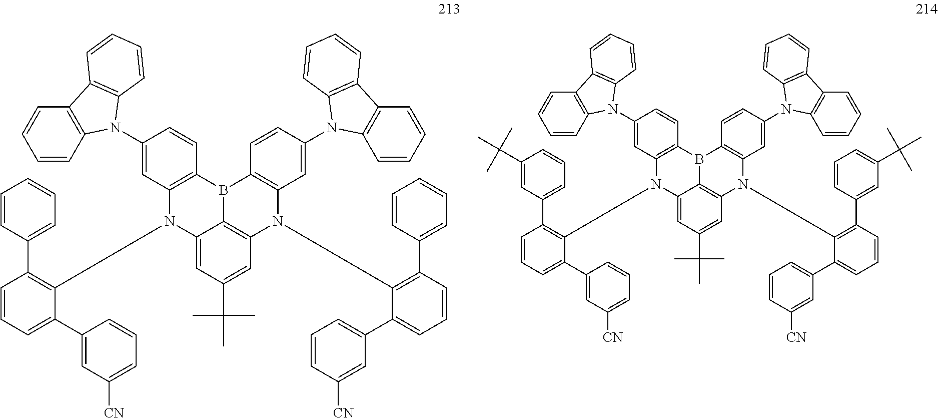

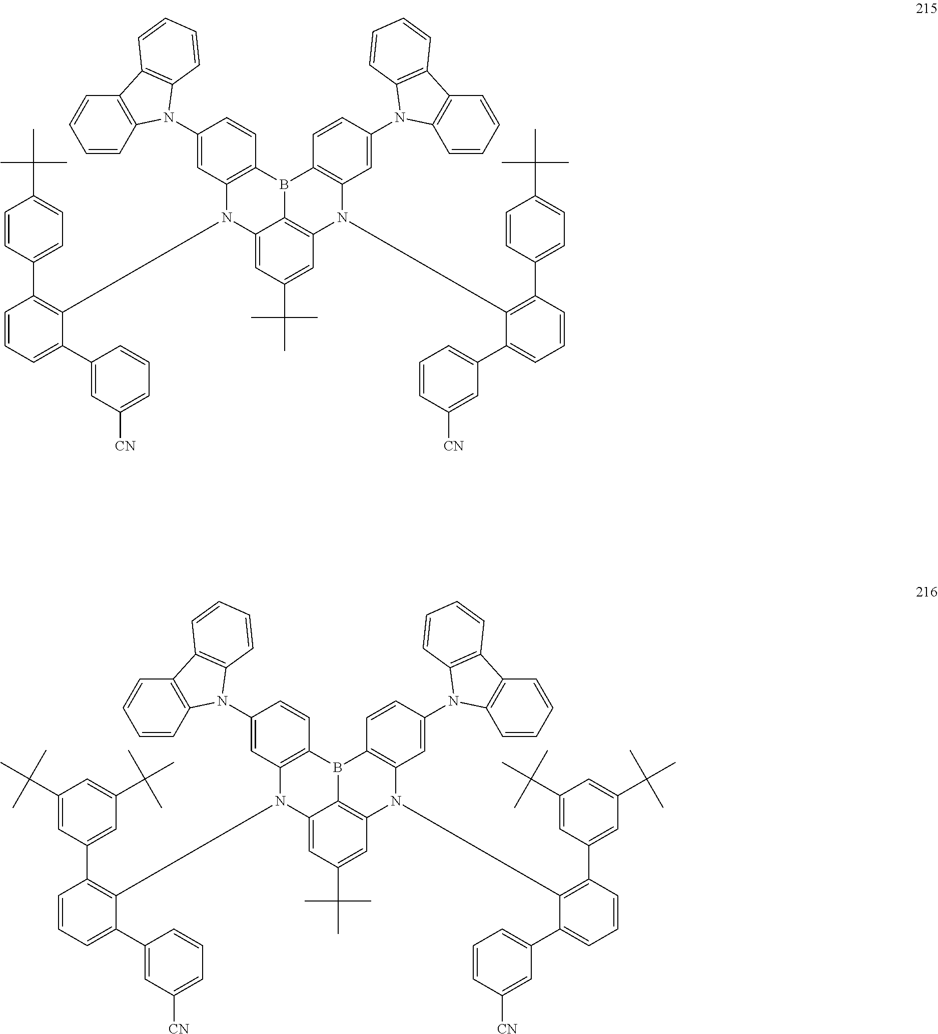

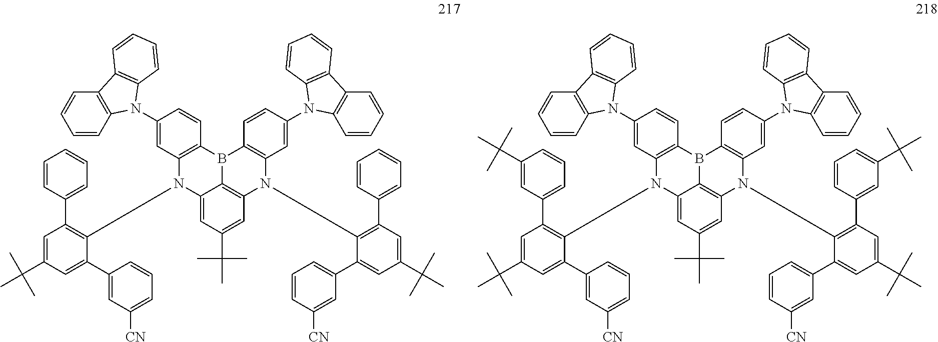

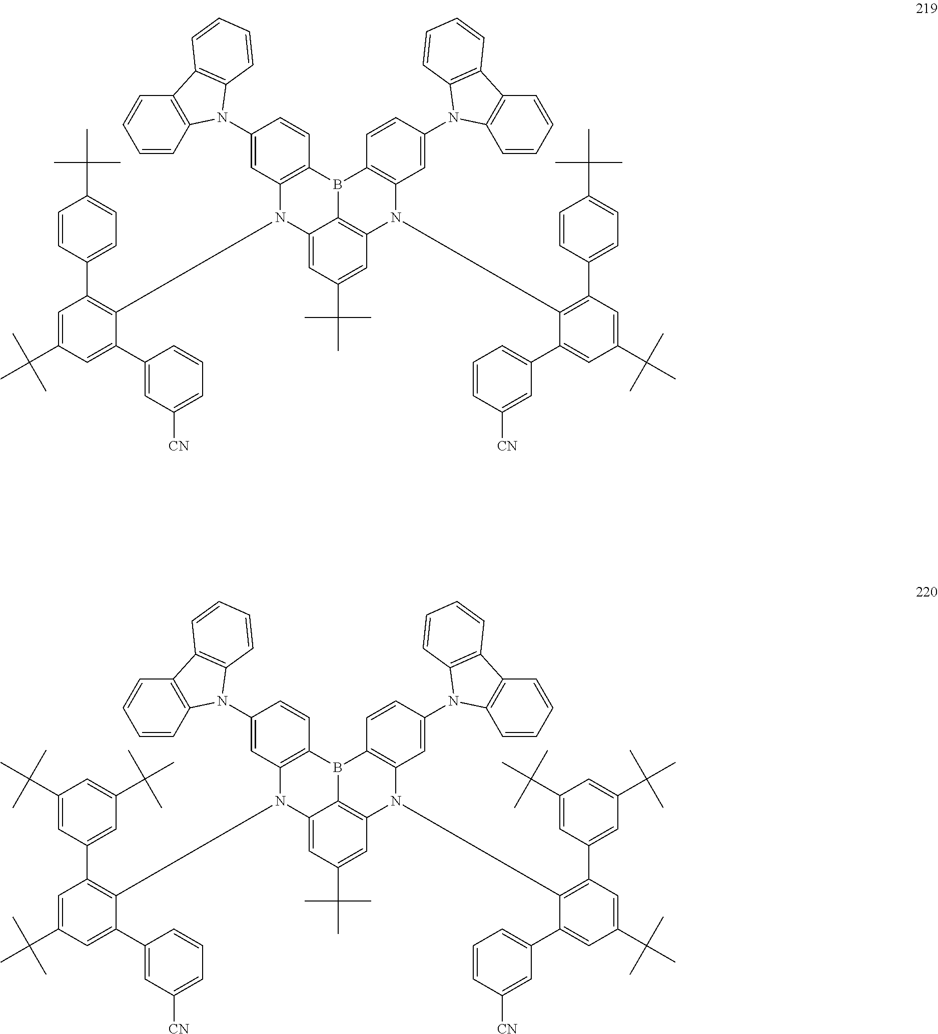

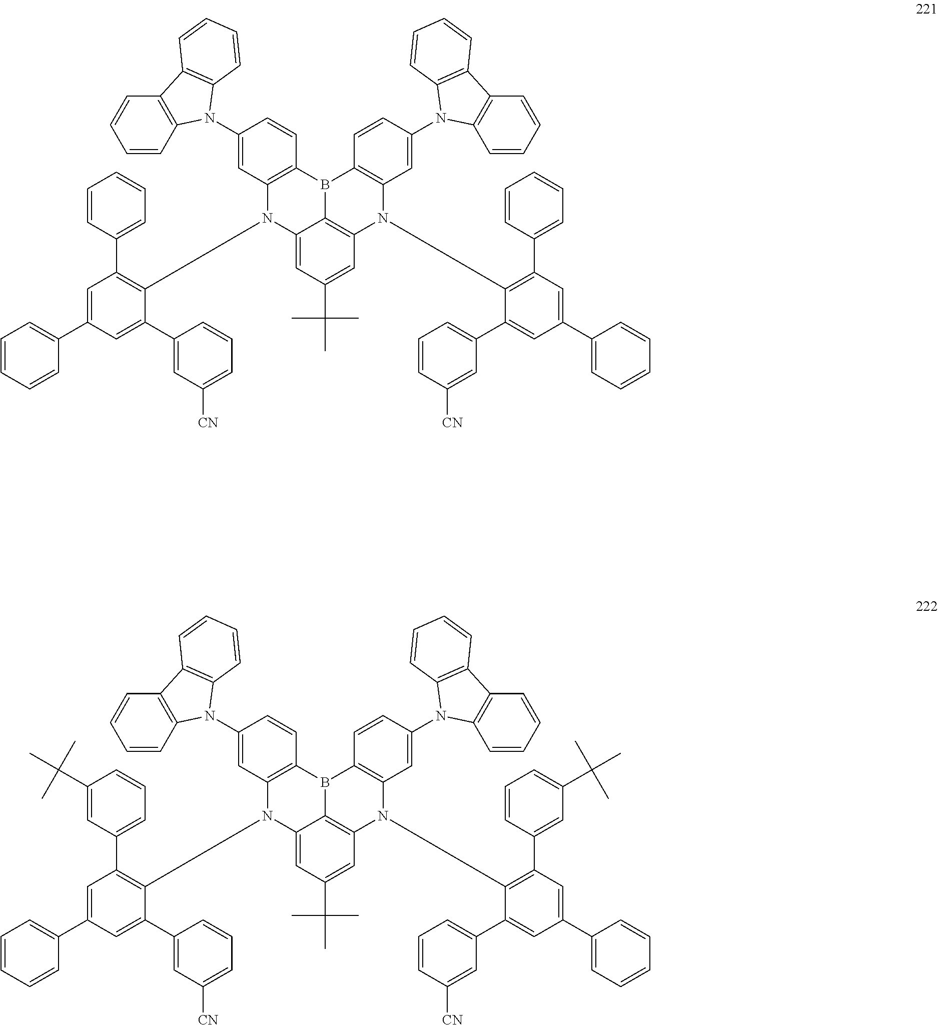

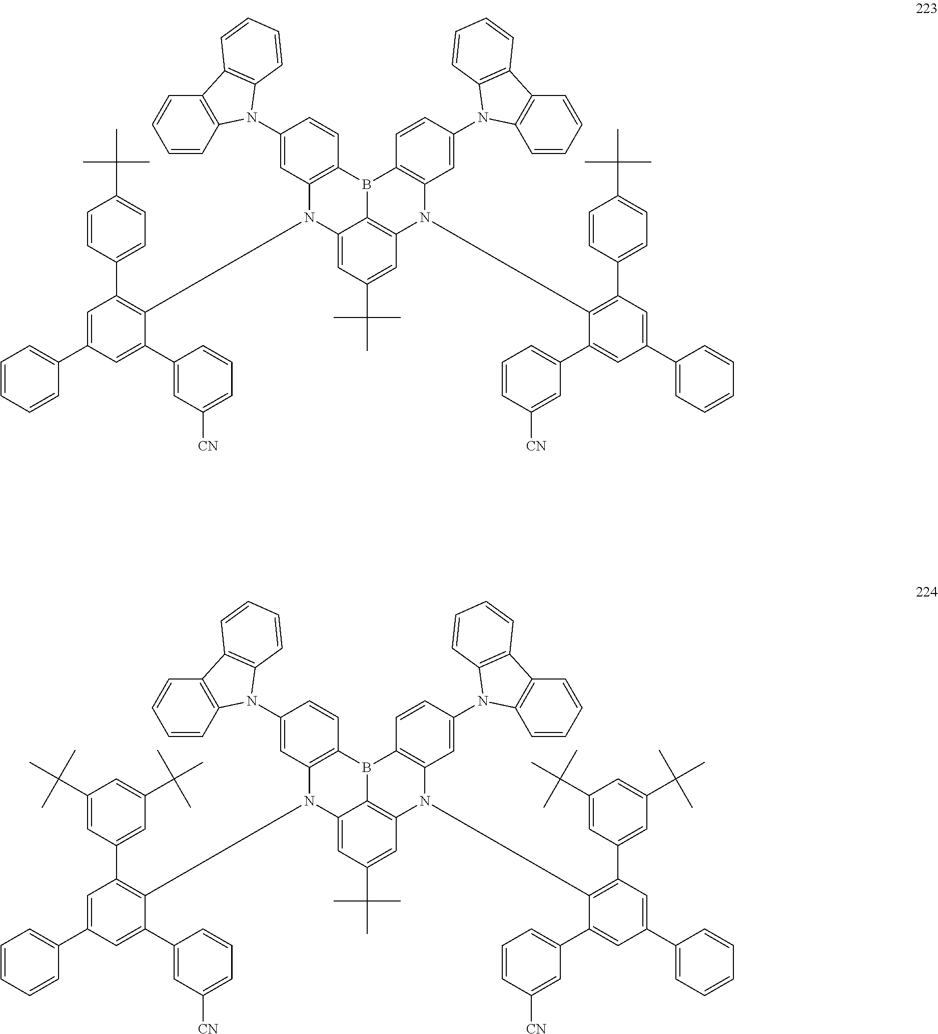 [SMILES: CC(C)(C)c1ccc(-c2cc(-c3ccccc3)cc(-c3cccc(C#N)c3)c2N2c3cc(-n4c5ccccc5c5ccccc54)ccc3B3c4ccc(-n5c6ccccc6c6ccccc65)cc4N(c4c(-c5ccc(C(C)(C)C)cc5)cc(-c5ccccc5)cc4-c4cccc(C#N)c4)c4cc(C(C)(C)C)cc2c43)cc1 ; CC(C)(C)c1cc(-c2cc(-c3ccccc3)cc(-c3cccc(C#N)c3)c2N2c3cc(-n4c5ccccc5c5ccccc54)ccc3B3c4ccc(-n5c6ccccc6c6ccccc65)cc4N(c4c(-c5cccc(C#N)c5)cc(-c5ccccc5)cc4-c4cc(C(C)(C)C)cc(C(C)(C)C)c4)c4cc(C(C)(C)C)cc2c43)cc(C(C)(C)C)c1]

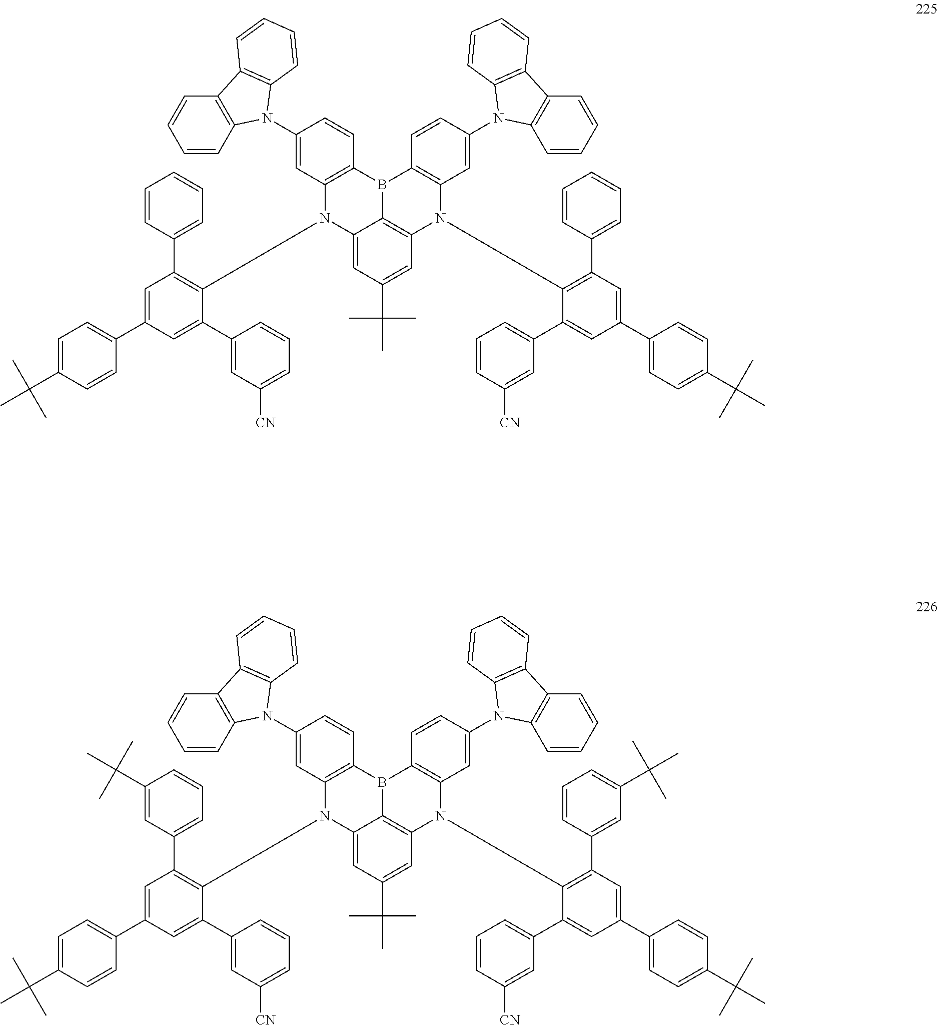

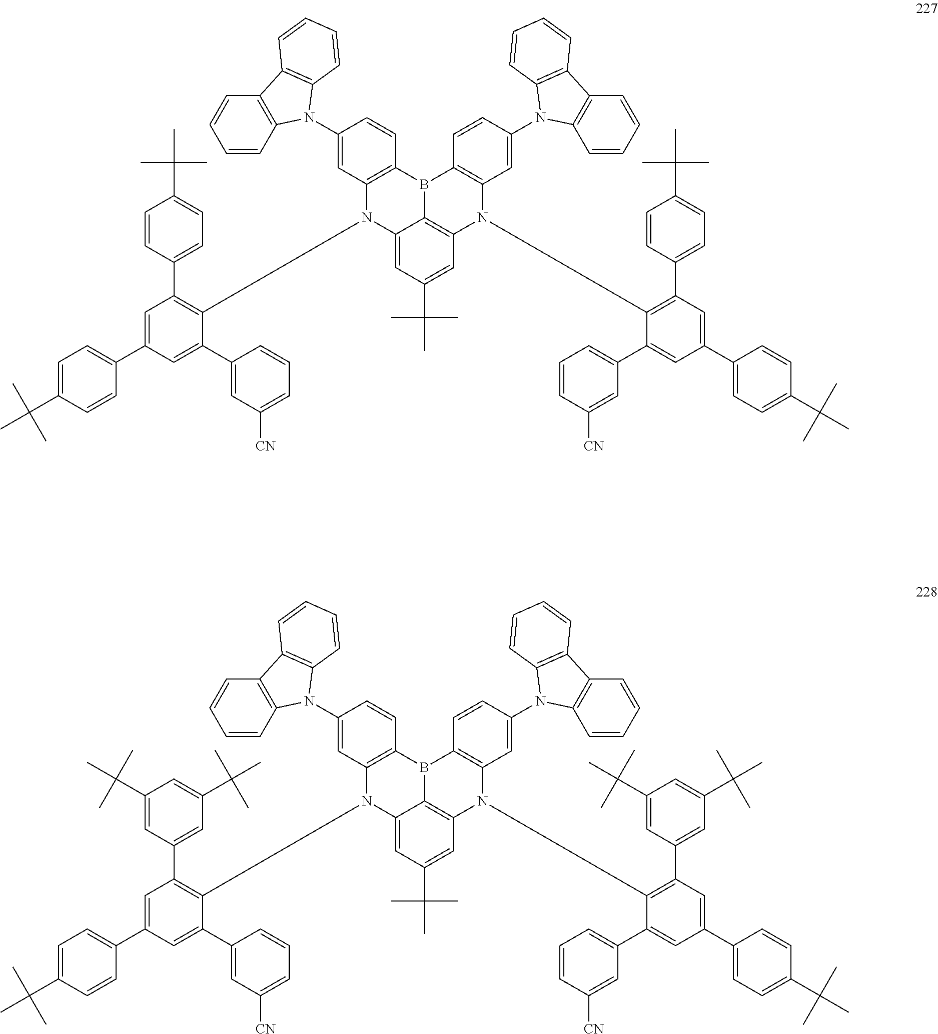

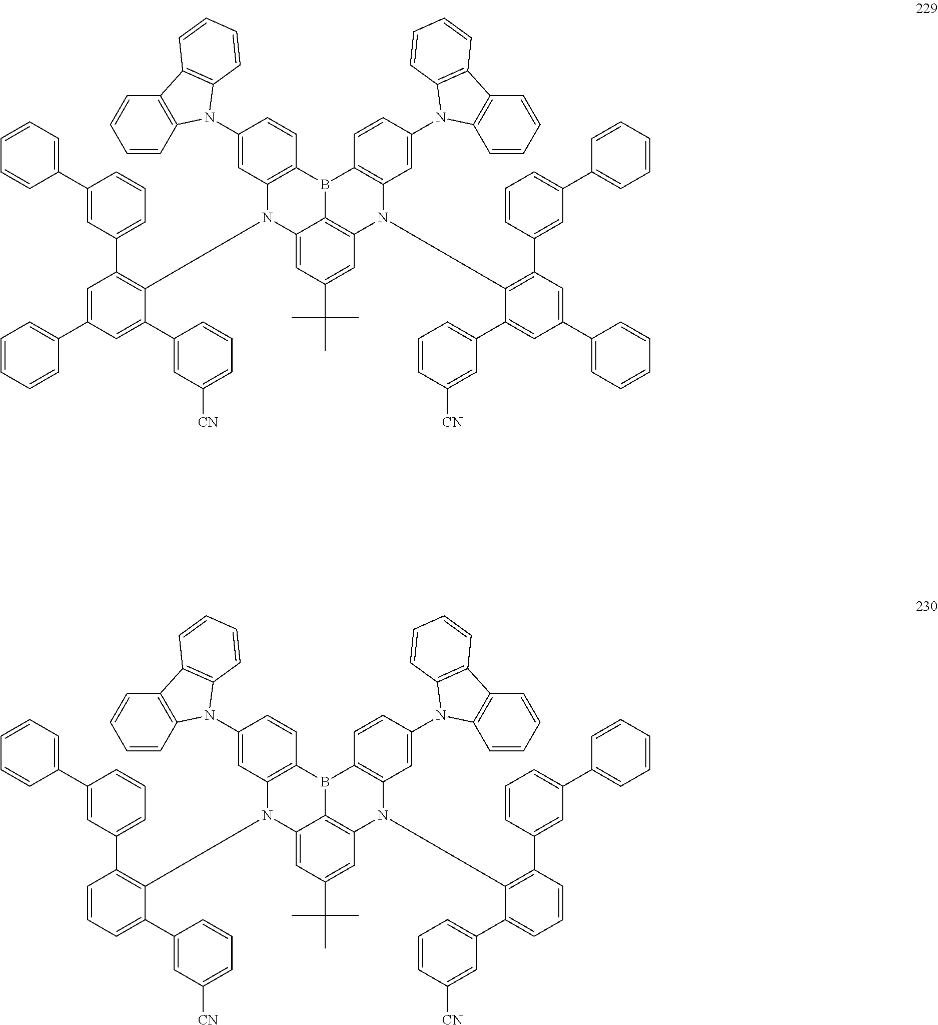 [SMILES: CC(C)(C)c1cc2c3c(c1)N(c1c(-c4cccc(C#N)c4)cc(-c4ccccc4)cc1-c1cccc(-c4ccccc4)c1)c1cc(-n4c5ccccc5c5ccccc54)ccc1B3c1ccc(-n3c4ccccc4c4ccccc43)cc1N2c1c(-c2cccc(C#N)c2)cc(-c2ccccc2)cc1-c1cccc(-c2ccccc2)c1 ; CC(C)(C)c1cc2c3c(c1)N(c1c(-c4cccc(C#N)c4)cccc1-c1cccc(-c4ccccc4)c1)c1cc(-n4c5ccccc5c5ccccc54)ccc1B3c1ccc(-n3c4ccccc4c4ccccc43)cc1N2c1c(-c2cccc(C#N)c2)cccc1-c1cccc(-c2ccccc2)c1]

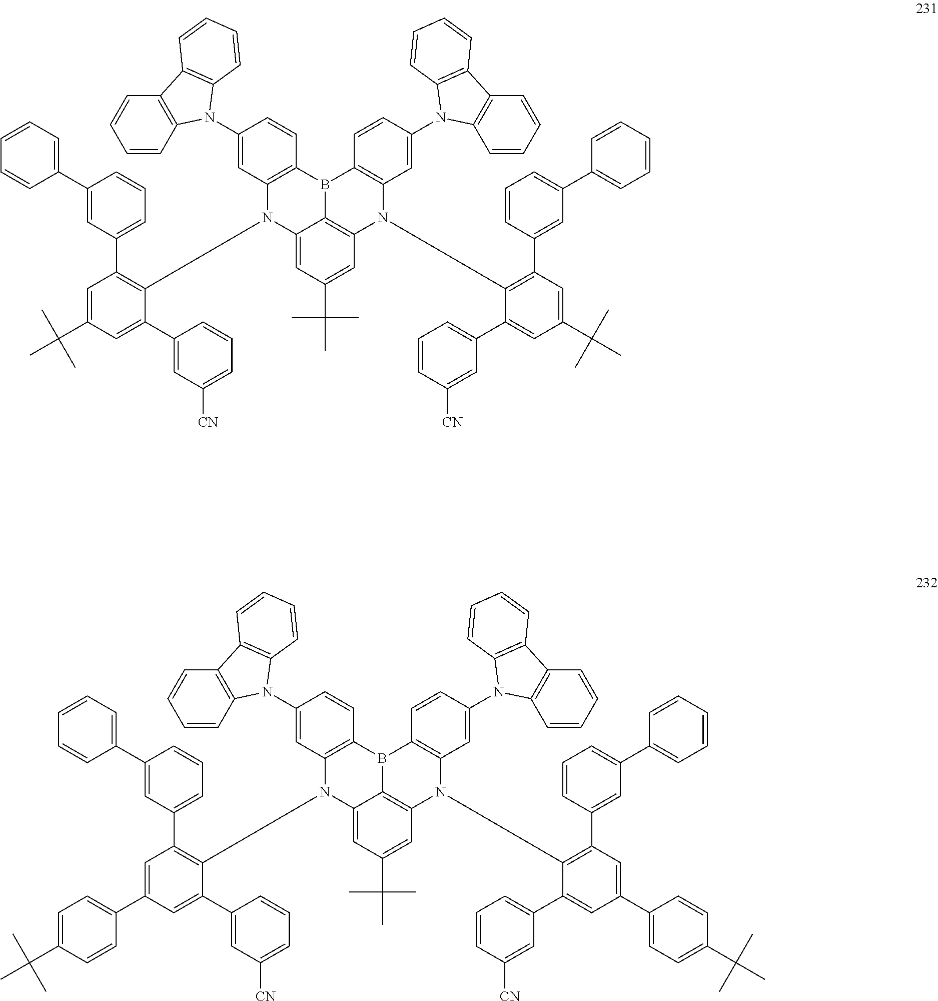 [SMILES: CC(C)(C)c1cc(-c2cccc(C#N)c2)c(N2c3cc(-n4c5ccccc5c5ccccc54)ccc3B3c4ccc(-n5c6ccccc6c6ccccc65)cc4N(c4c(-c5cccc(C#N)c5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1ccc(-c2cc(-c3cccc(C#N)c3)c(N3c4cc(-n5c6ccccc6c6ccccc65)ccc4B4c5ccc(-n6c7ccccc7c7ccccc76)cc5N(c5c(-c6cccc(C#N)c6)cc(-c6ccc(C(C)(C)C)cc6)cc5-c5cccc(-c6ccccc6)c5)c5cc(C(C)(C)C)cc3c54)c(-c3cccc(-c4ccccc4)c3)c2)cc1]

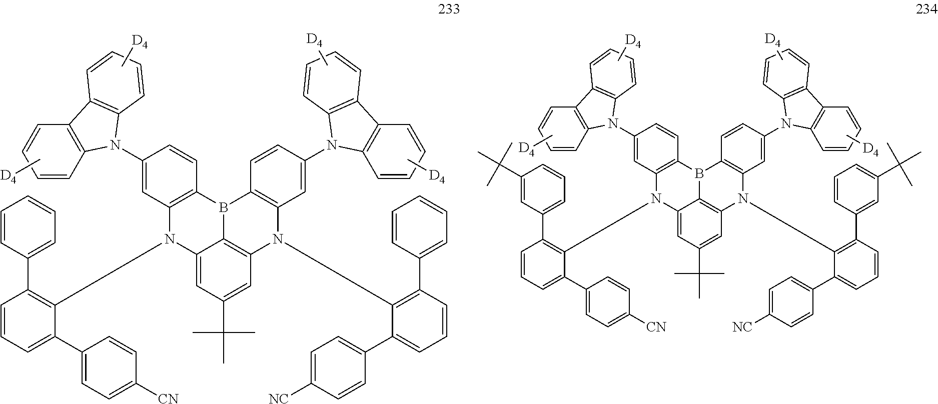

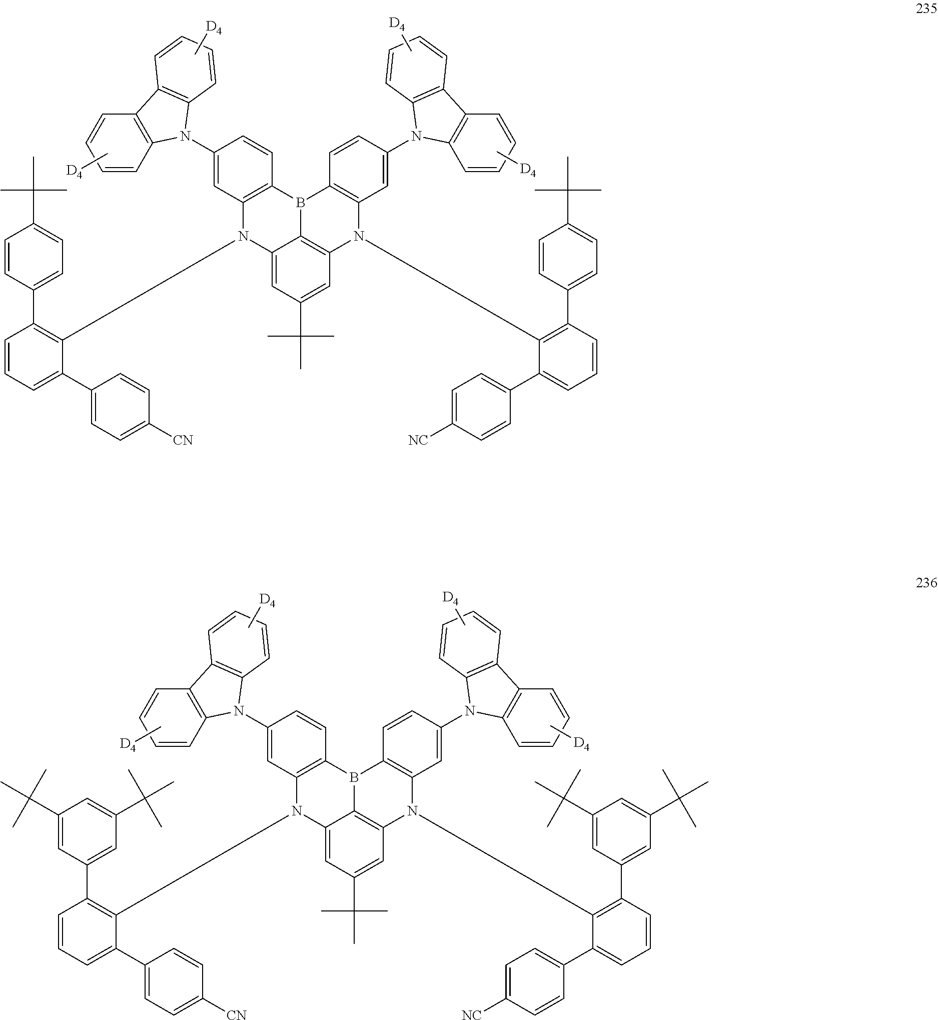

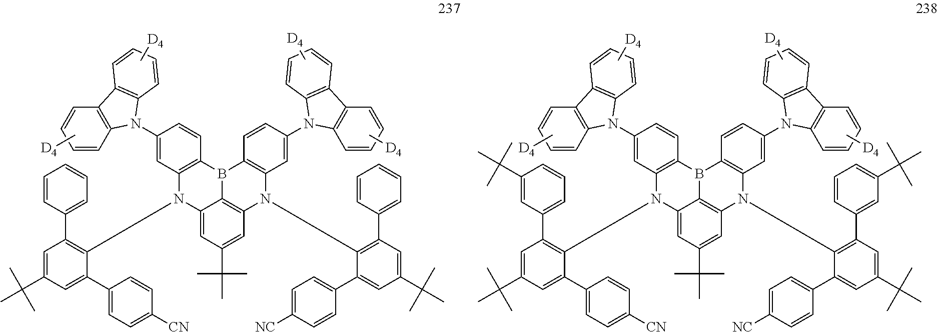

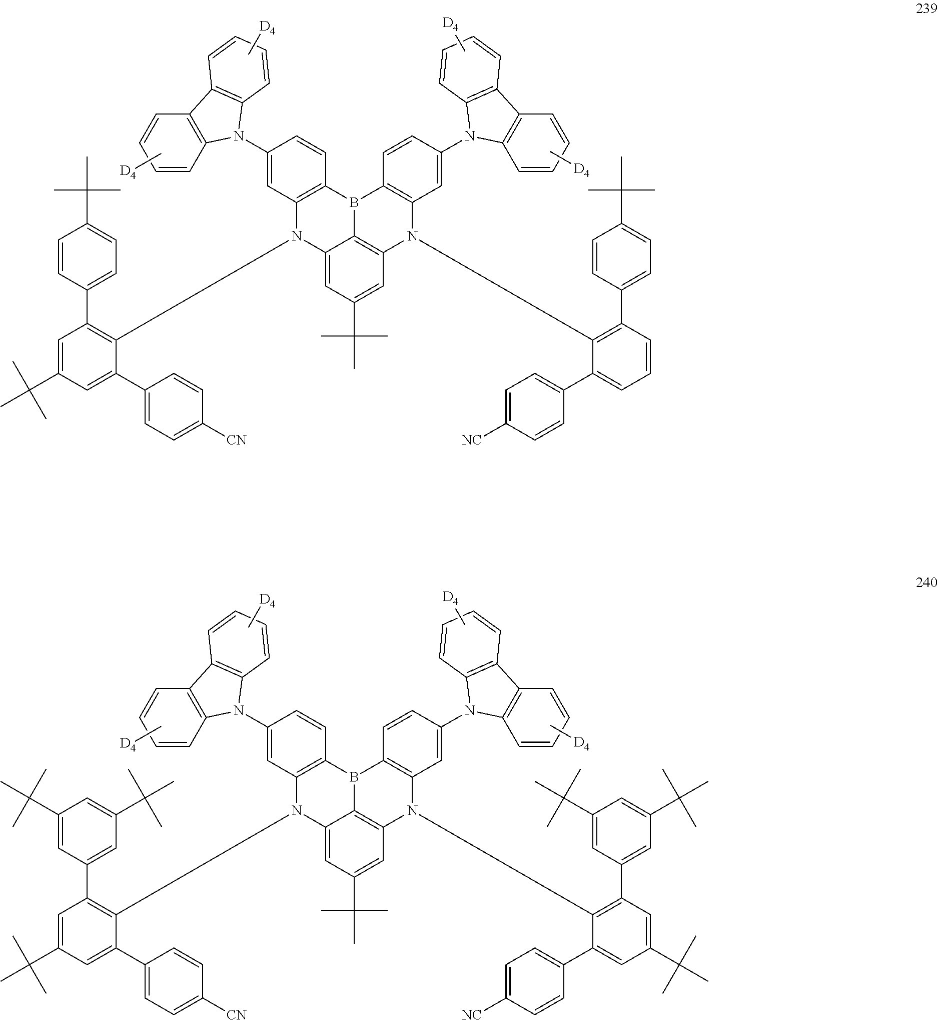

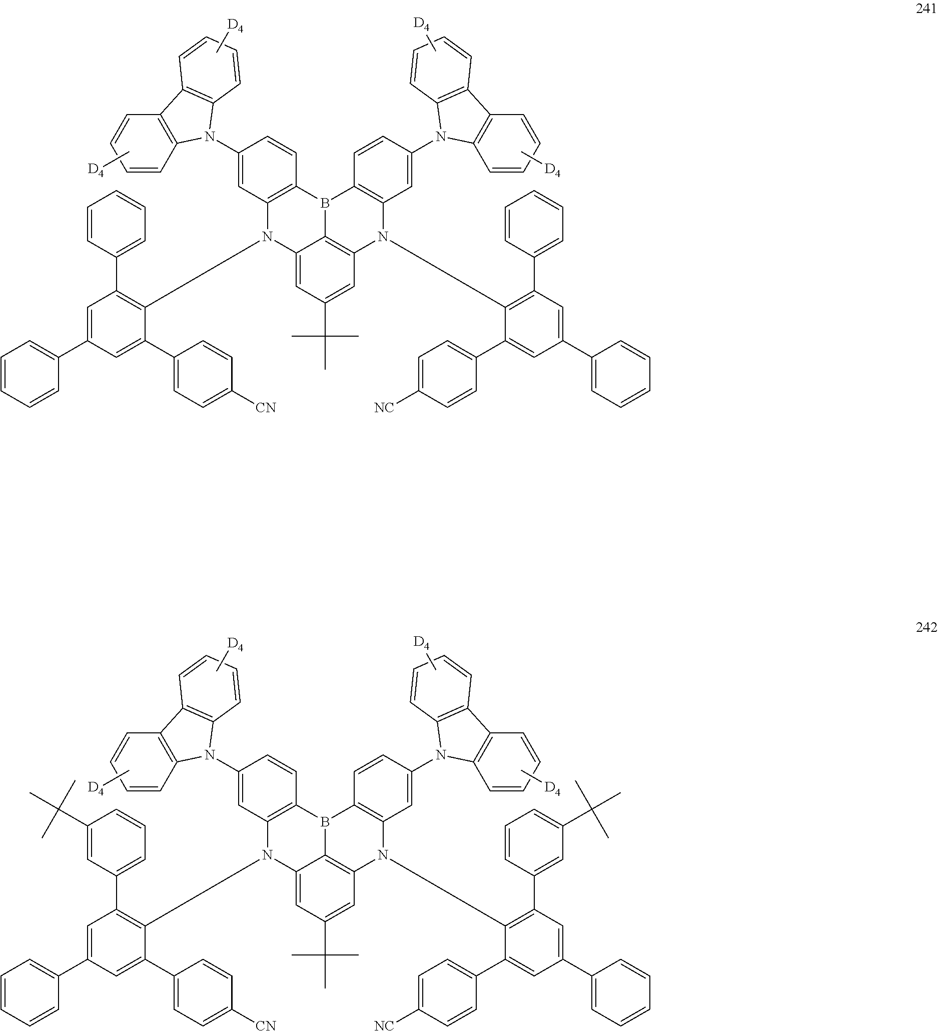

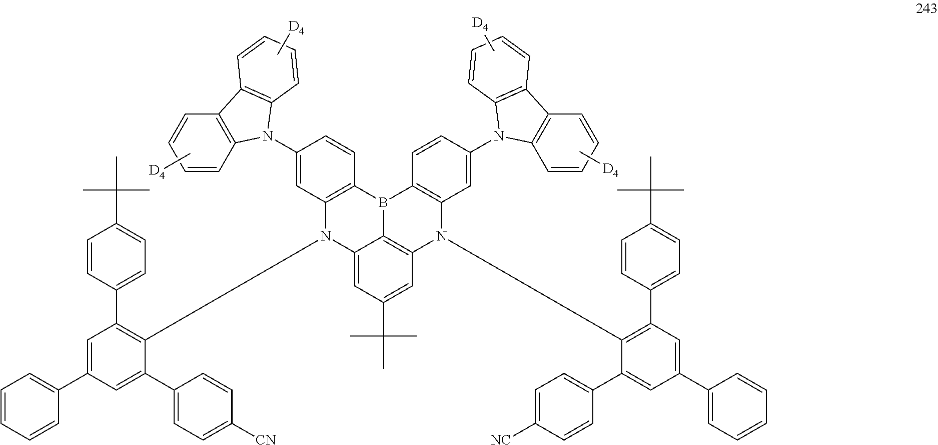

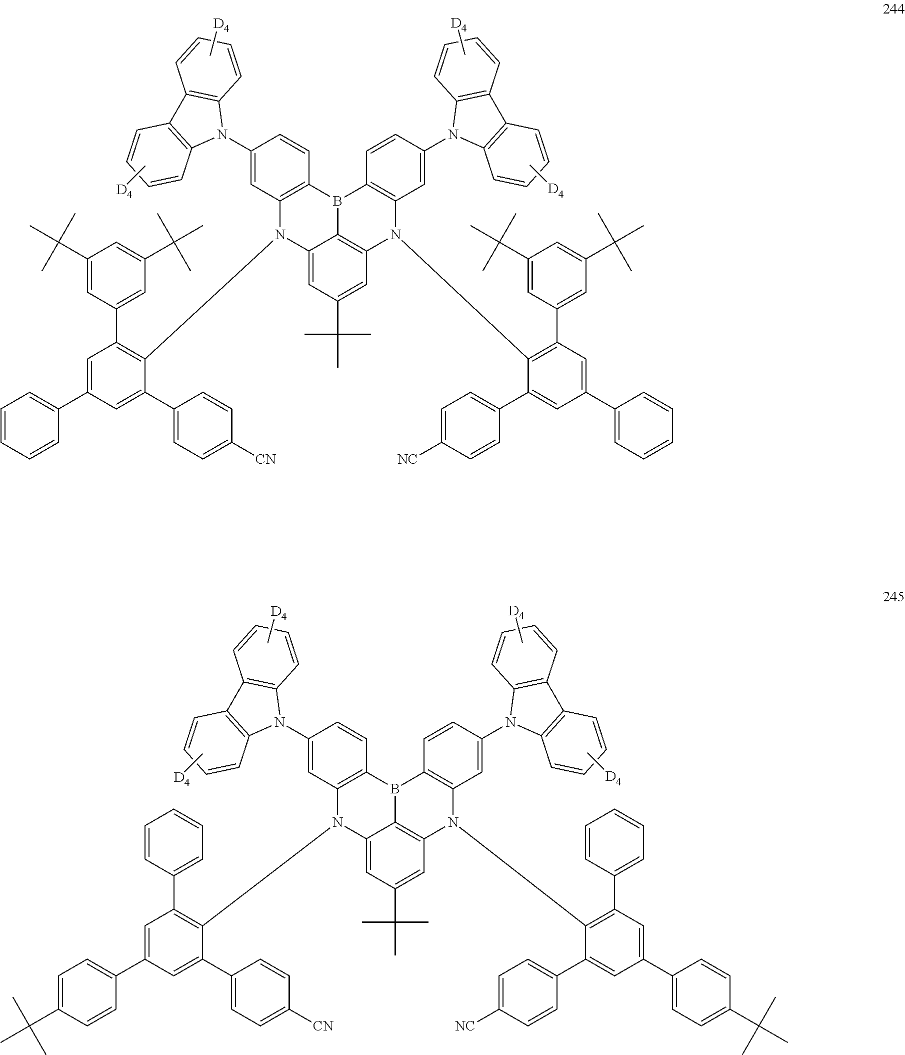

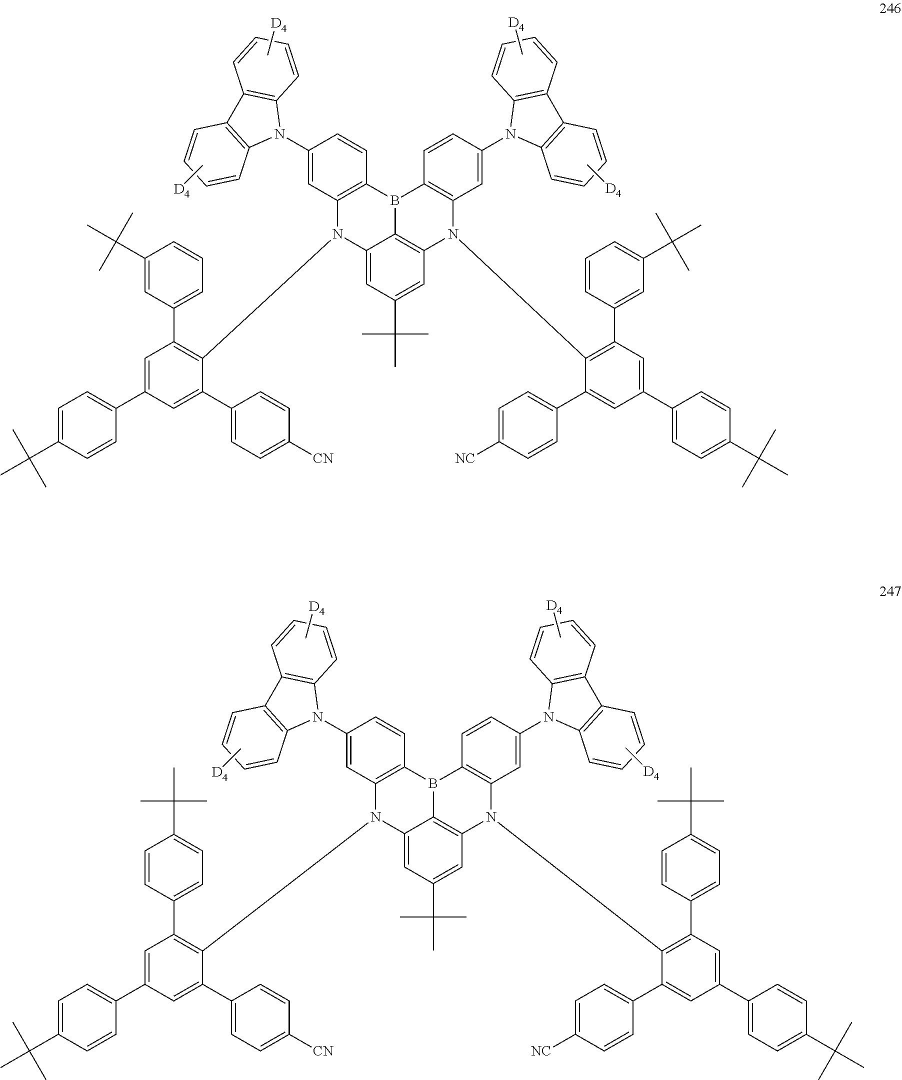

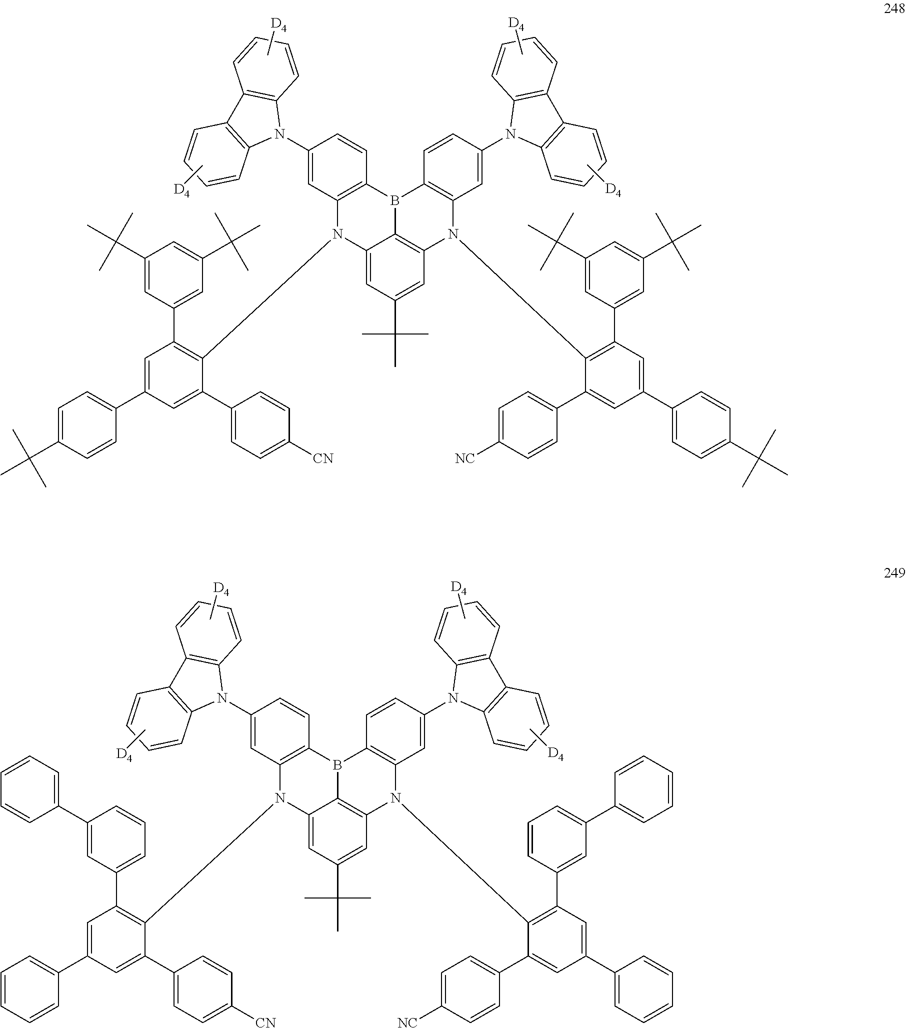

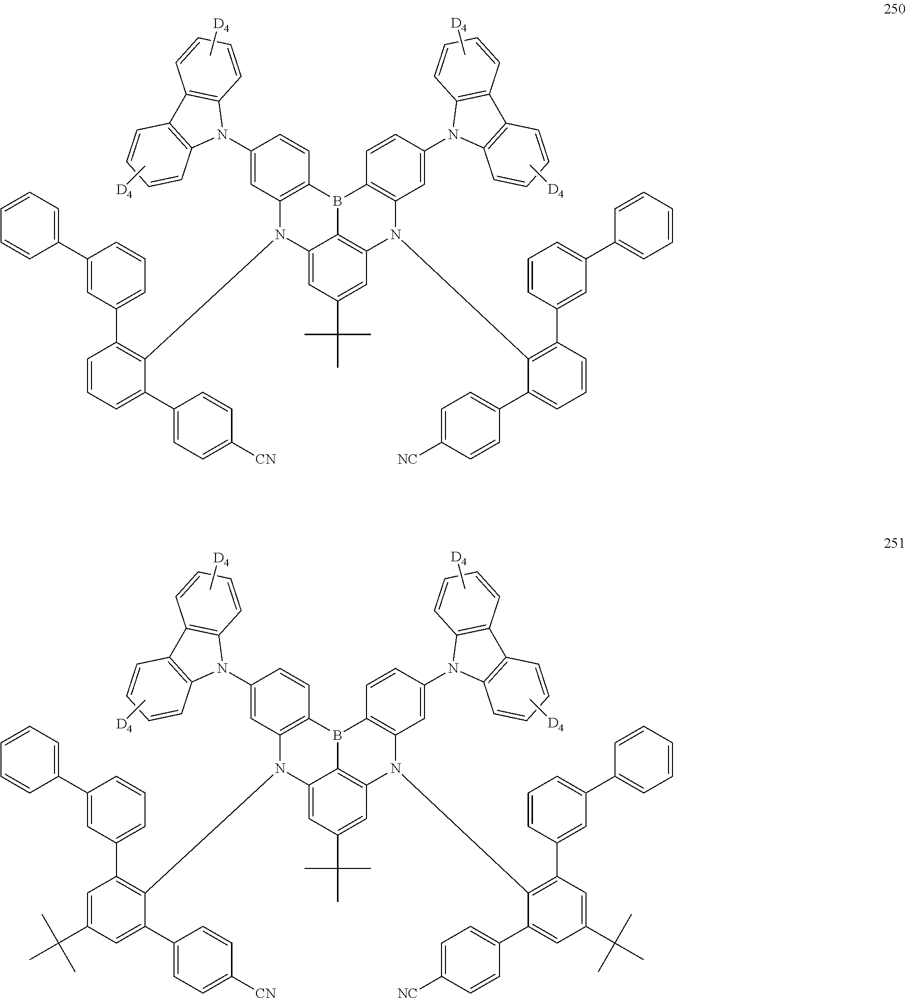

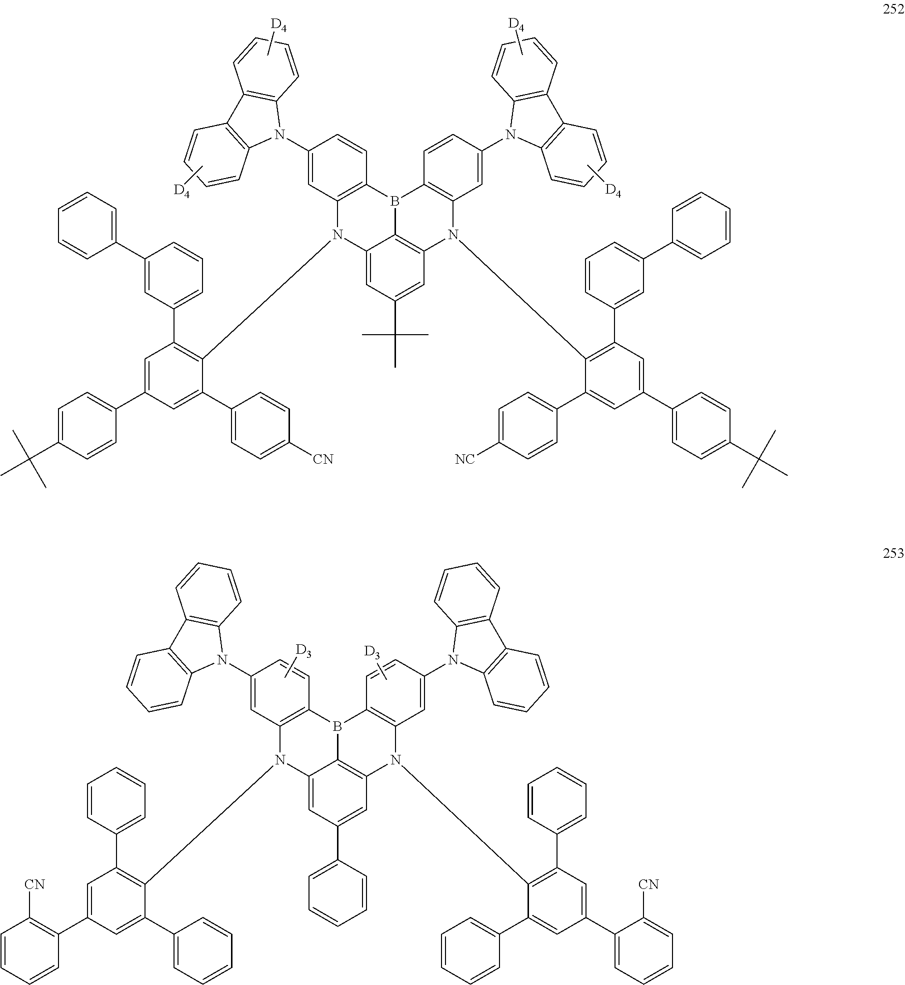

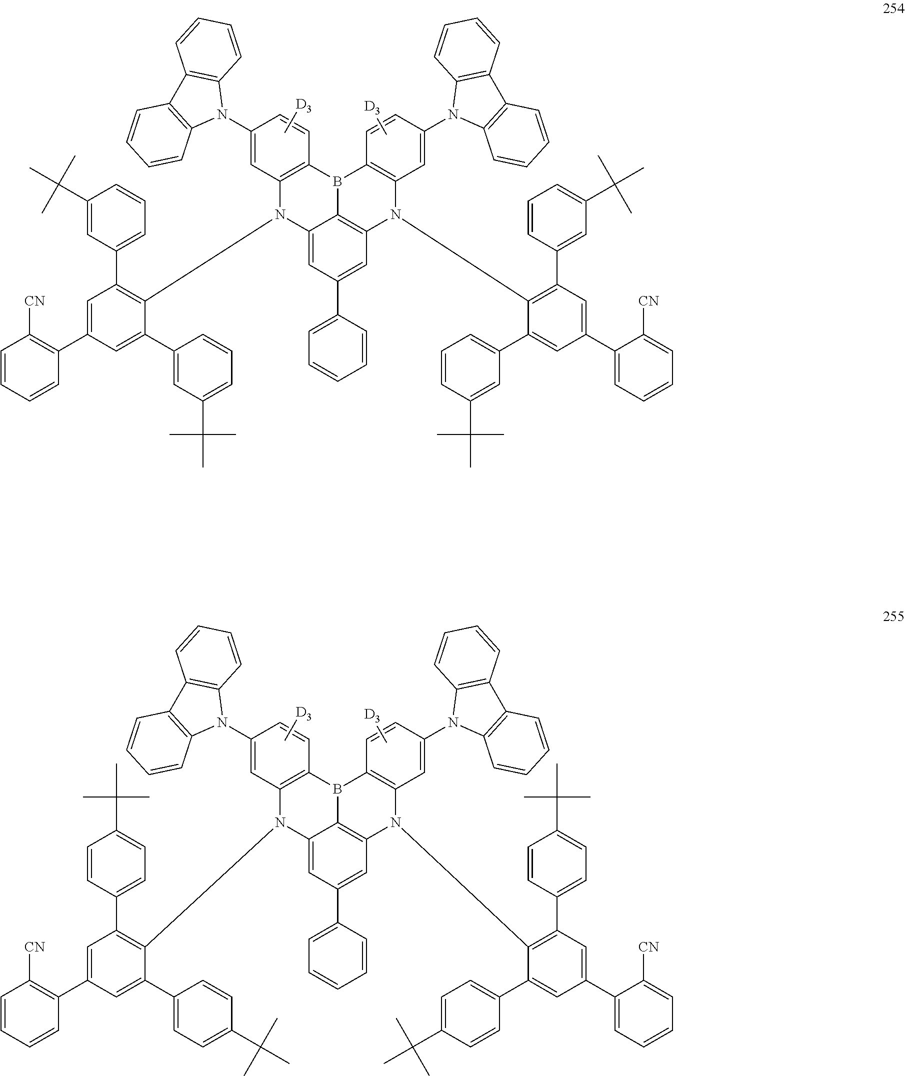

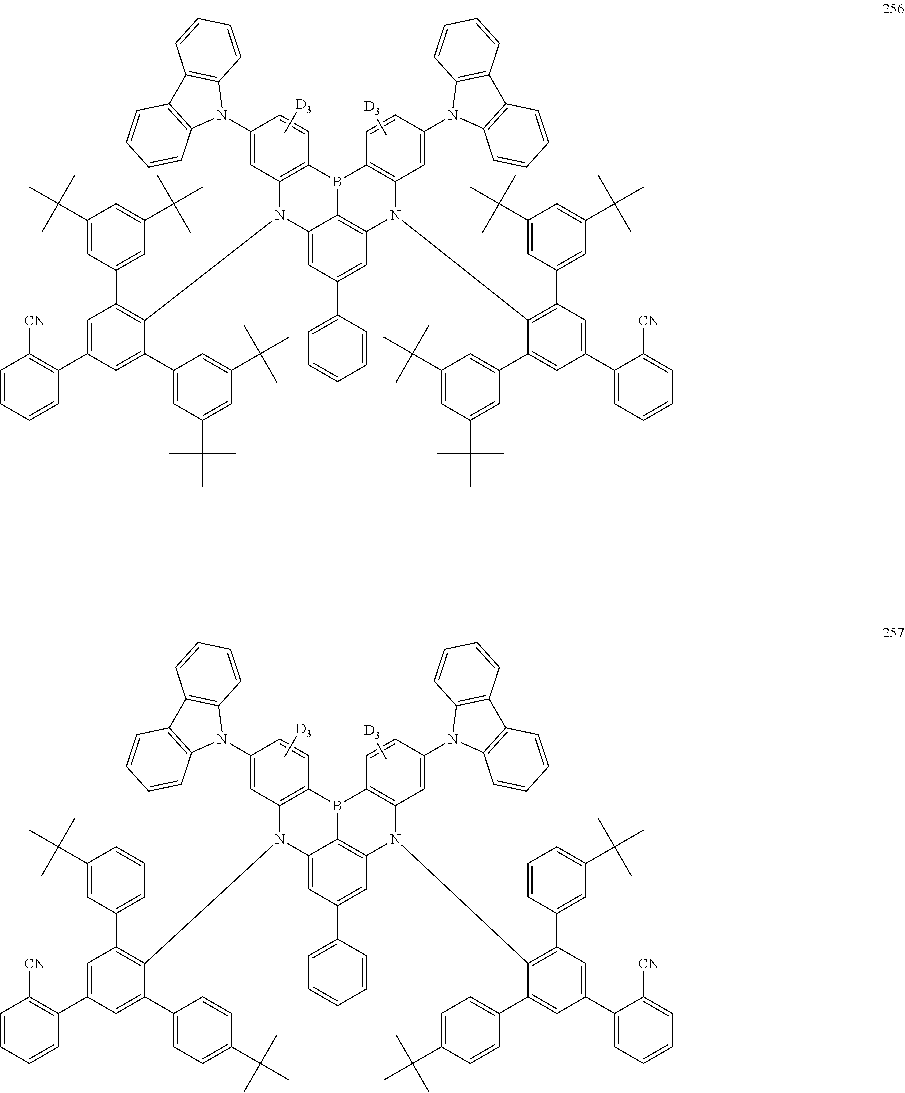

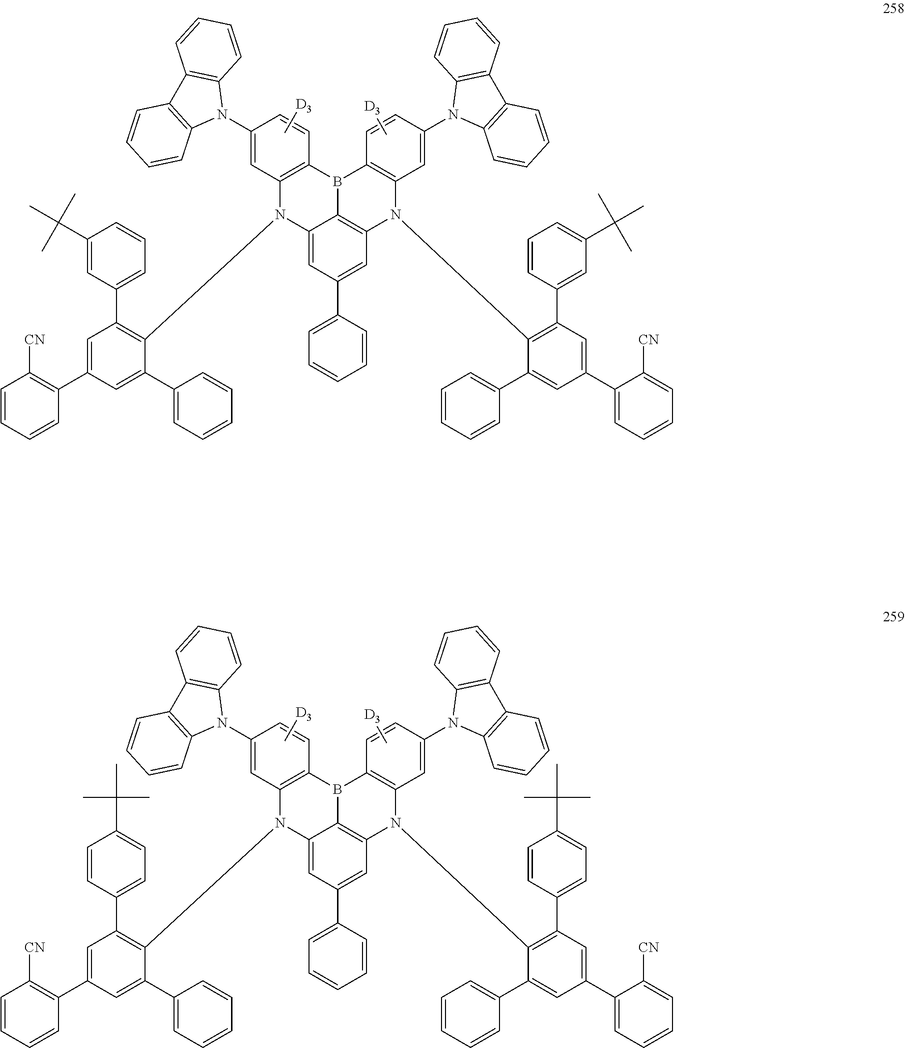

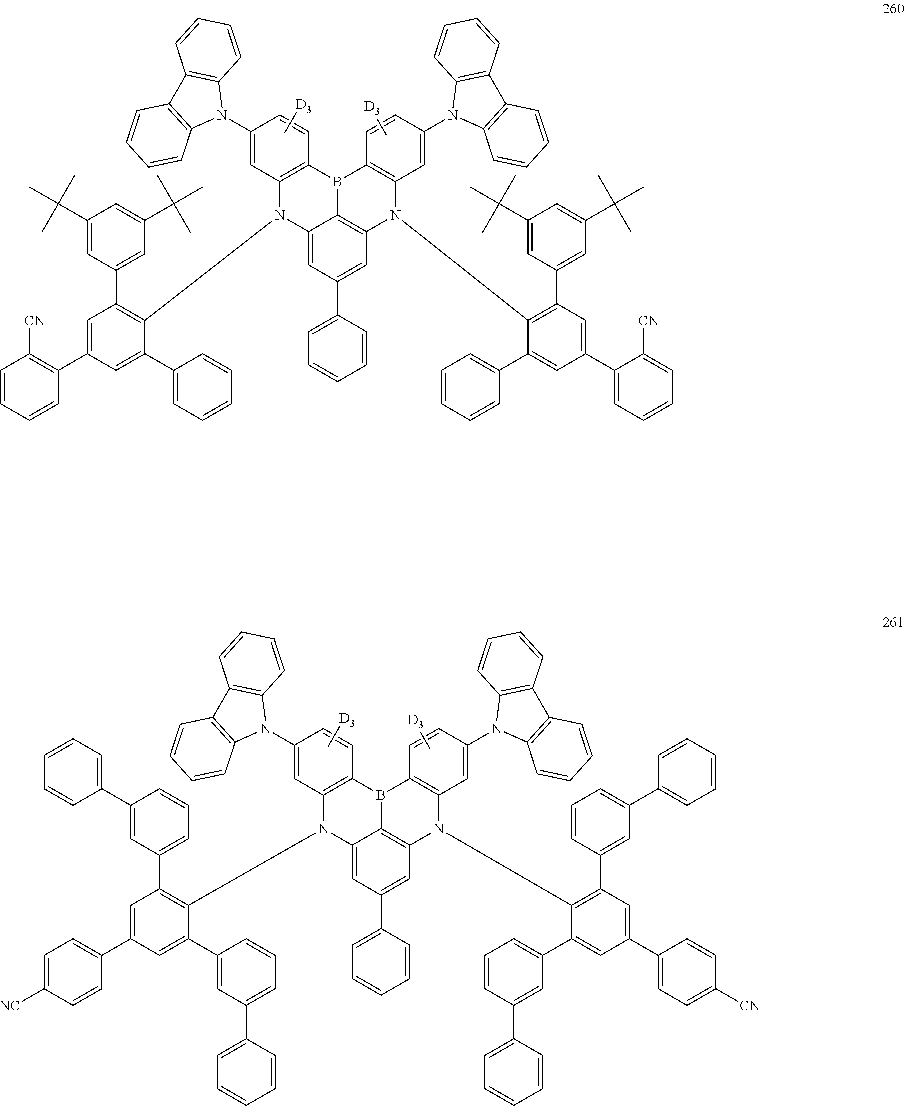

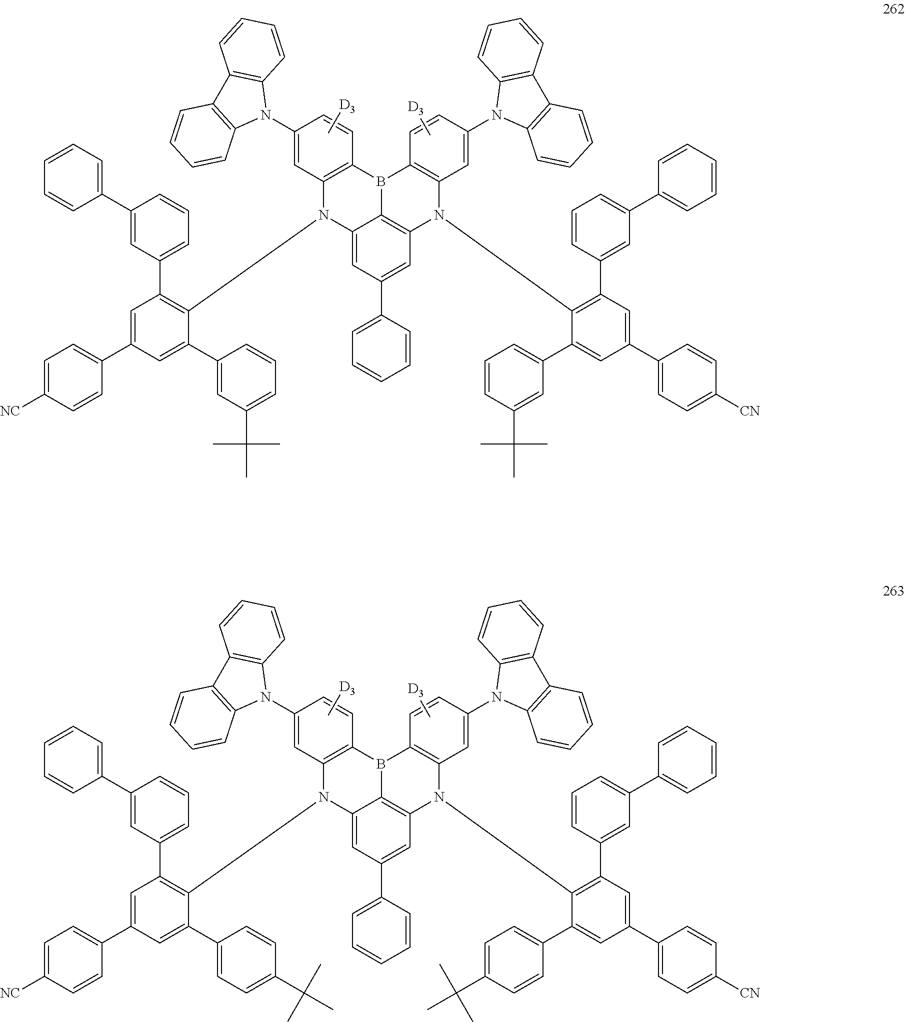

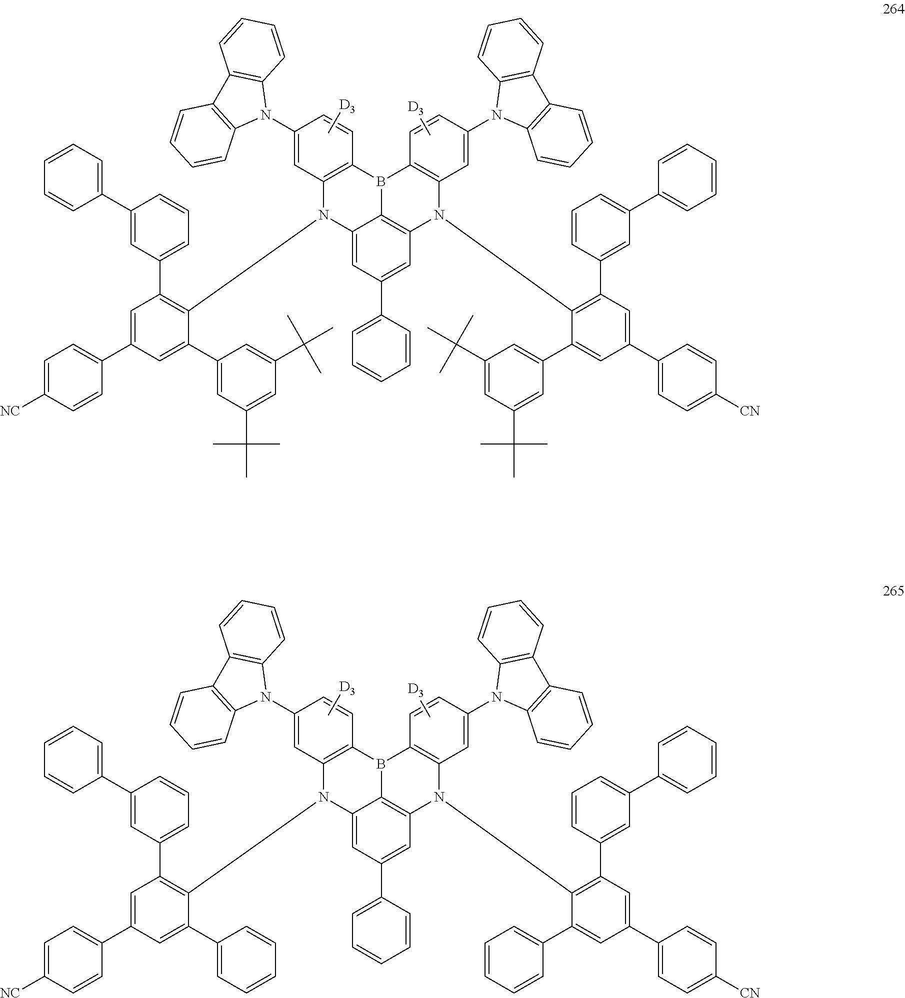

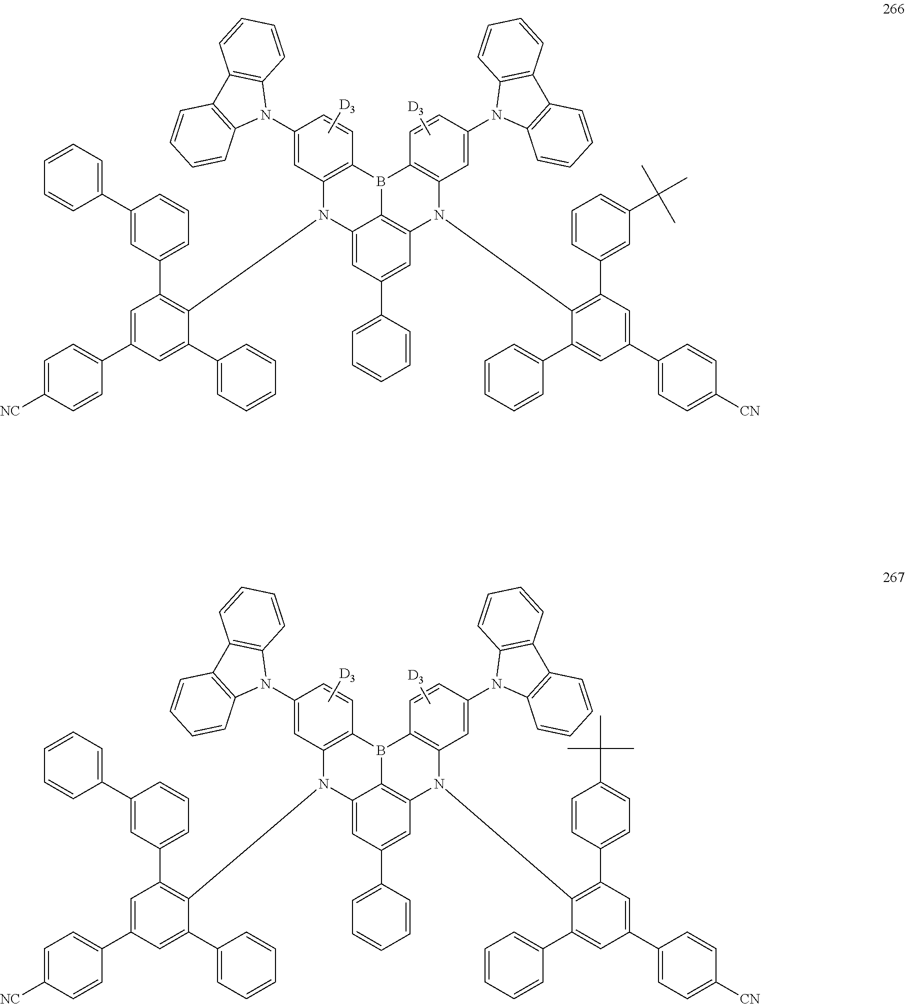

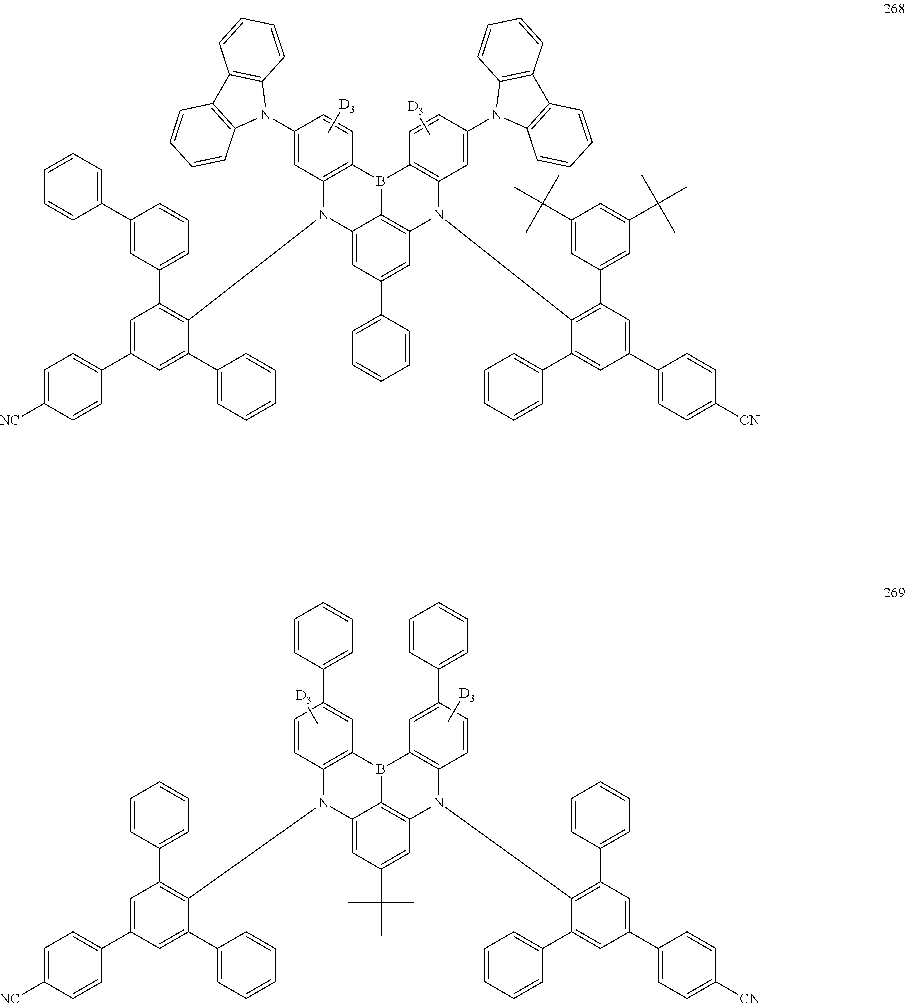

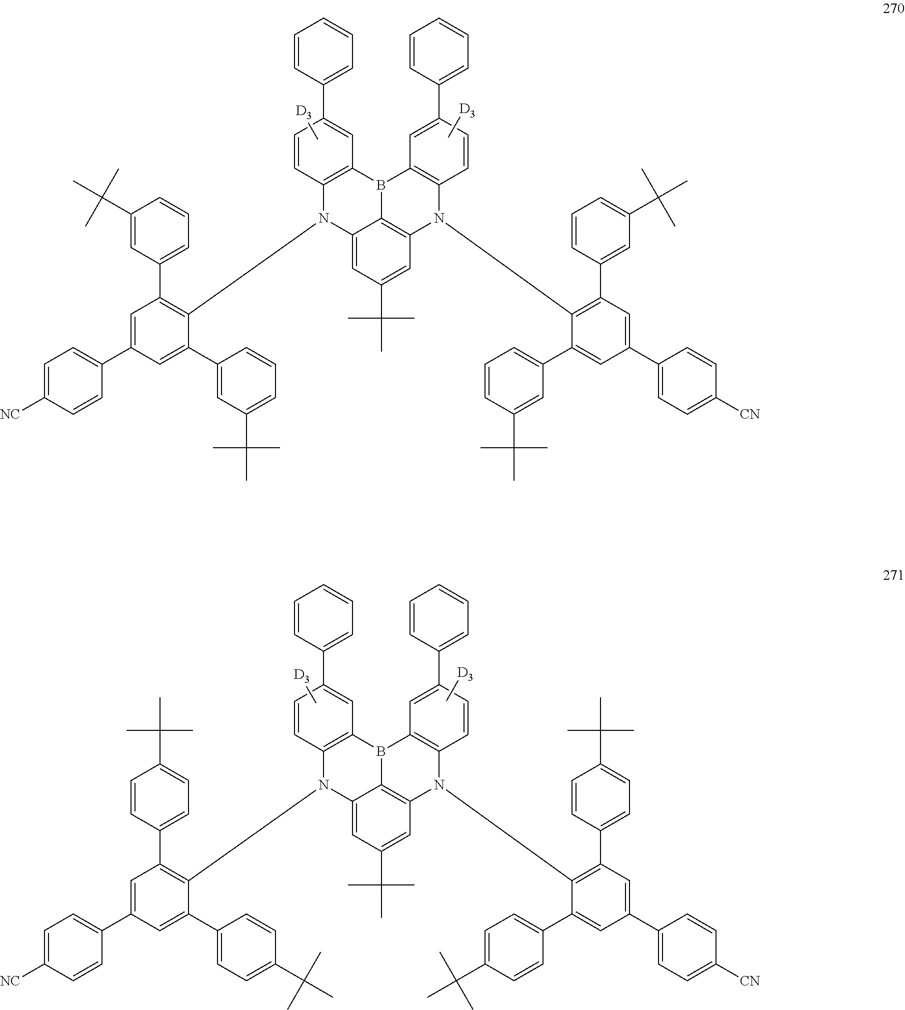

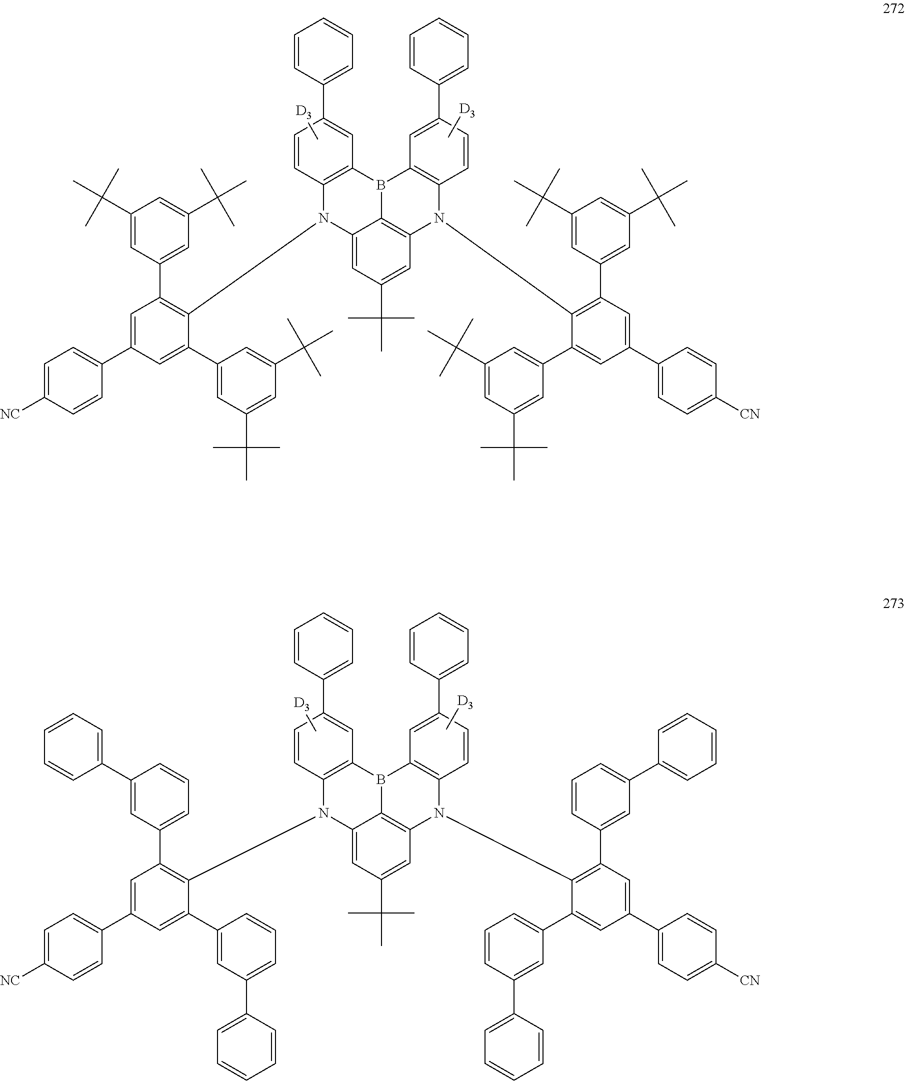

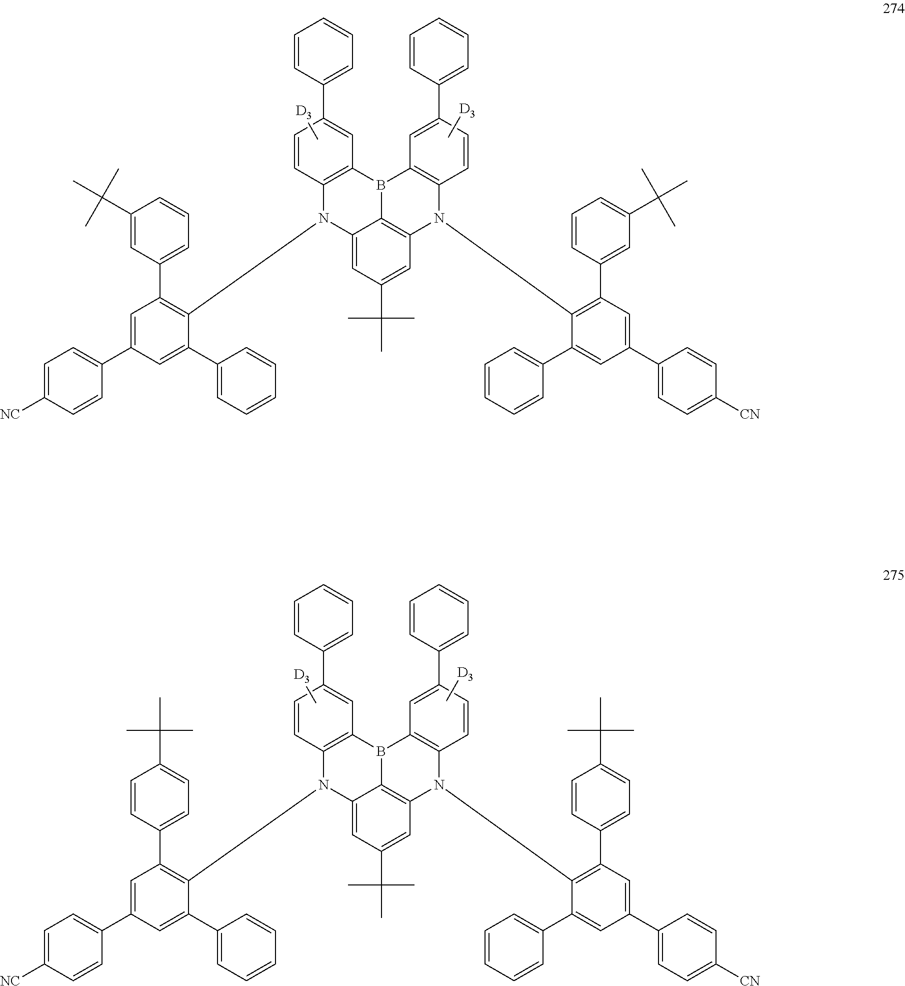

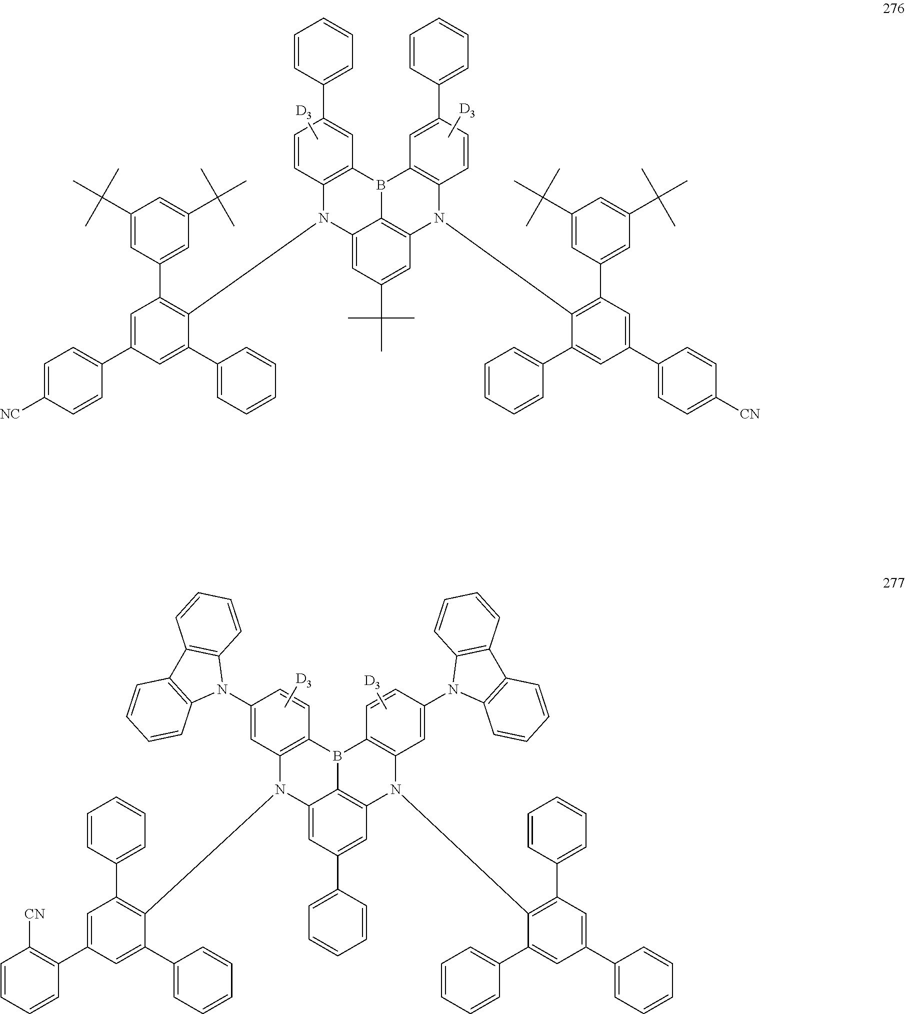

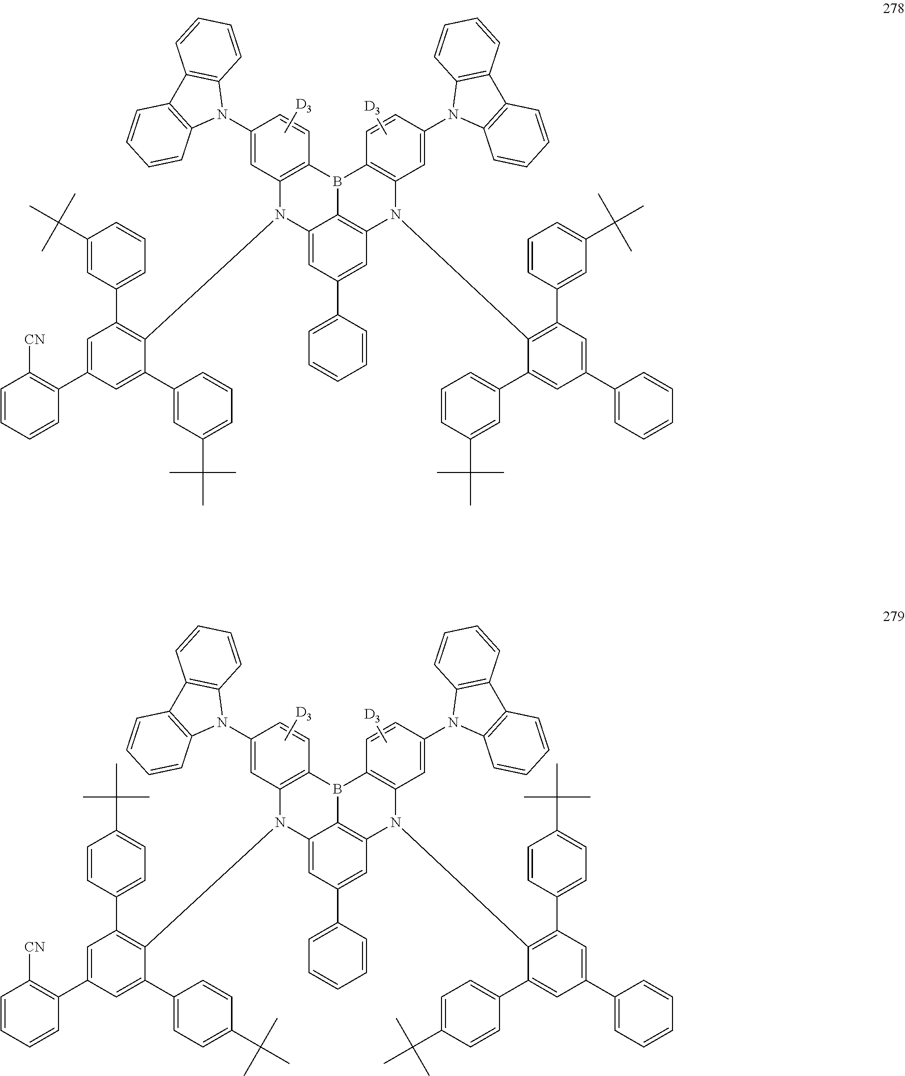

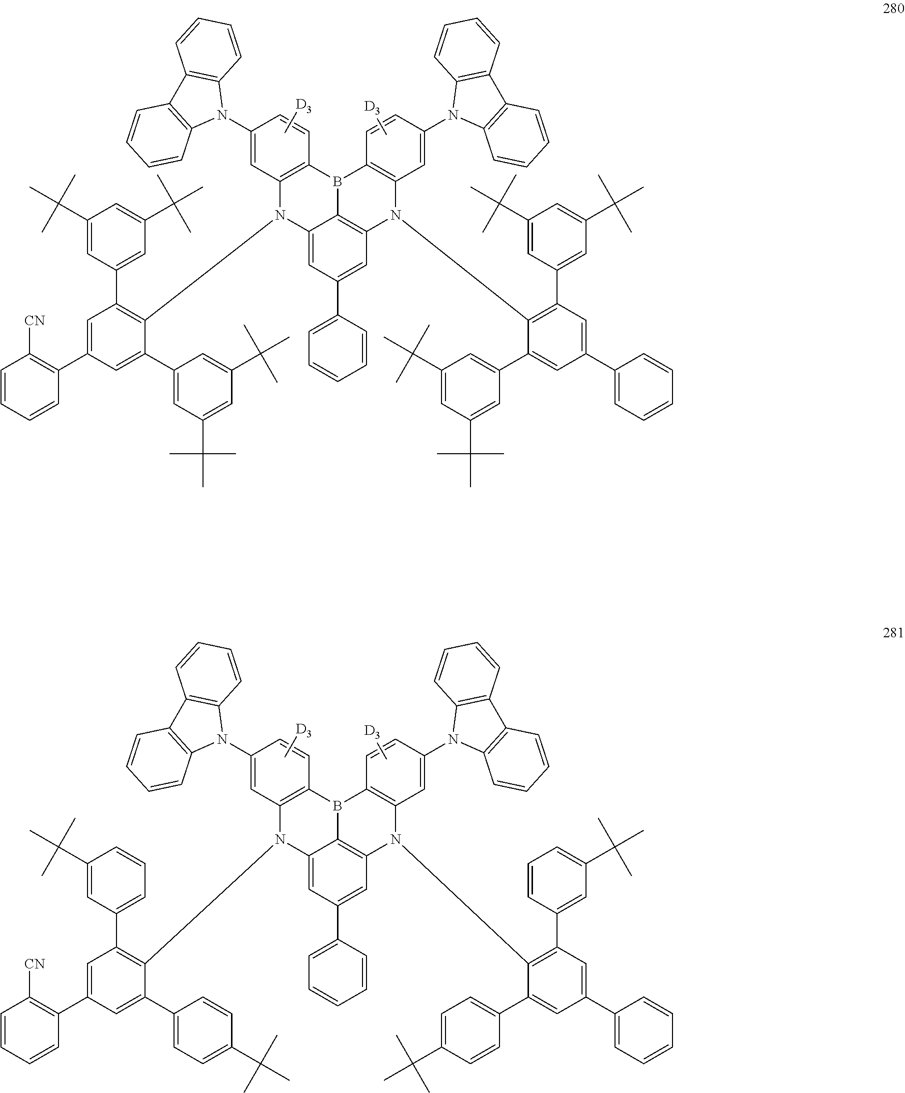

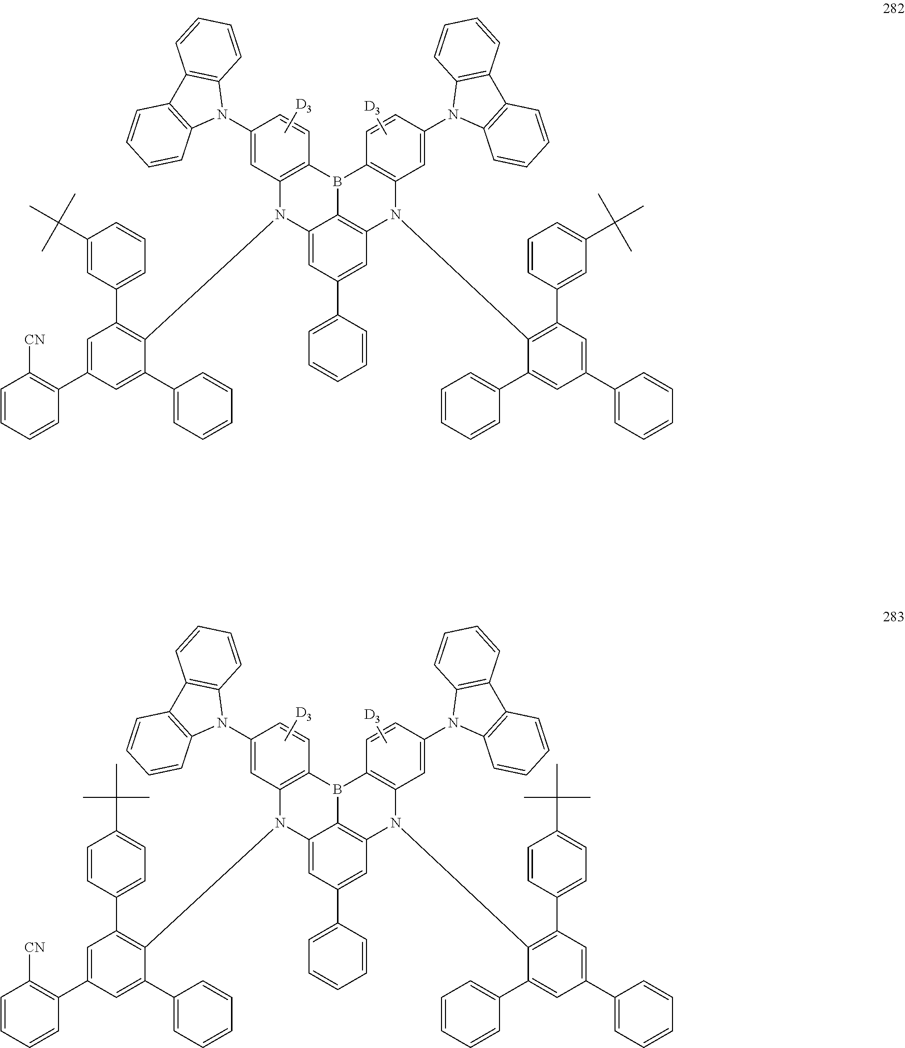

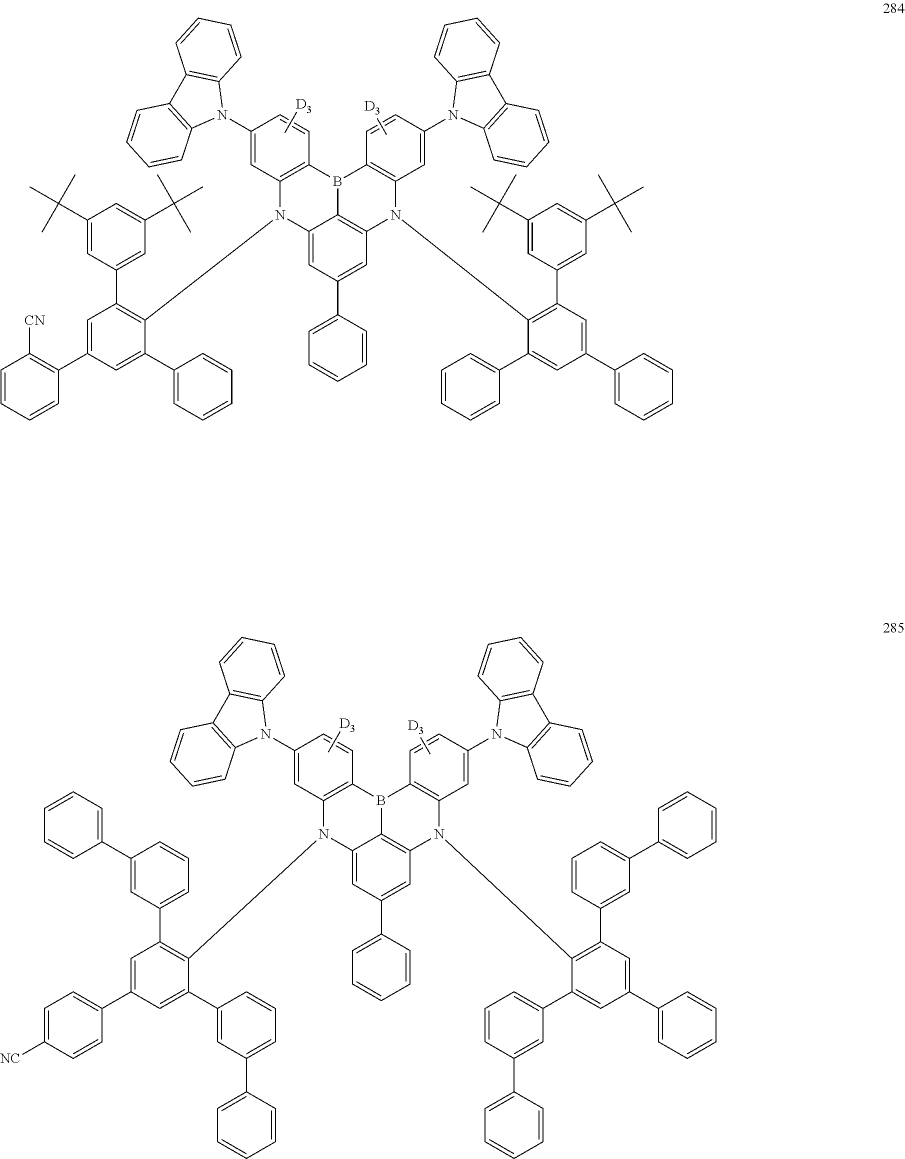

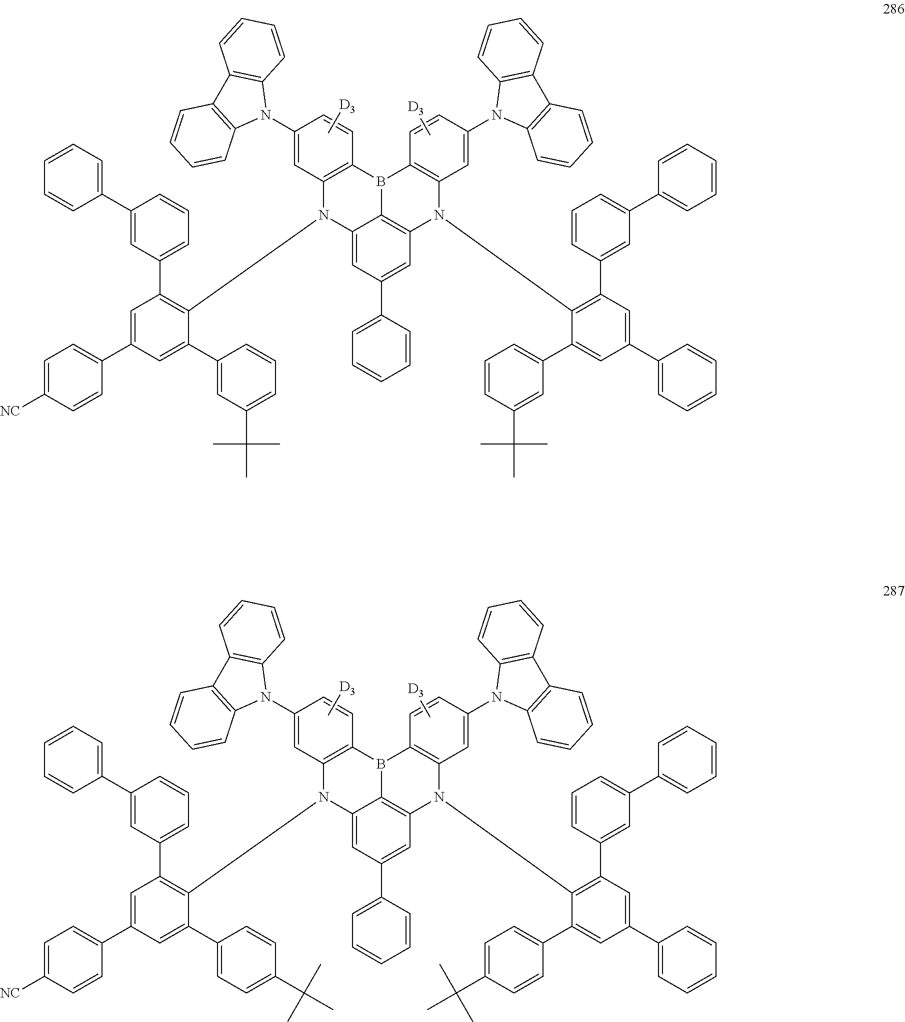

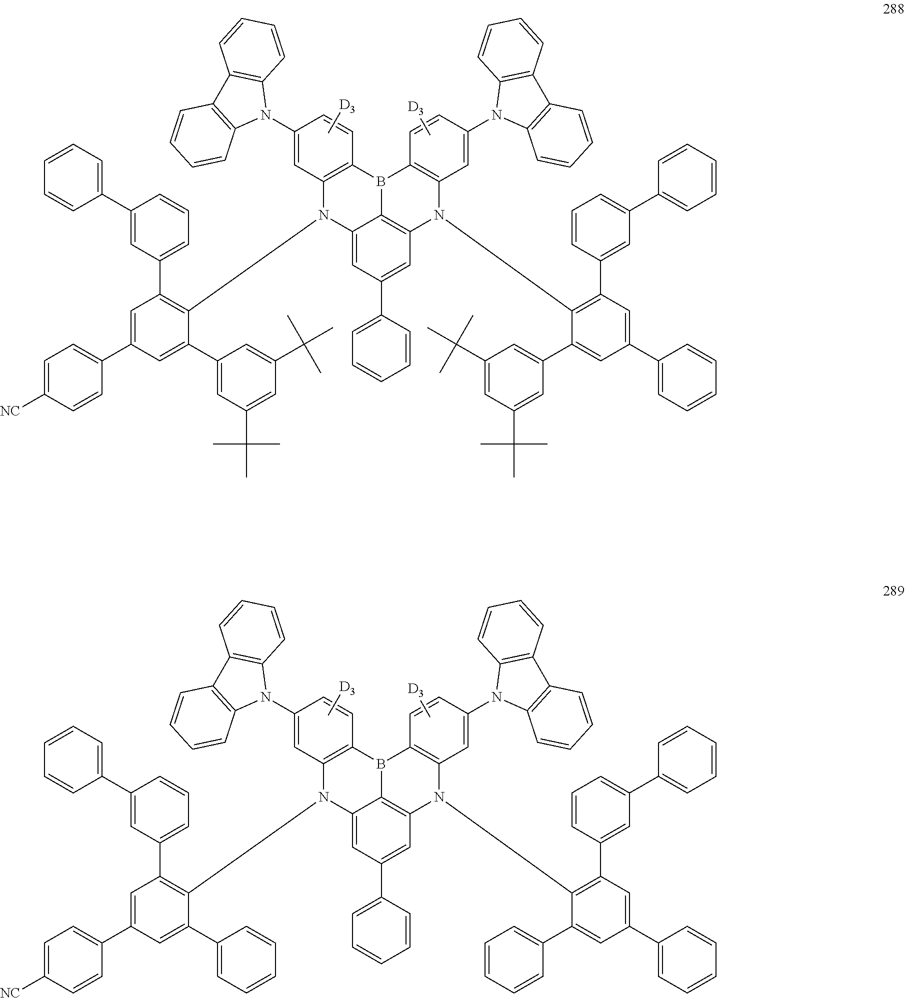

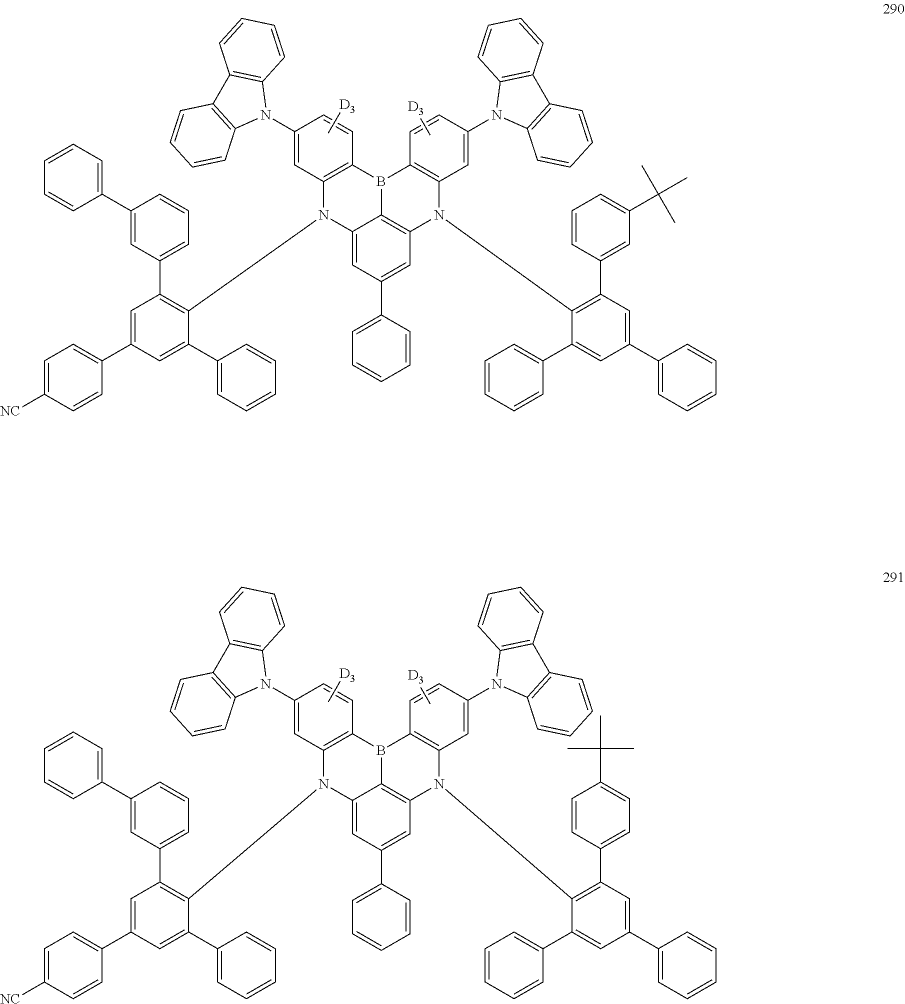

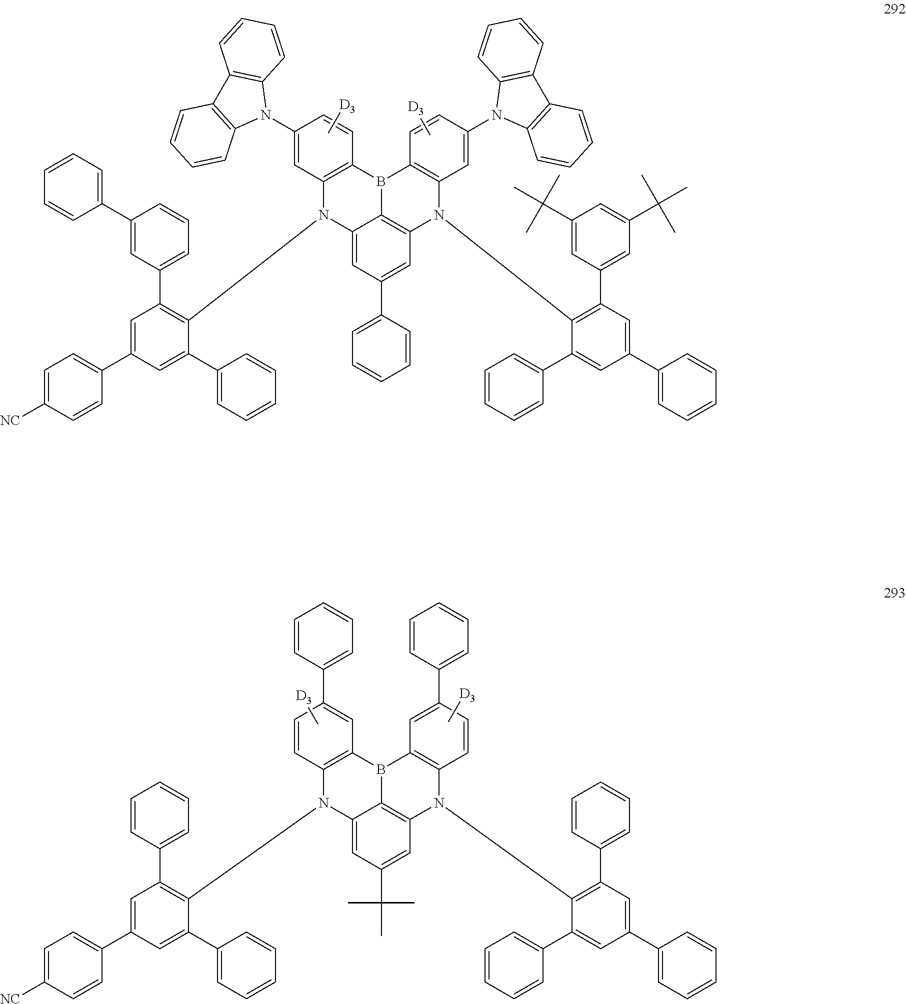

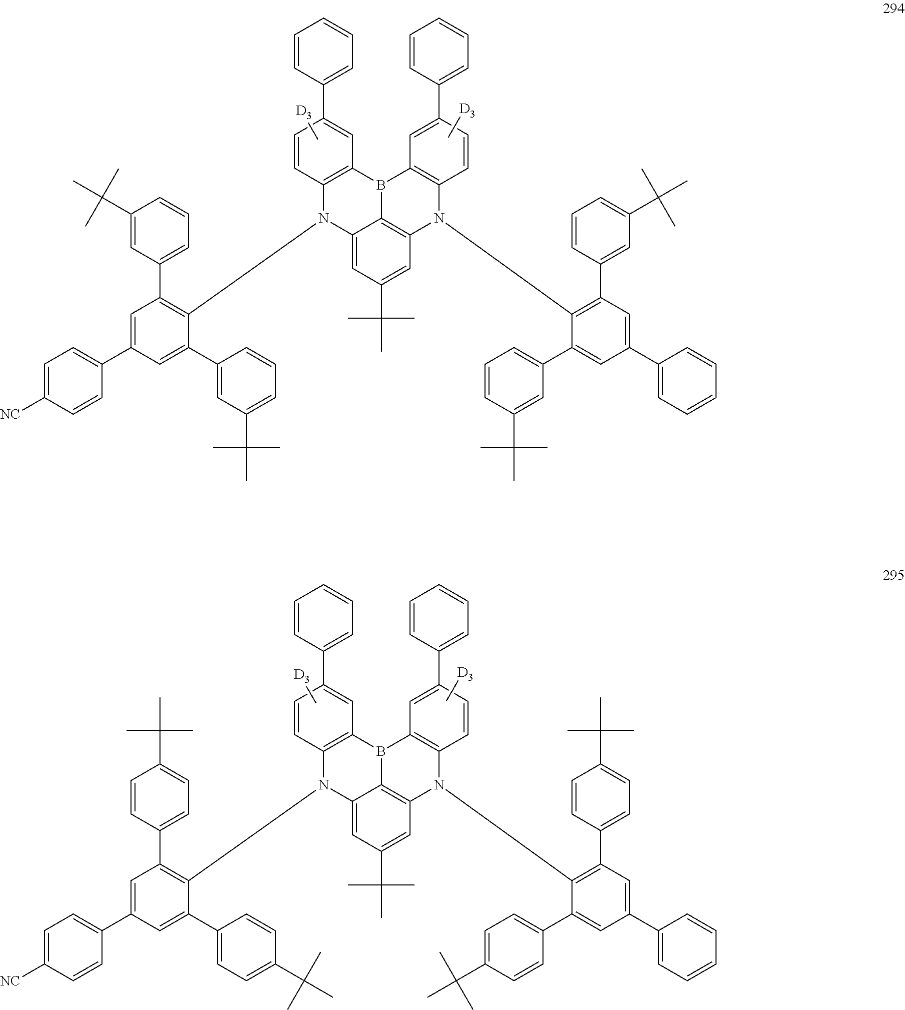

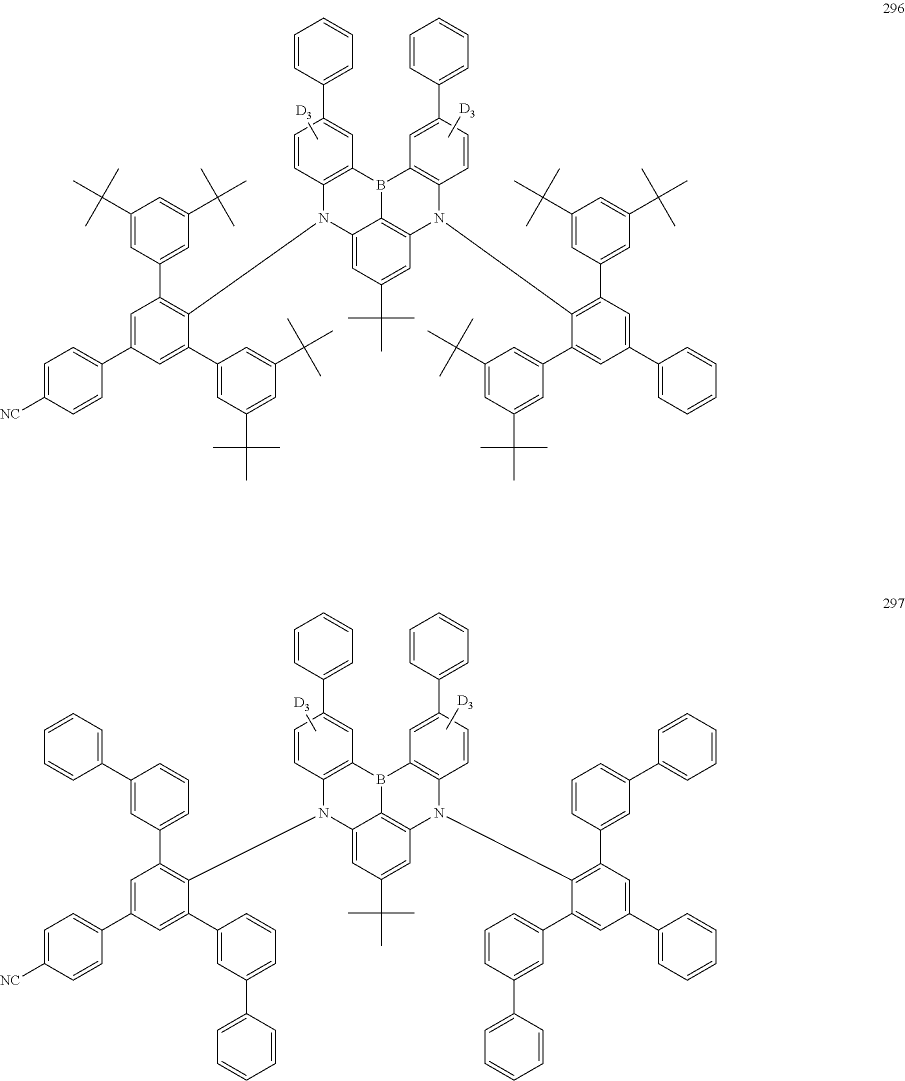

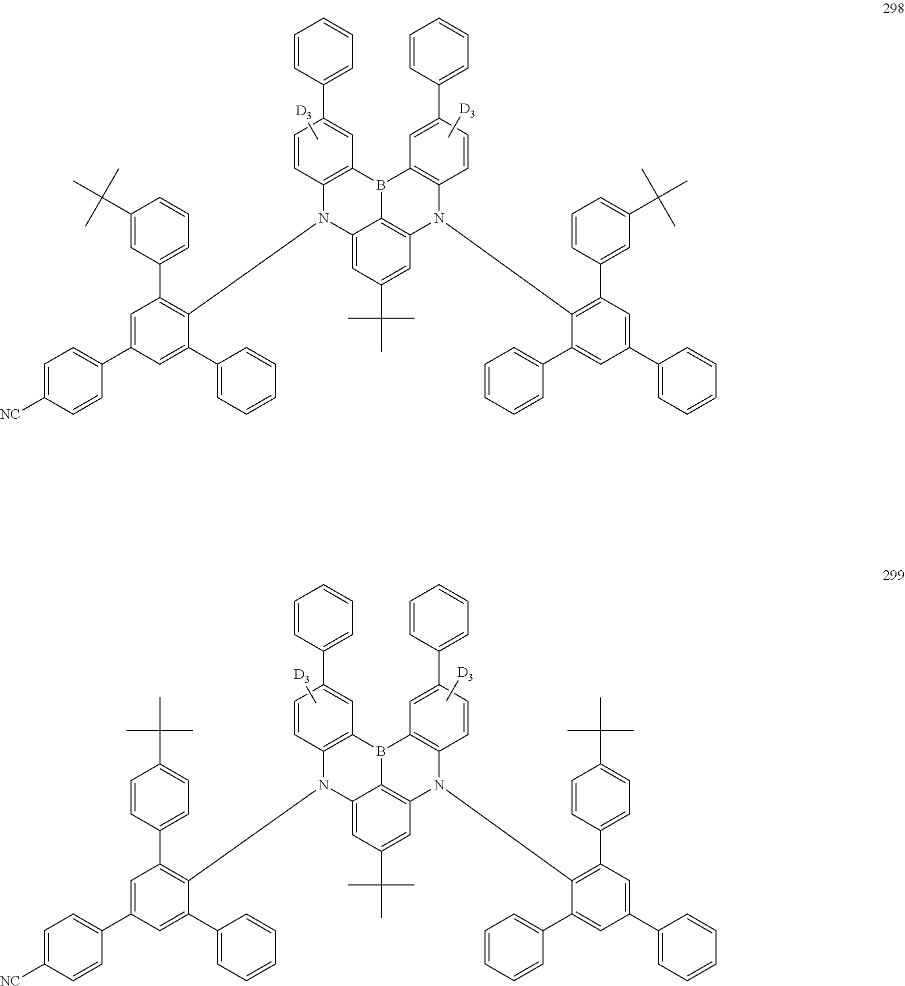

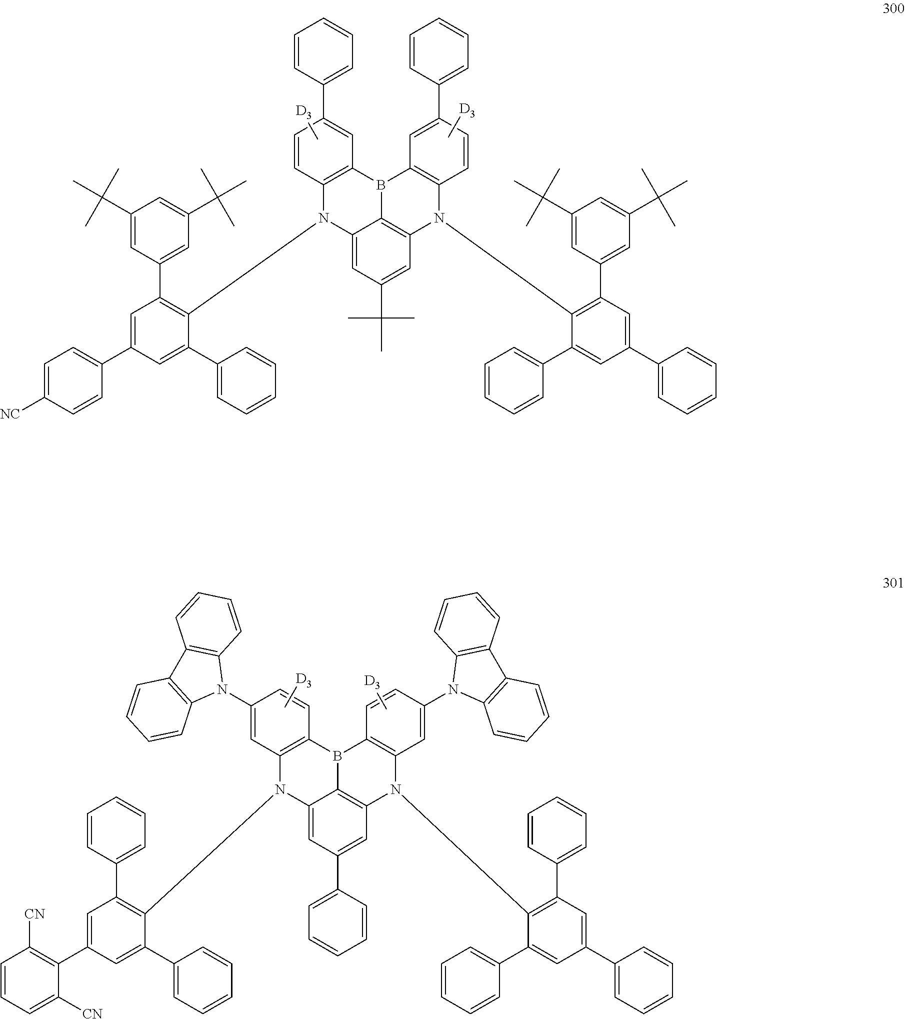

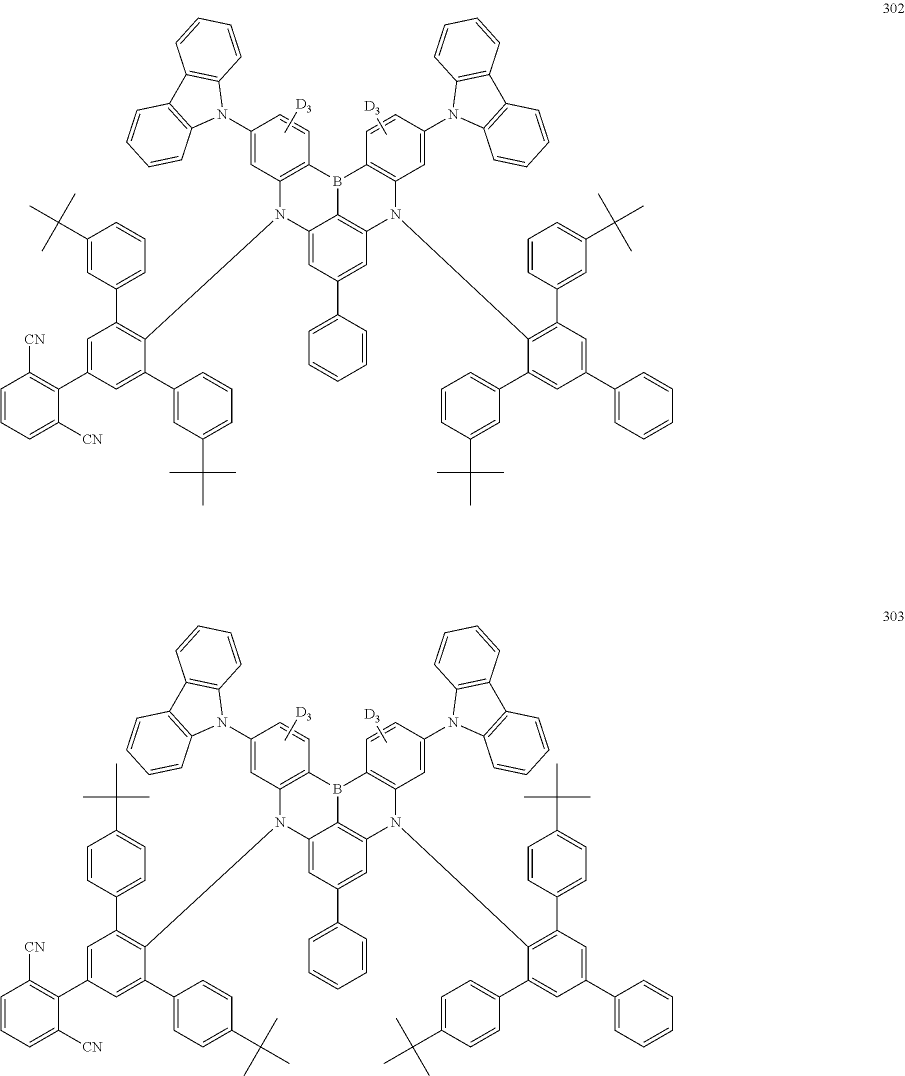

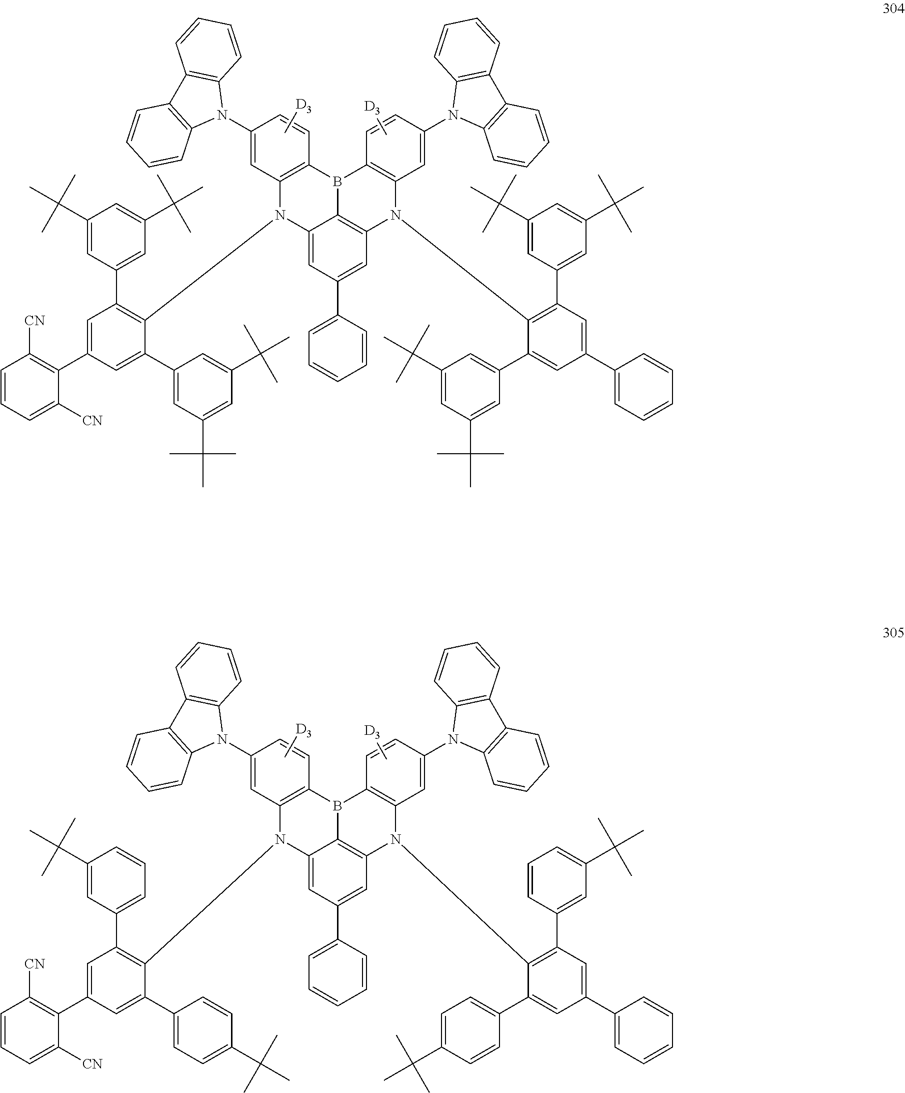

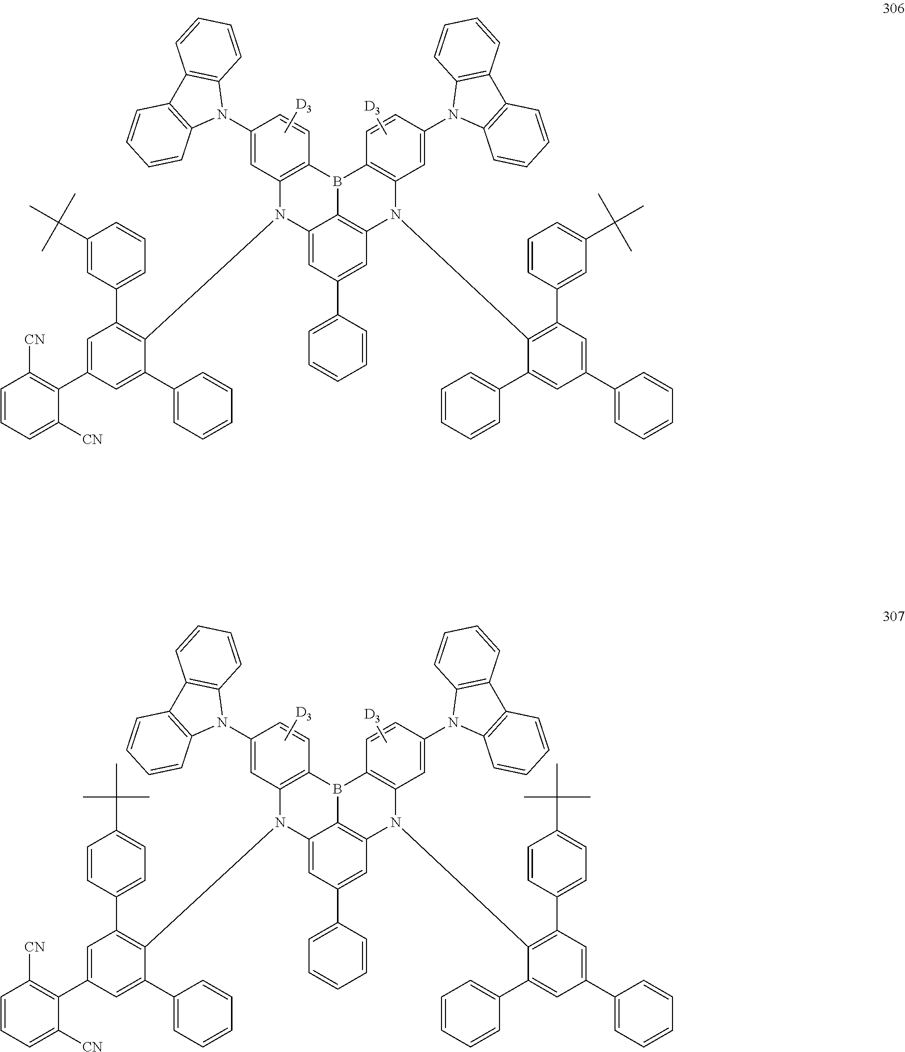

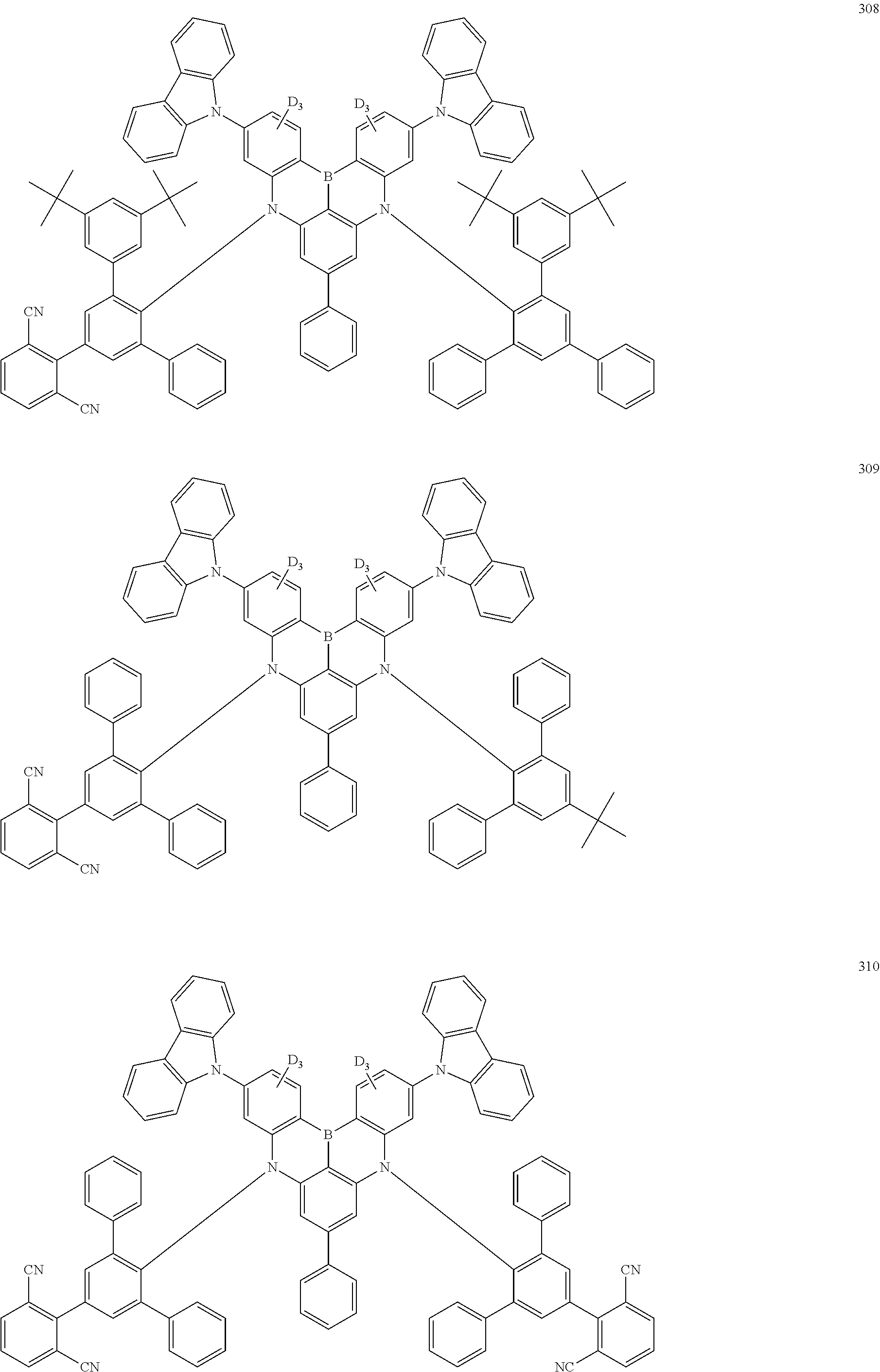

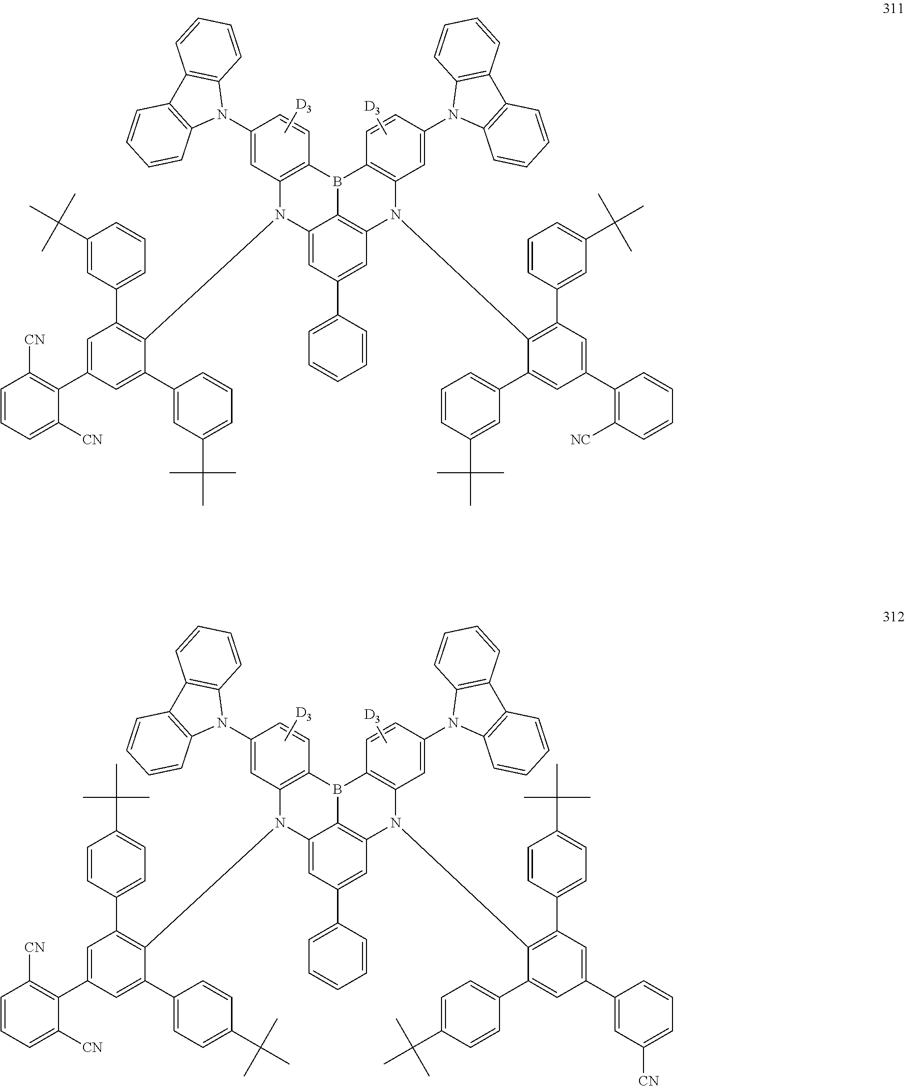

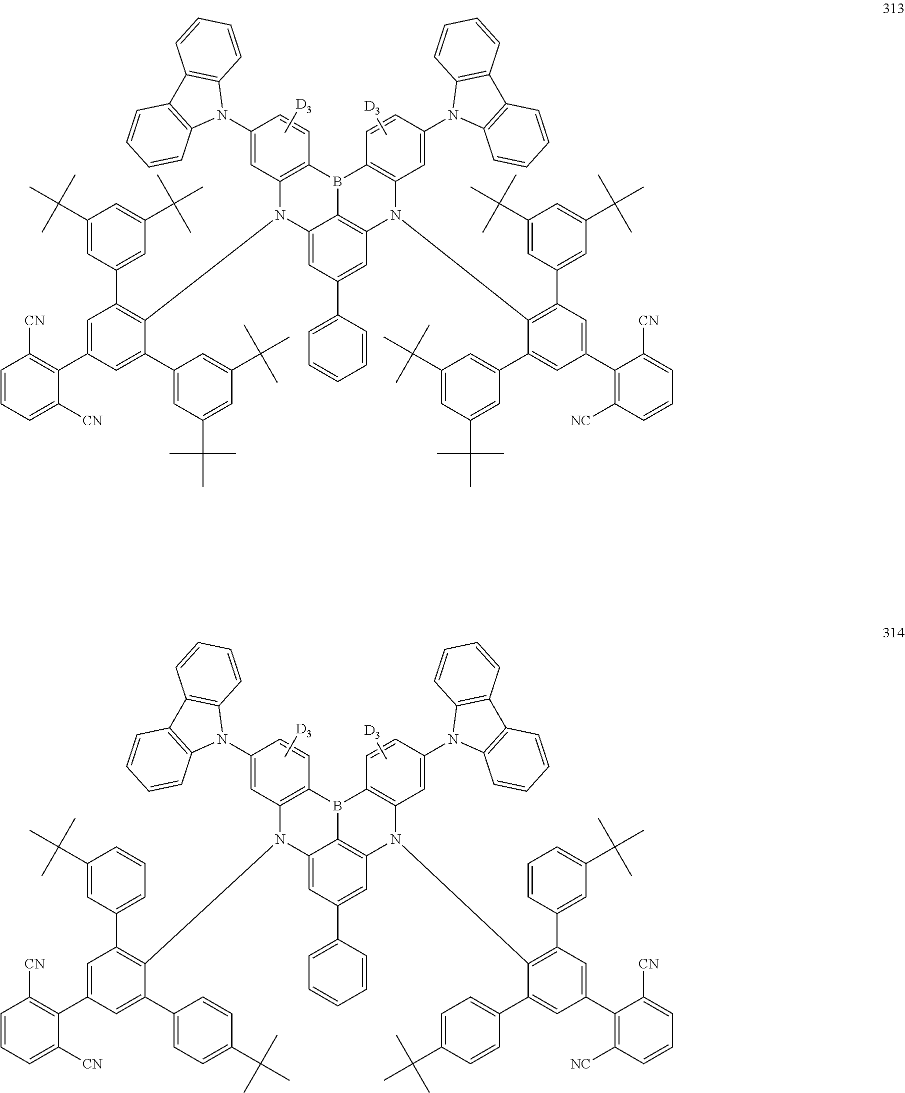

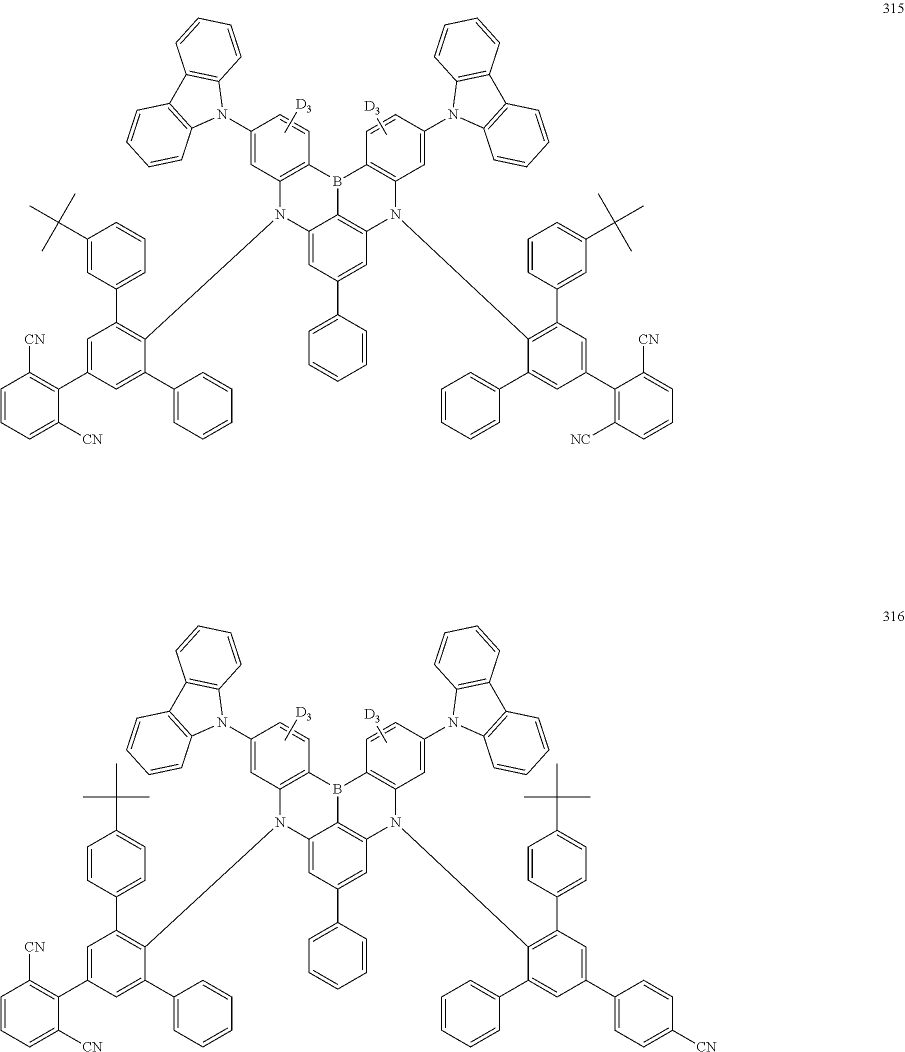

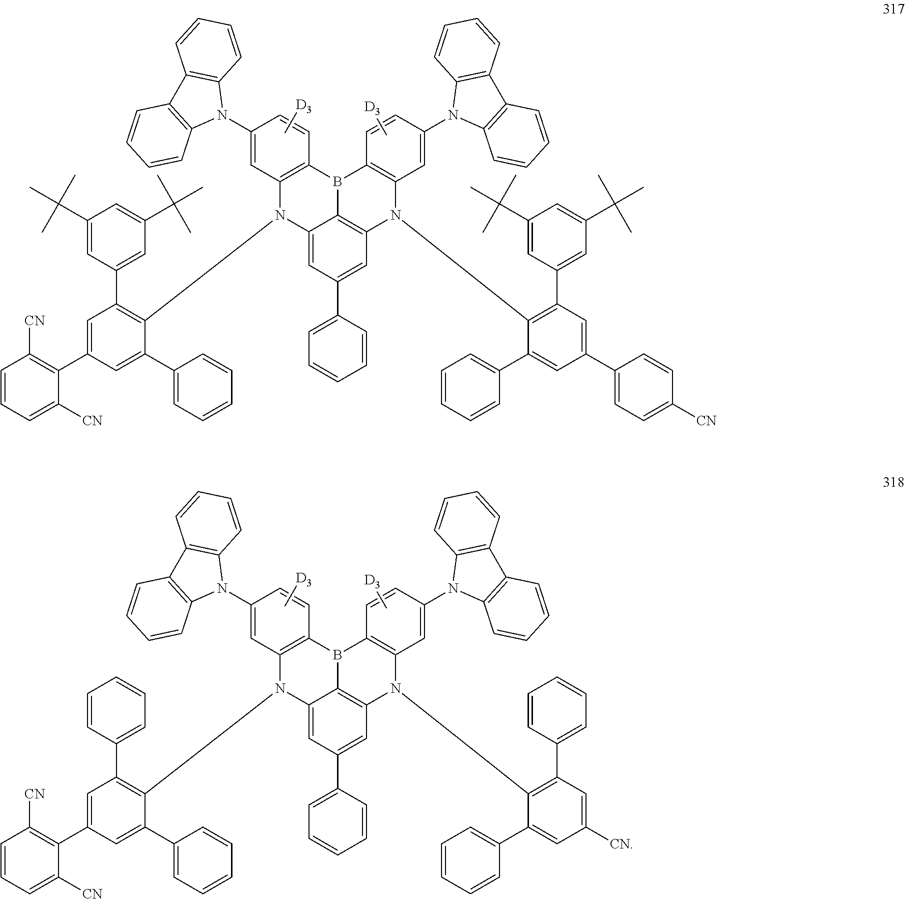

14. The light emitting element of claim 1, wherein the emission layer further comprises at least one of a second compound represented by Formula HT-1 and a third compound represented by Formula ET-1: 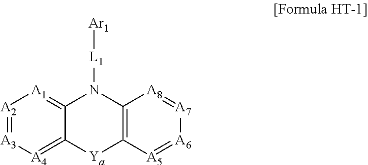
wherein in Formula HT-1,
A₁ to A₈ are each independently N or C(R₄₁),
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, C(R₄₂)(R₄₃), or Si(R₄₄)(R₄₅),
Ar₁ is a substituted or unsubstituted aryl group having 6 to 30 ring-forming carbon atoms or a substituted or unsubstituted heteroaryl group having 2 to 30 ring-forming carbon atoms, and
R₄₁ to R₄₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring; and 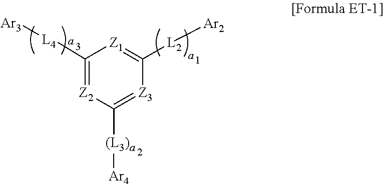
wherein in Formula ET-1,
at least one of Z₁ to Z₃ is each N,
the remainder of Z₁ to Z₃ is each independently C(R₄₆),
R₄₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
a₁ to a₃ are each independently an integer from 0 to 10,
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms,
when a₁ is 2 or greater, L₂ is a substituted or unsubstituted arylene group having 6 to 30 ring-forming carbon atoms or a substituted or unsubstituted heteroarylene group having 2 to 30 ring-forming carbon atoms,
when a₂ is 2 or greater, L₃ is a substituted or unsubstituted arylene group having 6 to 30 ring-forming carbon atoms or a substituted or unsubstituted heteroarylene group having 2 to 30 ring-forming carbon atoms,
when a₃ is 2 or greater, L₄ is a substituted or unsubstituted arylene group having 6 to 30 ring-forming carbon atoms or a substituted or unsubstituted heteroarylene group having 2 to 30 ring-forming carbon atoms, and
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

15. The light emitting element of claim 1, wherein the emission layer further comprises a fourth compound represented by Formula D-1: 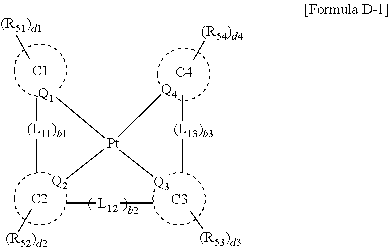
wherein in Formula D-1,
Q₁ to Q₄ are each independently C or N,
C1 to C4 are each independently a substituted or unsubstituted hydrocarbon ring having 5 to 30 ring-forming carbon atoms or a substituted or unsubstituted heterocycle having 2 to 30 ring-forming carbon atoms,
L₁₁ to L₁₃ are each independently a direct linkage, 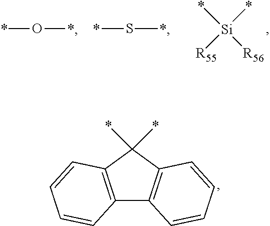
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b1 to b3 are each independently 0 or 1,
R₅₁ to R₅₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring, and
d1 to d4 are each independently an integer from 0 to 4.

16. A fused polycyclic compound represented by Formula 1: 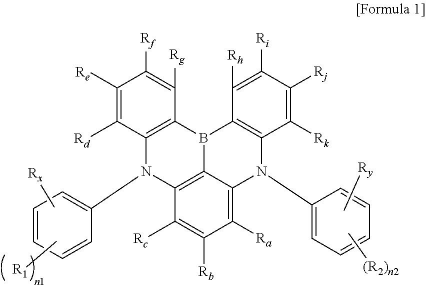
wherein in Formula 1,
R₁, R₂, and Rₐ to Rₖ are each independently a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring,
Rₓ and R_{y} are each independently a substituted or unsubstituted aryl group having 6 to 30 ring-forming carbon atoms, a substituted or unsubstituted heteroaryl group having 2 to 30 ring-forming carbon atoms, or a group represented by Formula 2,
n1 and n2 are each independently an integer from 0 to 4, and
at least one of Rₓ and R_{y} is each independently a group represented by Formula 2: 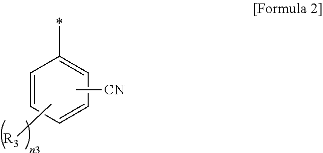
wherein in Formula 2,
R₃ is a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
CN is a cyano group,
n3 is an integer from 0 to 4, and [symbol]
represents a bond to Formula 1.

17. The fused polycyclic compound of claim 16, wherein the fused polycyclic compound represented by Formula 1 is represented by Formula 3-1 or Formula 3-2: 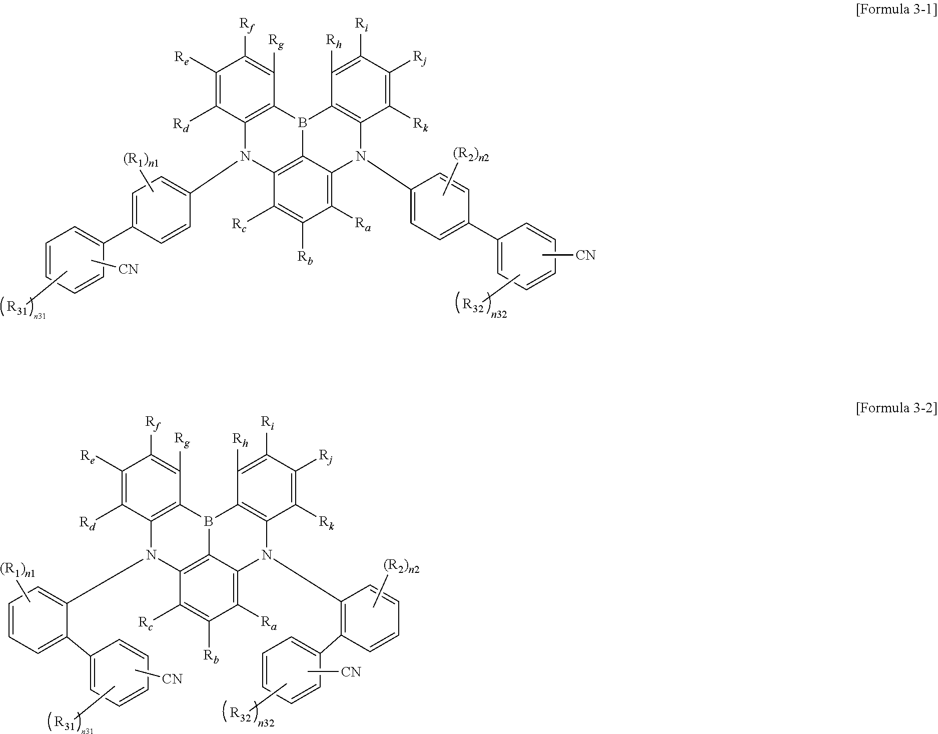
wherein in Formulas 3-1 and 3-2,
R₃₁ and R₃₂ are each independently a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n31 and n32 are each independently an integer from 0 to 4, and
R₁, R₂, Rₐ to Rₖ, n1, and n2 are the same as defined in Formula 1.

18. The fused polycyclic compound of claim 16, wherein the fused polycyclic compound represented by Formula 1 is represented by one of Formulas 4-1 to 4-6: 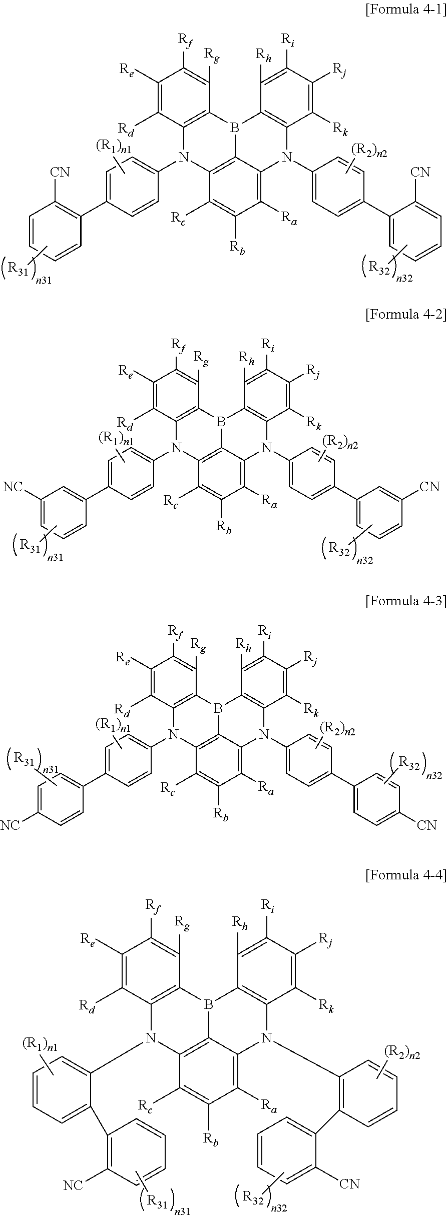 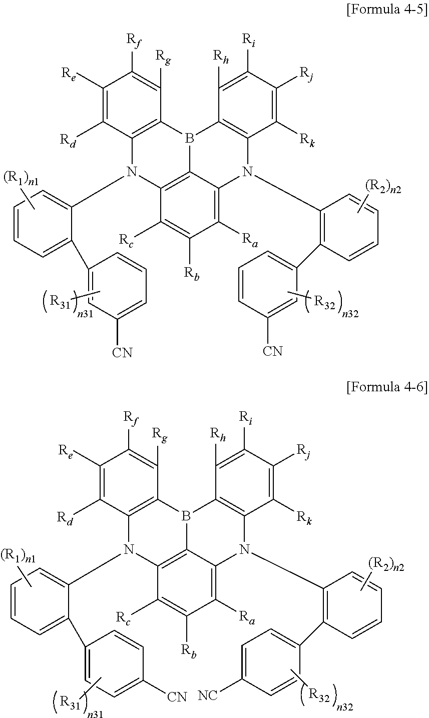
wherein in Formulas 4-1 to 4-6,
R₃₁ and R₃₂ are each independently a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n31 and n32 are each independently an integer from 0 to 4, and
R₁, R₂, Rₐ to Rₖ, n1, and n2 are the same as defined in Formula 1.

19. The fused polycyclic compound of claim 16, wherein the fused polycyclic compound represented by Formula 1 is represented by Formula 5: 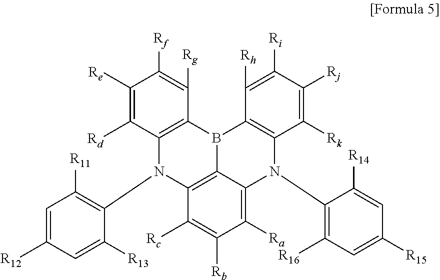
wherein in Formula 5,
R₁₁ to R₁₆ are each independently a hydrogen atom, a deuterium atom, a substituted or unsubstituted aryl group having 6 to 30 ring-forming carbon atoms, a substituted or unsubstituted heteroaryl group having 2 to 30 ring-forming carbon atoms, or a group represented by Formula 2,
at least one of R₁₁ to R₁₆ is each independently a group represented by Formula 2, and
Rₐ to Rₖ are the same as defined in Formula 1.

20. The fused polycyclic compound of claim 16, wherein the fused polycyclic compound is selected from Compound Group 1: 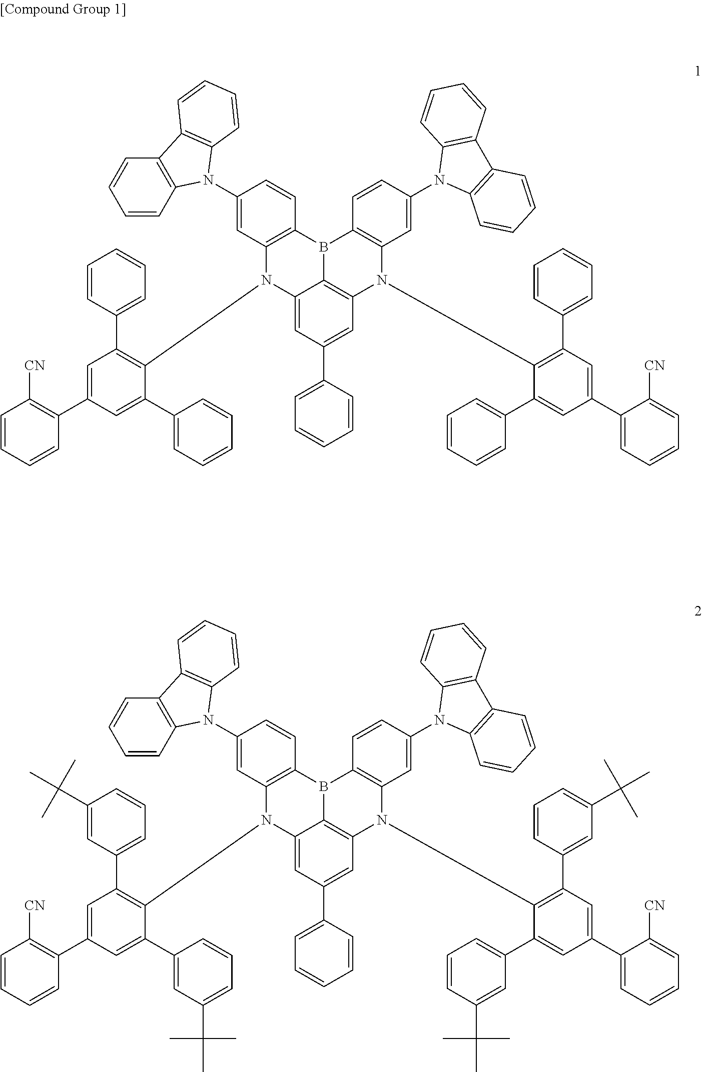 [SMILES: N#Cc1ccccc1-c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(-c5ccccc5C#N)cc4-c4ccccc4)c4cc(-c5ccccc5)cc2c43)c(-c2ccccc2)c1 ; CC(C)(C)c1cccc(-c2cc(-c3ccccc3C#N)cc(-c3cccc(C(C)(C)C)c3)c2N2c3cc(-n4c5ccccc5c5ccccc54)ccc3B3c4ccc(-n5c6ccccc6c6ccccc65)cc4N(c4c(-c5cccc(C(C)(C)C)c5)cc(-c5ccccc5C#N)cc4-c4cccc(C(C)(C)C)c4)c4cc(-c5ccccc5)cc2c43)c1] 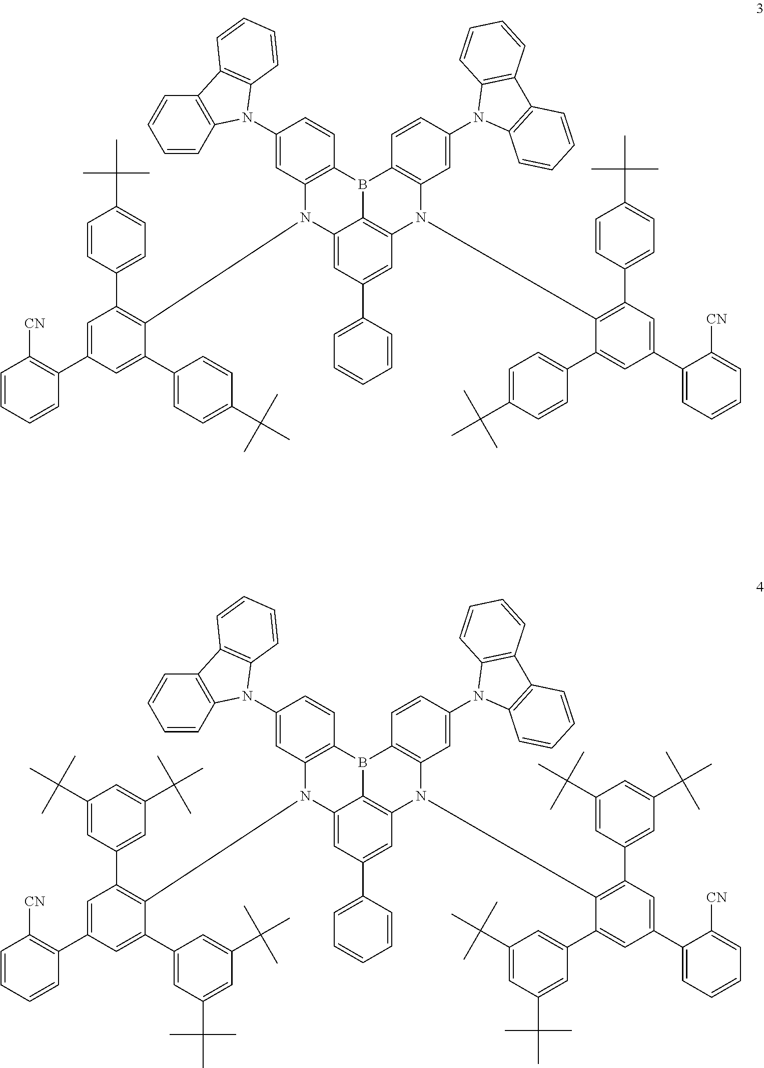 [SMILES: CC(C)(C)c1ccc(-c2cc(-c3ccccc3C#N)cc(-c3ccc(C(C)(C)C)cc3)c2N2c3cc(-n4c5ccccc5c5ccccc54)ccc3B3c4ccc(-n5c6ccccc6c6ccccc65)cc4N(c4c(-c5ccc(C(C)(C)C)cc5)cc(-c5ccccc5C#N)cc4-c4ccc(C(C)(C)C)cc4)c4cc(-c5ccccc5)cc2c43)cc1 ; CC(C)(C)c1cc(-c2cc(-c3ccccc3C#N)cc(-c3cc(C(C)(C)C)cc(C(C)(C)C)c3)c2N2c3cc(-n4c5ccccc5c5ccccc54)ccc3B3c4ccc(-n5c6ccccc6c6ccccc65)cc4N(c4c(-c5cc(C(C)(C)C)cc(C(C)(C)C)c5)cc(-c5ccccc5C#N)cc4-c4cc(C(C)(C)C)cc(C(C)(C)C)c4)c4cc(-c5ccccc5)cc2c43)cc(C(C)(C)C)c1] 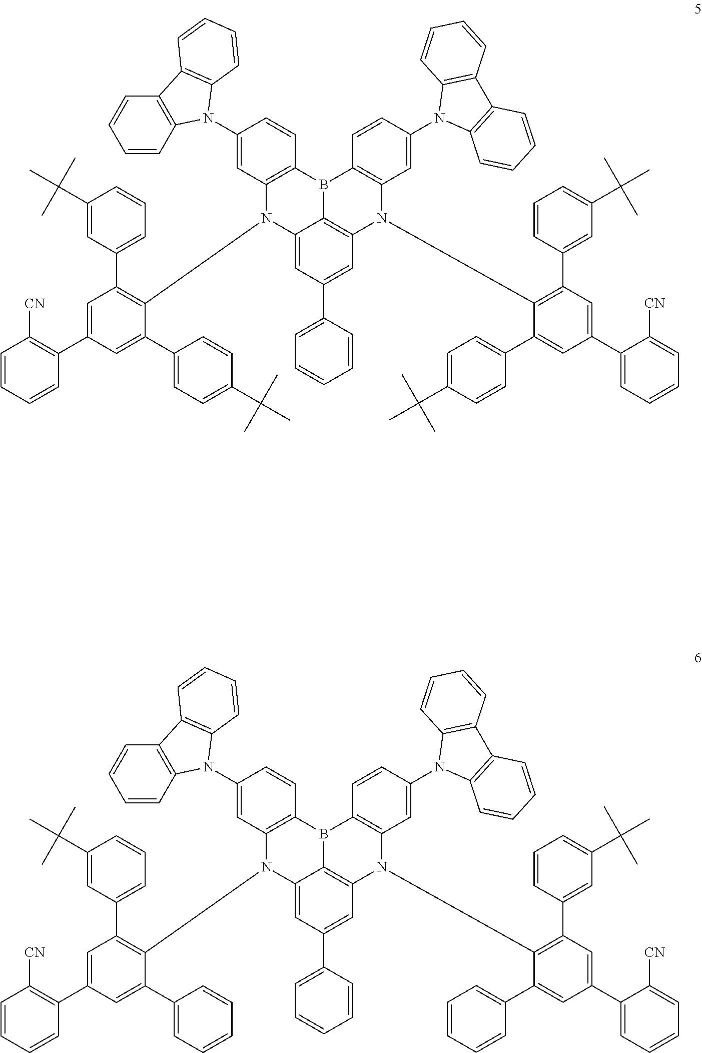 [SMILES: CC(C)(C)c1ccc(-c2cc(-c3ccccc3C#N)cc(-c3cccc(C(C)(C)C)c3)c2N2c3cc(-n4c5ccccc5c5ccccc54)ccc3B3c4ccc(-n5c6ccccc6c6ccccc65)cc4N(c4c(-c5ccc(C(C)(C)C)cc5)cc(-c5ccccc5C#N)cc4-c4cccc(C(C)(C)C)c4)c4cc(-c5ccccc5)cc2c43)cc1 ; CC(C)(C)c1cccc(-c2cc(-c3ccccc3C#N)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5ccccc5C#N)cc4-c4cccc(C(C)(C)C)c4)c4cc(-c5ccccc5)cc2c43)c1] 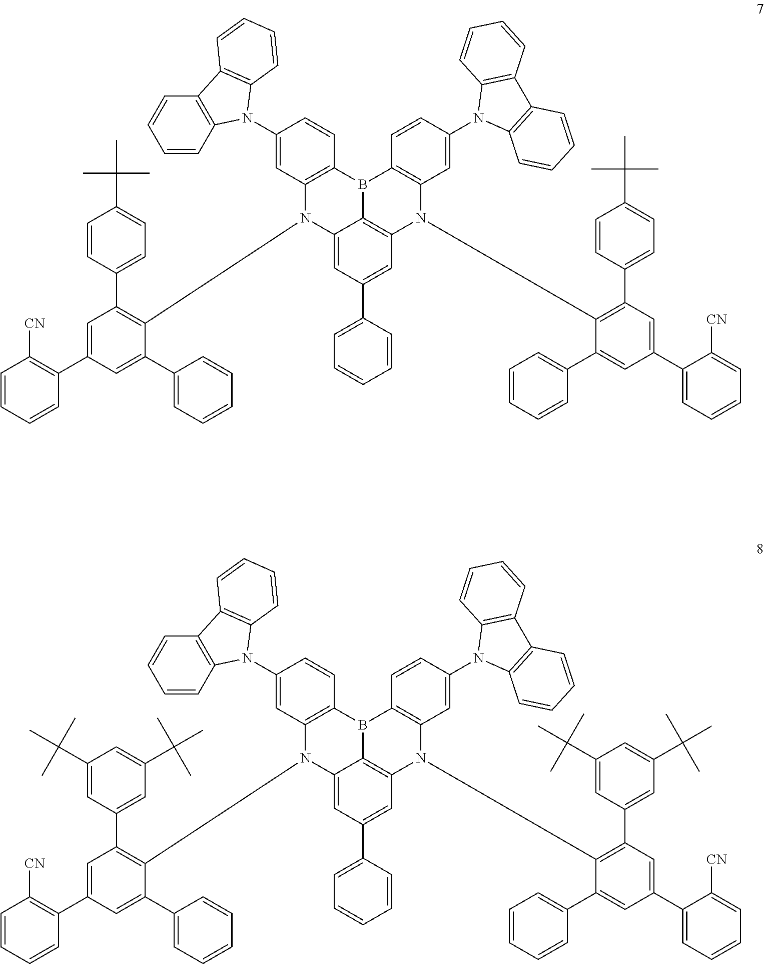 [SMILES: CC(C)(C)c1ccc(-c2cc(-c3ccccc3C#N)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5ccccc5C#N)cc4-c4ccc(C(C)(C)C)cc4)c4cc(-c5ccccc5)cc2c43)cc1 ; CC(C)(C)c1cc(-c2cc(-c3ccccc3C#N)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5ccccc5C#N)cc4-c4cc(C(C)(C)C)cc(C(C)(C)C)c4)c4cc(-c5ccccc5)cc2c43)cc(C(C)(C)C)c1] 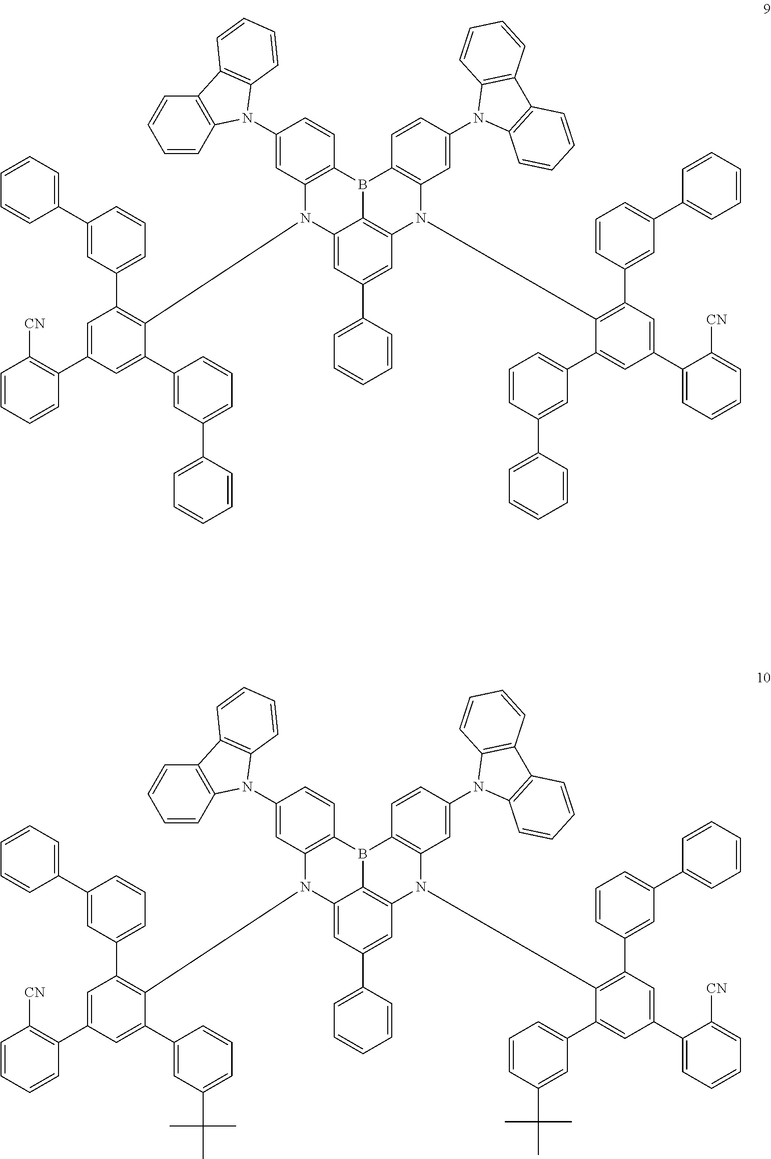 [SMILES: N#Cc1ccccc1-c1cc(-c2cccc(-c3ccccc3)c2)c(N2c3cc(-n4c5ccccc5c5ccccc54)ccc3B3c4ccc(-n5c6ccccc6c6ccccc65)cc4N(c4c(-c5cccc(-c6ccccc6)c5)cc(-c5ccccc5C#N)cc4-c4cccc(-c5ccccc5)c4)c4cc(-c5ccccc5)cc2c43)c(-c2cccc(-c3ccccc3)c2)c1 ; CC(C)(C)c1cccc(-c2cc(-c3ccccc3C#N)cc(-c3cccc(-c4ccccc4)c3)c2N2c3cc(-n4c5ccccc5c5ccccc54)ccc3B3c4ccc(-n5c6ccccc6c6ccccc65)cc4N(c4c(-c5cccc(-c6ccccc6)c5)cc(-c5ccccc5C#N)cc4-c4cccc(C(C)(C)C)c4)c4cc(-c5ccccc5)cc2c43)c1] 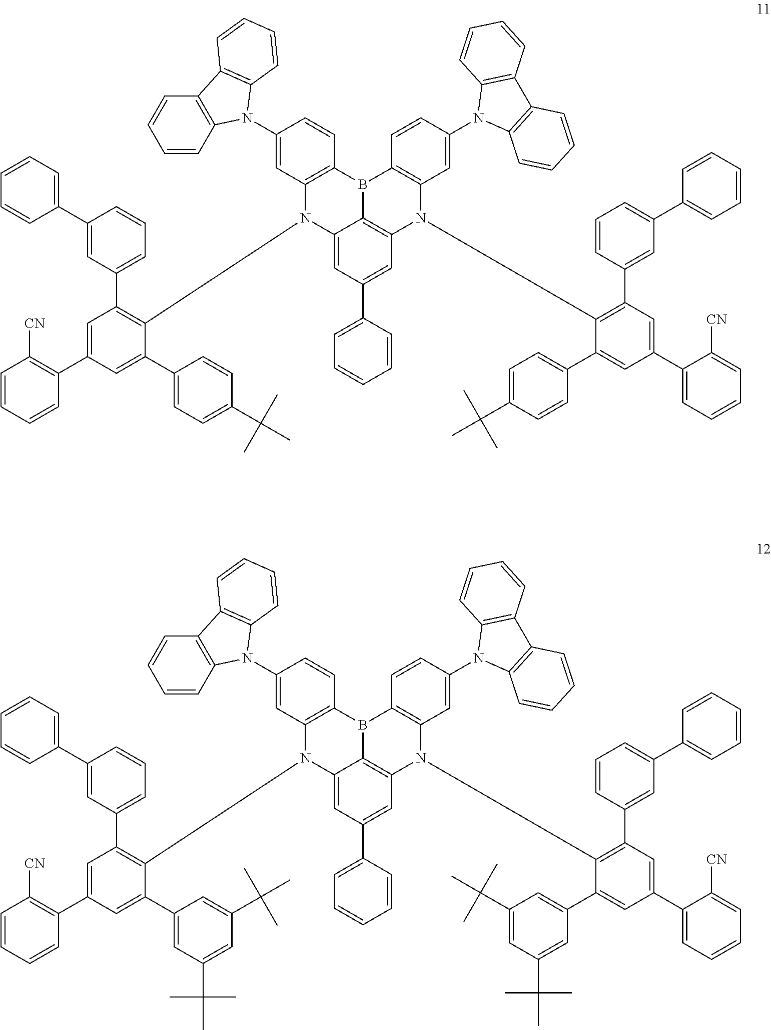 [SMILES: CC(C)(C)c1ccc(-c2cc(-c3ccccc3C#N)cc(-c3cccc(-c4ccccc4)c3)c2N2c3cc(-n4c5ccccc5c5ccccc54)ccc3B3c4ccc(-n5c6ccccc6c6ccccc65)cc4N(c4c(-c5ccc(C(C)(C)C)cc5)cc(-c5ccccc5C#N)cc4-c4cccc(-c5ccccc5)c4)c4cc(-c5ccccc5)cc2c43)cc1 ; CC(C)(C)c1cc(-c2cc(-c3ccccc3C#N)cc(-c3cccc(-c4ccccc4)c3)c2N2c3cc(-n4c5ccccc5c5ccccc54)ccc3B3c4ccc(-n5c6ccccc6c6ccccc65)cc4N(c4c(-c5cccc(-c6ccccc6)c5)cc(-c5ccccc5C#N)cc4-c4cc(C(C)(C)C)cc(C(C)(C)C)c4)c4cc(-c5ccccc5)cc2c43)cc(C(C)(C)C)c1] 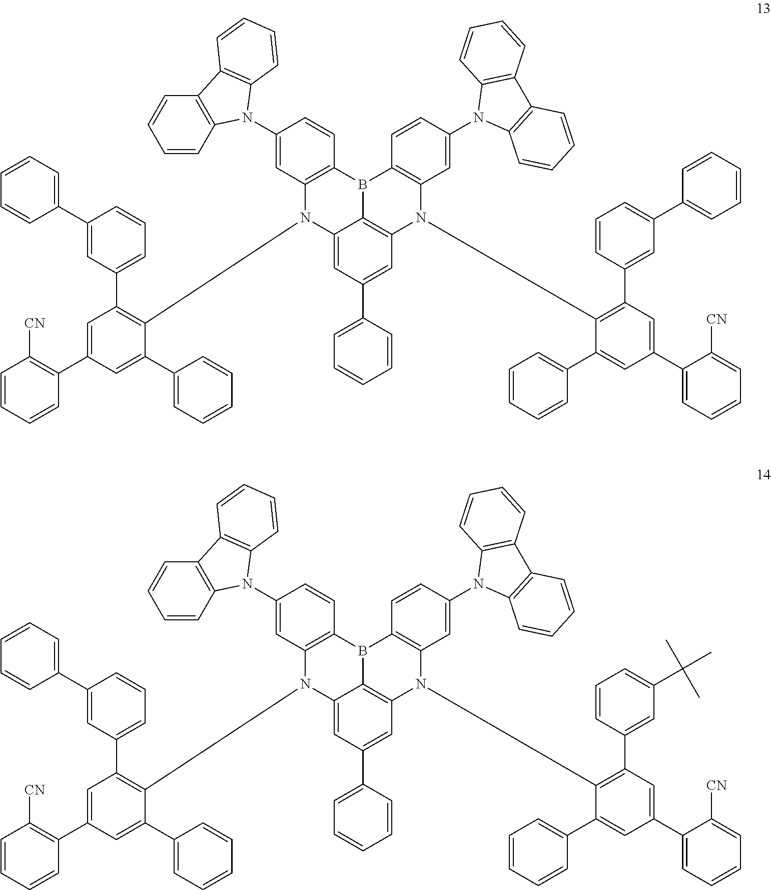 [SMILES: N#Cc1ccccc1-c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(-c5ccccc5C#N)cc4-c4cccc(-c5ccccc5)c4)c4cc(-c5ccccc5)cc2c43)c(-c2cccc(-c3ccccc3)c2)c1 ; CC(C)(C)c1cccc(-c2cc(-c3ccccc3C#N)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5ccccc5C#N)cc4-c4cccc(-c5ccccc5)c4)c4cc(-c5ccccc5)cc2c43)c1] 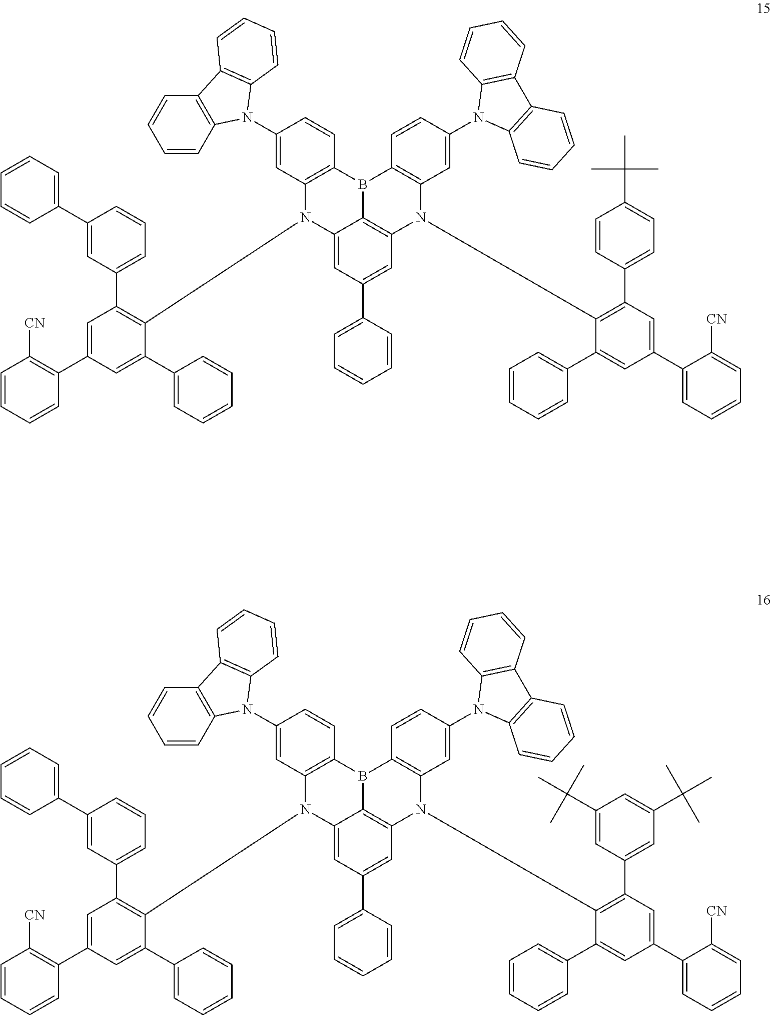 [SMILES: CC(C)(C)c1ccc(-c2cc(-c3ccccc3C#N)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5ccccc5C#N)cc4-c4cccc(-c5ccccc5)c4)c4cc(-c5ccccc5)cc2c43)cc1 ; CC(C)(C)c1cc(-c2cc(-c3ccccc3C#N)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5ccccc5C#N)cc4-c4cccc(-c5ccccc5)c4)c4cc(-c5ccccc5)cc2c43)cc(C(C)(C)C)c1] 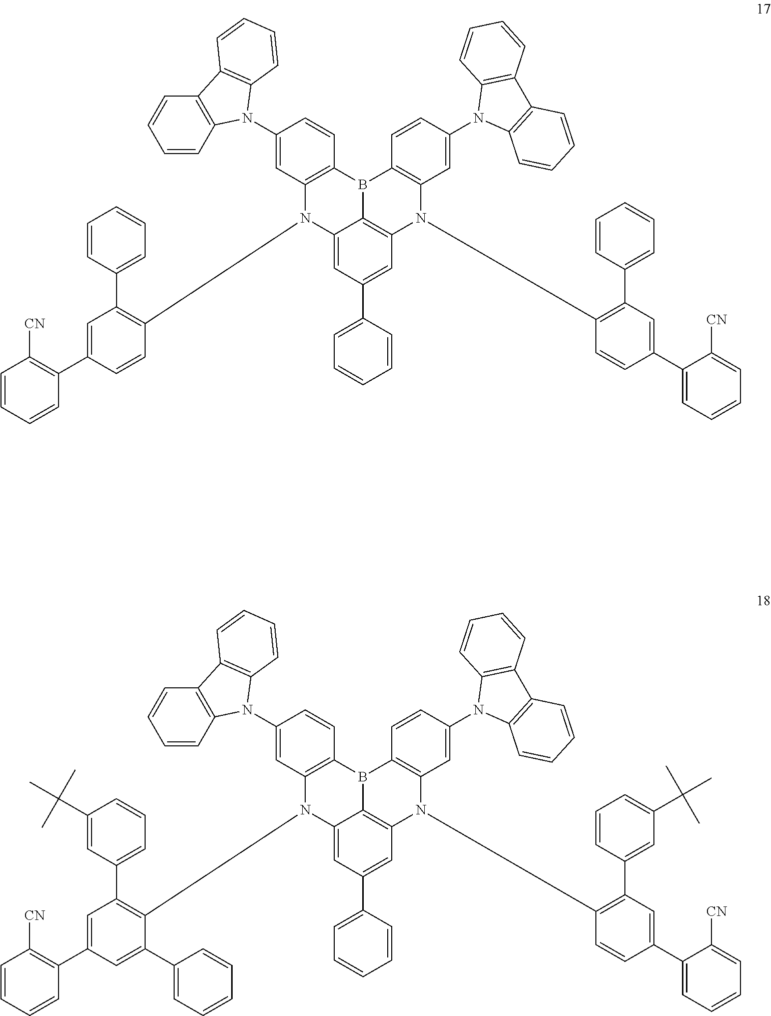 [SMILES: N#Cc1ccccc1-c1ccc(N2c3cc(-n4c5ccccc5c5ccccc54)ccc3B3c4ccc(-n5c6ccccc6c6ccccc65)cc4N(c4ccc(-c5ccccc5C#N)cc4-c4ccccc4)c4cc(-c5ccccc5)cc2c43)c(-c2ccccc2)c1 ; CC(C)(C)c1cccc(-c2cc(-c3ccccc3C#N)ccc2N2c3cc(-n4c5ccccc5c5ccccc54)ccc3B3c4ccc(-n5c6ccccc6c6ccccc65)cc4N(c4c(-c5ccccc5)cc(-c5ccccc5C#N)cc4-c4cccc(C(C)(C)C)c4)c4cc(-c5ccccc5)cc2c43)c1] 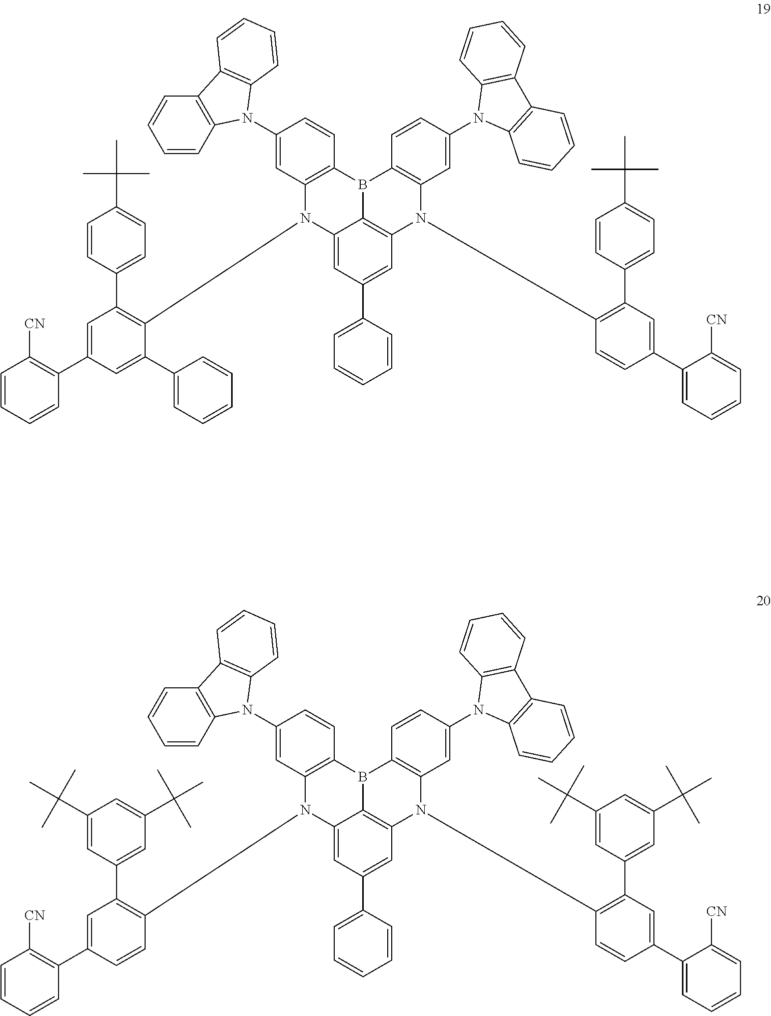 [SMILES: CC(C)(C)c1ccc(-c2cc(-c3ccccc3C#N)ccc2N2c3cc(-n4c5ccccc5c5ccccc54)ccc3B3c4ccc(-n5c6ccccc6c6ccccc65)cc4N(c4c(-c5ccccc5)cc(-c5ccccc5C#N)cc4-c4ccc(C(C)(C)C)cc4)c4cc(-c5ccccc5)cc2c43)cc1 ; CC(C)(C)c1cc(-c2cc(-c3ccccc3C#N)ccc2N2c3cc(-n4c5ccccc5c5ccccc54)ccc3B3c4ccc(-n5c6ccccc6c6ccccc65)cc4N(c4ccc(-c5ccccc5C#N)cc4-c4cc(C(C)(C)C)cc(C(C)(C)C)c4)c4cc(-c5ccccc5)cc2c43)cc(C(C)(C)C)c1] 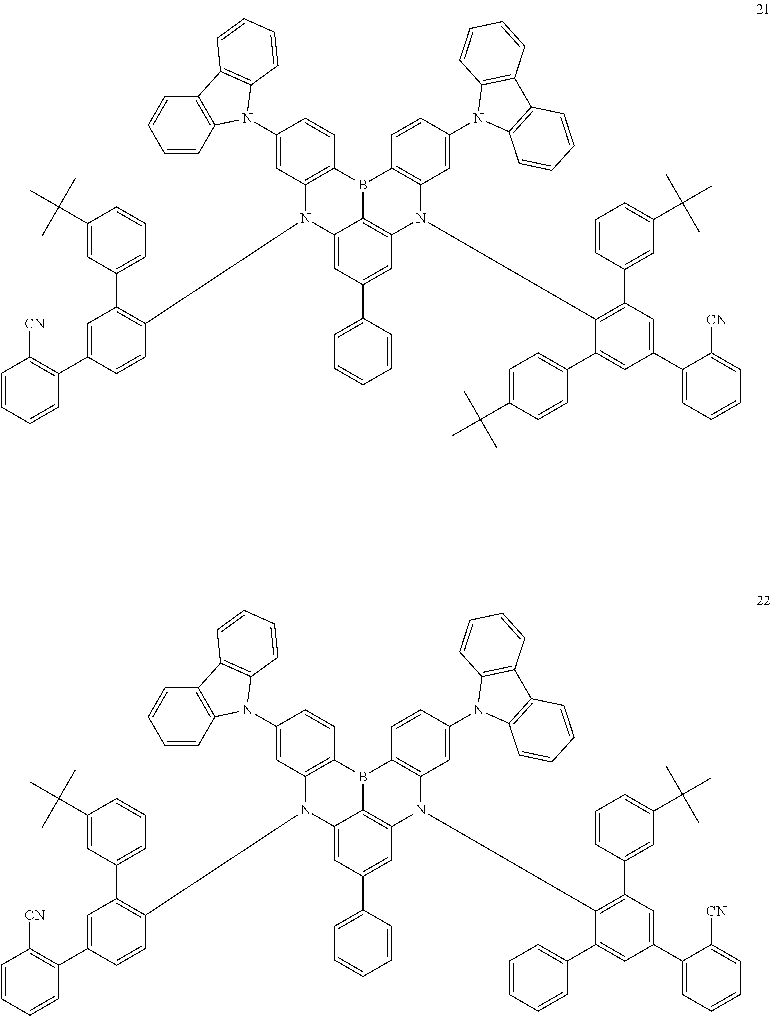 [SMILES: CC(C)(C)c1ccc(-c2cc(-c3ccccc3C#N)cc(-c3cccc(C(C)(C)C)c3)c2N2c3cc(-n4c5ccccc5c5ccccc54)ccc3B3c4ccc(-n5c6ccccc6c6ccccc65)cc4N(c4ccc(-c5ccccc5C#N)cc4-c4cccc(C(C)(C)C)c4)c4cc(-c5ccccc5)cc2c43)cc1 ; CC(C)(C)c1cccc(-c2cc(-c3ccccc3C#N)ccc2N2c3cc(-n4c5ccccc5c5ccccc54)ccc3B3c4ccc(-n5c6ccccc6c6ccccc65)cc4N(c4c(-c5ccccc5)cc(-c5ccccc5C#N)cc4-c4cccc(C(C)(C)C)c4)c4cc(-c5ccccc5)cc2c43)c1] 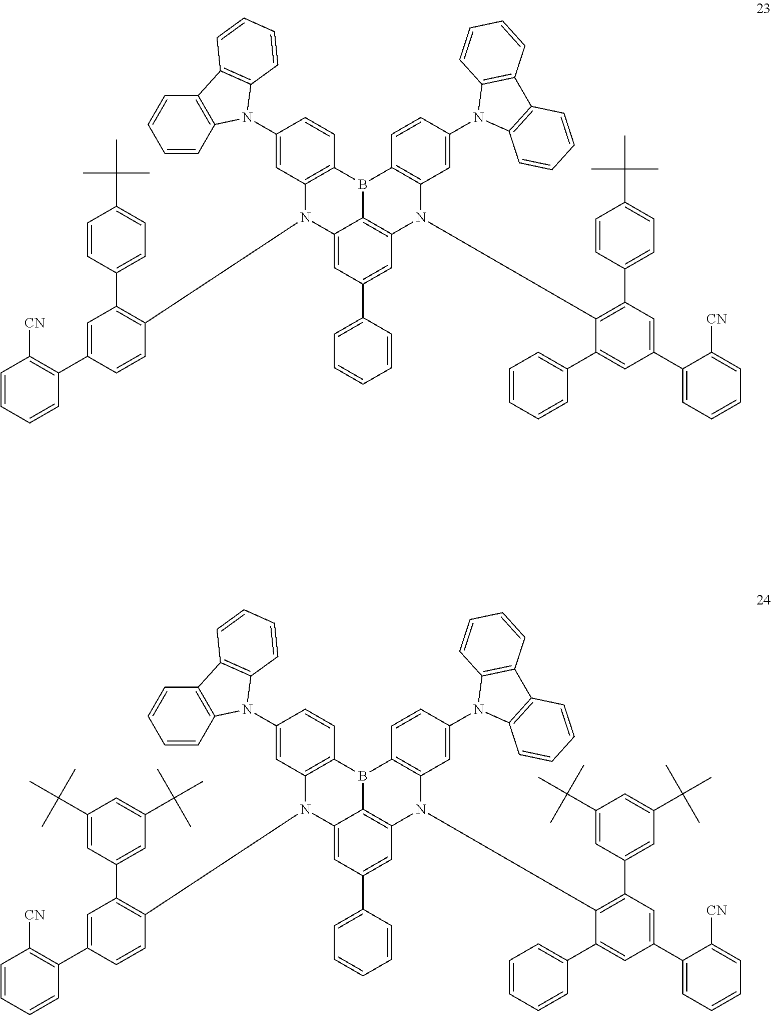 [SMILES: CC(C)(C)c1ccc(-c2cc(-c3ccccc3C#N)ccc2N2c3cc(-n4c5ccccc5c5ccccc54)ccc3B3c4ccc(-n5c6ccccc6c6ccccc65)cc4N(c4c(-c5ccccc5)cc(-c5ccccc5C#N)cc4-c4ccc(C(C)(C)C)cc4)c4cc(-c5ccccc5)cc2c43)cc1 ; CC(C)(C)c1cc(-c2cc(-c3ccccc3C#N)ccc2N2c3cc(-n4c5ccccc5c5ccccc54)ccc3B3c4ccc(-n5c6ccccc6c6ccccc65)cc4N(c4c(-c5ccccc5)cc(-c5ccccc5C#N)cc4-c4cc(C(C)(C)C)cc(C(C)(C)C)c4)c4cc(-c5ccccc5)cc2c43)cc(C(C)(C)C)c1] 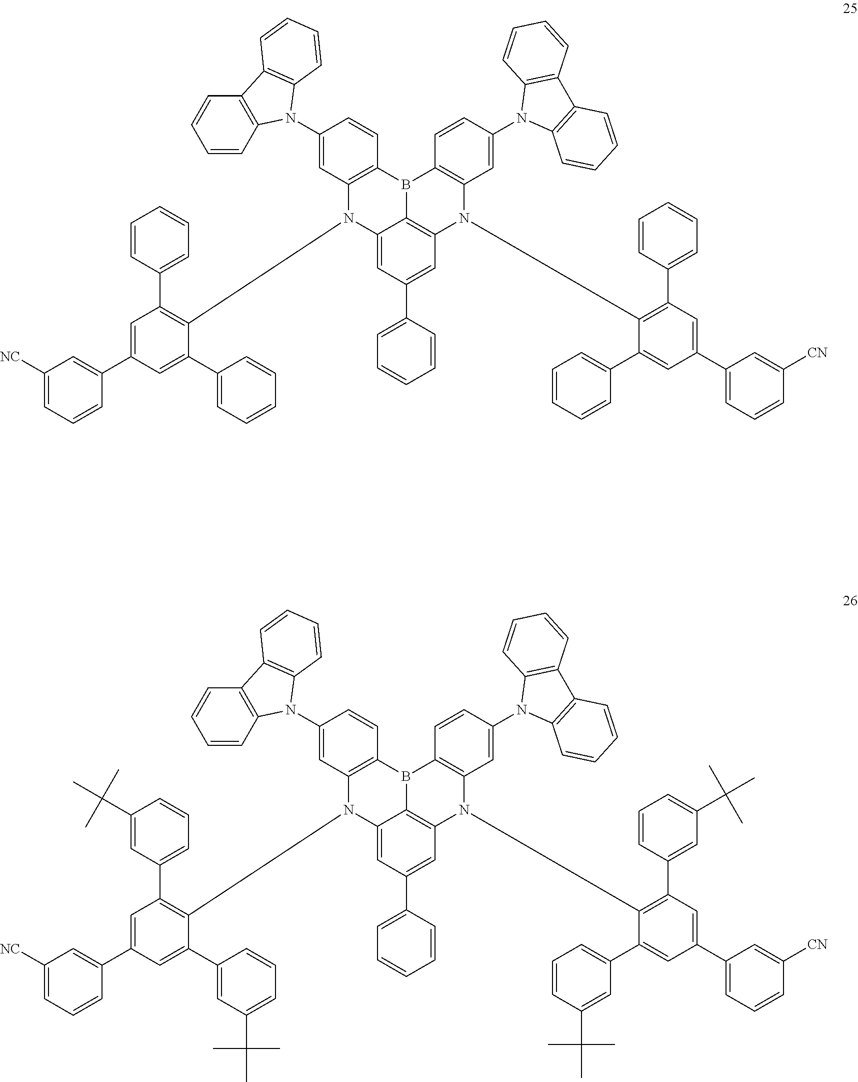 [SMILES: N#Cc1cccc(-c2cc(-c3ccccc3)c(N3c4cc(-n5c6ccccc6c6ccccc65)ccc4B4c5ccc(-n6c7ccccc7c7ccccc76)cc5N(c5c(-c6ccccc6)cc(-c6cccc(C#N)c6)cc5-c5ccccc5)c5cc(-c6ccccc6)cc3c54)c(-c3ccccc3)c2)c1 ; CC(C)(C)c1cccc(-c2cc(-c3cccc(C#N)c3)cc(-c3cccc(C(C)(C)C)c3)c2N2c3cc(-n4c5ccccc5c5ccccc54)ccc3B3c4ccc(-n5c6ccccc6c6ccccc65)cc4N(c4c(-c5cccc(C(C)(C)C)c5)cc(-c5cccc(C#N)c5)cc4-c4cccc(C(C)(C)C)c4)c4cc(-c5ccccc5)cc2c43)c1] 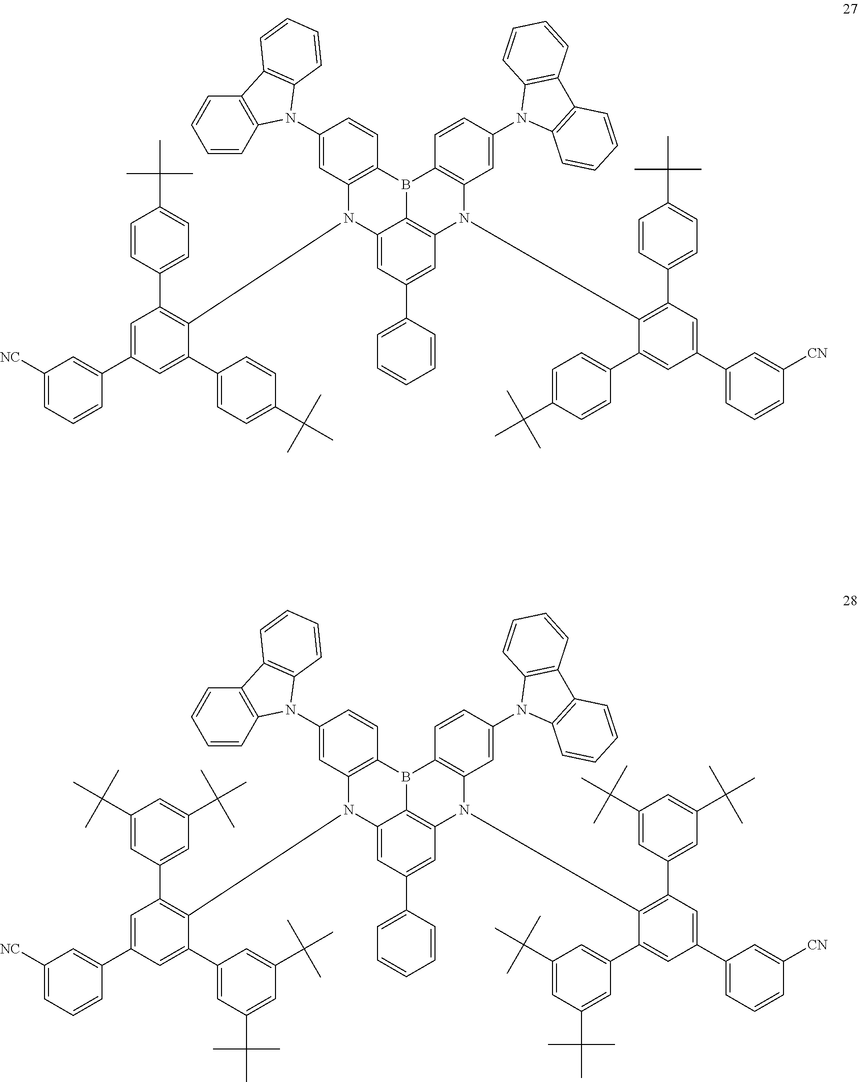 [SMILES: CC(C)(C)c1ccc(-c2cc(-c3cccc(C#N)c3)cc(-c3ccc(C(C)(C)C)cc3)c2N2c3cc(-n4c5ccccc5c5ccccc54)ccc3B3c4ccc(-n5c6ccccc6c6ccccc65)cc4N(c4c(-c5ccc(C(C)(C)C)cc5)cc(-c5cccc(C#N)c5)cc4-c4ccc(C(C)(C)C)cc4)c4cc(-c5ccccc5)cc2c43)cc1 ; CC(C)(C)c1cc(-c2cc(-c3cccc(C#N)c3)cc(-c3cc(C(C)(C)C)cc(C(C)(C)C)c3)c2N2c3cc(-n4c5ccccc5c5ccccc54)ccc3B3c4ccc(-n5c6ccccc6c6ccccc65)cc4N(c4c(-c5cc(C(C)(C)C)cc(C(C)(C)C)c5)cc(-c5cccc(C#N)c5)cc4-c4cc(C(C)(C)C)cc(C(C)(C)C)c4)c4cc(-c5ccccc5)cc2c43)cc(C(C)(C)C)c1] 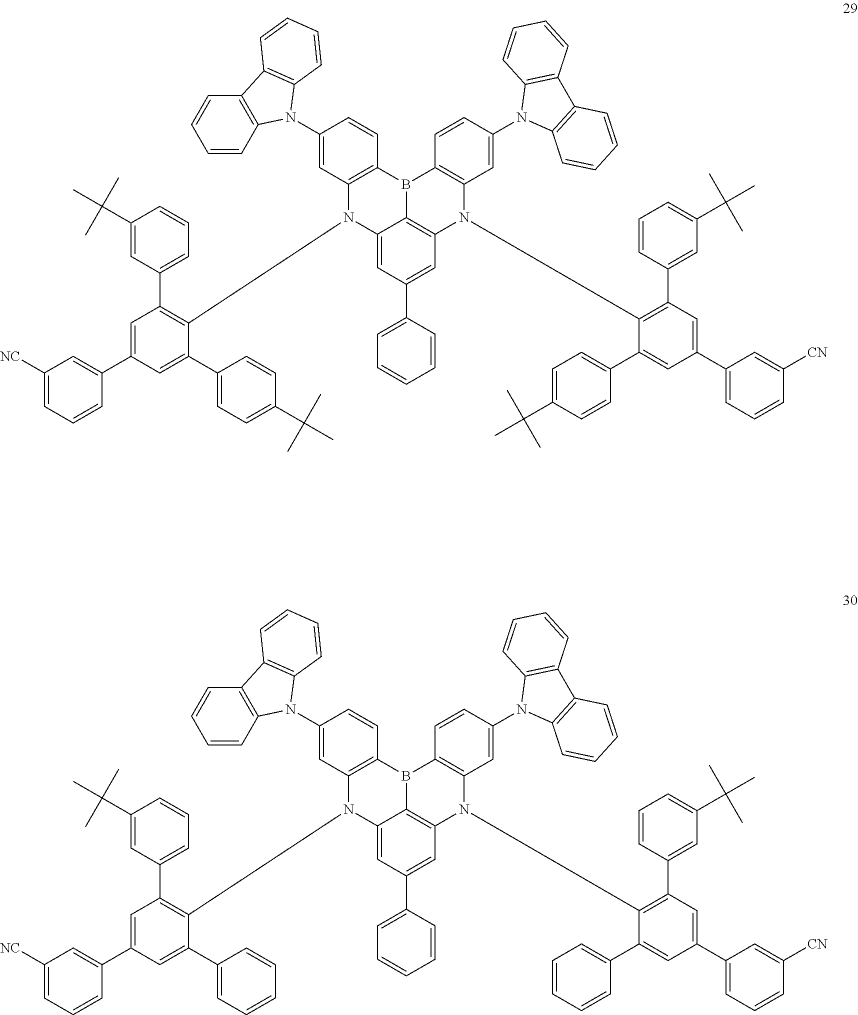 [SMILES: CC(C)(C)c1ccc(-c2cc(-c3cccc(C#N)c3)cc(-c3cccc(C(C)(C)C)c3)c2N2c3cc(-n4c5ccccc5c5ccccc54)ccc3B3c4ccc(-n5c6ccccc6c6ccccc65)cc4N(c4c(-c5ccc(C(C)(C)C)cc5)cc(-c5cccc(C#N)c5)cc4-c4cccc(C(C)(C)C)c4)c4cc(-c5ccccc5)cc2c43)cc1 ; CC(C)(C)c1cccc(-c2cc(-c3cccc(C#N)c3)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5cccc(C#N)c5)cc4-c4cccc(C(C)(C)C)c4)c4cc(-c5ccccc5)cc2c43)c1] 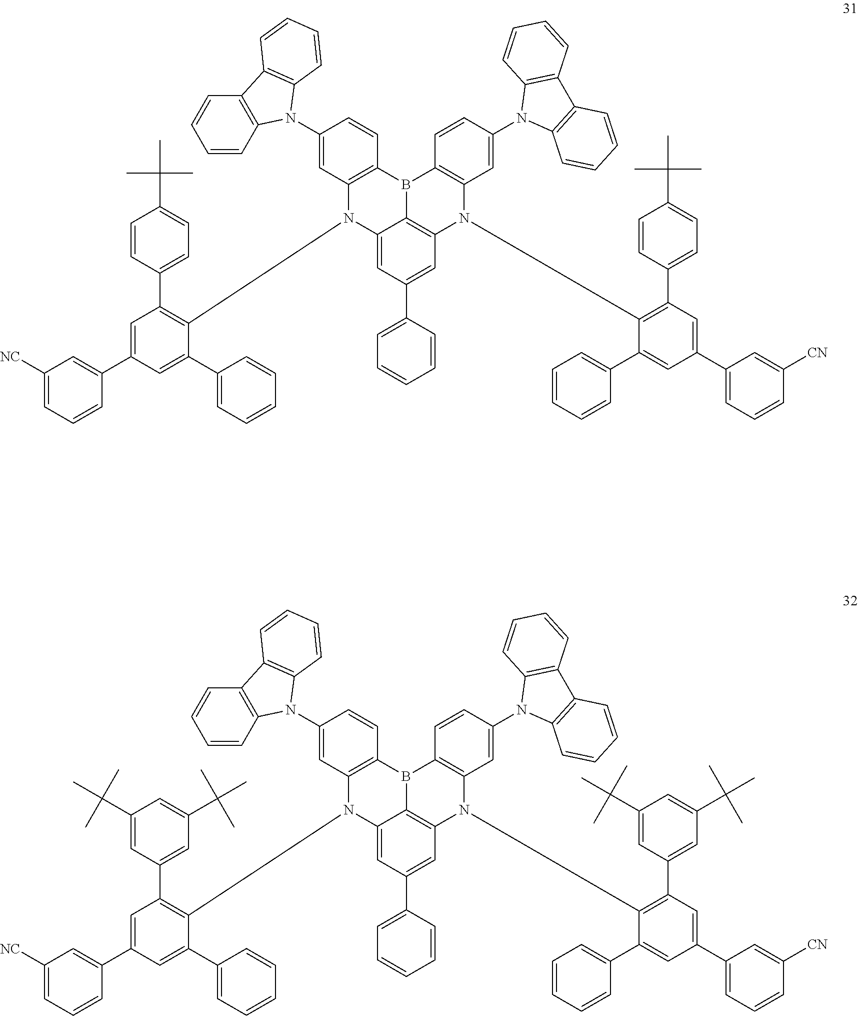 [SMILES: CC(C)(C)c1ccc(-c2cc(-c3cccc(C#N)c3)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5cccc(C#N)c5)cc4-c4ccc(C(C)(C)C)cc4)c4cc(-c5ccccc5)cc2c43)cc1 ; CC(C)(C)c1cc(-c2cc(-c3cccc(C#N)c3)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5cccc(C#N)c5)cc4-c4cc(C(C)(C)C)cc(C(C)(C)C)c4)c4cc(-c5ccccc5)cc2c43)cc(C(C)(C)C)c1] 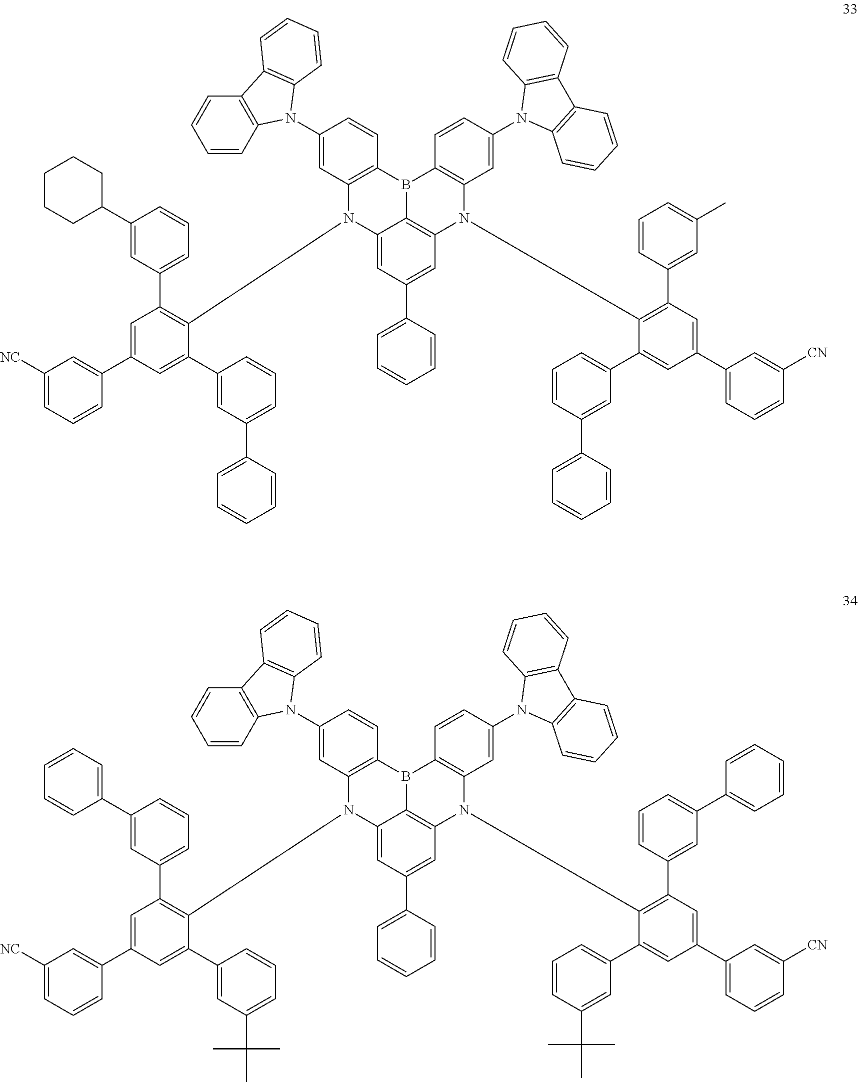 [SMILES: Cc1cccc(-c2cc(-c3cccc(C#N)c3)cc(-c3cccc(-c4ccccc4)c3)c2N2c3cc(-n4c5ccccc5c5ccccc54)ccc3B3c4ccc(-n5c6ccccc6c6ccccc65)cc4N(c4c(-c5cccc(-c6ccccc6)c5)cc(-c5cccc(C#N)c5)cc4-c4cccc(C5CCCCC5)c4)c4cc(-c5ccccc5)cc2c43)c1 ; CC(C)(C)c1cccc(-c2cc(-c3cccc(C#N)c3)cc(-c3cccc(-c4ccccc4)c3)c2N2c3cc(-n4c5ccccc5c5ccccc54)ccc3B3c4ccc(-n5c6ccccc6c6ccccc65)cc4N(c4c(-c5cccc(-c6ccccc6)c5)cc(-c5cccc(C#N)c5)cc4-c4cccc(C(C)(C)C)c4)c4cc(-c5ccccc5)cc2c43)c1] 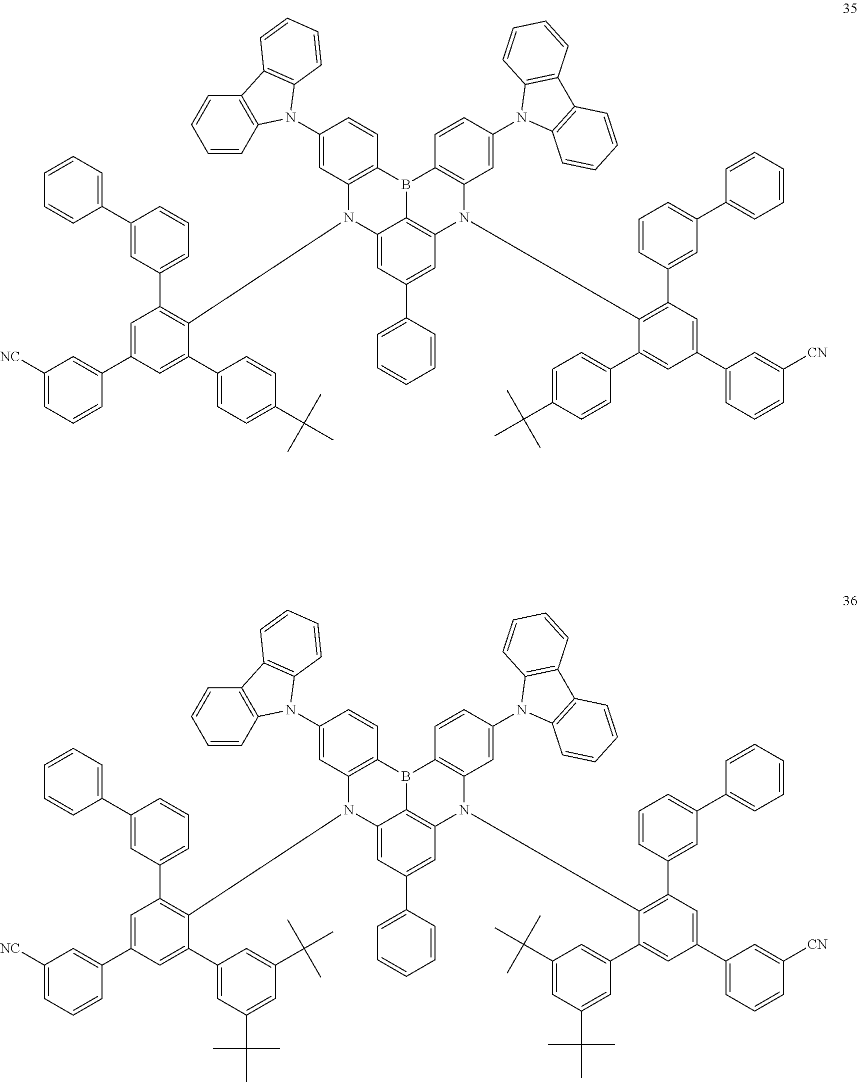 [SMILES: CC(C)(C)c1ccc(-c2cc(-c3cccc(C#N)c3)cc(-c3cccc(-c4ccccc4)c3)c2N2c3cc(-n4c5ccccc5c5ccccc54)ccc3B3c4ccc(-n5c6ccccc6c6ccccc65)cc4N(c4c(-c5ccc(C(C)(C)C)cc5)cc(-c5cccc(C#N)c5)cc4-c4cccc(-c5ccccc5)c4)c4cc(-c5ccccc5)cc2c43)cc1 ; CC(C)(C)c1cc(-c2cc(-c3cccc(C#N)c3)cc(-c3cccc(-c4ccccc4)c3)c2N2c3cc(-n4c5ccccc5c5ccccc54)ccc3B3c4ccc(-n5c6ccccc6c6ccccc65)cc4N(c4c(-c5cccc(-c6ccccc6)c5)cc(-c5cccc(C#N)c5)cc4-c4cc(C(C)(C)C)cc(C(C)(C)C)c4)c4cc(-c5ccccc5)cc2c43)cc(C(C)(C)C)c1] 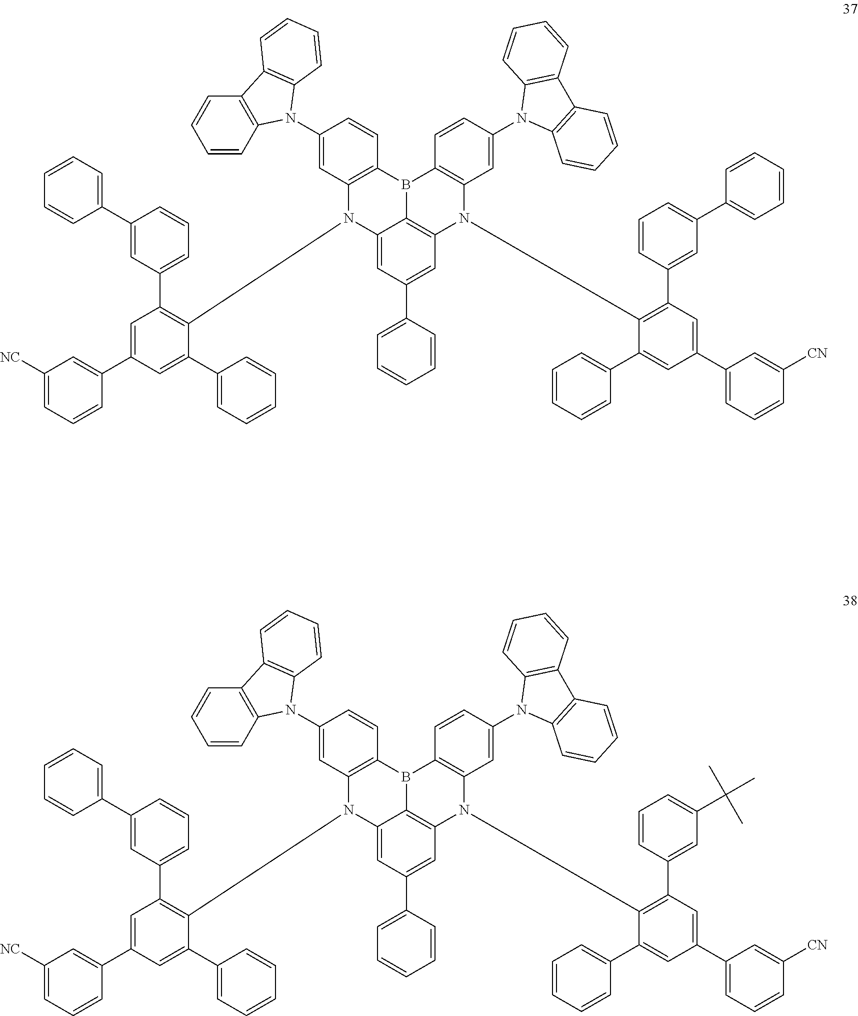 [SMILES: N#Cc1cccc(-c2cc(-c3ccccc3)c(N3c4cc(-n5c6ccccc6c6ccccc65)ccc4B4c5ccc(-n6c7ccccc7c7ccccc76)cc5N(c5c(-c6ccccc6)cc(-c6cccc(C#N)c6)cc5-c5cccc(-c6ccccc6)c5)c5cc(-c6ccccc6)cc3c54)c(-c3cccc(-c4ccccc4)c3)c2)c1 ; CC(C)(C)c1cccc(-c2cc(-c3cccc(C#N)c3)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5cccc(C#N)c5)cc4-c4cccc(-c5ccccc5)c4)c4cc(-c5ccccc5)cc2c43)c1] 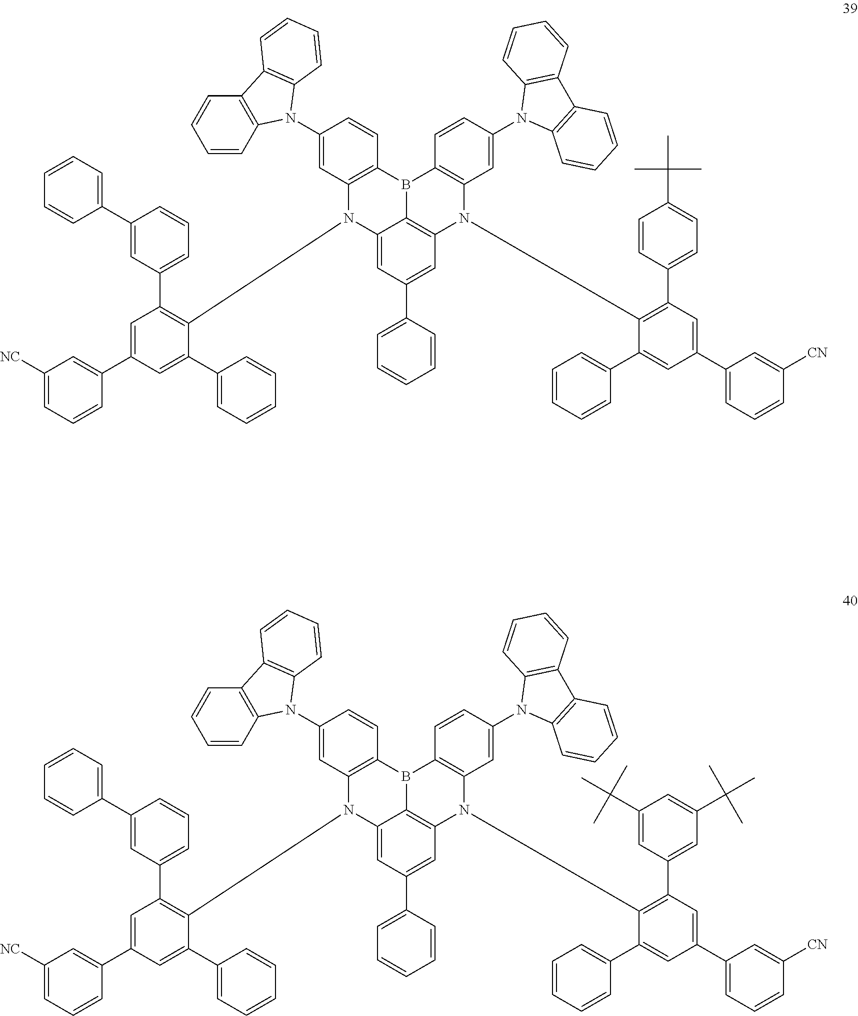 [SMILES: CC(C)(C)c1ccc(-c2cc(-c3cccc(C#N)c3)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5cccc(C#N)c5)cc4-c4cccc(-c5ccccc5)c4)c4cc(-c5ccccc5)cc2c43)cc1 ; CC(C)(C)c1cc(-c2cc(-c3cccc(C#N)c3)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5cccc(C#N)c5)cc4-c4cccc(-c5ccccc5)c4)c4cc(-c5ccccc5)cc2c43)cc(C(C)(C)C)c1] 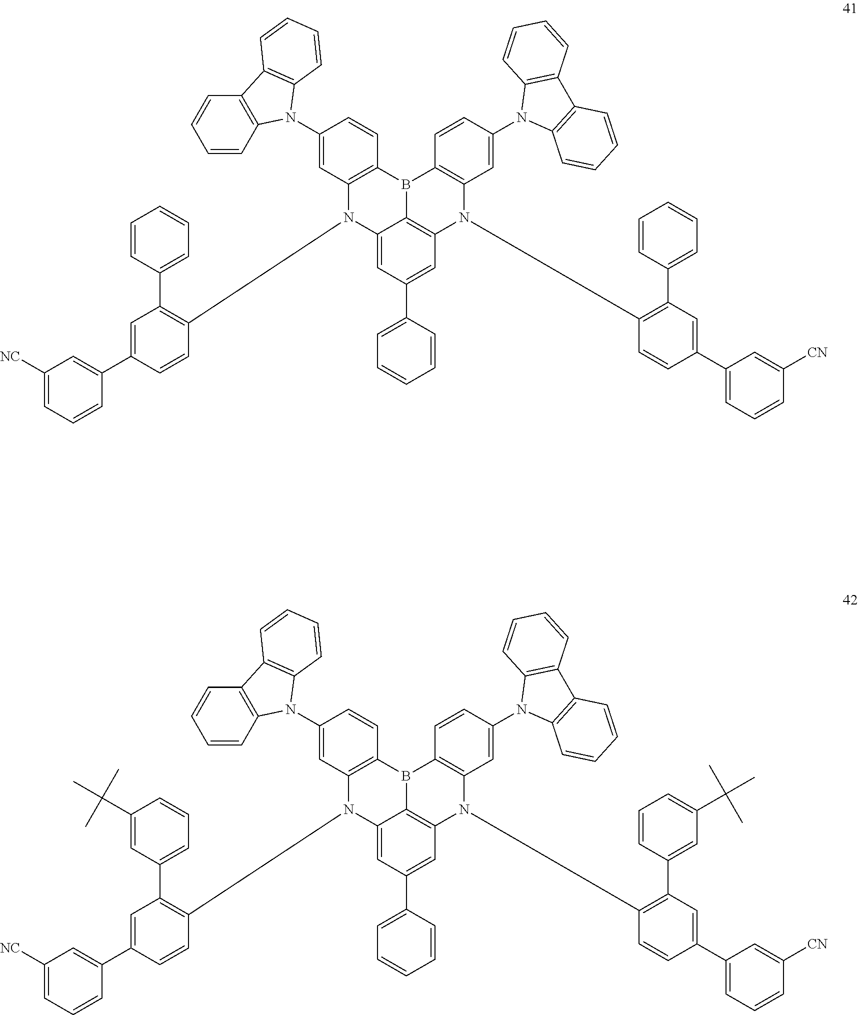 [SMILES: N#Cc1cccc(-c2ccc(N3c4cc(-n5c6ccccc6c6ccccc65)ccc4B4c5ccc(-n6c7ccccc7c7ccccc76)cc5N(c5ccc(-c6cccc(C#N)c6)cc5-c5ccccc5)c5cc(-c6ccccc6)cc3c54)c(-c3ccccc3)c2)c1 ; CC(C)(C)c1cccc(-c2cc(-c3cccc(C#N)c3)ccc2N2c3cc(-n4c5ccccc5c5ccccc54)ccc3B3c4ccc(-n5c6ccccc6c6ccccc65)cc4N(c4ccc(-c5cccc(C#N)c5)cc4-c4cccc(C(C)(C)C)c4)c4cc(-c5ccccc5)cc2c43)c1] 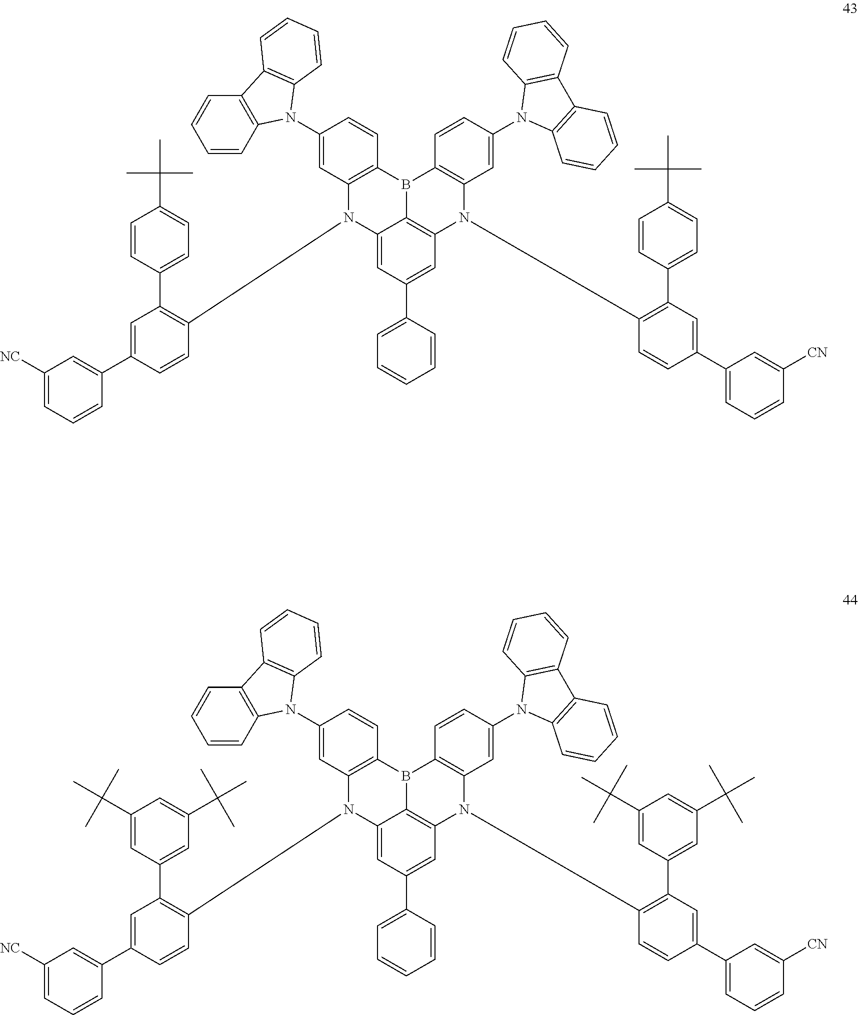 [SMILES: CC(C)(C)c1ccc(-c2cc(-c3cccc(C#N)c3)ccc2N2c3cc(-n4c5ccccc5c5ccccc54)ccc3B3c4ccc(-n5c6ccccc6c6ccccc65)cc4N(c4ccc(-c5cccc(C#N)c5)cc4-c4ccc(C(C)(C)C)cc4)c4cc(-c5ccccc5)cc2c43)cc1 ; CC(C)(C)c1cc(-c2cc(-c3cccc(C#N)c3)ccc2N2c3cc(-n4c5ccccc5c5ccccc54)ccc3B3c4ccc(-n5c6ccccc6c6ccccc65)cc4N(c4ccc(-c5cccc(C#N)c5)cc4-c4cc(C(C)(C)C)cc(C(C)(C)C)c4)c4cc(-c5ccccc5)cc2c43)cc(C(C)(C)C)c1] 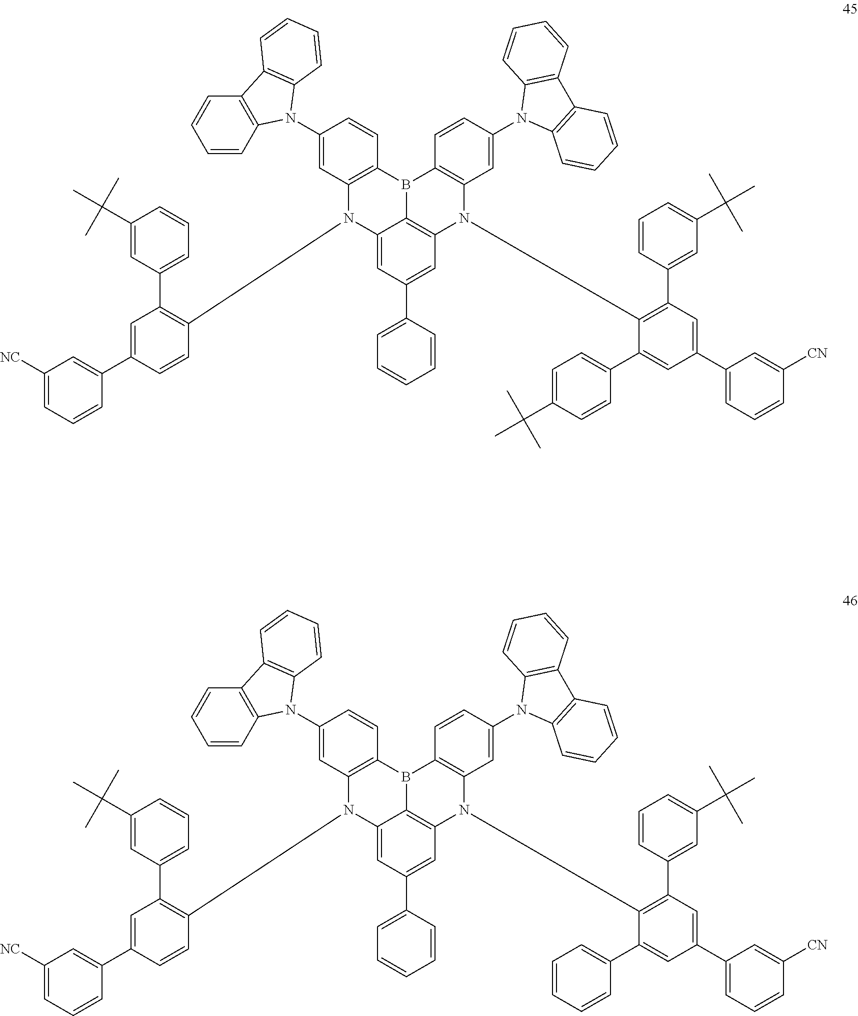 [SMILES: CC(C)(C)c1ccc(-c2cc(-c3cccc(C#N)c3)cc(-c3cccc(C(C)(C)C)c3)c2N2c3cc(-n4c5ccccc5c5ccccc54)ccc3B3c4ccc(-n5c6ccccc6c6ccccc65)cc4N(c4ccc(-c5cccc(C#N)c5)cc4-c4cccc(C(C)(C)C)c4)c4cc(-c5ccccc5)cc2c43)cc1 ; CC(C)(C)c1cccc(-c2cc(-c3cccc(C#N)c3)ccc2N2c3cc(-n4c5ccccc5c5ccccc54)ccc3B3c4ccc(-n5c6ccccc6c6ccccc65)cc4N(c4c(-c5ccccc5)cc(-c5cccc(C#N)c5)cc4-c4cccc(C(C)(C)C)c4)c4cc(-c5ccccc5)cc2c43)c1] 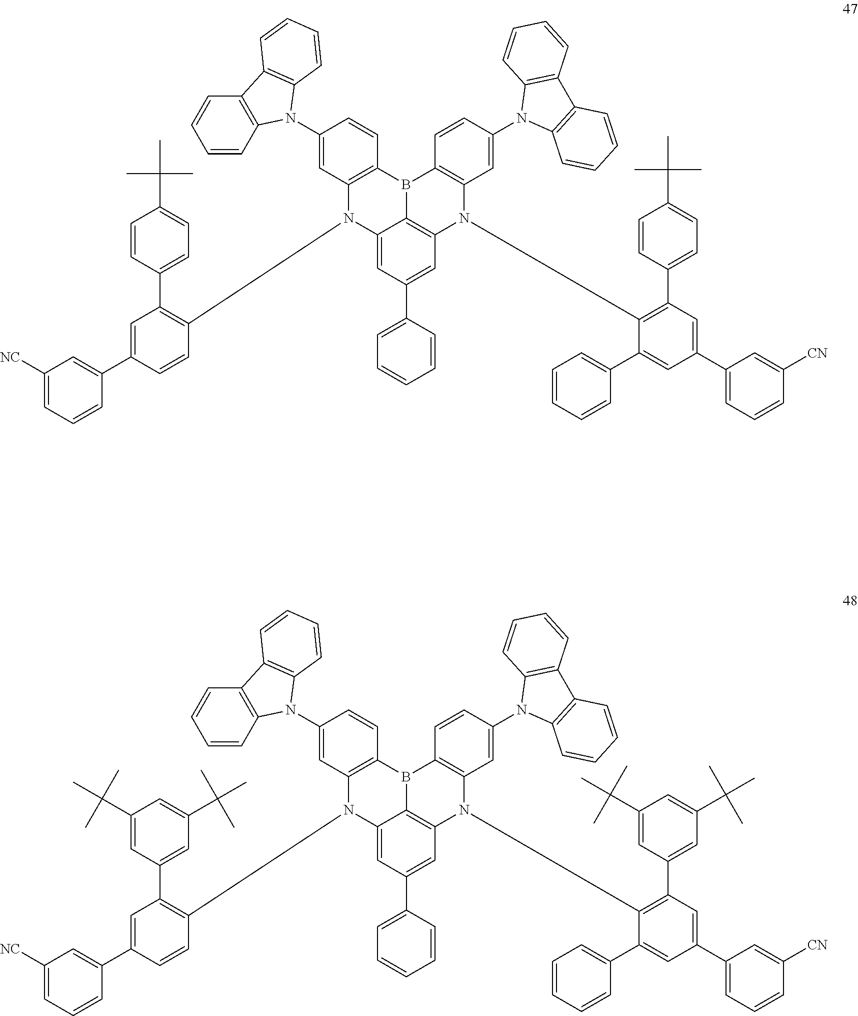 [SMILES: CC(C)(C)c1ccc(-c2cc(-c3cccc(C#N)c3)ccc2N2c3cc(-n4c5ccccc5c5ccccc54)ccc3B3c4ccc(-n5c6ccccc6c6ccccc65)cc4N(c4c(-c5ccccc5)cc(-c5cccc(C#N)c5)cc4-c4ccc(C(C)(C)C)cc4)c4cc(-c5ccccc5)cc2c43)cc1 ; CC(C)(C)c1cc(-c2cc(-c3cccc(C#N)c3)ccc2N2c3cc(-n4c5ccccc5c5ccccc54)ccc3B3c4ccc(-n5c6ccccc6c6ccccc65)cc4N(c4c(-c5ccccc5)cc(-c5cccc(C#N)c5)cc4-c4cc(C(C)(C)C)cc(C(C)(C)C)c4)c4cc(-c5ccccc5)cc2c43)cc(C(C)(C)C)c1] 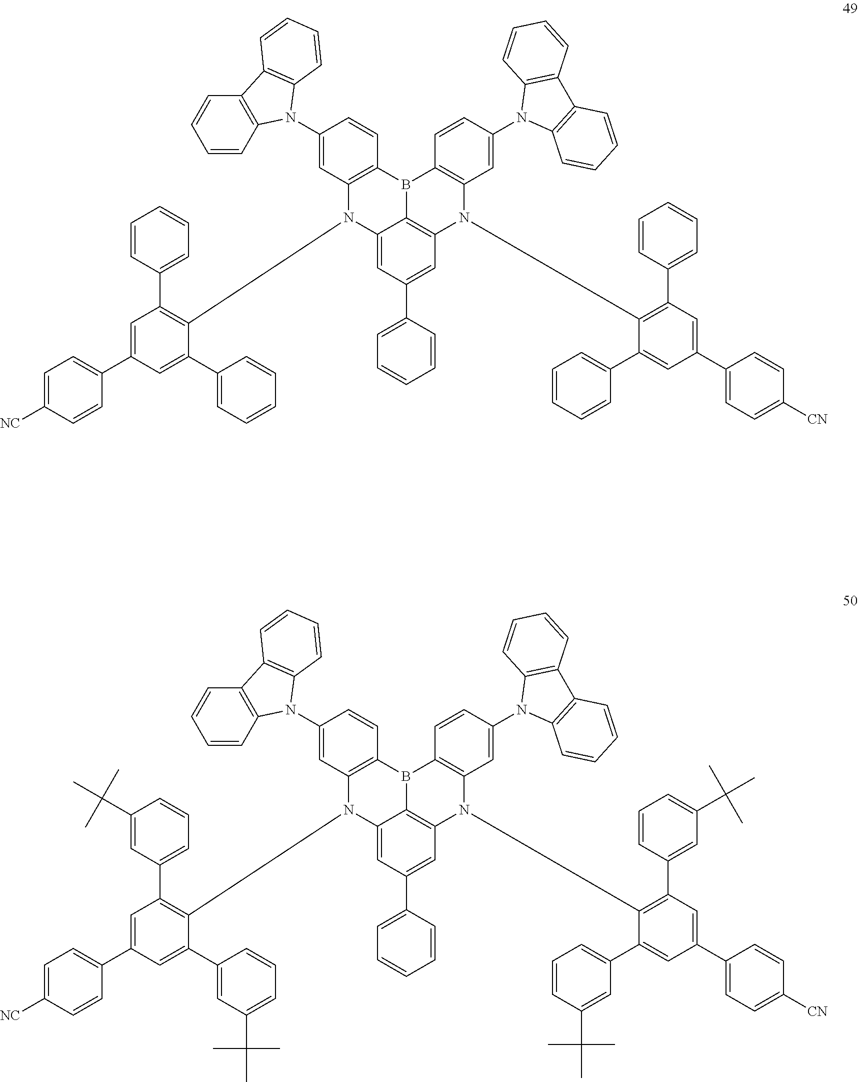 [SMILES: N#Cc1ccc(-c2cc(-c3ccccc3)c(N3c4cc(-n5c6ccccc6c6ccccc65)ccc4B4c5ccc(-n6c7ccccc7c7ccccc76)cc5N(c5c(-c6ccccc6)cc(-c6ccc(C#N)cc6)cc5-c5ccccc5)c5cc(-c6ccccc6)cc3c54)c(-c3ccccc3)c2)cc1 ; CC(C)(C)c1cccc(-c2cc(-c3ccc(C#N)cc3)cc(-c3cccc(C(C)(C)C)c3)c2N2c3cc(-n4c5ccccc5c5ccccc54)ccc3B3c4ccc(-n5c6ccccc6c6ccccc65)cc4N(c4c(-c5cccc(C(C)(C)C)c5)cc(-c5ccc(C#N)cc5)cc4-c4cccc(C(C)(C)C)c4)c4cc(-c5ccccc5)cc2c43)c1] 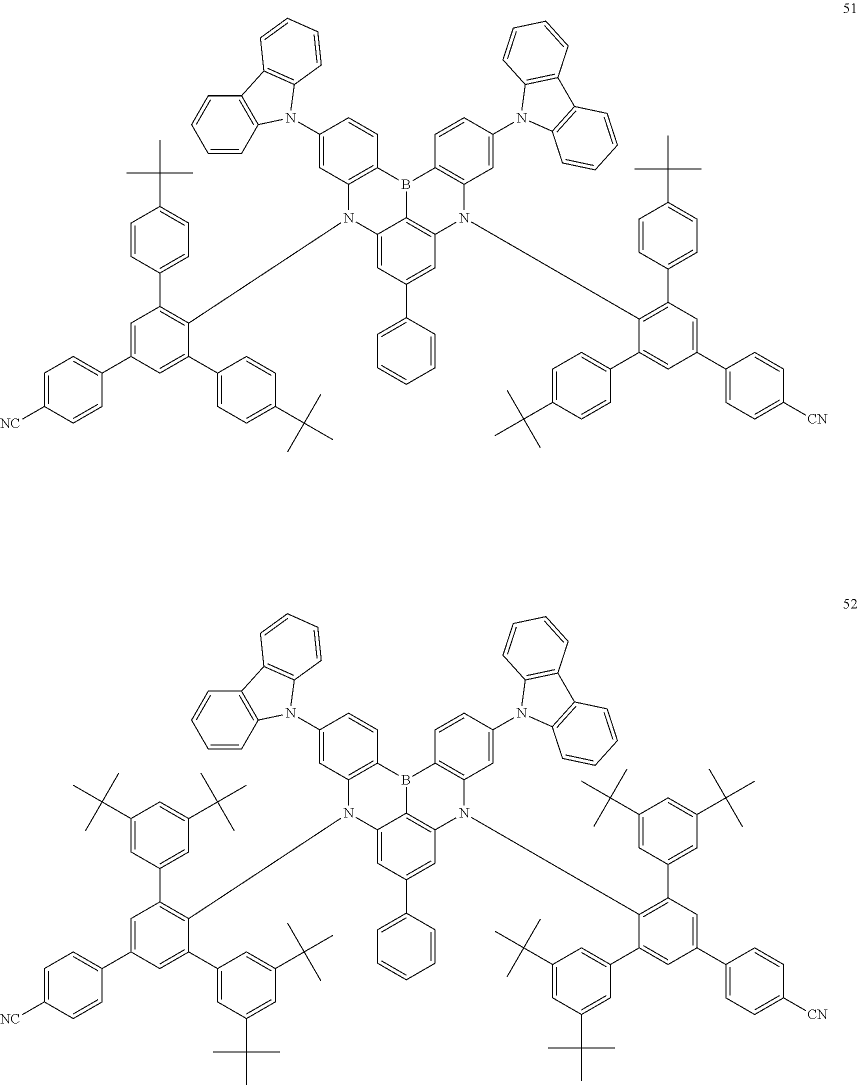 [SMILES: CC(C)(C)c1ccc(-c2cc(-c3ccc(C#N)cc3)cc(-c3ccc(C(C)(C)C)cc3)c2N2c3cc(-n4c5ccccc5c5ccccc54)ccc3B3c4ccc(-n5c6ccccc6c6ccccc65)cc4N(c4c(-c5ccc(C(C)(C)C)cc5)cc(-c5ccc(C#N)cc5)cc4-c4ccc(C(C)(C)C)cc4)c4cc(-c5ccccc5)cc2c43)cc1 ; CC(C)(C)c1cc(-c2cc(-c3ccc(C#N)cc3)cc(-c3cc(C(C)(C)C)cc(C(C)(C)C)c3)c2N2c3cc(-n4c5ccccc5c5ccccc54)ccc3B3c4ccc(-n5c6ccccc6c6ccccc65)cc4N(c4c(-c5cc(C(C)(C)C)cc(C(C)(C)C)c5)cc(-c5ccc(C#N)cc5)cc4-c4cc(C(C)(C)C)cc(C(C)(C)C)c4)c4cc(-c5ccccc5)cc2c43)cc(C(C)(C)C)c1] 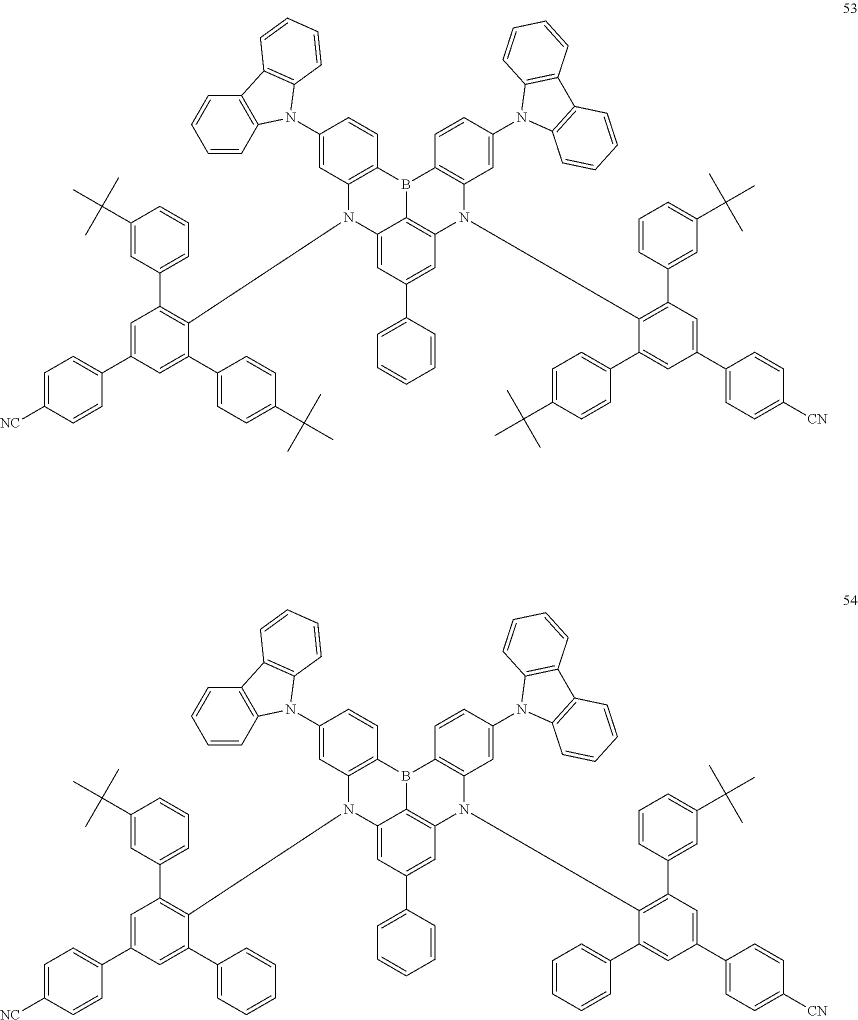 [SMILES: CC(C)(C)c1ccc(-c2cc(-c3ccc(C#N)cc3)cc(-c3cccc(C(C)(C)C)c3)c2N2c3cc(-n4c5ccccc5c5ccccc54)ccc3B3c4ccc(-n5c6ccccc6c6ccccc65)cc4N(c4c(-c5ccc(C(C)(C)C)cc5)cc(-c5ccc(C#N)cc5)cc4-c4cccc(C(C)(C)C)c4)c4cc(-c5ccccc5)cc2c43)cc1 ; CC(C)(C)c1cccc(-c2cc(-c3ccc(C#N)cc3)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5ccc(C#N)cc5)cc4-c4cccc(C(C)(C)C)c4)c4cc(-c5ccccc5)cc2c43)c1] 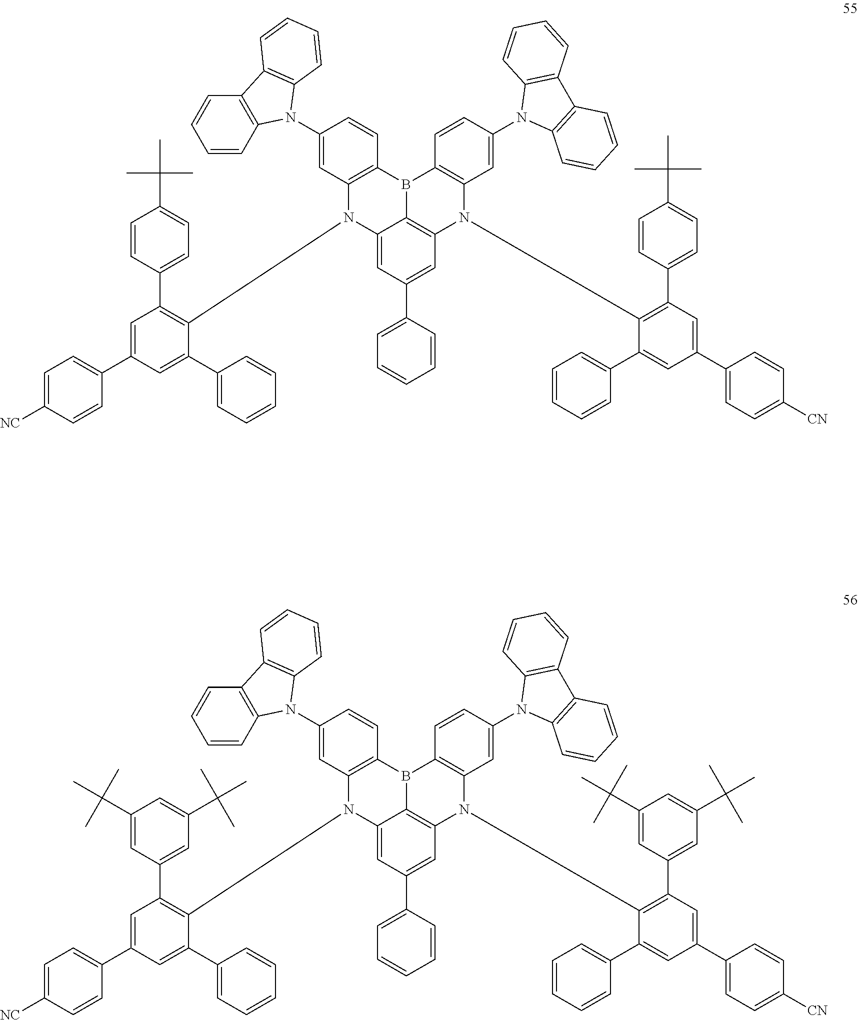 [SMILES: CC(C)(C)c1ccc(-c2cc(-c3ccc(C#N)cc3)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5ccc(C#N)cc5)cc4-c4ccc(C(C)(C)C)cc4)c4cc(-c5ccccc5)cc2c43)cc1 ; CC(C)(C)c1cc(-c2cc(-c3ccc(C#N)cc3)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5ccc(C#N)cc5)cc4-c4cc(C(C)(C)C)cc(C(C)(C)C)c4)c4cc(-c5ccccc5)cc2c43)cc(C(C)(C)C)c1] 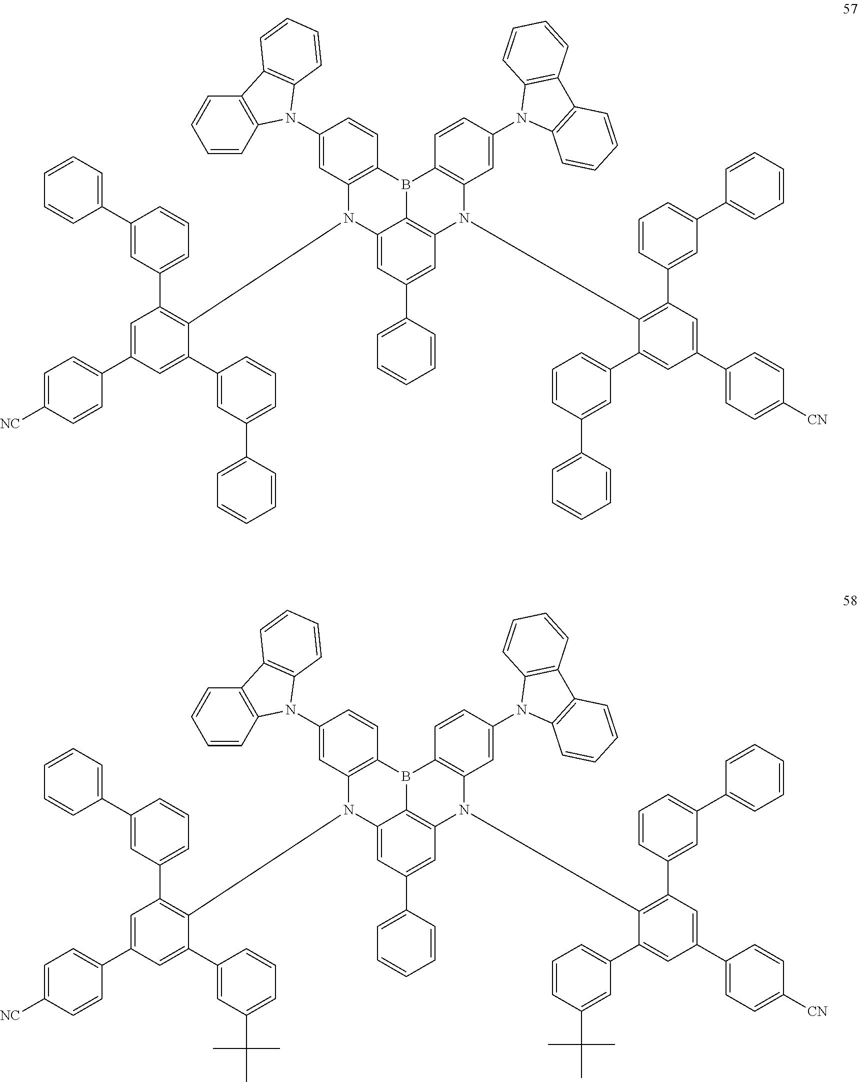 [SMILES: N#Cc1ccc(-c2cc(-c3cccc(-c4ccccc4)c3)c(N3c4cc(-n5c6ccccc6c6ccccc65)ccc4B4c5ccc(-n6c7ccccc7c7ccccc76)cc5N(c5c(-c6cccc(-c7ccccc7)c6)cc(-c6ccc(C#N)cc6)cc5-c5cccc(-c6ccccc6)c5)c5cc(-c6ccccc6)cc3c54)c(-c3cccc(-c4ccccc4)c3)c2)cc1 ; CC(C)(C)c1cccc(-c2cc(-c3ccc(C#N)cc3)cc(-c3cccc(-c4ccccc4)c3)c2N2c3cc(-n4c5ccccc5c5ccccc54)ccc3B3c4ccc(-n5c6ccccc6c6ccccc65)cc4N(c4c(-c5cccc(-c6ccccc6)c5)cc(-c5ccc(C#N)cc5)cc4-c4cccc(C(C)(C)C)c4)c4cc(-c5ccccc5)cc2c43)c1] 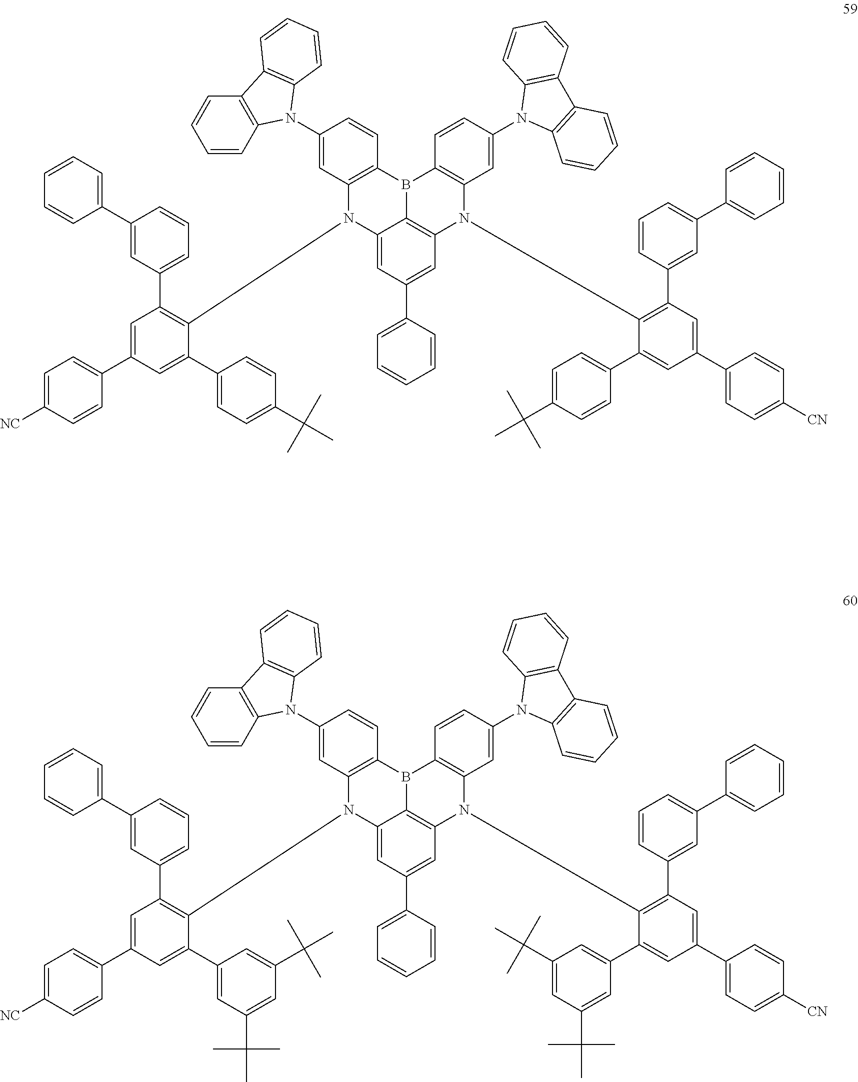 [SMILES: CC(C)(C)c1ccc(-c2cc(-c3ccc(C#N)cc3)cc(-c3cccc(-c4ccccc4)c3)c2N2c3cc(-n4c5ccccc5c5ccccc54)ccc3B3c4ccc(-n5c6ccccc6c6ccccc65)cc4N(c4c(-c5ccc(C(C)(C)C)cc5)cc(-c5ccc(C#N)cc5)cc4-c4cccc(-c5ccccc5)c4)c4cc(-c5ccccc5)cc2c43)cc1 ; CC(C)(C)c1cc(-c2cc(-c3ccc(C#N)cc3)cc(-c3cccc(-c4ccccc4)c3)c2N2c3cc(-n4c5ccccc5c5ccccc54)ccc3B3c4ccc(-n5c6ccccc6c6ccccc65)cc4N(c4c(-c5cccc(-c6ccccc6)c5)cc(-c5ccc(C#N)cc5)cc4-c4cc(C(C)(C)C)cc(C(C)(C)C)c4)c4cc(-c5ccccc5)cc2c43)cc(C(C)(C)C)c1] 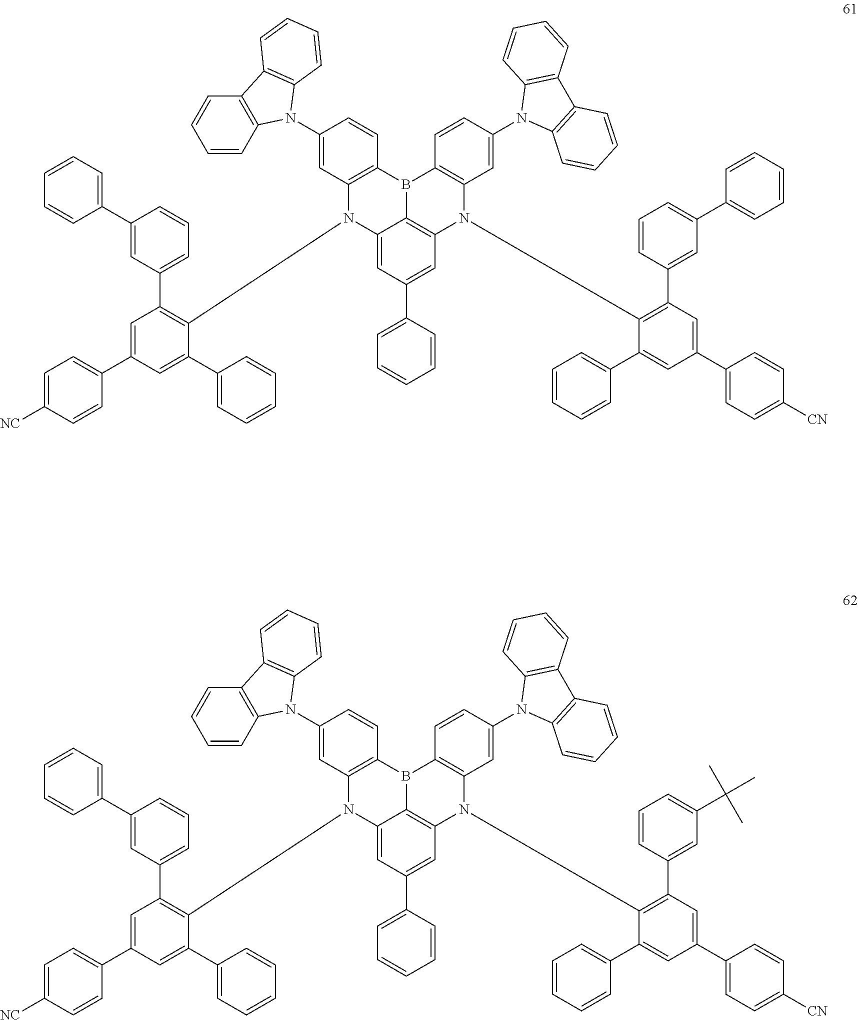 [SMILES: N#Cc1ccc(-c2cc(-c3ccccc3)c(N3c4cc(-n5c6ccccc6c6ccccc65)ccc4B4c5ccc(-n6c7ccccc7c7ccccc76)cc5N(c5c(-c6ccccc6)cc(-c6ccc(C#N)cc6)cc5-c5cccc(-c6ccccc6)c5)c5cc(-c6ccccc6)cc3c54)c(-c3cccc(-c4ccccc4)c3)c2)cc1 ; CC(C)(C)c1cccc(-c2cc(-c3ccc(C#N)cc3)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5ccc(C#N)cc5)cc4-c4cccc(-c5ccccc5)c4)c4cc(-c5ccccc5)cc2c43)c1] 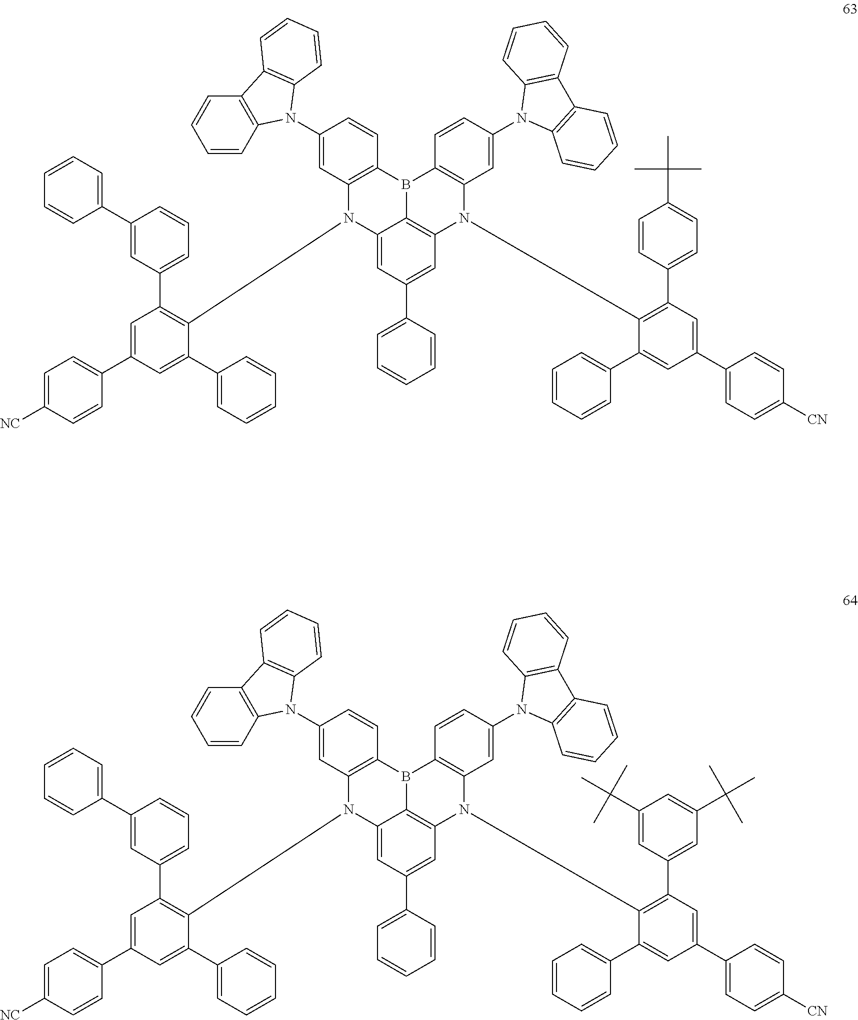 [SMILES: CC(C)(C)c1ccc(-c2cc(-c3ccc(C#N)cc3)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5ccc(C#N)cc5)cc4-c4cccc(-c5ccccc5)c4)c4cc(-c5ccccc5)cc2c43)cc1 ; CC(C)(C)c1cc(-c2cc(-c3ccc(C#N)cc3)cc(-c3ccccc3)c2N2c3cc(-n4c5ccccc5c5ccccc54)ccc3B3c4ccc(-n5c6ccccc6c6ccccc65)cc4N(c4c(-c5ccccc5)cc(-c5ccc(C#N)cc5)cc4-c4cccc(-c5ccccc5)c4)c4cc(-c5ccccc5)cc2c43)cc(C(C)(C)C)c1] 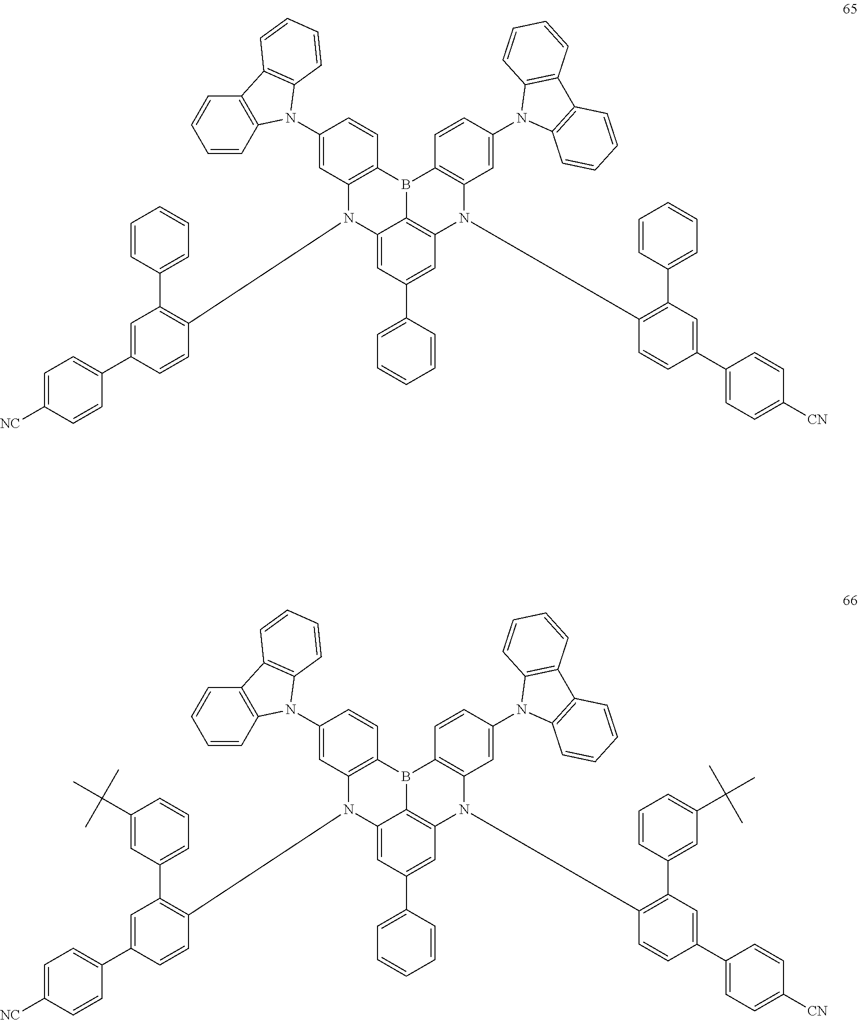 [SMILES: N#Cc1ccc(-c2ccc(N3c4cc(-n5c6ccccc6c6ccccc65)ccc4B4c5ccc(-n6c7ccccc7c7ccccc76)cc5N(c5ccc(-c6ccc(C#N)cc6)cc5-c5ccccc5)c5cc(-c6ccccc6)cc3c54)c(-c3ccccc3)c2)cc1 ; CC(C)(C)c1cccc(-c2cc(-c3ccc(C#N)cc3)ccc2N2c3cc(-n4c5ccccc5c5ccccc54)ccc3B3c4ccc(-n5c6ccccc6c6ccccc65)cc4N(c4ccc(-c5ccc(C#N)cc5)cc4-c4cccc(C(C)(C)C)c4)c4cc(-c5ccccc5)cc2c43)c1] 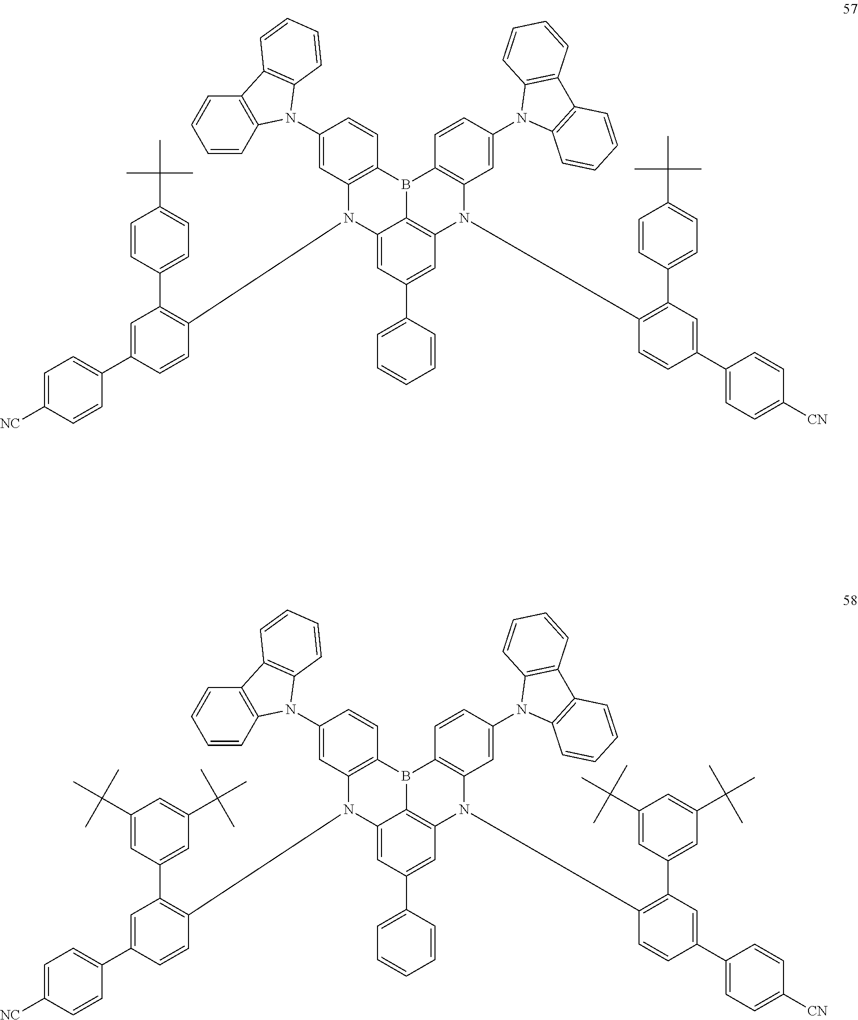 [SMILES: CC(C)(C)c1ccc(-c2cc(-c3ccc(C#N)cc3)ccc2N2c3cc(-n4c5ccccc5c5ccccc54)ccc3B3c4ccc(-n5c6ccccc6c6ccccc65)cc4N(c4ccc(-c5ccc(C#N)cc5)cc4-c4ccc(C(C)(C)C)cc4)c4cc(-c5ccccc5)cc2c43)cc1 ; CC(C)(C)c1cc(-c2cc(-c3ccc(C#N)cc3)ccc2N2c3cc(-n4c5ccccc5c5ccccc54)ccc3B3c4ccc(-n5c6ccccc6c6ccccc65)cc4N(c4ccc(-c5ccc(C#N)cc5)cc4-c4cc(C(C)(C)C)cc(C(C)(C)C)c4)c4cc(-c5ccccc5)cc2c43)cc(C(C)(C)C)c1] 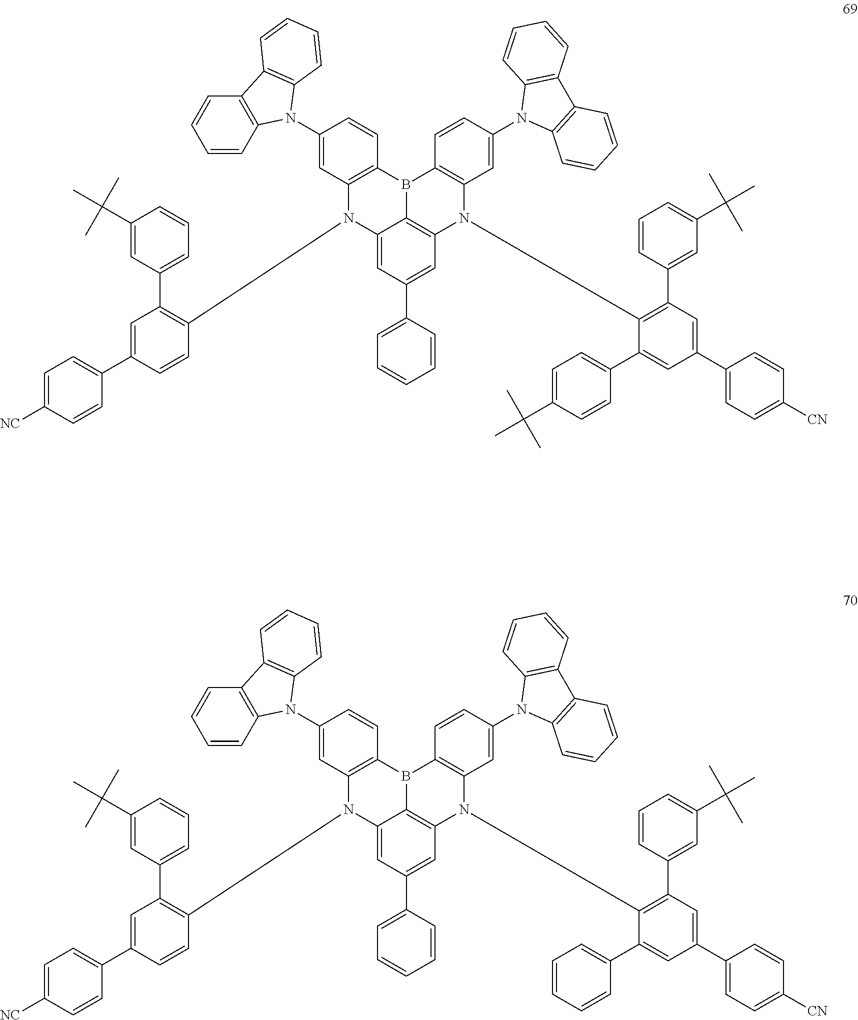 [SMILES: CC(C)(C)c1ccc(-c2cc(-c3ccc(C#N)cc3)cc(-c3cccc(C(C)(C)C)c3)c2N2c3cc(-n4c5ccccc5c5ccccc54)ccc3B3c4ccc(-n5c6ccccc6c6ccccc65)cc4N(c4ccc(-c5ccc(C#N)cc5)cc4-c4cccc(C(C)(C)C)c4)c4cc(-c5ccccc5)cc2c43)cc1 ; CC(C)(C)c1cccc(-c2cc(-c3ccc(C#N)cc3)ccc2N2c3cc(-n4c5ccccc5c5ccccc54)ccc3B3c4ccc(-n5c6ccccc6c6ccccc65)cc4N(c4c(-c5ccccc5)cc(-c5ccc(C#N)cc5)cc4-c4cccc(C(C)(C)C)c4)c4cc(-c5ccccc5)cc2c43)c1] 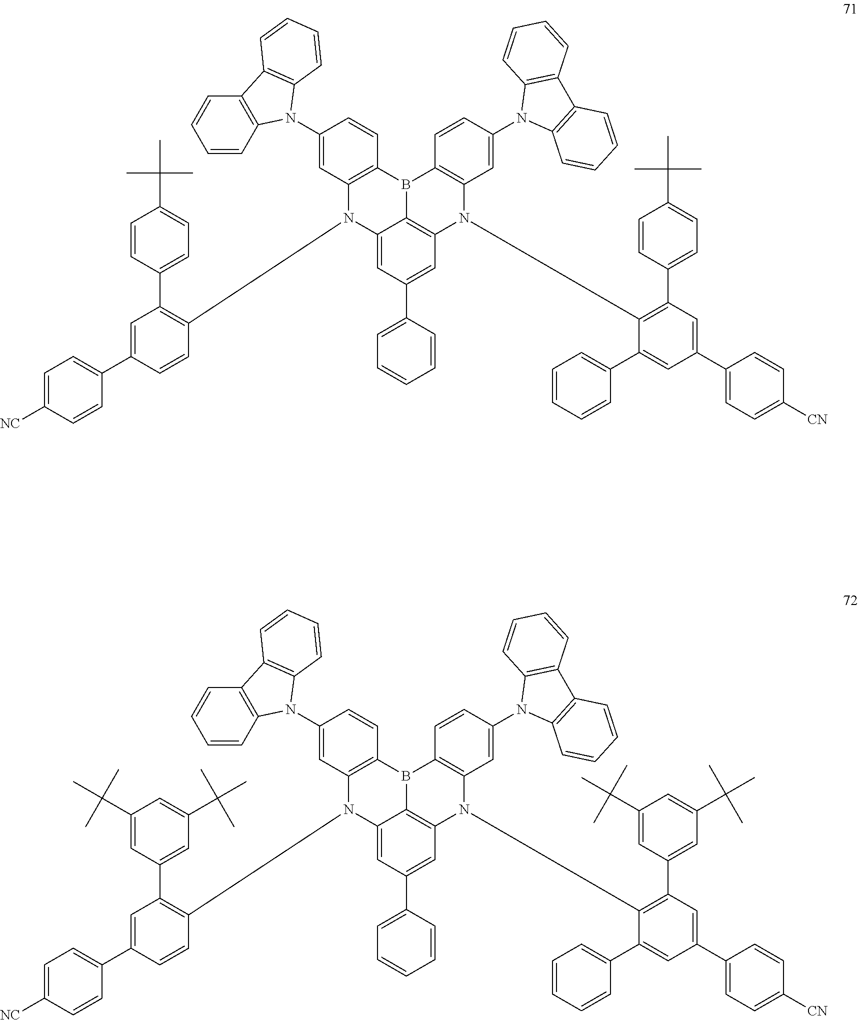 [SMILES: CC(C)(C)c1ccc(-c2cc(-c3ccc(C#N)cc3)ccc2N2c3cc(-n4c5ccccc5c5ccccc54)ccc3B3c4ccc(-n5c6ccccc6c6ccccc65)cc4N(c4c(-c5ccccc5)cc(-c5ccc(C#N)cc5)cc4-c4ccc(C(C)(C)C)cc4)c4cc(-c5ccccc5)cc2c43)cc1 ; CC(C)(C)c1cc(-c2cc(-c3ccc(C#N)cc3)ccc2N2c3cc(-n4c5ccccc5c5ccccc54)ccc3B3c4ccc(-n5c6ccccc6c6ccccc65)cc4N(c4c(-c5ccccc5)cc(-c5ccc(C#N)cc5)cc4-c4cc(C(C)(C)C)cc(C(C)(C)C)c4)c4cc(-c5ccccc5)cc2c43)cc(C(C)(C)C)c1] 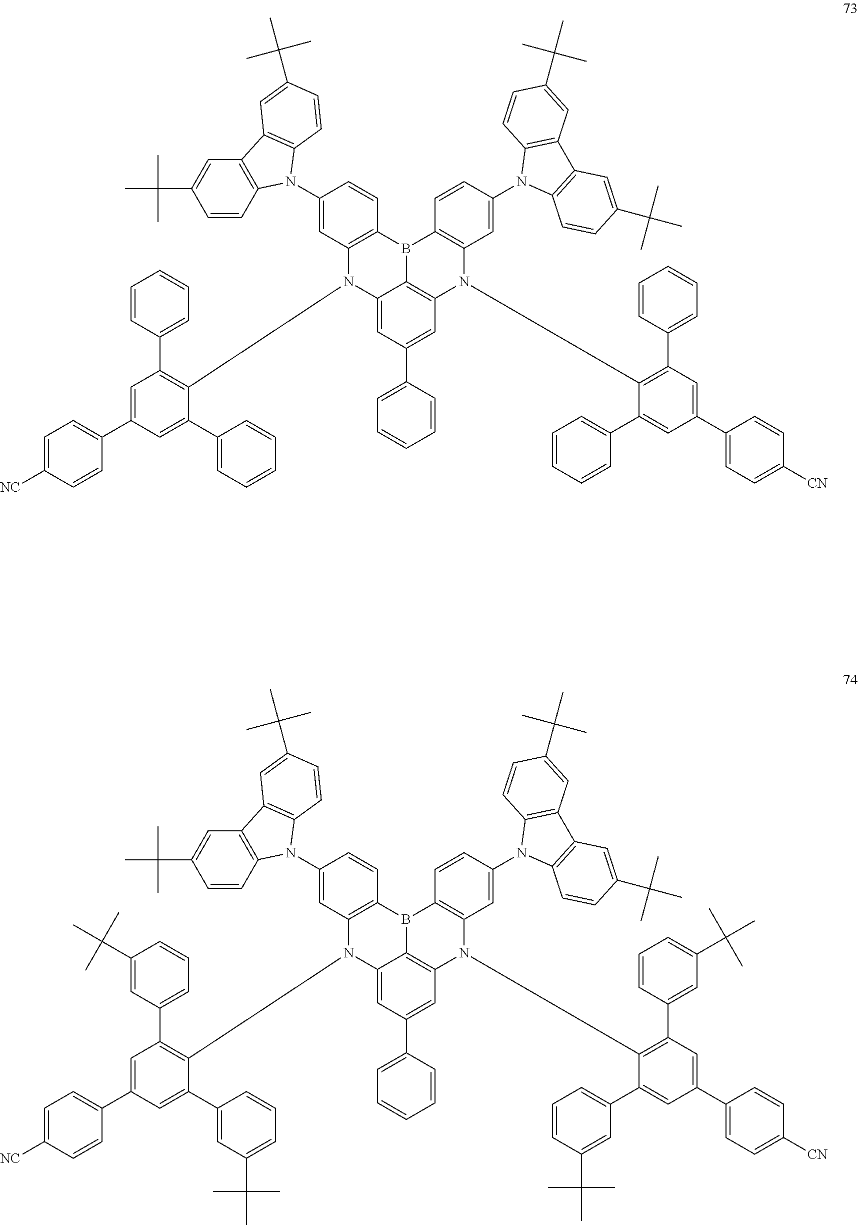 [SMILES: CC(C)(C)c1ccc2c(c1)c1cc(C(C)(C)C)ccc1n2-c1ccc2c(c1)N(c1c(-c3ccccc3)cc(-c3ccc(C#N)cc3)cc1-c1ccccc1)c1cc(-c3ccccc3)cc3c1B2c1ccc(-n2c4ccc(C(C)(C)C)cc4c4cc(C(C)(C)C)ccc42)cc1N3c1c(-c2ccccc2)cc(-c2ccc(C#N)cc2)cc1-c1ccccc1 ; CC(C)(C)c1cccc(-c2cc(-c3ccc(C#N)cc3)cc(-c3cccc(C(C)(C)C)c3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5cccc(C(C)(C)C)c5)cc(-c5ccc(C#N)cc5)cc4-c4cccc(C(C)(C)C)c4)c4cc(-c5ccccc5)cc2c43)c1] 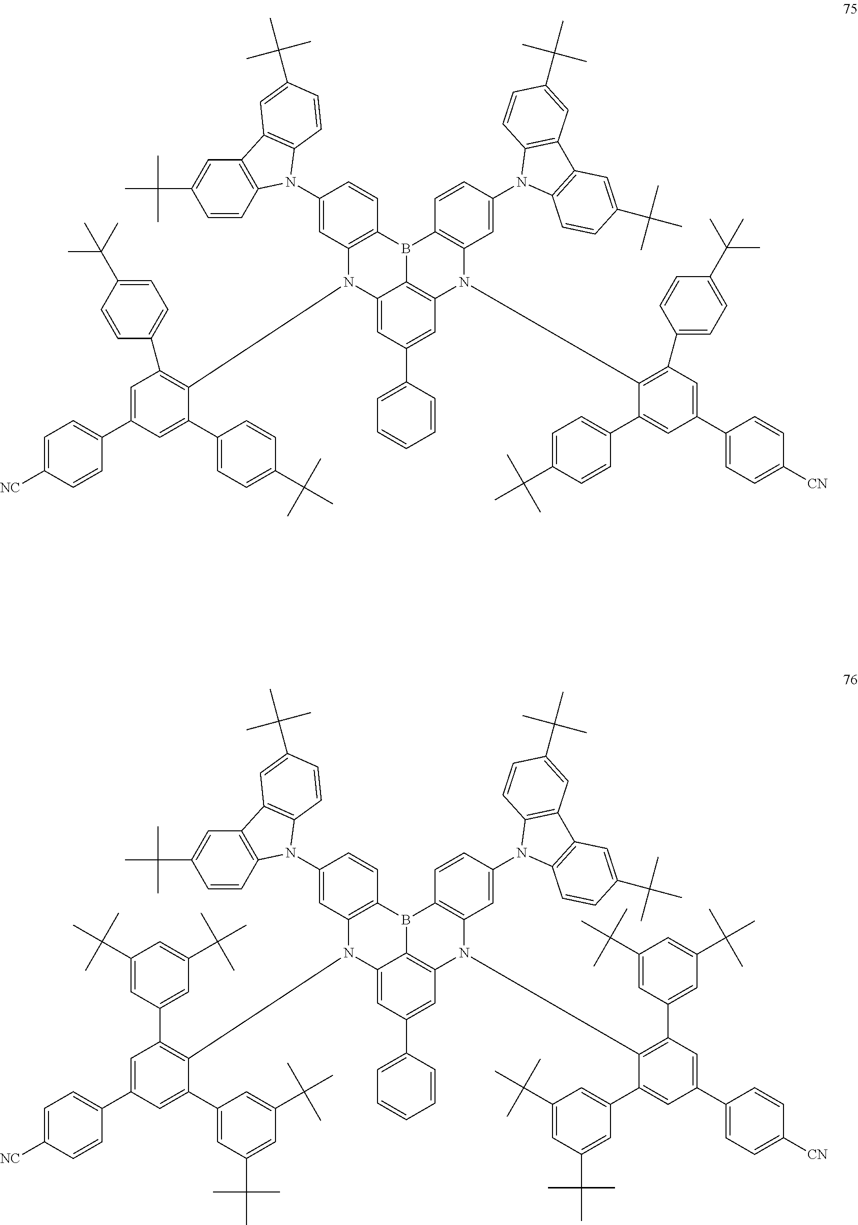 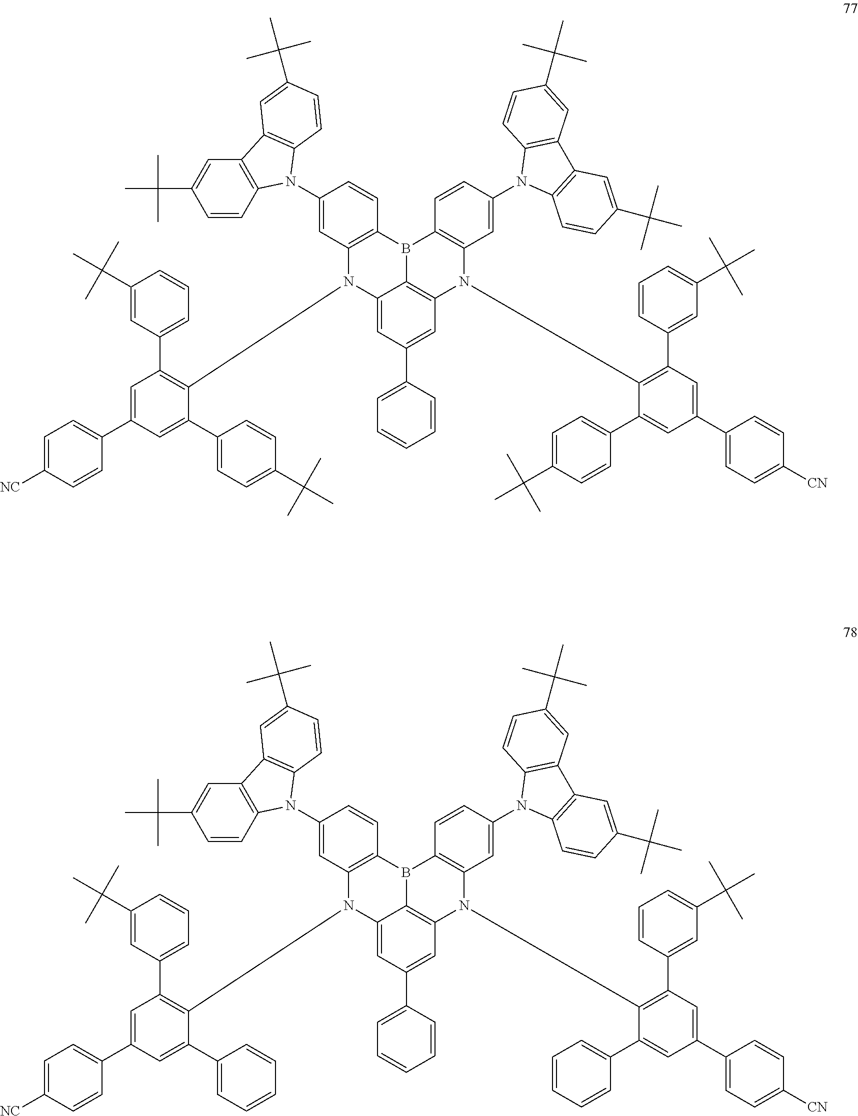 [SMILES: CC(C)(C)c1ccc(-c2cc(-c3ccc(C#N)cc3)cc(-c3cccc(C(C)(C)C)c3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccc(C(C)(C)C)cc5)cc(-c5ccc(C#N)cc5)cc4-c4cccc(C(C)(C)C)c4)c4cc(-c5ccccc5)cc2c43)cc1 ; CC(C)(C)c1cccc(-c2cc(-c3ccc(C#N)cc3)cc(-c3ccccc3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(-c5ccc(C#N)cc5)cc4-c4cccc(C(C)(C)C)c4)c4cc(-c5ccccc5)cc2c43)c1] 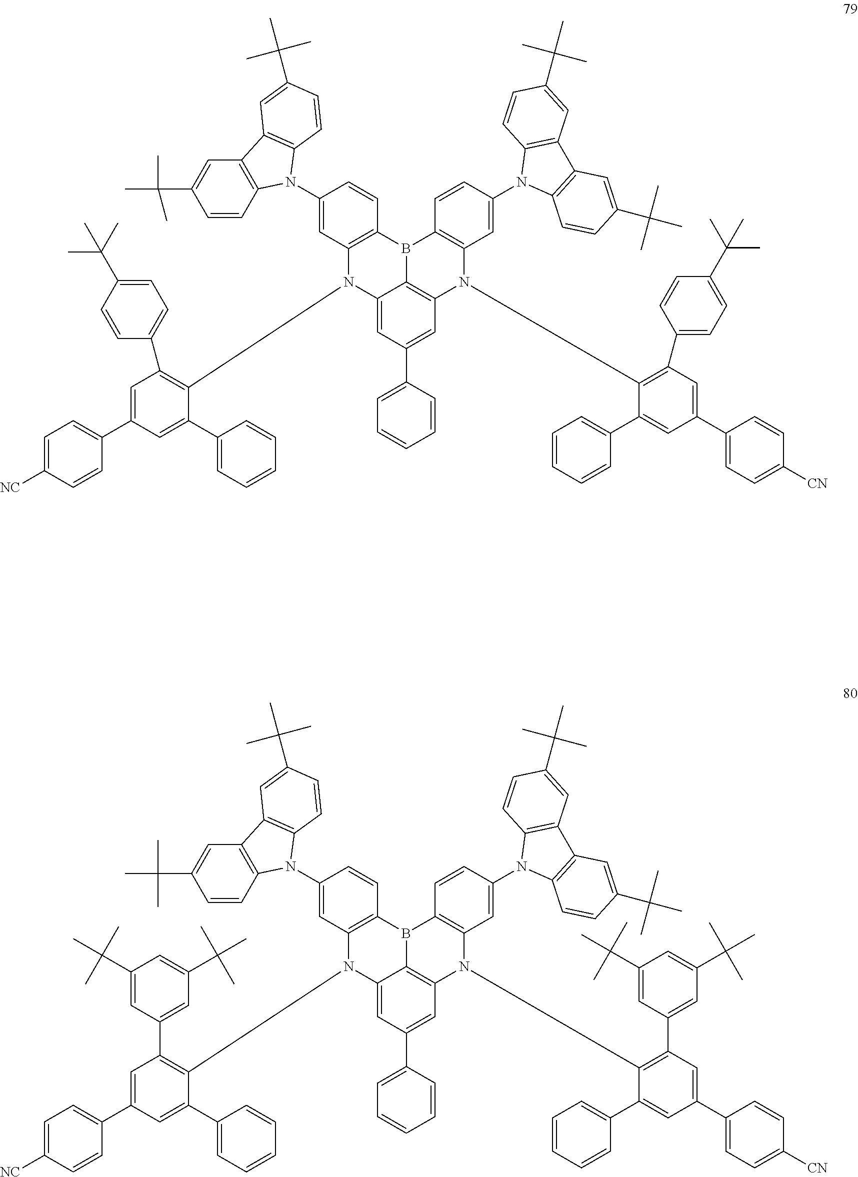 [SMILES: CC(C)(C)c1ccc(-c2cc(-c3ccc(C#N)cc3)cc(-c3ccccc3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(-c5ccc(C#N)cc5)cc4-c4ccc(C(C)(C)C)cc4)c4cc(-c5ccccc5)cc2c43)cc1 ; CC(C)(C)c1cc(-c2cc(-c3ccc(C#N)cc3)cc(-c3ccccc3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(-c5ccc(C#N)cc5)cc4-c4cc(C(C)(C)C)cc(C(C)(C)C)c4)c4cc(-c5ccccc5)cc2c43)cc(C(C)(C)C)c1] 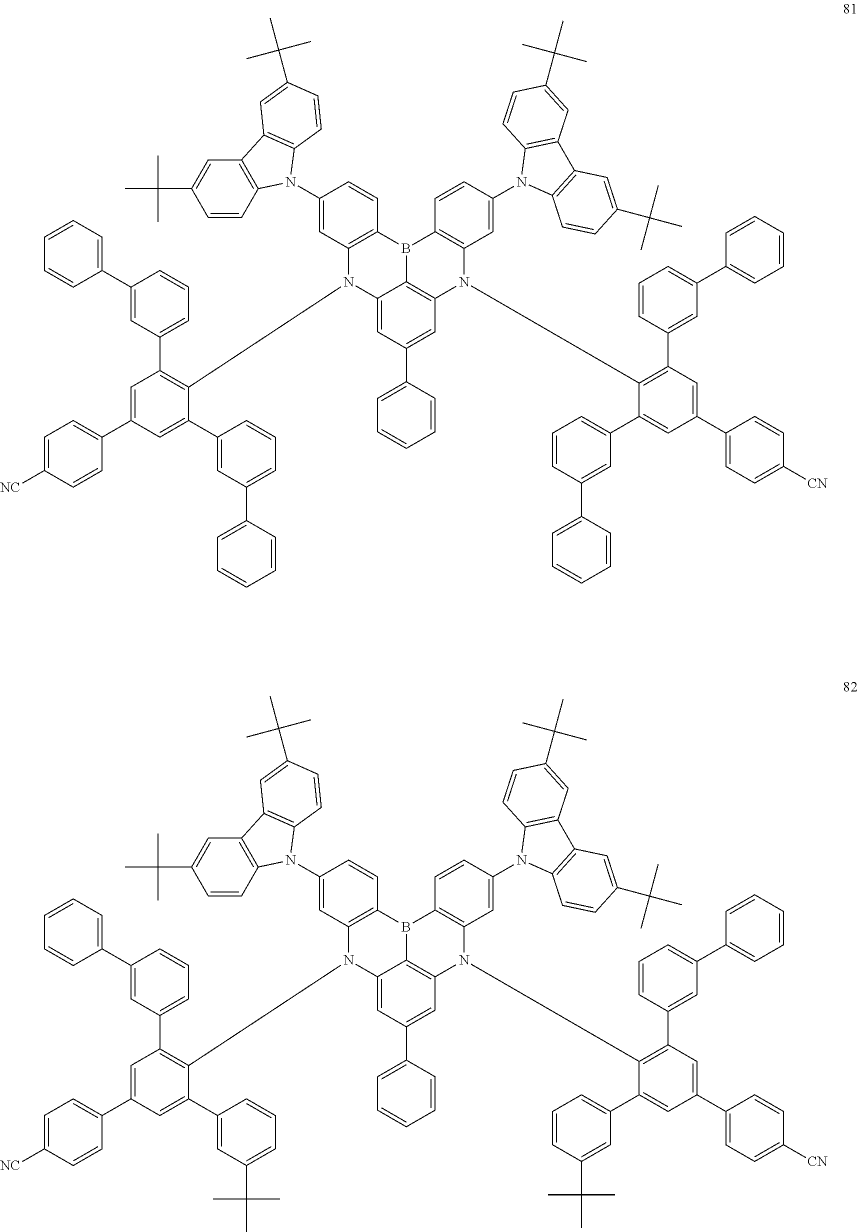 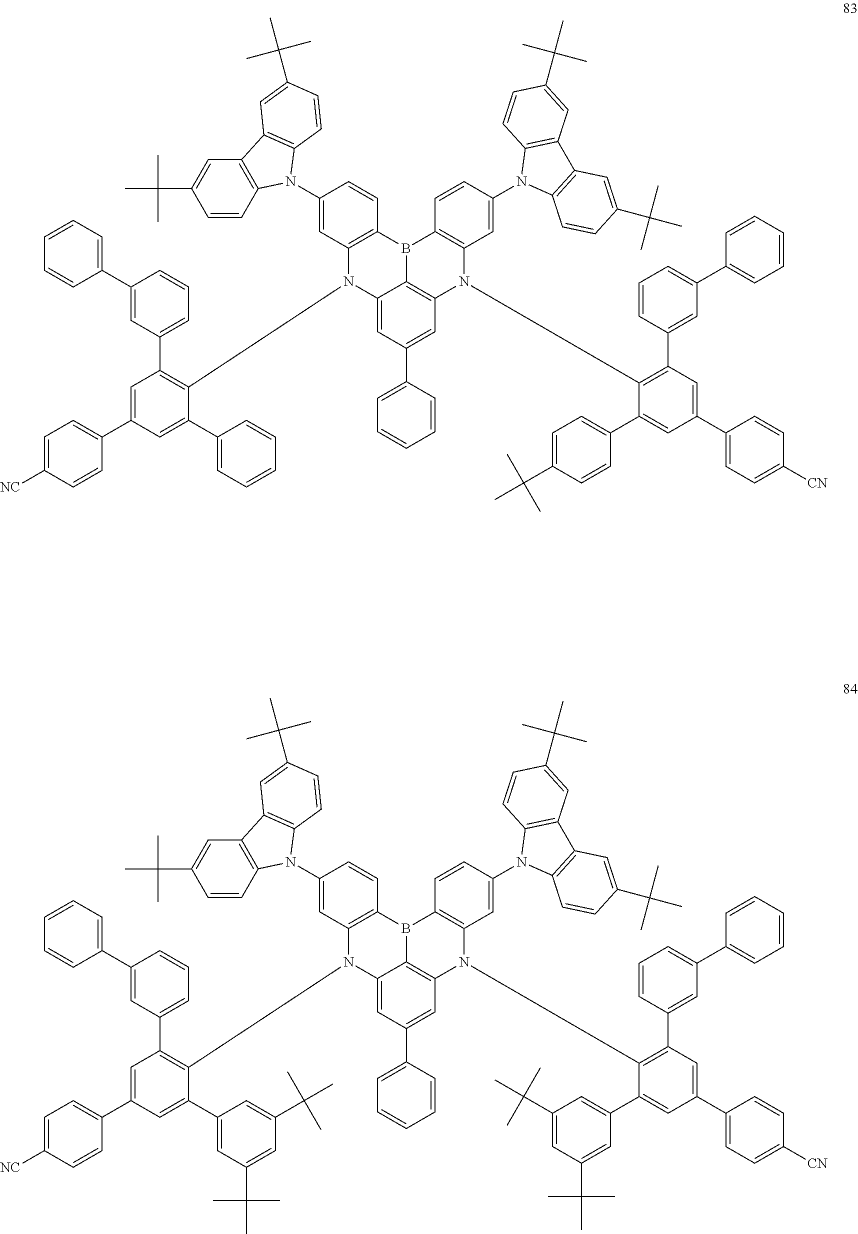 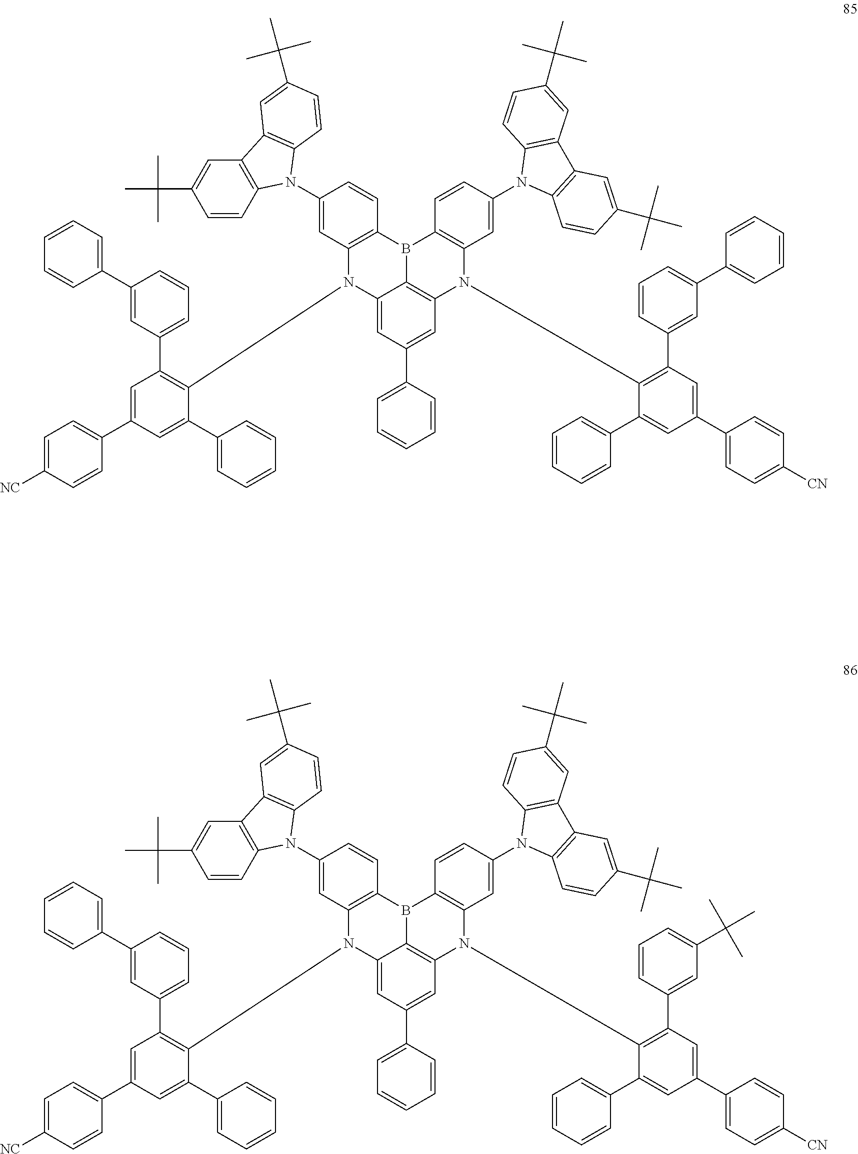 [SMILES: CC(C)(C)c1ccc2c(c1)c1cc(C(C)(C)C)ccc1n2-c1ccc2c(c1)N(c1c(-c3ccccc3)cc(-c3ccc(C#N)cc3)cc1-c1cccc(-c3ccccc3)c1)c1cc(-c3ccccc3)cc3c1B2c1ccc(-n2c4ccc(C(C)(C)C)cc4c4cc(C(C)(C)C)ccc42)cc1N3c1c(-c2ccccc2)cc(-c2ccc(C#N)cc2)cc1-c1cccc(-c2ccccc2)c1 ; CC(C)(C)c1cccc(-c2cc(-c3ccc(C#N)cc3)cc(-c3ccccc3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(-c5ccc(C#N)cc5)cc4-c4cccc(-c5ccccc5)c4)c4cc(-c5ccccc5)cc2c43)c1] 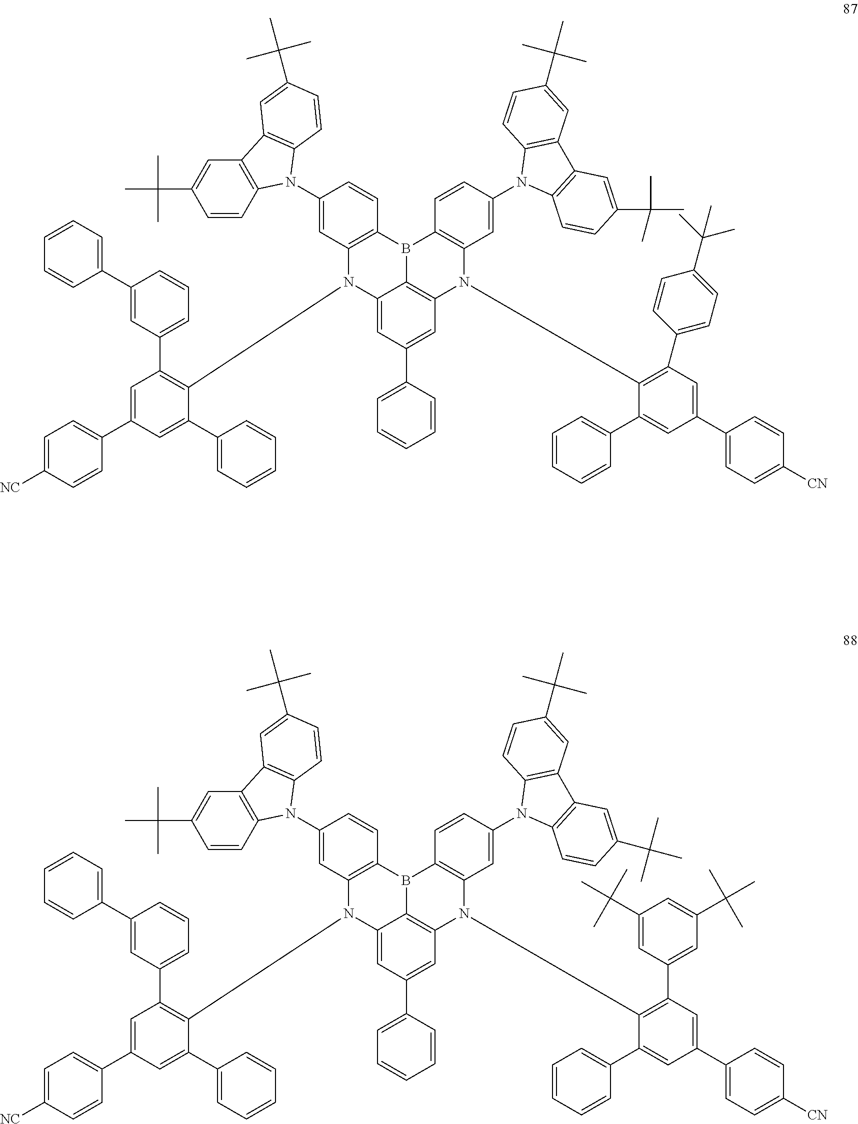 [SMILES: CC(C)(C)c1ccc(-c2cc(-c3ccc(C#N)cc3)cc(-c3ccccc3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(-c5ccc(C#N)cc5)cc4-c4cccc(-c5ccccc5)c4)c4cc(-c5ccccc5)cc2c43)cc1 ; CC(C)(C)c1cc(-c2cc(-c3ccc(C#N)cc3)cc(-c3ccccc3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(-c5ccc(C#N)cc5)cc4-c4cccc(-c5ccccc5)c4)c4cc(-c5ccccc5)cc2c43)cc(C(C)(C)C)c1] 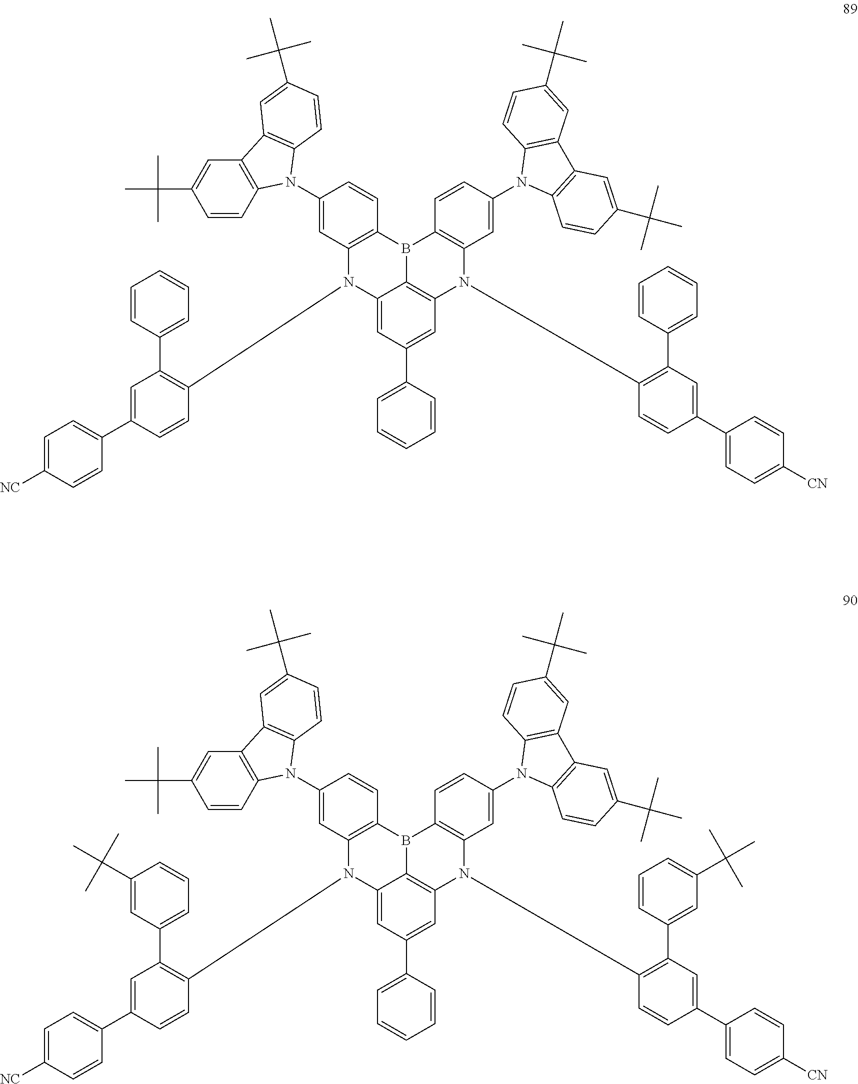 [SMILES: CC(C)(C)c1ccc2c(c1)c1cc(C(C)(C)C)ccc1n2-c1ccc2c(c1)N(c1ccc(-c3ccc(C#N)cc3)cc1-c1ccccc1)c1cc(-c3ccccc3)cc3c1B2c1ccc(-n2c4ccc(C(C)(C)C)cc4c4cc(C(C)(C)C)ccc42)cc1N3c1ccc(-c2ccc(C#N)cc2)cc1-c1ccccc1 ; CC(C)(C)c1cccc(-c2cc(-c3ccc(C#N)cc3)ccc2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(-c5ccc(C#N)cc5)cc4-c4cccc(C(C)(C)C)c4)c4cc(-c5ccccc5)cc2c43)c1] 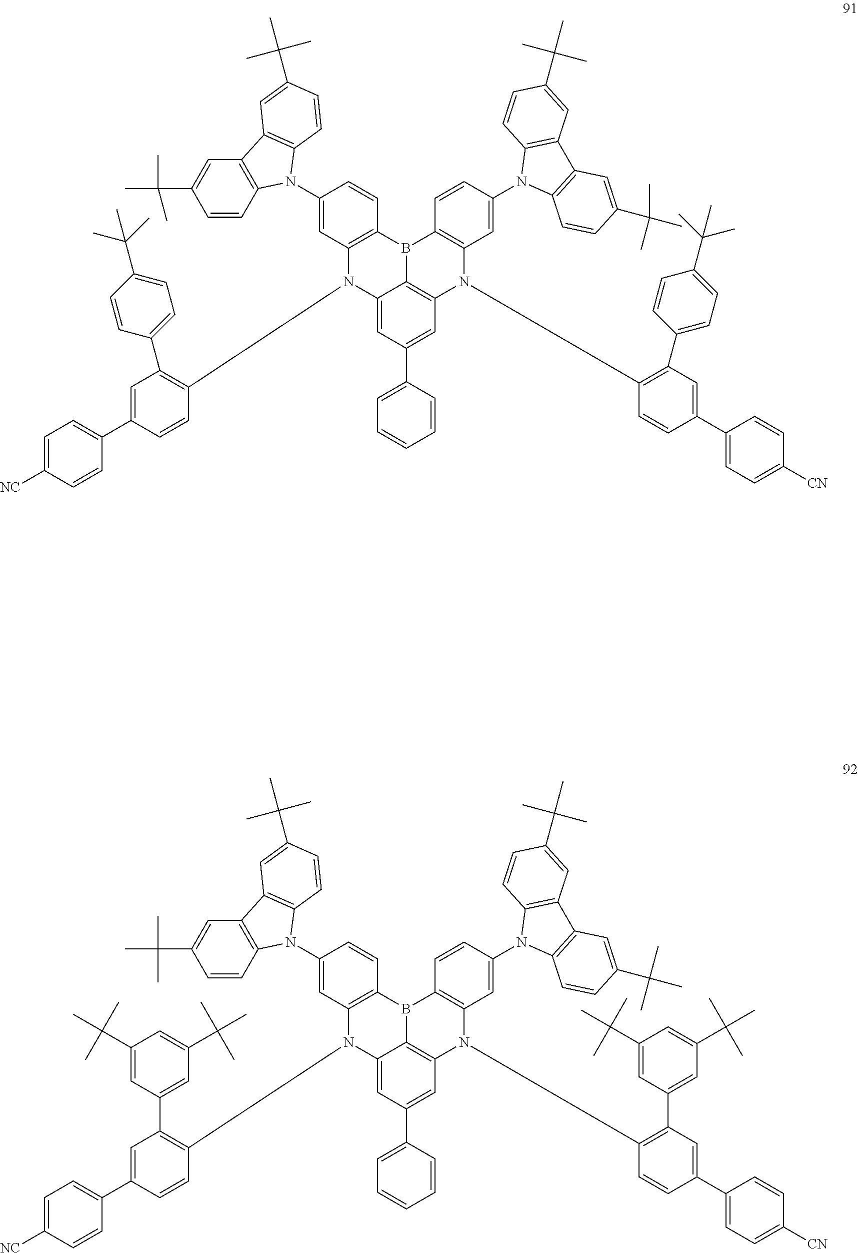 [SMILES: CC(C)(C)c1ccc(-c2cc(-c3ccc(C#N)cc3)ccc2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(-c5ccc(C#N)cc5)cc4-c4ccc(C(C)(C)C)cc4)c4cc(-c5ccccc5)cc2c43)cc1 ; CC(C)(C)c1cc(-c2cc(-c3ccc(C#N)cc3)ccc2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(-c5ccc(C#N)cc5)cc4-c4cc(C(C)(C)C)cc(C(C)(C)C)c4)c4cc(-c5ccccc5)cc2c43)cc(C(C)(C)C)c1] 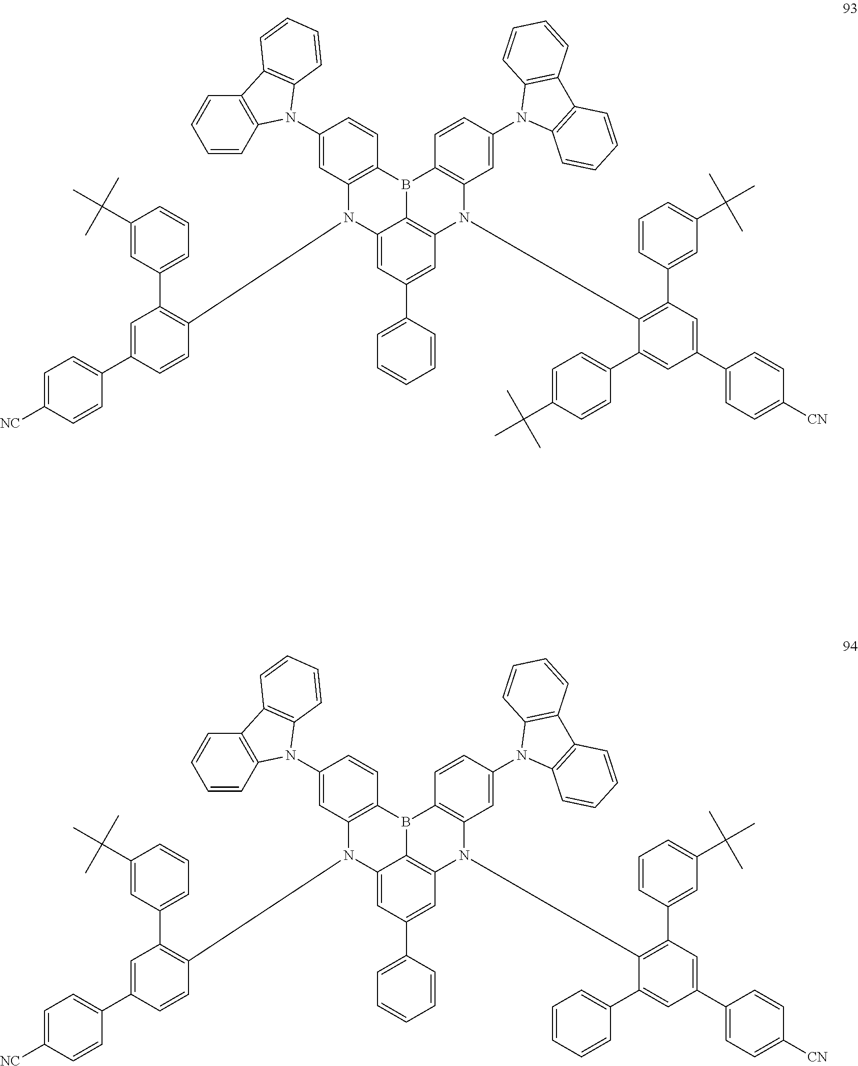 [SMILES: CC(C)(C)c1ccc(-c2cc(-c3ccc(C#N)cc3)cc(-c3cccc(C(C)(C)C)c3)c2N2c3cc(-n4c5ccccc5c5ccccc54)ccc3B3c4ccc(-n5c6ccccc6c6ccccc65)cc4N(c4ccc(-c5ccc(C#N)cc5)cc4-c4cccc(C(C)(C)C)c4)c4cc(-c5ccccc5)cc2c43)cc1 ; CC(C)(C)c1cccc(-c2cc(-c3ccc(C#N)cc3)ccc2N2c3cc(-n4c5ccccc5c5ccccc54)ccc3B3c4ccc(-n5c6ccccc6c6ccccc65)cc4N(c4c(-c5ccccc5)cc(-c5ccc(C#N)cc5)cc4-c4cccc(C(C)(C)C)c4)c4cc(-c5ccccc5)cc2c43)c1] 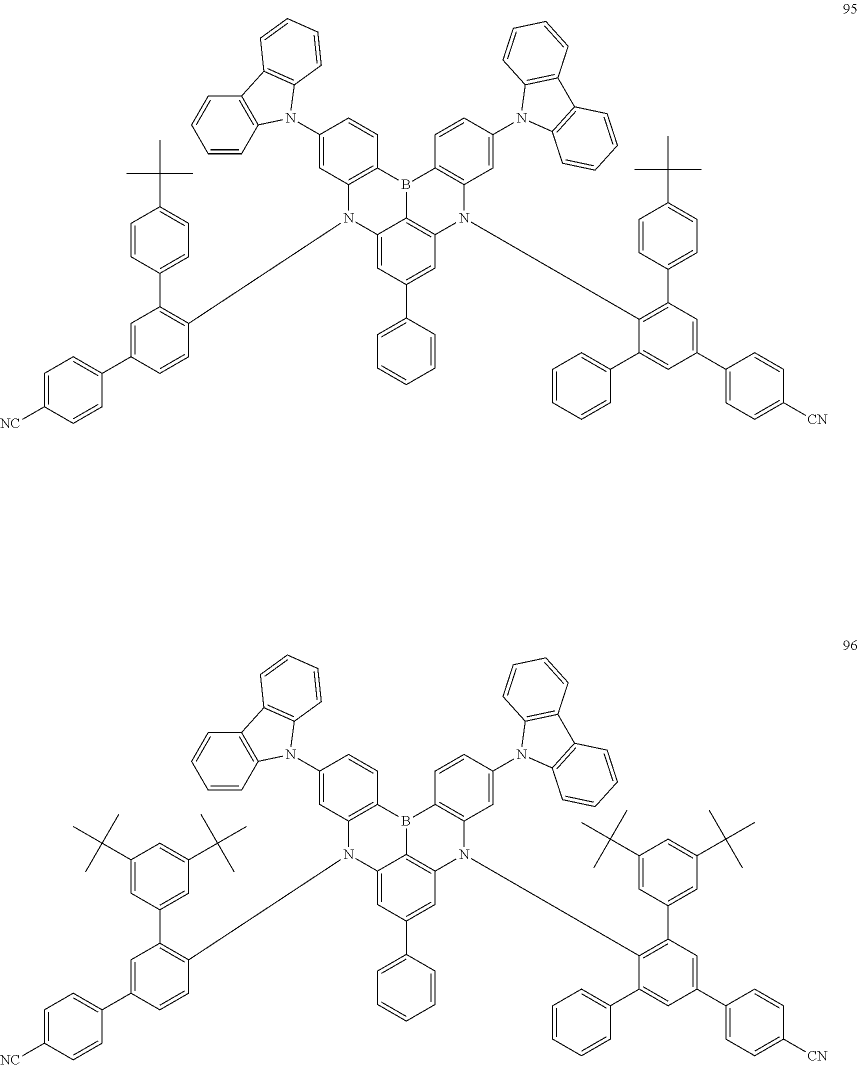 [SMILES: CC(C)(C)c1ccc(-c2cc(-c3ccc(C#N)cc3)ccc2N2c3cc(-n4c5ccccc5c5ccccc54)ccc3B3c4ccc(-n5c6ccccc6c6ccccc65)cc4N(c4c(-c5ccccc5)cc(-c5ccc(C#N)cc5)cc4-c4ccc(C(C)(C)C)cc4)c4cc(-c5ccccc5)cc2c43)cc1 ; CC(C)(C)c1cc(-c2cc(-c3ccc(C#N)cc3)ccc2N2c3cc(-n4c5ccccc5c5ccccc54)ccc3B3c4ccc(-n5c6ccccc6c6ccccc65)cc4N(c4c(-c5ccccc5)cc(-c5ccc(C#N)cc5)cc4-c4cc(C(C)(C)C)cc(C(C)(C)C)c4)c4cc(-c5ccccc5)cc2c43)cc(C(C)(C)C)c1] 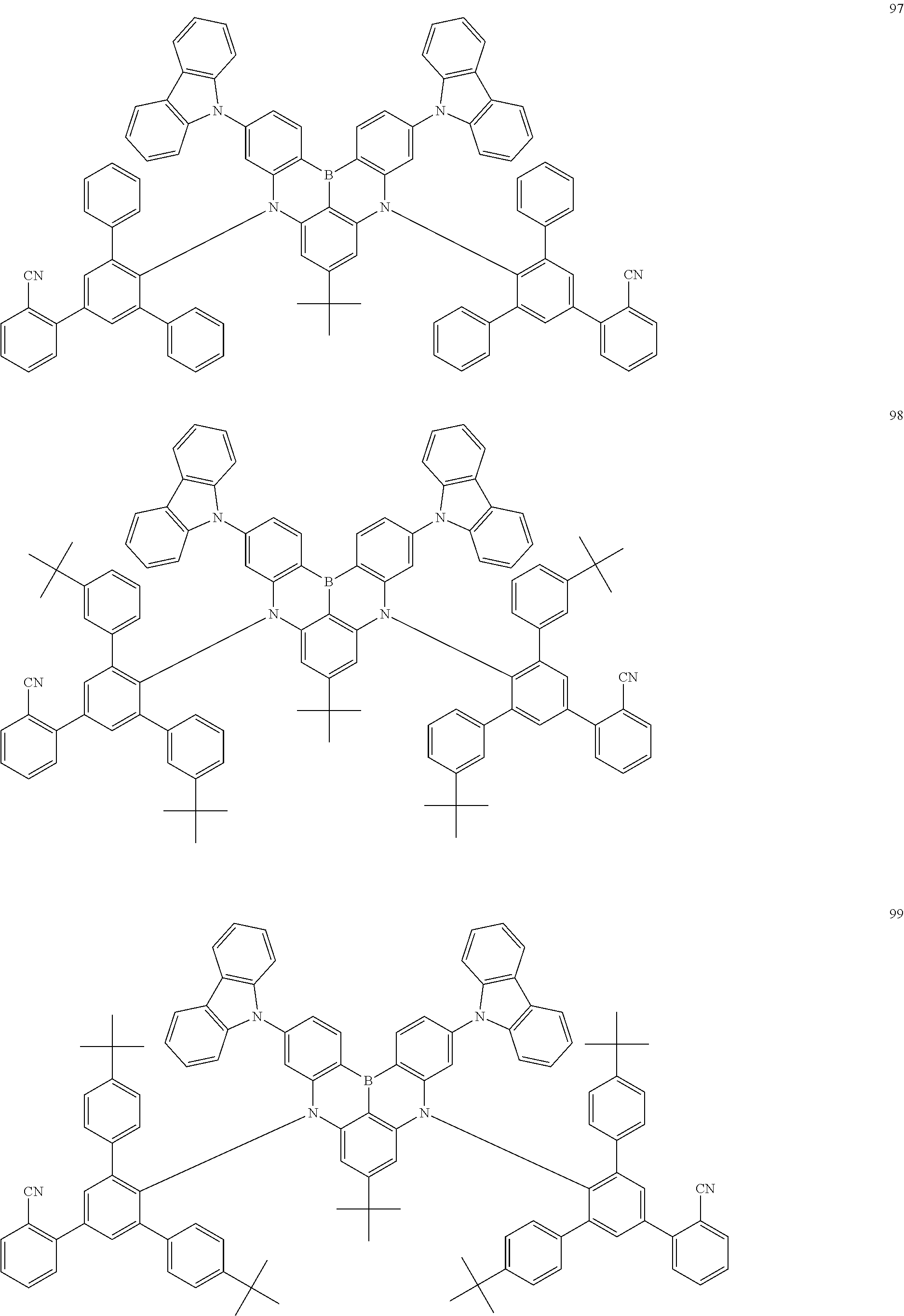 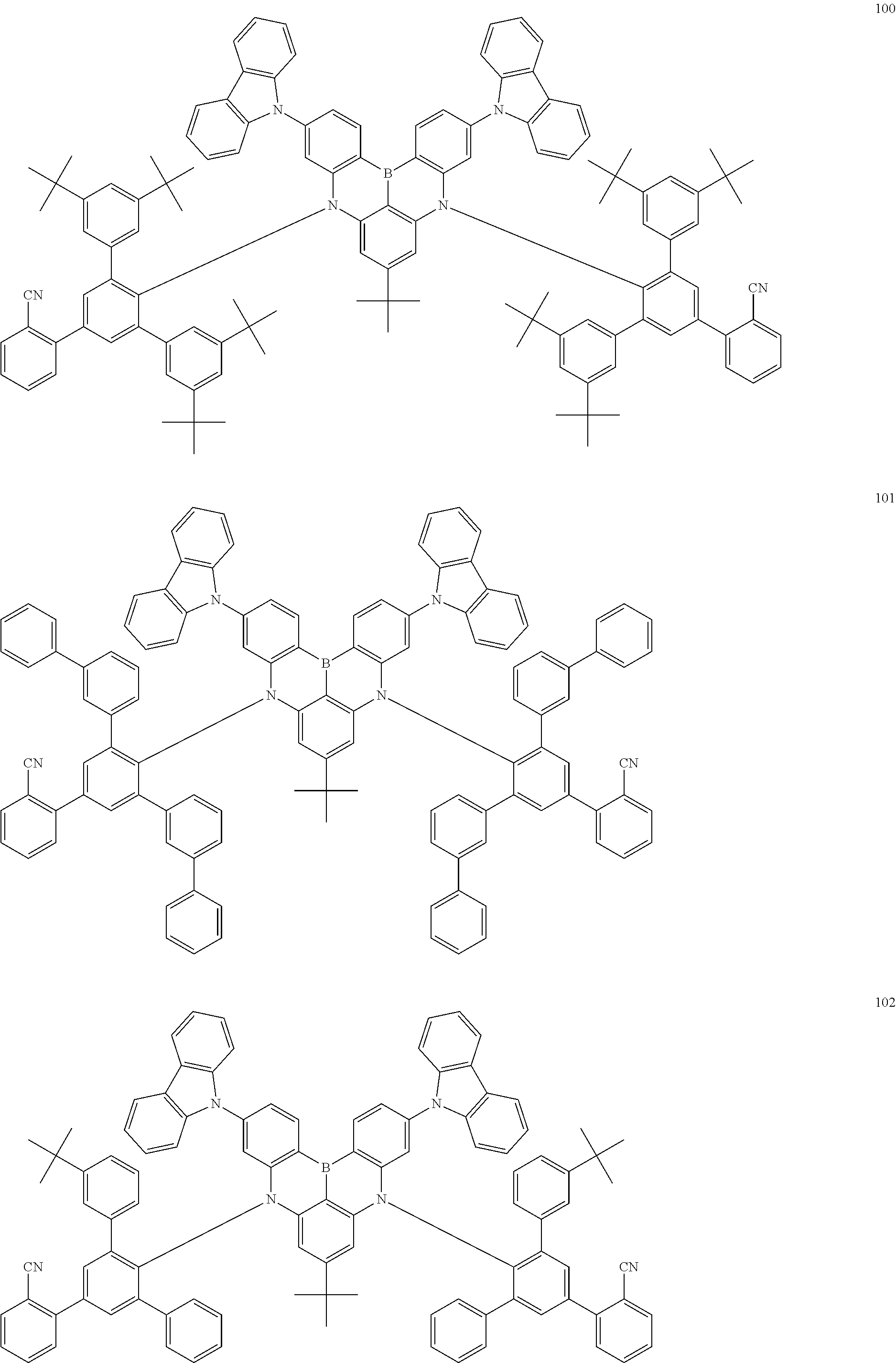 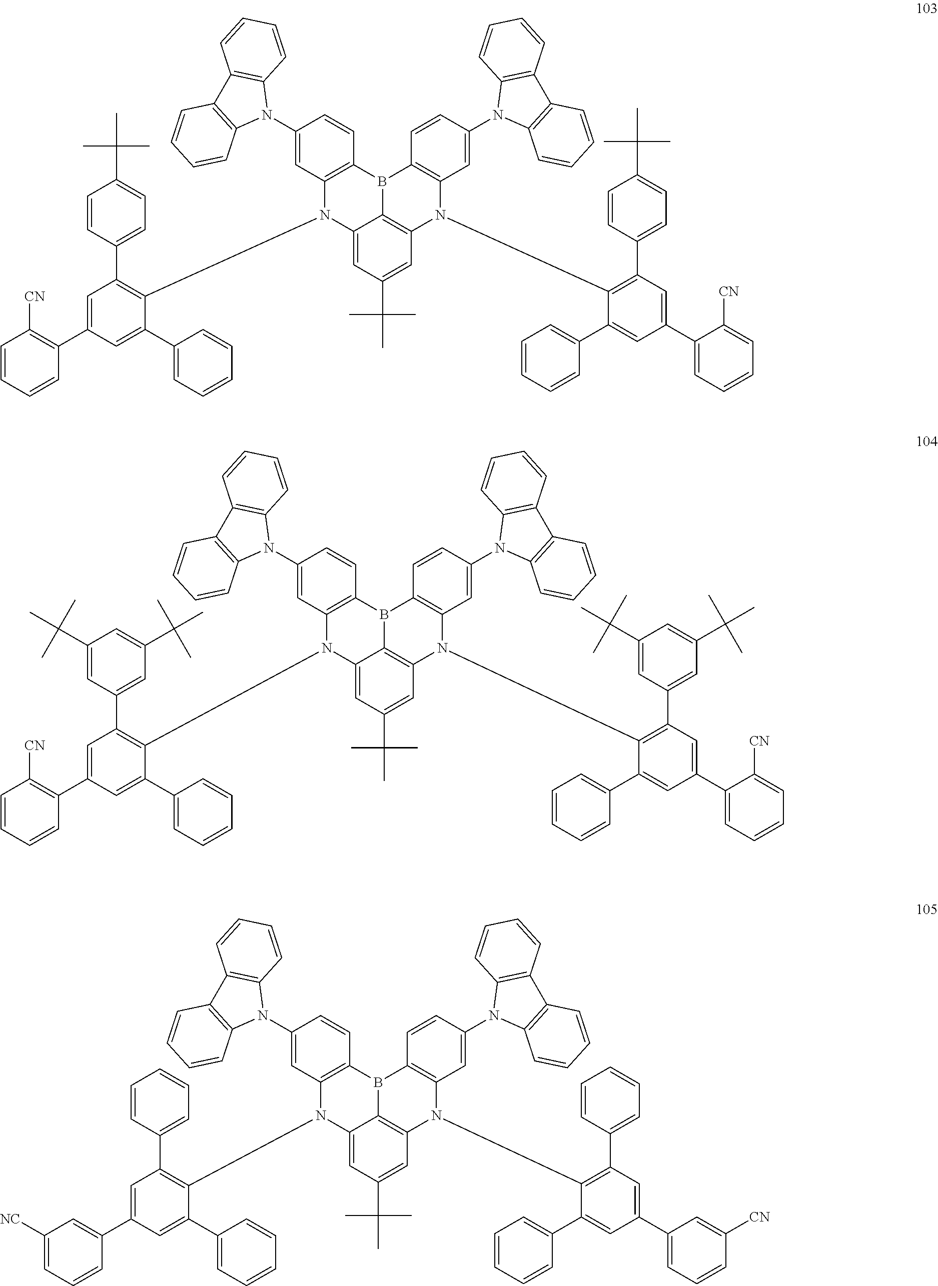 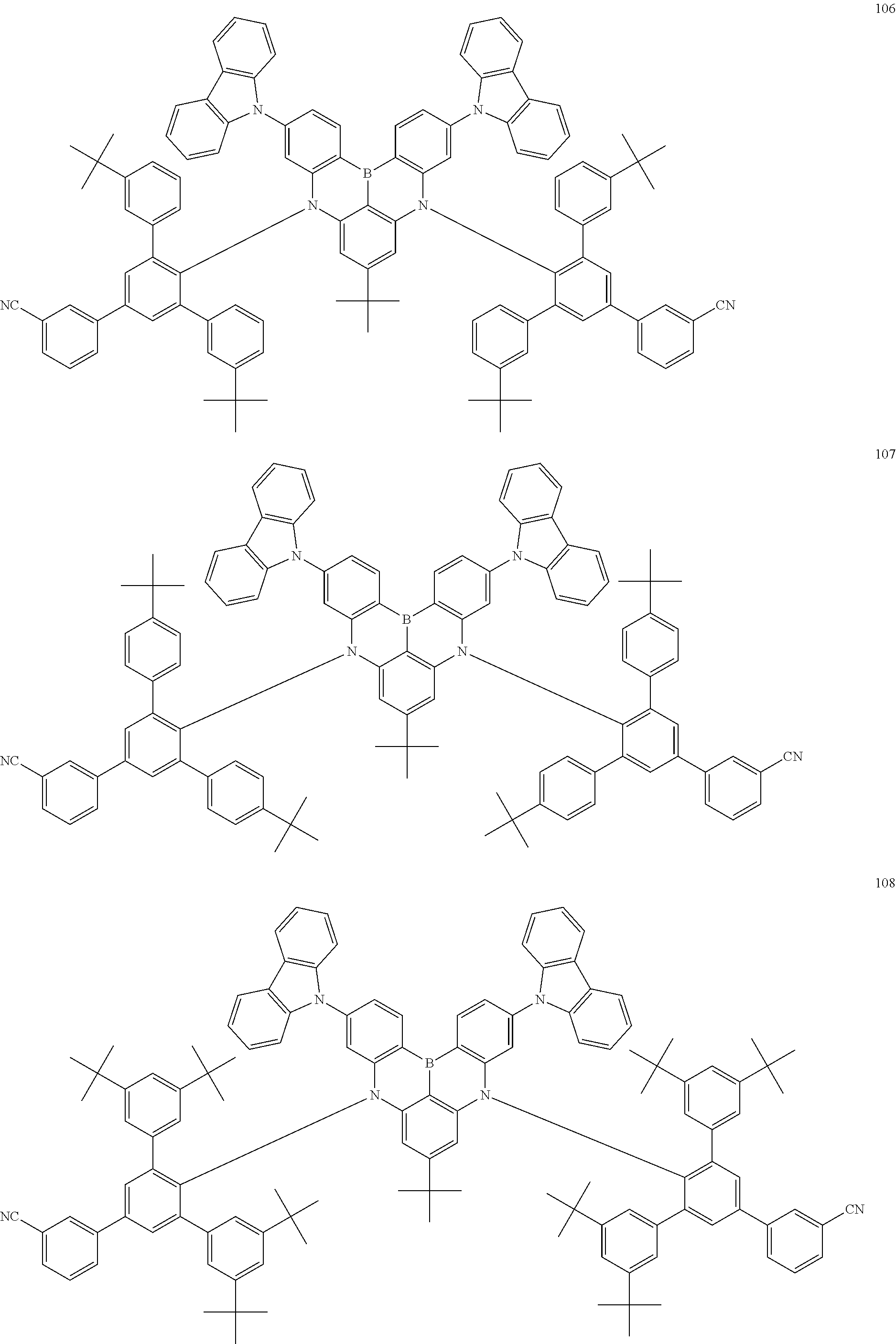 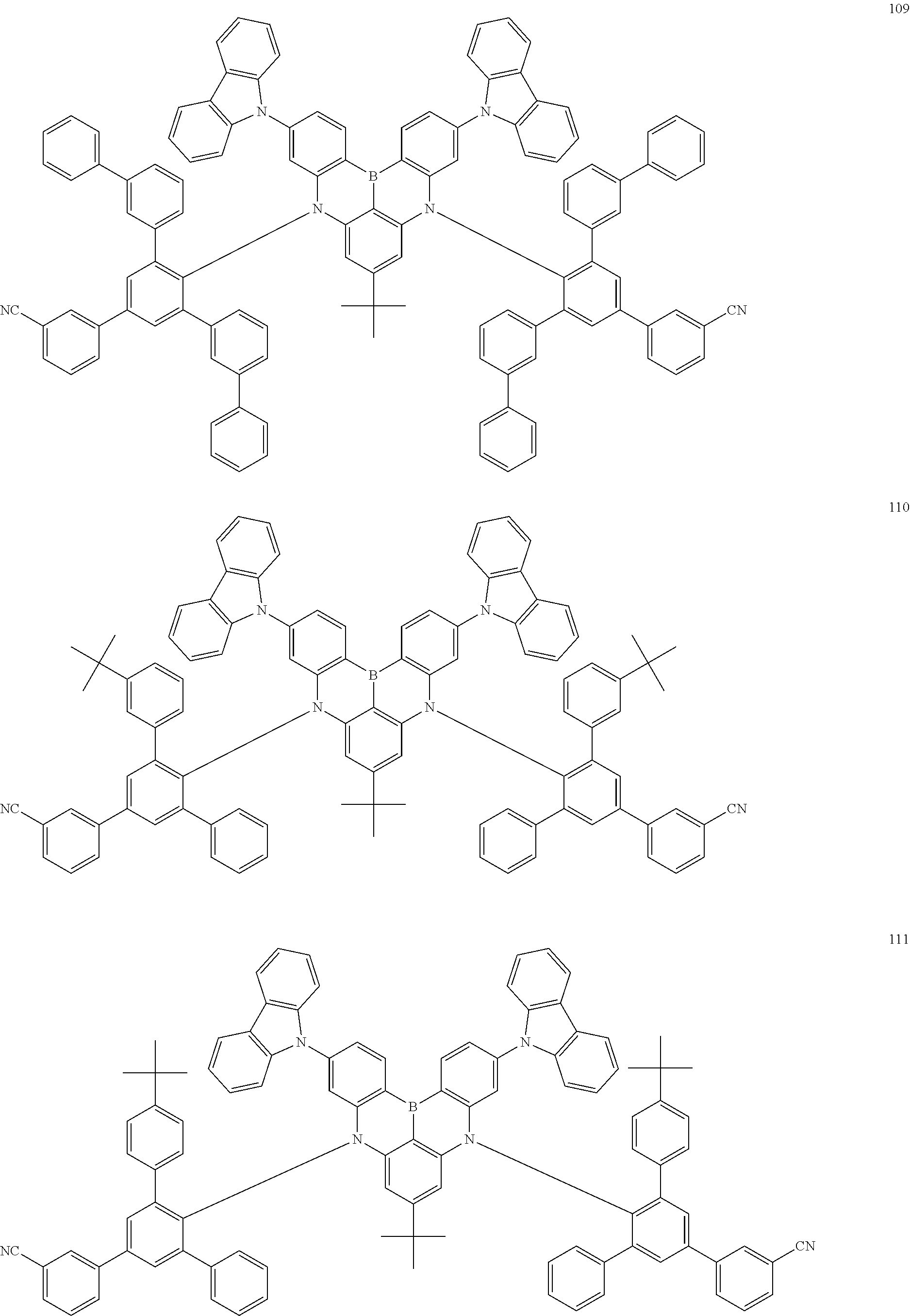 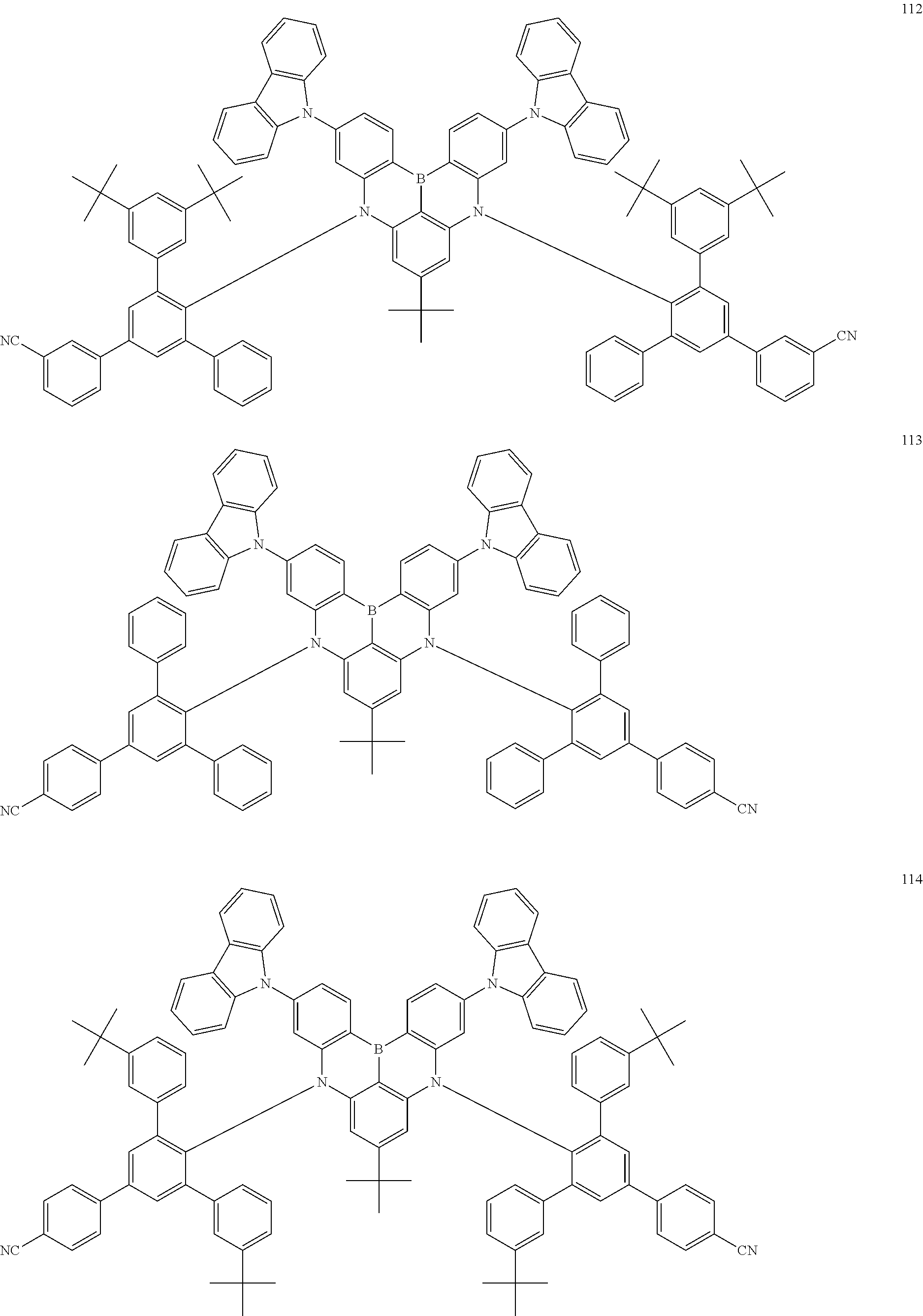 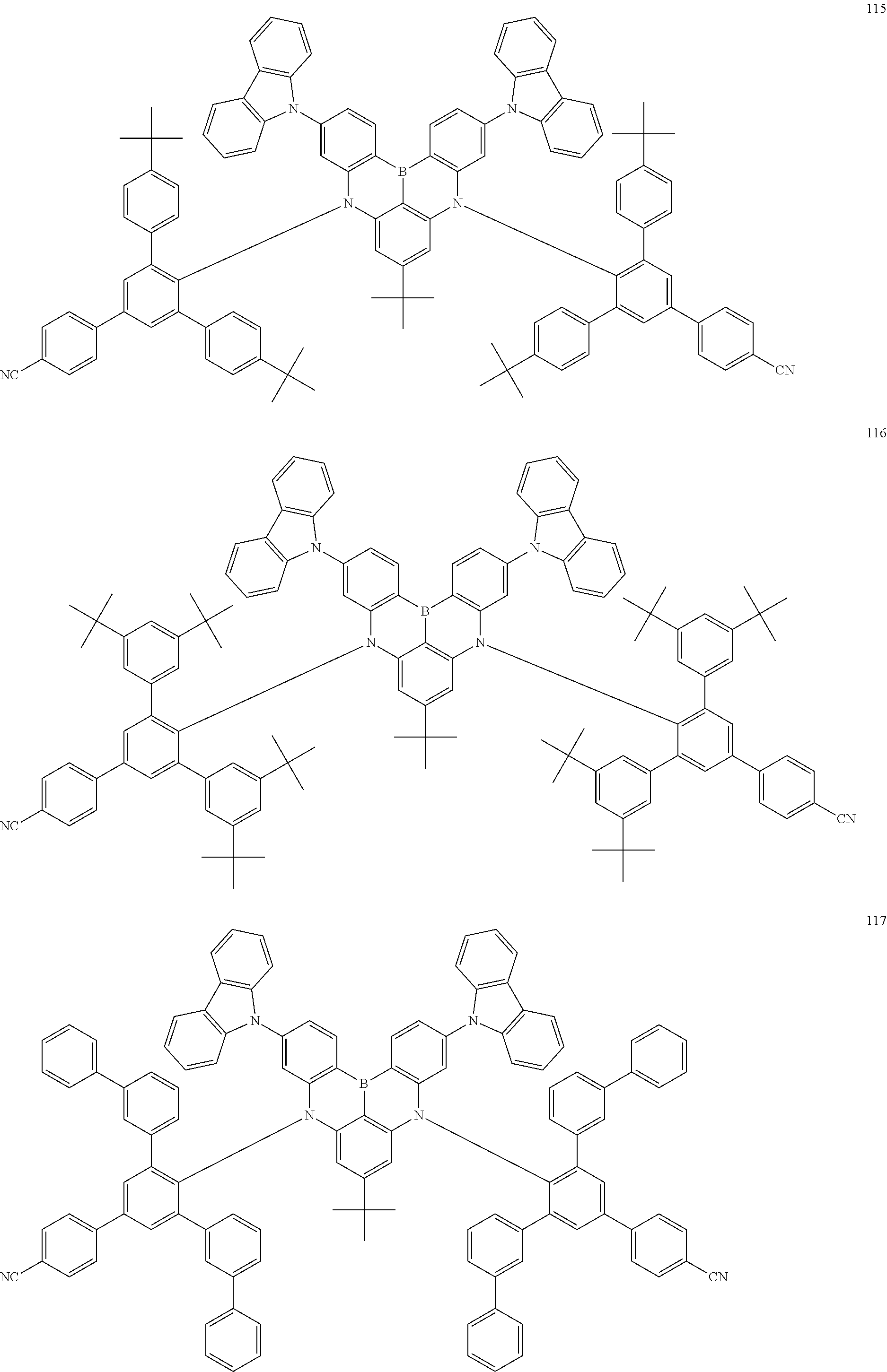 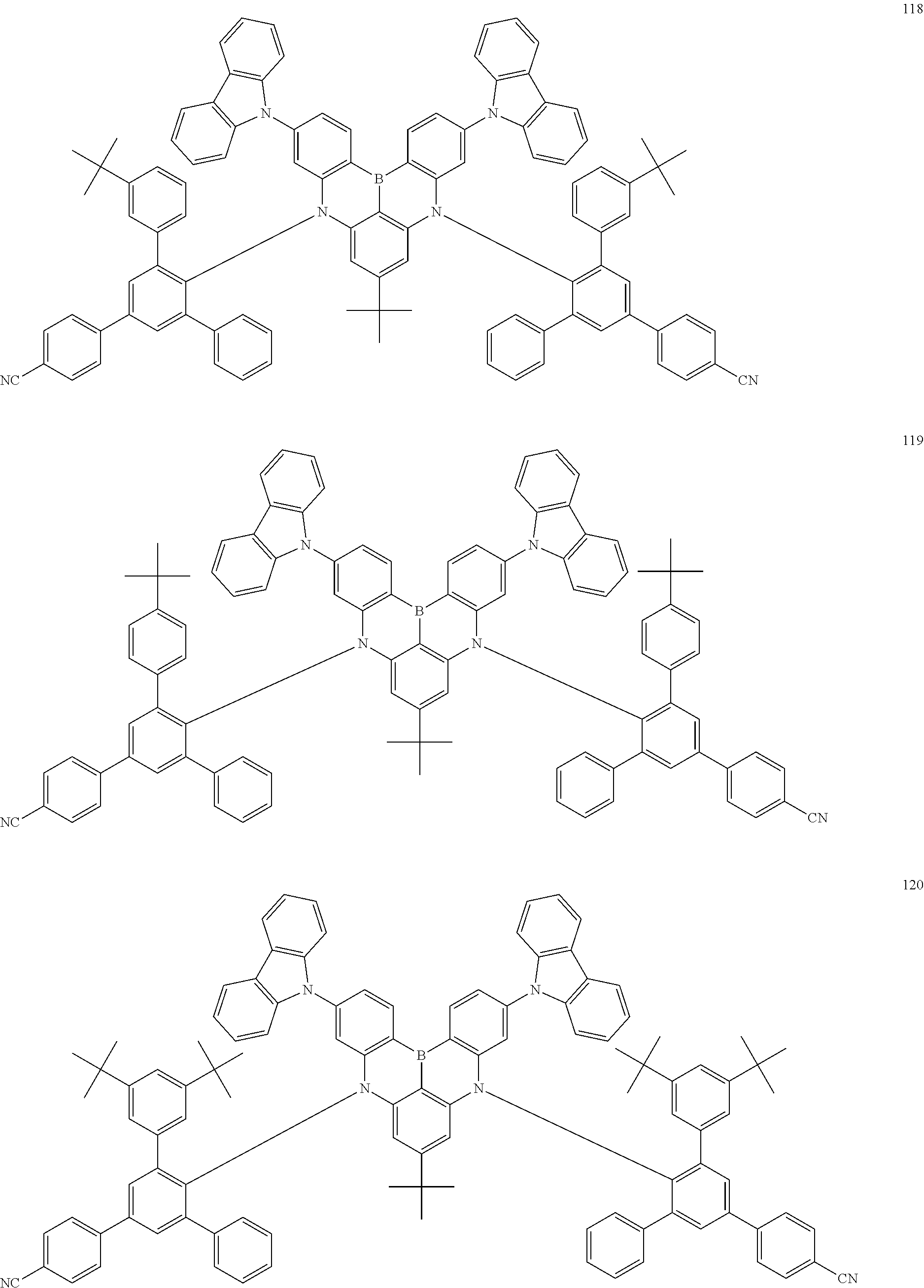 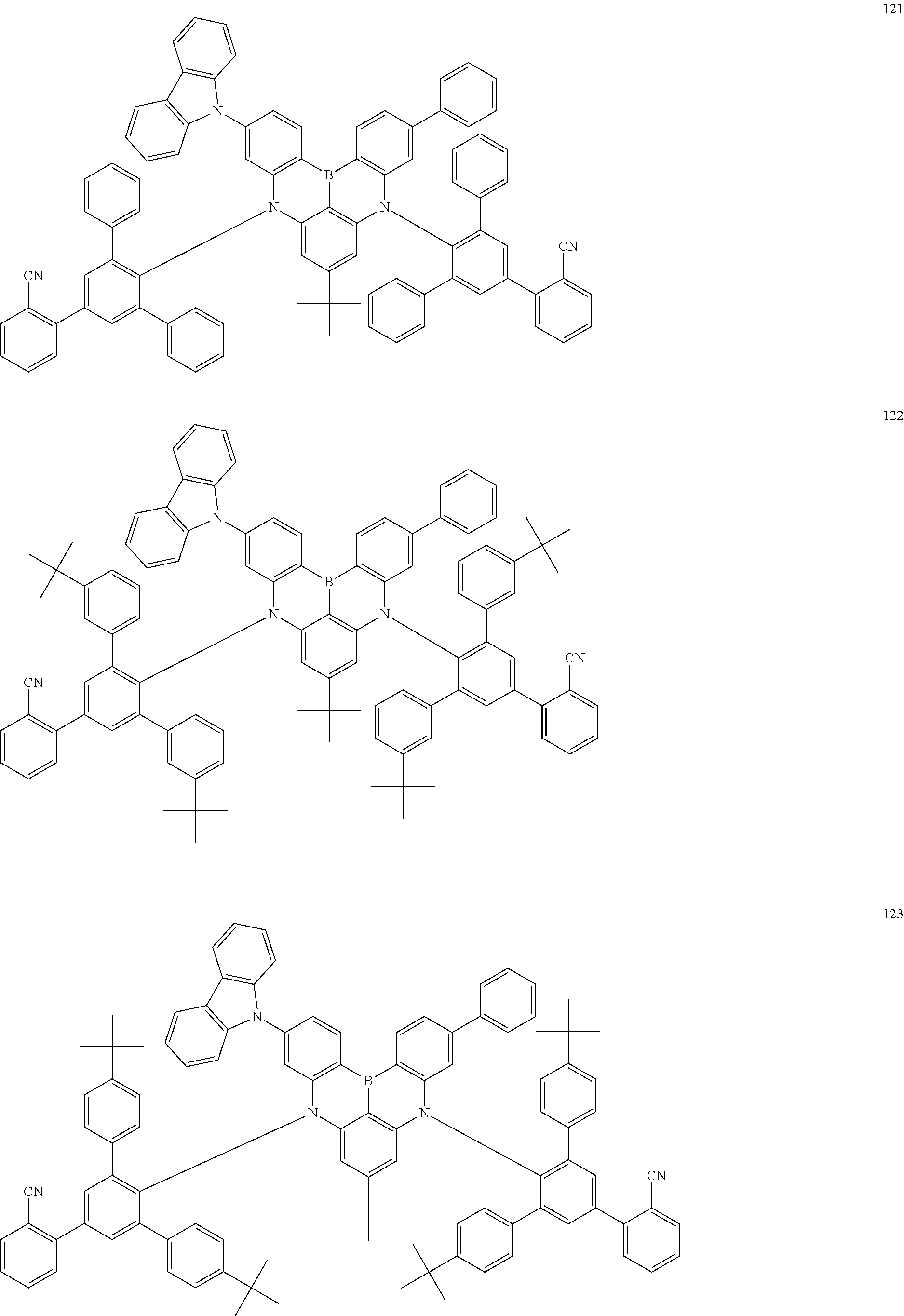 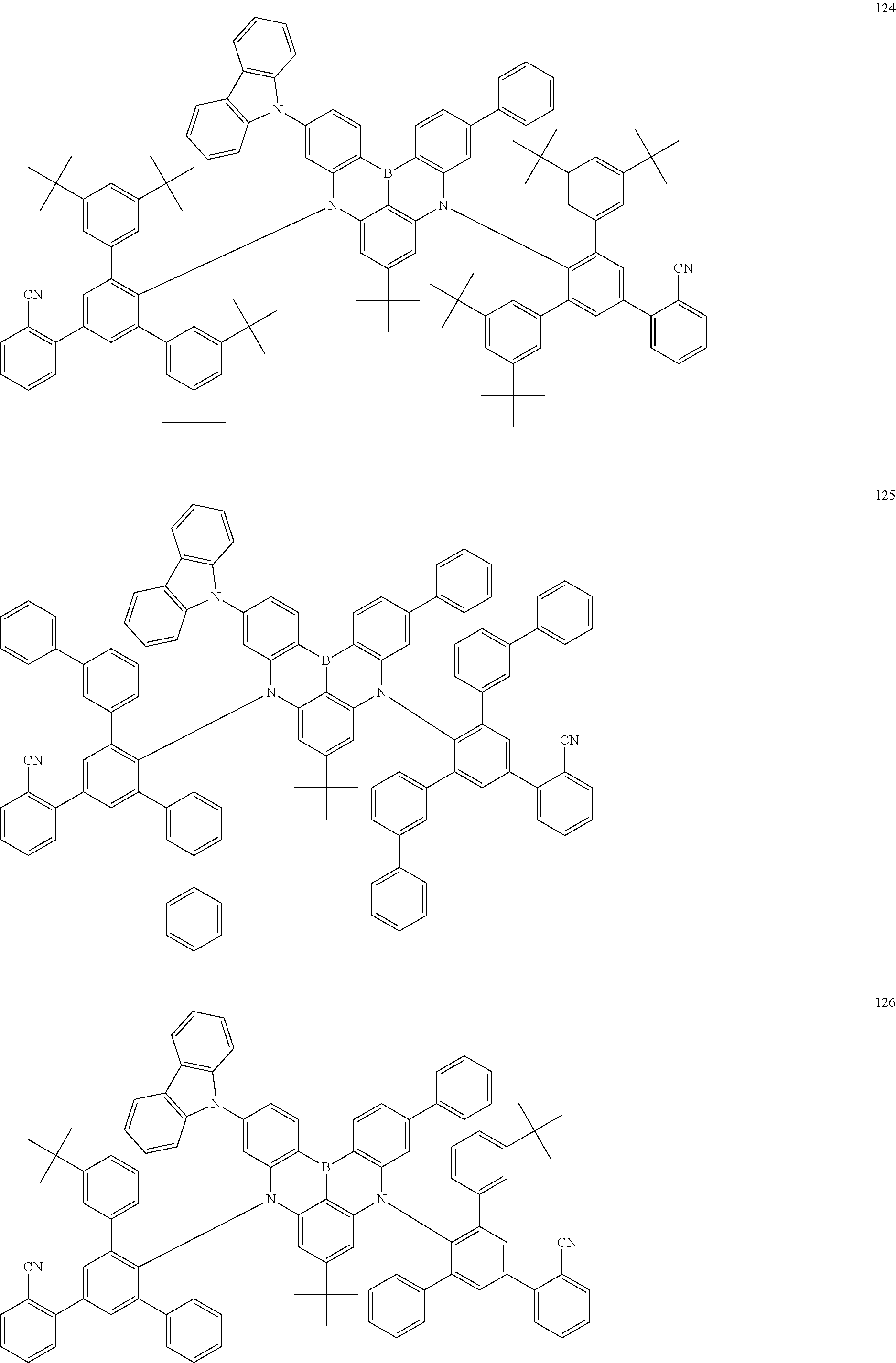 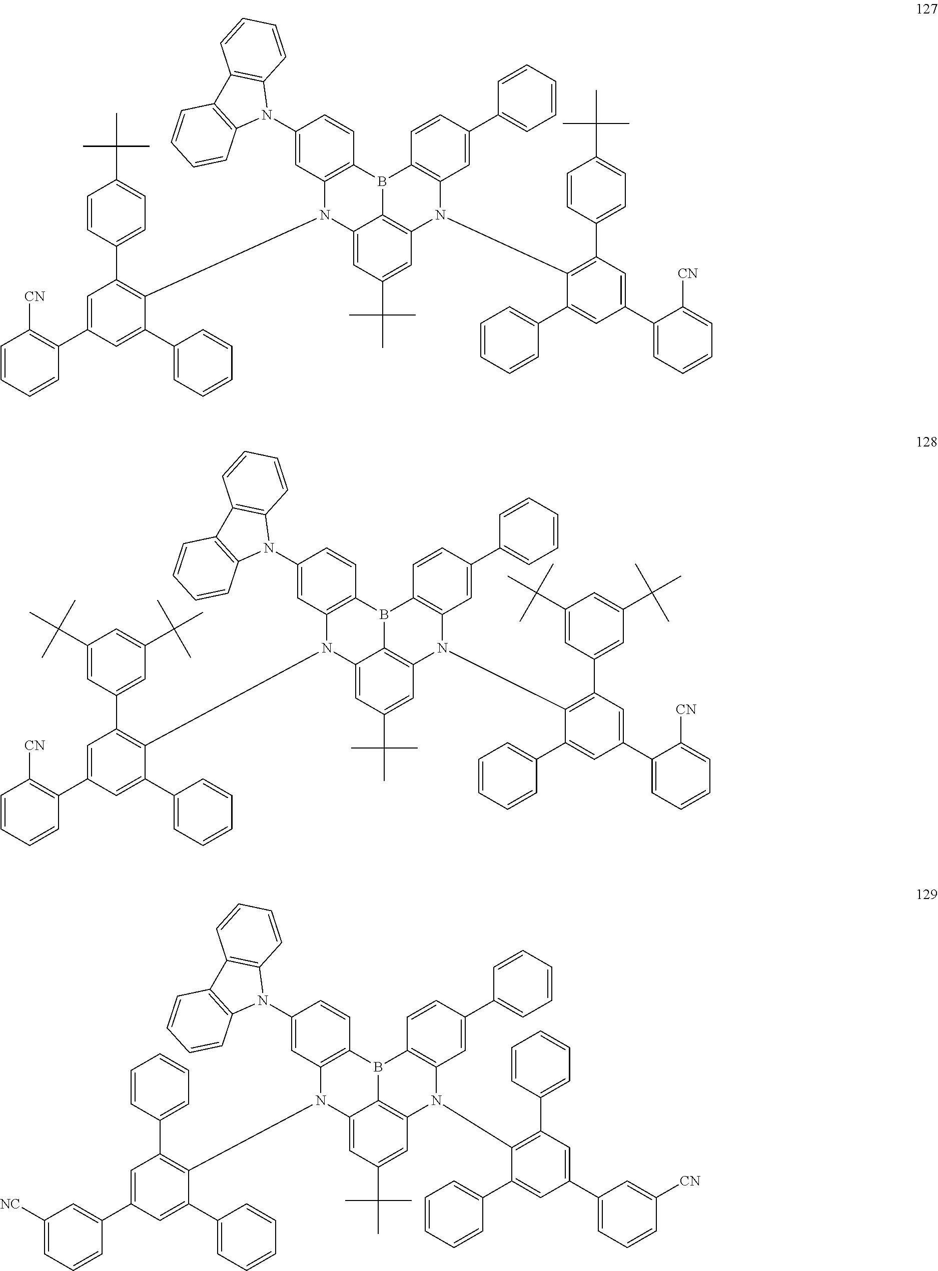 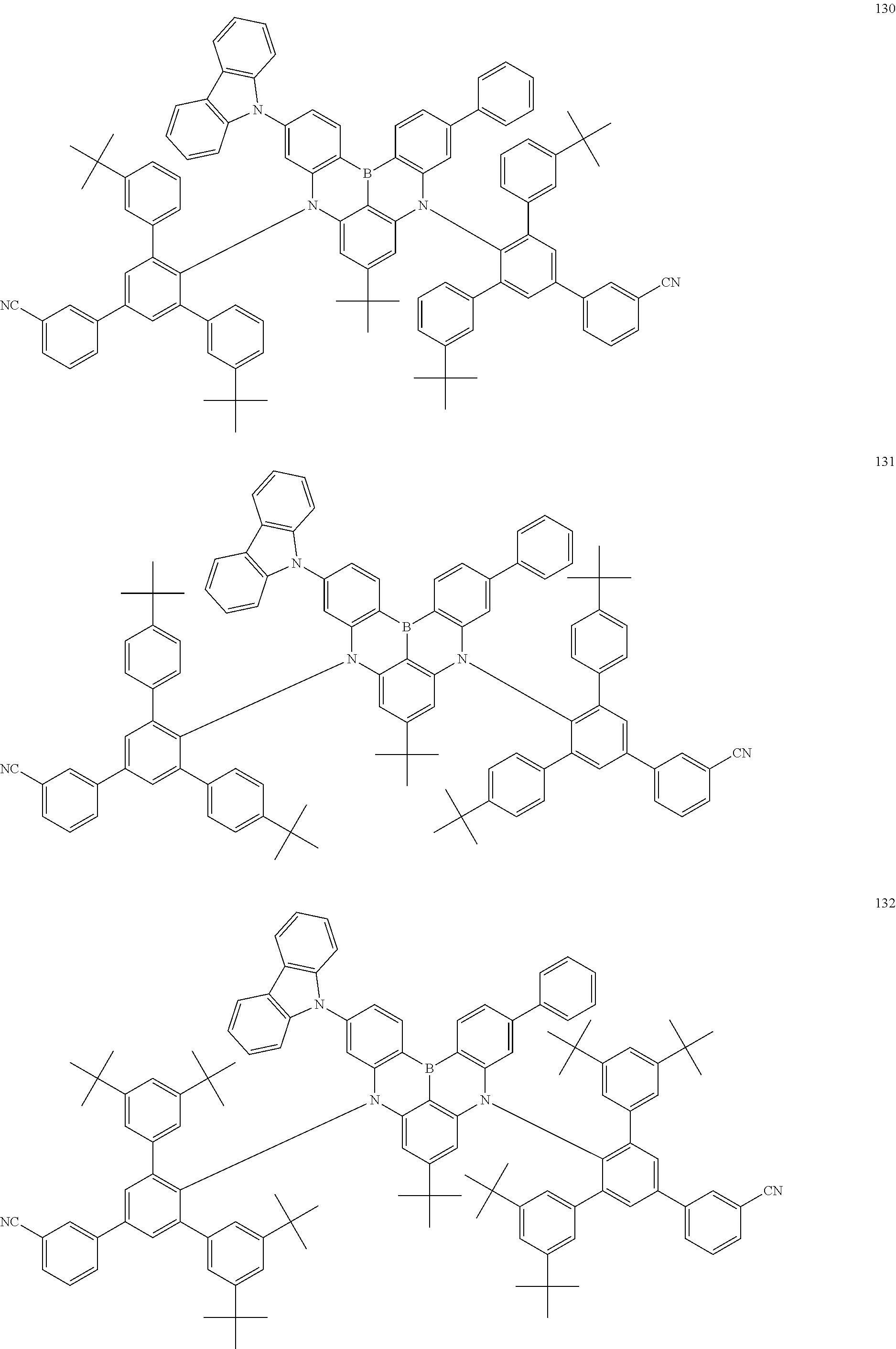 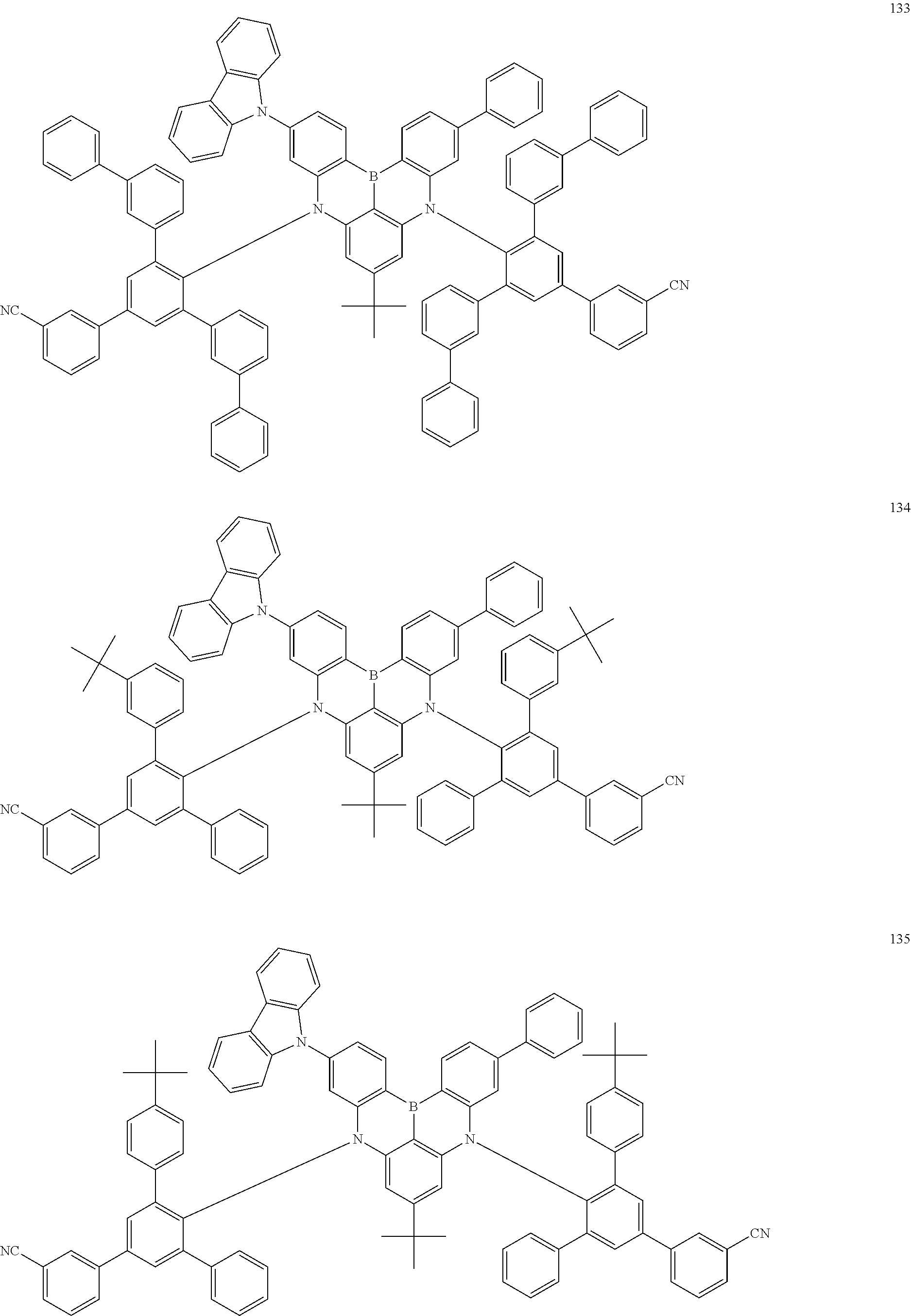 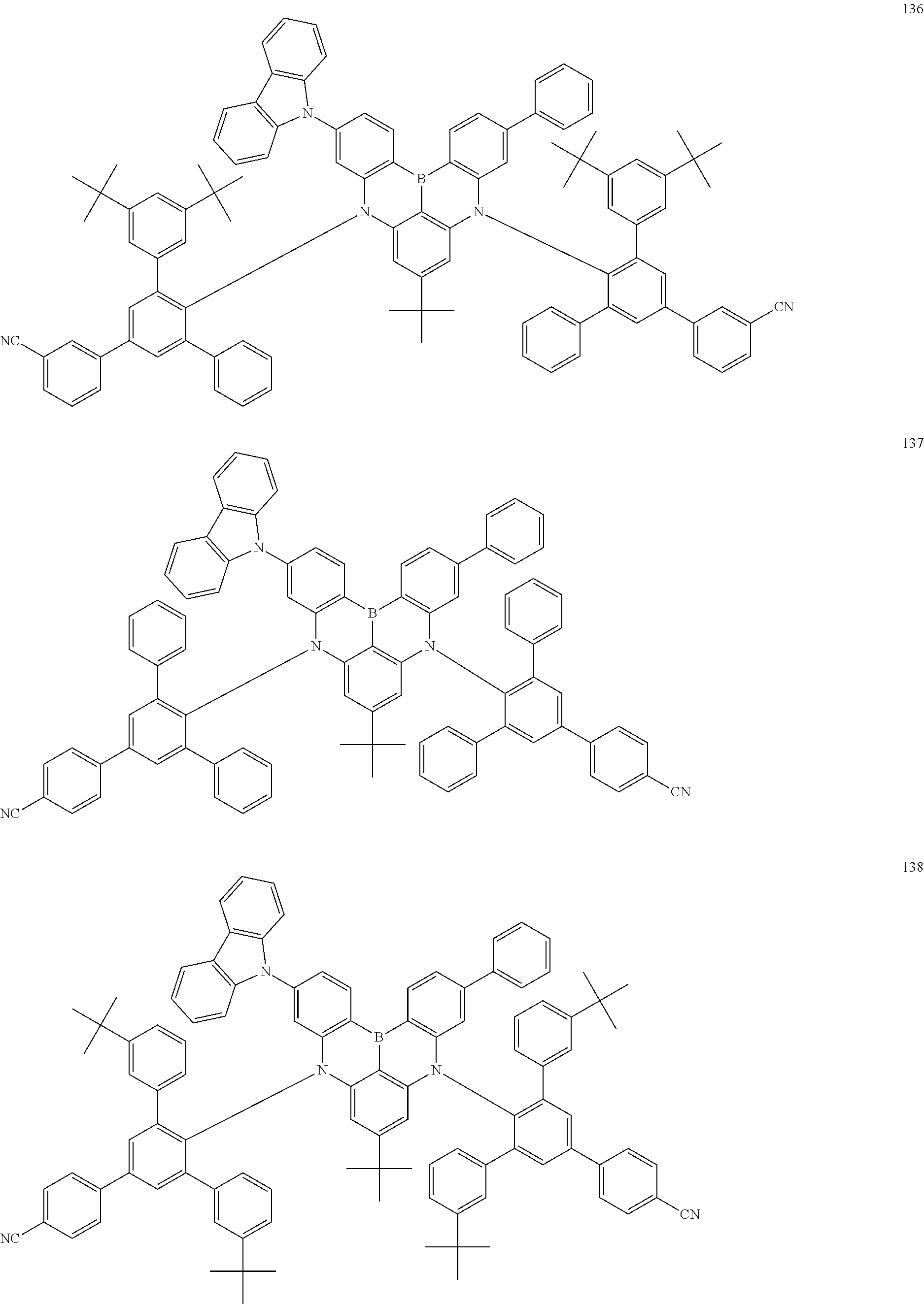 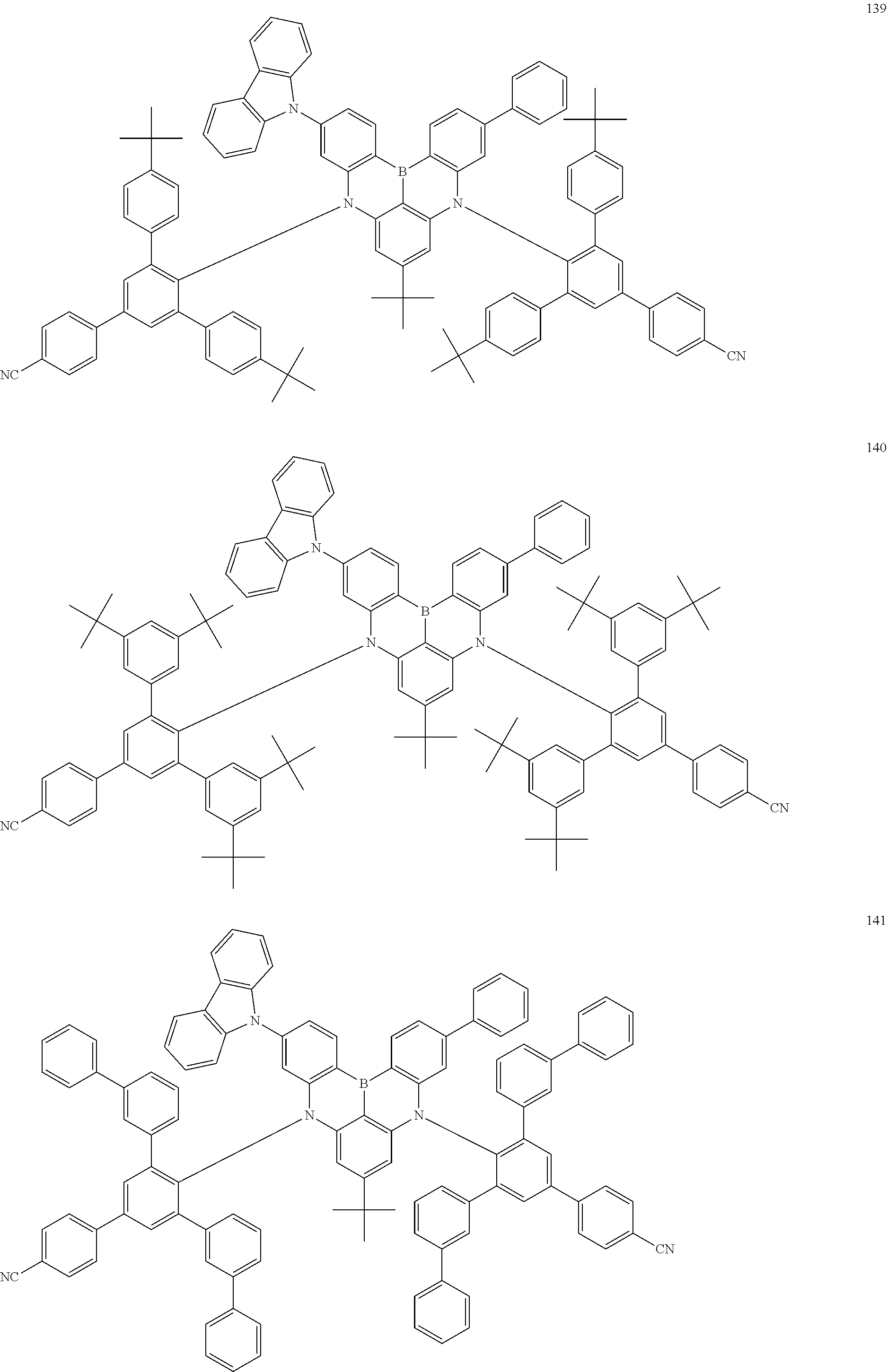 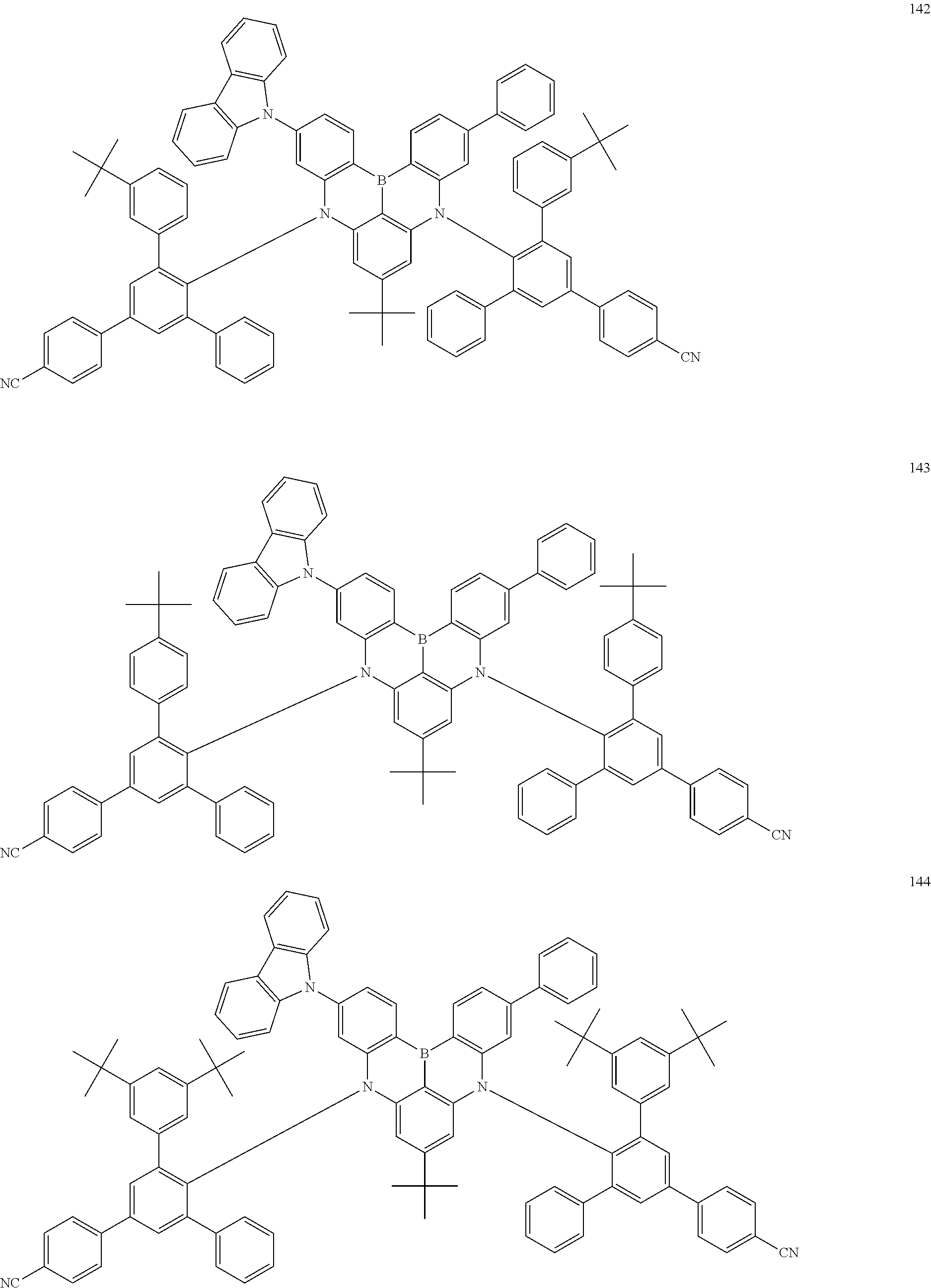 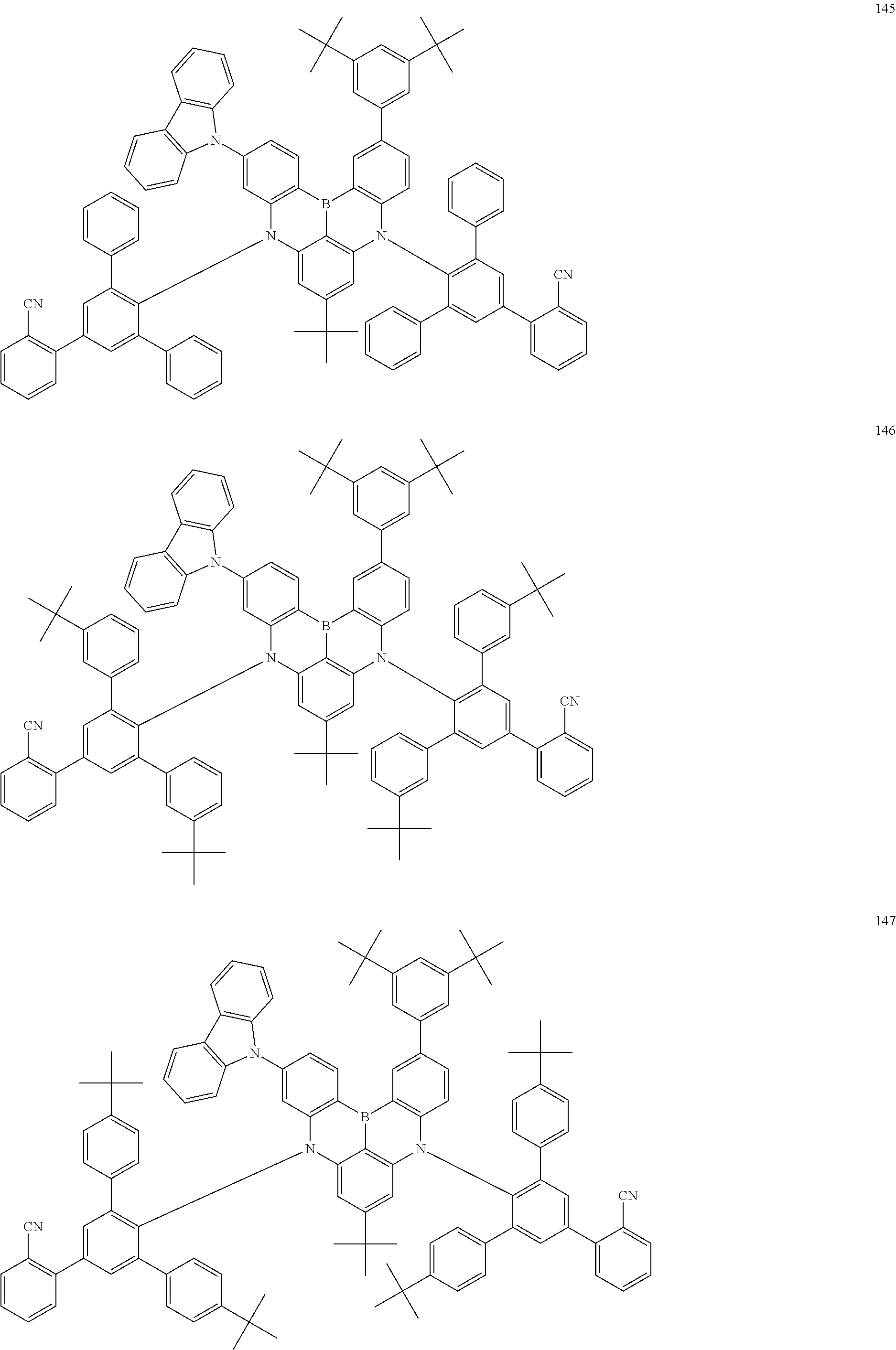 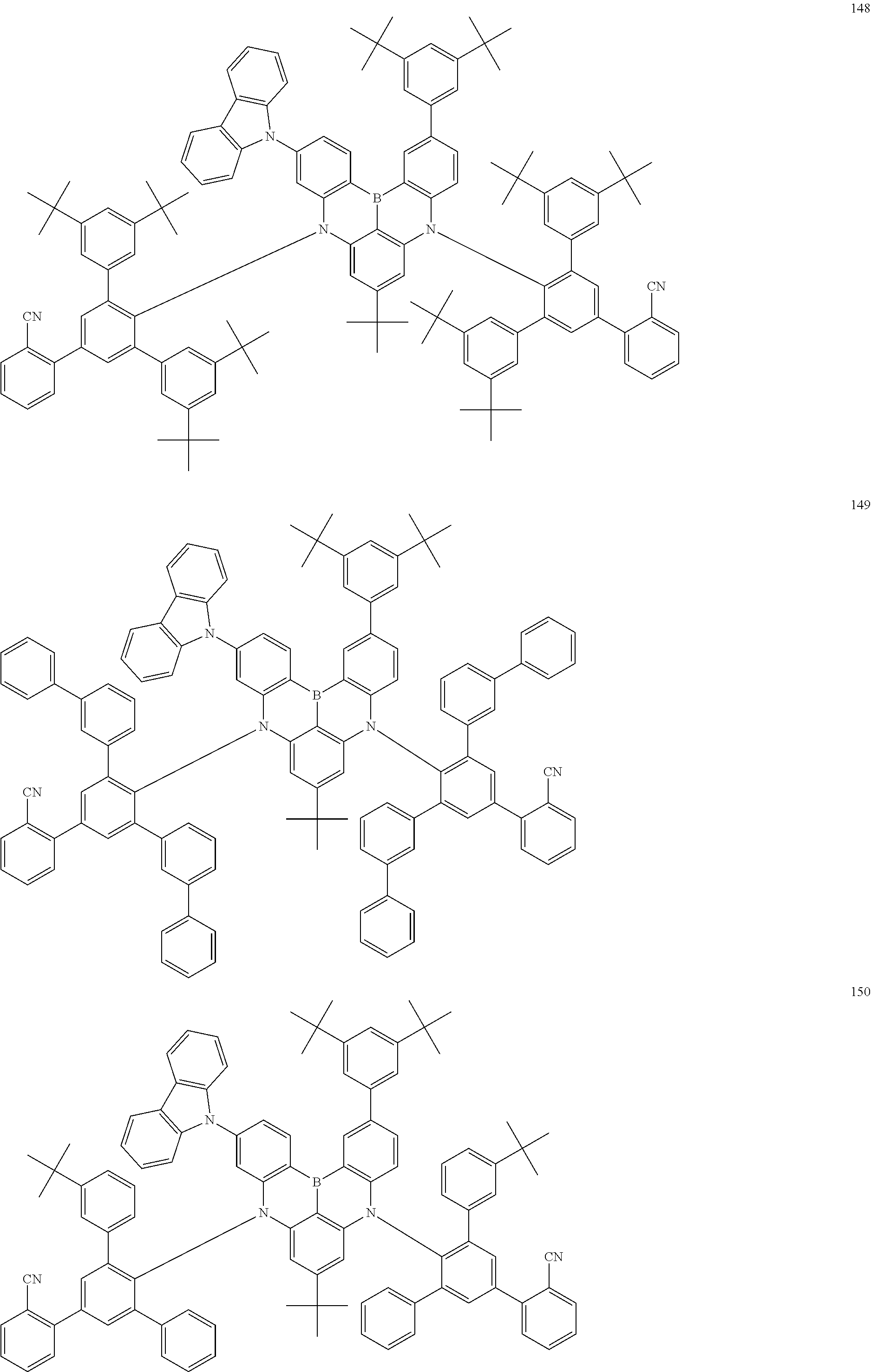 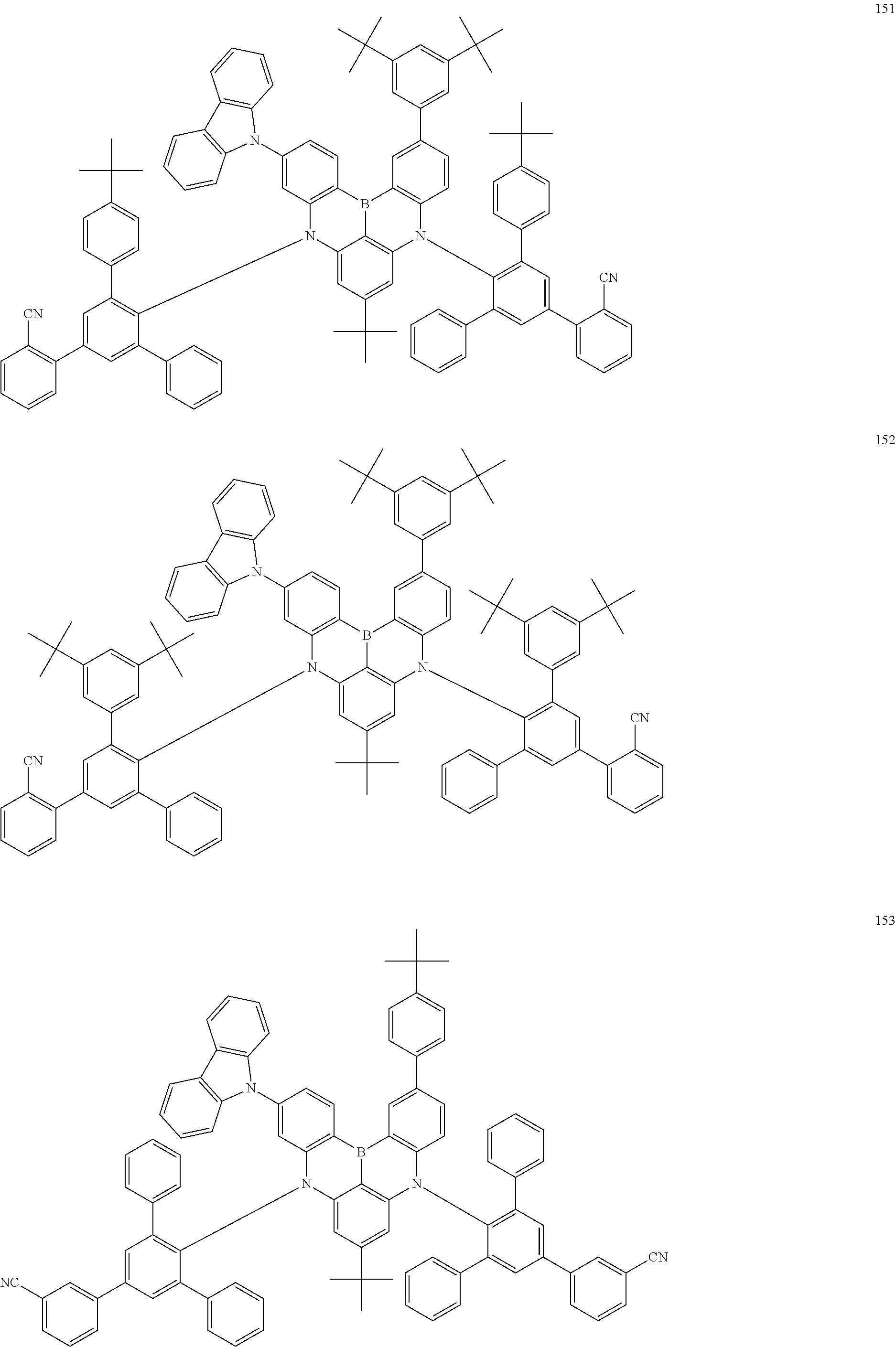 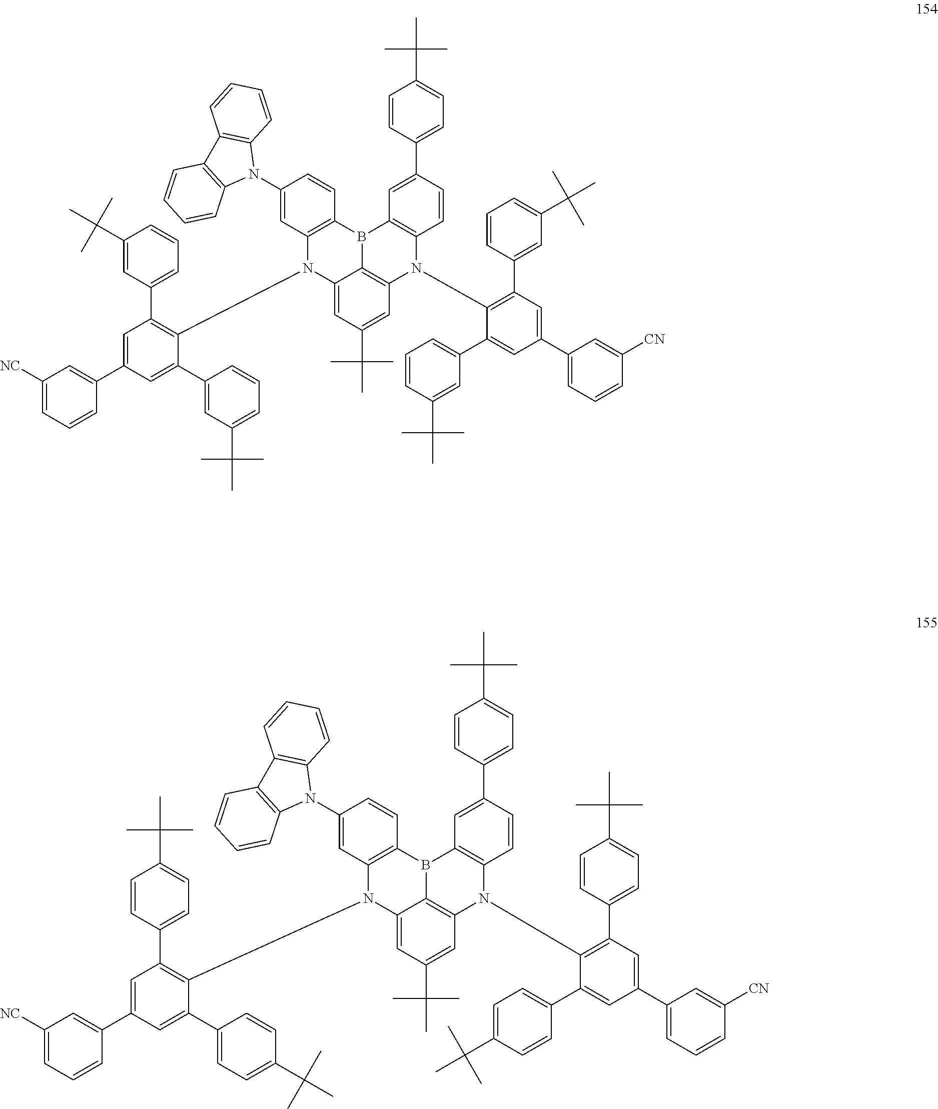 [SMILES: CC(C)(C)c1ccc(-c2ccc3c(c2)B2c4ccc(-n5c6ccccc6c6ccccc65)cc4N(c4c(-c5cccc(C(C)(C)C)c5)cc(-c5cccc(C#N)c5)cc4-c4cccc(C(C)(C)C)c4)c4cc(C(C)(C)C)cc(c42)N3c2c(-c3cccc(C(C)(C)C)c3)cc(-c3cccc(C#N)c3)cc2-c2cccc(C(C)(C)C)c2)cc1 ; CC(C)(C)c1ccc(-c2ccc3c(c2)B2c4ccc(-n5c6ccccc6c6ccccc65)cc4N(c4c(-c5ccc(C(C)(C)C)cc5)cc(-c5cccc(C#N)c5)cc4-c4ccc(C(C)(C)C)cc4)c4cc(C(C)(C)C)cc(c42)N3c2c(-c3ccc(C(C)(C)C)cc3)cc(-c3cccc(C#N)c3)cc2-c2ccc(C(C)(C)C)cc2)cc1] 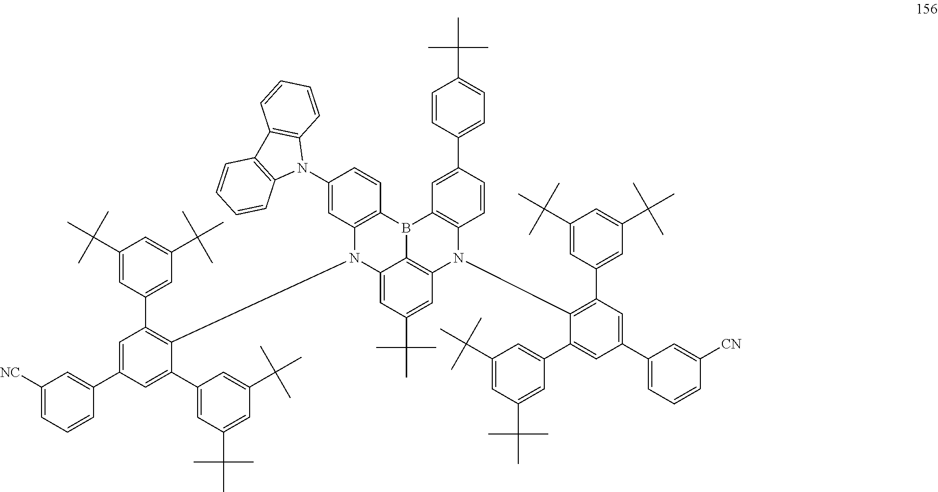 [SMILES: CC(C)(C)c1ccc(-c2ccc3c(c2)B2c4ccc(-n5c6ccccc6c6ccccc65)cc4N(c4c(-c5cc(C(C)(C)C)cc(C(C)(C)C)c5)cc(-c5cccc(C#N)c5)cc4-c4cc(C(C)(C)C)cc(C(C)(C)C)c4)c4cc(C(C)(C)C)cc(c42)N3c2c(-c3cc(C(C)(C)C)cc(C(C)(C)C)c3)cc(-c3cccc(C#N)c3)cc2-c2cc(C(C)(C)C)cc(C(C)(C)C)c2)cc1] 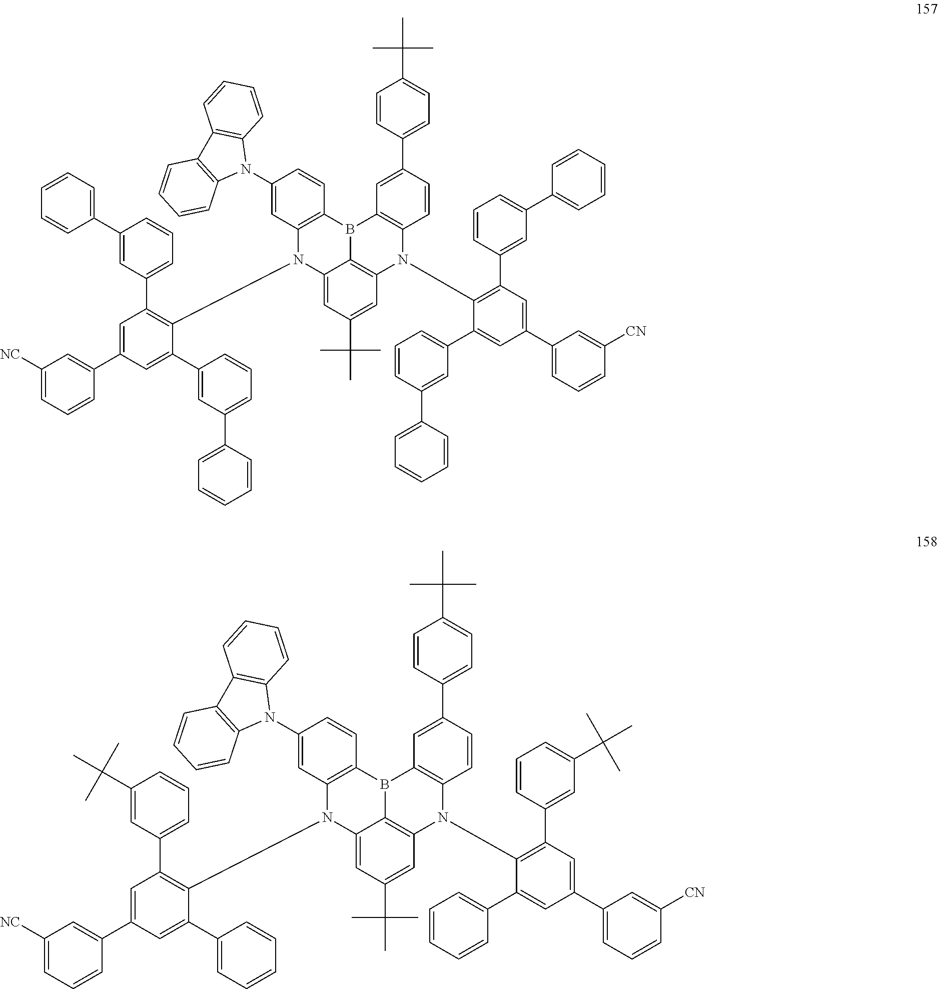 [SMILES: CC(C)(C)c1ccc(-c2ccc3c(c2)B2c4ccc(-n5c6ccccc6c6ccccc65)cc4N(c4c(-c5cccc(-c6ccccc6)c5)cc(-c5cccc(C#N)c5)cc4-c4cccc(-c5ccccc5)c4)c4cc(C(C)(C)C)cc(c42)N3c2c(-c3cccc(-c4ccccc4)c3)cc(-c3cccc(C#N)c3)cc2-c2cccc(-c3ccccc3)c2)cc1 ; CC(C)(C)c1ccc(-c2ccc3c(c2)B2c4ccc(-n5c6ccccc6c6ccccc65)cc4N(c4c(-c5ccccc5)cc(-c5cccc(C#N)c5)cc4-c4cccc(C(C)(C)C)c4)c4cc(C(C)(C)C)cc(c42)N3c2c(-c3ccccc3)cc(-c3cccc(C#N)c3)cc2-c2cccc(C(C)(C)C)c2)cc1] 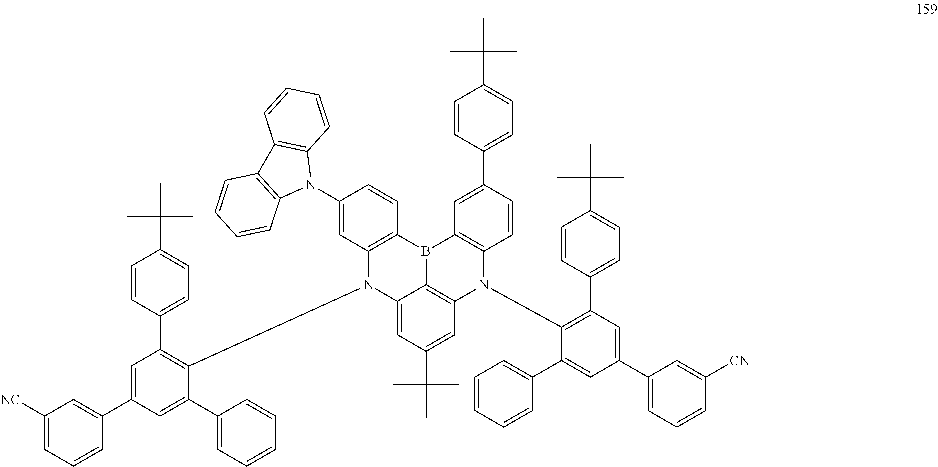 [SMILES: CC(C)(C)c1ccc(-c2ccc3c(c2)B2c4ccc(-n5c6ccccc6c6ccccc65)cc4N(c4c(-c5ccccc5)cc(-c5cccc(C#N)c5)cc4-c4ccc(C(C)(C)C)cc4)c4cc(C(C)(C)C)cc(c42)N3c2c(-c3ccccc3)cc(-c3cccc(C#N)c3)cc2-c2ccc(C(C)(C)C)cc2)cc1] 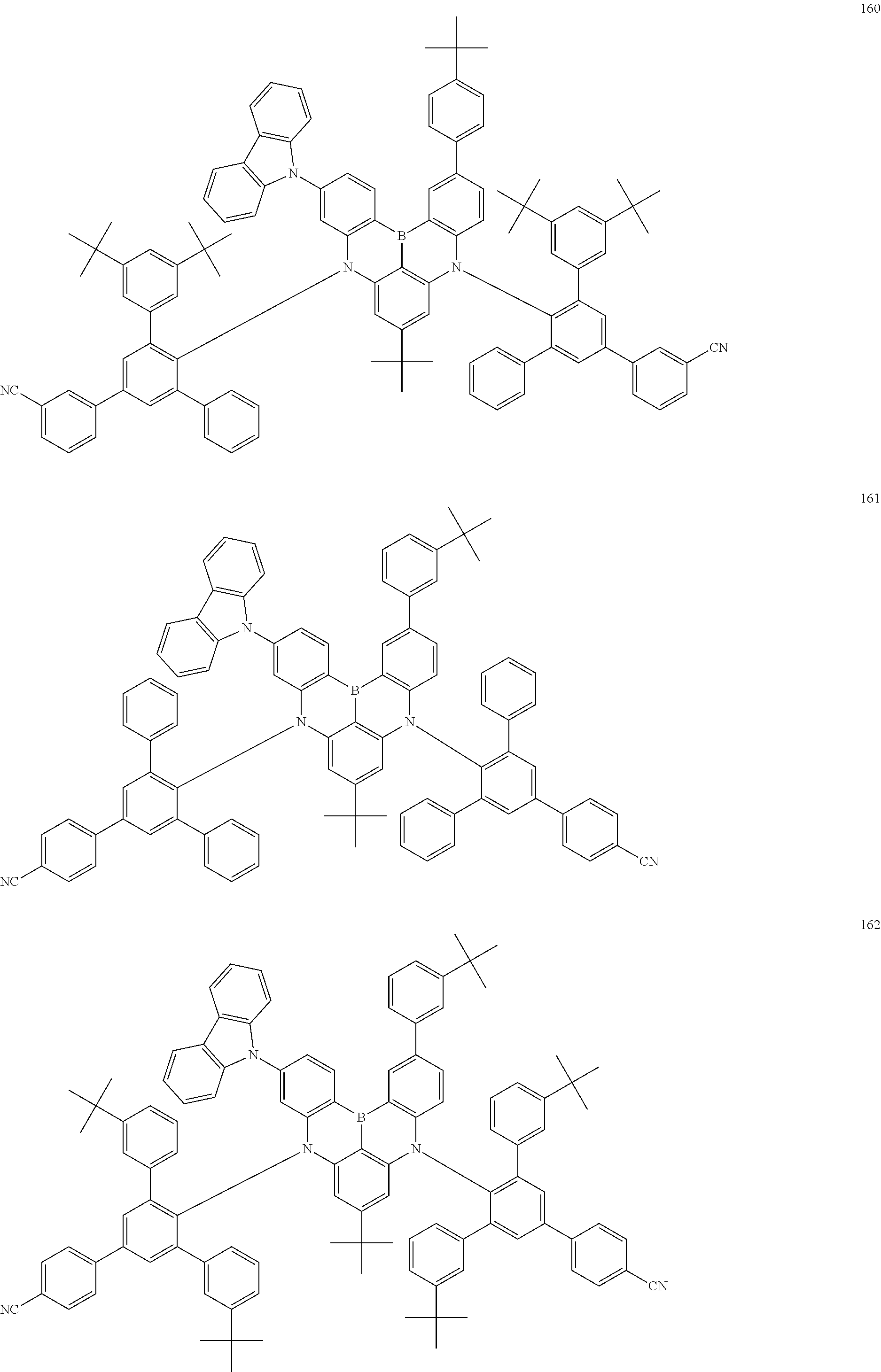 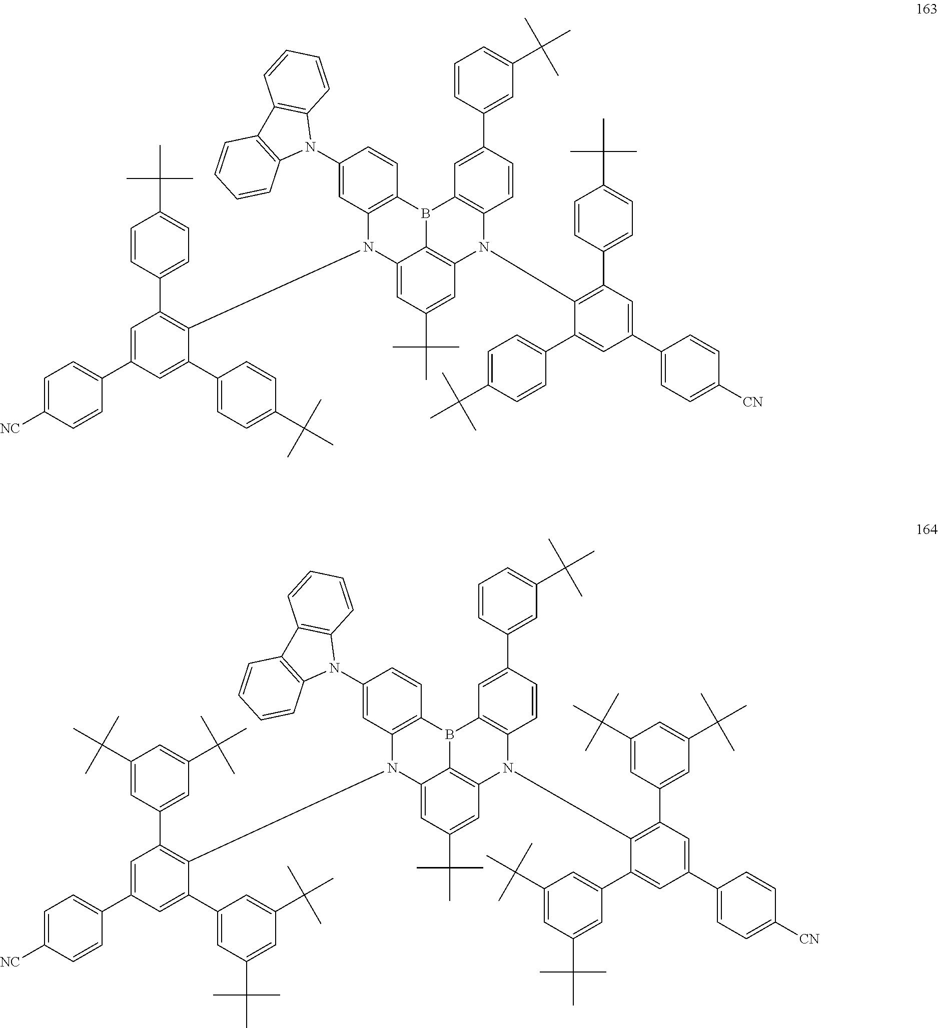 [SMILES: CC(C)(C)c1ccc(-c2cc(-c3ccc(C#N)cc3)cc(-c3ccc(C(C)(C)C)cc3)c2N2c3ccc(-c4cccc(C(C)(C)C)c4)cc3B3c4ccc(-n5c6ccccc6c6ccccc65)cc4N(c4c(-c5ccc(C(C)(C)C)cc5)cc(-c5ccc(C#N)cc5)cc4-c4ccc(C(C)(C)C)cc4)c4cc(C(C)(C)C)cc2c43)cc1 ; CC(C)(C)c1cccc(-c2ccc3c(c2)B2c4ccc(-n5c6ccccc6c6ccccc65)cc4N(c4c(-c5cc(C(C)(C)C)cc(C(C)(C)C)c5)cc(-c5ccc(C#N)cc5)cc4-c4cc(C(C)(C)C)cc(C(C)(C)C)c4)c4cc(C(C)(C)C)cc(c42)N3c2c(-c3cc(C(C)(C)C)cc(C(C)(C)C)c3)cc(-c3ccc(C#N)cc3)cc2-c2cc(C(C)(C)C)cc(C(C)(C)C)c2)c1] 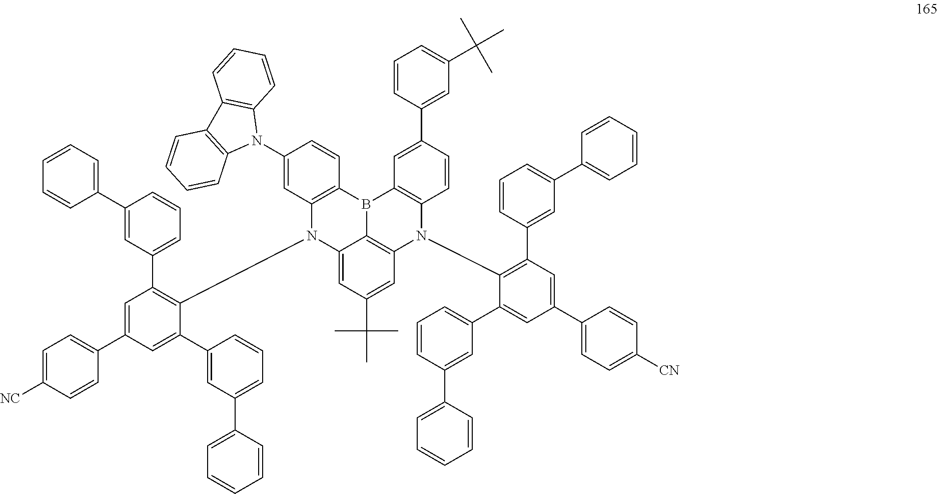 [SMILES: CC(C)(C)c1cccc(-c2ccc3c(c2)B2c4ccc(-n5c6ccccc6c6ccccc65)cc4N(c4c(-c5cccc(-c6ccccc6)c5)cc(-c5ccc(C#N)cc5)cc4-c4cccc(-c5ccccc5)c4)c4cc(C(C)(C)C)cc(c42)N3c2c(-c3cccc(-c4ccccc4)c3)cc(-c3ccc(C#N)cc3)cc2-c2cccc(-c3ccccc3)c2)c1] 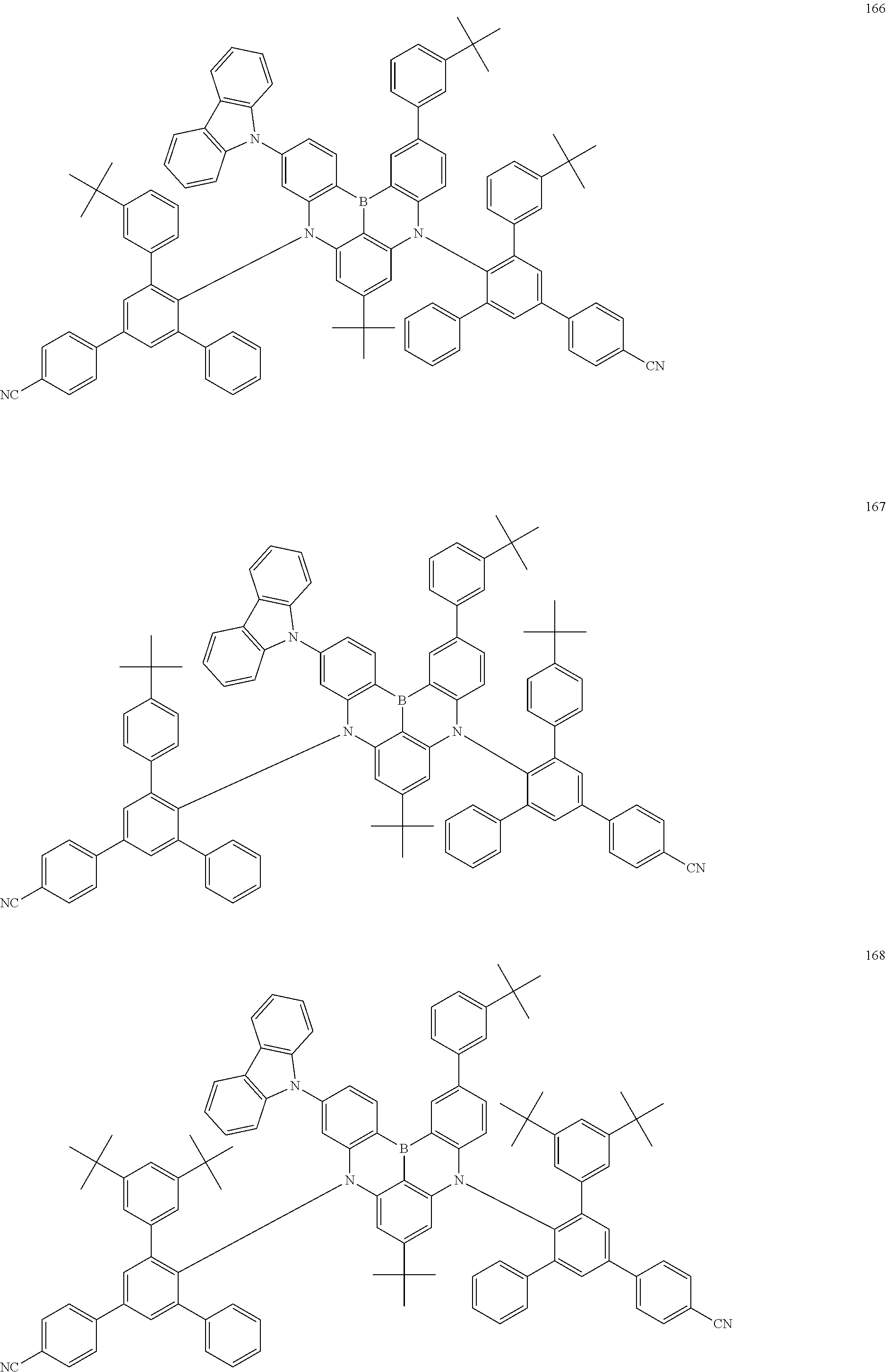 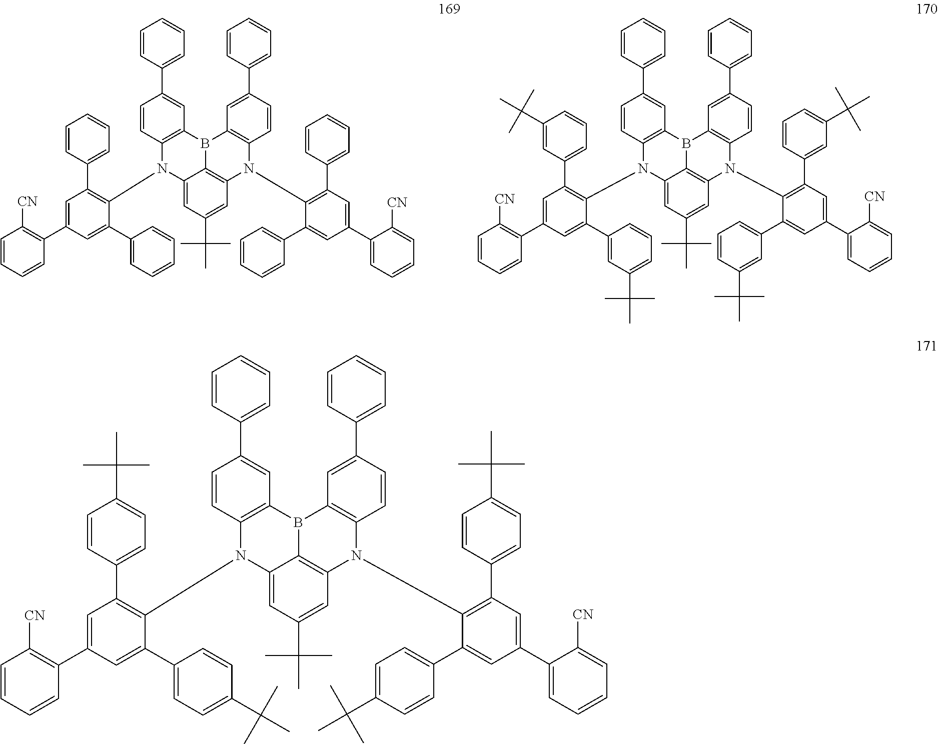 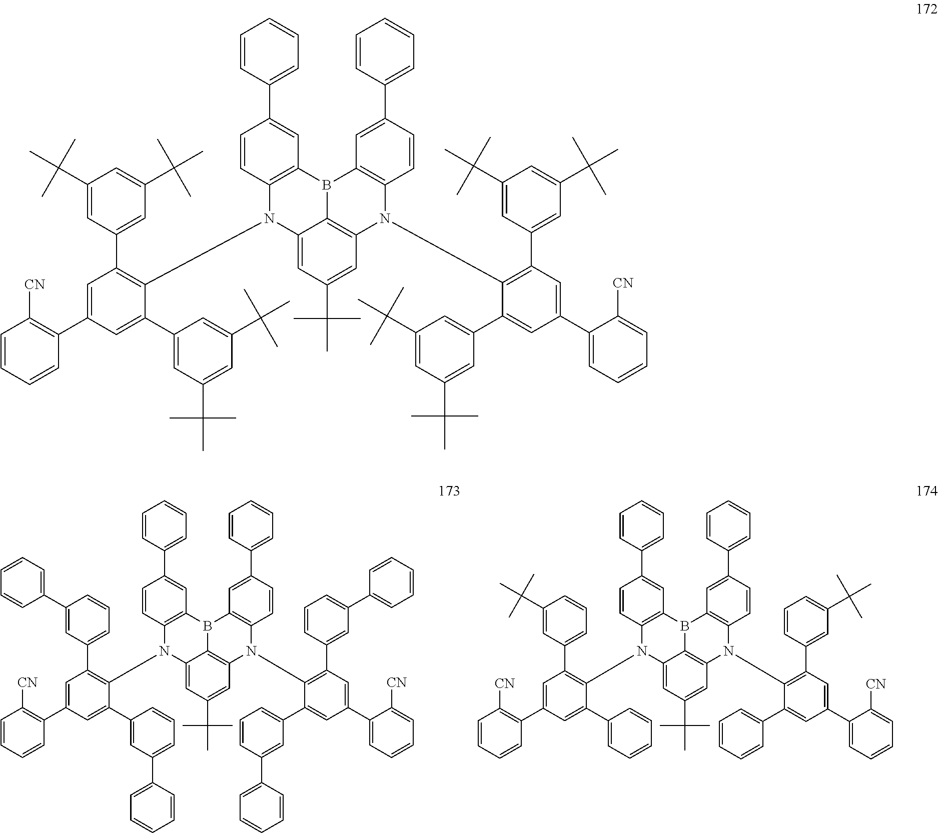 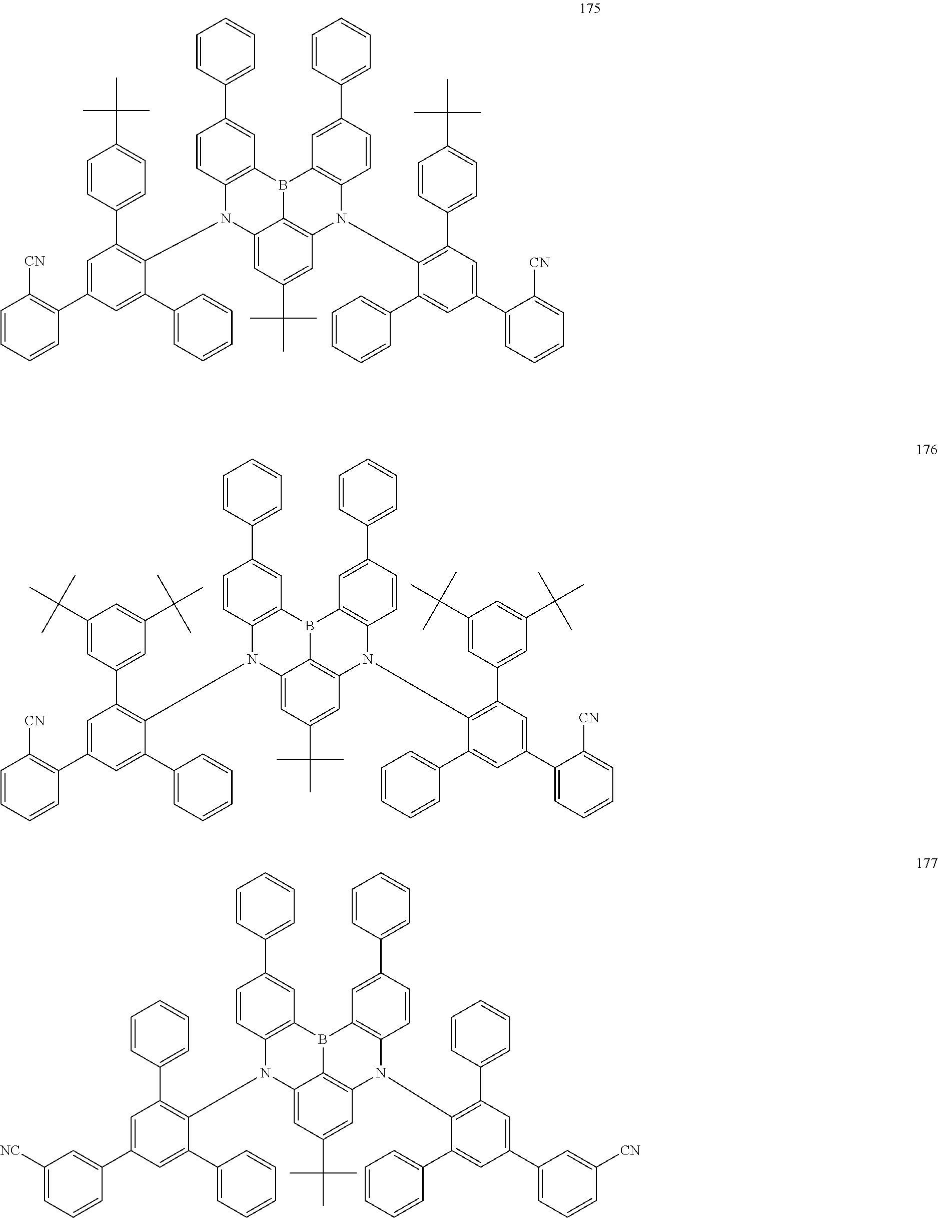 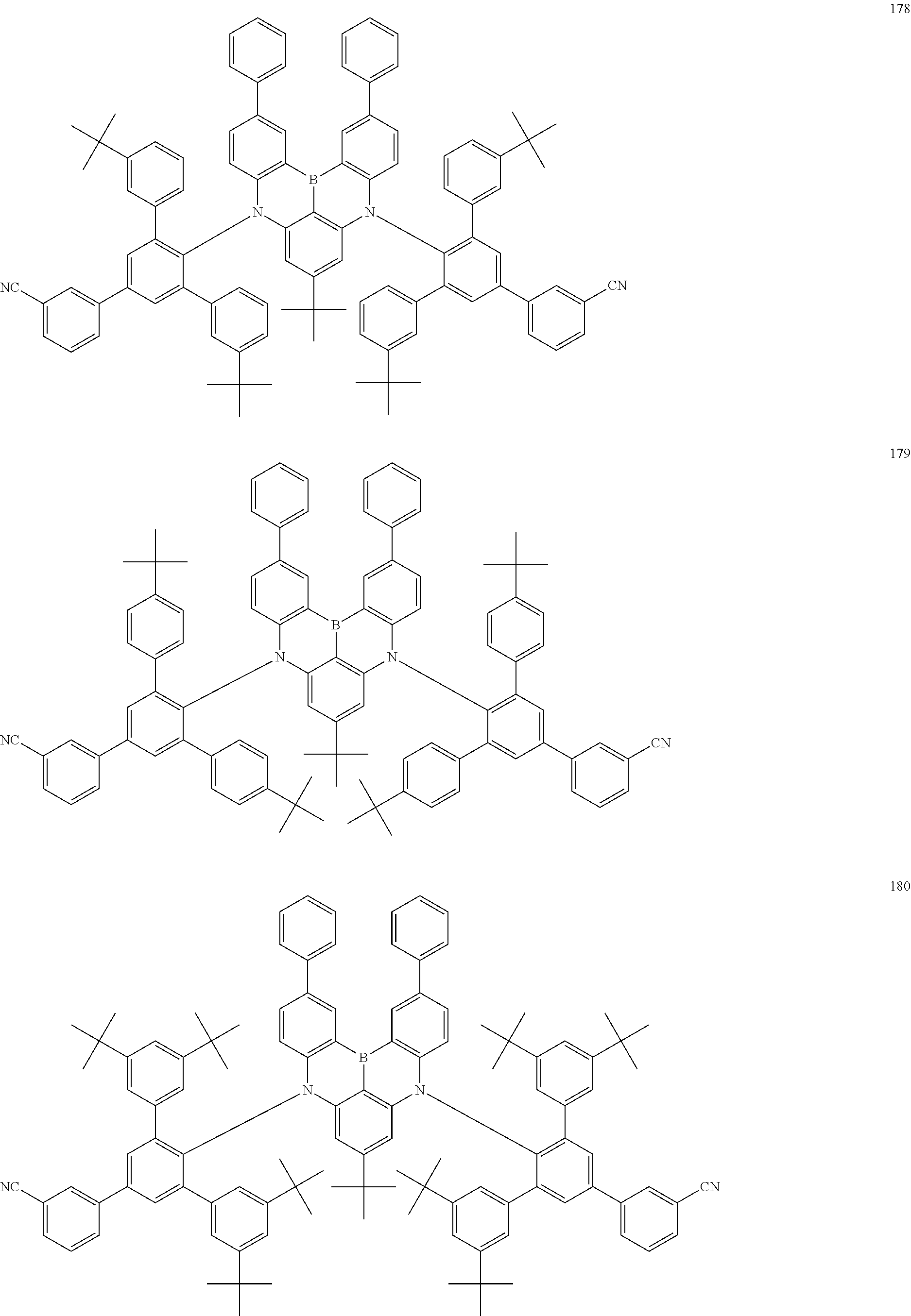 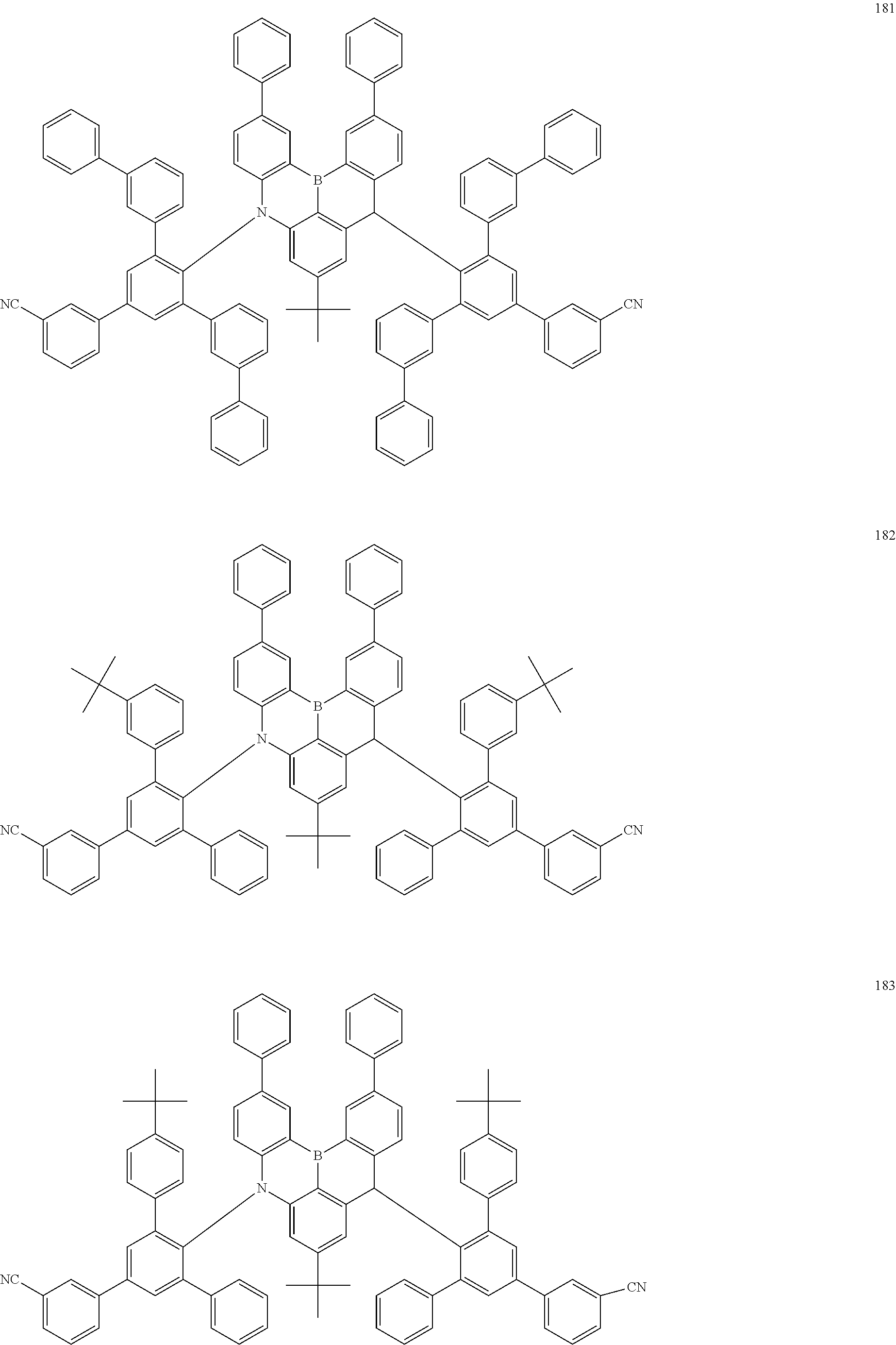 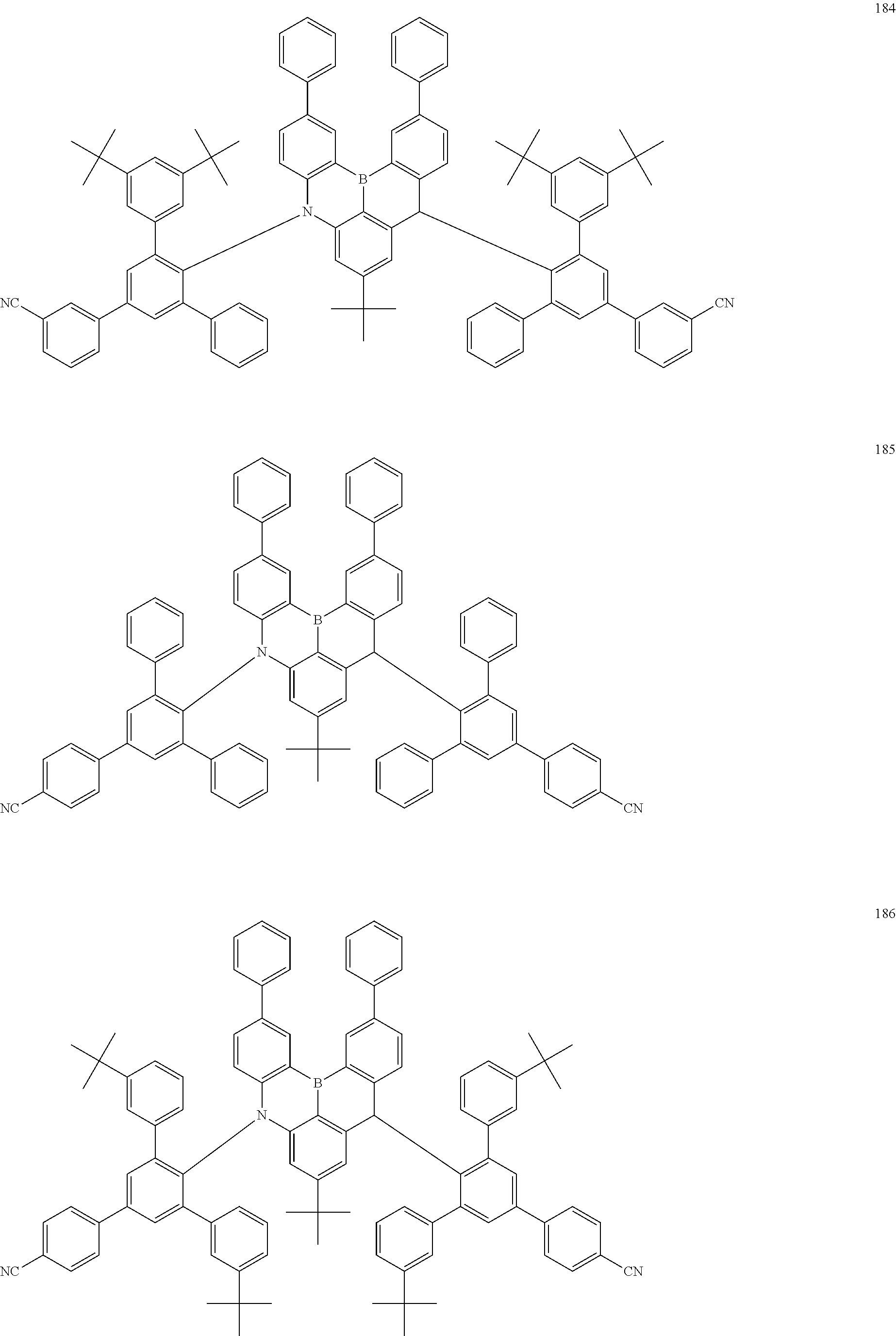 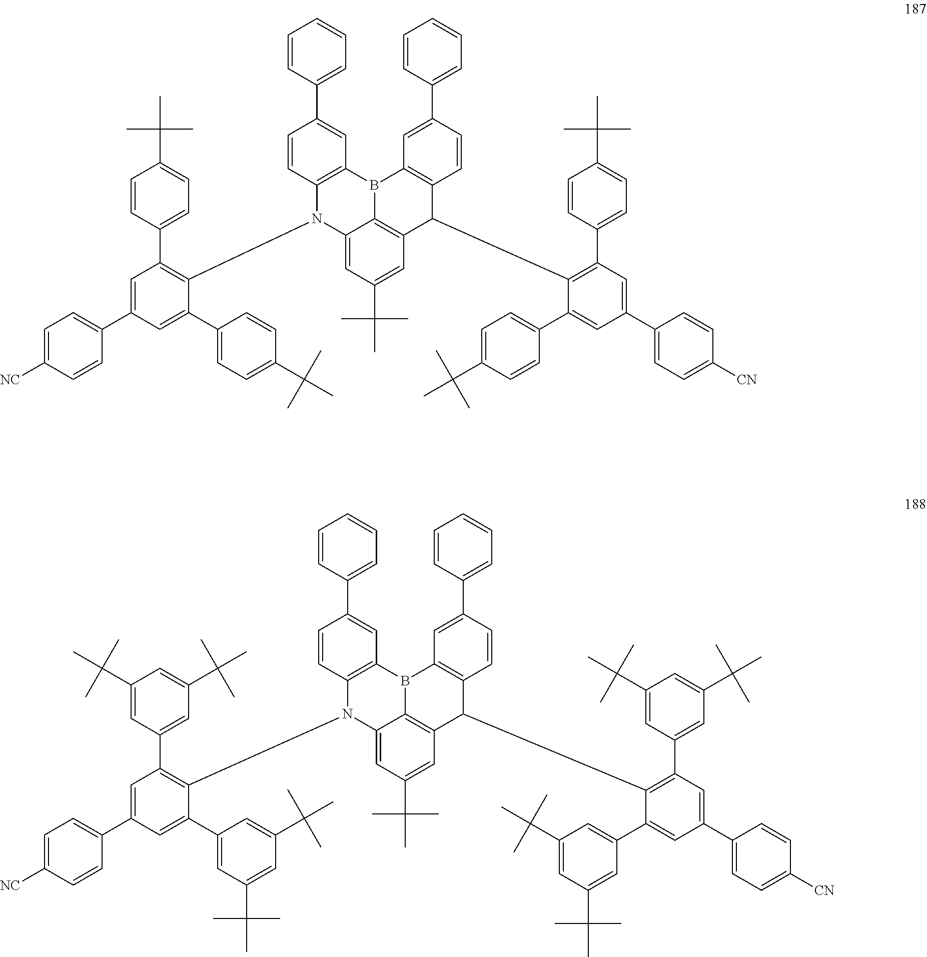 [SMILES: CC(C)(C)c1ccc(-c2cc(-c3ccc(C#N)cc3)cc(-c3ccc(C(C)(C)C)cc3)c2C2c3ccc(-c4ccccc4)cc3B3c4cc(-c5ccccc5)ccc4N(c4c(-c5ccc(C(C)(C)C)cc5)cc(-c5ccc(C#N)cc5)cc4-c4ccc(C(C)(C)C)cc4)c4cc(C(C)(C)C)cc2c43)cc1 ; CC(C)(C)c1cc(-c2cc(-c3ccc(C#N)cc3)cc(-c3cc(C(C)(C)C)cc(C(C)(C)C)c3)c2C2c3ccc(-c4ccccc4)cc3B3c4cc(-c5ccccc5)ccc4N(c4c(-c5cc(C(C)(C)C)cc(C(C)(C)C)c5)cc(-c5ccc(C#N)cc5)cc4-c4cc(C(C)(C)C)cc(C(C)(C)C)c4)c4cc(C(C)(C)C)cc2c43)cc(C(C)(C)C)c1] 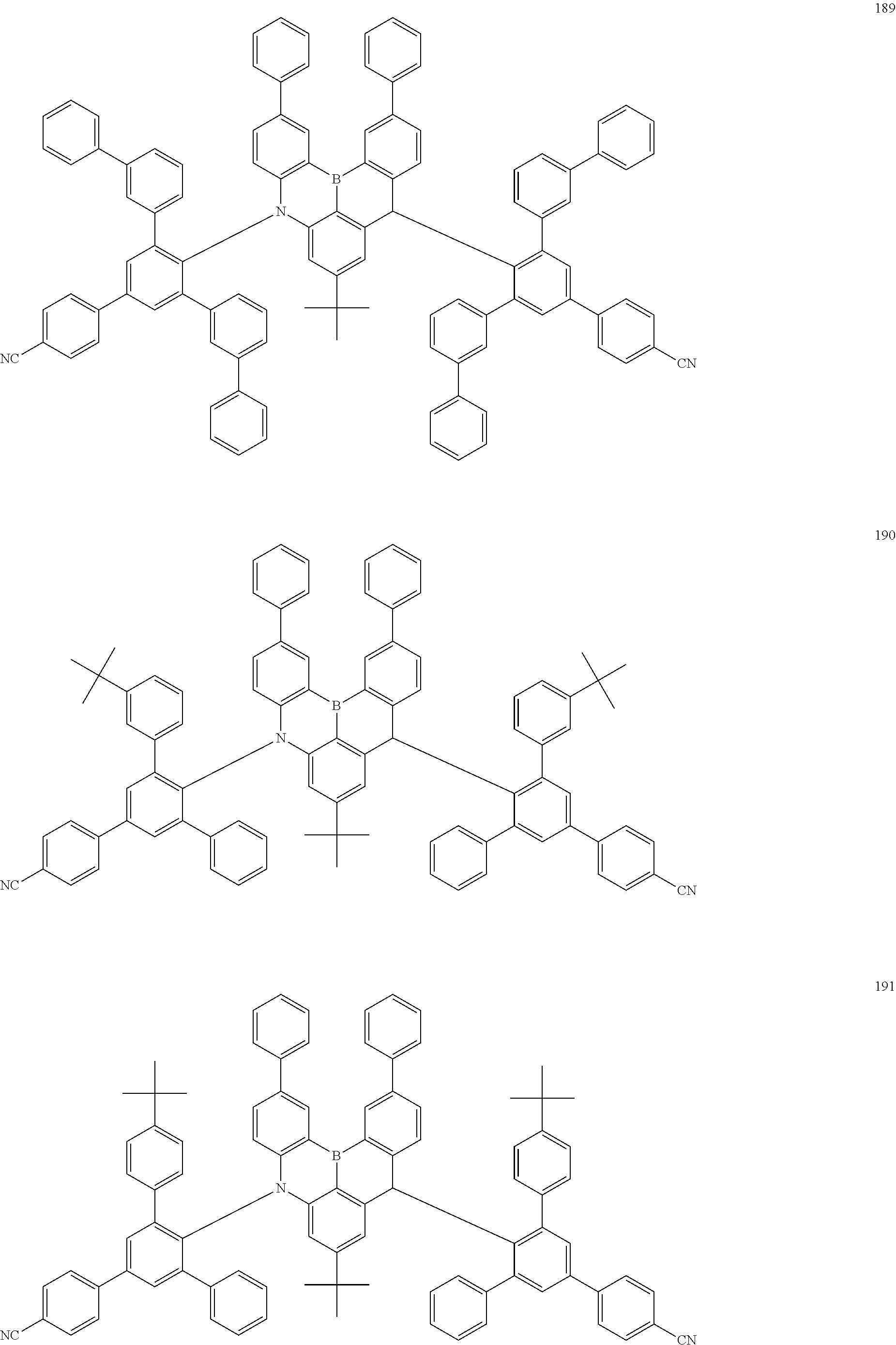 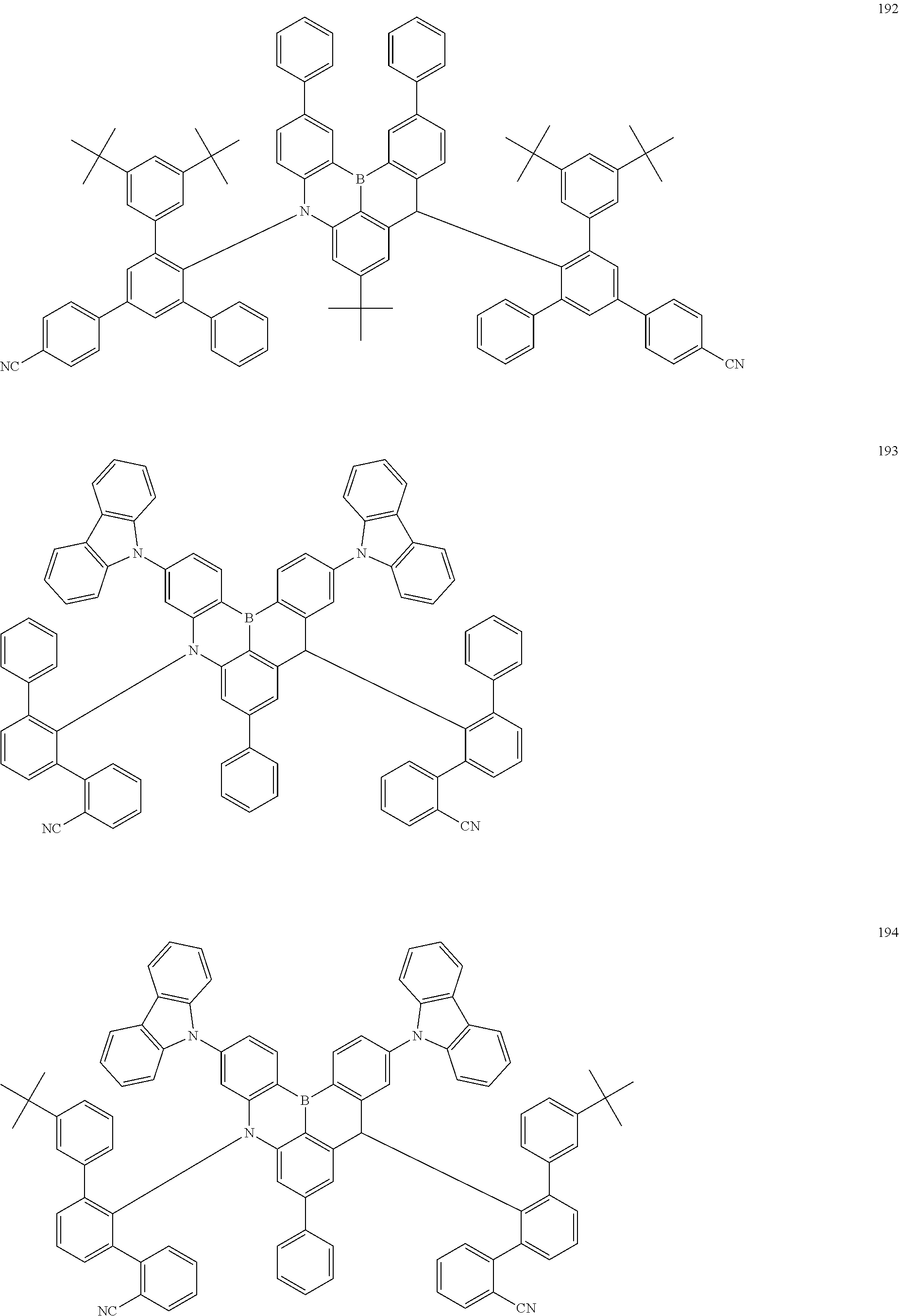 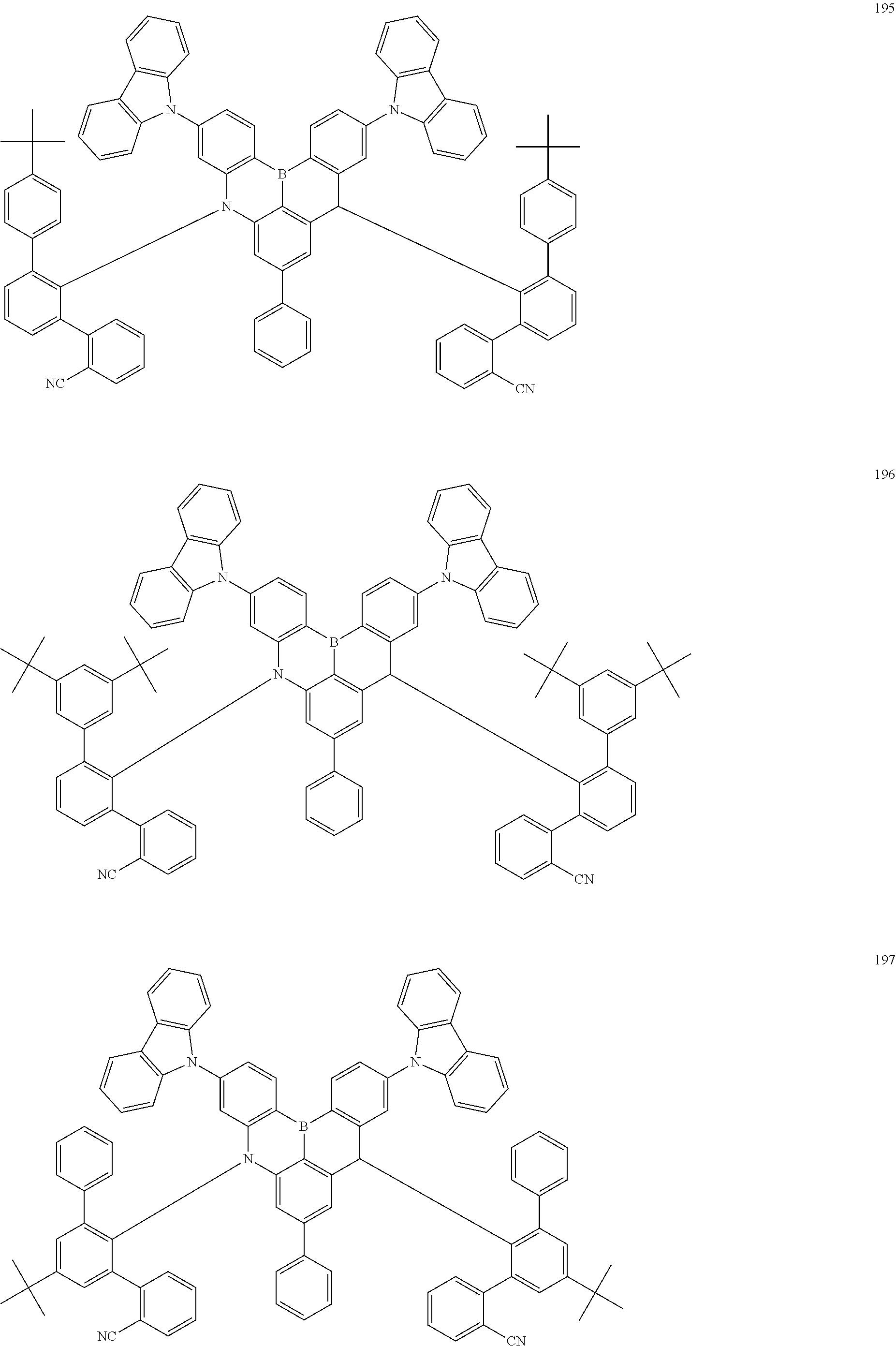 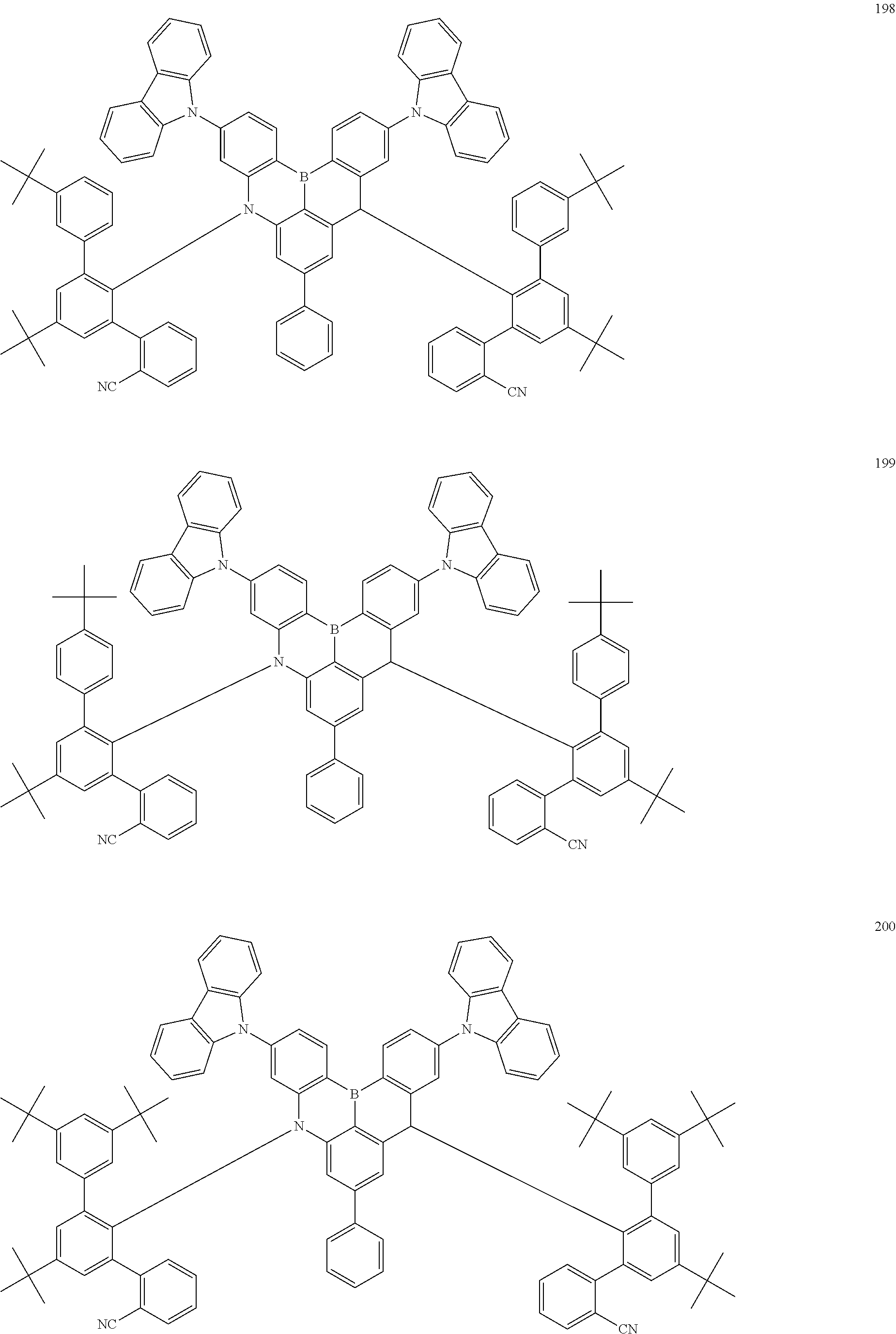 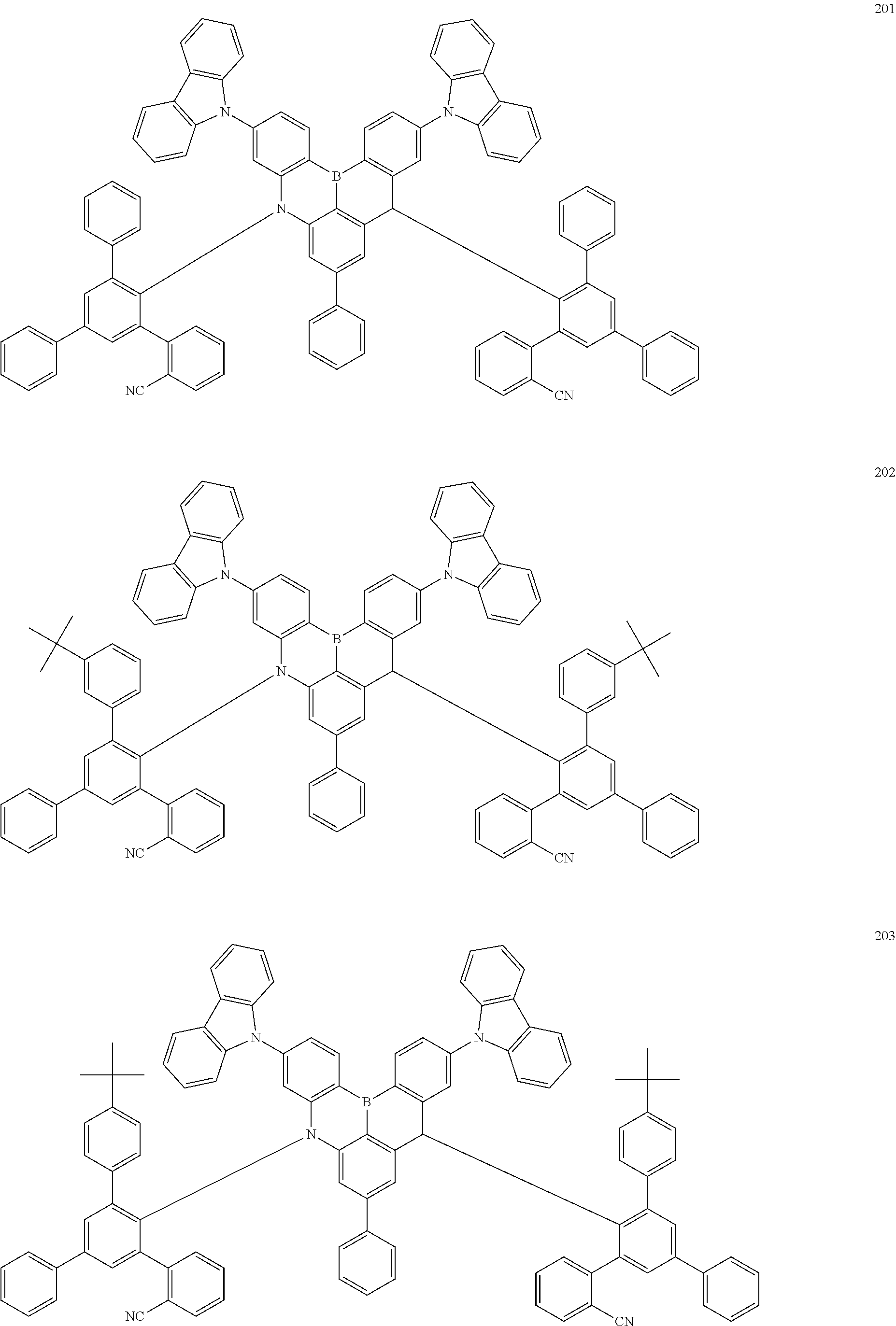 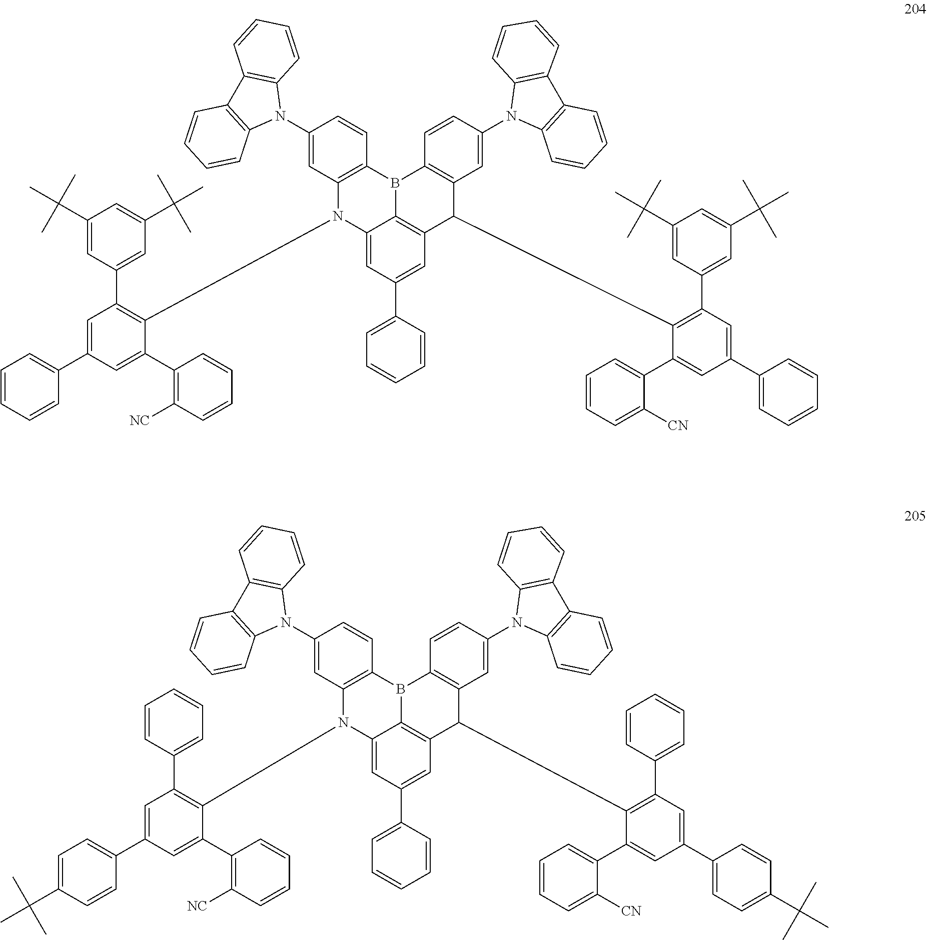 [SMILES: CC(C)(C)c1cc(-c2cc(-c3ccccc3)cc(-c3ccccc3C#N)c2C2c3cc(-n4c5ccccc5c5ccccc54)ccc3B3c4ccc(-n5c6ccccc6c6ccccc65)cc4N(c4c(-c5cc(C(C)(C)C)cc(C(C)(C)C)c5)cc(-c5ccccc5)cc4-c4ccccc4C#N)c4cc(-c5ccccc5)cc2c43)cc(C(C)(C)C)c1 ; CC(C)(C)c1ccc(-c2cc(-c3ccccc3)c(C3c4cc(-n5c6ccccc6c6ccccc65)ccc4B4c5ccc(-n6c7ccccc7c7ccccc76)cc5N(c5c(-c6ccccc6)cc(-c6ccc(C(C)(C)C)cc6)cc5-c5ccccc5C#N)c5cc(-c6ccccc6)cc3c54)c(-c3ccccc3C#N)c2)cc1] 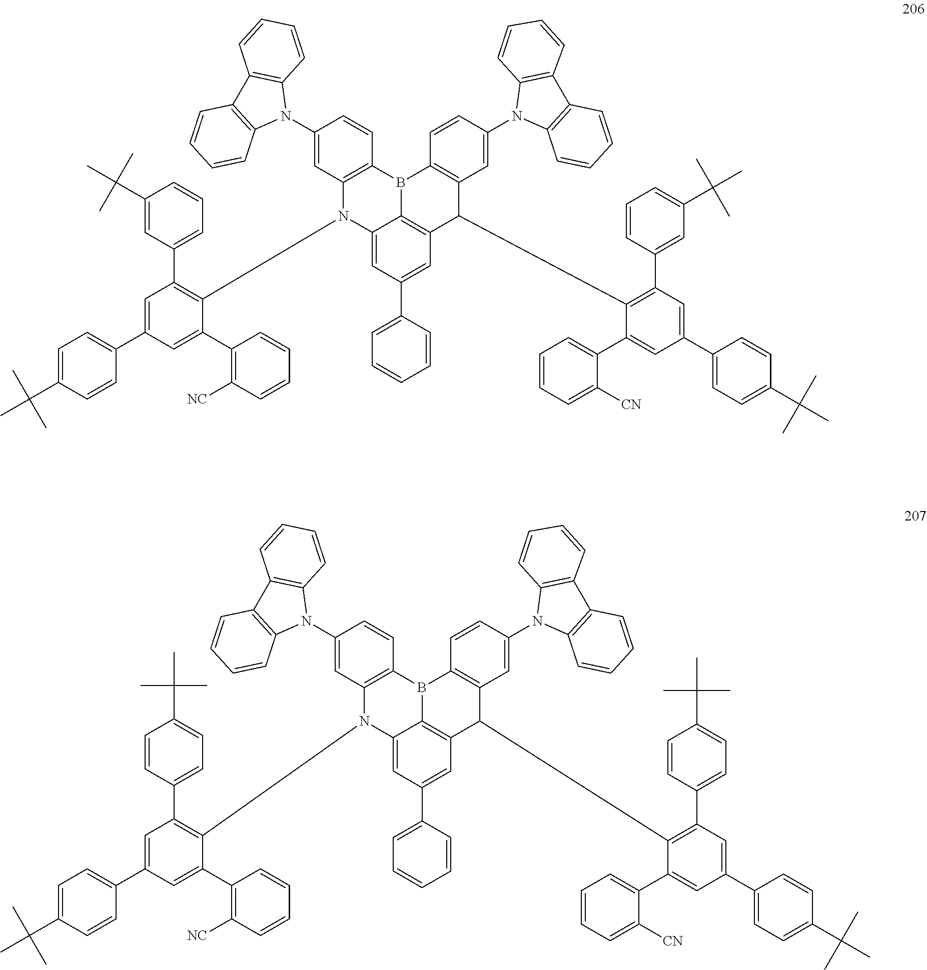 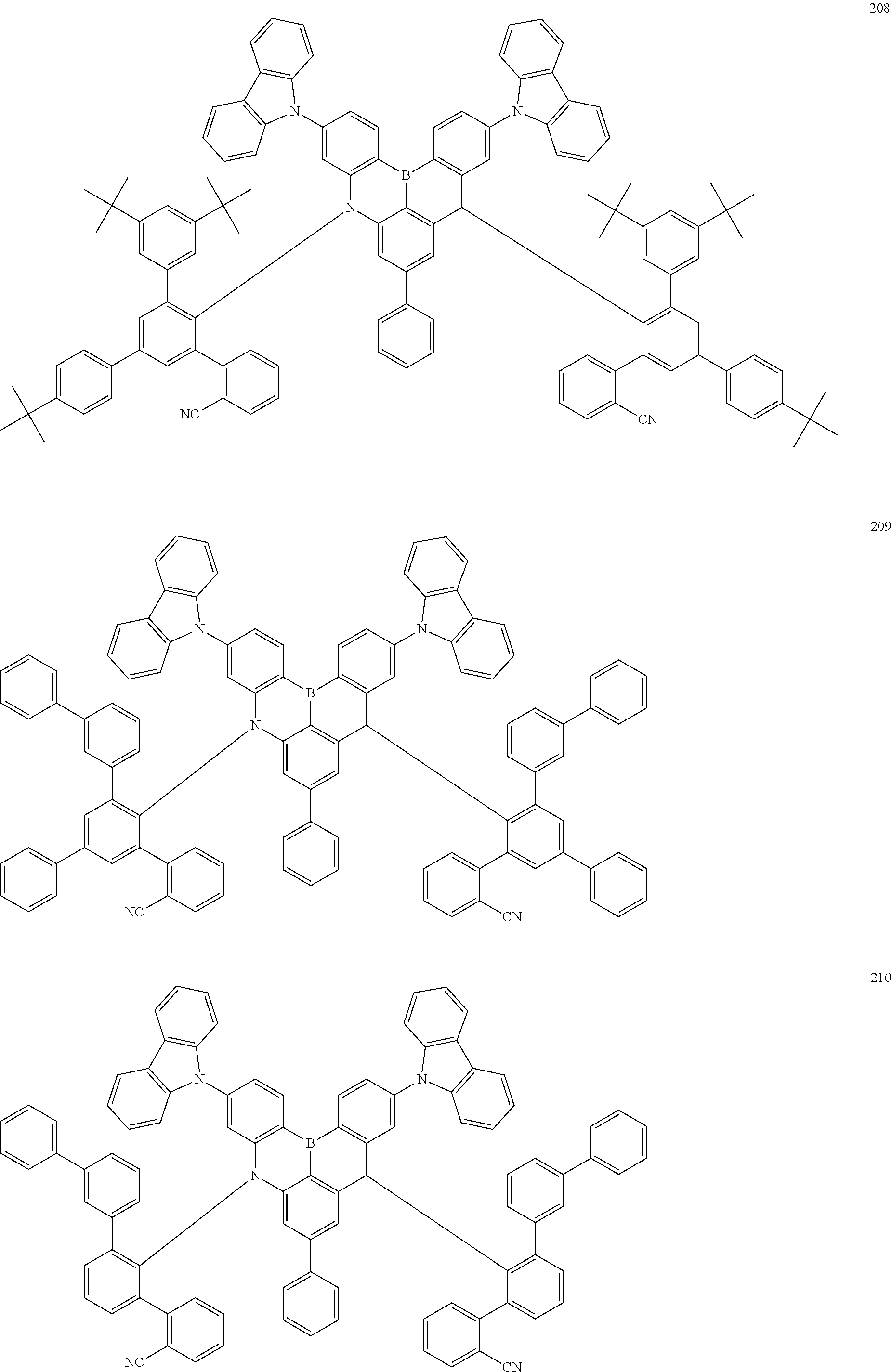 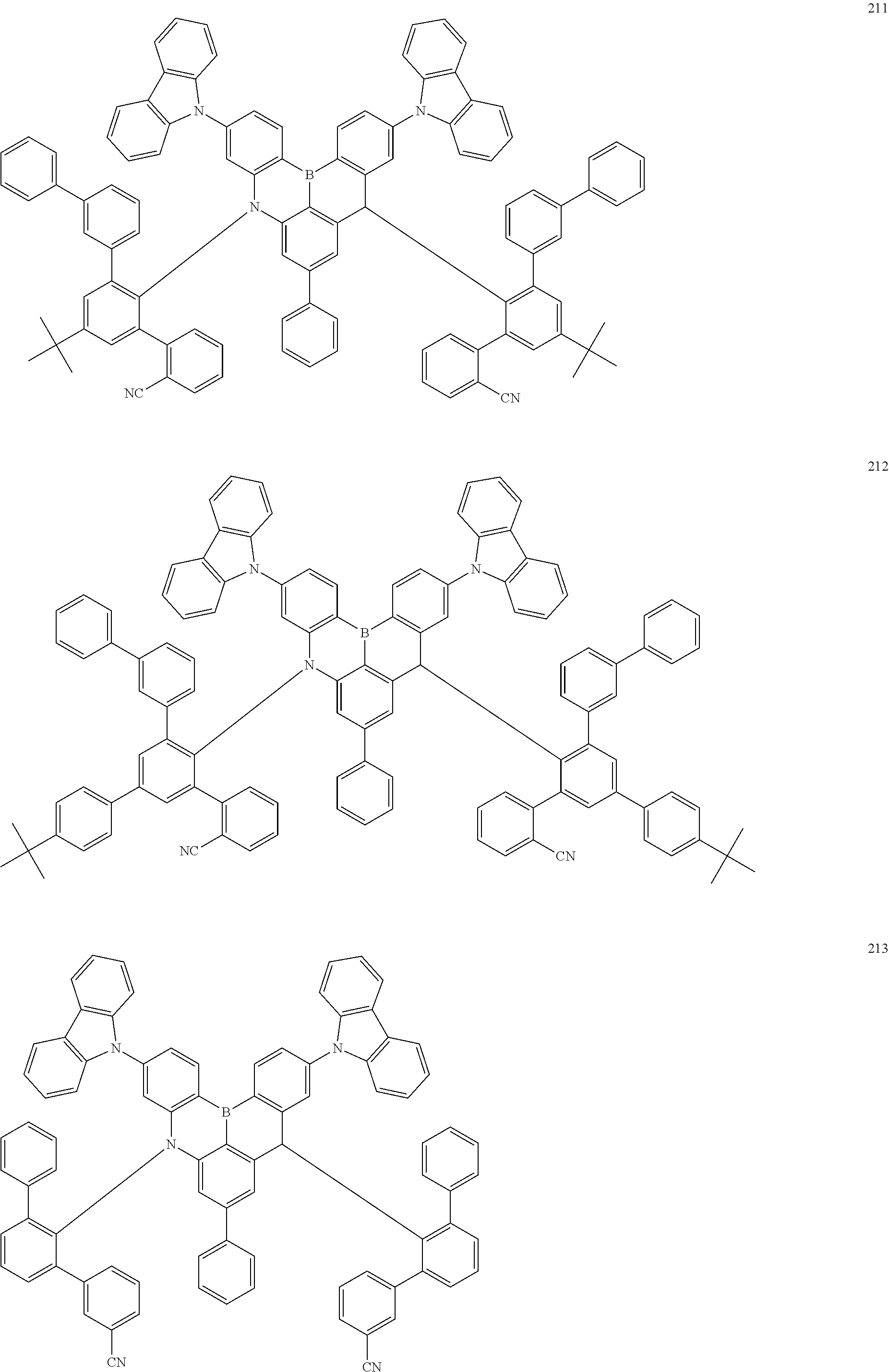 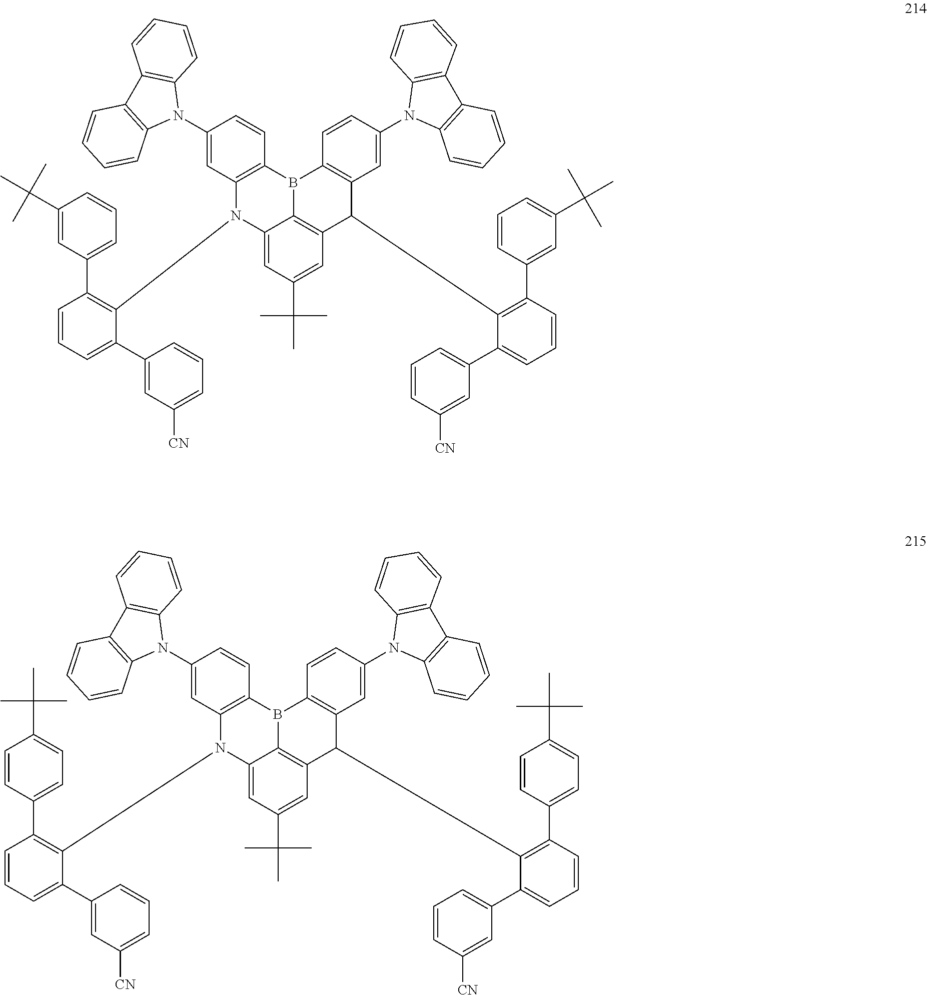 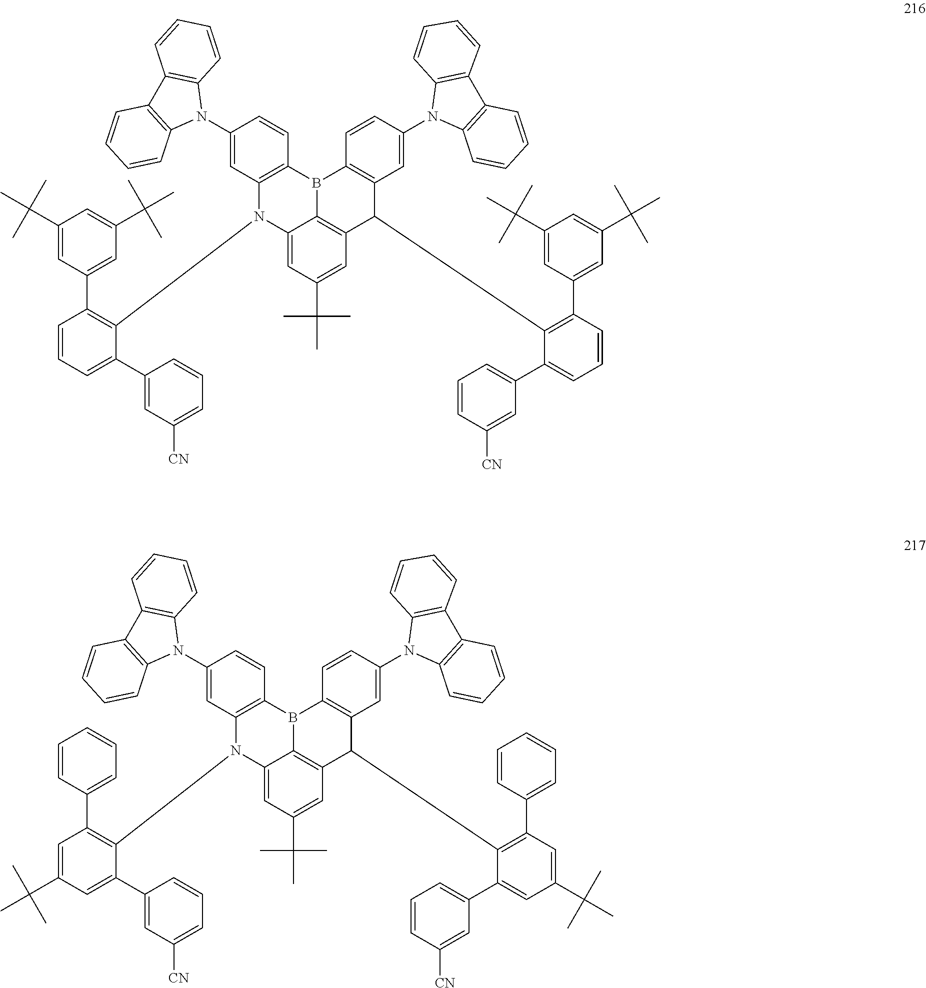 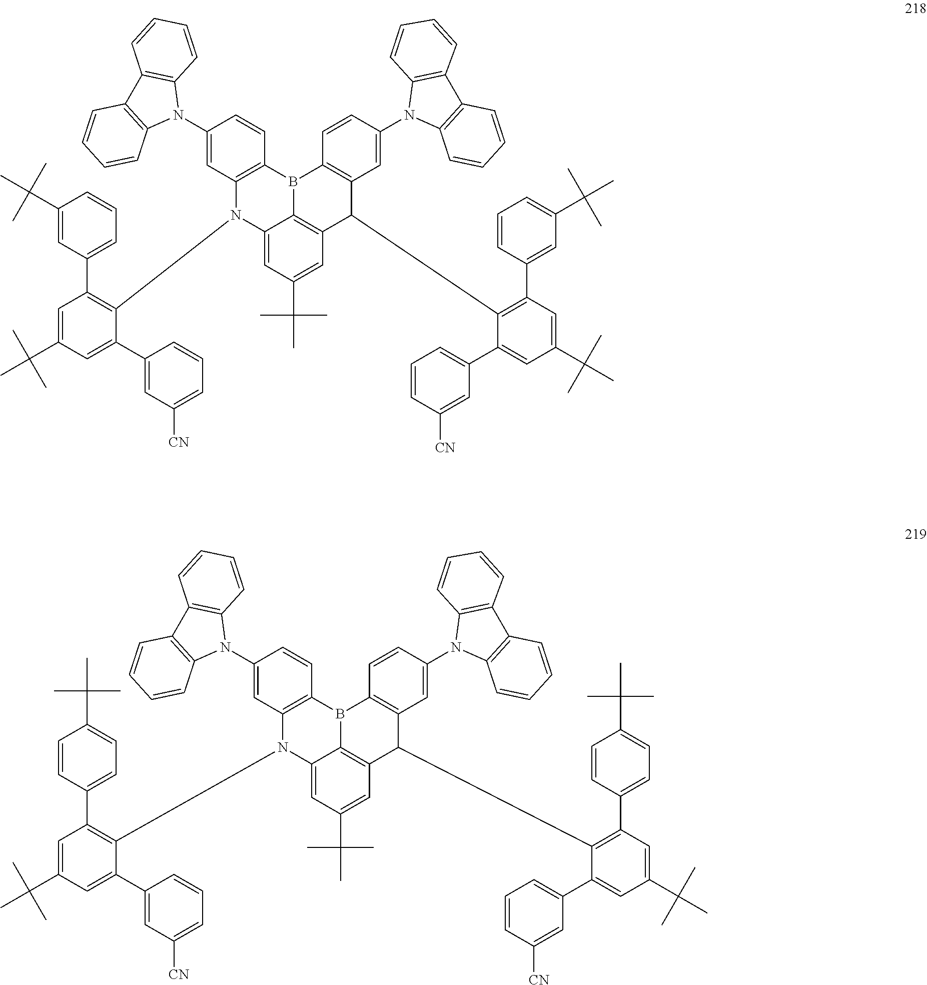 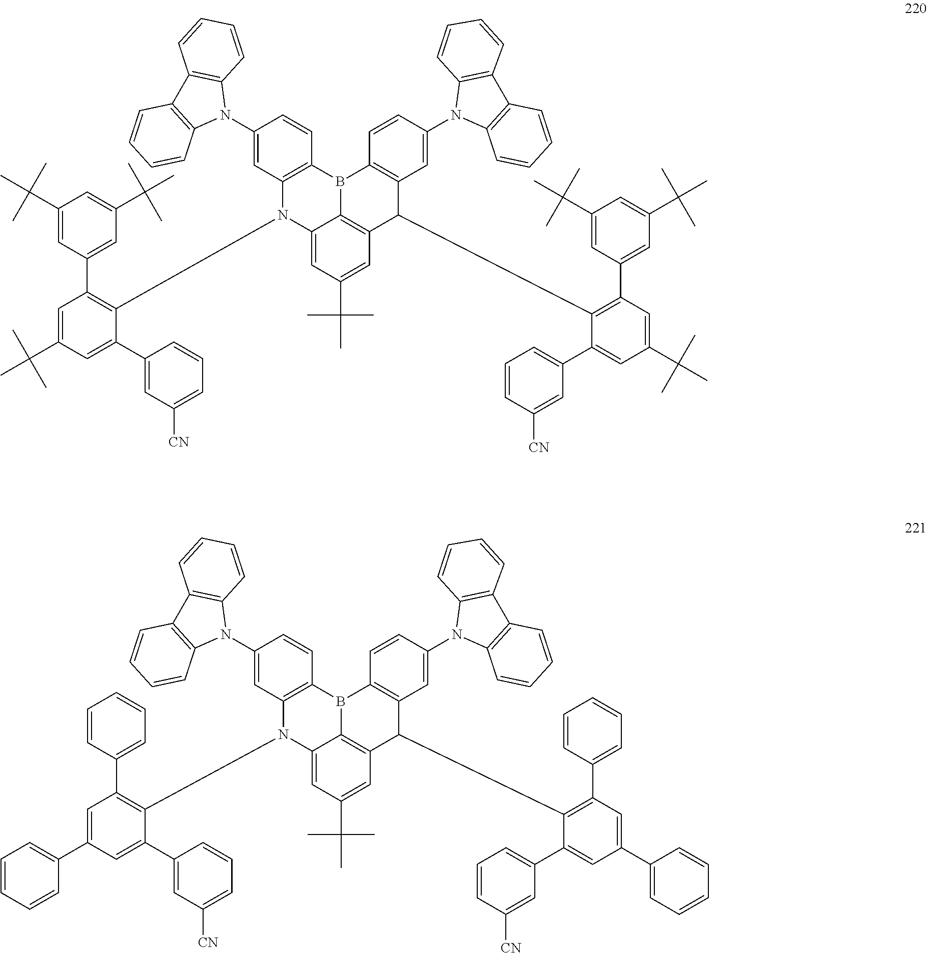 [SMILES: CC(C)(C)c1cc(-c2cc(C(C)(C)C)cc(-c3cccc(C#N)c3)c2C2c3cc(-n4c5ccccc5c5ccccc54)ccc3B3c4ccc(-n5c6ccccc6c6ccccc65)cc4N(c4c(-c5cccc(C#N)c5)cc(C(C)(C)C)cc4-c4cc(C(C)(C)C)cc(C(C)(C)C)c4)c4cc(C(C)(C)C)cc2c43)cc(C(C)(C)C)c1 ; CC(C)(C)c1cc2c3c(c1)N(c1c(-c4ccccc4)cc(-c4ccccc4)cc1-c1cccc(C#N)c1)c1cc(-n4c5ccccc5c5ccccc54)ccc1B3c1ccc(-n3c4ccccc4c4ccccc43)cc1C2c1c(-c2ccccc2)cc(-c2ccccc2)cc1-c1cccc(C#N)c1] 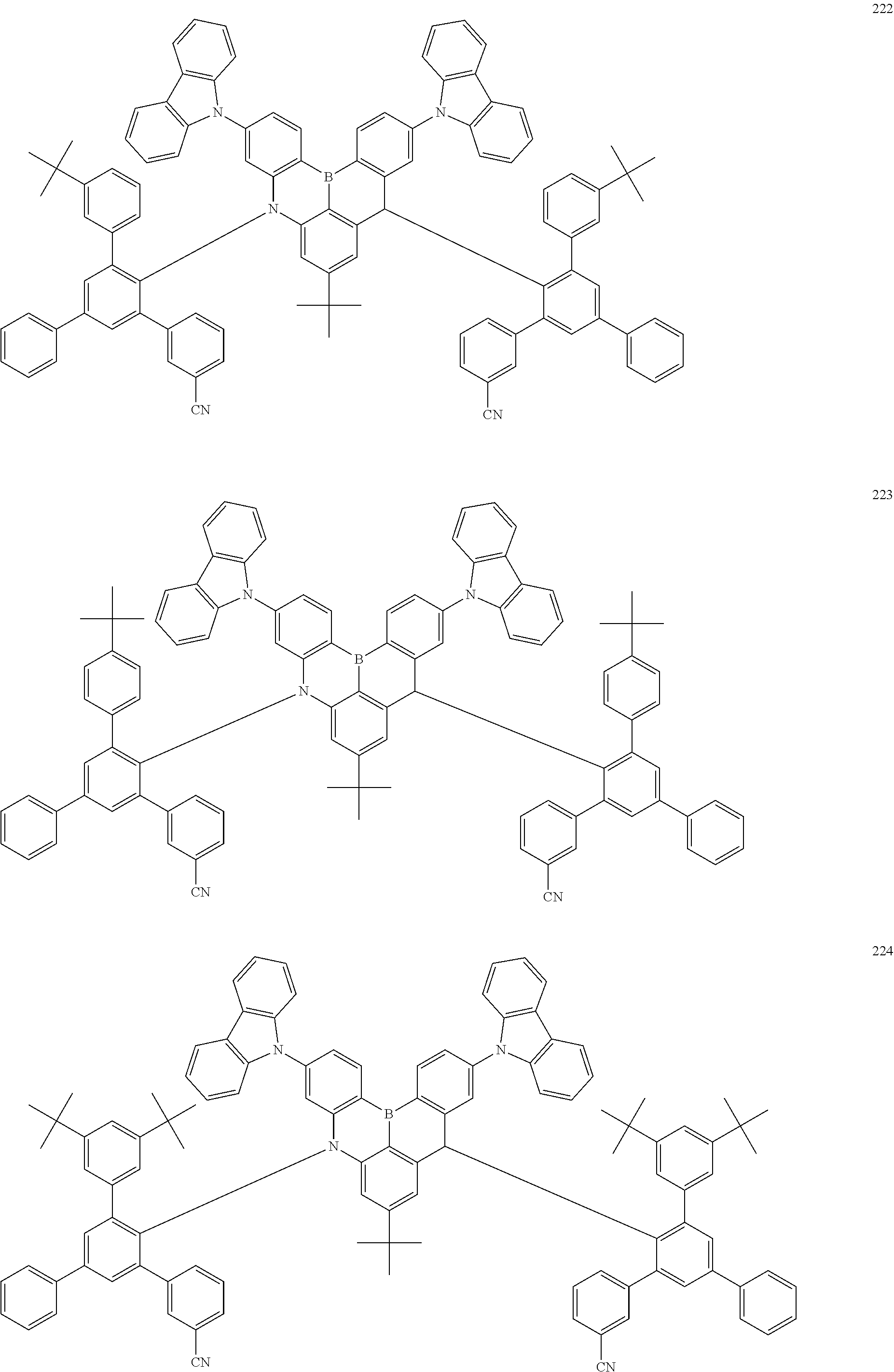 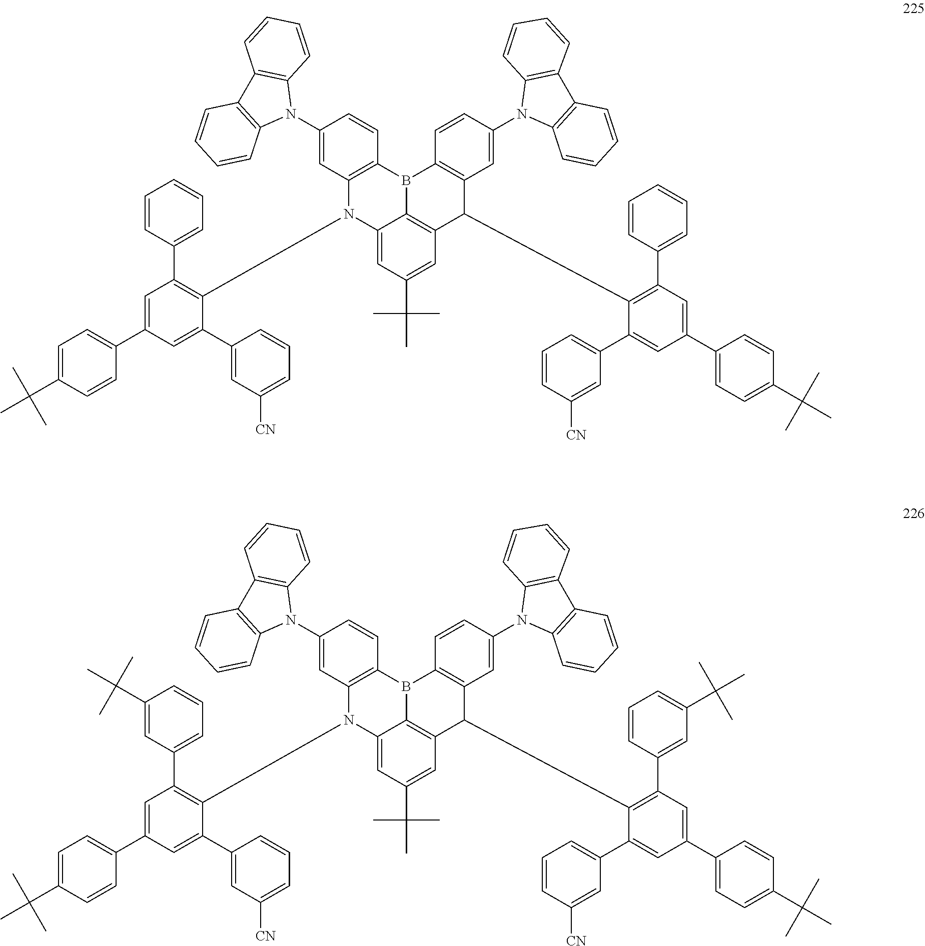 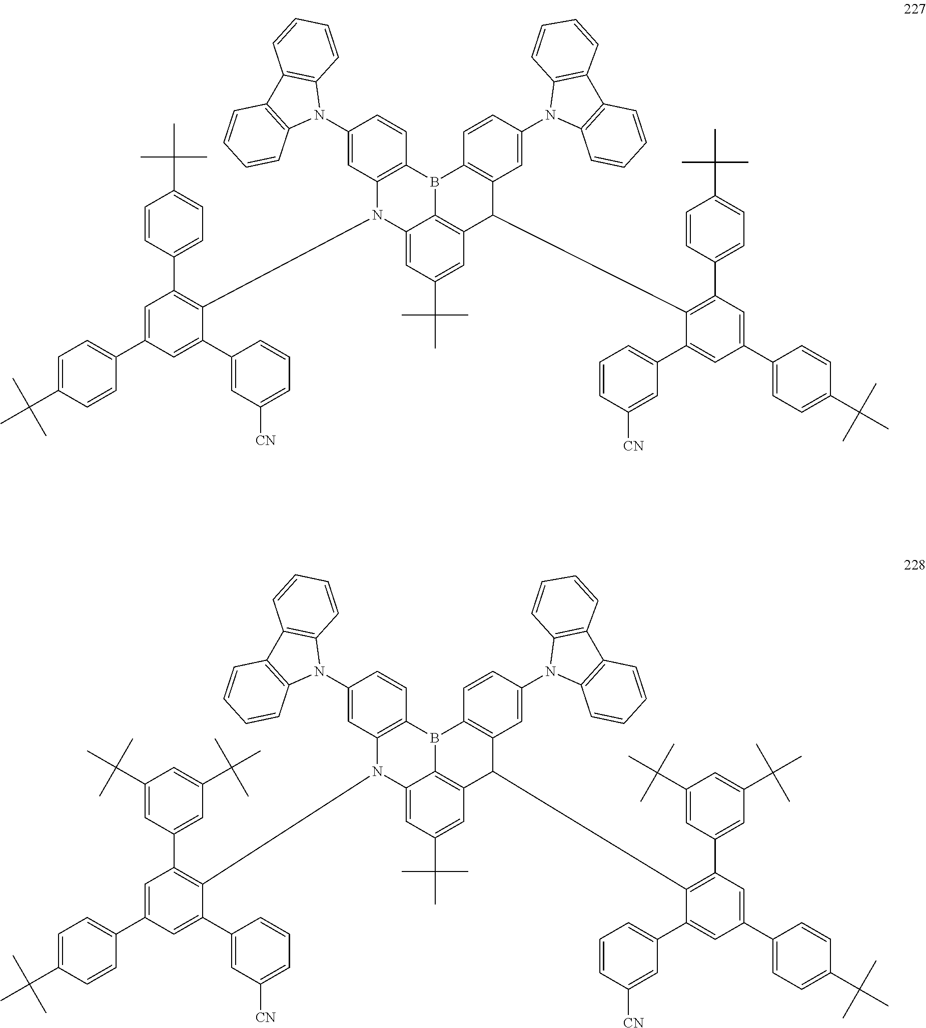 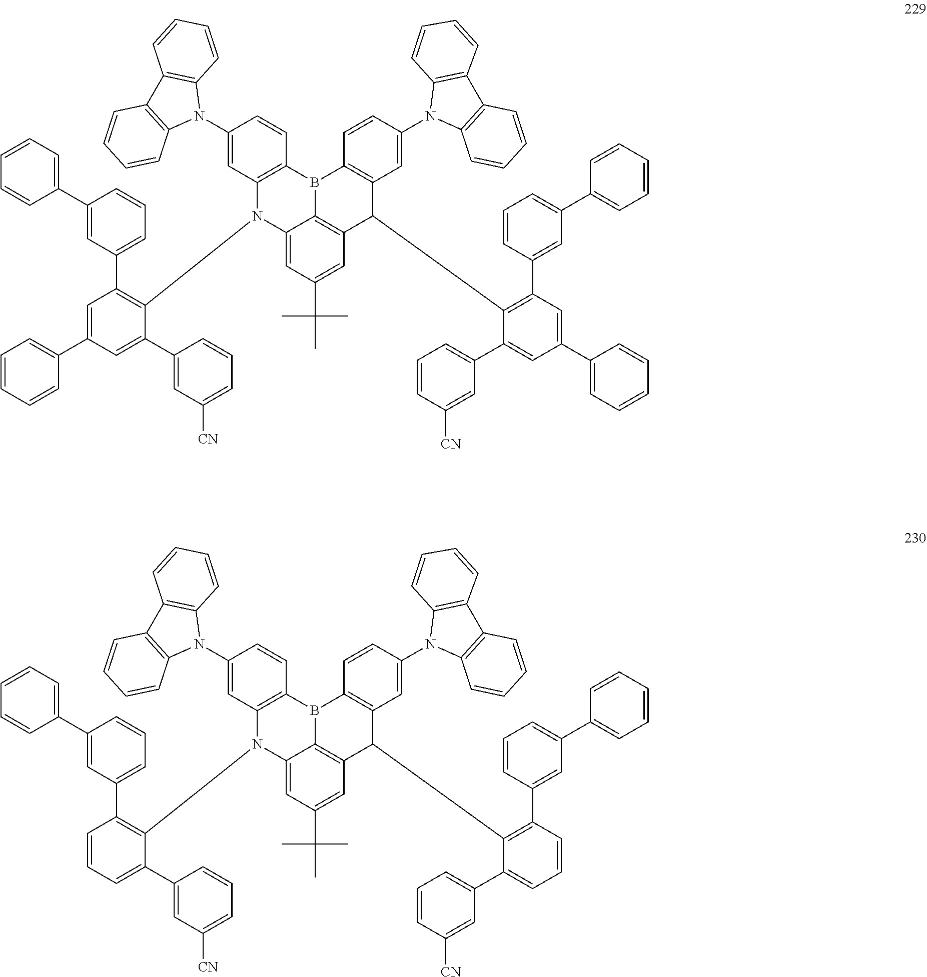 [SMILES: CC(C)(C)c1cc2c3c(c1)N(c1c(-c4cccc(C#N)c4)cc(-c4ccccc4)cc1-c1cccc(-c4ccccc4)c1)c1cc(-n4c5ccccc5c5ccccc54)ccc1B3c1ccc(-n3c4ccccc4c4ccccc43)cc1C2c1c(-c2cccc(C#N)c2)cc(-c2ccccc2)cc1-c1cccc(-c2ccccc2)c1 ; CC(C)(C)c1cc2c3c(c1)N(c1c(-c4cccc(C#N)c4)cccc1-c1cccc(-c4ccccc4)c1)c1cc(-n4c5ccccc5c5ccccc54)ccc1B3c1ccc(-n3c4ccccc4c4ccccc43)cc1C2c1c(-c2cccc(C#N)c2)cccc1-c1cccc(-c2ccccc2)c1] 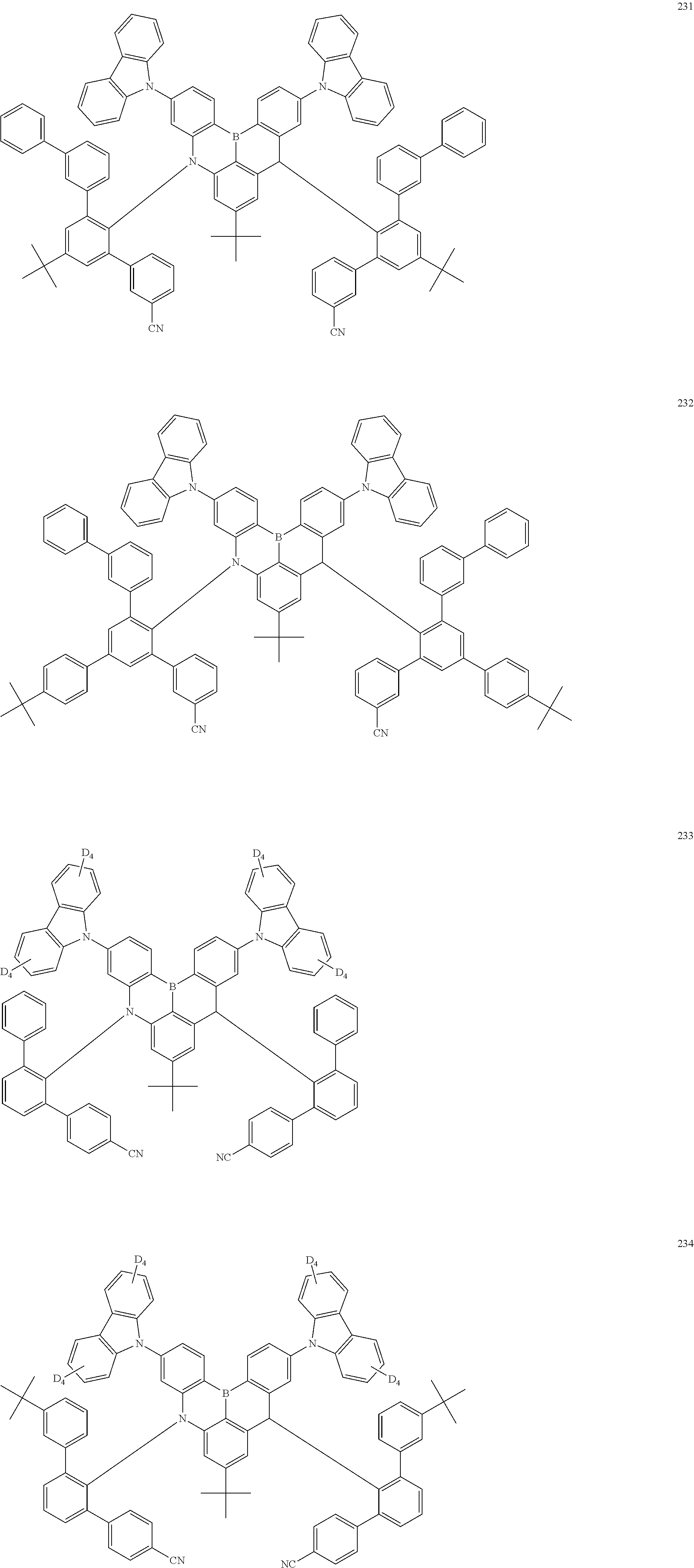 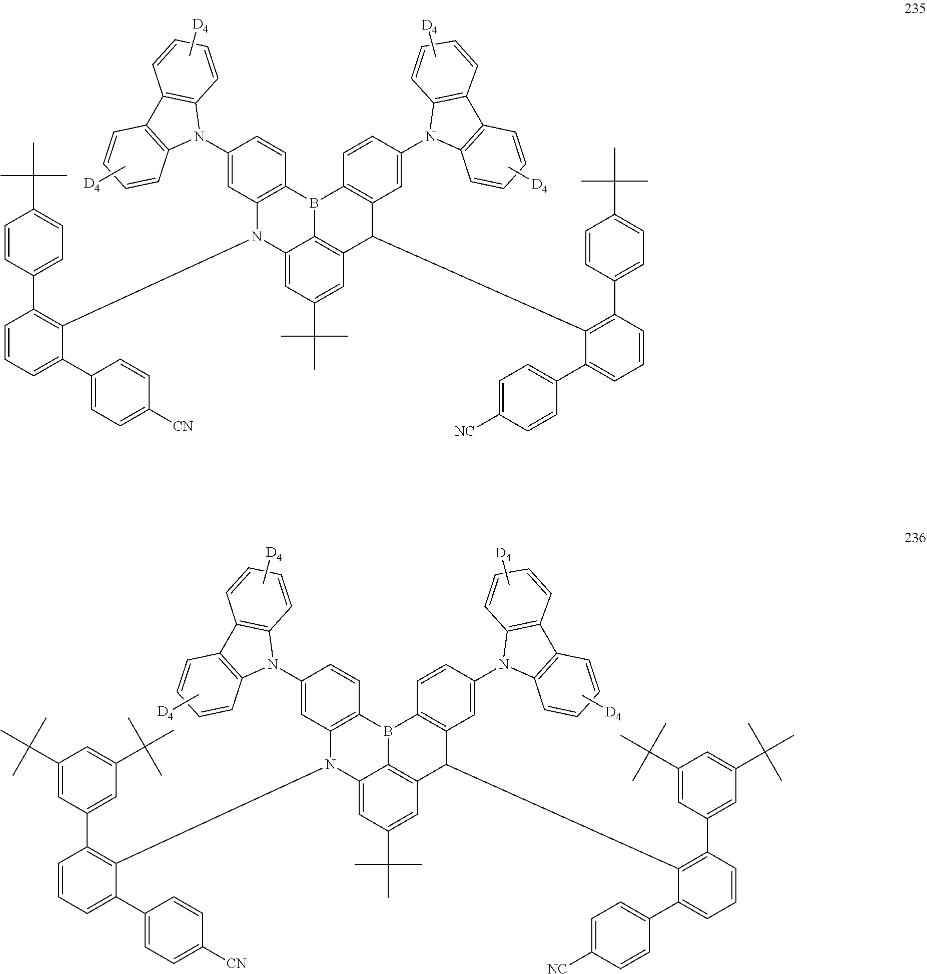 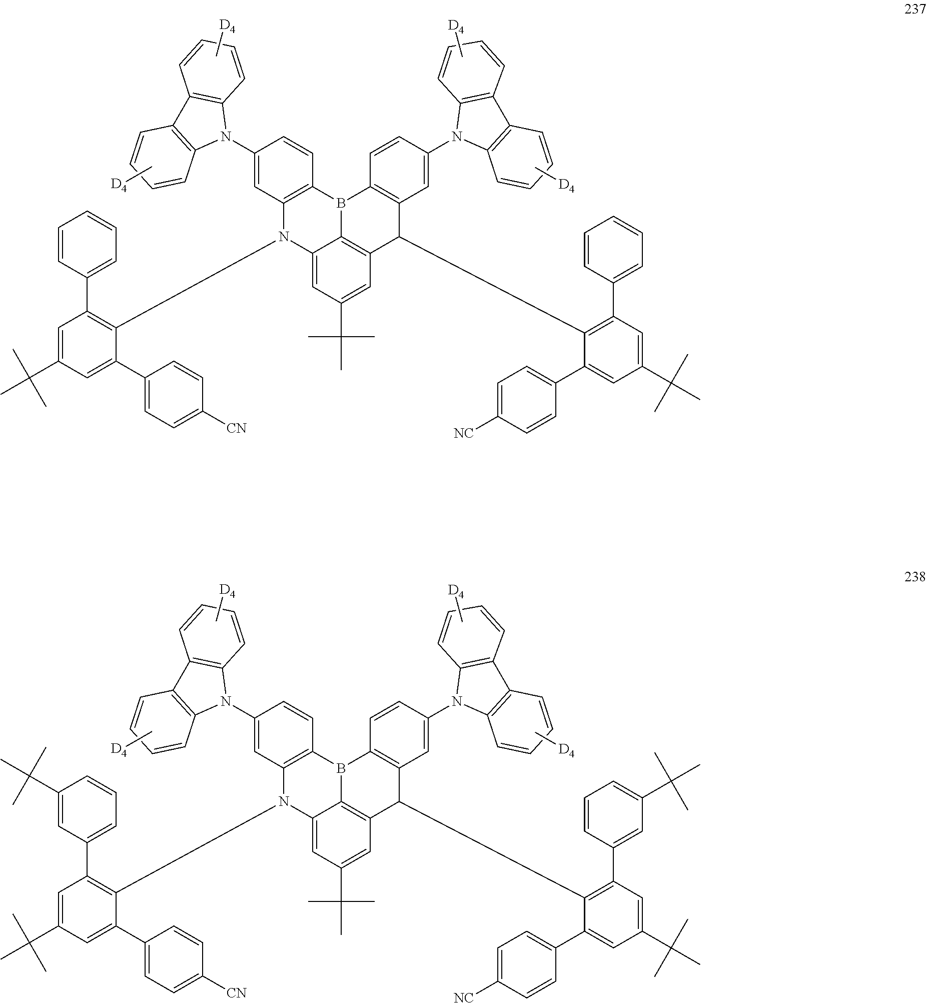 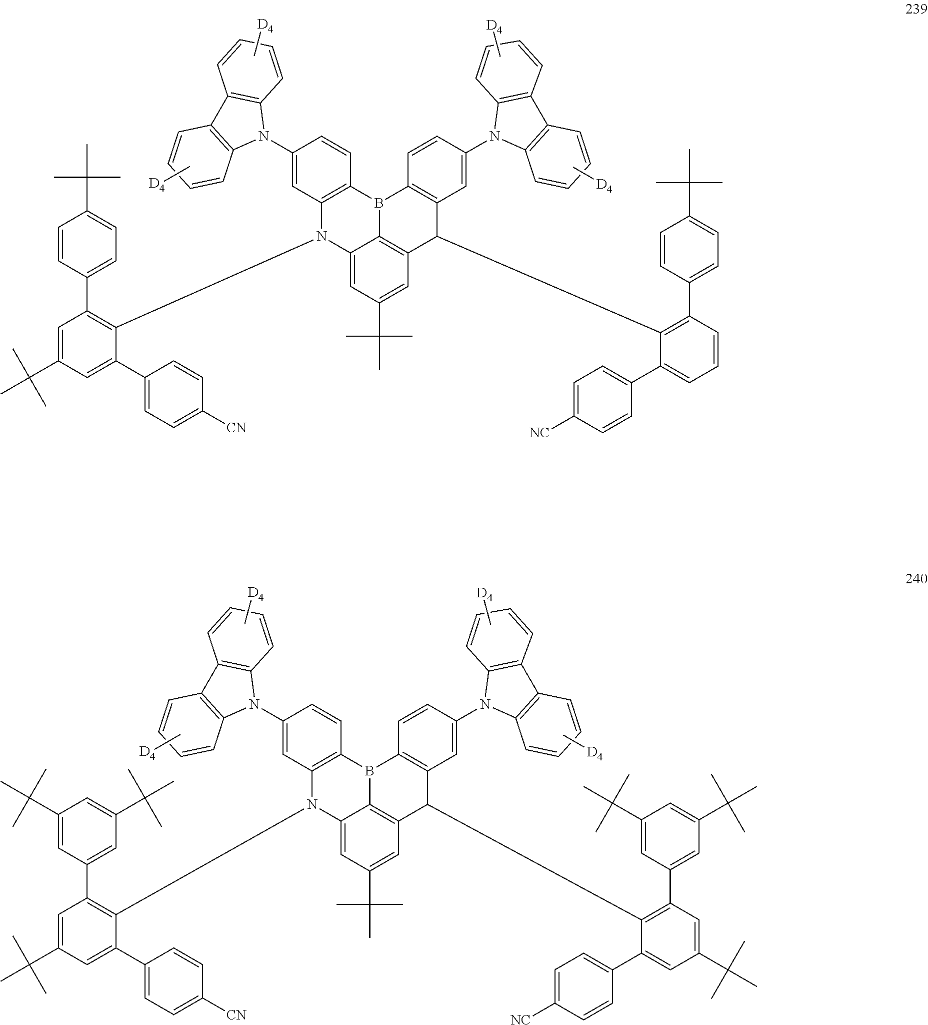 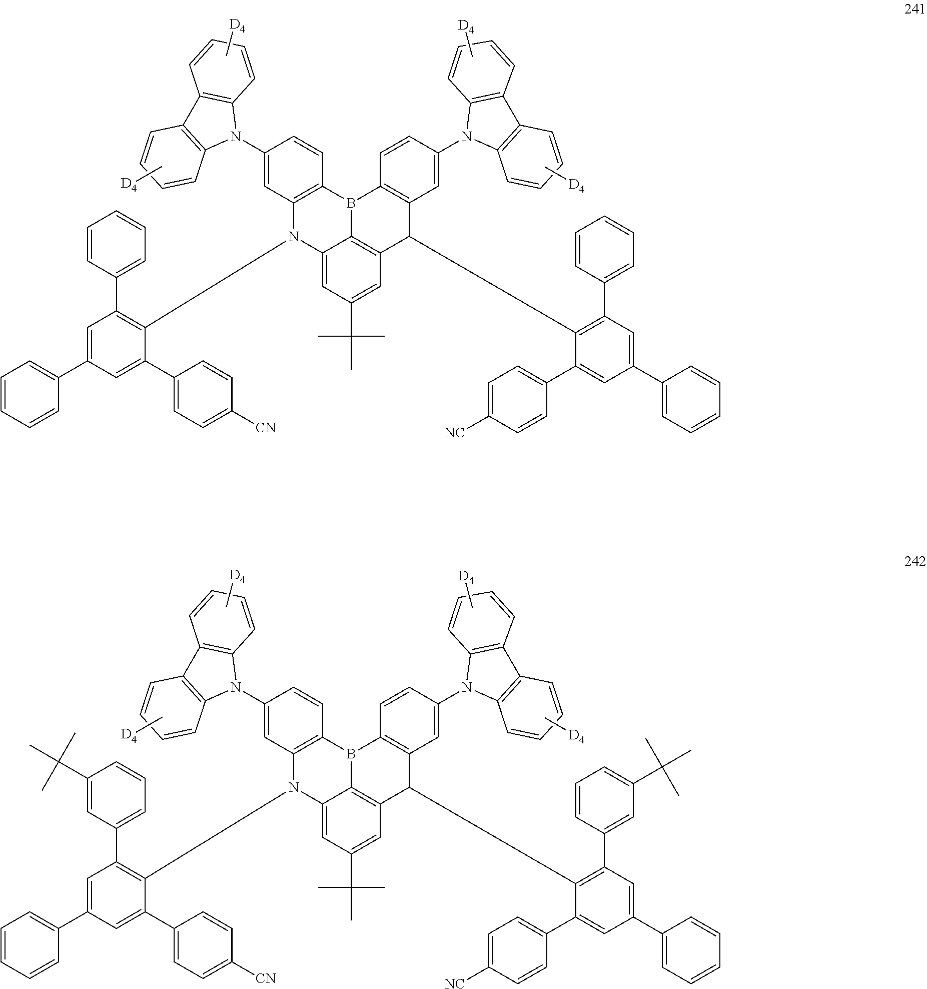 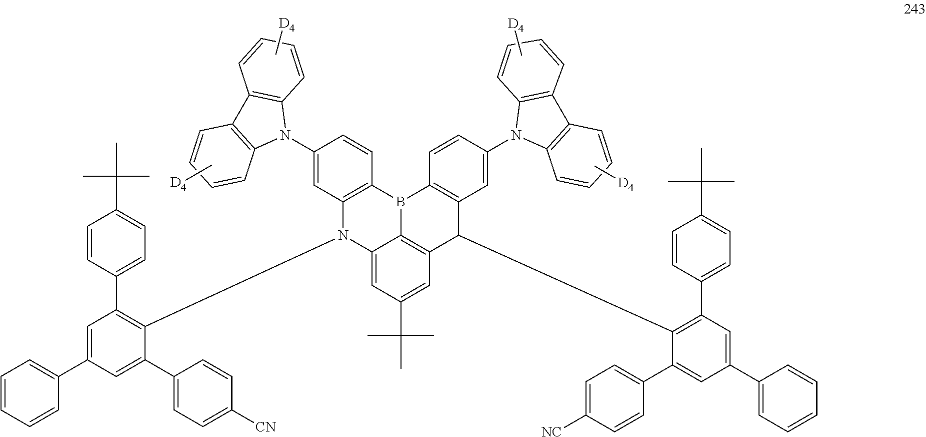 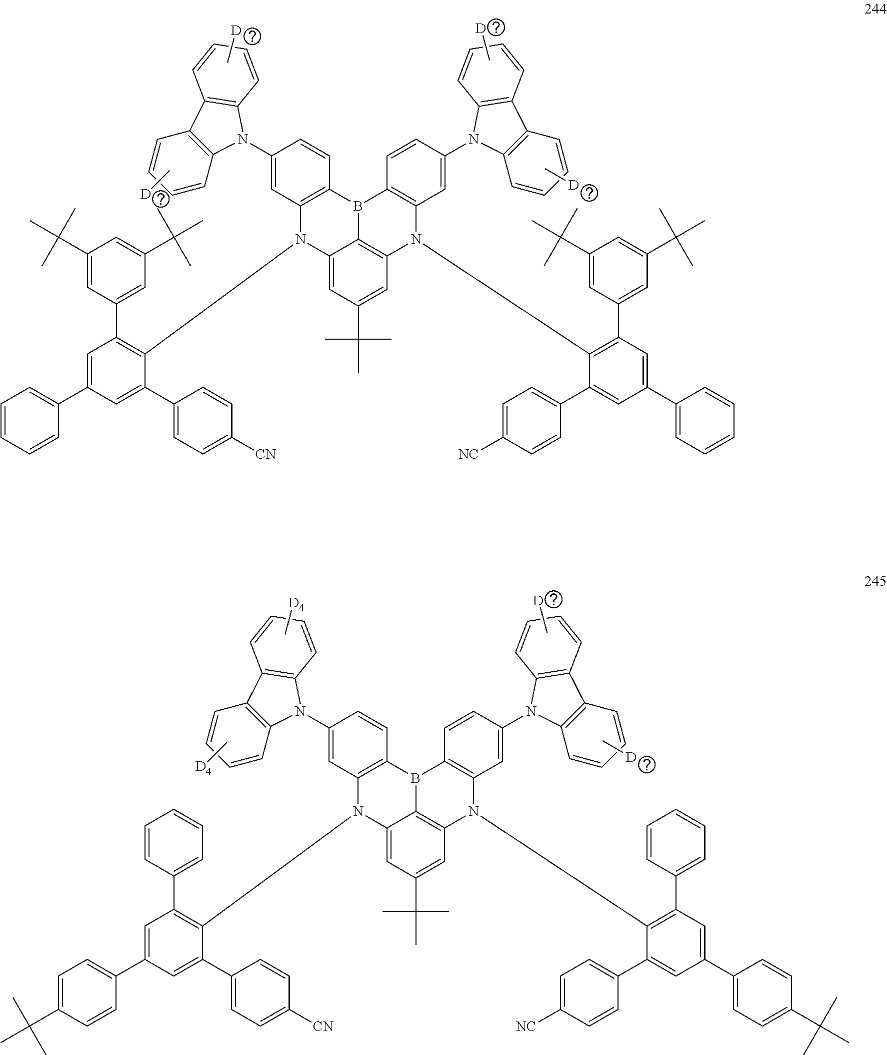 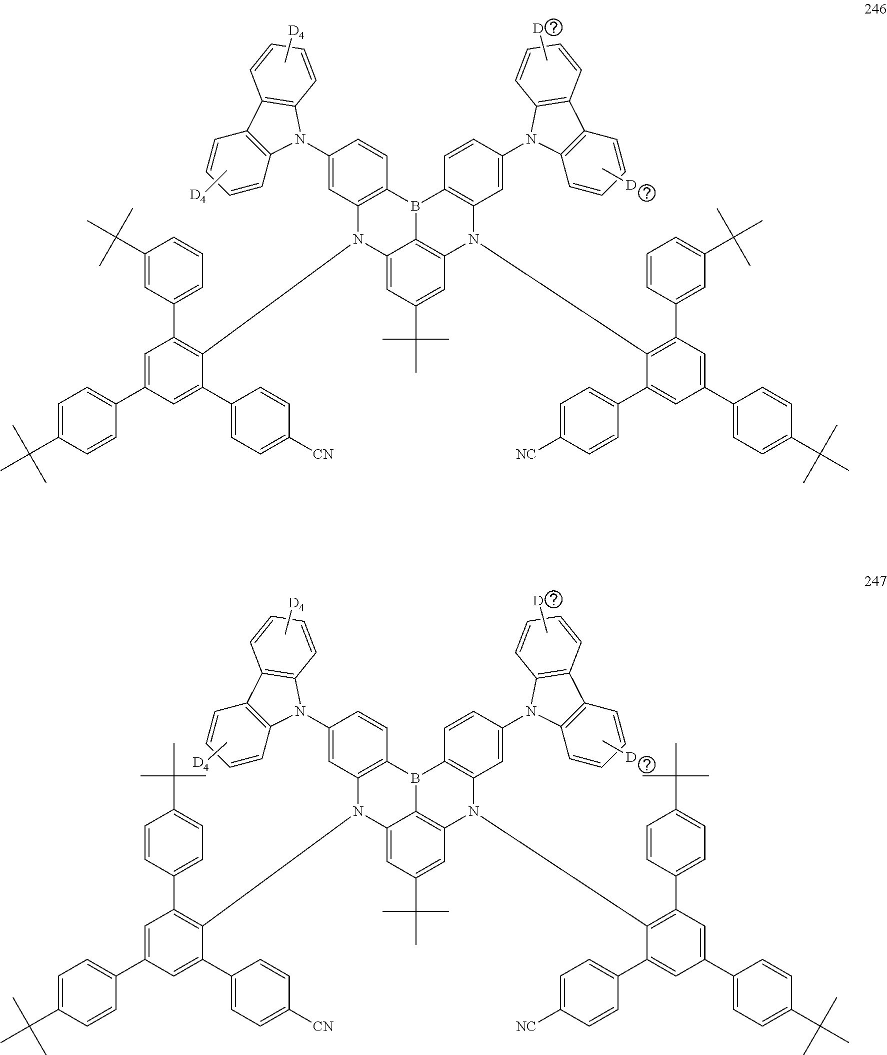 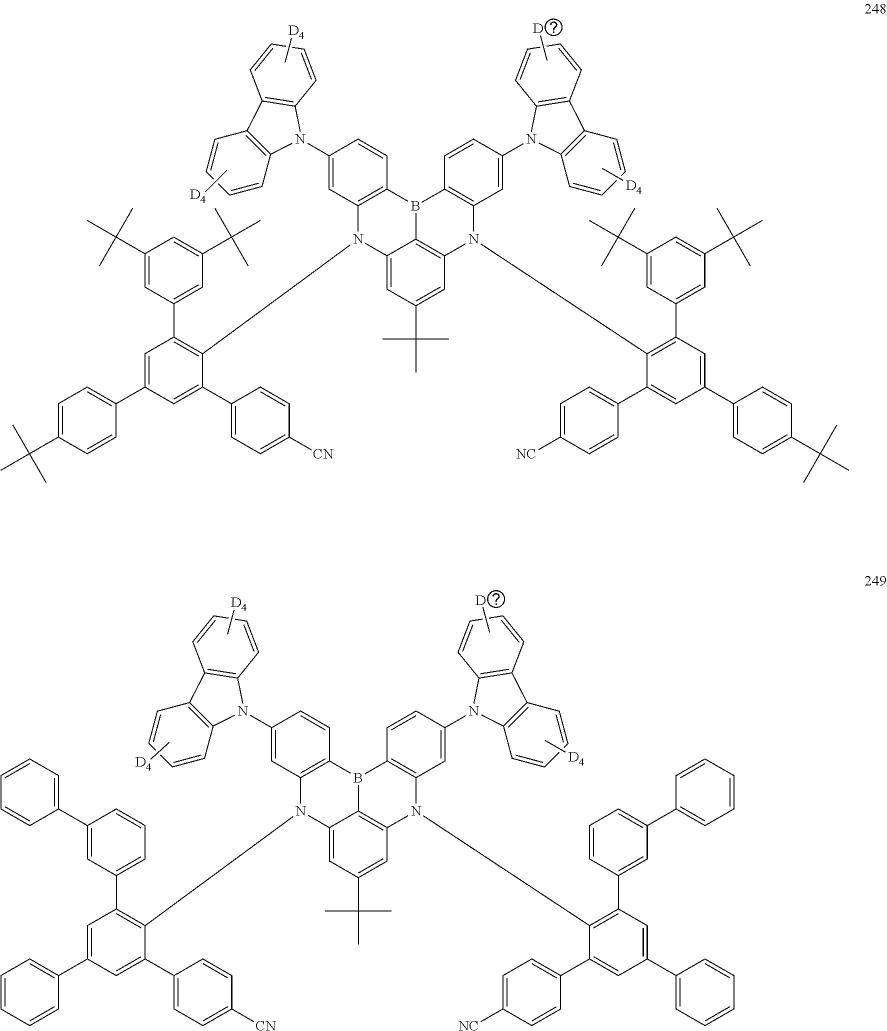 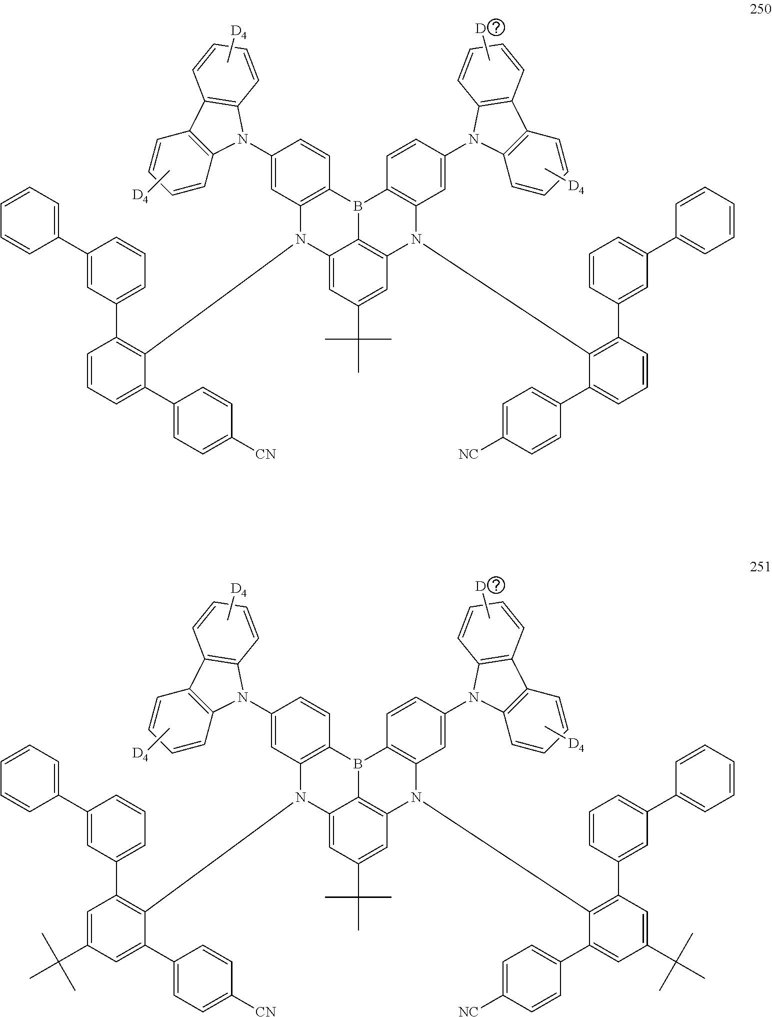 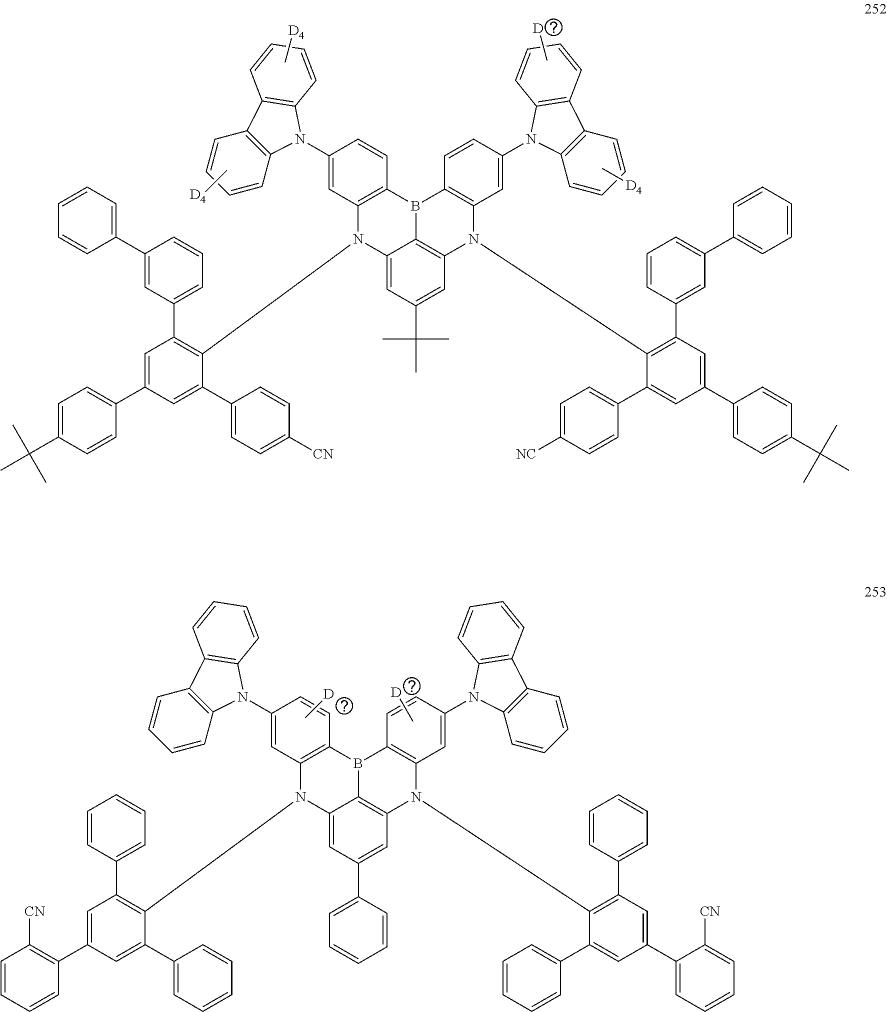 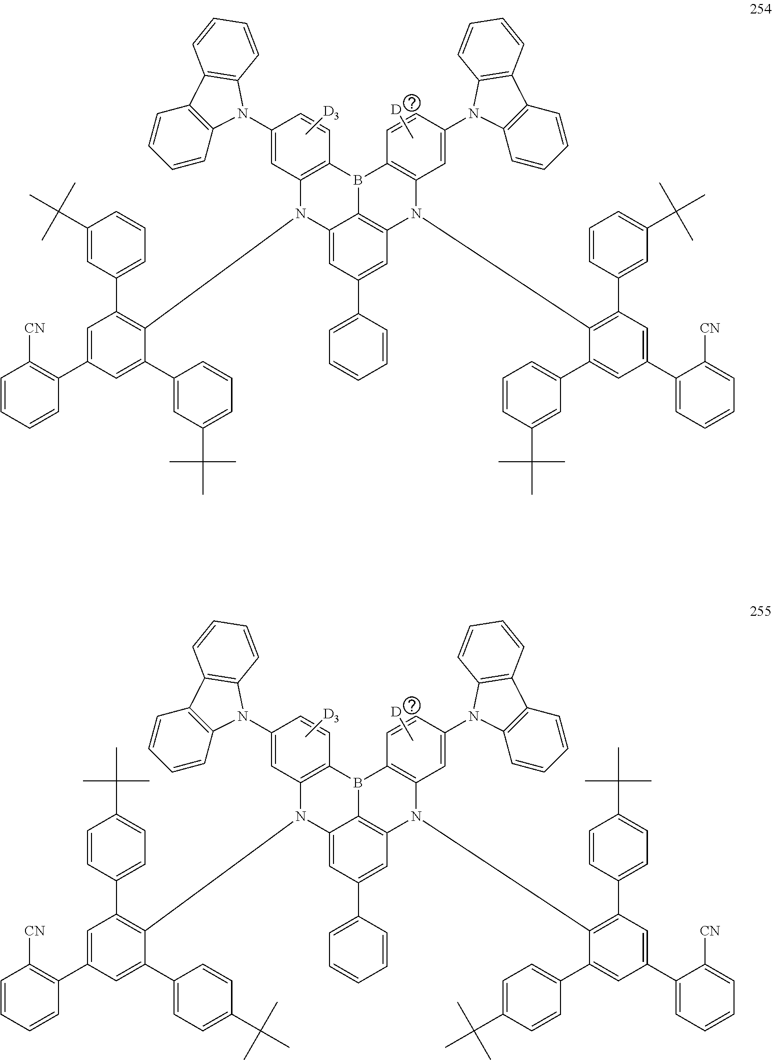 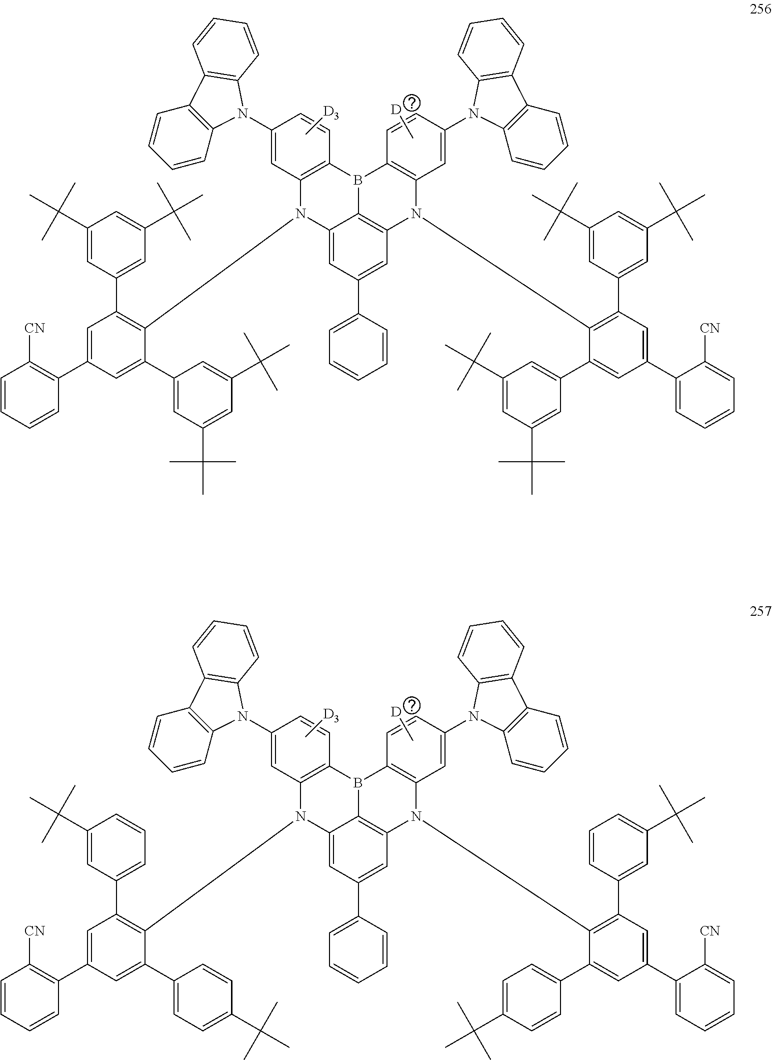 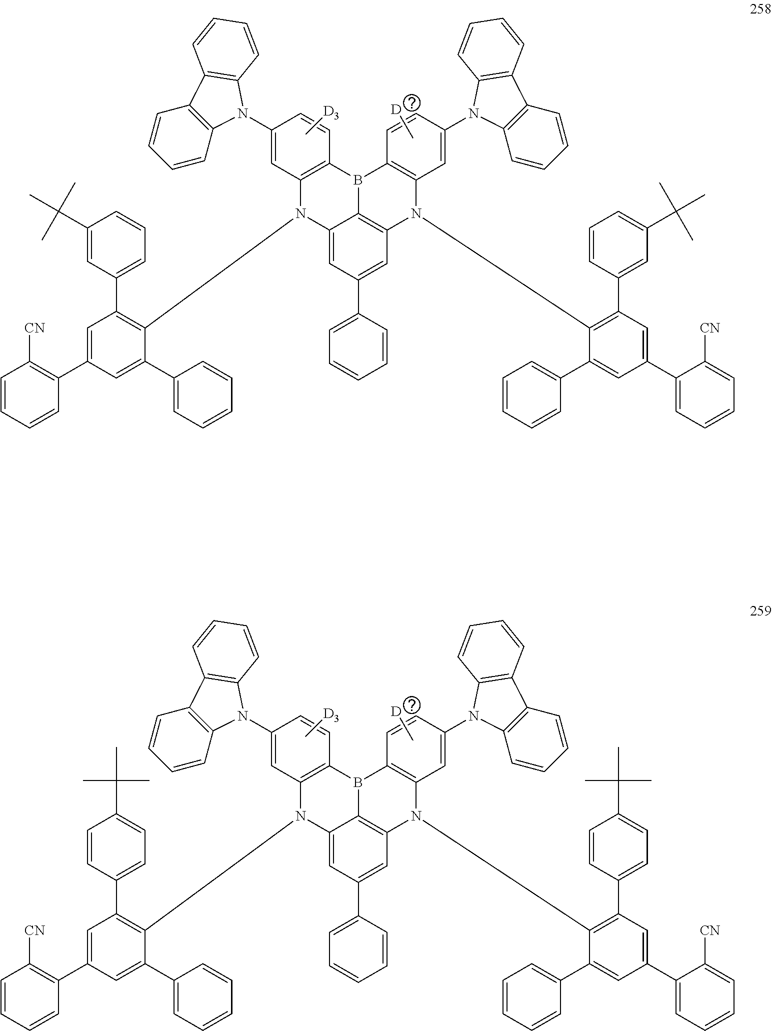 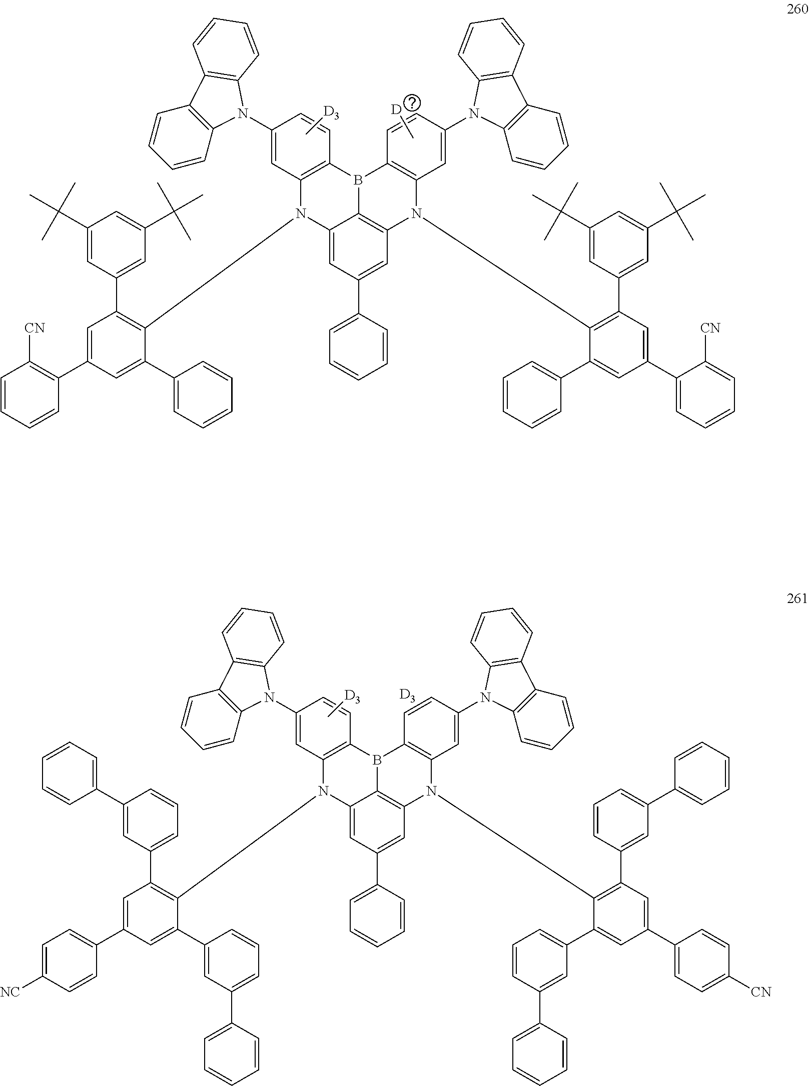 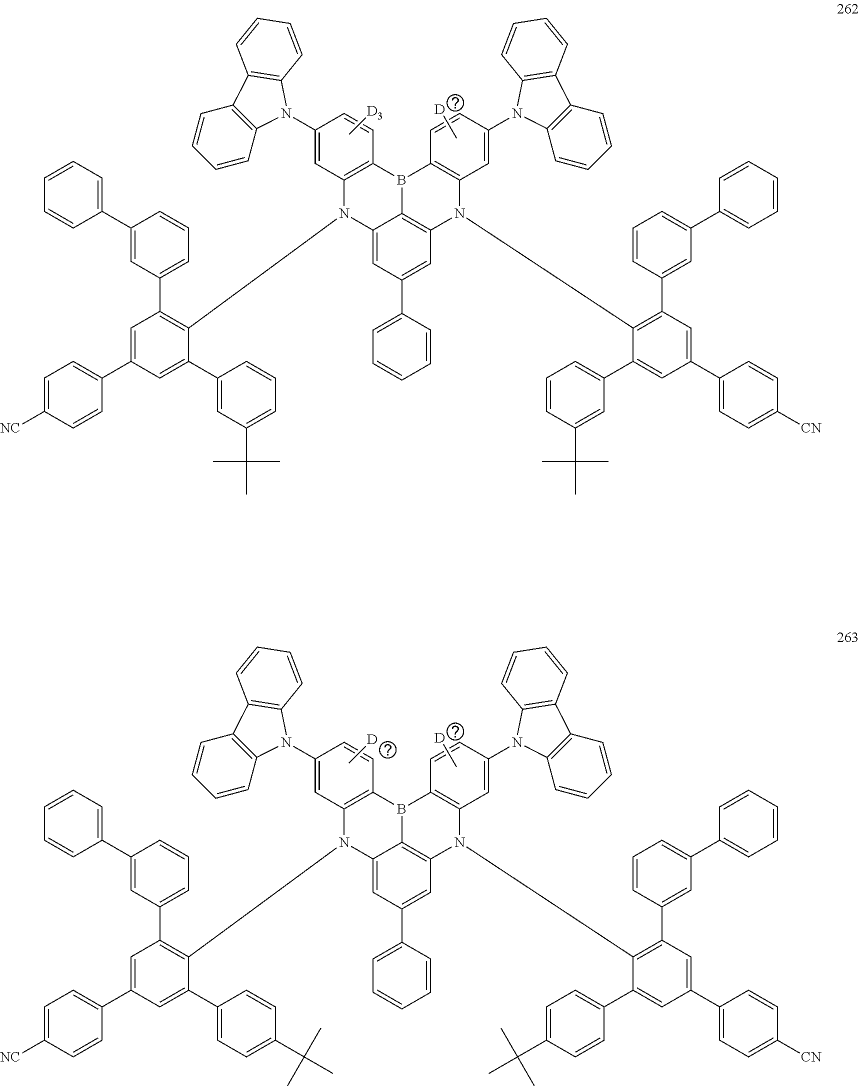 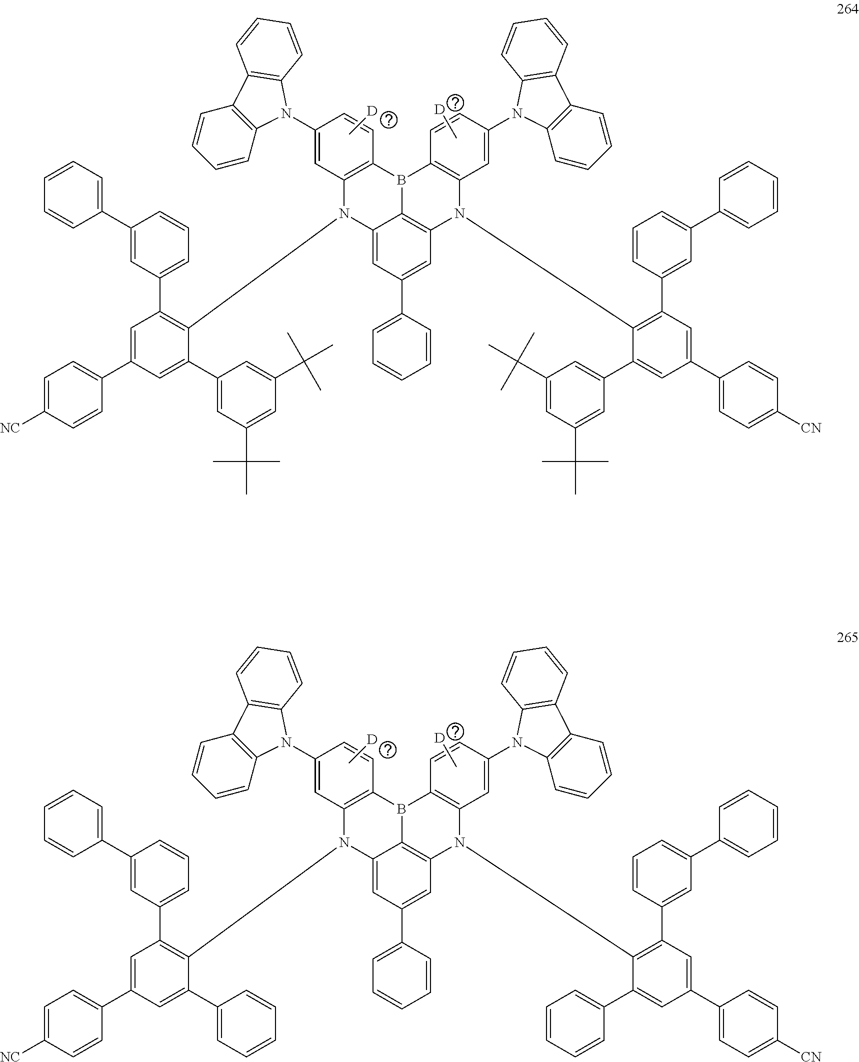 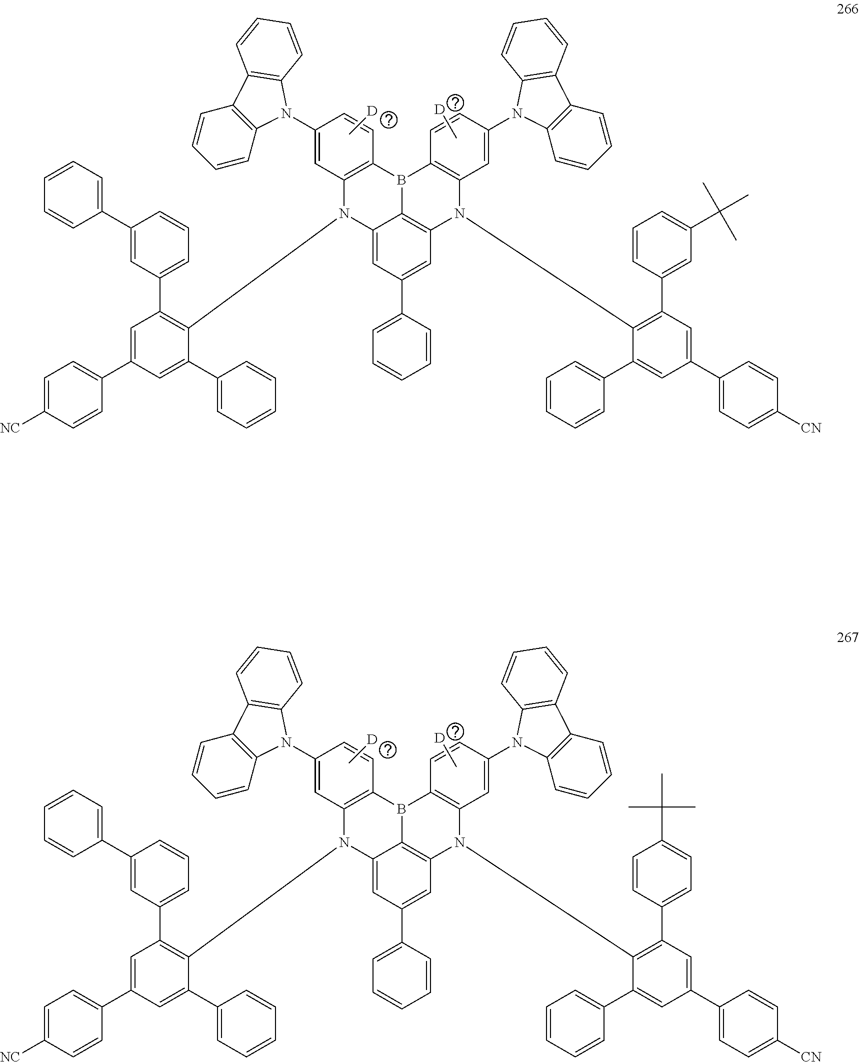 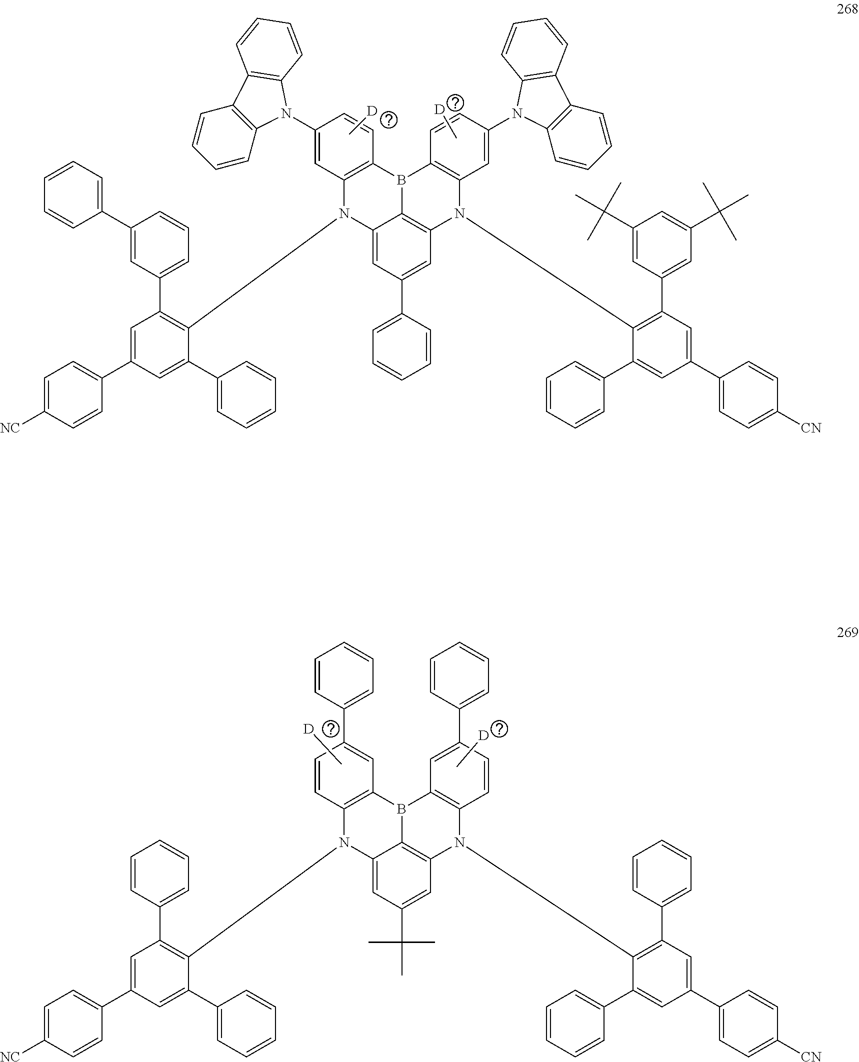 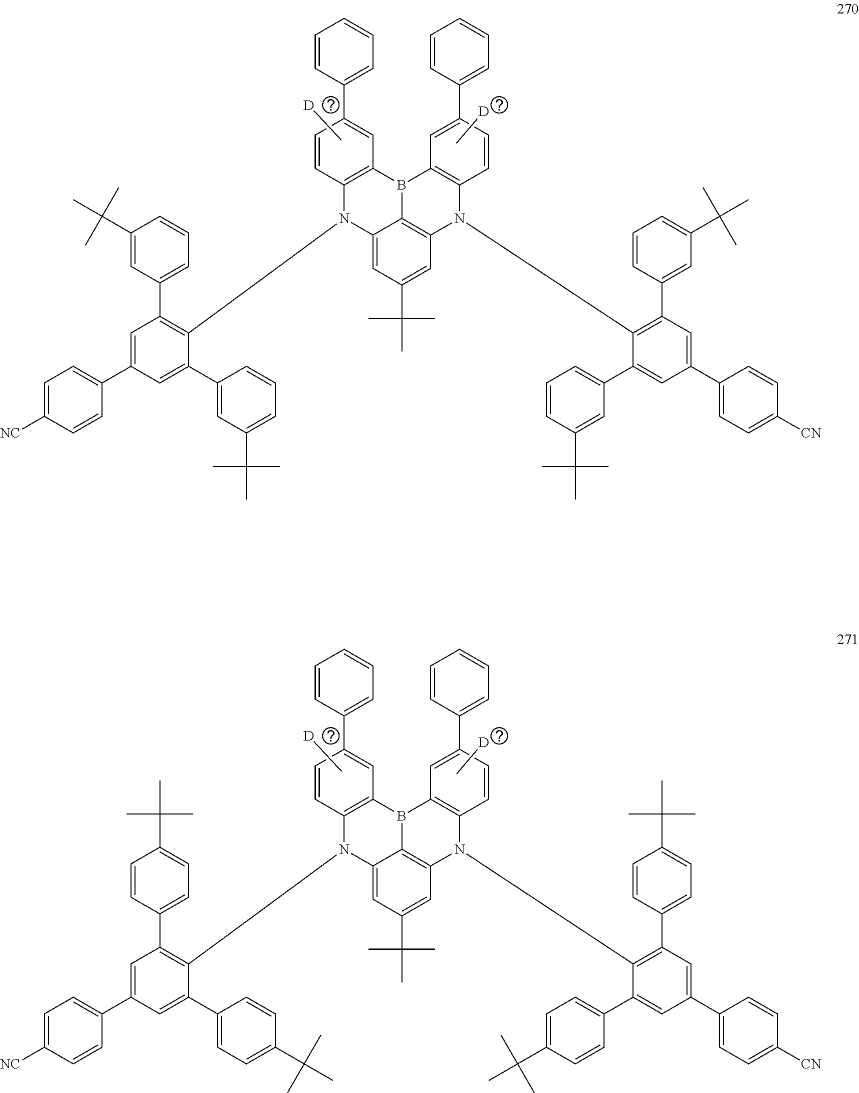 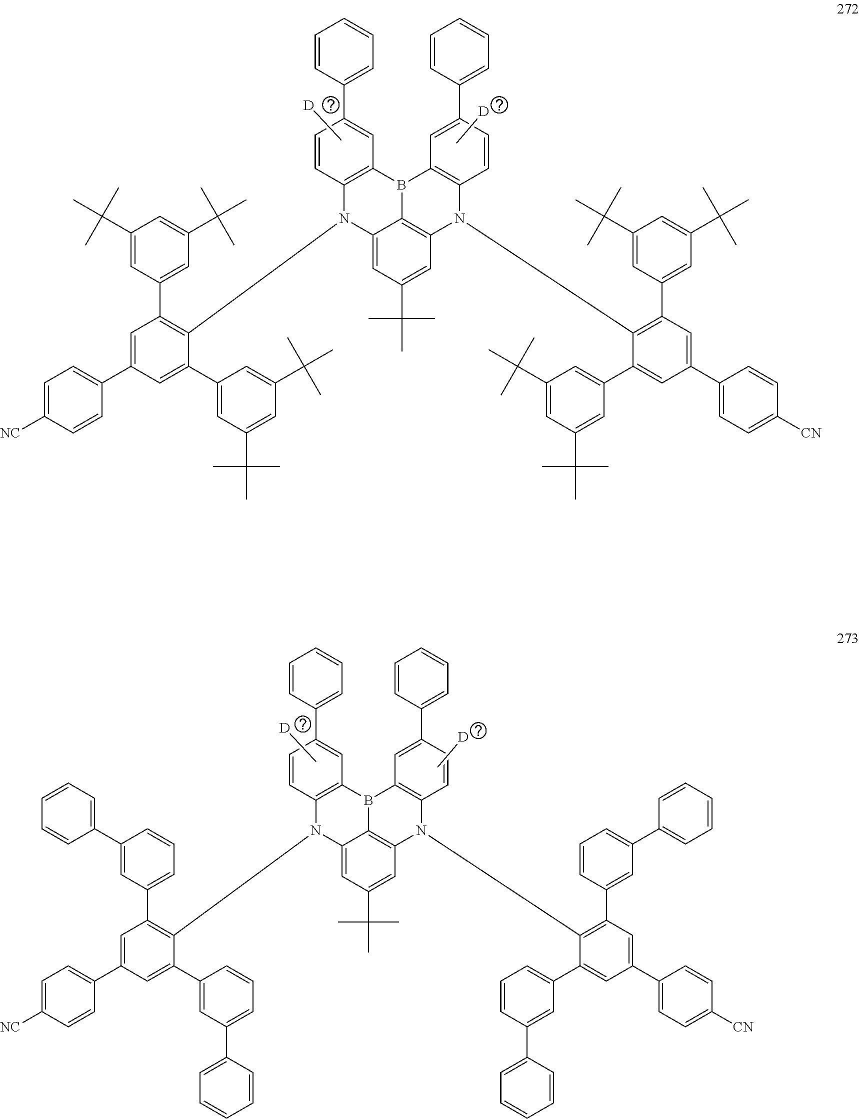 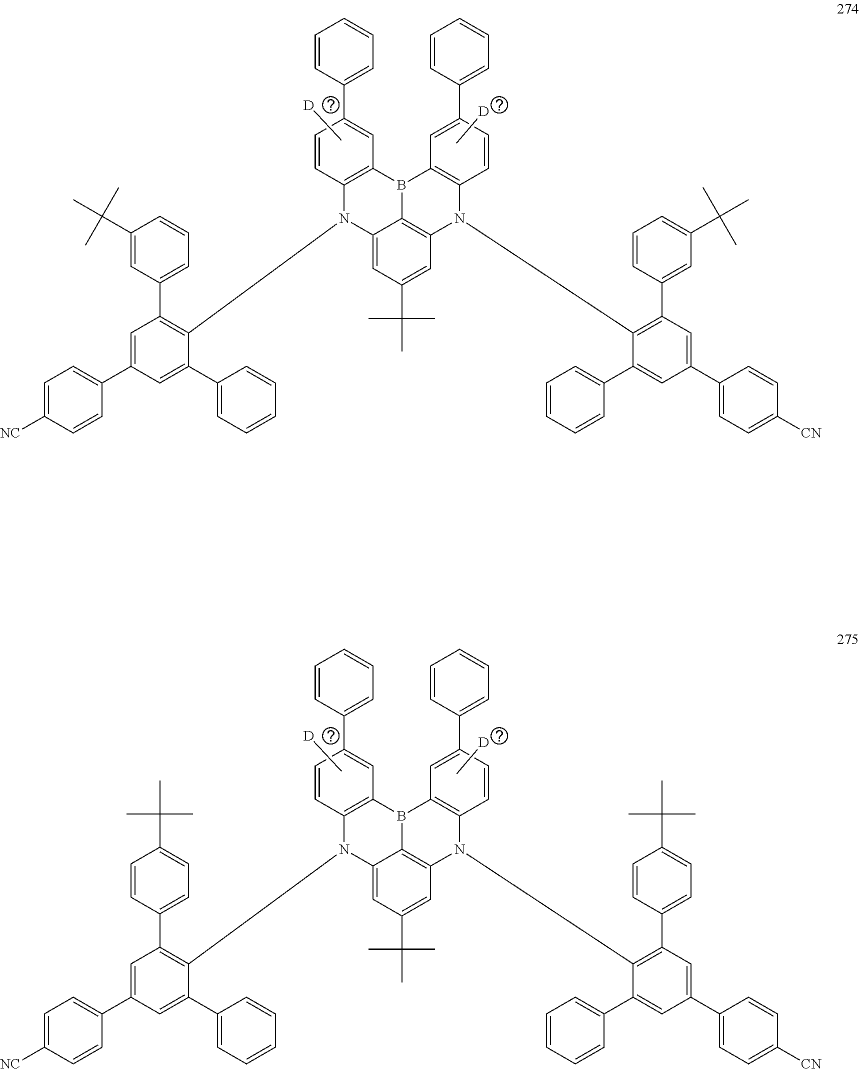 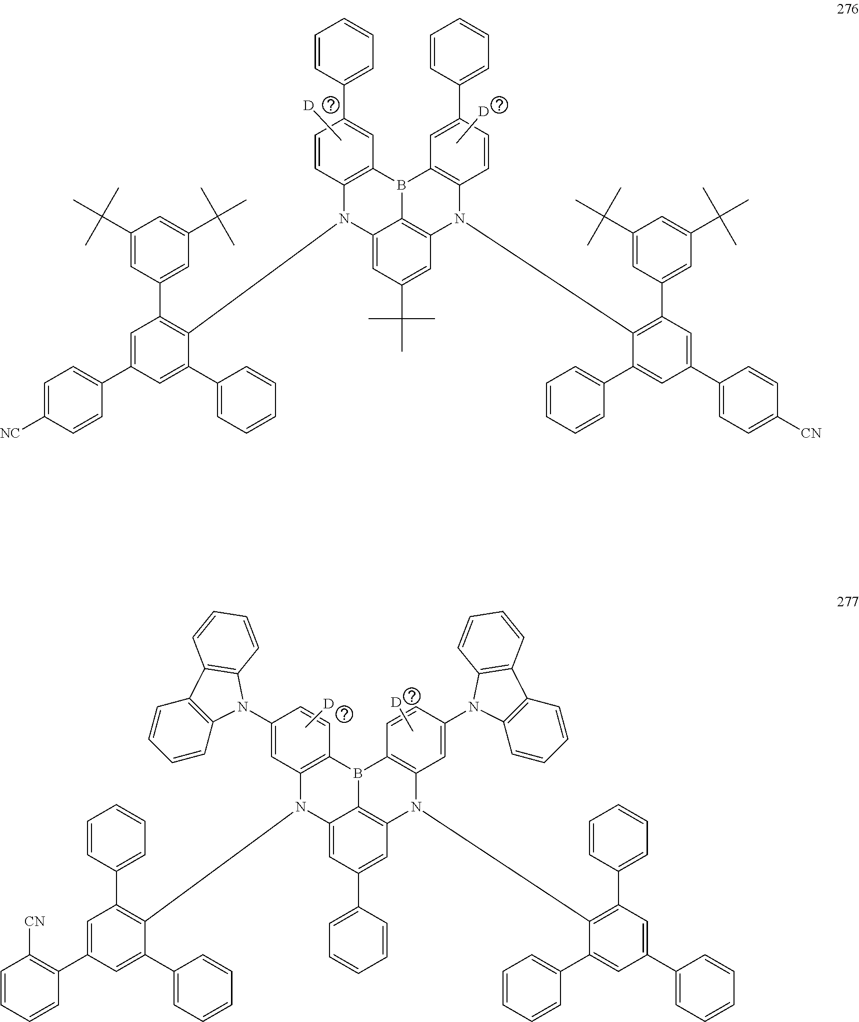 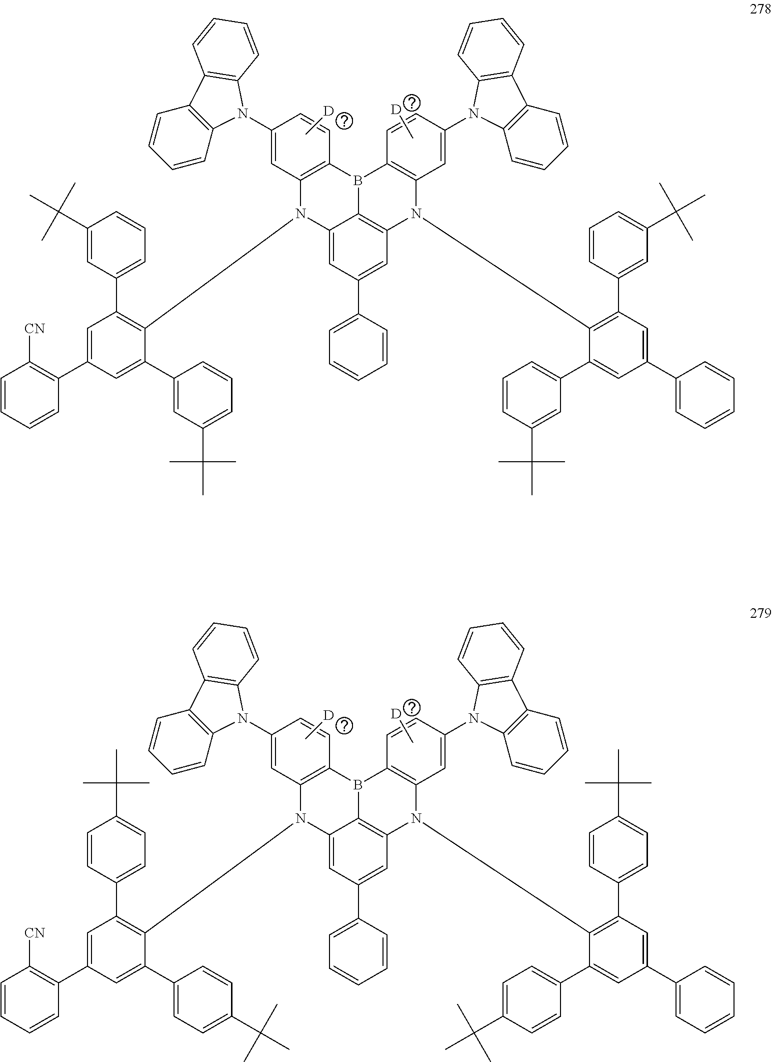 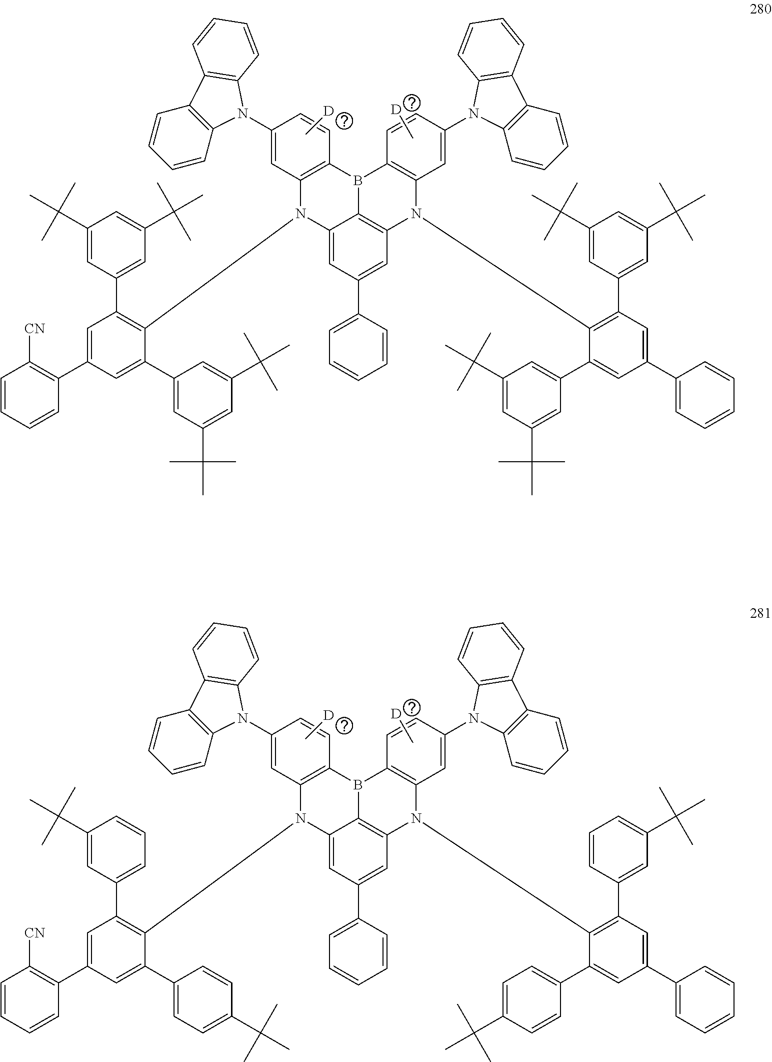 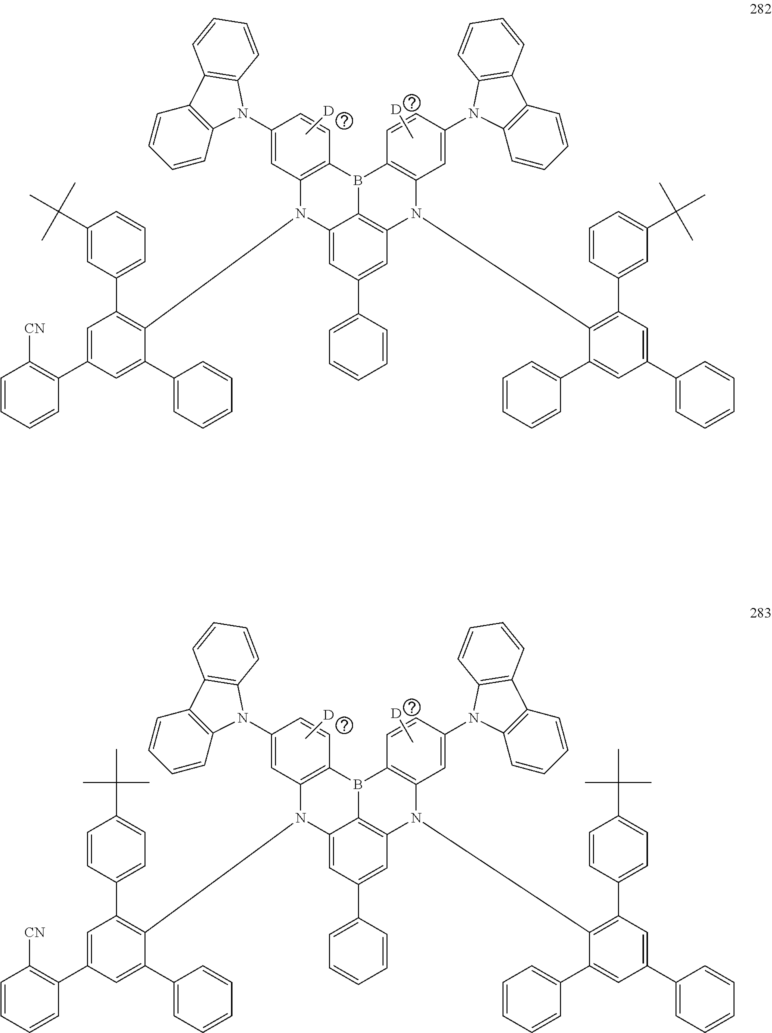 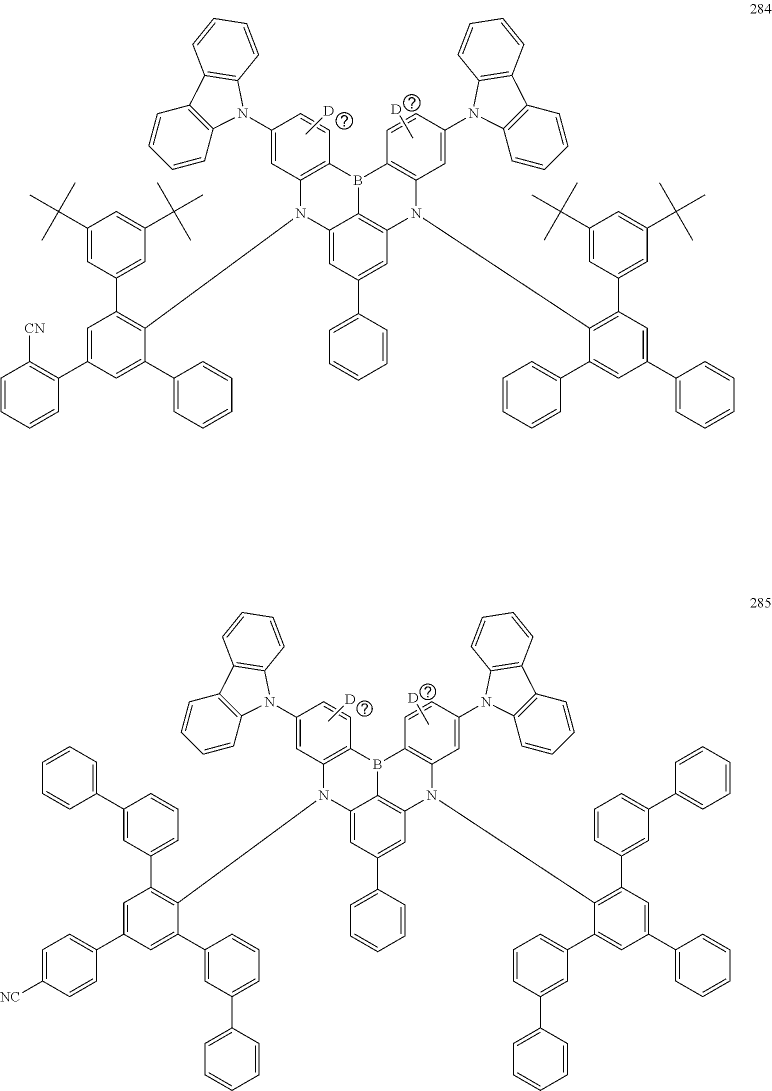 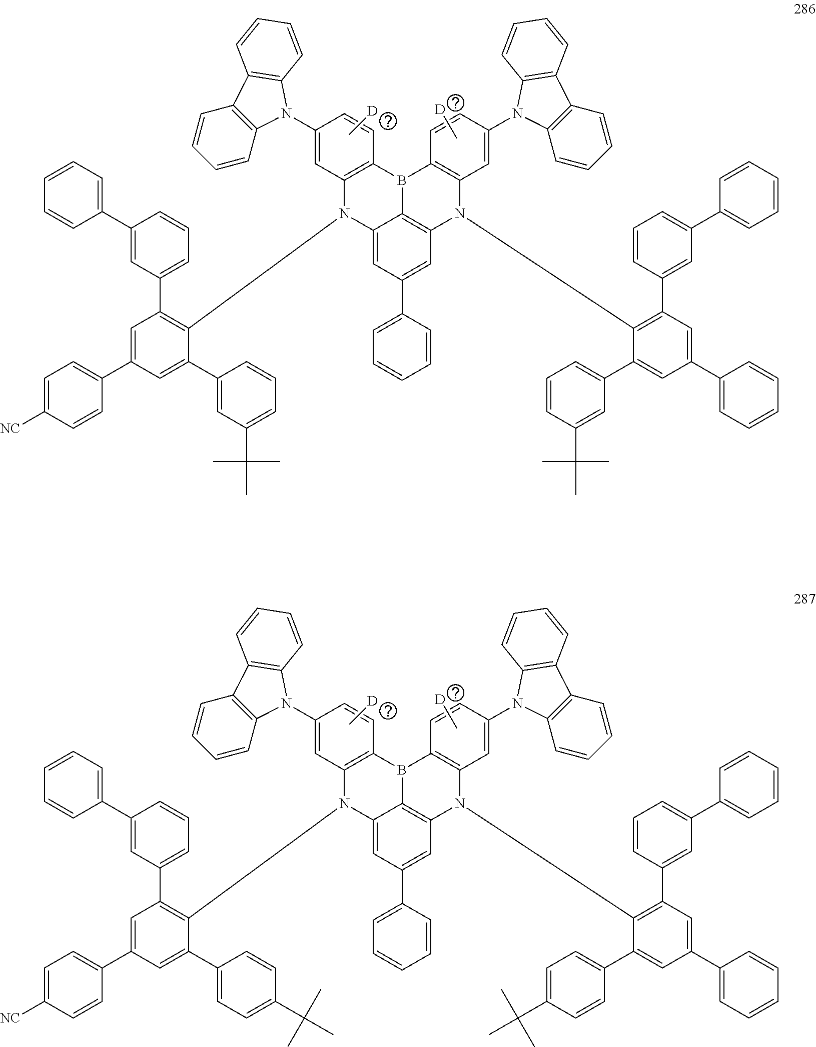 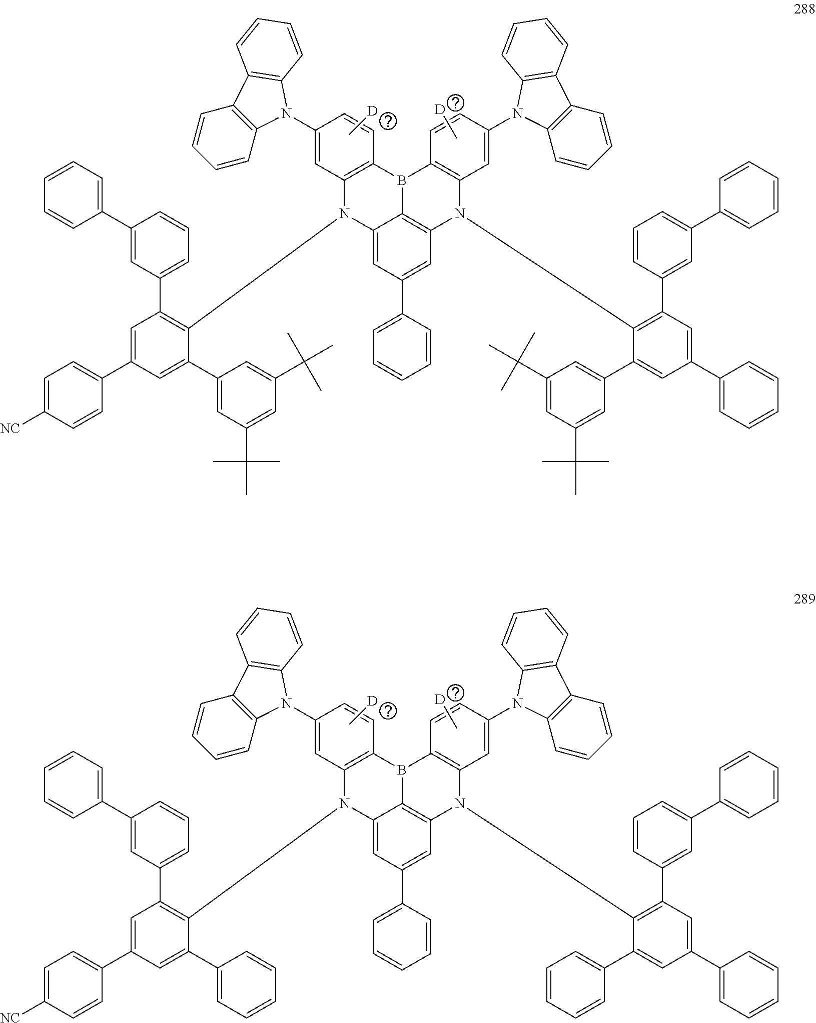 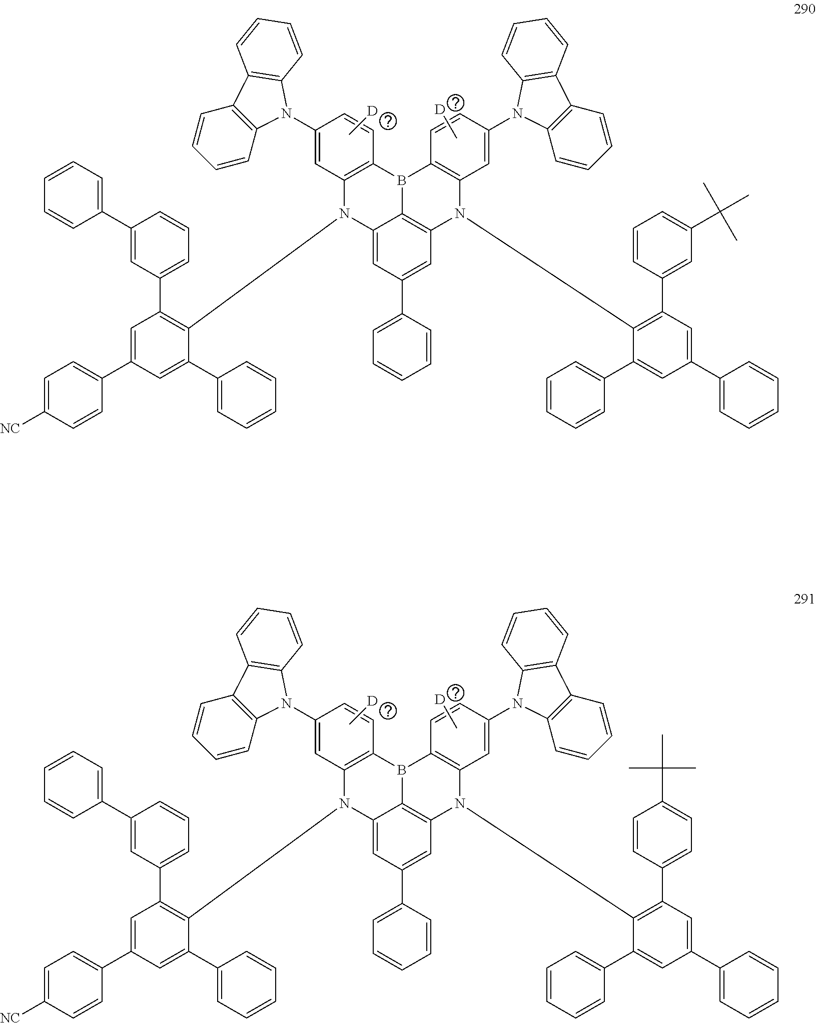 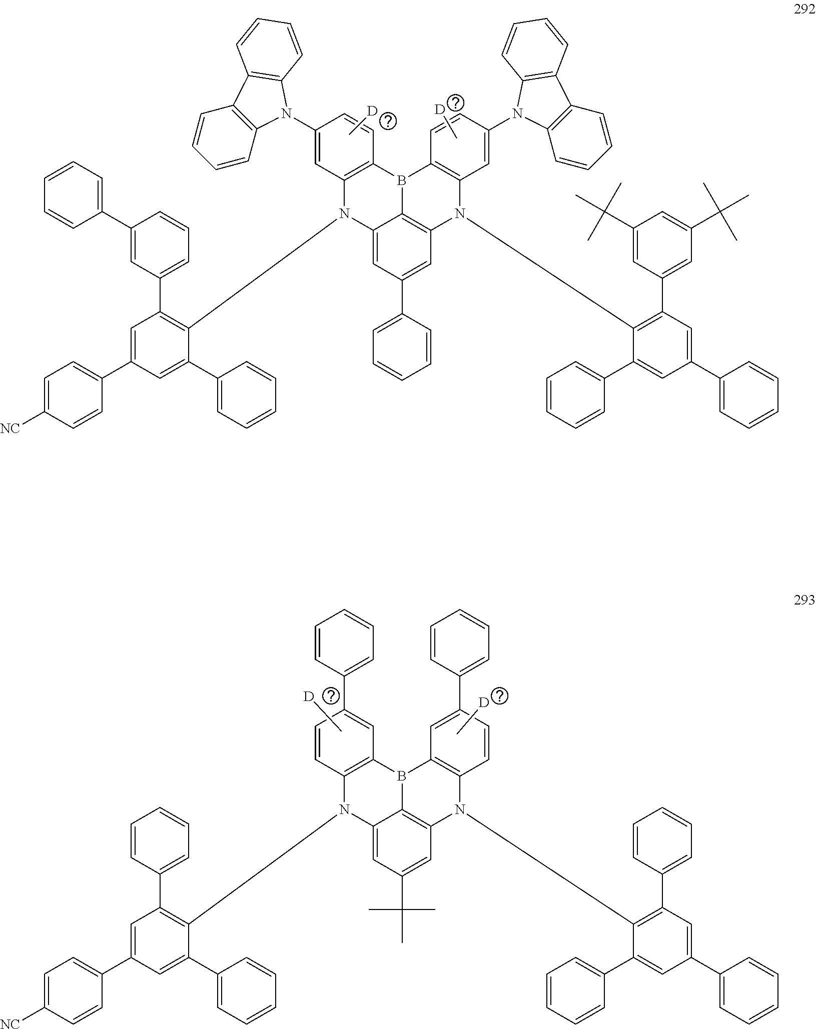 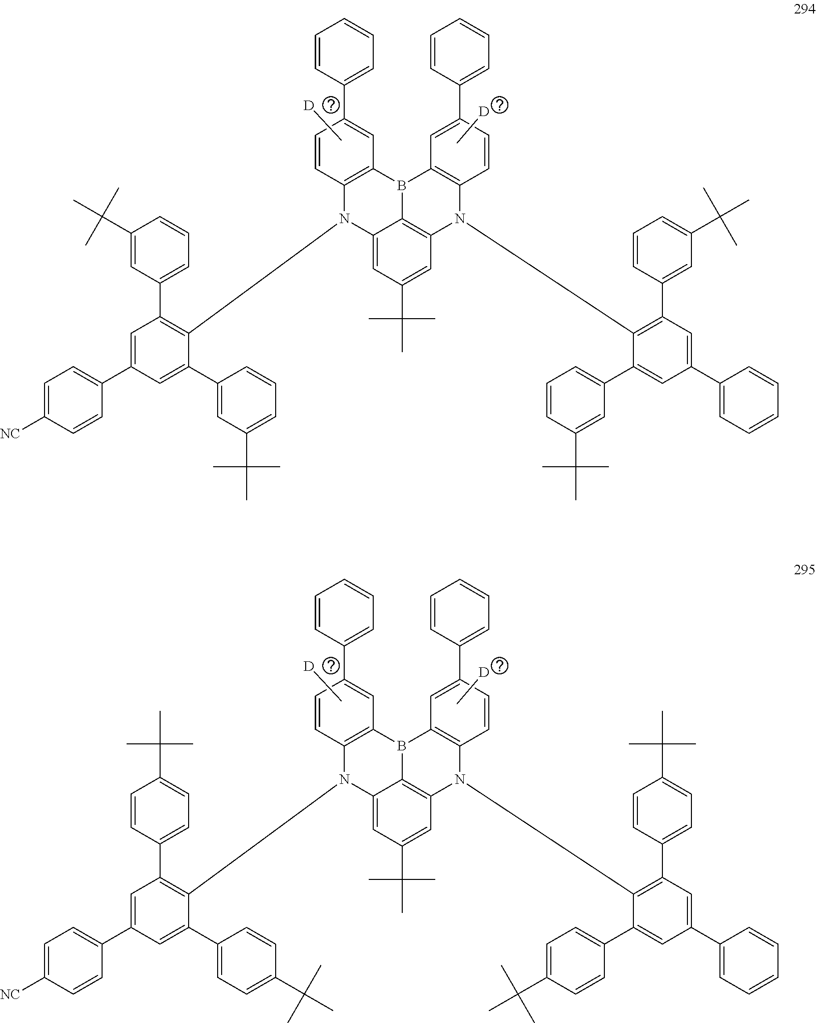 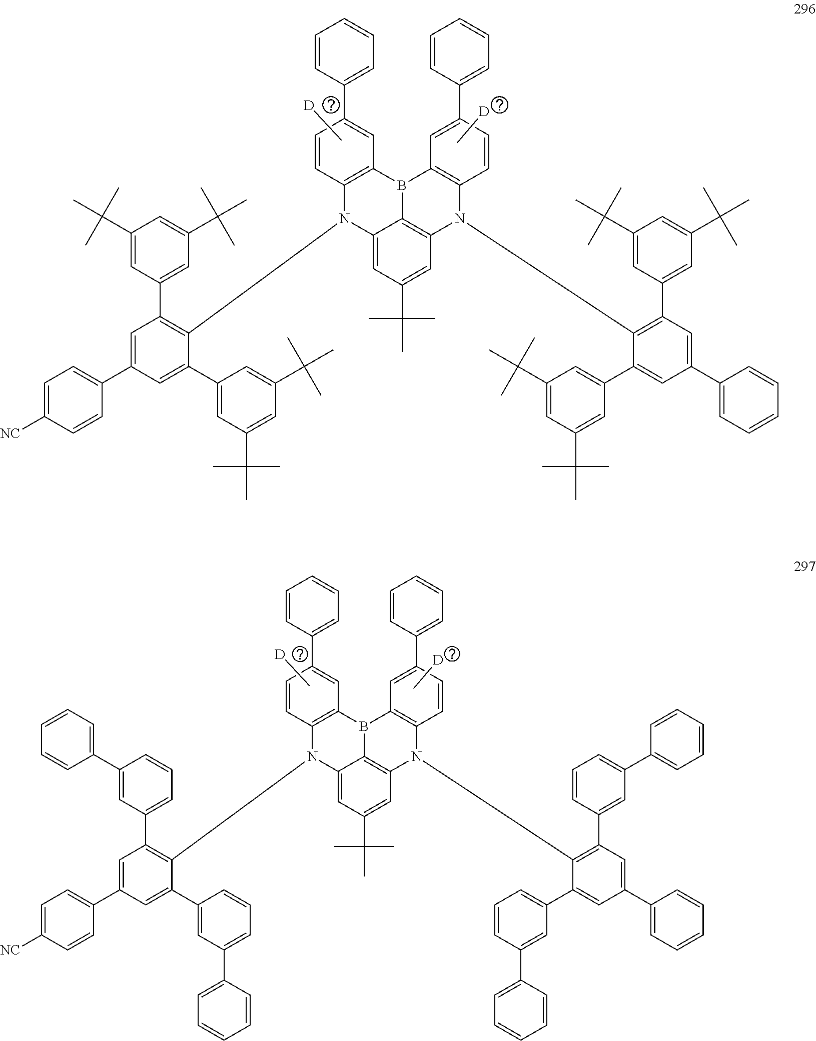 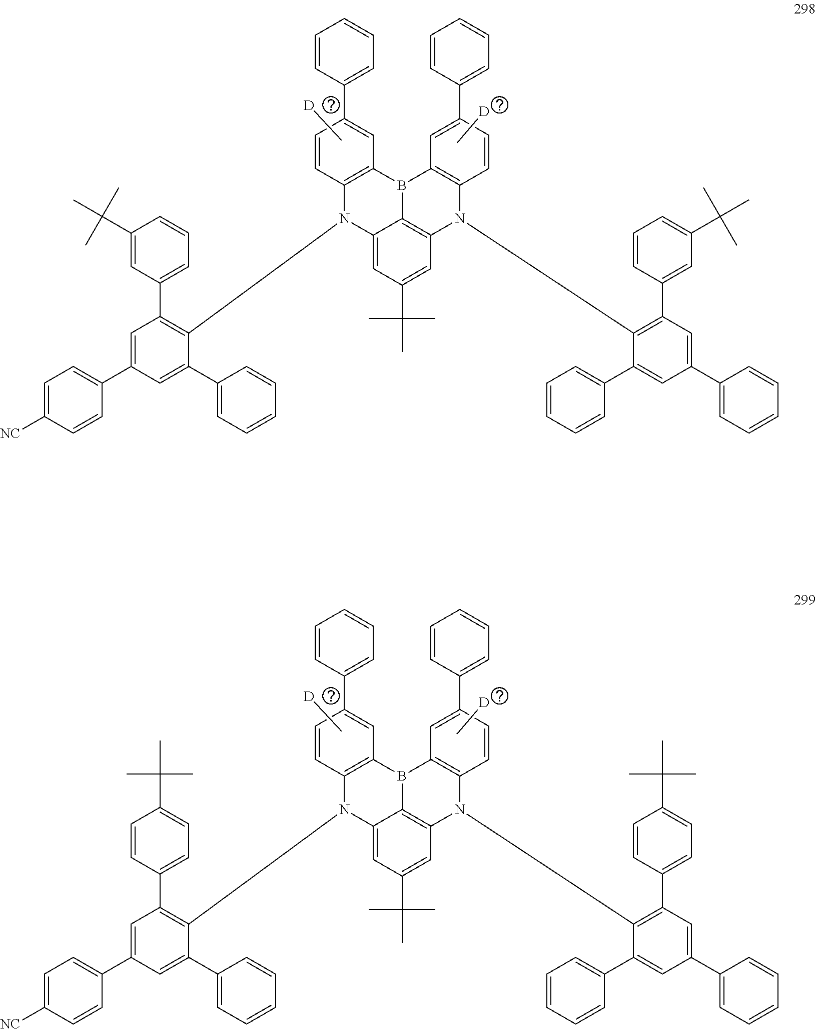 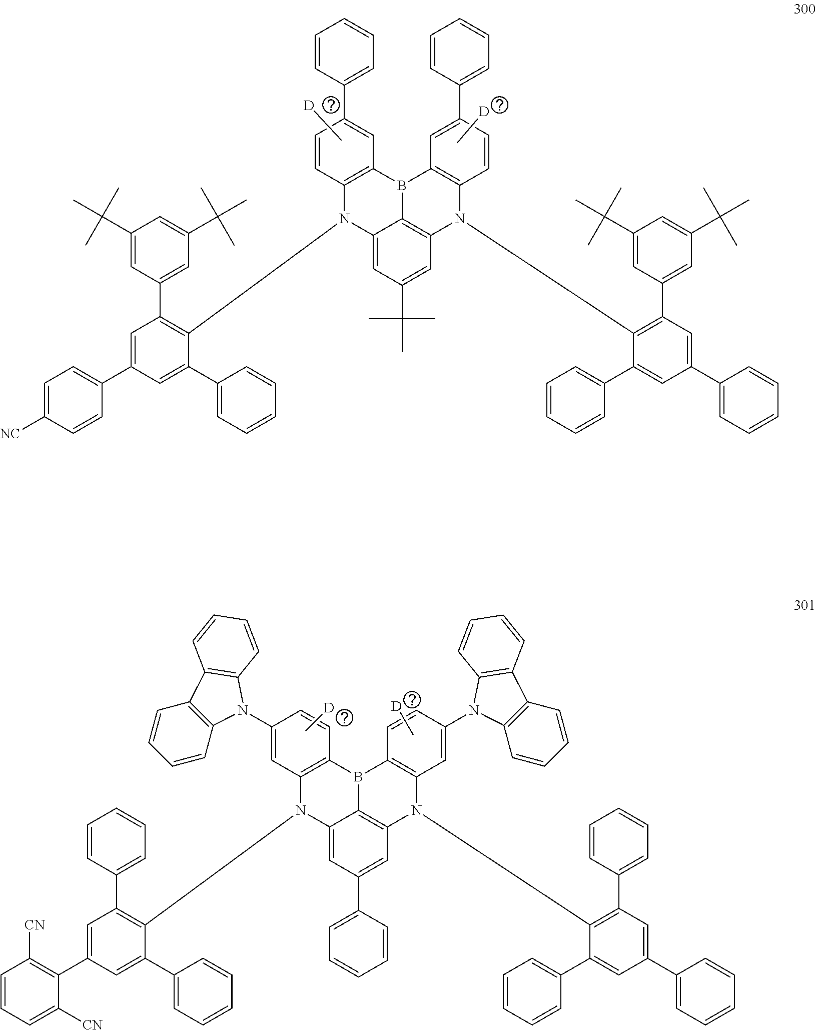 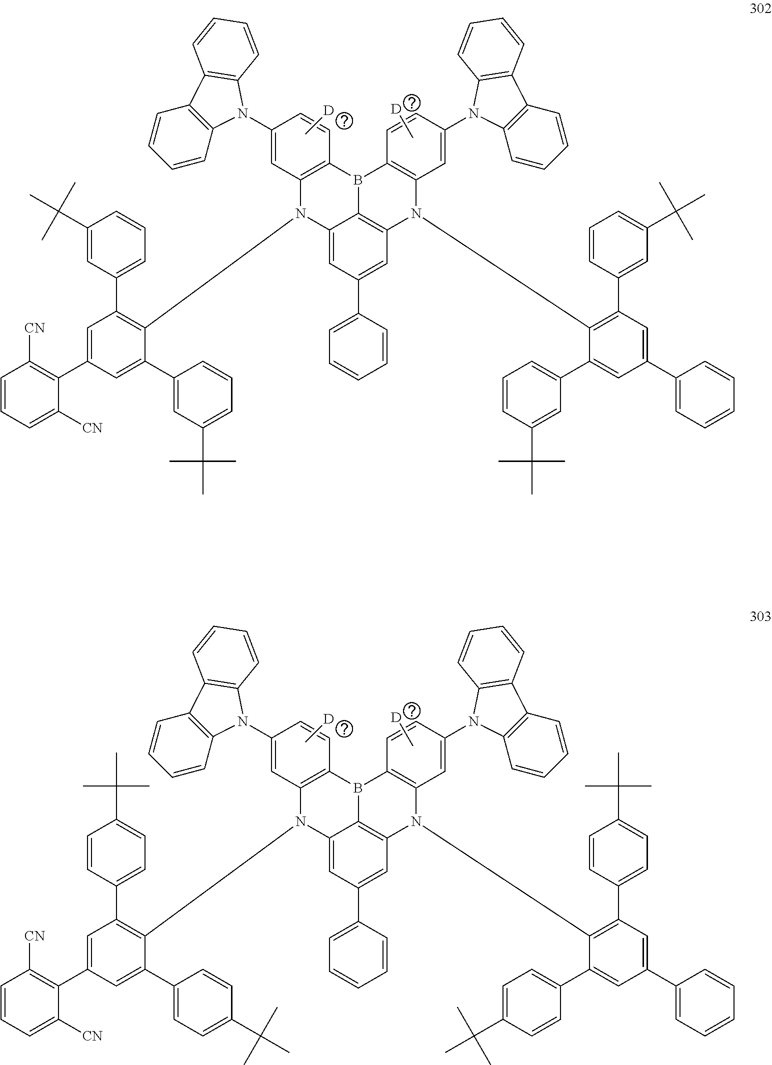 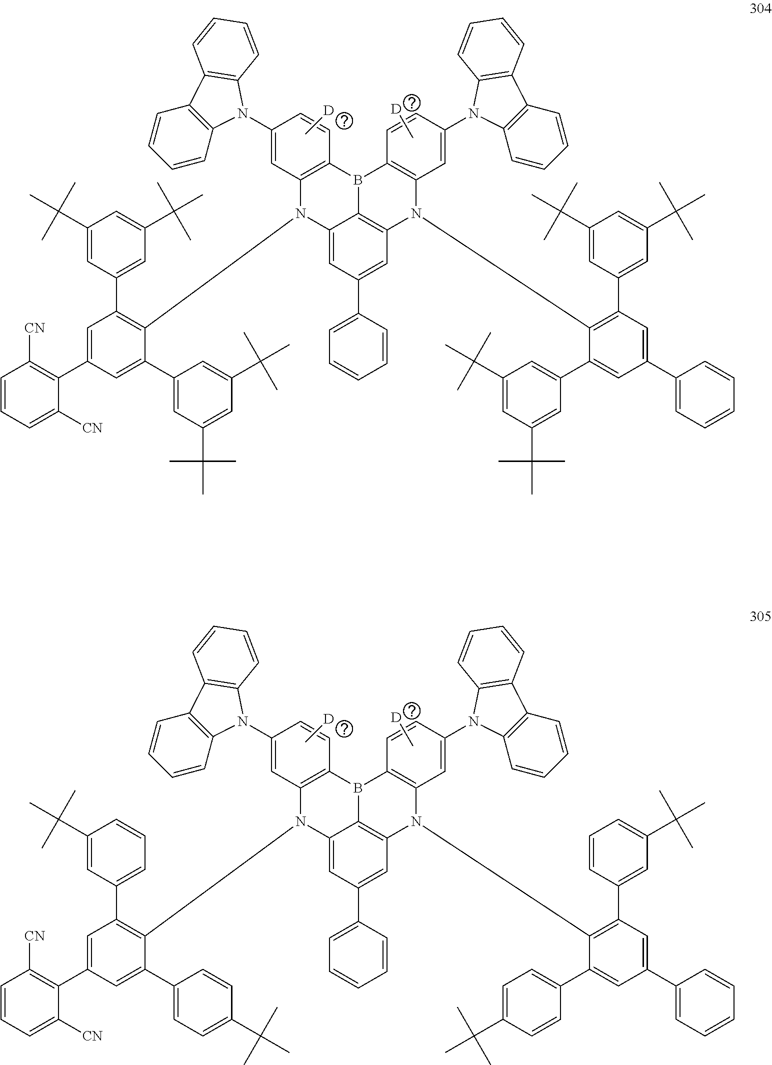 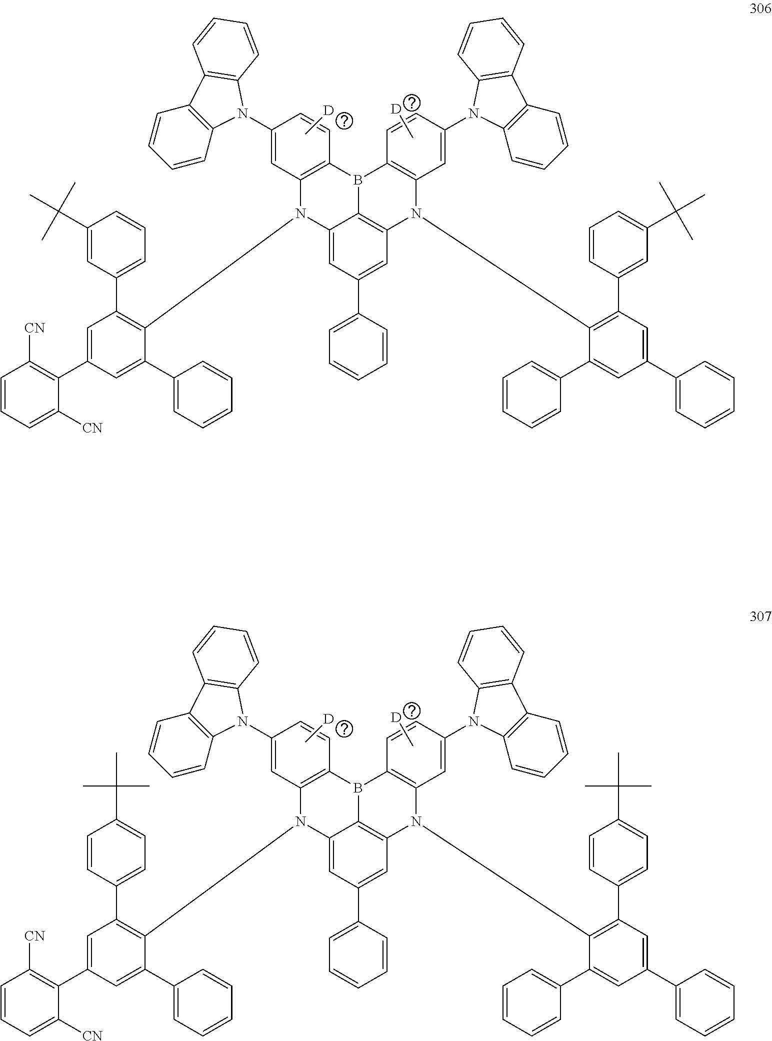 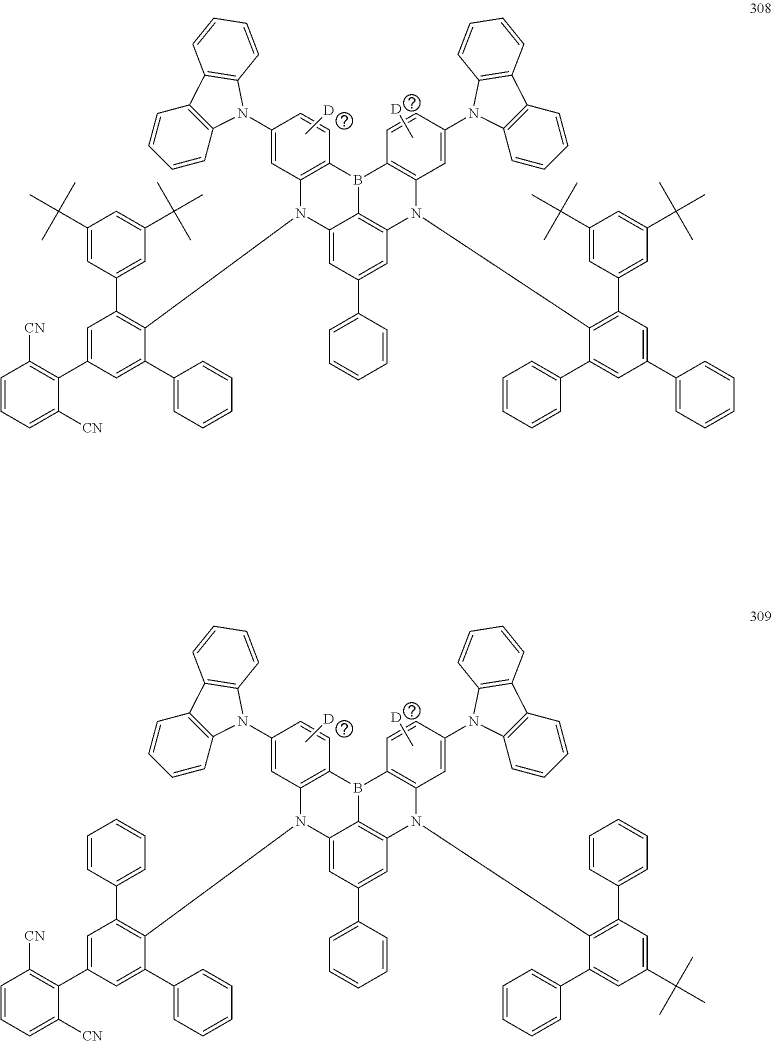 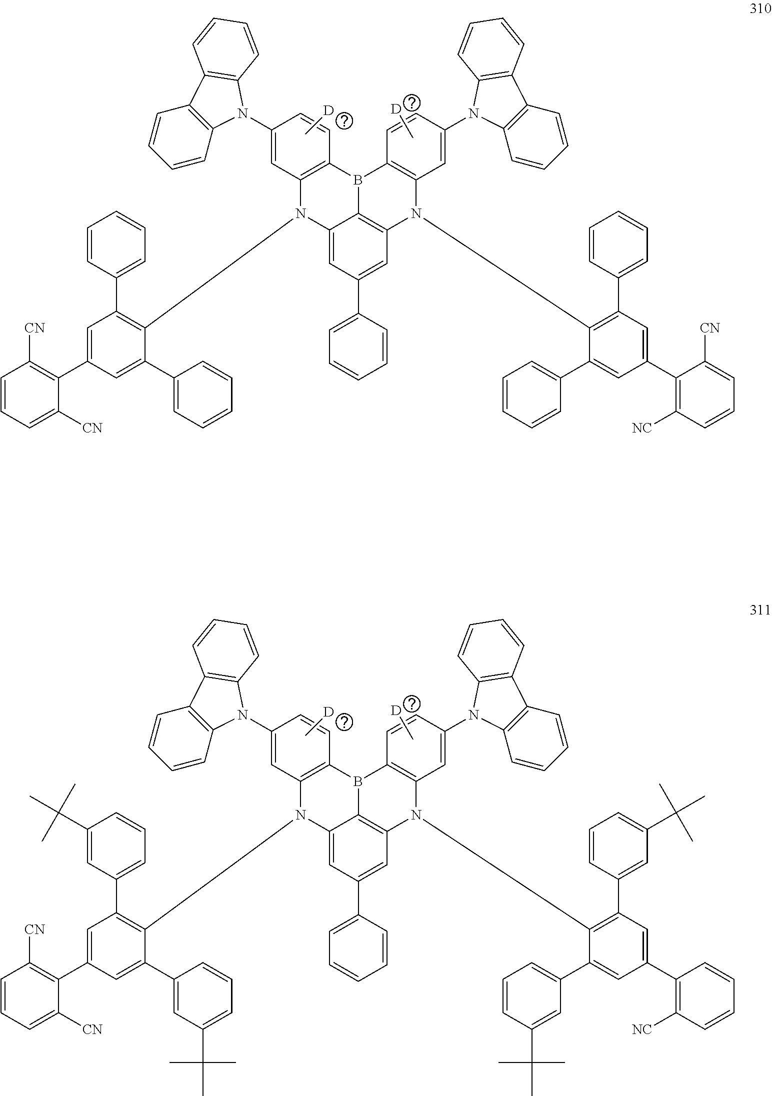 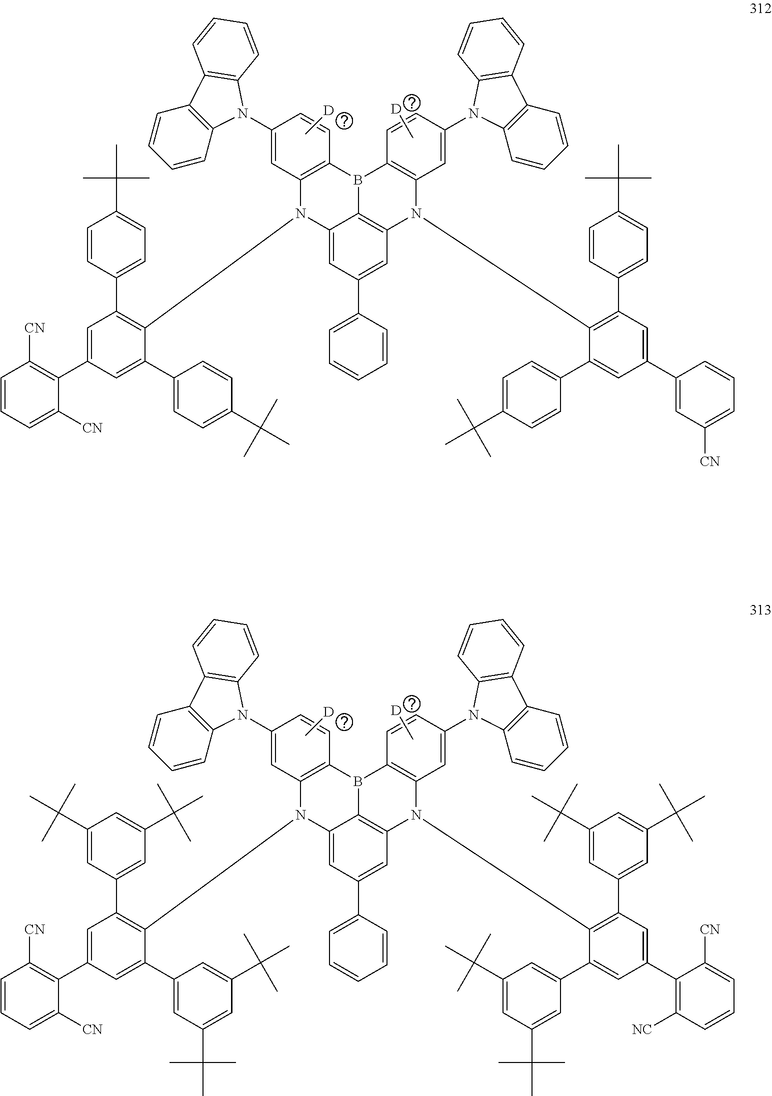 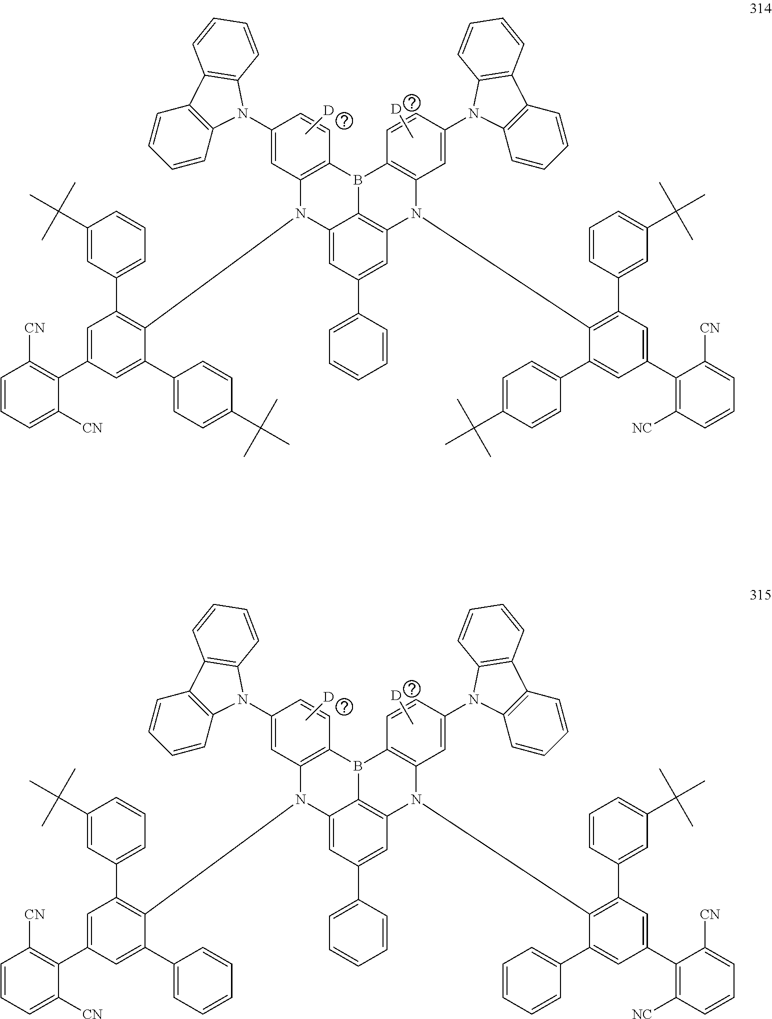 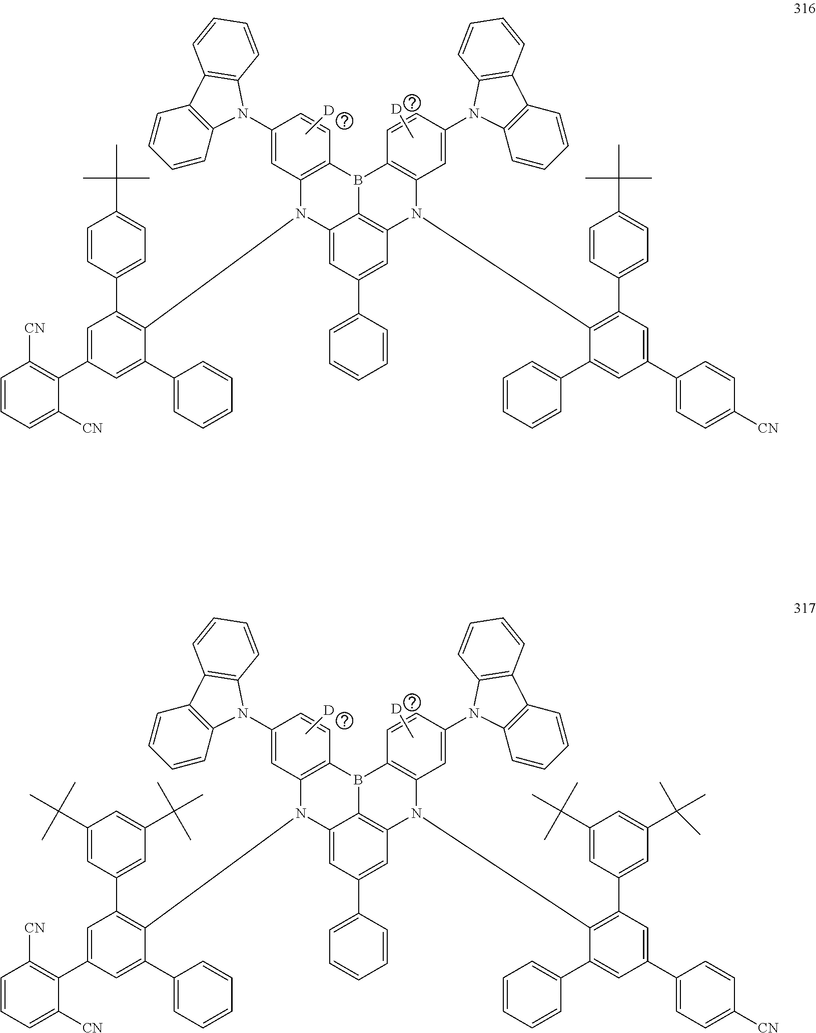 [chemical structure]
